(19) United States
(12) Patent Application Publication
(10) Pub. No.: US 2024/0260467 A1
(43) Pub. Date: Aug. 1, 2024

(54) LIGHT EMITTING ELEMENT AND POLYCYCLIC COMPOUND FOR THE SAME

(71) Applicant: Samsung Display Co., Ltd., Yongin-si (KR)

(72) Inventors: Hirokazu KUWABARA, Yokohama (JP); Keigo HOSHI, Yokohama (JP); Ryuhei FURUE, Yokohama (JP)

(73) Assignee: Samsung Display Co., Ltd., Yongin-si (KR)

(21) Appl. No.: 18/530,901

(22) Filed: Dec. 6, 2023

(30) Foreign Application Priority Data
Dec. 6, 2022 (KR) 10-2022-0169165

(51) Int. Cl. H10K 85/60; C07B 59/00; C09K 11/06; H10K 85/30; H10K 85/40

(52) U.S. Cl. CPC H10K 85/658; C07B 59/004; C09K 11/06; H10K 85/346; H10K 85/40; H10K 85/622; H10K 85/623; H10K 85/631; H10K 85/654; H10K 85/6572; H10K 2101/20

(57) ABSTRACT

Embodiments provide a light emitting element that includes a first electrode, a second electrode disposed on the first electrode, and an emission layer disposed between the first electrode and the second electrode. the emission layer includes a polycyclic compound represented by Formula 1, which is explained in the specification.

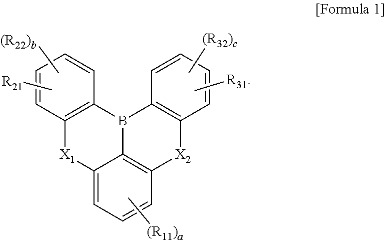

### CROSS-REFERENCE TO RELATED APPLICATION(S)

This application claims priority to and benefits of Korean Patent Application No. 10-2022-0169165 under 35 U.S.C. § 119, filed on Dec. 6, 2022 in the Korean Intellectual Property Office, the entire contents of which are incorporated herein by reference.

### BACKGROUND

### 1. Technical Field

The disclosure relates to a light emitting element and a polycyclic compound used therein.

### 2. Description of the Related Art

Active development continues for organic electroluminescence display devices and the like as image display devices. In contrast to liquid crystal display devices and the like, an organic electroluminescence display device is a so-called self-luminescent display device in which holes and electrons respectively injected from a first electrode and a second electrode recombine in an emission layer, so that a light emitting material that includes an organic compound in the emission layer emits light to achieve display.

In the application of organic electroluminescence elements to display devices, there is a demand for organic electroluminescence elements having a low driving voltage, high light emitting efficiency, and long service life, and continuous development is required on materials for organic electroluminescence elements that are capable of stably achieving such characteristics.

In order to implement a highly efficient organic electroluminescence element, technologies pertaining to phosphorescence emission using triplet state energy or to delayed fluorescence using triplet-triplet annihilation (TTA) in which singlet excitons are generated through collision of triplet excitons are being developed. Development is currently directed to thermally activated delayed fluorescence (TADF) materials which uses delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having increased service life.

The disclosure also provides a polycyclic compound as a material for a light emitting element, which increases service life.

An embodiment provides a light emitting element which may include a first electrode, a second electrode disposed on the first electrode, and an emission layer disposed between the first electrode and the second electrode, wherein the emission layer may include a first compound represented by Formula 1, and at least one of a second compound and a third compound.

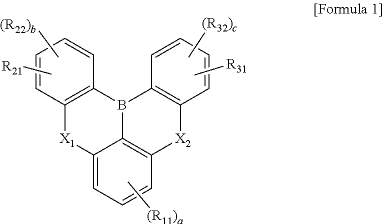

In Formula 1, a to c may each independently be an integer from 0 to 3; X₁ and X₂ may each independently be O, S, or N(Rₐ); at least one of R₂₁ and R₃₁ may each independently be a group represented by Formula 2; the remainder of R₂₁ and R₃₁ may be a substituted or unsubstituted aryl group having 6 to 30 ring-forming carbon atoms, or a substituted or unsubstituted heteroaryl group having 2 to 30 ring-forming carbon atoms; Rₐ may be a substituted or unsubstituted aryl group having 6 to 30 ring-forming carbon atoms, or a substituted or unsubstituted heteroaryl group having 2 to 30 ring-forming carbon atoms, and may not be a group represented by Formula 2; R₁₁, R₂₂, and R₃₂ may each independently be a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; and at least one hydrogen atom in Formula 1 may be optionally substituted with a deuterium atom.

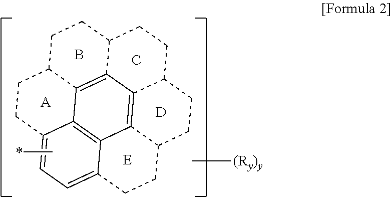

In Formula 2, at least two of A to E may each be a benzene ring; the remainder of A to E may not be present; y may be an integer from 0 to 11; R_{y} may be a hydrogen atom, a deuterium atom, a halogen atom, or a substituted or unsubstituted alkyl group having 1 to 20 carbon atoms; and at least one hydrogen atom in Formula 2 may be optionally substituted with a deuterium atom.

In an embodiment, the first compound may be represented by Formula 3-1 or Formula 3-2.

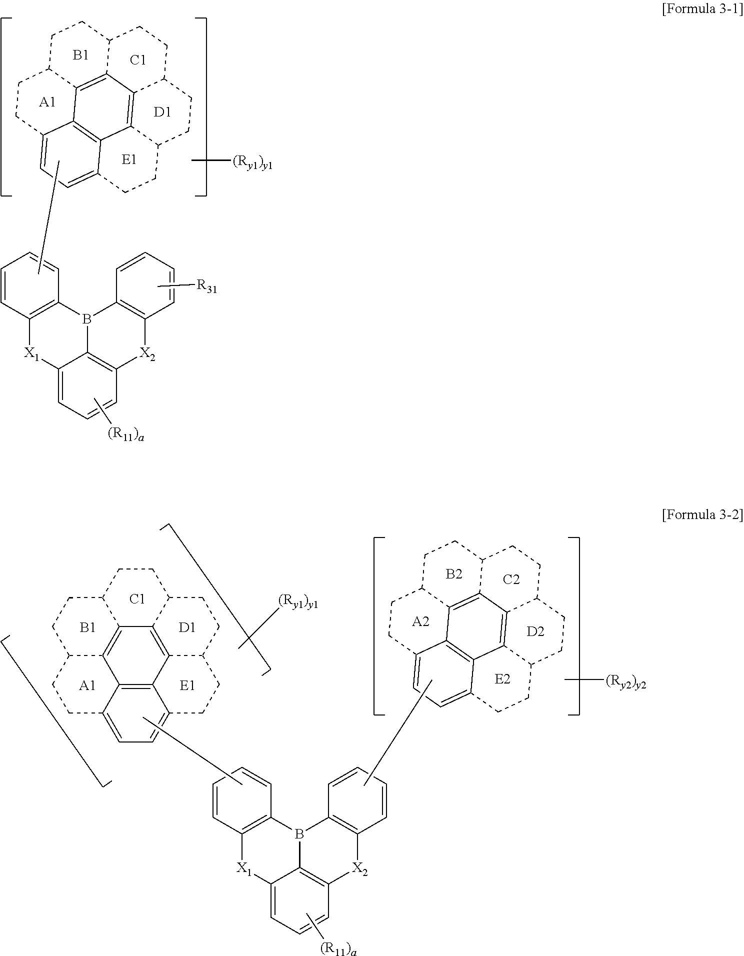

In Formulas 3-1 and 3-2, at least two of A1 to E1 may each be a benzene ring; the remainder of A1 to E1 may not be present; at least two of A2 to E2 may each be a benzene ring; the remainder of A2 to E2 may not be present; y1 and y2 may each independently be an integer from 0 to 11; R_{y1} and R_{y}2 may each independently be a hydrogen atom, a deuterium atom, a halogen atom, or a substituted or unsubstituted alkyl group having 1 to 20 carbon atoms; a, R₁₁, R₃₁, X₁, and X₂ are the same as defined in Formula 1; and at least one hydrogen atom in Formulas 3-1 and 3-2 may be optionally substituted with a deuterium atom.

In an embodiment, in Formula 3-1, R₃₁ may be a substituted or unsubstituted carbazole group or a substituted or unsubstituted phenyl group.

In an embodiment, the first compound may be represented by any one of Formulas 4-1 to 4-3.

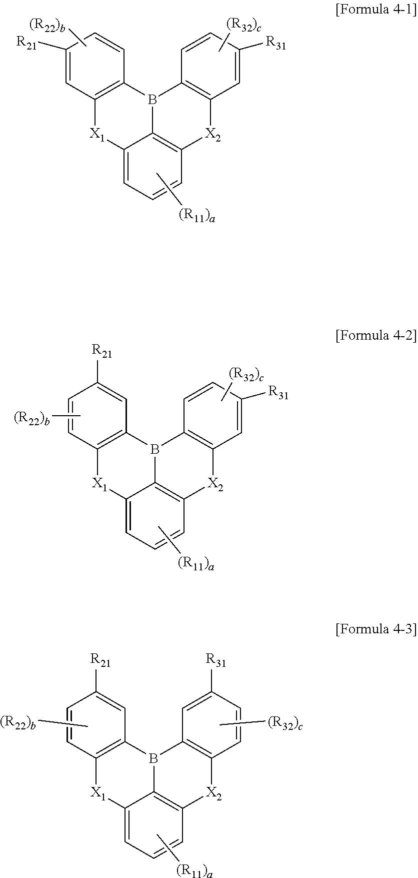

In Formulas 4-1 to 4-3, a, b, c, X₁, X₂, R₁₁, R₂₁, R₃₁, R₂₂, and R₃₂ are the same as defined in Formula 1; and at least one hydrogen atom in Formulas 4-1 to 4-3 may be optionally substituted with a deuterium atom.

In an embodiment, the first compound may be represented by Formula 5.

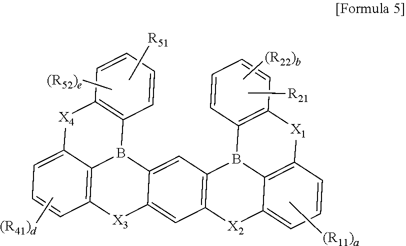

In Formula 5, at least one of R₂₁ and R₅₁ may each independently be a group represented by Formula 2; the remainder of R₂₁ and R₅₁ may be a substituted or unsubstituted aryl group having 6 to 30 ring-forming carbon atoms or a substituted or unsubstituted heteroaryl group having 2 to 30 ring-forming carbon atoms; X₃ and X₄ may each independently be O, S, or N(R_{b}); d and e may each independently be an integer from 0 to 3; Re may be a substituted or unsubstituted aryl group having 6 to 30 ring-forming carbon atoms or a substituted or unsubstituted heteroaryl group having 2 to 30 ring-forming carbon atoms, and may not be a group represented by Formula 2; R₄₁ and R₅₂ may each independently be a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; a, b, R₁₁, R₂₂, X₁, and X₂ are the same as defined in Formula 1; and at least one hydrogen atom in Formula 5 may be optionally substituted with a deuterium atom.

In an embodiment, a group represented by Formula 2 may be represented by any one of Formulas D1 to D6.

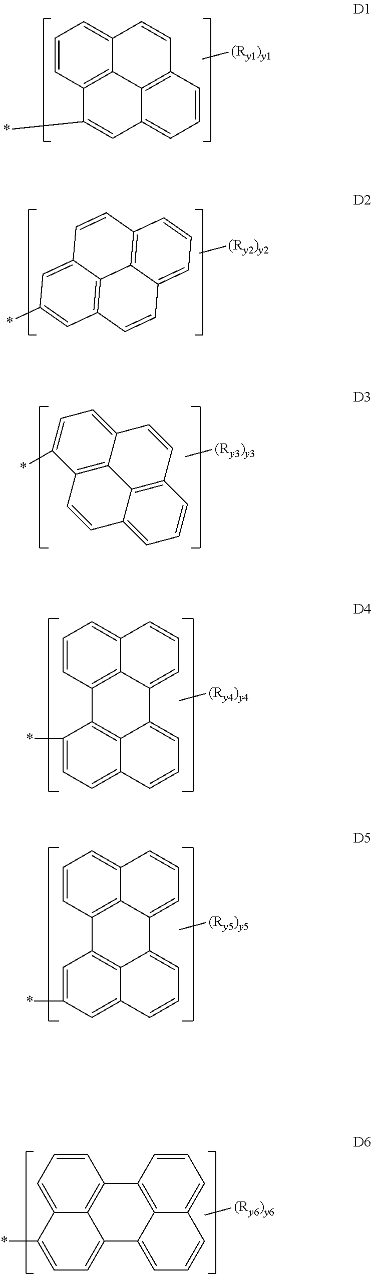

In Formulas D1 to D6, y1 to y3 may each independently be an integer from 0 to 9; y4 to y6 may each independently be an integer from 0 to 11; R_{y1} to R_{y6} may each independently be a hydrogen atom, a deuterium atom, or an unsubstituted t-butyl group; and at least one hydrogen atom in Formulas D1 to D6 may be optionally substituted with a deuterium atom.

In an embodiment, the second compound may be represented by Formula HT-1.

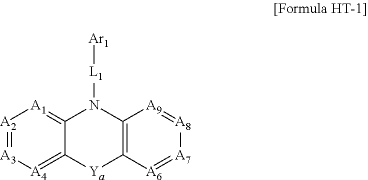

In Formula HT-1, A₁ to A₄ and A₆ to A₉ may each independently be N or C(R₄₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₄₂)(R₄₃), or Si(R₄₄)(R₄₅); Ar₁ may be a substituted or unsubstituted aryl group having 6 to 30 ring-forming carbon atoms or a substituted or unsubstituted heteroaryl group having 2 to 30 ring-forming carbon atoms; and R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

In an embodiment, the third compound may be represented by Formula ET-1.

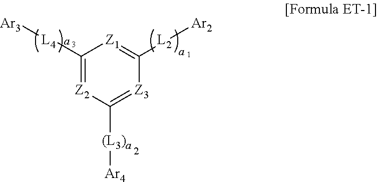

In Formula ET-1, at least one of Z₁ to Z₃ may each be N; the remainder of Z₁ to Z₃ may each independently be C(Rₐ₃); R₃ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; a₁ to a₃ may each independently be an integer from 0 to 10; L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms; and Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer may further include a fourth compound; and the fourth compound may be represented by Formula D-1.

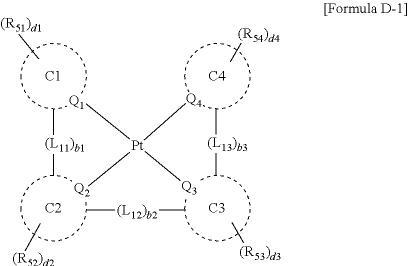

In Formula D-1, Q₁ to Q₄ may each independently be C or N; C1 to C4 may each independently be a substituted or unsubstituted hydrocarbon ring having 5 to 30 ring-forming carbon atoms or a substituted or unsubstituted heterocycle having 2 to 30 ring-forming carbon atoms; L₁₁ to L₁₃ may each independently be a direct linkage,

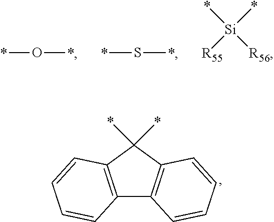

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon [symbol] atoms; in L₁₁ to L₁₃, [symbol] represents a bond to one of C1 to C4; b1 to b3 may each independently be 0 or 1; R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and d1 to d4 may each independently be an integer from 0 to 4.

In an embodiment, the emission layer may include the first compound, the second compound, the third compound, and the fourth compound.

In an embodiment, the emission layer may emit blue light.

In an embodiment, the emission layer may emit thermally activated delayed fluorescence.

In an embodiment, the emission layer may include at least one compound selected from Compound Group 1, which is explained below.

An embodiment provides a polycyclic compound which may be represented by Formula 1.

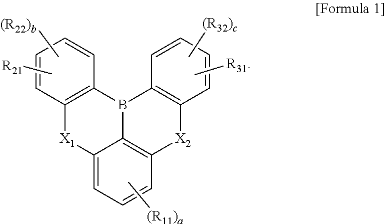

In Formula 1, a to c may each independently be an integer from 0 to 3; X₁ and X₂ may each independently be O, S, or N(Rₐ); at least one of R₂₁ and R₃₁ may each independently be a group represented by Formula 2; the remainder of R₂₁ and R₃₁ may be a substituted or unsubstituted aryl group having 6 to 30 ring-forming carbon atoms or a substituted or unsubstituted heteroaryl group having 2 to 30 ring-forming carbon atoms; Rₐ may be a substituted or unsubstituted aryl group having 6 to 30 ring-forming carbon atoms or a substituted or unsubstituted heteroaryl group having 2 to 30 ring-forming carbon atoms, and may not be a group represented by Formula 2; R₁₁, R₂₂, and R₃₂ may each independently be a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; and at least one hydrogen atom in Formula 1 may be optionally substituted with a deuterium atom.

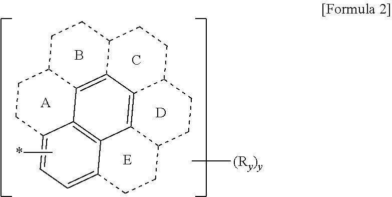

In Formula 2, at least two of A to E may each be a benzene ring; the remainder of A to E may not be present; y may be an integer from 0 to 11; R_{y} may be a hydrogen atom, a deuterium atom, a halogen atom, or a substituted or unsubstituted alkyl group having 1 to 20 carbon atoms; and at least one hydrogen atom in Formula 2 may be optionally substituted with a deuterium atom.

In an embodiment, Formula 1 may be represented by Formula 3-1 or Formula 3-2.

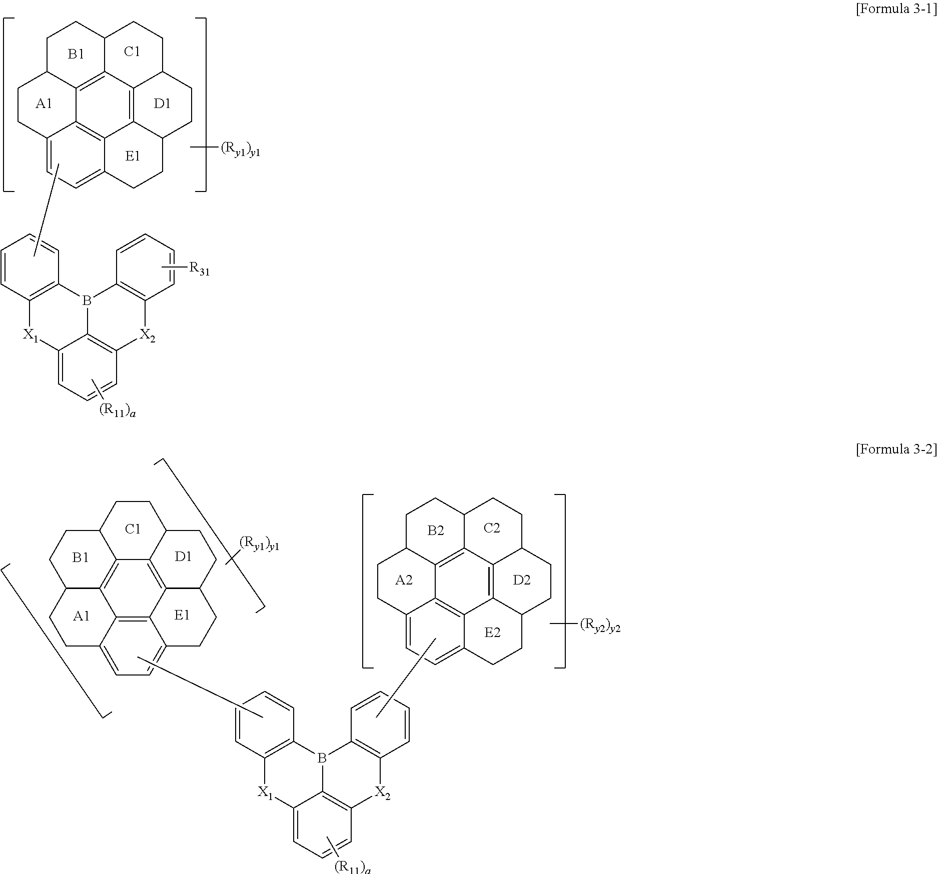

In Formulas 3-1 and 3-2, at least two of A1 to E1 may each be a benzene ring; the remainder of A1 to E1 may not be present; at least two of A2 to E2 may each be a benzene ring; the remainder of A2 to E2 may not be present; y1 and y2 may each independently be an integer from 0 to 11; R_{y1} and R_{y2} may each independently be a hydrogen atom, a deuterium atom, a halogen atom, or a substituted or unsubstituted alkyl group having 1 to 20 carbon atoms; a, R₁, R₃₁, X₁, and X₂ are the same as defined in Formula 1; and at least one hydrogen atom in Formulas 3-1 and 3-2 may be optionally substituted with a deuterium atom.

In an embodiment, in Formula 3-1, R₃₁ may be a substituted or unsubstituted carbazole group or a substituted or unsubstituted phenyl group.

In an embodiment, Formula 1 may be represented by any one of Formulas 4-1 to 4-3.

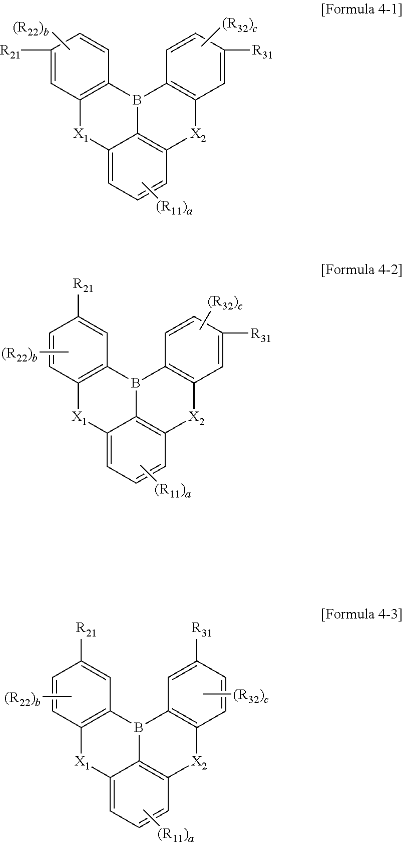

In Formulas 4-1 to 4-3, a, b, c, X₁, X₂, R₁₁, R₂₁, R₃₁, R₂₂, and R₃₂ are the same as defined in Formula 1; and at least one hydrogen atom in Formulas 4-1 to 4-3 may be optionally substituted with a deuterium atom.

In an embodiment, Formula 1 may be represented by Formula 5.

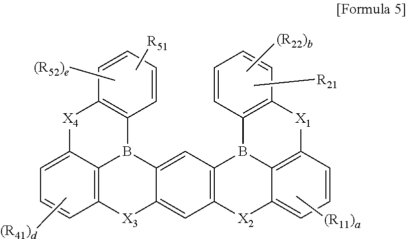

In Formula 5, at least one of R₂₁ and R₅₁ may each independently be a group represented by Formula 2; the remainder of R₂₁ and R₅₁ may be a substituted or unsubstituted aryl group having 6 to 30 ring-forming carbon atoms or a substituted or unsubstituted heteroaryl group having 2 to 30 ring-forming carbon atoms; X₃ and X₄ may each independently be O, S, or N(R_{b}); d and e may each independently be an integer from 0 to 3; R_{b} may be a substituted or unsubstituted aryl group having 6 to 30 ring-forming carbon atoms or a substituted or unsubstituted heteroaryl group having 2 to 30 ring-forming carbon atoms, and may not be a group represented by Formula 2; R₄₁ and R₅₂ may each independently be a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; a, b, R₁₁, R₂₂, X₁, and X₂ are the same as defined in Formula 1; and at least one hydrogen atom in Formula 5 may be optionally substituted with a deuterium atom.

In an embodiment, a group represented by Formula 2 may be represented by any one of Formulas D1 to D6.

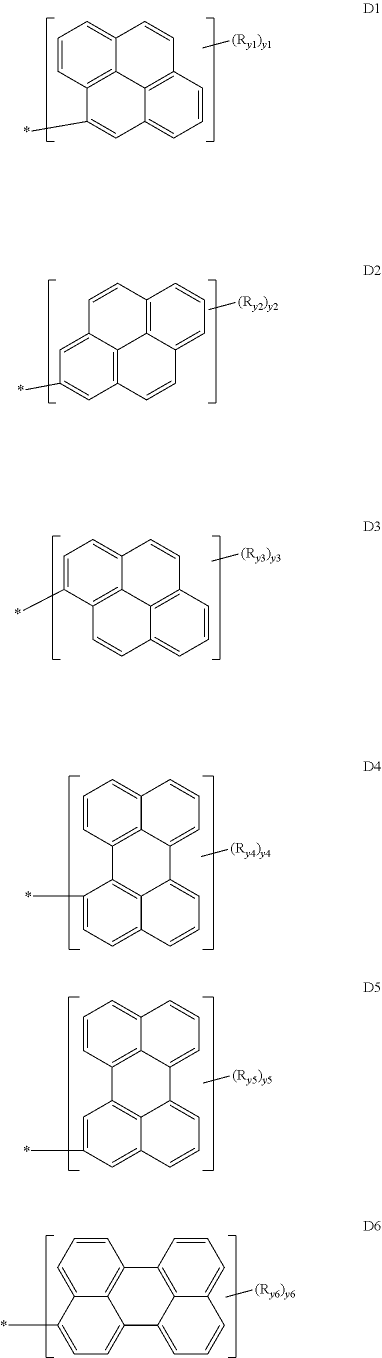

In Formulas D1 to D6, y1 to y3 may each independently be an integer from 0 to 9; y4 to y6 may each independently be an integer from 0 to 11; R_{y}1 to R_{y6} may each independently be a hydrogen atom, a deuterium atom, or an unsubstituted t-butyl group; and at least one hydrogen atom in Formulas D1 to D6 may be optionally substituted with a deuterium atom.

In an embodiment, the polycyclic compound represented by Formula 1 may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an electronic device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly connected to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. For example, two methyl groups in 4,5-dimethylphenanthrene may be interpreted as mutually “adjacent groups”.

In the specification, examples of a halogen atom may include a fluorine atom, a chlorine atom, a bromine atom, and an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and the like, but are not limited thereto.

In the specification, an alkenyl group may be a hydrocarbon group including at least one carbon-carbon double bond in the middle or an end of an alkyl group having 2 or more carbon atoms. An alkenyl group may be linear or branched. The number of carbon atoms in an alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, and the like, but are not limited thereto.

In the specification, an alkynyl group may be a hydrocarbon group including at least one carbon-carbon triple bond in the middle or an end of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, and the like, but are not limited thereto.

In the specification, a hydrocarbon ring group may be any functional group or substituent derived from an aliphatic hydrocarbon ring. A hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but are not limited thereto.

In the specification, a fluorenyl group may be substituted, and two substituents may be bonded to each other to form a spiro structure. Examples of a substituted fluorenyl group may include the compounds shown below. However, embodiments are not limited thereto.

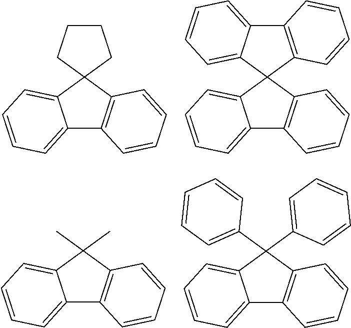

In the specification, a heterocyclic group may be any functional group or substituent derived from a ring including at least one of B, O, N, P, Si, or S as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, or S as a heteroatom. When a heterocyclic group contains two or more heteroatoms, the two or more heteroatoms may be the same as or different from each other. A heterocyclic group may be monocyclic or polycyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and the like, but are not limited to thereto.

In the specification, a heteroaryl group may include at least one of B, O, N, P, Si, or S as a heteroatom. When a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and the like, but are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the specification, the number of carbon atoms in an amino group is not particularly limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, and the like, but are not limited thereto.

In the specification, the number of carbon atoms in a carbonyl group is not particularly limited, but may be 1 to 40, 1 to 30, or 1 to 20. For example, a carbonyl group may have one of the following structures, but is not limited thereto.

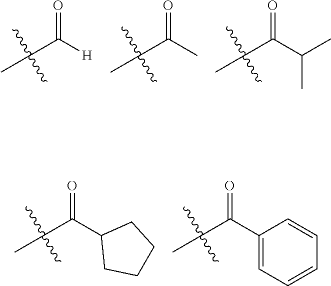

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkyl thio group or an aryl thio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but are not limited to thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20, or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and the like, but are not limited thereto.

In the specification, a boron group may be a boron atom that is bonded to an alkyl group or to an aryl group as defined above. A boron group may be an alkyl boron group or an aryl boron group. Examples of a boron group may include a dimethyl boron group, a diethyl boron group, a t-butylmethyl boron group, a diphenyl boron group, a phenyl boron group, and the like, but are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, and the like, but are not limited thereto.

In the specification, examples of the alkyl group may include an alkylthio group, an alkyl sulfoxy group, an alkylaryl group, an alkylamino group, an alkyl boron group, an alkyl silyl group, and an alkyl amine group.

In the specification, examples of the aryl group may include an aryloxy group, an arylthio group, an aryl sulfoxy group, an arylamino group, an aryl boron group, an aryl silyl group, and an aryl amine group.

In the specification, a direct linkage may be a single bond.

In the specification, the symbols [symbol] and [symbol] each represent a bond to a neighboring atom in a corresponding formula or moiety.

Hereinafter, embodiments will be described with reference to the accompanying drawings.

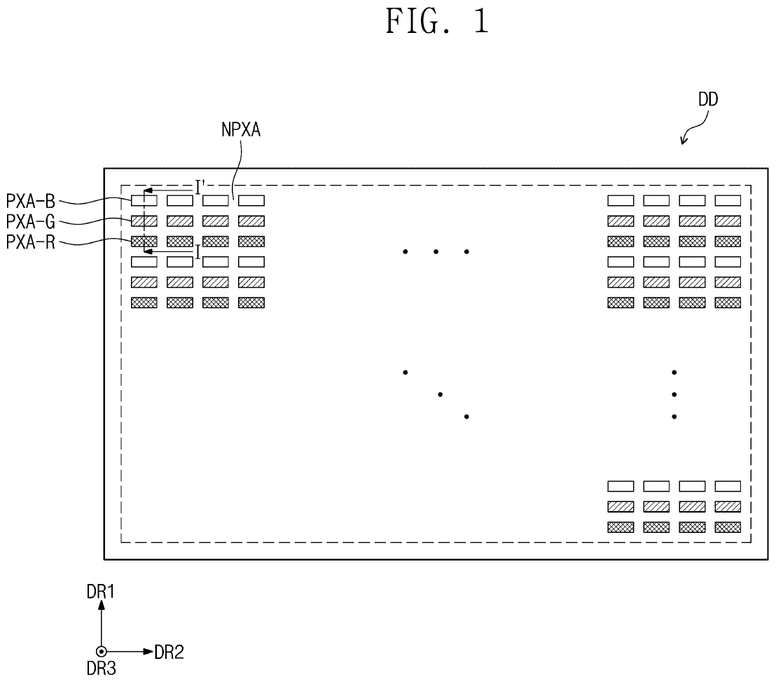

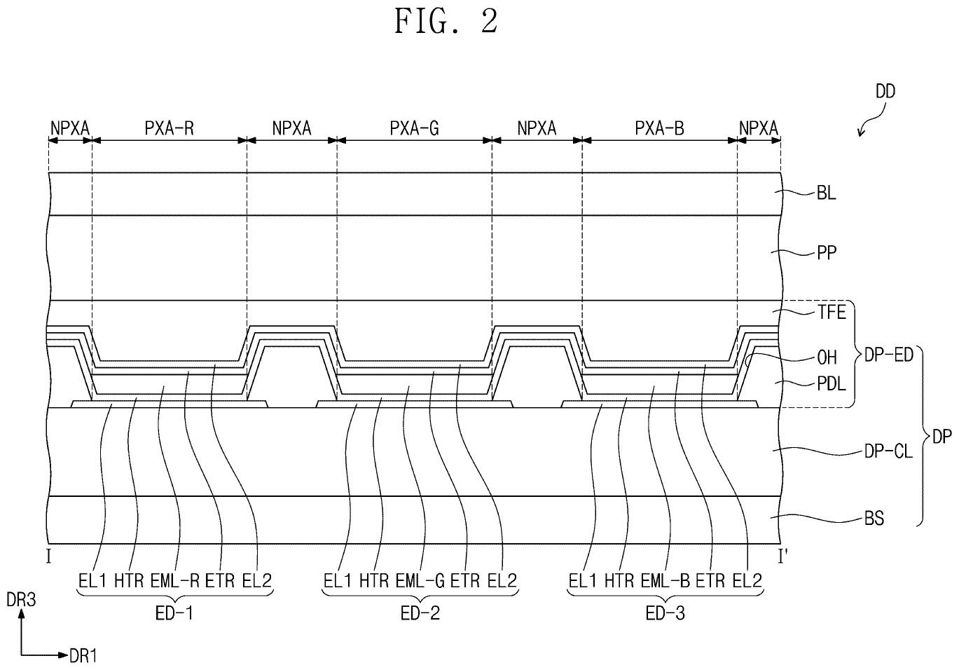

FIG. 1 is a schematic plan view of a display device DD according to an embodiment. FIG. 2 is a schematic cross-sectional view of a display device DD according to an embodiment. FIG. 2 is a schematic cross-sectional view showing a portion corresponding to line I-I′ in FIG. 1.

A display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP and may control light that is reflected at the display panel DP from an external light. The optical layer PP may include, for example, a polarizing layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, or the like. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, light emitting elements ED-1, ED-2, and ED-3 disposed between the pixel defining films PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, or the like. However, embodiments are not limited thereto, and the base layer BS may include an inorganic layer, an organic layer, or a composite material layer.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

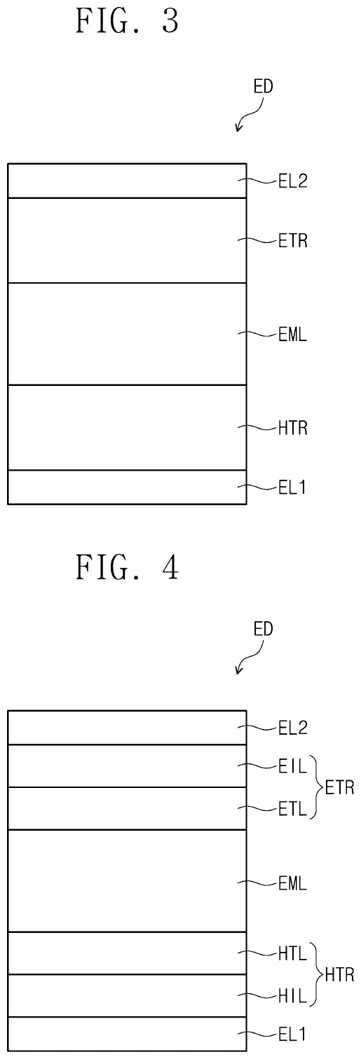

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are each provided as a common layer throughout the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining films PDL. For example, in an embodiment, the hole transport region HTR, the emission layers EML-R, EML-G, and EML-B, and the electron transport region ETR of the light emitting elements ED-1, ED-2, and ED-3 may each be patterned and provided through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a stack of multiple layers. The encapsulation layer TFE may include at least one insulating layer. In an embodiment, the encapsulation layer TFE may include at least one inorganic film (hereinafter, an encapsulation inorganic film). In an embodiment, the encapsulation layer TFE may include at least one organic film (hereinafter, an encapsulation organic film) and at least one encapsulation inorganic film.

The encapsulation inorganic film protects the display element layer DP-ED from moisture and/or oxygen, and the encapsulation organic film protects the display element layer DP-ED from foreign substances such as dust particles. The encapsulation inorganic film may include silicon nitride, silicon oxy nitride, silicon oxide, titanium oxide, aluminum oxide, and the like, but is not limited thereto. The encapsulation organic film may include an acrylic-based compound, an epoxy-based compound, or the like. The encapsulation organic film may include a photopolymerizable organic material, but embodiments are not limited thereto.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining films PDL. The non-light emitting regions NPXA may be regions between the neighboring light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2 and ED-3 may be disposed in the openings OH defined by the pixel defining films PDL and separated from each other.

The light emitting regions PXA-R, PXA-G, and PXA-B may be arranged into groups according to the color of light generated from the light emitting elements ED-1, ED-2, and ED-3. In the display device DD according to an embodiment shown in FIGS. 1 and 2, three light emitting regions PXA-R, PXA-G, and PXA-B which respectively emit red light, green light, and blue light, are shown as an example. For example, the display device DD may include a red light emitting region PXA-R, a green light emitting region PXA-G, and a blue light emitting region PXA-B, which are distinct from one another.

In the display device DD according to an embodiment, the light emitting elements ED-1, ED-2, and ED-3 may emit light having wavelength ranges that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2 and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 show that the light emitting regions PXA-R, PXA-G, and PXA-B are all similar in size, but embodiments are not limited thereto. In an embodiment, the light emitting regions PXA-R, PXA-G and PXA-B may be different in size from each other, according to a wavelength range of emitted light. For example, the areas of the light emitting regions PXA-R, PXA-G, and PXA-B may be areas in a plan view that are defined by the first directional axis DR1 and the second directional axis DR2. A third direction axis DR3 may be perpendicular to a plane that is defined by the first direction axis DR1 and the second direction axis DR2.

An arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged may be provided in various combinations according to the display quality characteristics that are required for the display device DD. For example, the light emitting regions PXA-R, PXA-G, and PXA-B may be arranged in a pentile configuration (such as PENTILE®) or in a diamond configuration (such as Diamond Pixel®).

The areas of each of the light emitting regions PXA-R, PXA-G, and PXA-B may be different in size from one another. For example, in an embodiment, the green light emitting region PXA-G may be smaller than the blue light emitting region PXA-B in size, but embodiments are not limited thereto.

Hereinafter, FIGS. 3 to 6 are each a schematic cross-sectional view of a light emitting element according to an embodiment. The light emitting element ED according to an embodiment shown in FIGS. 3 to 6 may each include a first electrode EL1, a hole transport region HTR, an emission layer EML, an electron transport region ETR, and a second electrode EL2.

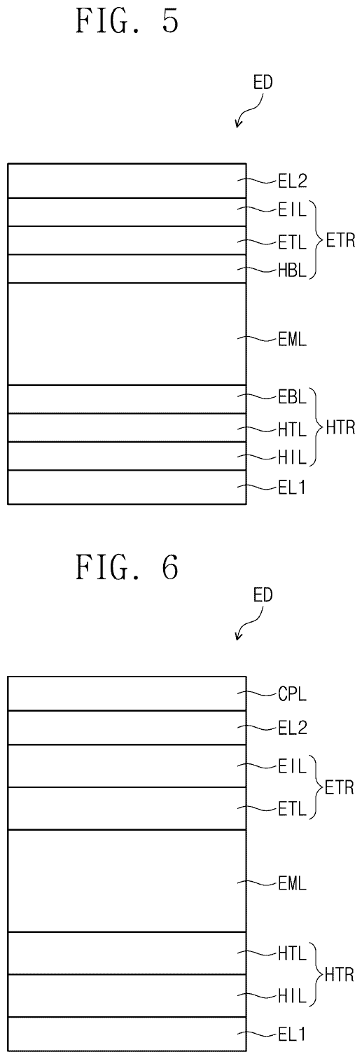

FIG. 4 shows, as compared with FIG. 3, a schematic cross-sectional view of a light emitting element ED according to an embodiment in which the hole transport region HTR includes a hole injection layer HIL and a hole transport layer HTL, and the electron transport region ETR includes an electron injection layer EIL and an electron transport layer ETL. FIG. 5 shows, as compared with FIG. 3, a schematic cross-sectional view of a light emitting element ED according to an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, as compared with FIG. 4, a schematic cross-sectional view of a light emitting element ED according to an embodiment, in which a capping layer CPL is disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

When the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, A1, Pt, Pd, Au, Ni, Nd, Ir, Cr, Li, Ca, LiF/Ca (a stack structure of LiF and Ca), LiF/A1 (a stack structure of LiF and A1), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), or the like. For example, the first electrode EL1 may have a three-layer structure of ITO/Ag/ITO, but embodiments are not limited thereto. In an embodiment, the first electrode EL1 may include the above-described metal materials, a combination of two or more metal materials selected from the above-described metal materials, or oxides of the above-described metal materials. The first electrode EL1 may have a thickness in a range of about 700 Å to about 10,000 Å. For example, the first electrode EL1 may have a thickness in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), a light emitting auxiliary layer (not shown), and an electron blocking layer EBL. The hole transport region HTR may have, for example, a thickness in a range of about 50 Å to about 15,000 Å.

The hole transport region HTR may be a layer consisting of a single material, a layer including different materials, or a structure including multiple layers including different materials.

In embodiments, the hole transport region HTR may have a single-layer structure formed of a hole injection layer HIL or a hole transport layer HTL, or may have a single-layer structure formed of a hole injection material or a hole transport material. In embodiments, the hole transport region HTR may have a single-layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1.

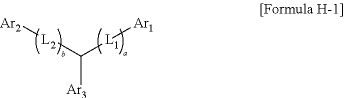

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, a compound represented by Formula H-1 may be a monoamine compound. In another embodiment, a compound represented by Formula H-1 may be a diamine compound in which at least one of Ar₁ to Ar₃ includes an amine group as a substituent. In yet another embodiment, a compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H.

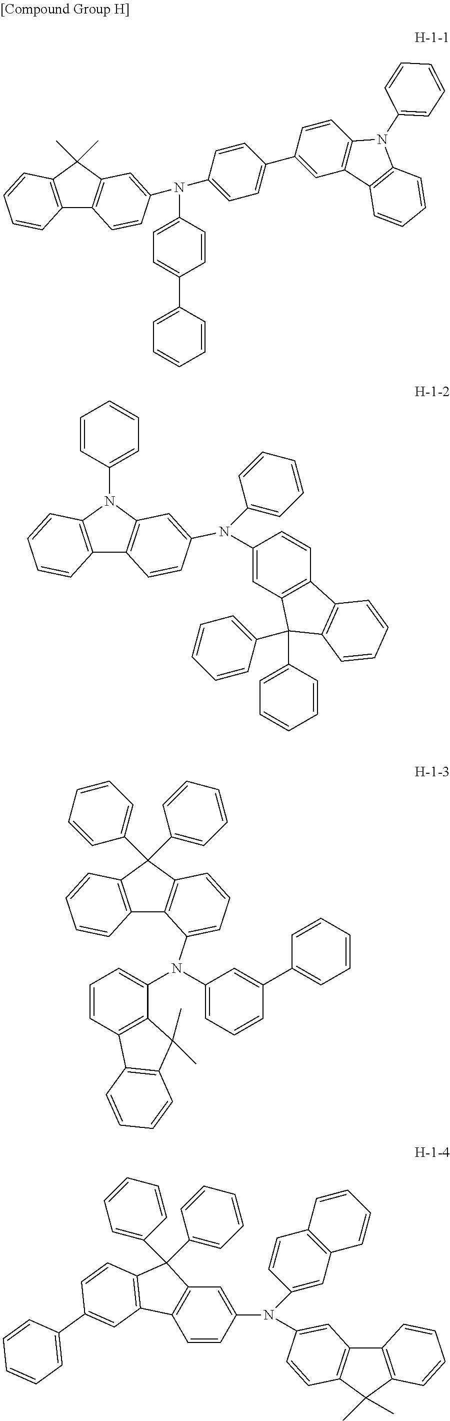 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

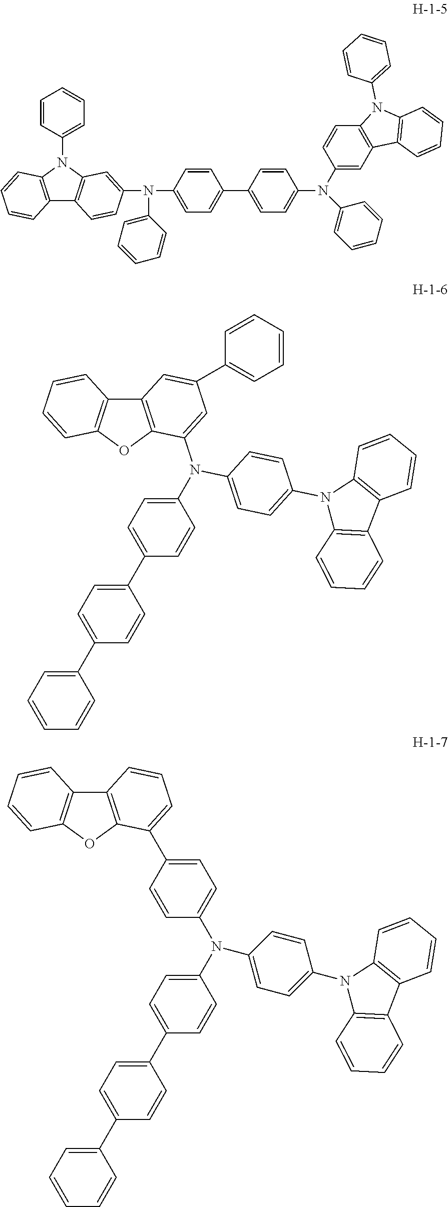

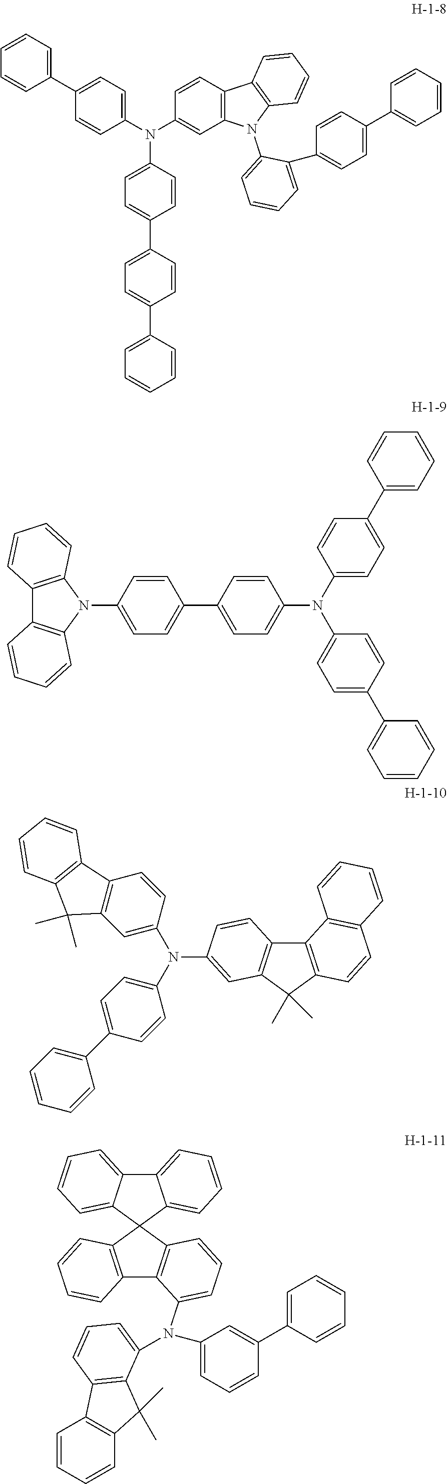

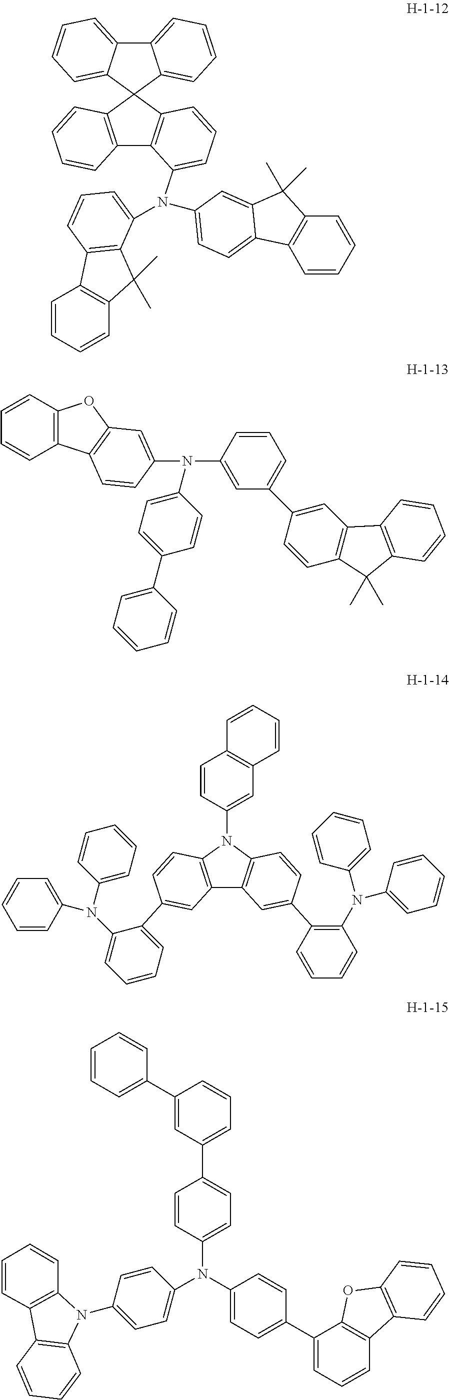 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

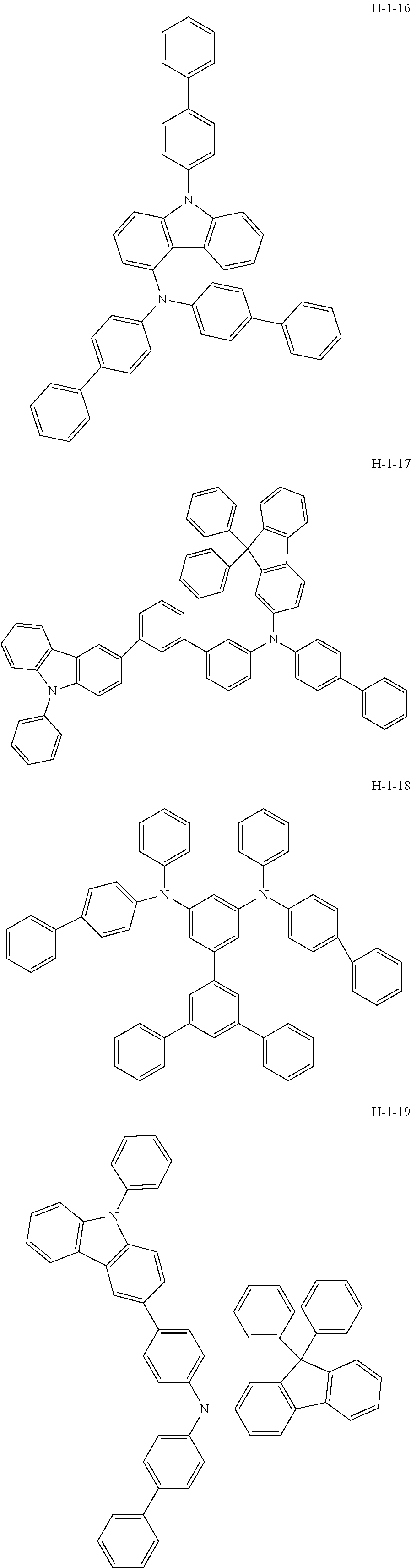 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrene sulfonate) (PEDOT/PSS), polyaniline/Dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h] quinoxaline-2,3,6,7,10,11-hexacarbonitrile (HATCN), and the like.

The hole transport region HTR may include carbazole-based derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and the like.

The hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and the like.

The hole transport region HTR may include the compounds of the hole transport region HTR described above in at least one of a hole injection layer HIL, a hole transport layer HTL, or an electron blocking layer EBL.

The hole transport region HTR may have a thickness in a range of about 100 Å to about 10,000 Å. For example, the hole transport region HTR may have a thickness in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but is not limited thereto.

For example, the p-dopant may include halogenated metal compounds such as CuI and RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and the like, but is not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from an emission layer EML, and may thus increase light emitting efficiency. Materials which may be included in the hole transport region HTR may be used as materials included in the buffer layer (not shown). The electron blocking layer EBL may prevent the injection of electrons from an electron transport region ETR to a hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

In an embodiment, the emission layer EML may include a polycyclic compound according to an embodiment. The polycyclic compound may be a dopant material. In the specification, the polycyclic compound according to an embodiment may be referred to as a first compound.

The polycyclic compound may include a structure in which aromatic rings are fused through a boron atom and two heteroatoms. For example, the polycyclic compound may include three aromatic rings that are bonded through a boron atom and two heteroatoms. In the specification, a structure in which three aromatic rings are bonded through a boron atom and two heteroatoms may be referred to as a “core”. The “core” in which three aromatic rings are bonded through a boron atom and two heteroatoms may have the structure shown below:

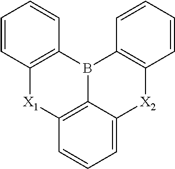

In another embodiment, the polycyclic compound may have a structure in which aromatic rings are fused through two boron atoms and four heteroatoms. For example, the polycyclic compound may include five aromatic rings that are bonded through two boron atoms and four heteroatoms. In the specification, a structure in which five aromatic rings are bonded through two boron atoms and four heteroatoms may be referred to as a “core”. The “core” in which five aromatic rings are bonded through two boron atoms and four heteroatoms may have the structure shown below:

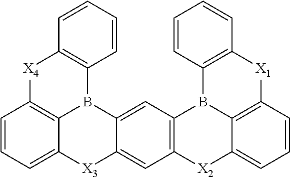

The polycyclic compound may have a structure in which at least one naphthyl substituent to which at least two benzene rings are fused is bonded to the core. For example, the polycyclic compound may include a pyrene derivative as a substituent of the core. The naphthyl substituent to which at least two benzene rings are fused contributes to increased stability of the core, and accordingly, the polycyclic compound may have improved material stability.

The polycyclic compound may have a structure having improved core stability, thereby contributing to an improvement in service life of the light emitting element ED. The light emitting element ED may include the polycyclic compound having increased stability in the emission layer EML to achieve long service life.

The polycyclic compound may be represented by Formula 1. Formula 1 includes a core in which three benzene rings are fused through a boron atom and two heteroatoms.

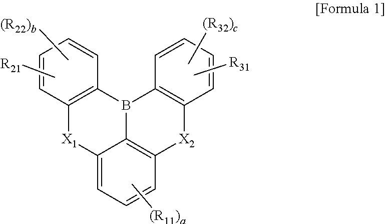

In Formula 1, a to c may each independently be an integer from 0 to 3. In Formula 1, a may indicate the number of R₁₁ groups. For example, when a is 0, no R₁₁ groups are included as a substituent, and when a is 1, one R₁₁ group is included as a substituent. A case in which a is 0 may be the same as a case in which a is 3 and all three R₁₁ groups are hydrogen atoms. When a is 2 or greater, multiple R₁₁ groups may all be the same, or at least one group thereof may be different from the remainder.

In Formula 1, b may indicate the number of R₂₂ groups. For example, when b is 0, no R₂₂ groups are included as a substituent, and when b is 1, one R₂₂ groups is included as a substituent. A case in which b is 0 may be the same as a case in which b is 3 and all three R₂₂ groups are hydrogen atoms. When b is 2 or greater, multiple R₂₂ groups may all be the same, or at least one group thereof may be different from the remainder.

In Formula 1, c may indicate the number of R₃₂ groups. For example, when c is 0, no R₃₂ groups are included as a substituent, and when a is 1, one R₃₂ group is included as a substituent. A case in which c is 0 may be the same as a case in which c is 3 and all three R₃₂ groups are hydrogen atoms. When c is 2 or greater, multiple R₃₂ groups may all be the same, or at least one group thereof may be different from the remainder.

In Formula 1, X₁ and X₂ may each independently be O, S, or N(Rₐ). X₁ and X₂ may be the same as or different from each other. In Formula 1, Rₐ may be a substituted or unsubstituted aryl group having 6 to 30 ring-forming carbon atoms, or a substituted or unsubstituted heteroaryl group having 2 to 30 ring-forming carbon atoms, and may not be a group represented by Formula 2, which will be explained later. For example, Rₐ may be a substituted or unsubstituted phenyl group, a substituted or unsubstituted biphenyl group, or a substituted or unsubstituted terphenyl group.

In Formula 1, R₁₁, R₂₂, and R₃₂ may each independently be a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula 1, at least one of R₂₁ and R₃₁ may each independently be a group represented by Formula 2; and the remainder of R₂₁ and R₃₁ may be a substituted or unsubstituted aryl group having 6 to 30 ring-forming carbon atoms or a substituted or unsubstituted heteroaryl group having 2 to 30 ring-forming carbon atoms. For example, one of R₂₁ and R₃₁ may be a group represented by Formula 2, or both R₂₁ and R₃₁ may each independently be a group represented by Formula 2. When only one of R₂₁ or R₃₁ is a group represented by Formula 2, the remainder of R₂₁ and R₃₁ may be a substituted or unsubstituted aryl group having 6 to 30 ring-forming carbon atoms or a substituted or unsubstituted heteroaryl group having 2 to 30 ring-forming carbon atoms.

The polycyclic compound may have a stable molecular structure when at least one of R₂₁ and R₃₁ is each independently a group represented by Formula 2, and the remainder of R₂₁ and R₃₁ is a substituted or unsubstituted aryl group having 6 to 30 ring-forming carbon atoms or a substituted or unsubstituted heteroaryl group having 2 to 30 ring-forming carbon atoms. For example, when at least one of R₂₁ and R₃₁ is each independently a group represented by Formula 2, the at least one group represented by Formula 2 resonates with the core. Accordingly, a low triplet energy of R₂₁ and/or R₃₁ is transferred to the core, and thus, the polycyclic compound may have a stable molecular structure.

In an embodiment, R₂₁ and R₃₁ may be directly bonded to the core without a linker. When at least one of R₂₁ and R₃₁ is a group represented by Formula 2 that is directly bonded to the core without a linker, the at least one group represented by Formula 2 does not have a twisted structure with the core. Accordingly, the at least one group represented by Formula 2 may resonate with the core.

As described above, in Formula 1, Rₐ may be a substituted or unsubstituted aryl group having 6 to 30 ring-forming carbon atoms or a substituted or unsubstituted heteroaryl group having 2 to 30 ring-forming carbon atoms, and may not be a group represented by Formula 2. In contrast to a case in which at least one of R₂₁ and R₃₁ is each independently a group represented by Formula 2, when Rₐ is a group represented by Formula 2, the polycyclic compound does not show a stable molecular structure. When Rₐ is a group represented by Formula 2, the bond of such a group to a nitrogen atom of the core may have a twisted structure. As a result, when Rₐ is a group represented by Formula 2, the group does not resonate with the core, and a low triplet energy of Rₐ is not transferred to the core. Accordingly, the polycyclic compound may not have a stable molecular structure.

The remainder of R₂₁ and R₃₁, which is not a group represented by Formula 2, may be a substituted or unsubstituted aryl group having 6 to 30 ring-forming carbon atoms or a substituted or unsubstituted heteroaryl group having 2 to 30 ring-forming carbon atoms. For example, the remainder of R₂₁ and R₃₁, which is not a group represented by Formula 2, may be a substituted or unsubstituted phenyl group or a substituted or unsubstituted carbazole group.

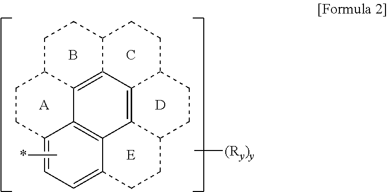

In Formula 2, [symbol] represents a bond between a carbon atom of Formula 2 to the core of Formula 1.

In Formula 2, at least two of A to E may each be a benzene ring; and the remainder of A to E may be not present. The group represented by Formula 2 may have a structure in which at least two benzene rings are fused to a naphthyl substituent. The naphthyl substituent to which the at least two benzene rings are fused may contribute to improved molecular stability. The polycyclic compound according to an embodiment includes a naphthyl substituent to which at least two benzene rings are fused, and may thus achieve an improvement in molecular stability. Accordingly, the light emitting element ED according to an embodiment includes a polycyclic compound including a naphthyl substituent to which at least two benzene rings are fused in an emission layer EML, and may thus exhibit a long service life.

In Formula 2, R_{y} may be a hydrogen atom, a deuterium atom, a halogen atom, or a substituted or unsubstituted alkyl group having 1 to 20 carbon atoms. For example, R_{y} may be a hydrogen atom, a deuterium atom, or a t-butyl group.

R_{y} may be a substituent of a naphthyl substituent to which at least two benzene rings are fused. For example, when A and B are benzene rings, R_{y} may be a substituent of at least one of the naphthyl substituent, A, or B.

In Formula 2, y may be an integer from 0 to 11. In Formula 2, y indicates the number of R_{y} groups that are a substituent of the substituent represented by Formula 2. For example, when y is 0, R_{y} is not included as a substituent of the substituent represented by Formula 2, and when y is 1, one R_{y} group may be included as a substituent of the substituent represented by Formula 2. A case in which y is 0 may be the same as a case in which y is 11 and all 11 R_{y} groups are hydrogen atoms. When y is 2 or greater, multiple R_{y} groups may all be the same, or at least one group thereof may be different from the remainder.

In an embodiment, a group represented by Formula 2 may be represented by any one of Formulas D1 to D6. Formulas D1 to D3 each represent a case in which Formula 2 includes a pyrenyl group, and Formulas D4 to D6 each represent a case in which Formula 2 includes a perylenyl group.

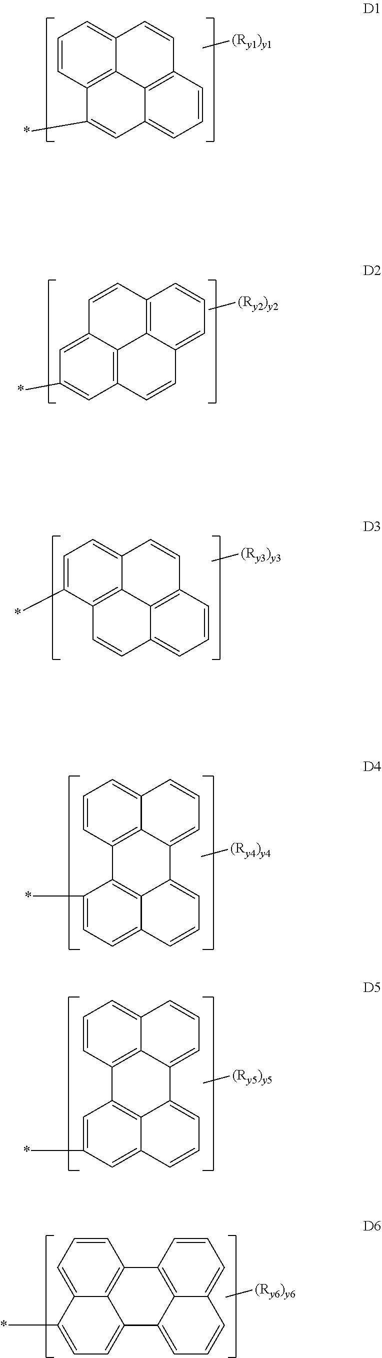

In Formulas D1 to D6, R_{y1} to R_{y6} may each independently be a hydrogen atom, a deuterium atom, or an unsubstituted t-butyl group. The descriptions of the position at which R_{y} is a substituent may also be applied to the position at which each of R_{y1} to R_{y6} is a substituent.

In Formulas D1 to D3, y1 to y3 may each independently be an integer from 0 to 9. In Formulas D4 to D6, y4 to y6 may each independently be an integer from 0 to 11. The descriptions of the relationship between y and R_{y} may also be applied to the relationship between y1 to y6 and R_{y1} to R_{y6}, respectively. In Formulas D1 to D6, at least one hydrogen atom in Formulas D1 to D6 may be optionally substituted with a deuterium atom.

In Formula 2, at least one hydrogen atom in Formula 2 may be optionally substituted with a deuterium atom. In Formula 1, at least one hydrogen atom in Formula 2 may be optionally substituted with a deuterium atom.

In an embodiment, Formula 1 may be represented by Formula 3-1 or Formula 3-2. Formula 3-1 represents a case where R₂₁ in Formula 1 is a group represented by Formula 2, and b and c are each 0. Formula 3-2 represents a case where R₂₁ and R₃₁ in Formula 1 are each independently a group represented by Formula 2, and b and c are each 0.

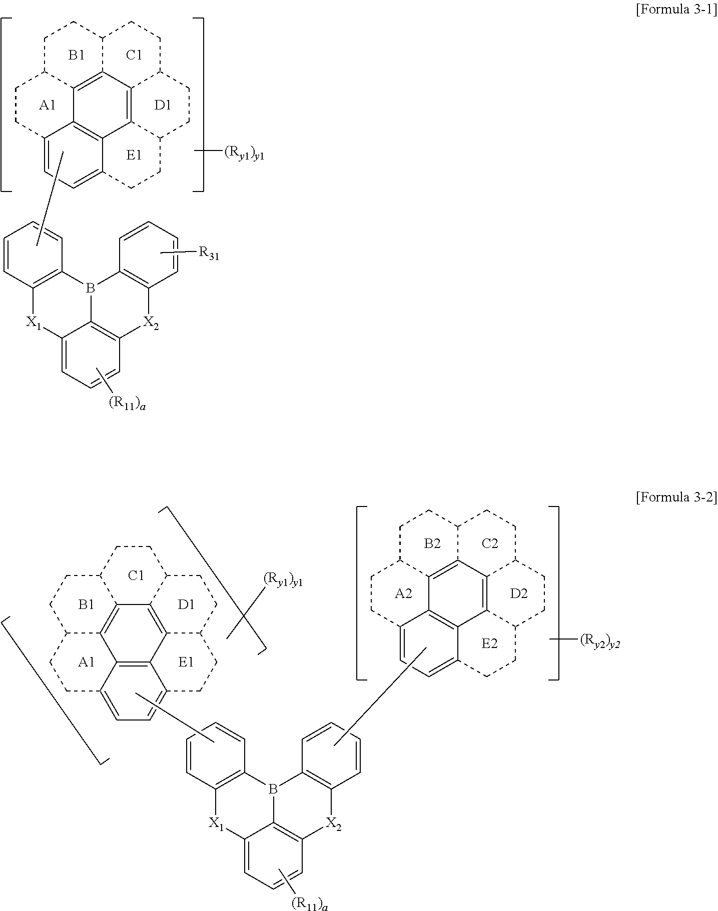

In Formulas 3-1 and 3-2, at least two of A1 to E1 may each be a benzene ring; and the remainder of A1 to E1 may be not present. Formula 3-1 may have a structure in which at least two benzene rings are fused to a naphthyl substituent. The naphthyl substituent to which at least two benzene rings are fused may contribute to improved molecular stability. The polycyclic compound includes a naphthyl substituent to which at least two benzene rings are fused, and may thus achieve an improvement in molecular stability. Accordingly, the light emitting element ED according to an embodiment includes a polycyclic compound including a naphthyl substituent to which at least two benzene rings are fused in an emission layer EML, and may thus exhibit a long service life.

In Formulas 3-1 and 3-2, R_{y1} and R_{y2} may each independently be a hydrogen atom, a deuterium atom, a halogen atom, or a substituted or unsubstituted alkyl group having 1 to 20 carbon atoms. In Formulas 3-1 and 3-2, y1 and y2 may each independently be an integer from 0 to 11. The descriptions of the position to which R_{y} is bonded in Formula 2 may also be applied to the position where R_{y1} is bonded in Formulas 3-1 and 3-2. The descriptions of the relationship between y and R_{y} in Formula 2 may also be applied to the relationship between y₁ and R_{y1} in Formulas 3-1 and 3-2. The descriptions of the position where R_{y} is bonded in Formula 2 may also be applied to the position where R_{y2} is bonded in Formula 3-2. The descriptions of the relationship between y and R_{y} in Formula 2 may also be applied to the relationship between y₂ and R_{y2} in Formula 3-2.

In Formula 3-2, at least two of A2 to E2 may each be a benzene ring; and the remainder of A2 to E2 may be not present. Formula 3-2 may have a structure in which at least two benzene rings are each fused to two naphthyl substituents. The naphthyl substituents to which at least two benzene rings are fused may contribute to improved molecular stability. The polycyclic compound includes two naphthyl substituents to which at least two benzene rings are each fused, and may thus achieve an improvement in molecular stability. Accordingly, the light emitting element ED according to an embodiment includes a polycyclic compound including two naphthyl substituents to which at least two benzene rings are each fused in an emission layer EML, and may thus exhibit a long service life.

In Formulas 3-1 and 3-2, a, R₁₁, R₃₁, X₁, and X₂ may be the same as defined in Formula 1. In Formulas 3-1 and 3-2, at least one hydrogen atom in Formulas 3-1 and 3-2 may be optionally substituted with a deuterium atom.

In an embodiment, Formula 1 may be represented by any one Formulas 4-1 to 4-3. Formulas 4-1 to 4-3 each represent a case where bonding positions of R₂₁ and R₃₁ in Formula 1 are further defined. Formula 4-1 represents a case in which R₂₁ and R₃₁ are each bonded at a para position to the boron atom of the core. Formula 4-2 represents a case in which R₂₁ is bonded at a meta position to the boron atom of the core and R₃₁ is bonded at a para position to the boron atom of the core. Formula 4-3 represents a case in which R₂₁ and R₃₁ are each bonded at a meta position to the boron atom of the core.

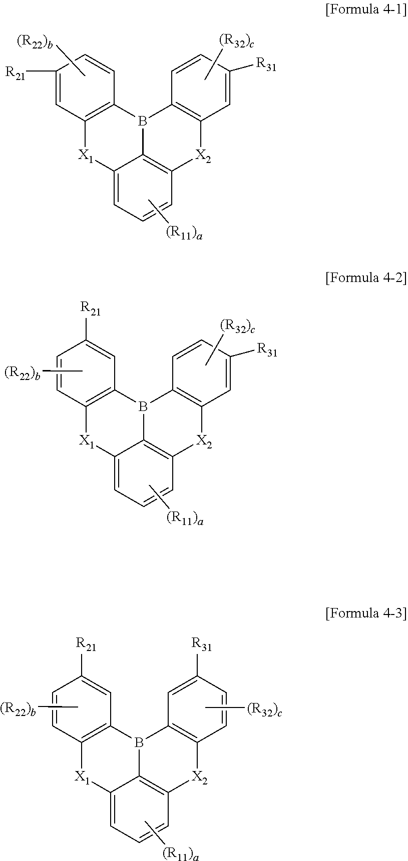

In Formulas 4-1 to 4-3, a, b, c, X₁, X₂, R₁₁, R₂₁, R₃₁, R₂₂, and R₃₂ may be the same as defined in Formula 1. In Formulas 4-1 to 4-3, at least one hydrogen atom in Formulas 4-1 to 4-3 may be optionally substituted with a deuterium atom.

In an embodiment, Formula 1 may be represented by Formula 5. Formula 5 has a structure in which the core in Formula 1 is extended. In contrast to Formula 1, Formula 5 includes a core in which five benzene rings are fused through two boron atoms and four heteroatoms.

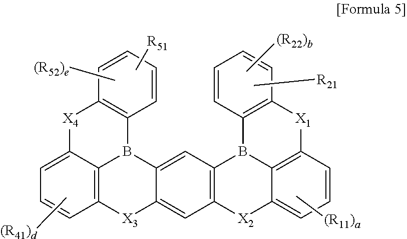

In Formula 5, at least one of R₂₁ and R₅₁ may each independently be a group represented by Formula 2; and the remainder of R₂₁ and R₅₁ may be a substituted or unsubstituted aryl group having 6 to 30 ring-forming carbon atoms or a substituted or unsubstituted heteroaryl group having 2 to 30 ring-forming carbon atoms. The polycyclic compound represented by Formula 5 may have a stable molecular structure when at least one of R₂₁ and R₅₁ is each independently a group represented by Formula 2, and the remainder of R₂₁ and R₅₁ is a substituted or unsubstituted aryl group having 6 to 30 ring-forming carbon atoms or a substituted or unsubstituted heteroaryl group having 2 to 30 ring-forming carbon atoms. Accordingly, the polycyclic compound represented by Formula 5 may contribute to improved service life of the light emitting element ED. The light emitting element ED according to an embodiment may include the polycyclic compound represented by Formula 5 to achieve a long service life.

In Formula 5, R₄₁ and R₅₂ may each independently be a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula 5, d and e may each independently be an integer from 0 to 3. In Formula 5, d may indicate the number of R₄₁ groups. For example, when d is 0, no R₄₁ groups are included as a substituent, and when d is 1, one R₄₁ is included as a substituent. A case in which d is 0 may be the same as a case in which d is 3 and all three R₄₁ groups are hydrogen atoms. When d is 2 or greater, multiple R₄₁ groups may all be the same, or at least one group thereof may be different from the remainder.

In Formula 5, e may indicate the number of R₅₂ groups. For example, when e is 0, no R₅₂ groups are included as a substituent, and when e is 1, one R₅₂ is included as a substituent. A case in which e is 0 may be the same as a case in which e is 3 and all three R₅₂ groups are hydrogen atoms. When e is 2 or greater, multiple R₅₂ groups may all be the same, or at least one group thereof may be different from the remainder.

In Formula 5, X₃ and X₄ may each independently be O, S, or N(R_{b}). X₃ and X₄ may be the same as or different from each other.

In Formula 5, Re may be a substituted or unsubstituted aryl group having 6 to 30 ring-forming carbon atoms or a substituted or unsubstituted heteroaryl group having 2 to 30 ring-forming carbon atoms, and may not be a group represented by Formula 2. For example, Re may be a substituted or unsubstituted phenyl group, a substituted or unsubstituted biphenyl group, or a substituted or unsubstituted terphenyl group.

In Formula 5, a, b, R₁₁, R₂₂, X₁, and X₂ may be the same as defined in Formula 1. In Formula 5, at least one hydrogen atom in Formula 5 may be optionally substituted with a deuterium atom.

In an embodiment, the polycyclic compound may be any compound selected from Compound Group 1. In an embodiment, in the light emitting element ED, the emission layer EML may include at least one compound selected from Compound Group 1:

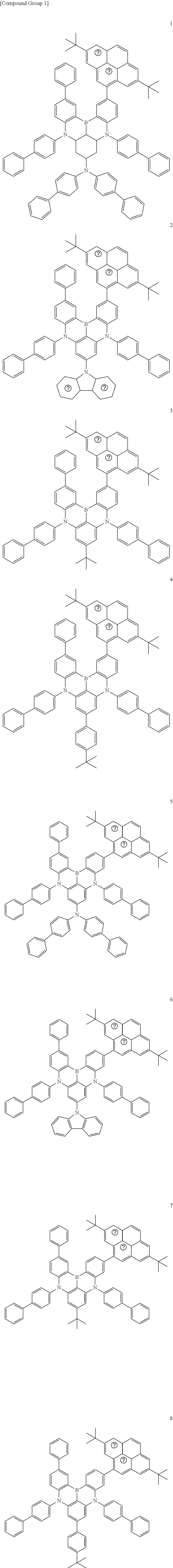

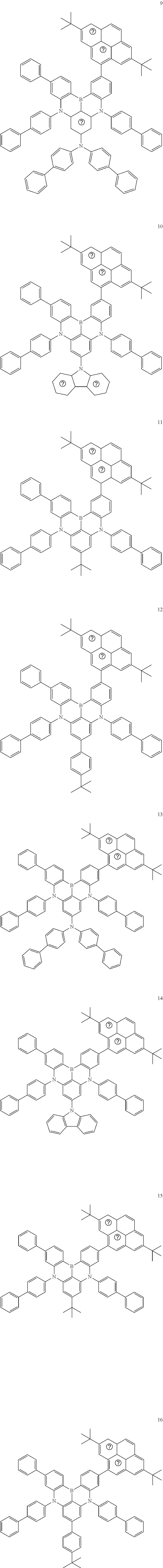

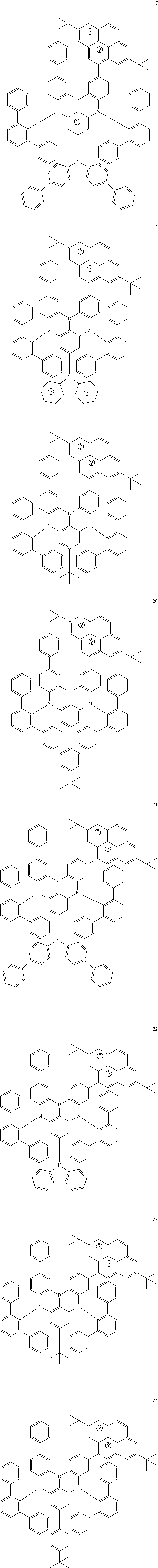

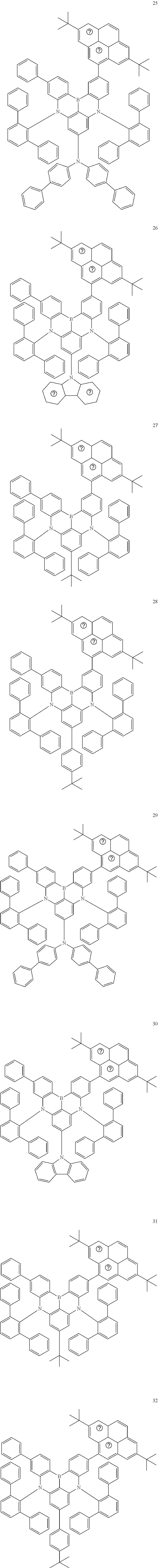

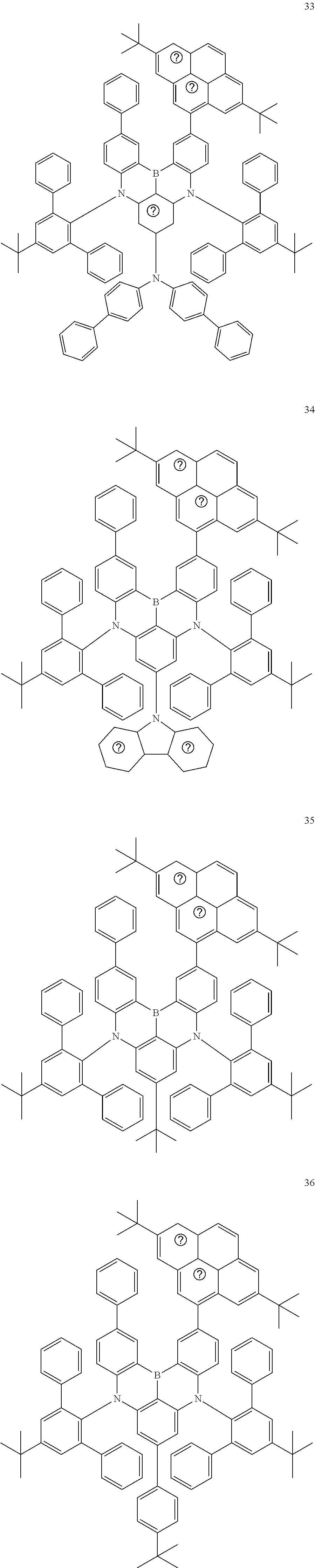

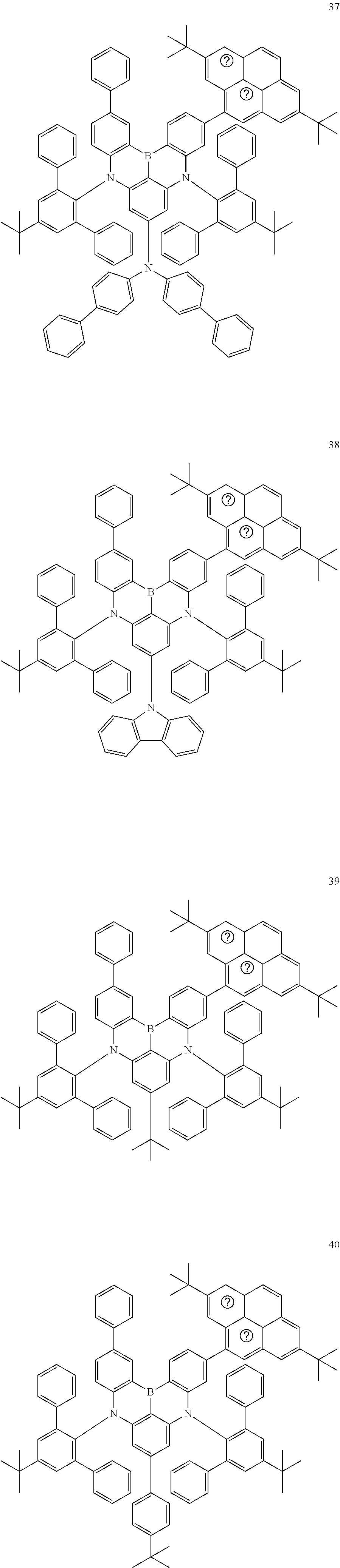

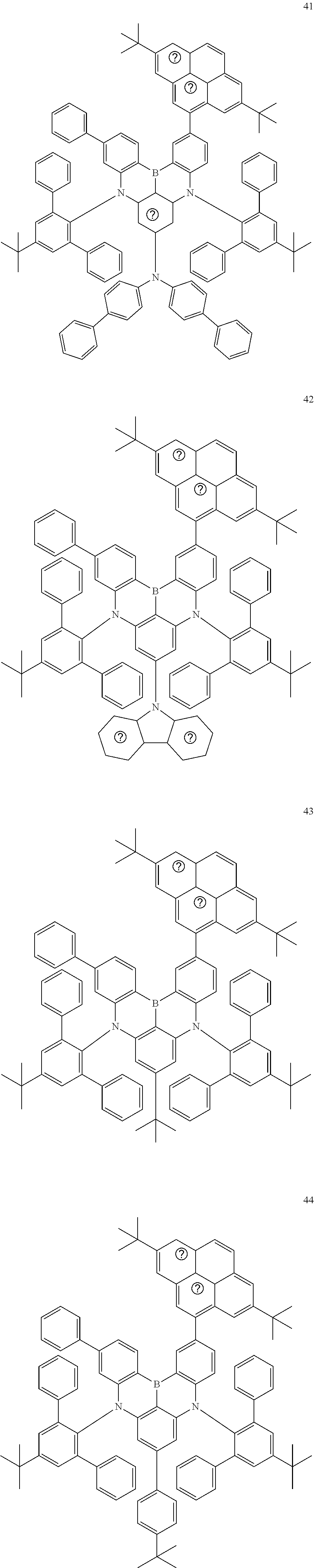

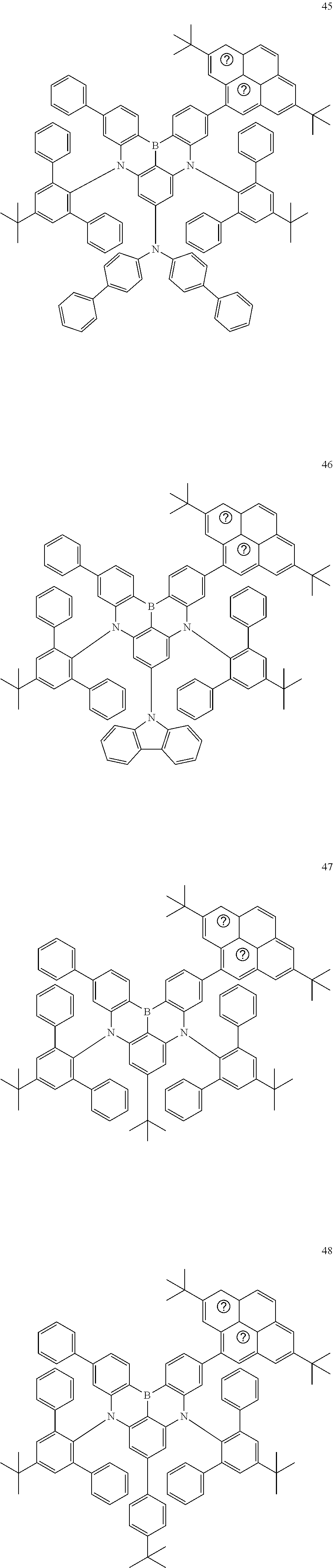

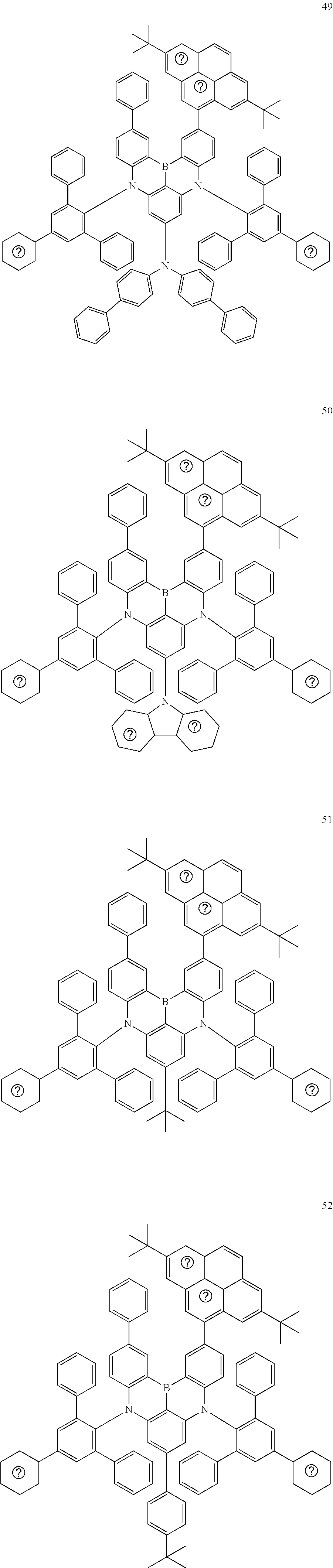

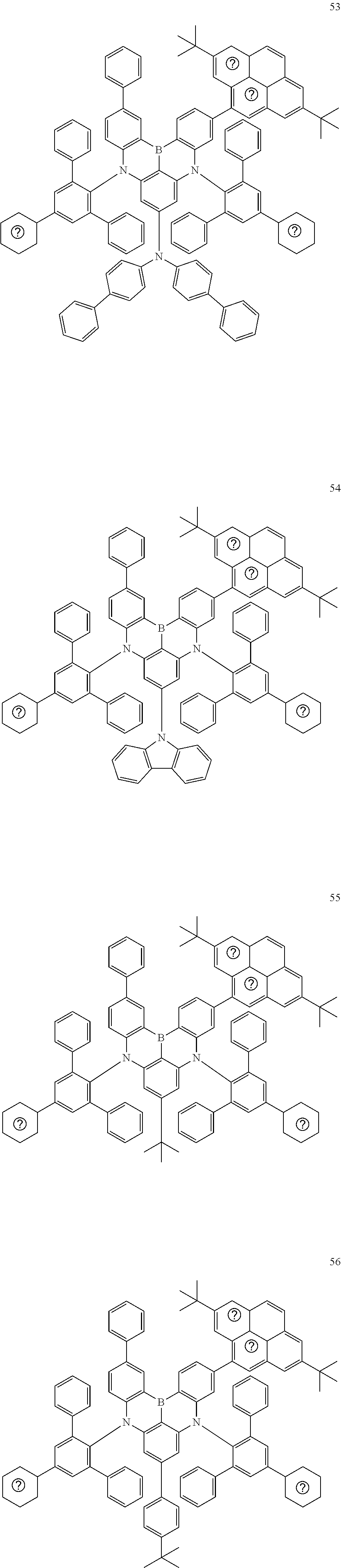

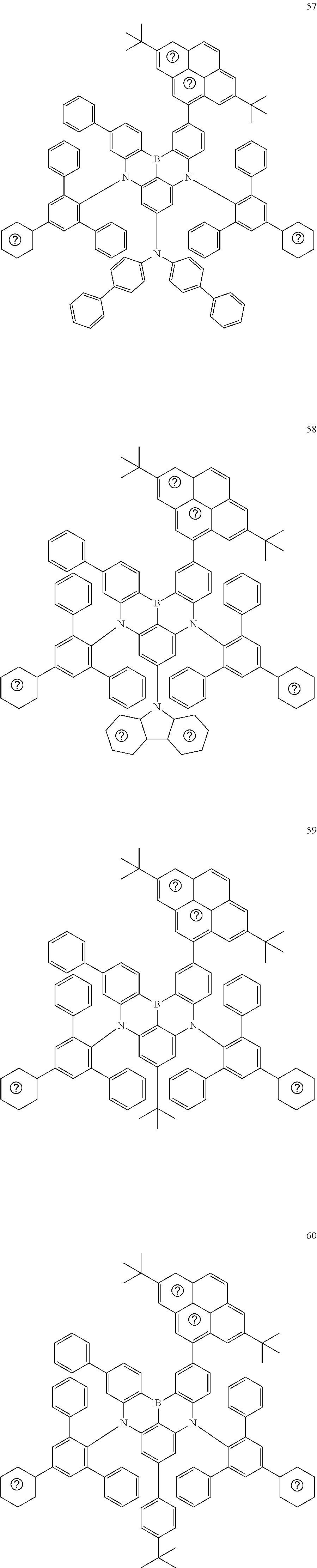

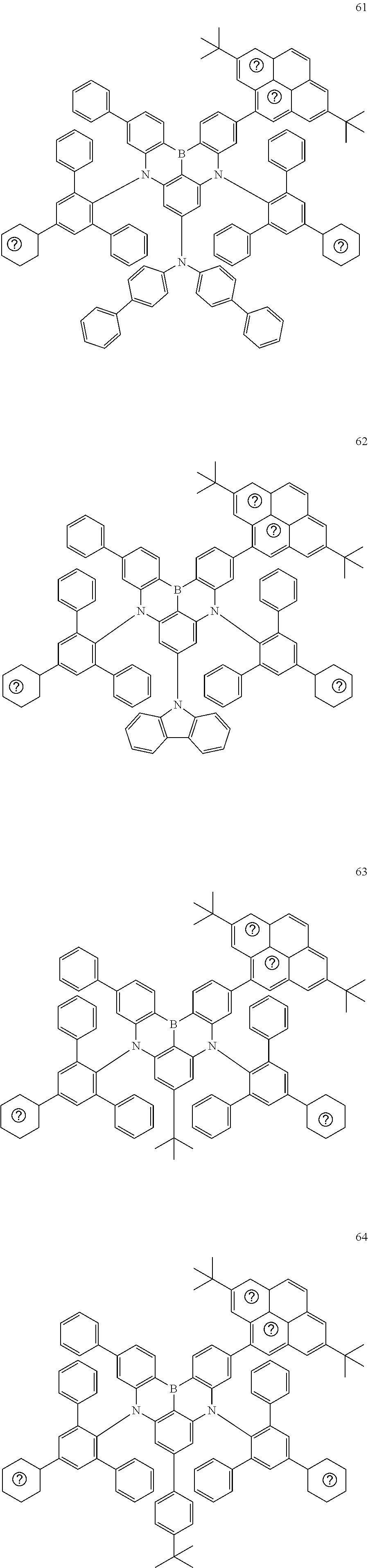

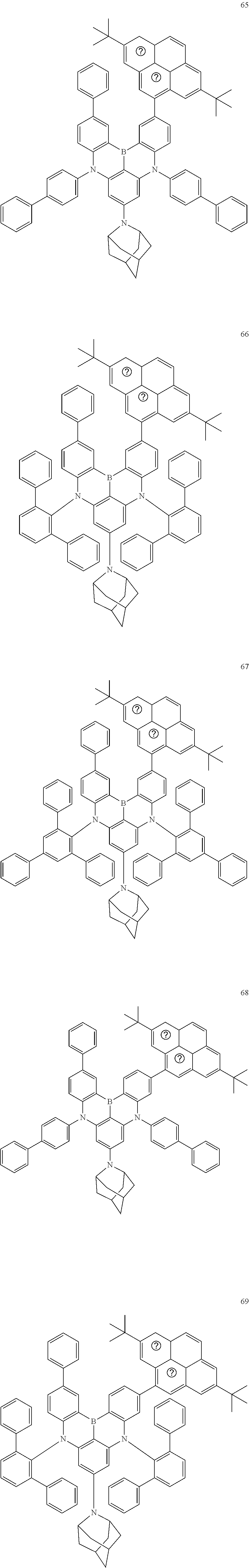

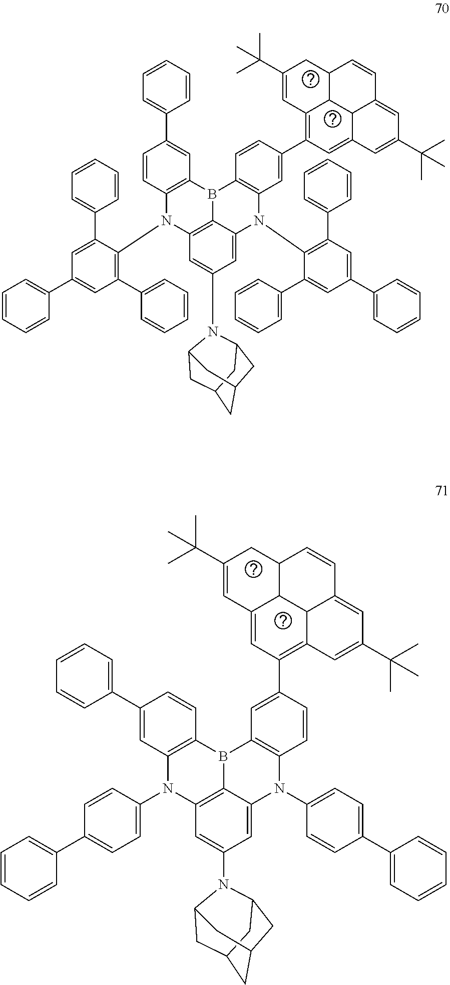 [SMILES: CC(C)(C)C1=CC2=CC(c3ccc4c(c3)N(c3c(-c5ccccc5)cc(-c5ccccc5)cc3-c3ccccc3)c3cc(N5C6CC7CC(C6)CC5C7)cc5c3B4c3cc(-c4ccccc4)ccc3N5c3c(-c4ccccc4)cc(-c4ccccc4)cc3-c3ccccc3)=C3C=C(C(C)(C)C)CC4C=CC(=C1)C2C34 ; CC(C)(C)C1=CC2=C(c3ccc4c(c3)B3c5ccc(-c6ccccc6)cc5N(c5ccc(-c6ccccc6)cc5)c5cc(N6C7CC8CC(C7)CC6C8)cc(c53)N4c3ccc(-c4ccccc4)cc3)C=C3C=C(C(C)(C)C)CC4C=CC(=C1)C2C34]

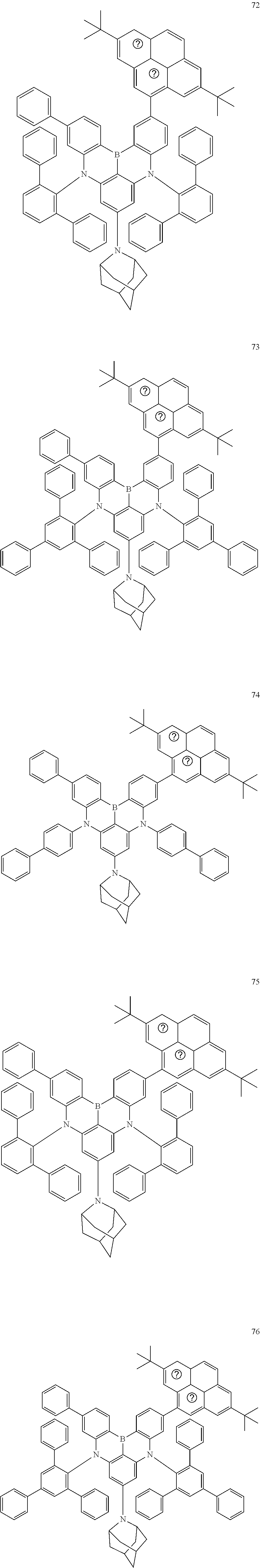

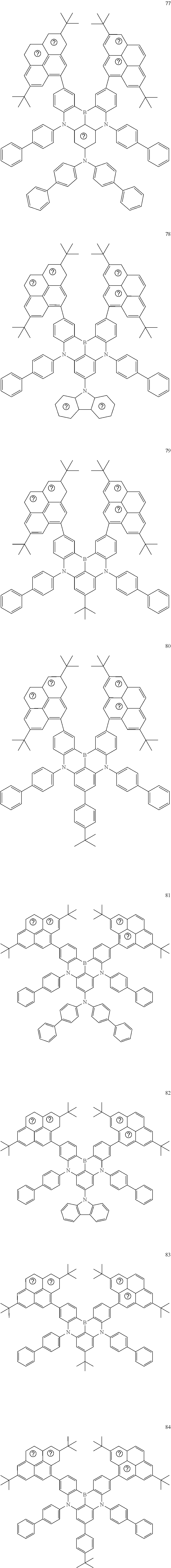

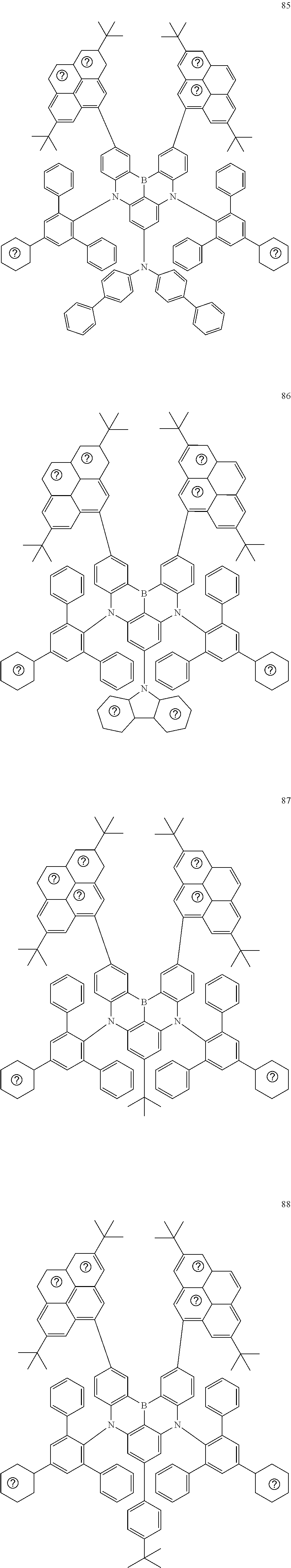

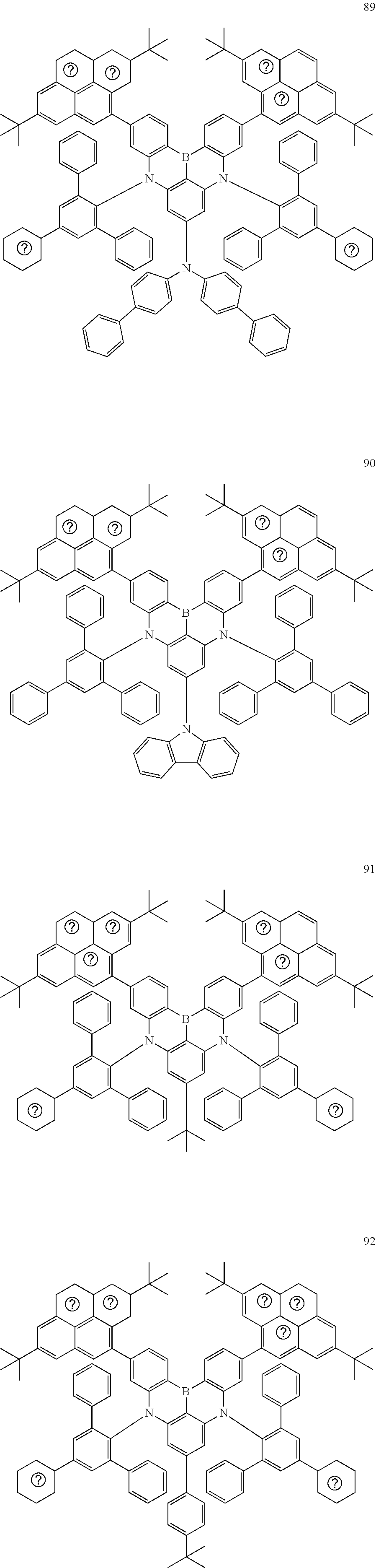

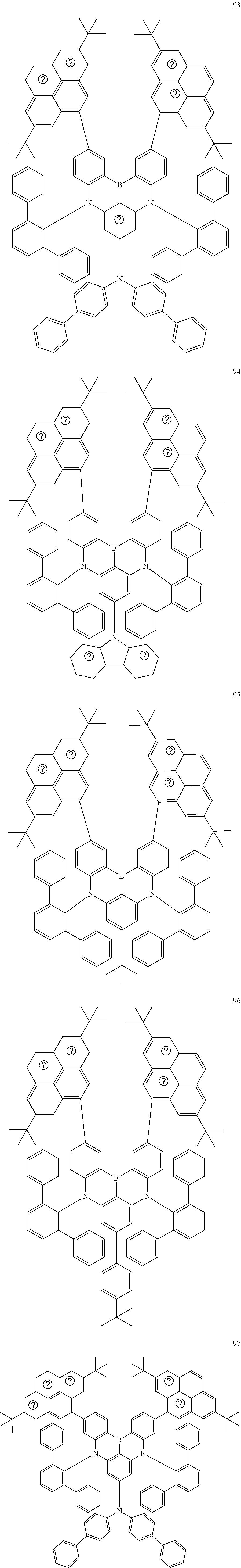

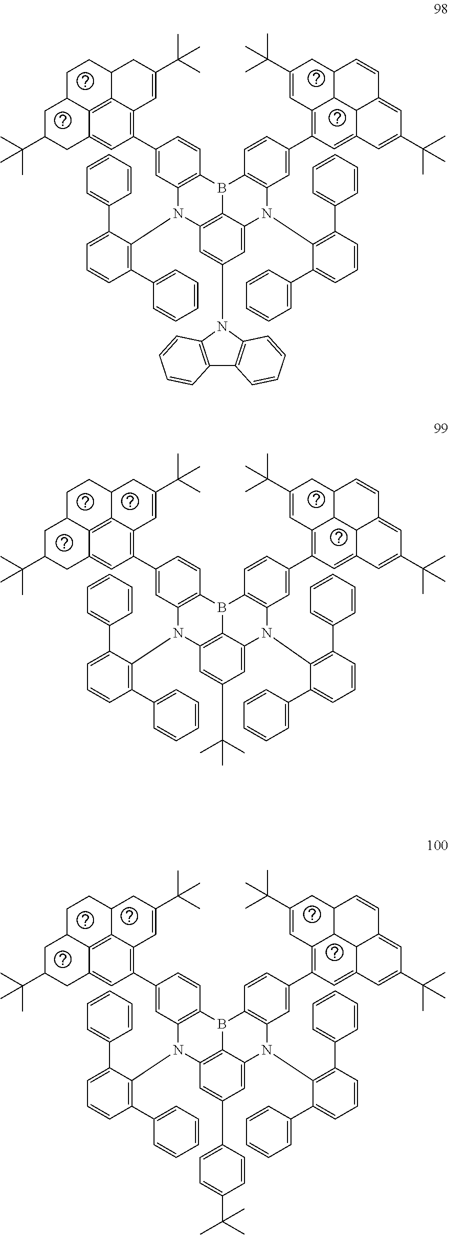

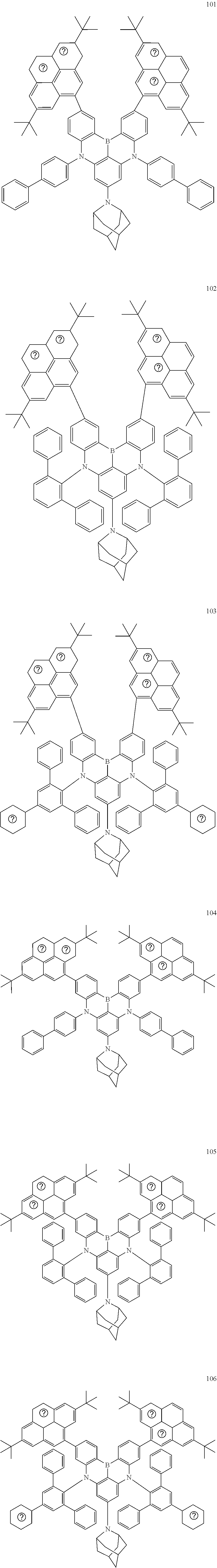

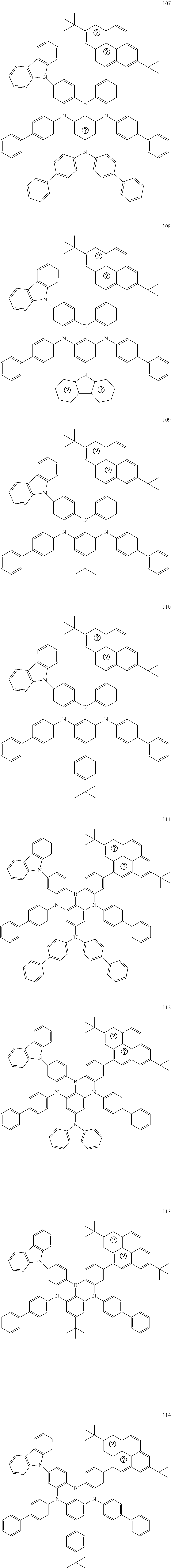

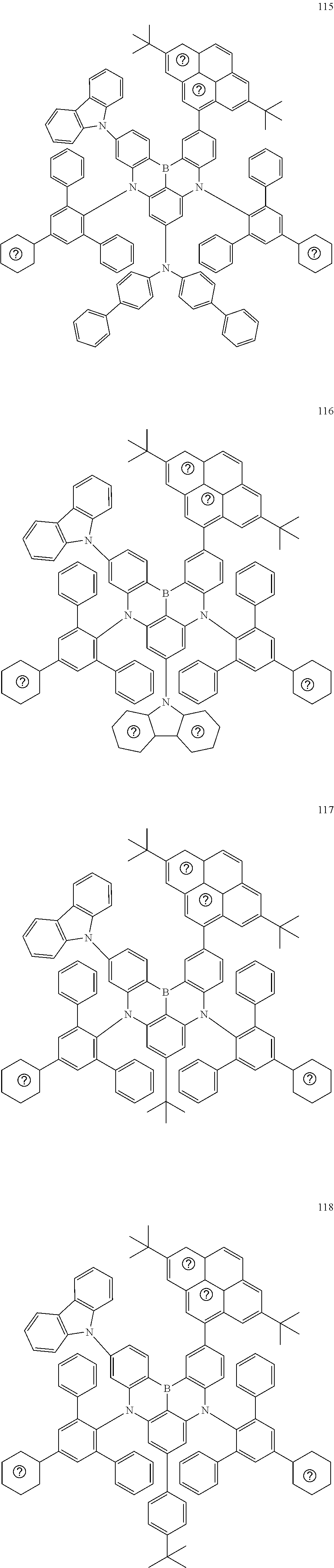

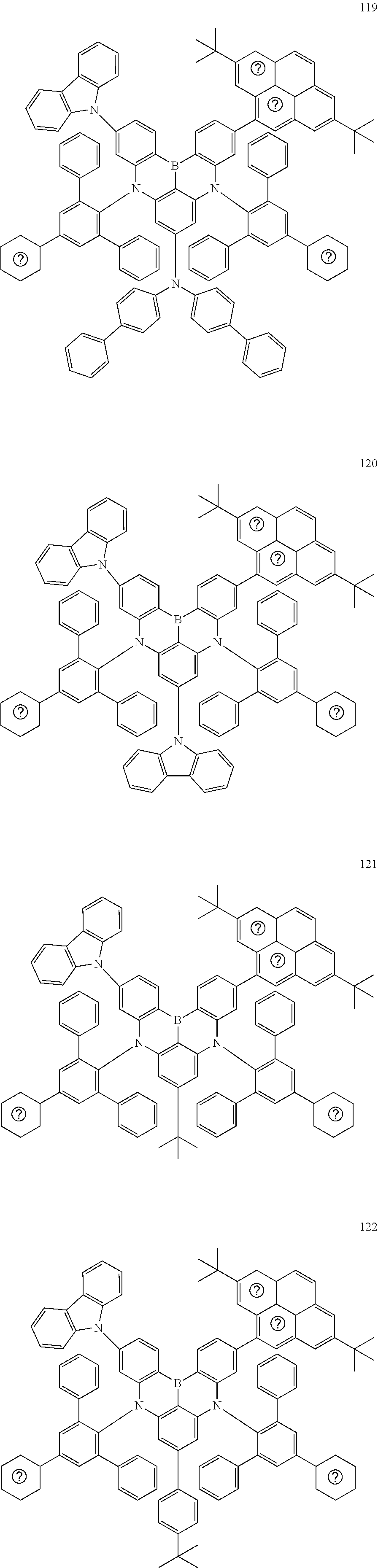

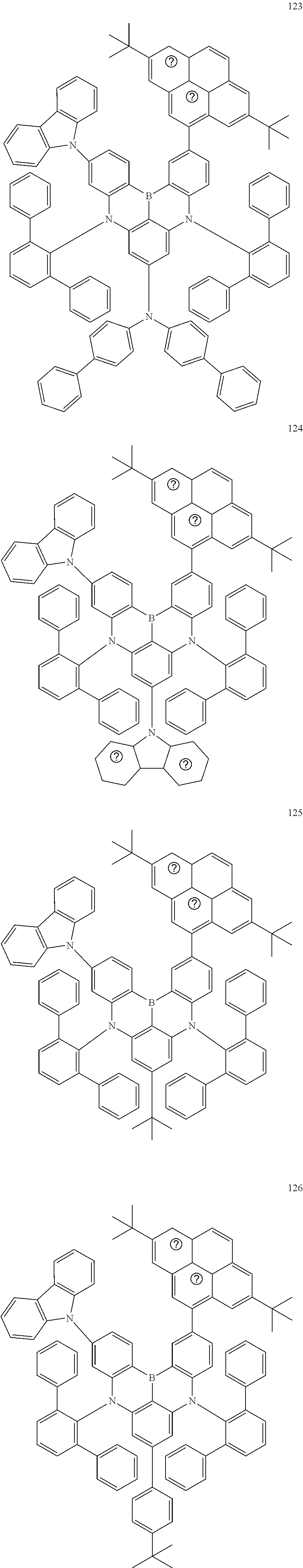

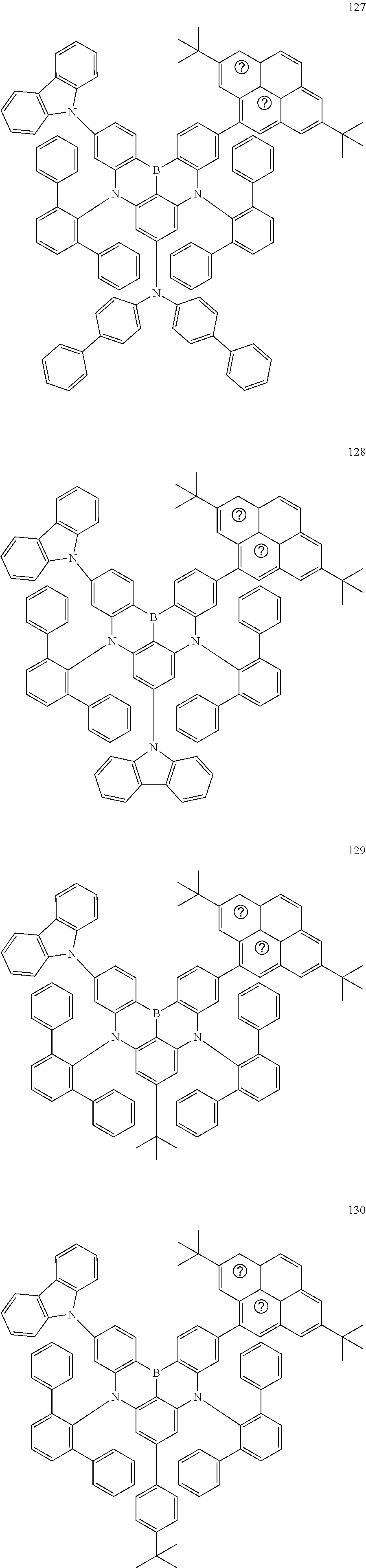

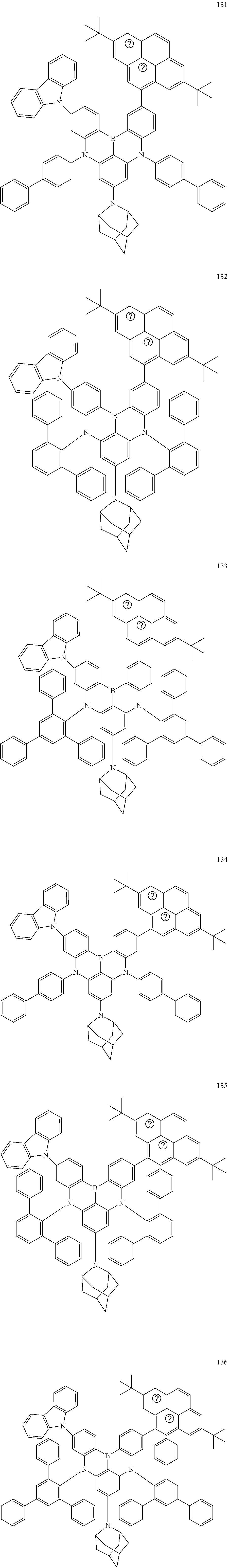

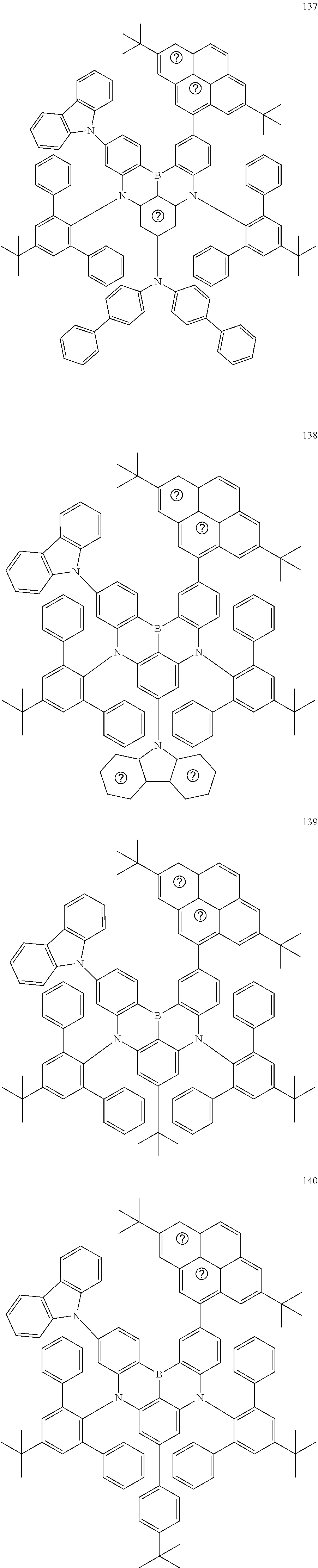

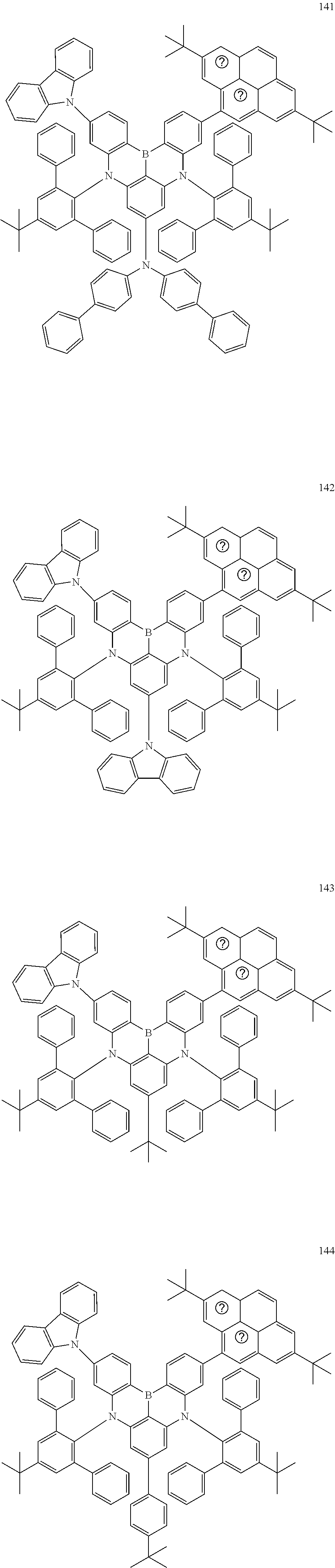

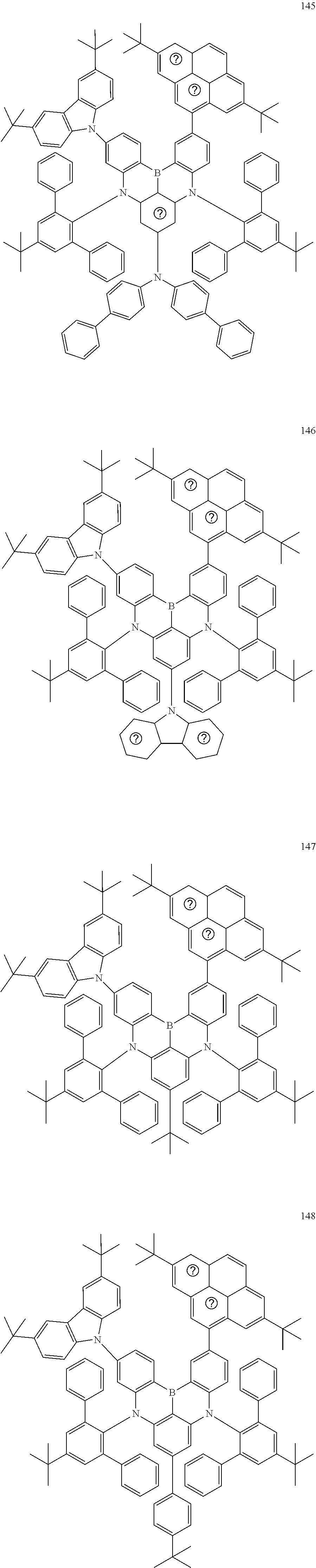

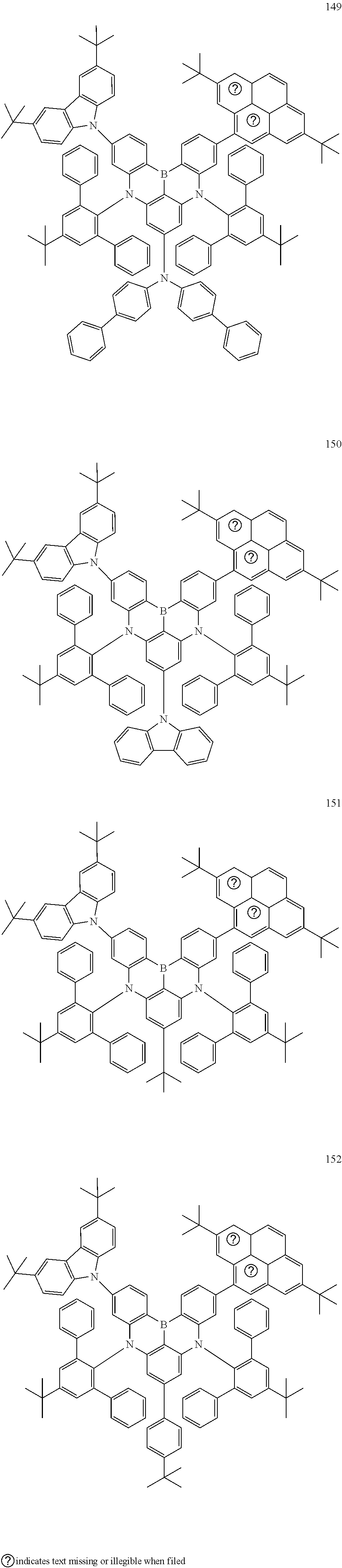

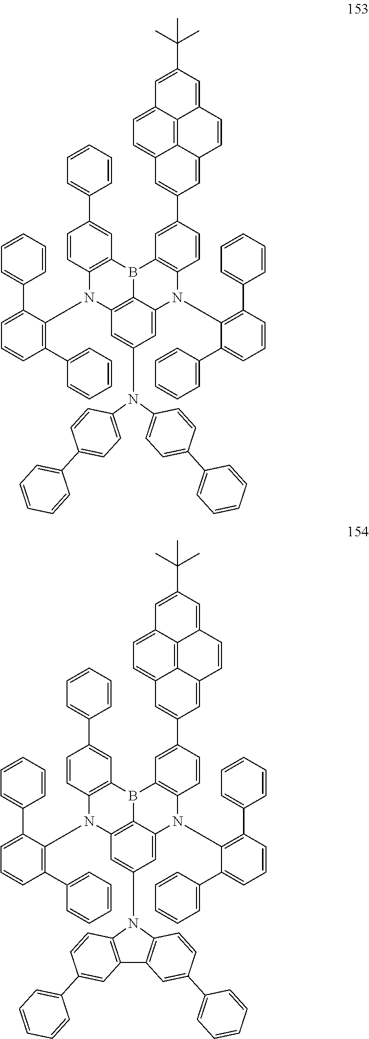 [SMILES: CC(C)(C)c1cc2ccc3cc(-c4ccc5c(c4)B4c6cc(-c7ccccc7)ccc6N(c6c(-c7ccccc7)cccc6-c6ccccc6)c6cc(N(c7ccc(-c8ccccc8)cc7)c7ccc(-c8ccccc8)cc7)cc(c64)N5c4c(-c5ccccc5)cccc4-c4ccccc4)cc4ccc(c1)c2c34 ; CC(C)(C)c1cc2ccc3cc(-c4ccc5c(c4)B4c6cc(-c7ccccc7)ccc6N(c6c(-c7ccccc7)cccc6-c6ccccc6)c6cc(-n7c8ccc(-c9ccccc9)cc8c8cc(-c9ccccc9)ccc87)cc(c64)N5c4c(-c5ccccc5)cccc4-c4ccccc4)cc4ccc(c1)c2c34]

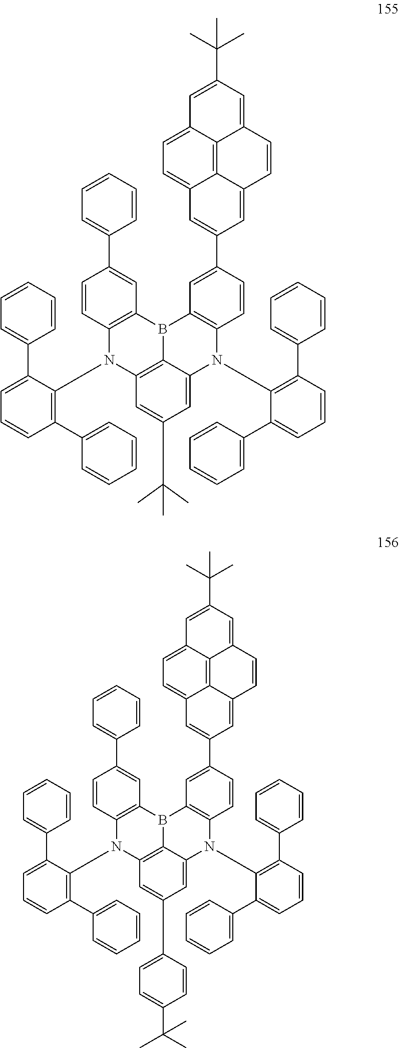 [SMILES: CC(C)(C)c1cc2c3c(c1)N(c1c(-c4ccccc4)cccc1-c1ccccc1)c1ccc(-c4cc5ccc6cc(C(C)(C)C)cc7ccc(c4)c5c67)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6ccc7cc(C(C)(C)C)cc8ccc(c5)c6c78)cc2B4c2cc(-c4ccccc4)ccc2N3c2c(-c3ccccc3)cccc2-c2ccccc2)cc1]

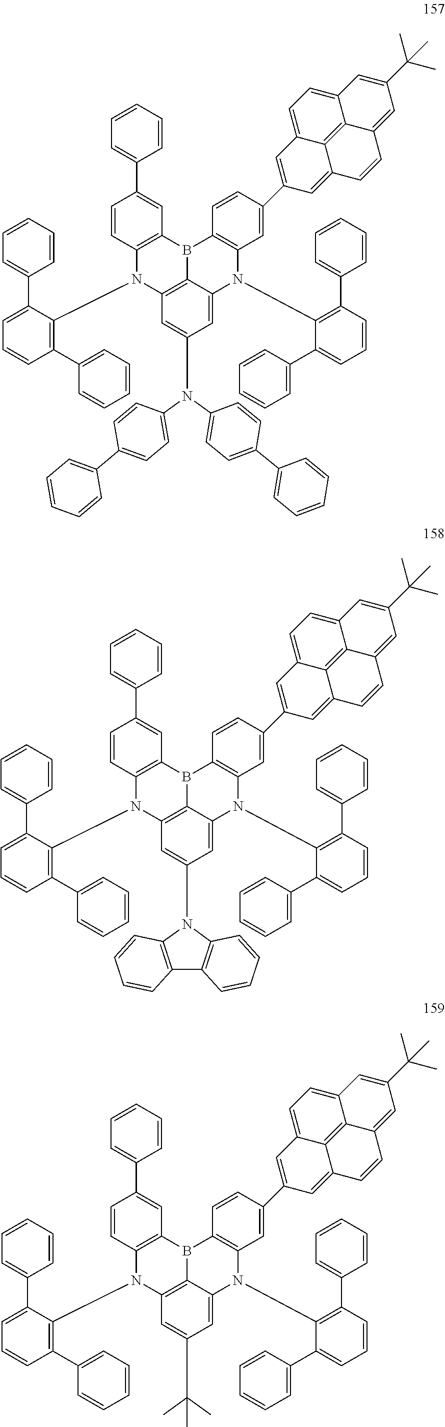 [SMILES: CC(C)(C)c1cc2ccc3cc(-c4ccc5c(c4)N(c4c(-c6ccccc6)cccc4-c4ccccc4)c4cc(N(c6ccc(-c7ccccc7)cc6)c6ccc(-c7ccccc7)cc6)cc6c4B5c4cc(-c5ccccc5)ccc4N6c4c(-c5ccccc5)cccc4-c4ccccc4)cc4ccc(c1)c2c34 ; CC(C)(C)c1cc2ccc3cc(-c4ccc5c(c4)N(c4c(-c6ccccc6)cccc4-c4ccccc4)c4cc(-n6c7ccccc7c7ccccc76)cc6c4B5c4cc(-c5ccccc5)ccc4N6c4c(-c5ccccc5)cccc4-c4ccccc4)cc4ccc(c1)c2c34 ; CC(C)(C)c1cc2c3c(c1)N(c1c(-c4ccccc4)cccc1-c1ccccc1)c1cc(-c4cc5ccc6cc(C(C)(C)C)cc7ccc(c4)c5c67)ccc1B3c1cc(-c3ccccc3)ccc1N2c1c(-c2ccccc2)cccc1-c1ccccc1]

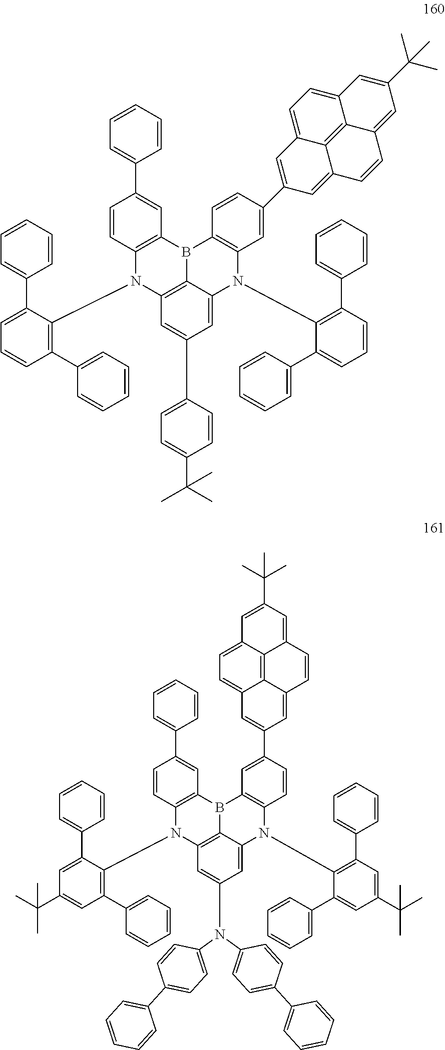

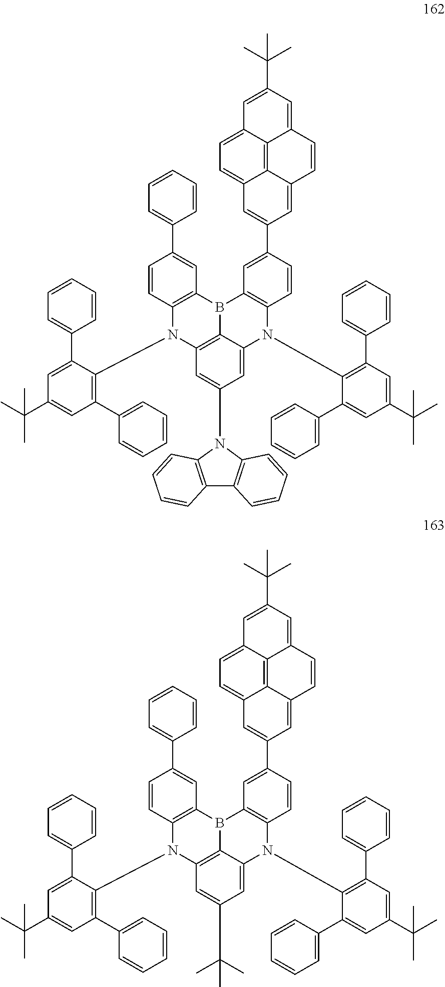

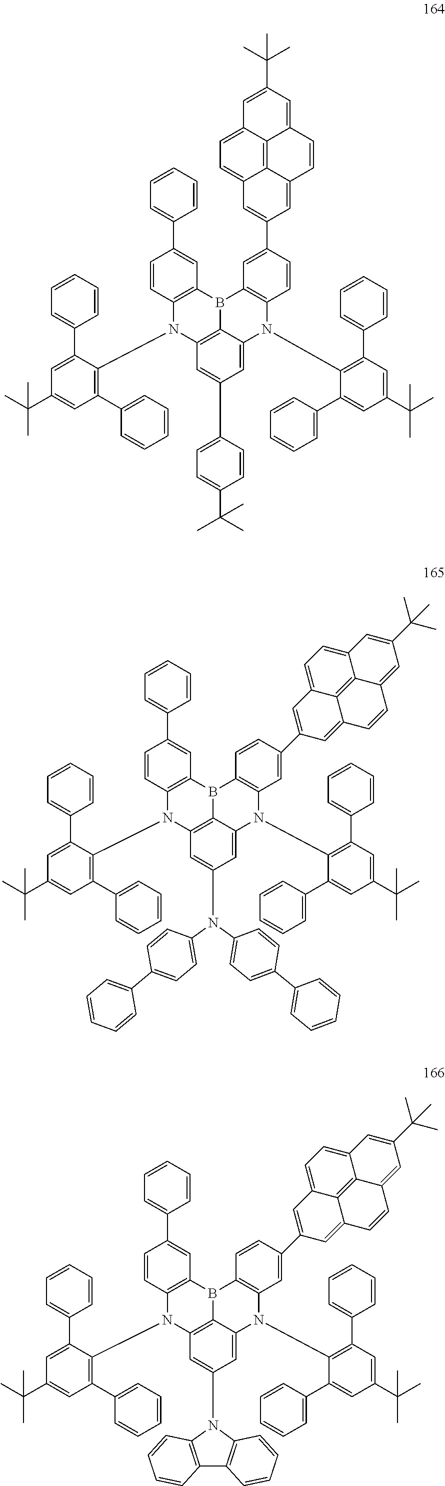

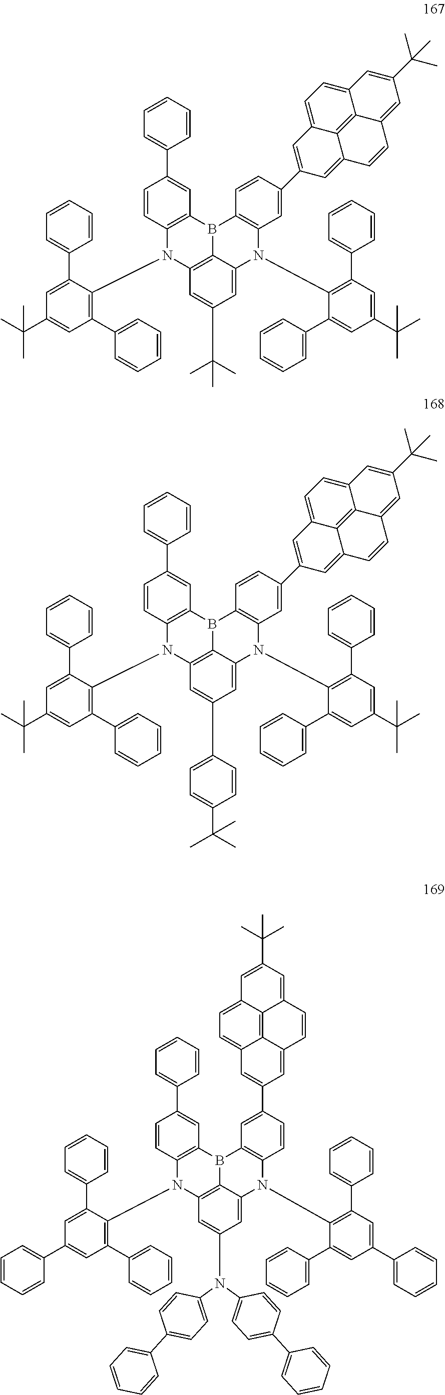

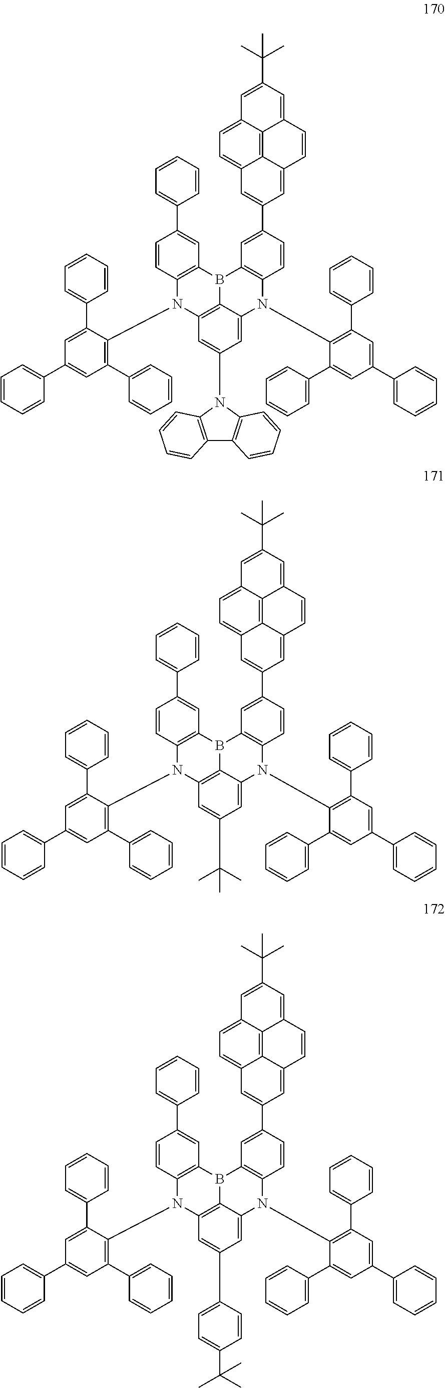

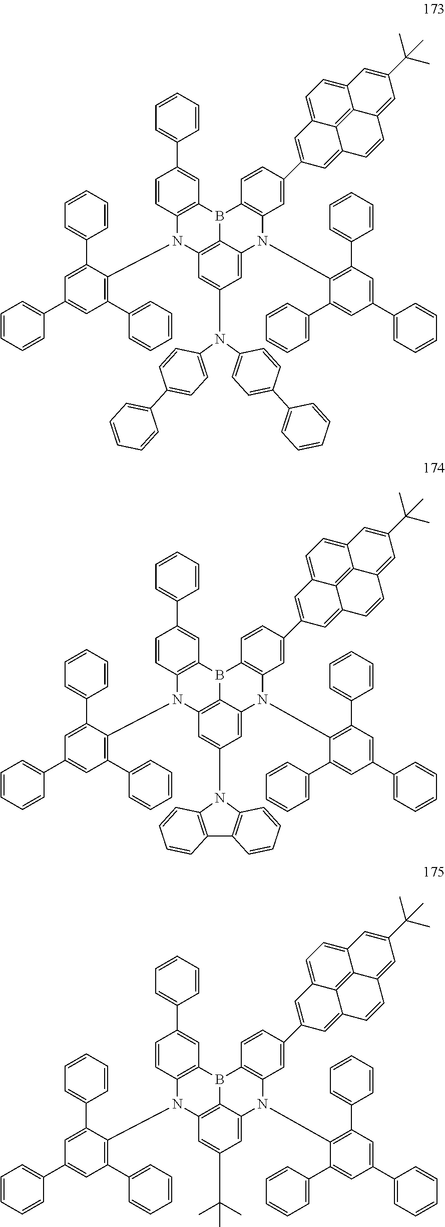

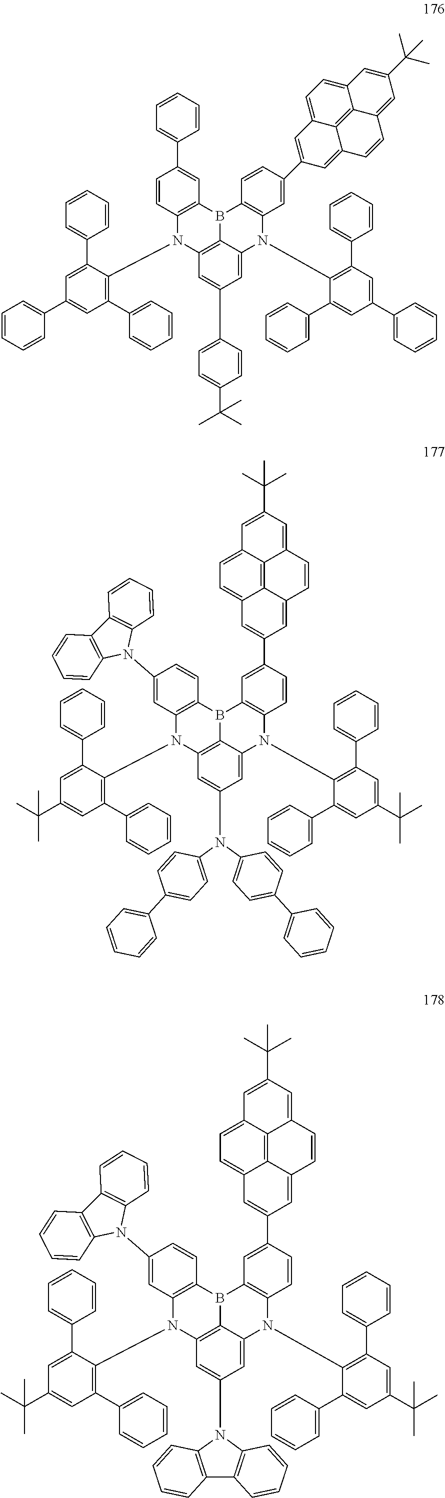

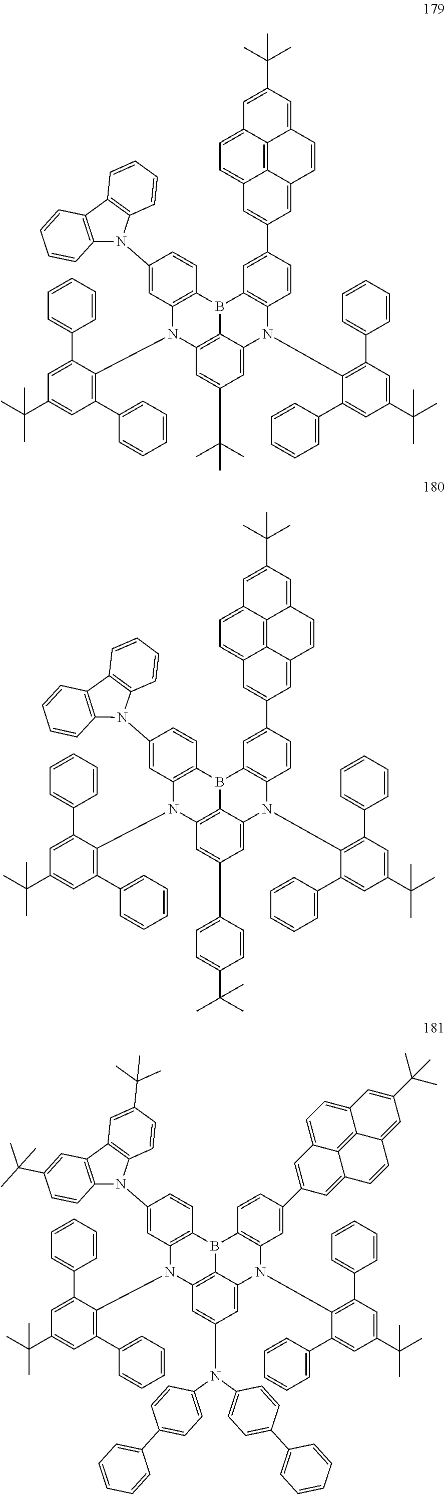

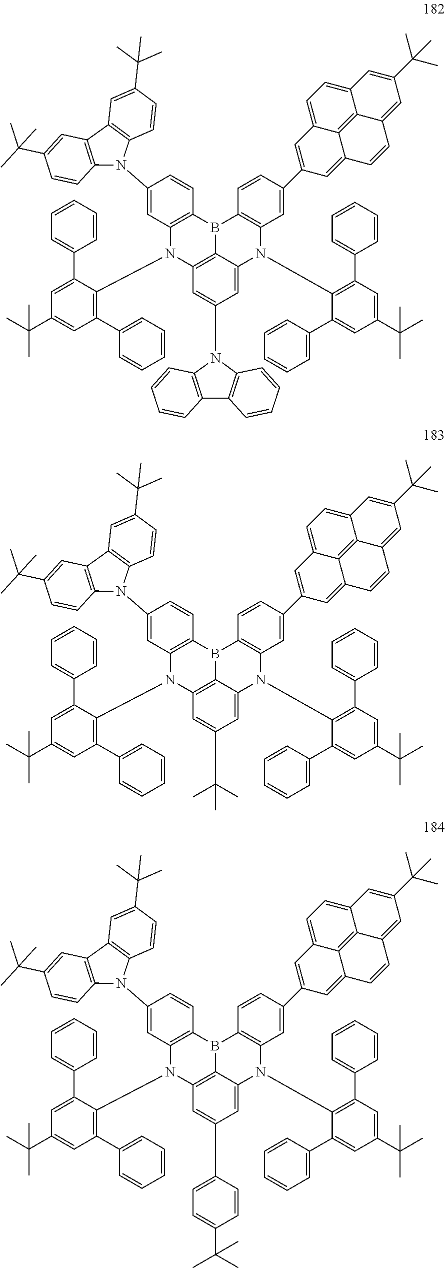

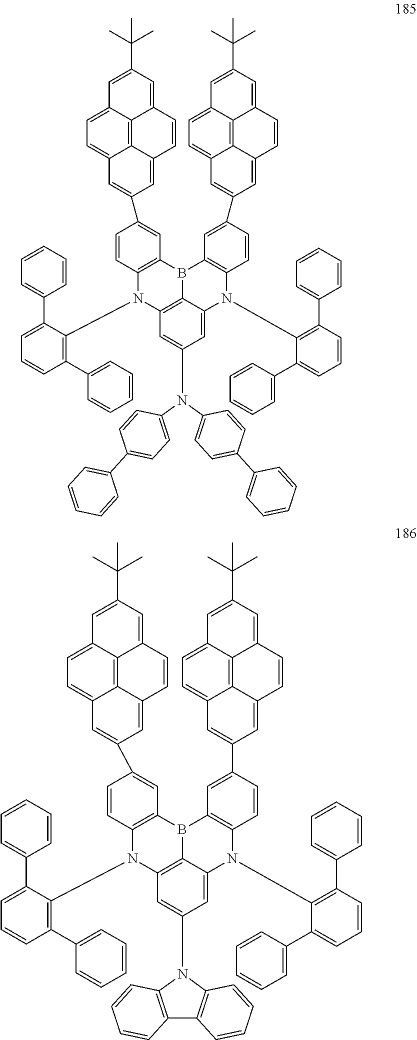

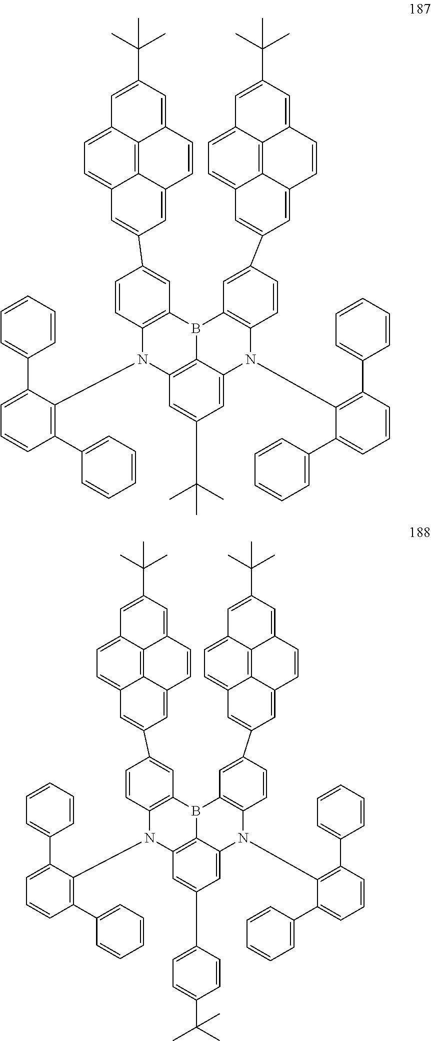 [SMILES: CC(C)(C)c1cc2c3c(c1)N(c1c(-c4ccccc4)cccc1-c1ccccc1)c1ccc(-c4cc5ccc6cc(C(C)(C)C)cc7ccc(c4)c5c67)cc1B3c1cc(-c3cc4ccc5cc(C(C)(C)C)cc6ccc(c3)c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6ccc7cc(C(C)(C)C)cc8ccc(c5)c6c78)cc2B4c2cc(-c4cc5ccc6cc(C(C)(C)C)cc7ccc(c4)c5c67)ccc2N3c2c(-c3ccccc3)cccc2-c2ccccc2)cc1]

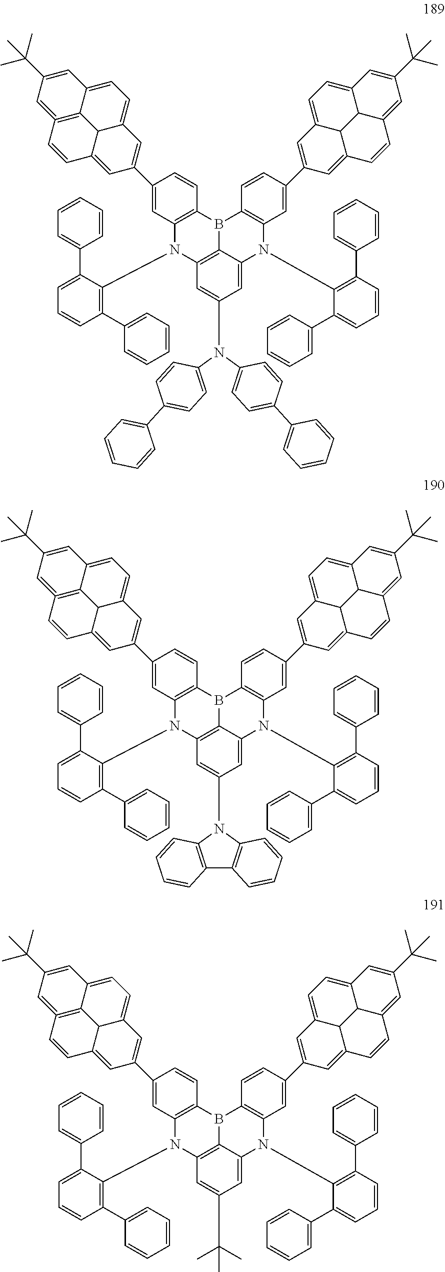

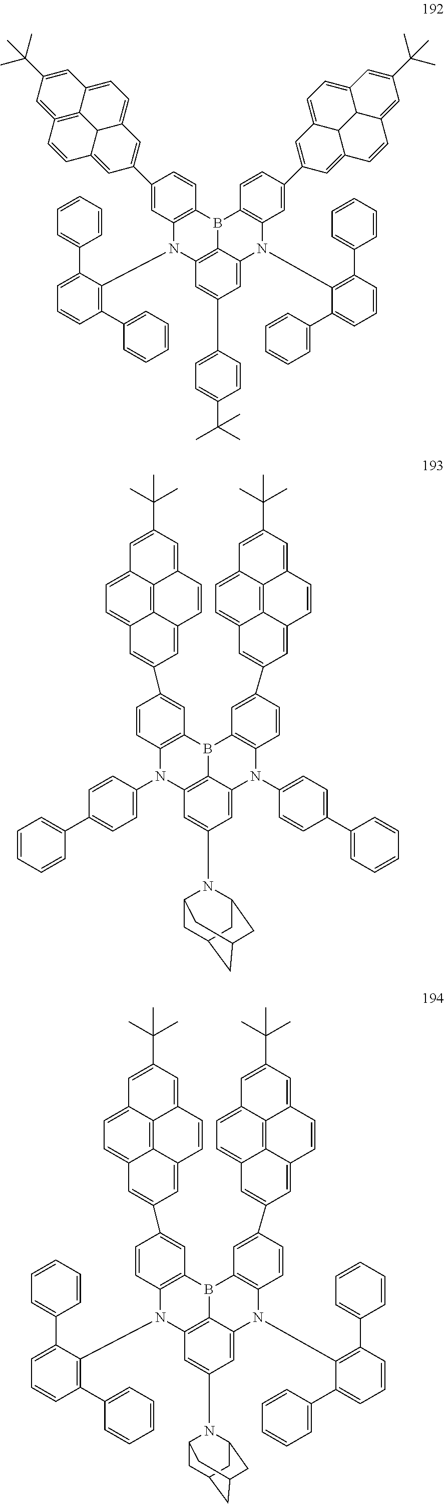

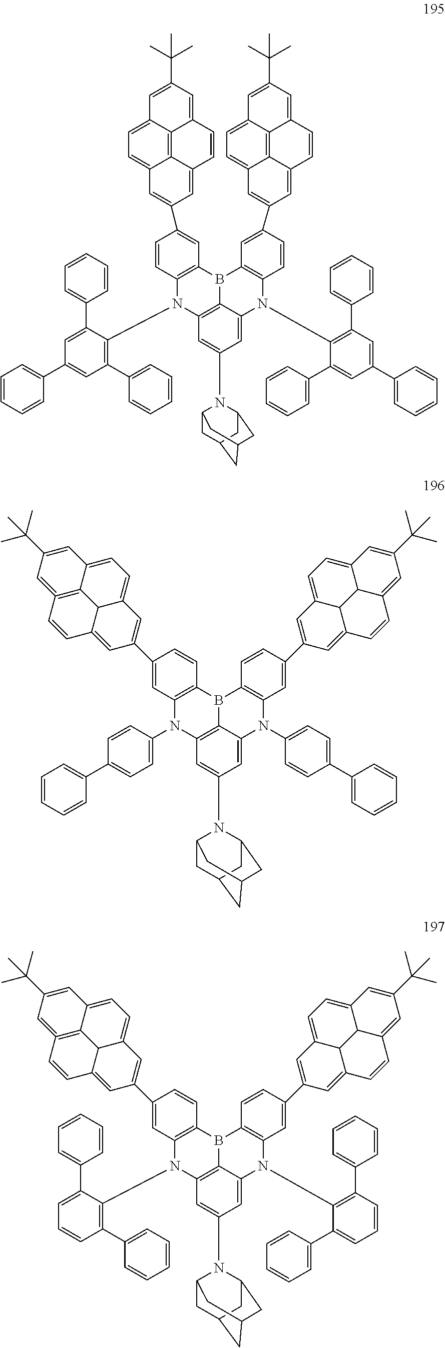

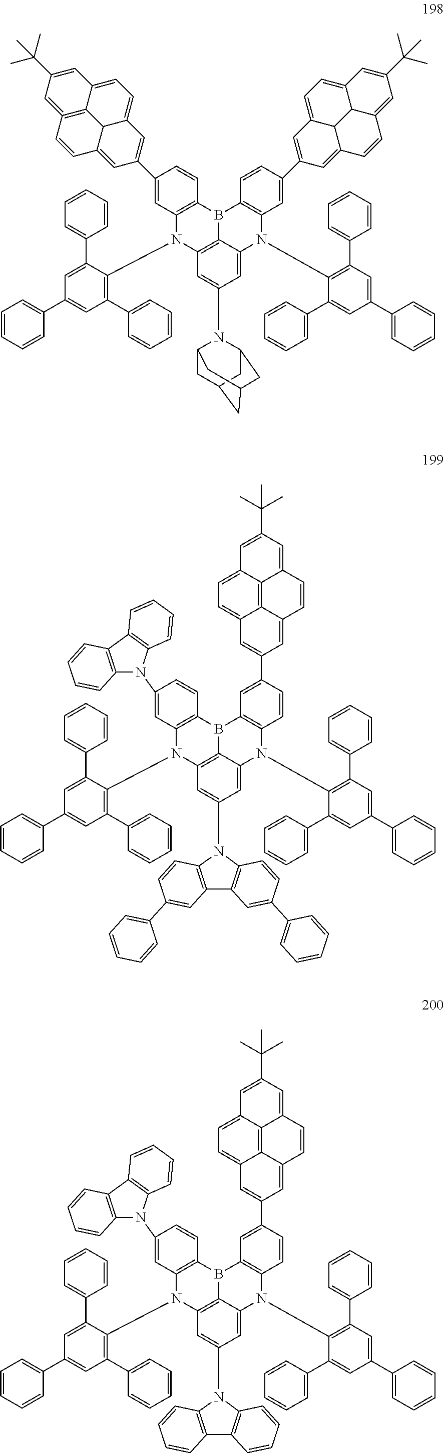

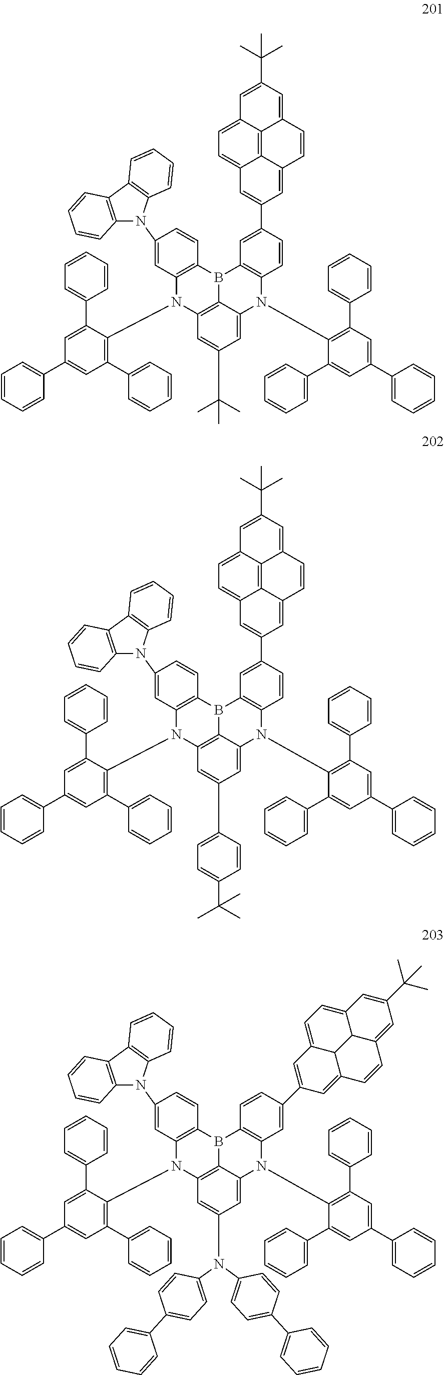

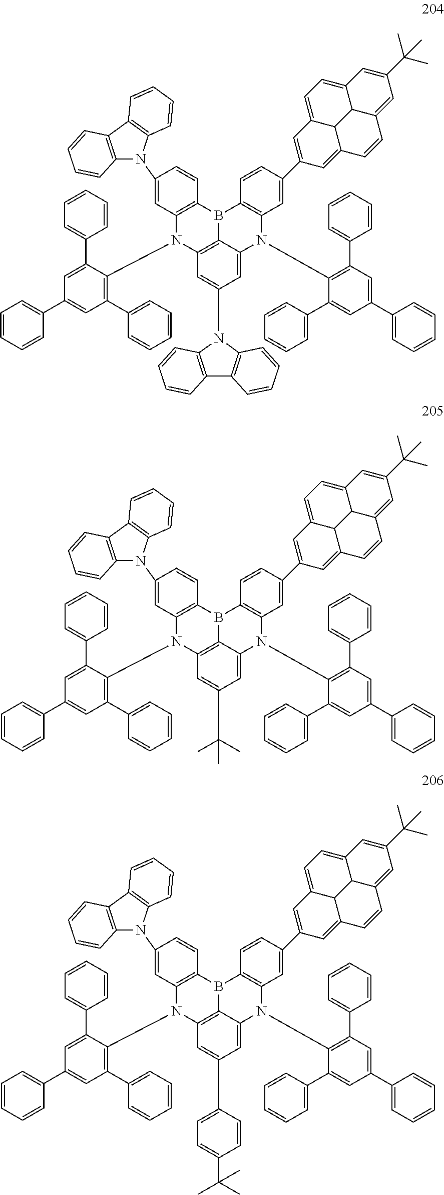

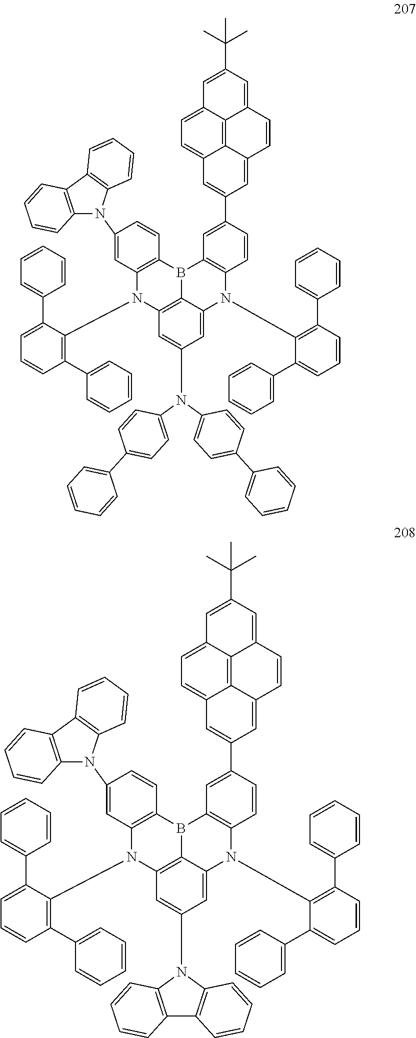 [SMILES: CC(C)(C)c1cc2ccc3cc(-c4ccc5c(c4)B4c6ccc(-n7c8ccccc8c8ccccc87)cc6N(c6c(-c7ccccc7)cccc6-c6ccccc6)c6cc(N(c7ccc(-c8ccccc8)cc7)c7ccc(-c8ccccc8)cc7)cc(c64)N5c4c(-c5ccccc5)cccc4-c4ccccc4)cc4ccc(c1)c2c34 ; CC(C)(C)c1cc2ccc3cc(-c4ccc5c(c4)B4c6ccc(-n7c8ccccc8c8ccccc87)cc6N(c6c(-c7ccccc7)cccc6-c6ccccc6)c6cc(-n7c8ccccc8c8ccccc87)cc(c64)N5c4c(-c5ccccc5)cccc4-c4ccccc4)cc4ccc(c1)c2c34]

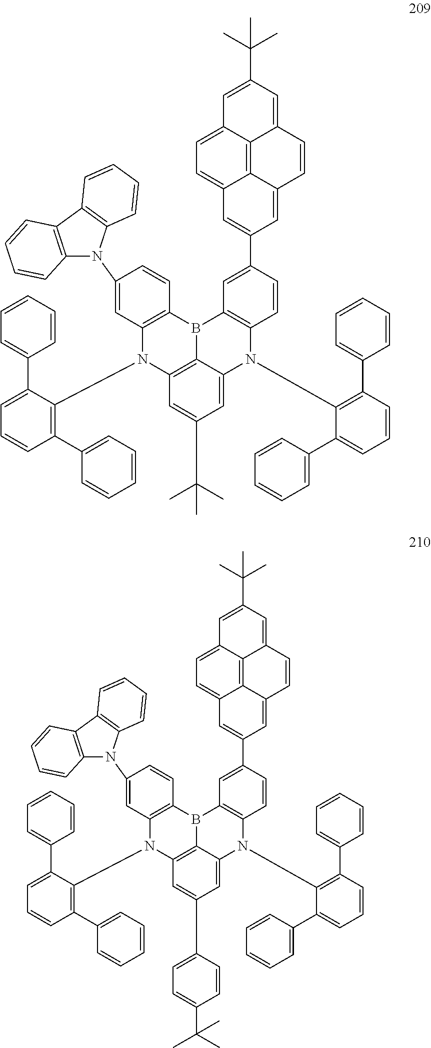 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3cc4ccc5cc(C(C)(C)C)cc6ccc(c3)c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4cc5ccc6cc(C(C)(C)C)cc7ccc(c4)c5c67)ccc2N3c2c(-c3ccccc3)cccc2-c2ccccc2)cc1]

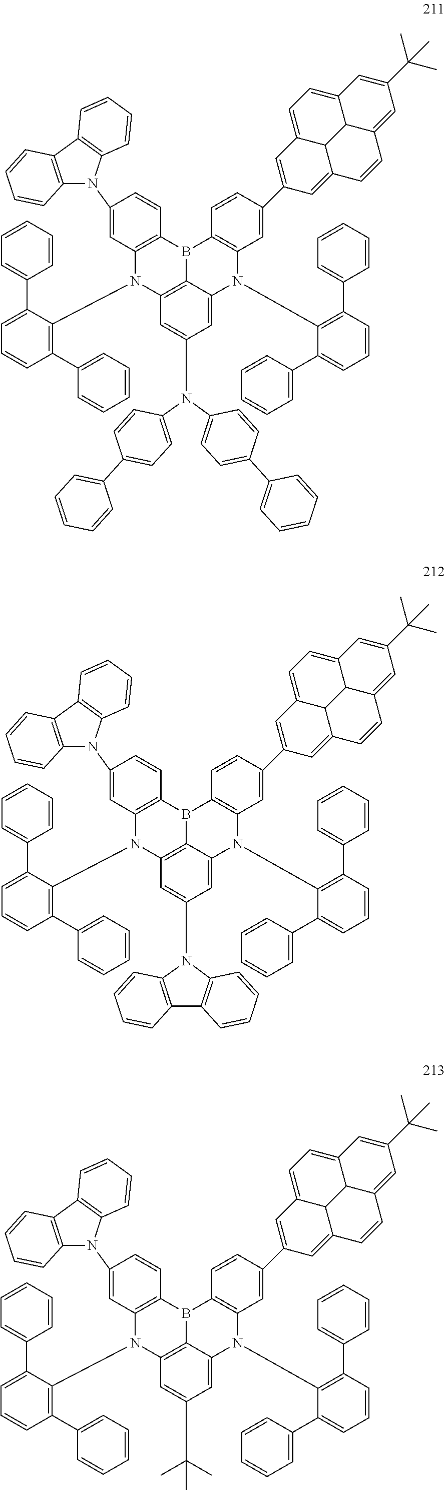

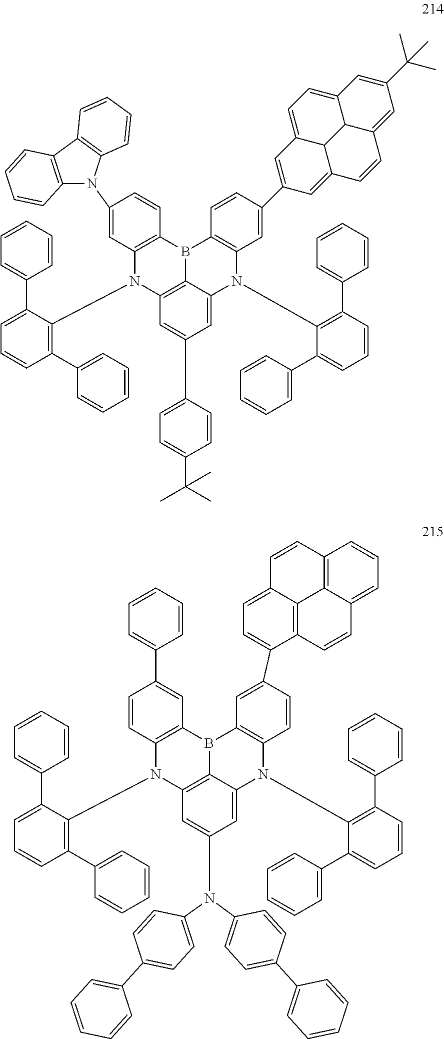 [SMILES: CC(C)(C)C1=CC2=CC=C3C=C(c4ccc5c(c4)N(c4c(-c6ccccc6)cccc4-c4ccccc4)c4cc(-c6ccc(C(C)(C)C)cc6)cc6c4B5c4ccc(-n5c7ccccc7c7ccccc75)cc4N6c4c(-c5ccccc5)cccc4-c4ccccc4)C=C4C=CC(=C1)C2C34 ; c1ccc(-c2ccc(N(c3ccc(-c4ccccc4)cc3)c3cc4c5c(c3)N(c3c(-c6ccccc6)cccc3-c3ccccc3)c3ccc(-c6ccc7ccc8cccc9ccc6c7c89)cc3B5c3cc(-c5ccccc5)ccc3N4c3c(-c4ccccc4)cccc3-c3ccccc3)cc2)cc1]

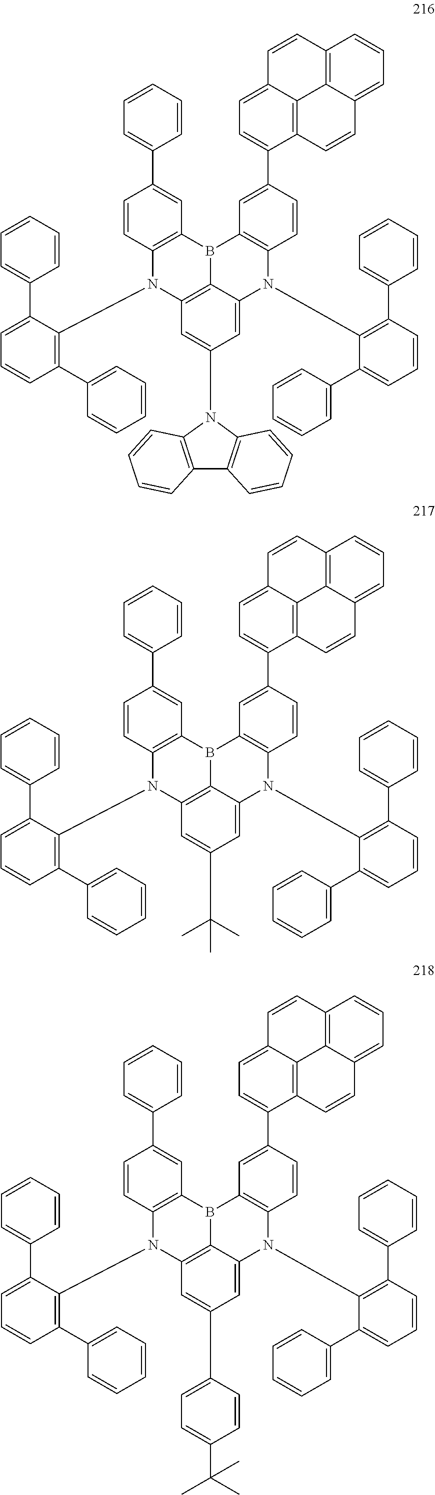 [SMILES: c1ccc(-c2ccc3c(c2)B2c4cc(-c5ccc6ccc7cccc8ccc5c6c78)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1 ; CC(C)(C)c1cc2c3c(c1)N(c1c(-c4ccccc4)cccc1-c1ccccc1)c1ccc(-c4ccc5ccc6cccc7ccc4c5c67)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6ccc7cccc8ccc5c6c78)cc2B4c2cc(-c4ccccc4)ccc2N3c2c(-c3ccccc3)cccc2-c2ccccc2)cc1]

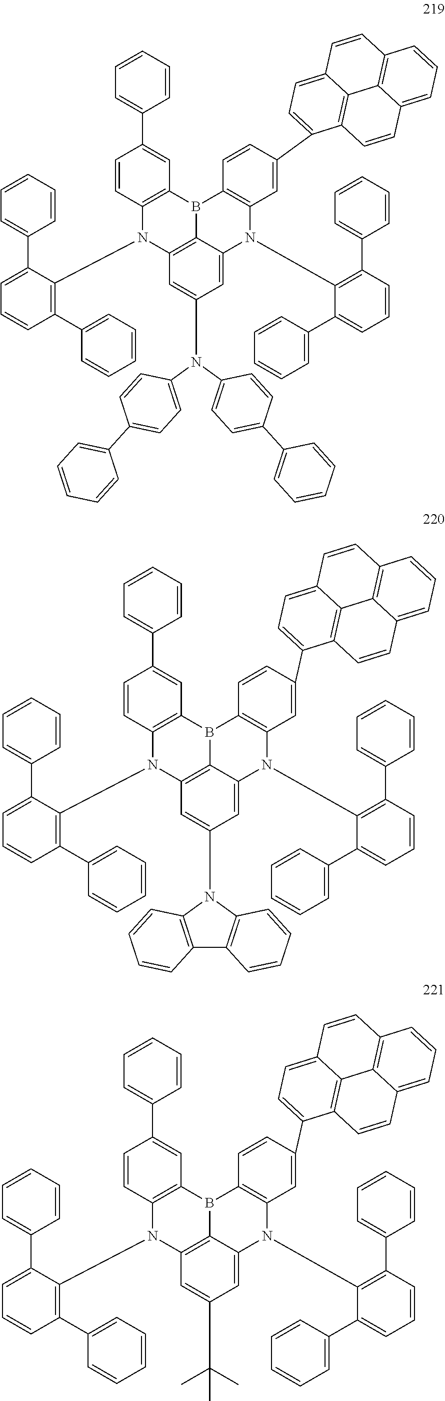 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7ccc8cccc9ccc6c7c89)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5ccc6ccc7cccc8ccc5c6c78)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1 ; CC(C)(C)c1cc2c3c(c1)N(c1c(-c4ccccc4)cccc1-c1ccccc1)c1cc(-c4ccc5ccc6cccc7ccc4c5c67)ccc1B3c1cc(-c3ccccc3)ccc1N2c1c(-c2ccccc2)cccc1-c1ccccc1]

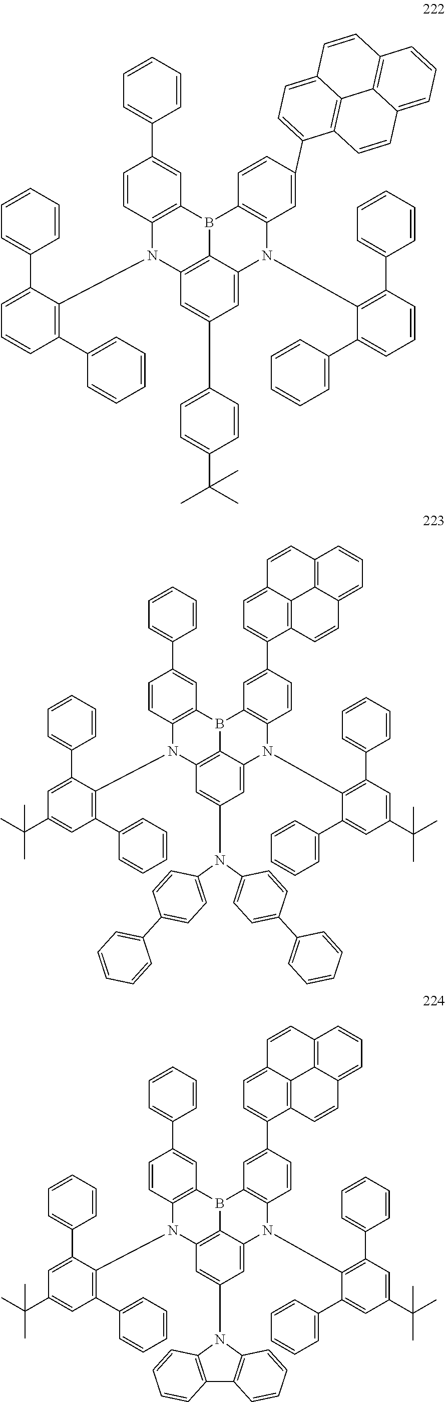

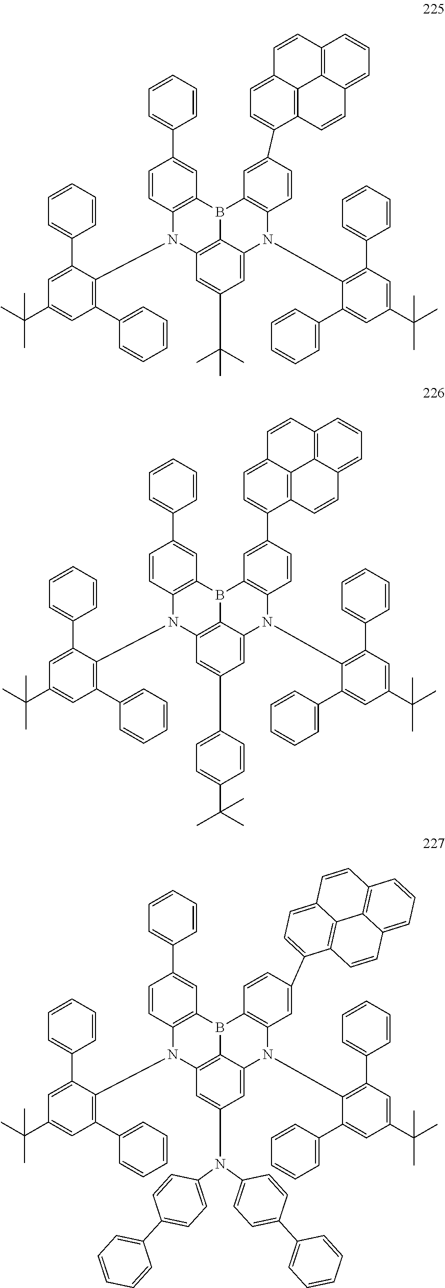

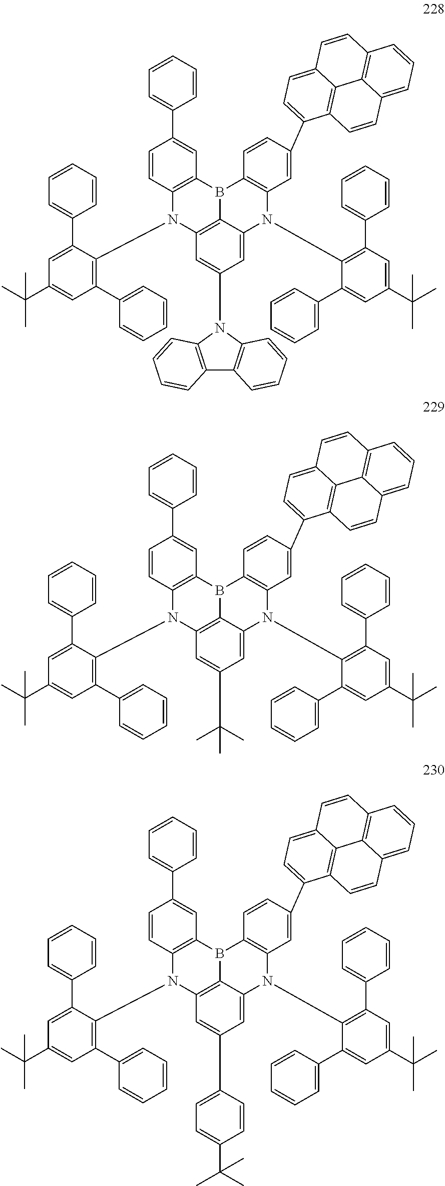

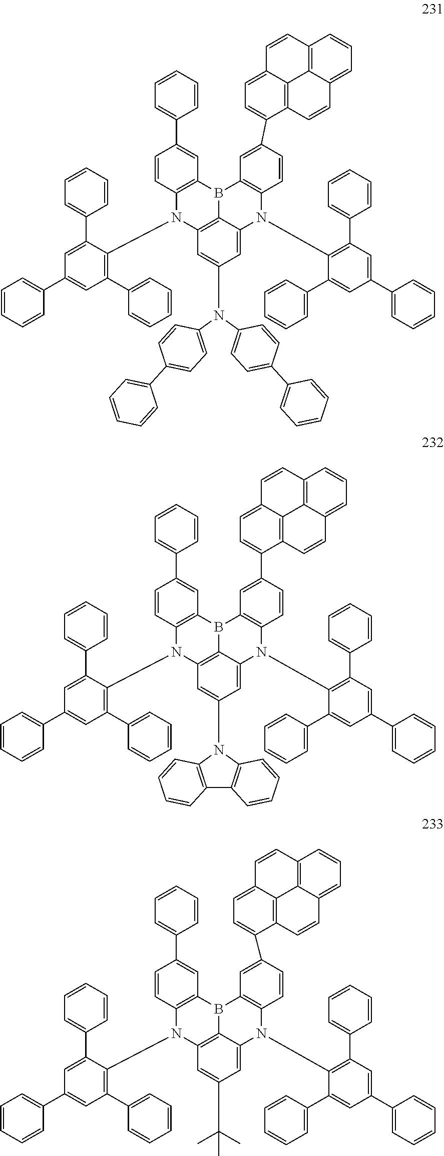

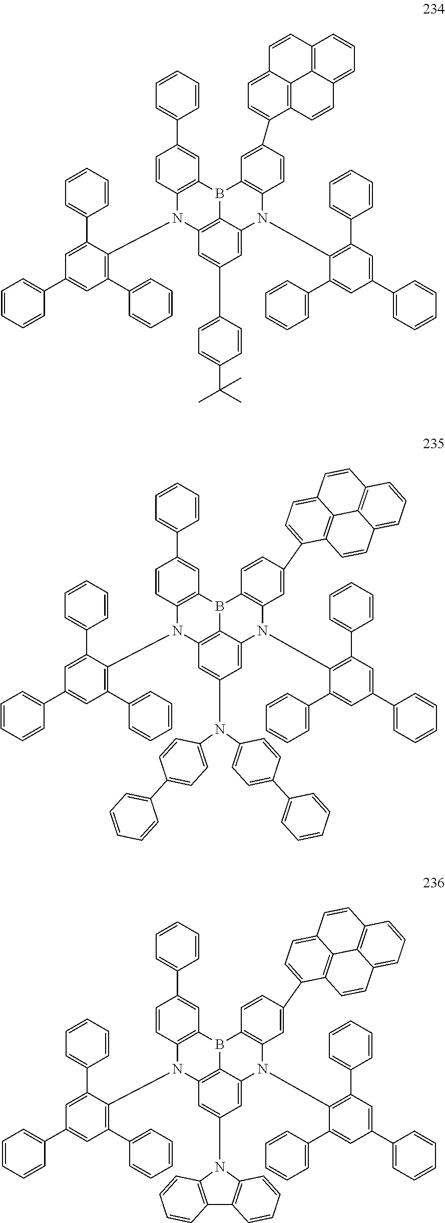

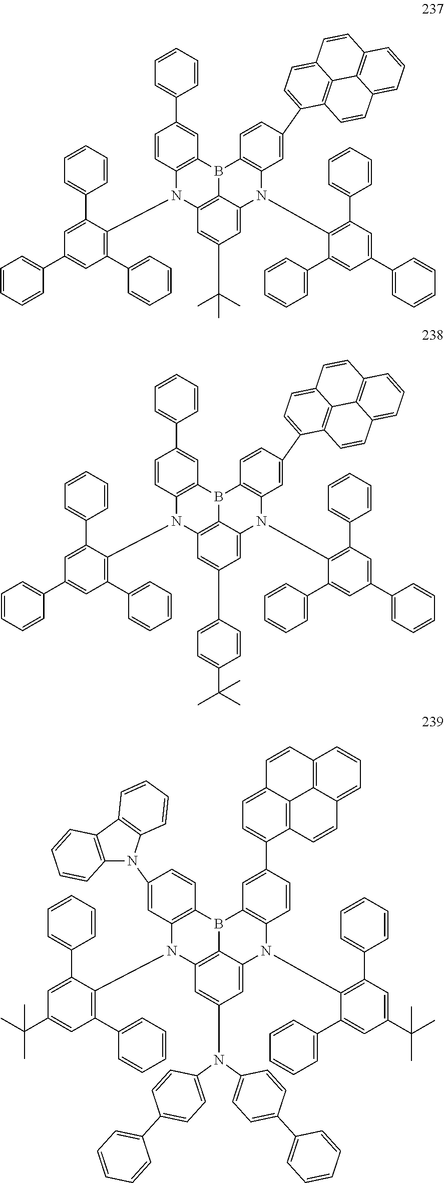

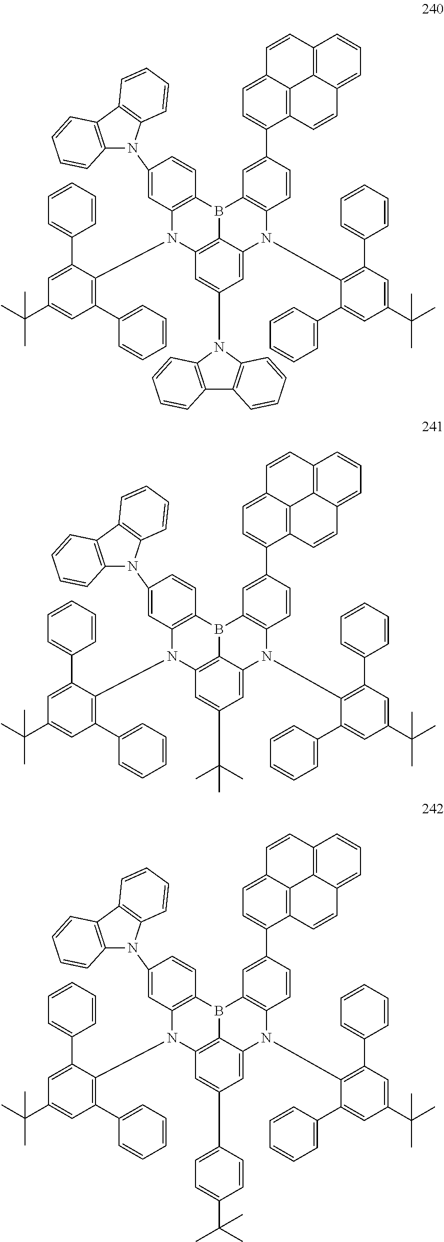

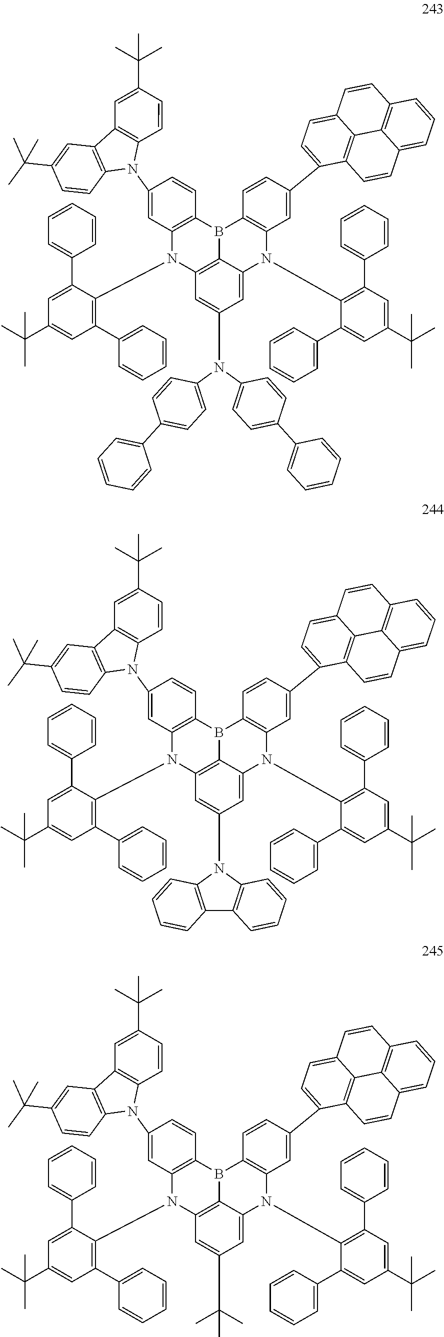

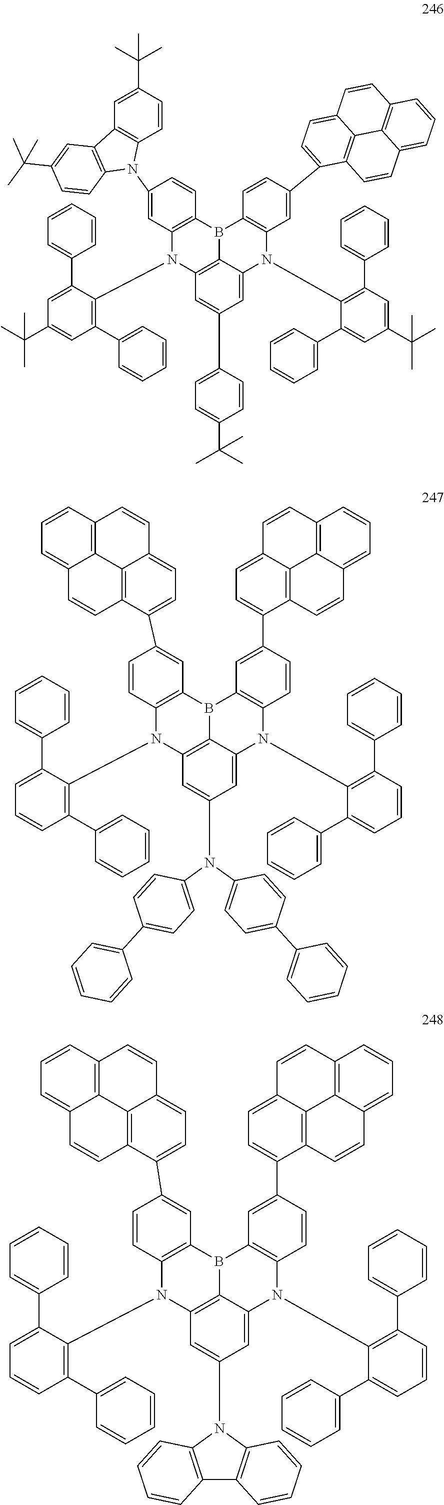

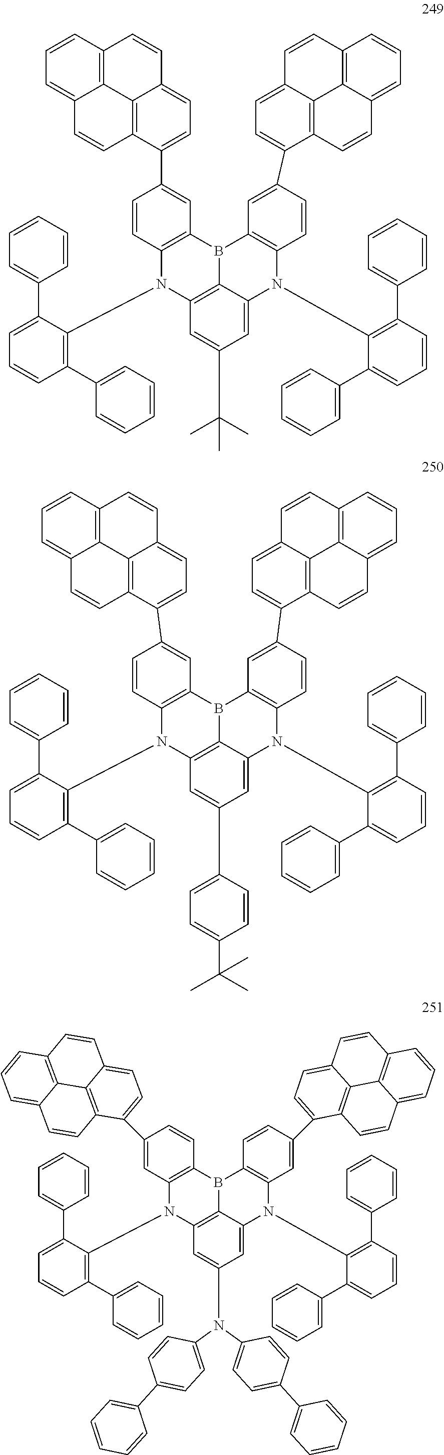

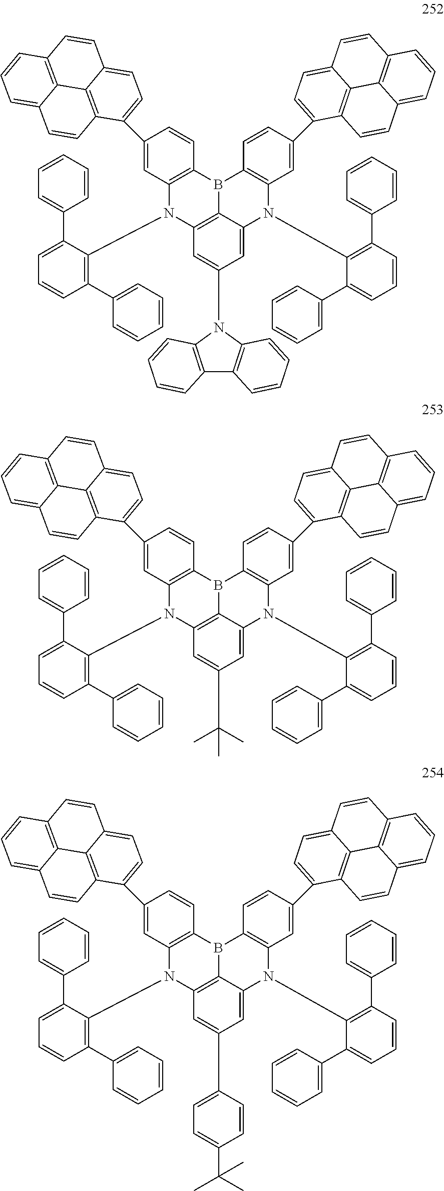 [SMILES: c1ccc(-c2cccc(-c3ccccc3)c2N2c3cc(-c4ccc5ccc6cccc7ccc4c5c67)ccc3B3c4ccc(-c5ccc6ccc7cccc8ccc5c6c78)cc4N(c4c(-c5ccccc5)cccc4-c4ccccc4)c4cc(-n5c6ccccc6c6ccccc65)cc2c43)cc1 ; CC(C)(C)c1cc2c3c(c1)N(c1c(-c4ccccc4)cccc1-c1ccccc1)c1cc(-c4ccc5ccc6cccc7ccc4c5c67)ccc1B3c1ccc(-c3ccc4ccc5cccc6ccc3c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6ccc7cccc8ccc5c6c78)ccc2B4c2ccc(-c4ccc5ccc6cccc7ccc4c5c67)cc2N3c2c(-c3ccccc3)cccc2-c2ccccc2)cc1]

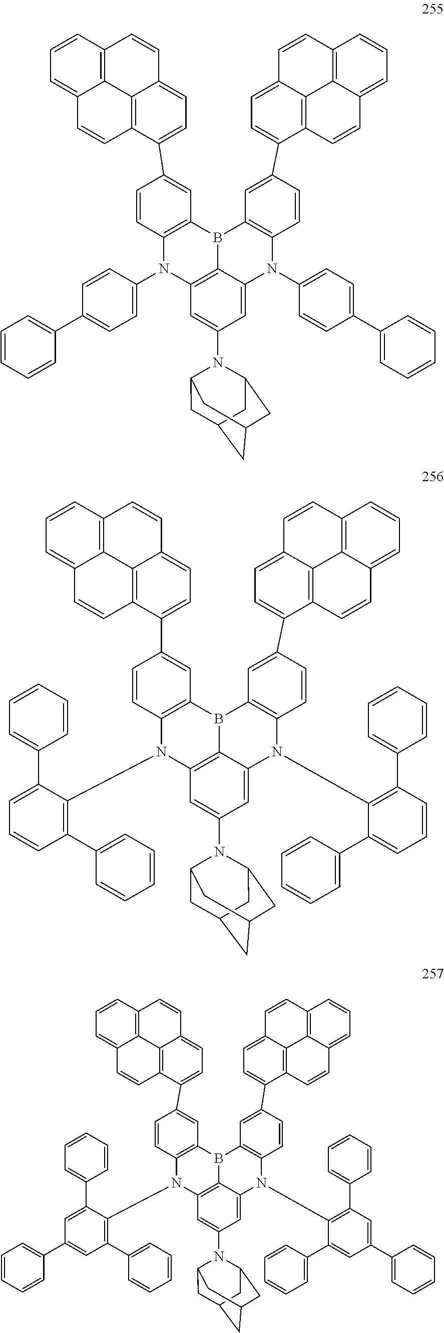

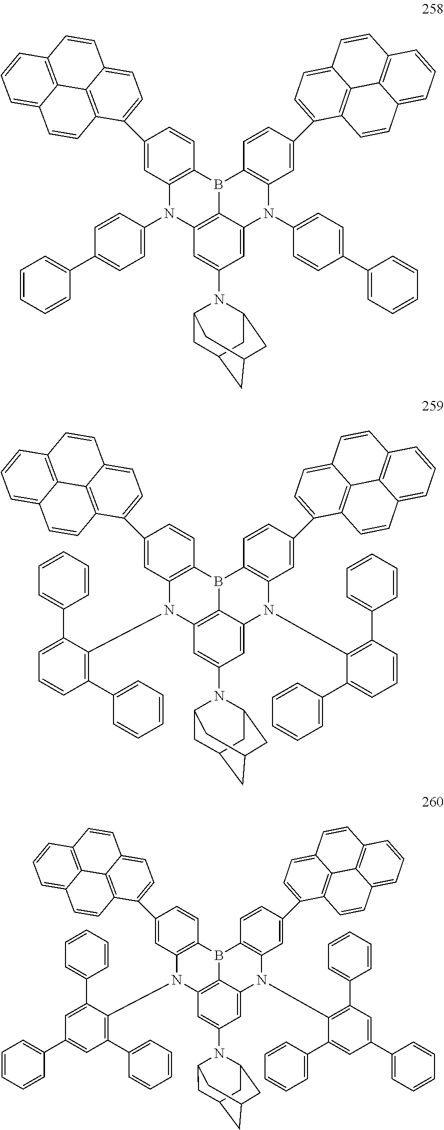

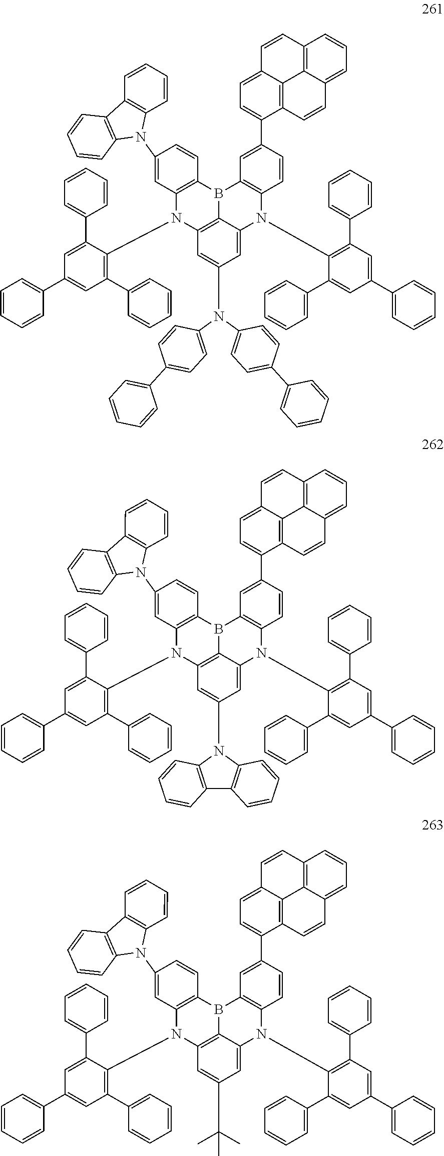

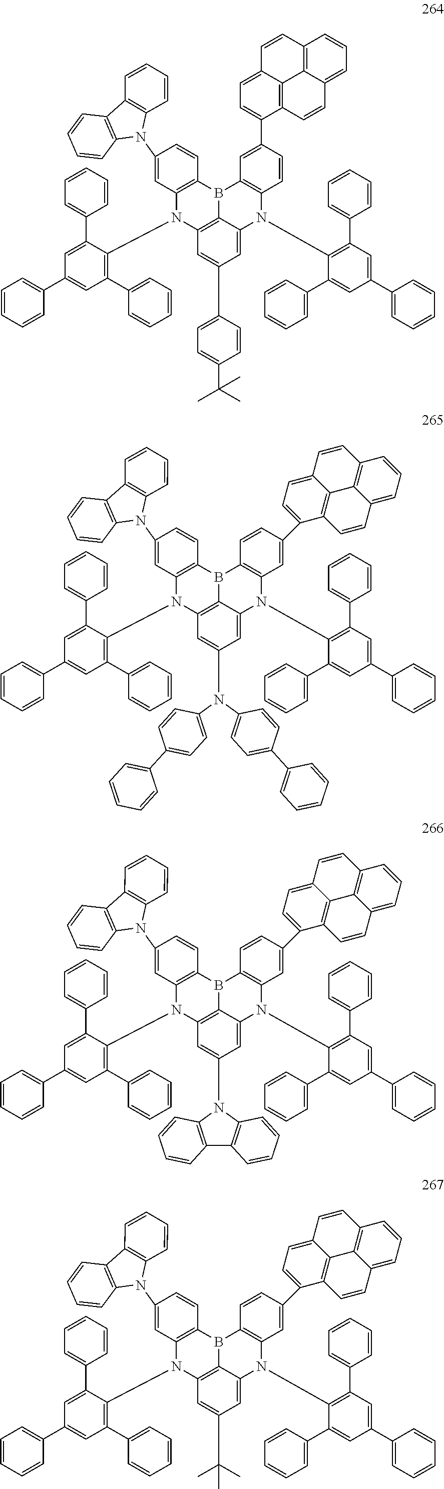

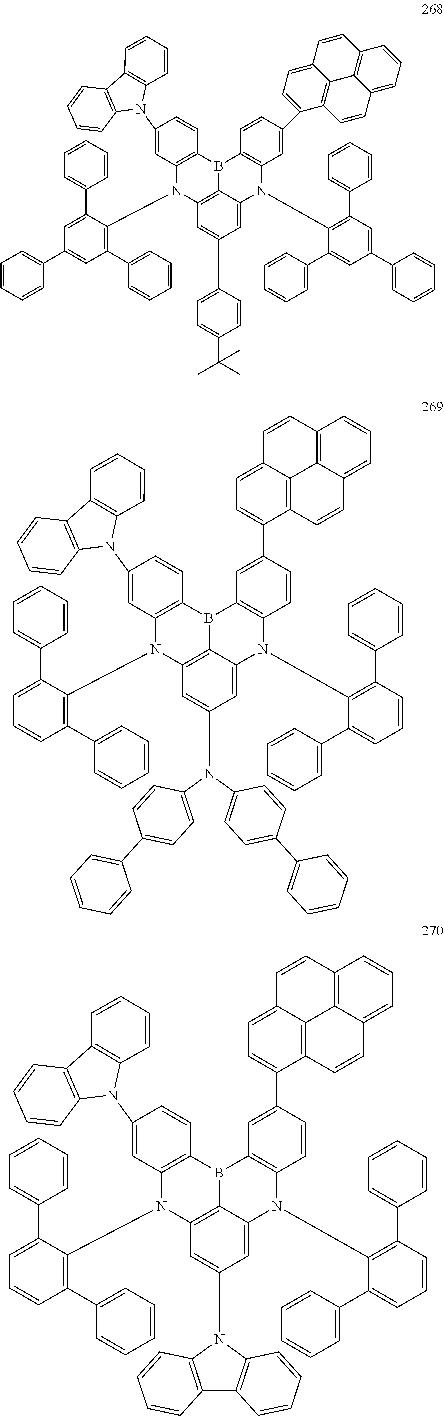

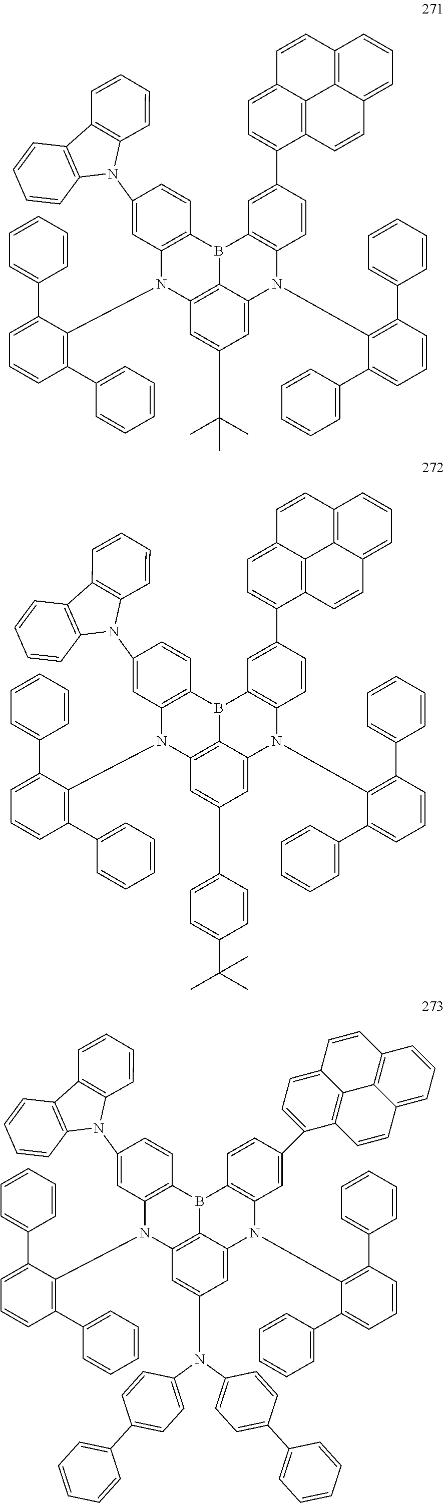 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccc4ccc5cccc6ccc3c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4ccc5ccc6cccc7ccc4c5c67)ccc2N3c2c(-c3ccccc3)cccc2-c2ccccc2)cc1 ; c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3ccc(-c5ccc6ccc7cccc8ccc5c6c78)cc3N4c3c(-c4ccccc4)cccc3-c3ccccc3)cc2)cc1]

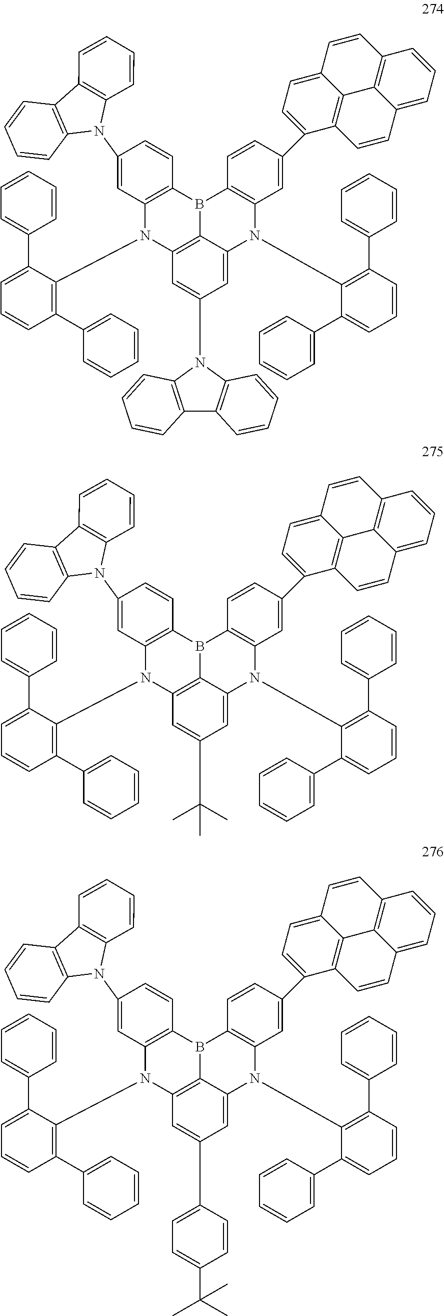 [SMILES: c1ccc(-c2cccc(-c3ccccc3)c2N2c3cc(-c4ccc5ccc6cccc7ccc4c5c67)ccc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1 ; CC(C)(C)c1cc2c3c(c1)N(c1c(-c4ccccc4)cccc1-c1ccccc1)c1cc(-n4c5ccccc5c5ccccc54)ccc1B3c1ccc(-c3ccc4ccc5cccc6ccc3c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4ccc5ccc6cccc7ccc4c5c67)cc2N3c2c(-c3ccccc3)cccc2-c2ccccc2)cc1]

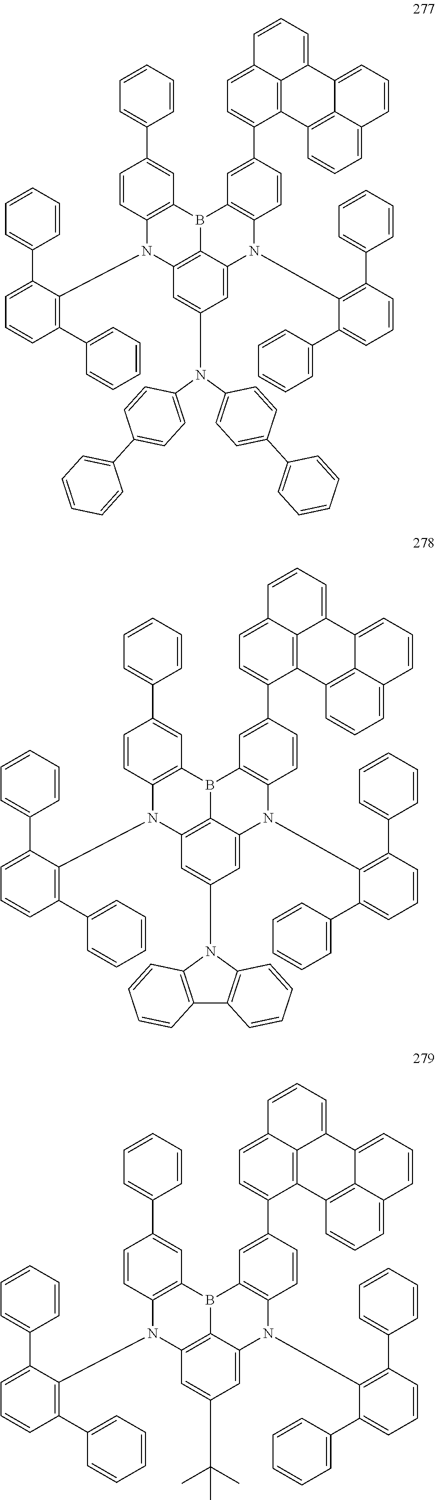 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7cccc8c9cccc%10cccc(c6c78)c%109)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5ccc6cccc7c8cccc9cccc(c5c67)c98)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1 ; CC(C)(C)c1cc2c3c(c1)N(c1c(-c4ccccc4)cccc1-c1ccccc1)c1ccc(-c4ccc5cccc6c7cccc8cccc(c4c56)c87)cc1B3c1cc(-c3ccccc3)ccc1N2c1c(-c2ccccc2)cccc1-c1ccccc1]

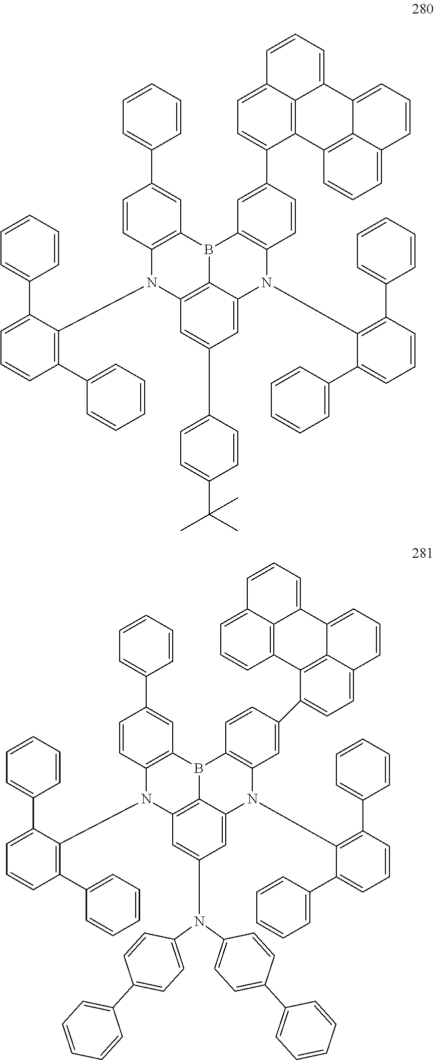 [SMILES: CC(C)(C)c1ccc(-c2cc3c4c(c2)N(c2c(-c5ccccc5)cccc2-c2ccccc2)c2ccc(-c5ccc6cccc7c8cccc9cccc(c5c67)c98)cc2B4c2cc(-c4ccccc4)ccc2N3c2c(-c3ccccc3)cccc2-c2ccccc2)cc1 ; c1ccc(-c2ccc(N(c3ccc(-c4ccccc4)cc3)c3cc4c5c(c3)N(c3c(-c6ccccc6)cccc3-c3ccccc3)c3cc(-c6ccc7cccc8c9cccc%10cccc(c6c78)c%109)ccc3B5c3cc(-c5ccccc5)ccc3N4c3c(-c4ccccc4)cccc3-c3ccccc3)cc2)cc1]

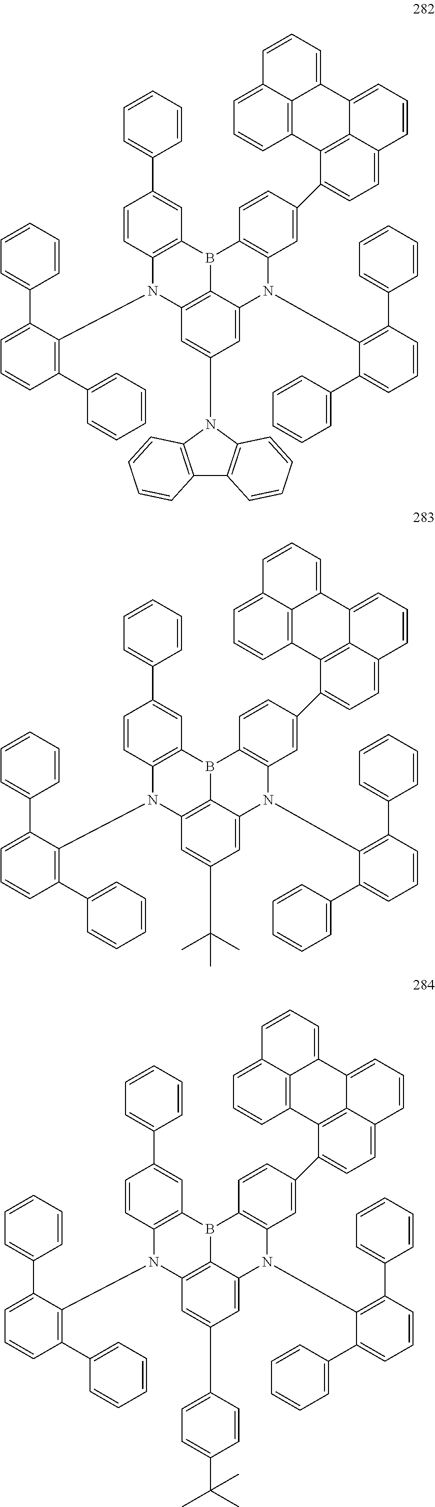 [SMILES: c1ccc(-c2ccc3c(c2)B2c4ccc(-c5ccc6cccc7c8cccc9cccc(c5c67)c98)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1 ; CC(C)(C)c1cc2c3c(c1)N(c1c(-c4ccccc4)cccc1-c1ccccc1)c1cc(-c4ccc5cccc6c7cccc8cccc(c4c56)c87)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6cccc7c8cccc9cccc(c5c67)c98)ccc2B4c2cc(-c4ccccc4)ccc2N3c2c(-c3ccccc3)cccc2-c2ccccc2)cc1]

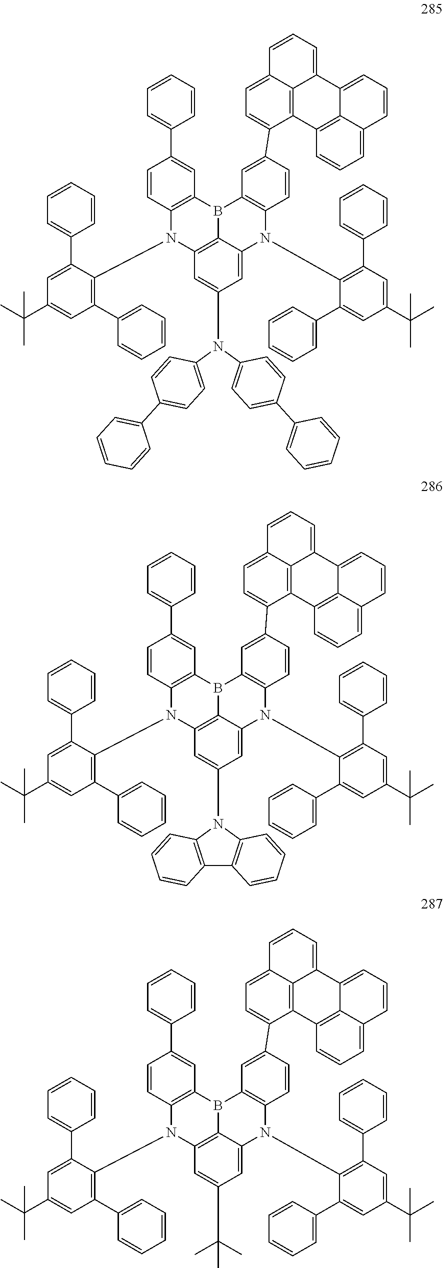

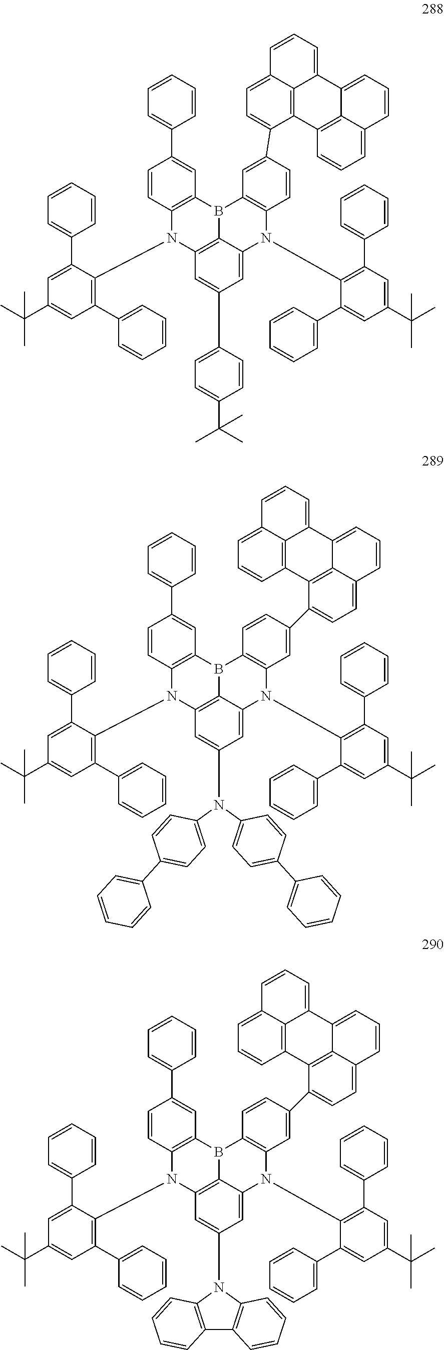

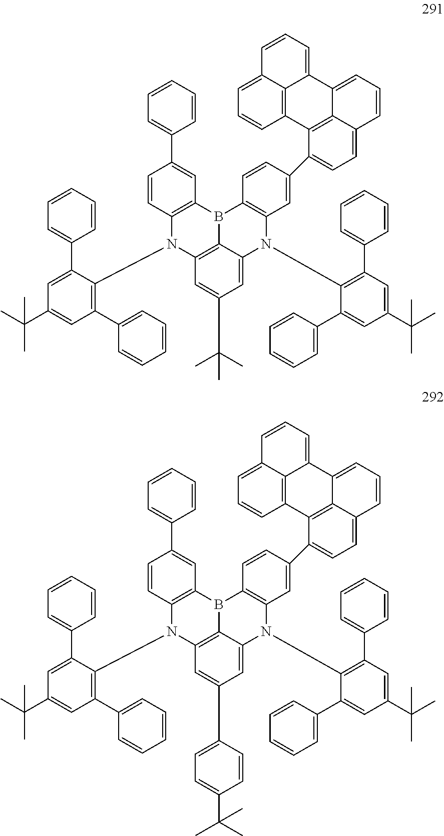

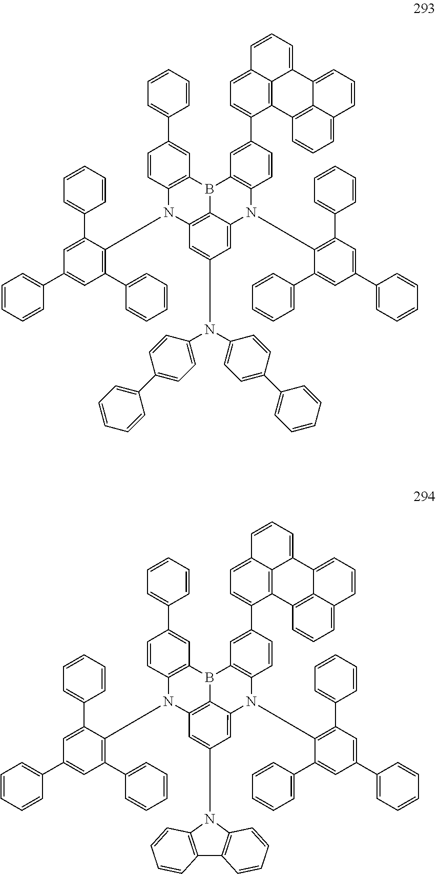 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccc7cccc8c9cccc%10cccc(c6c78)c%109)cc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4cc(-c5ccc6cccc7c8cccc9cccc(c5c67)c98)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1]

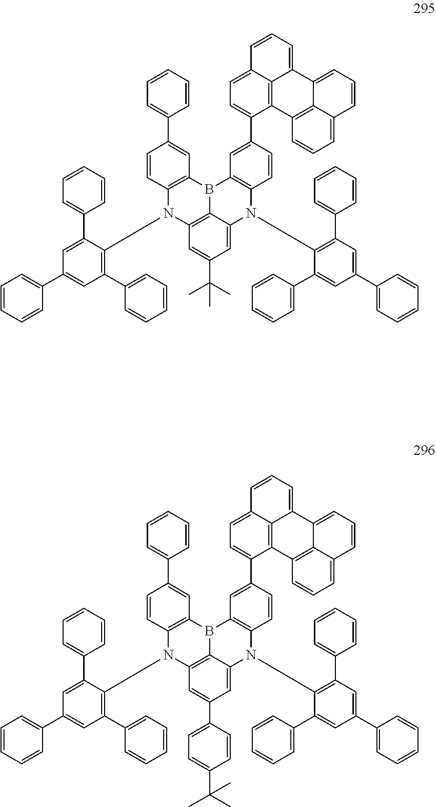 [SMILES: CC(C)(C)c1cc2c3c(c1)N(c1c(-c4ccccc4)cc(-c4ccccc4)cc1-c1ccccc1)c1ccc(-c4ccc5cccc6c7cccc8cccc(c4c56)c87)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5ccc6cccc7c8cccc9cccc(c5c67)c98)cc2B4c2cc(-c4ccccc4)ccc2N3c2c(-c3ccccc3)cc(-c3ccccc3)cc2-c2ccccc2)cc1]

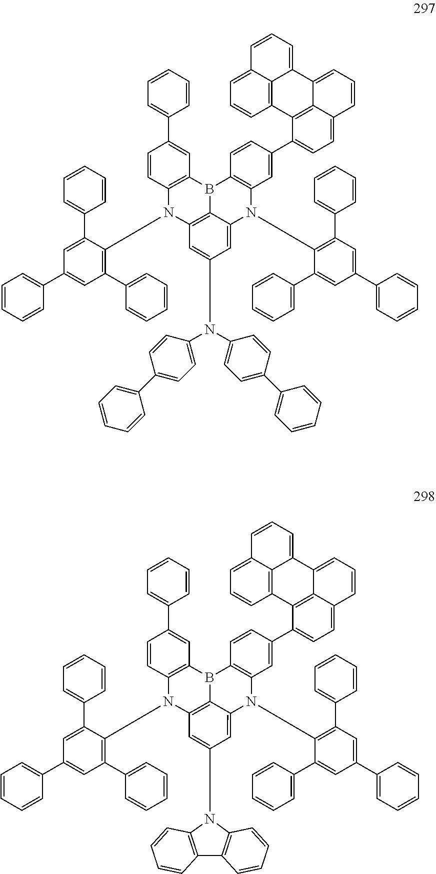 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-c6ccc7cccc8c9cccc%10cccc(c6c78)c%109)ccc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4ccc(-c5ccc6cccc7c8cccc9cccc(c5c67)c98)cc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1]

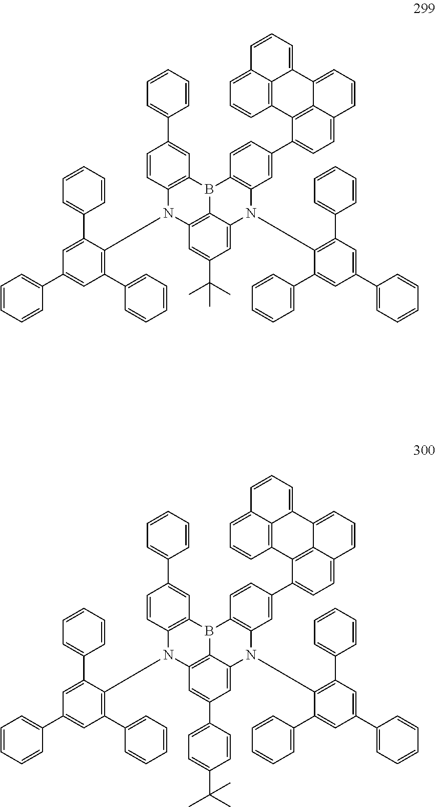 [SMILES: CC(C)(C)c1cc2c3c(c1)N(c1c(-c4ccccc4)cc(-c4ccccc4)cc1-c1ccccc1)c1cc(-c4ccc5cccc6c7cccc8cccc(c4c56)c87)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5ccc6cccc7c8cccc9cccc(c5c67)c98)ccc2B4c2cc(-c4ccccc4)ccc2N3c2c(-c3ccccc3)cc(-c3ccccc3)cc2-c2ccccc2)cc1]

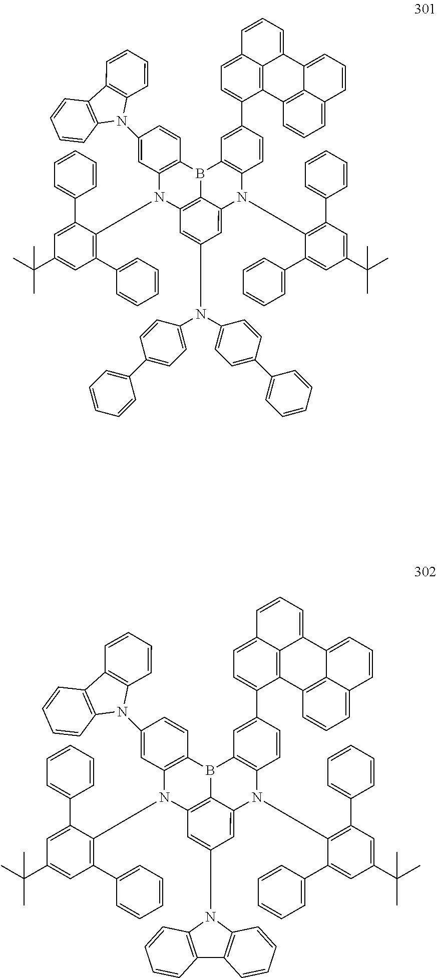

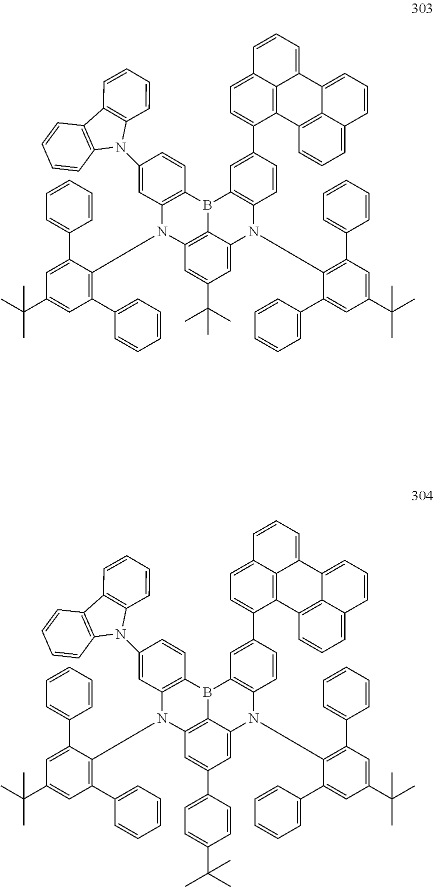

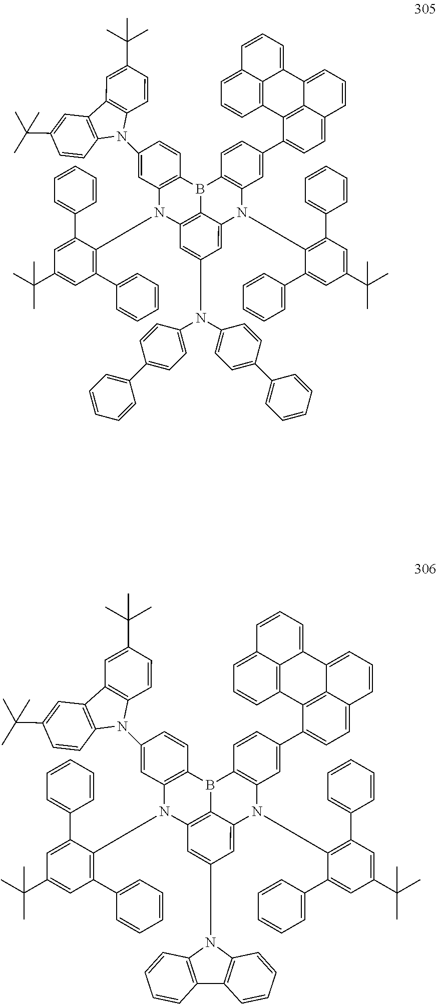

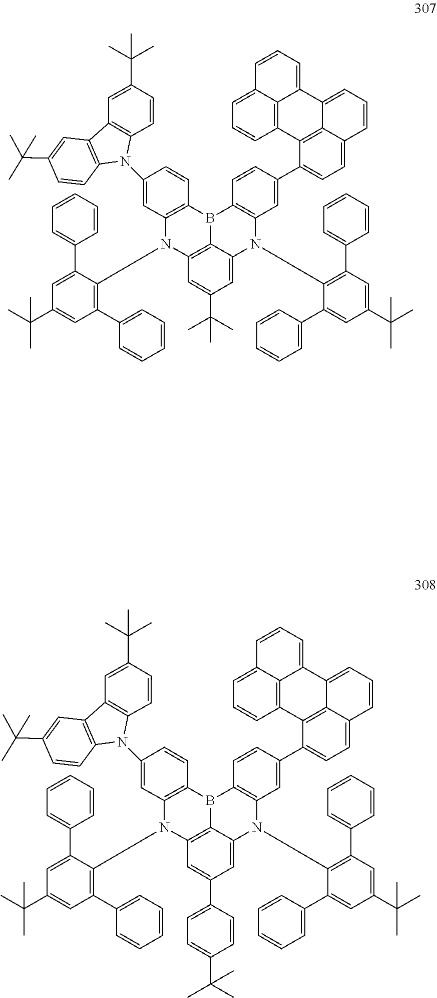

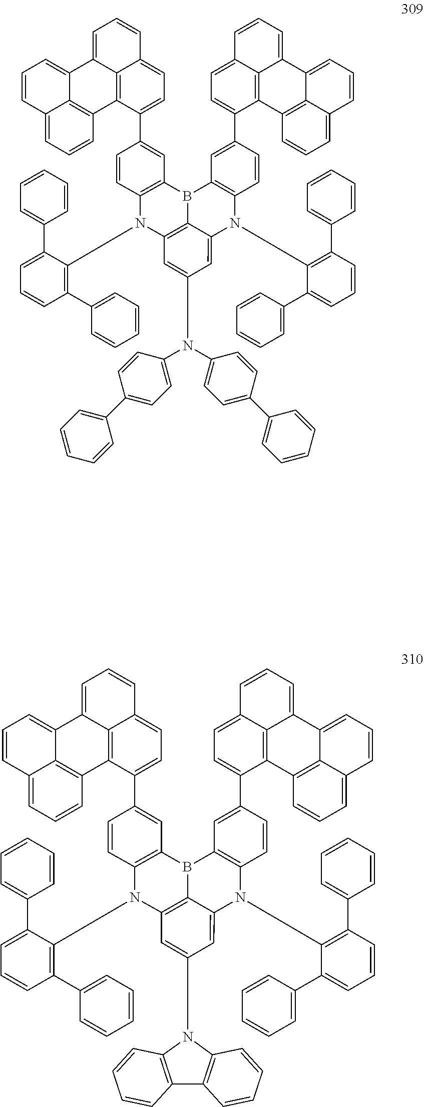 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7cccc8c9cccc%10cccc(c6c78)c%109)cc3B5c3cc(-c5ccc6cccc7c8cccc9cccc(c5c67)c98)ccc3N4c3c(-c4ccccc4)cccc3-c3ccccc3)cc2)cc1 ; c1ccc(-c2cccc(-c3ccccc3)c2N2c3ccc(-c4ccc5cccc6c7cccc8cccc(c4c56)c87)cc3B3c4cc(-c5ccc6cccc7c8cccc9cccc(c5c67)c98)ccc4N(c4c(-c5ccccc5)cccc4-c4ccccc4)c4cc(-n5c6ccccc6c6ccccc65)cc2c43)cc1]

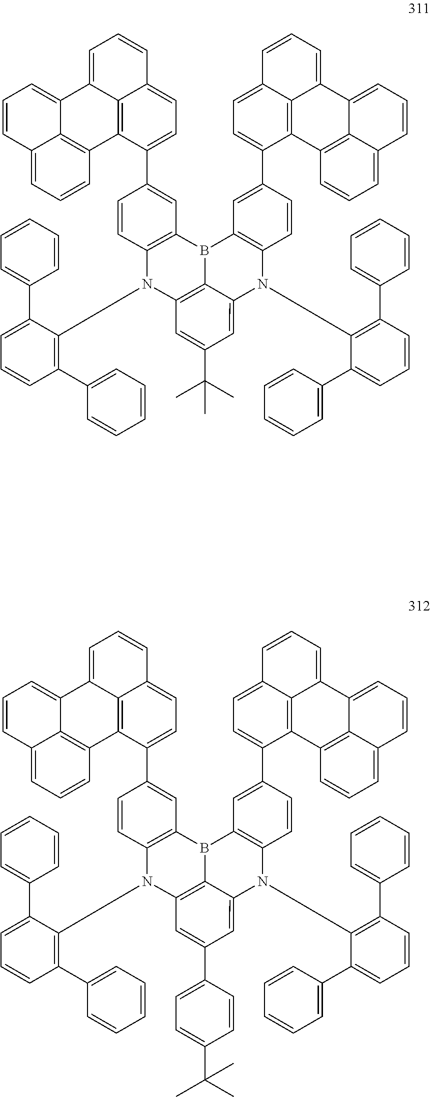 [SMILES: CC(C)(C)c1cc2c3c(c1)N(c1c(-c4ccccc4)cccc1-c1ccccc1)c1ccc(-c4ccc5cccc6c7cccc8cccc(c4c56)c87)cc1B3c1cc(-c3ccc4cccc5c6cccc7cccc(c3c45)c76)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6cccc7c8cccc9cccc(c5c67)c98)cc2B4c2cc(-c4ccc5cccc6c7cccc8cccc(c4c56)c87)ccc2N3c2c(-c3ccccc3)cccc2-c2ccccc2)cc1]

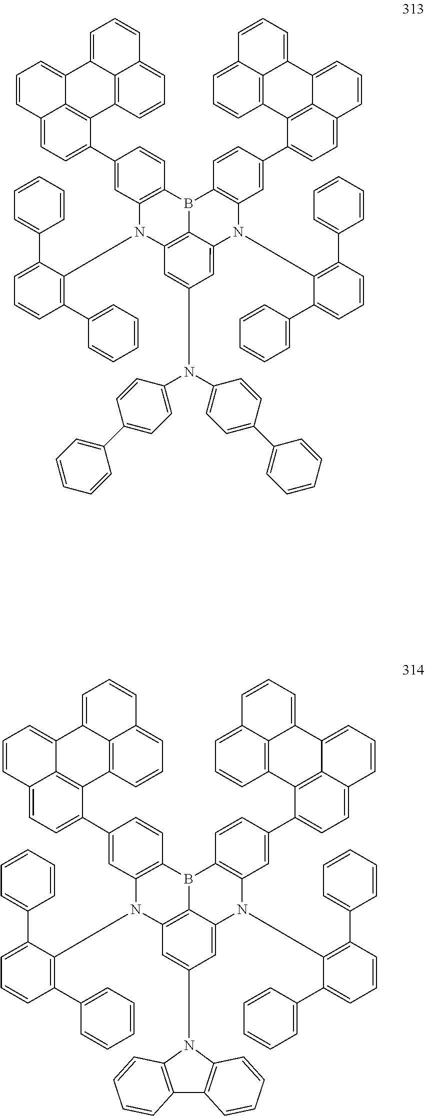 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7cccc8c9cccc%10cccc(c6c78)c%109)ccc3B5c3ccc(-c5ccc6cccc7c8cccc9cccc(c5c67)c98)cc3N4c3c(-c4ccccc4)cccc3-c3ccccc3)cc2)cc1 ; c1ccc(-c2cccc(-c3ccccc3)c2N2c3cc(-c4ccc5cccc6c7cccc8cccc(c4c56)c87)ccc3B3c4ccc(-c5ccc6cccc7c8cccc9cccc(c5c67)c98)cc4N(c4c(-c5ccccc5)cccc4-c4ccccc4)c4cc(-n5c6ccccc6c6ccccc65)cc2c43)cc1]

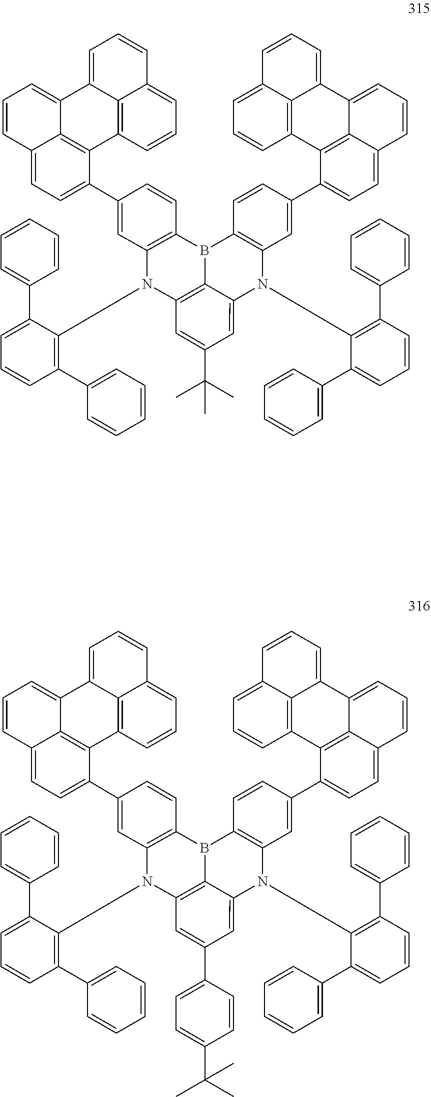 [SMILES: CC(C)(C)c1cc2c3c(c1)N(c1c(-c4ccccc4)cccc1-c1ccccc1)c1cc(-c4ccc5cccc6c7cccc8cccc(c4c56)c87)ccc1B3c1ccc(-c3ccc4cccc5c6cccc7cccc(c3c45)c76)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6cccc7c8cccc9cccc(c5c67)c98)ccc2B4c2ccc(-c4ccc5cccc6c7cccc8cccc(c4c56)c87)cc2N3c2c(-c3ccccc3)cccc2-c2ccccc2)cc1]

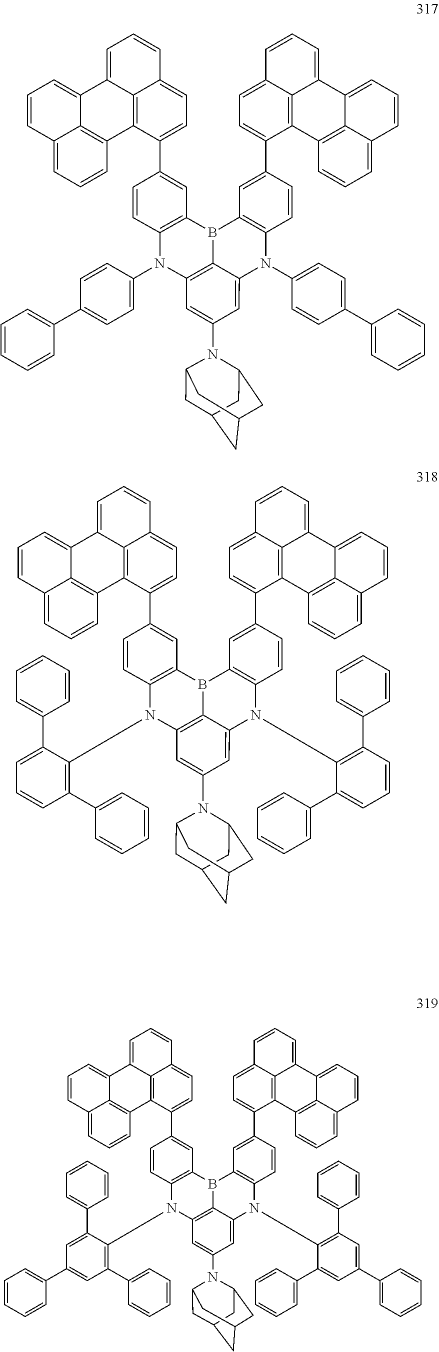

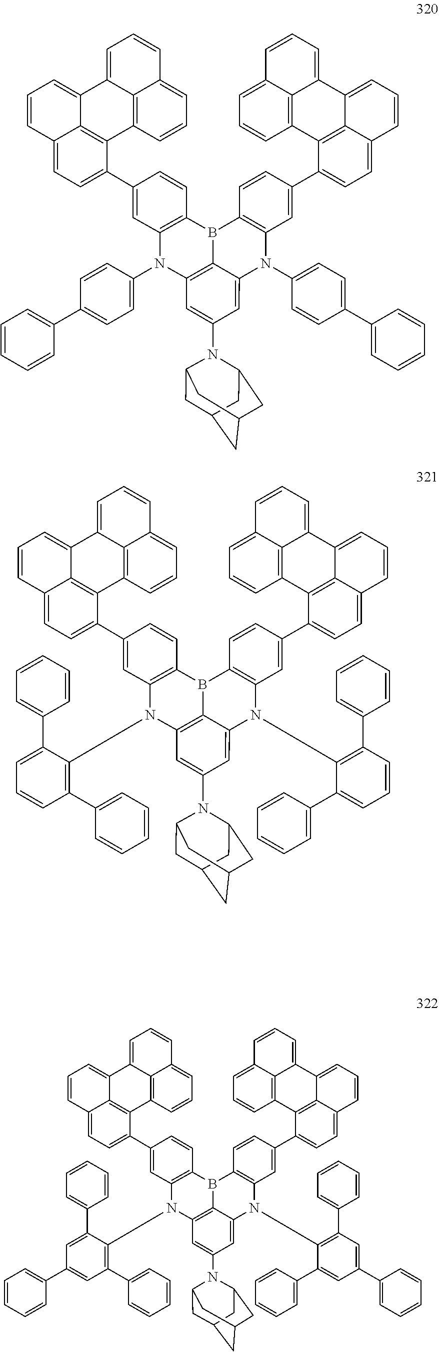

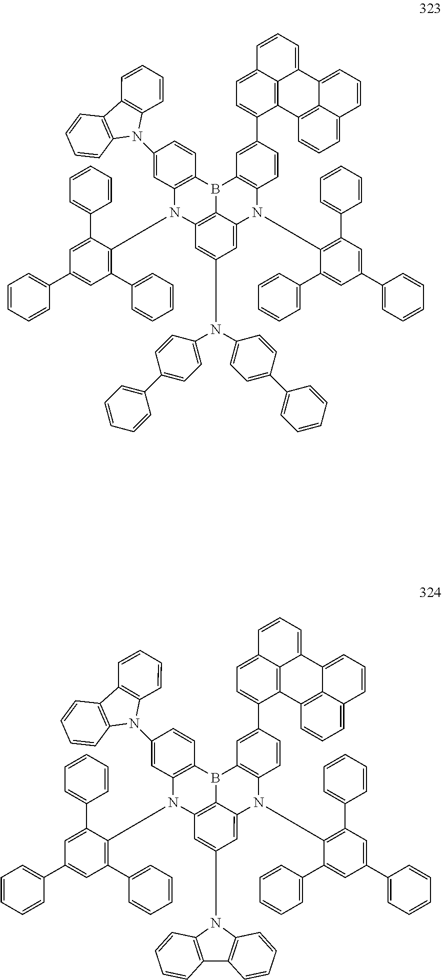 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3cc(-c5ccc6cccc7c8cccc9cccc(c5c67)c98)ccc3N4c3c(-c4ccccc4)cc(-c4ccccc4)cc3-c3ccccc3)cc2)cc1 ; c1ccc(-c2cc(-c3ccccc3)c(N3c4ccc(-c5ccc6cccc7c8cccc9cccc(c5c67)c98)cc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

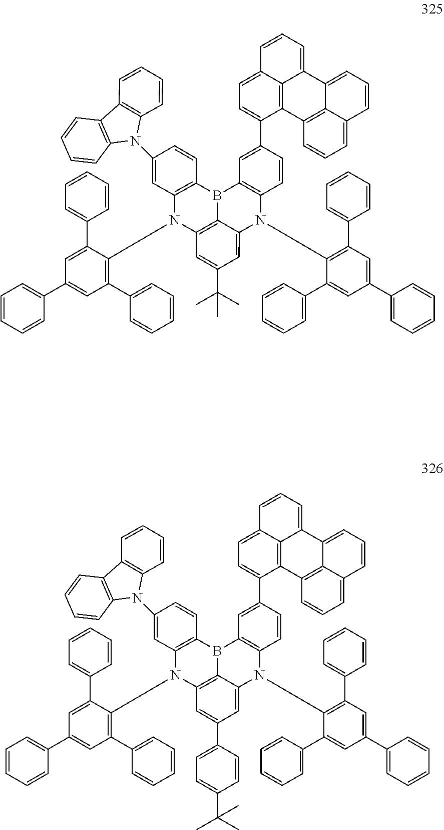 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1cc(-c3ccc4cccc5c6cccc7cccc(c3c45)c76)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4ccc5cccc6c7cccc8cccc(c4c56)c87)ccc2N3c2c(-c3ccccc3)cc(-c3ccccc3)cc2-c2ccccc2)cc1]

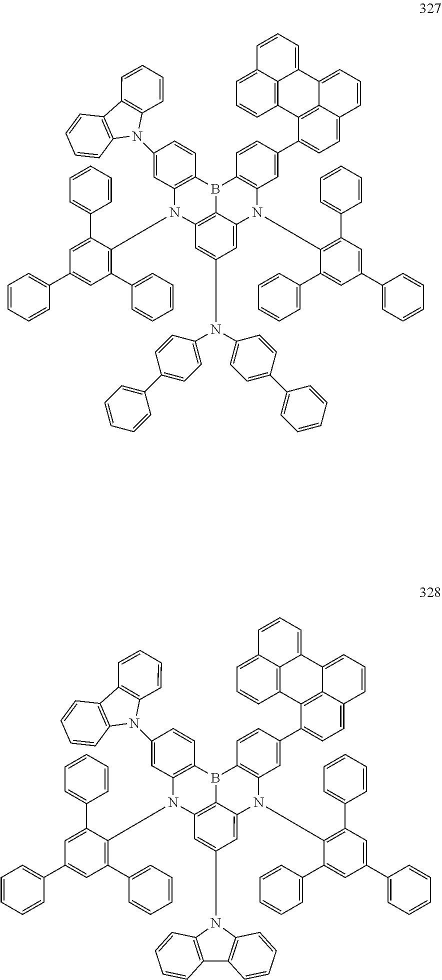 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3ccc(-c5ccc6cccc7c8cccc9cccc(c5c67)c98)cc3N4c3c(-c4ccccc4)cc(-c4ccccc4)cc3-c3ccccc3)cc2)cc1 ; c1ccc(-c2cc(-c3ccccc3)c(N3c4cc(-c5ccc6cccc7c8cccc9cccc(c5c67)c98)ccc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

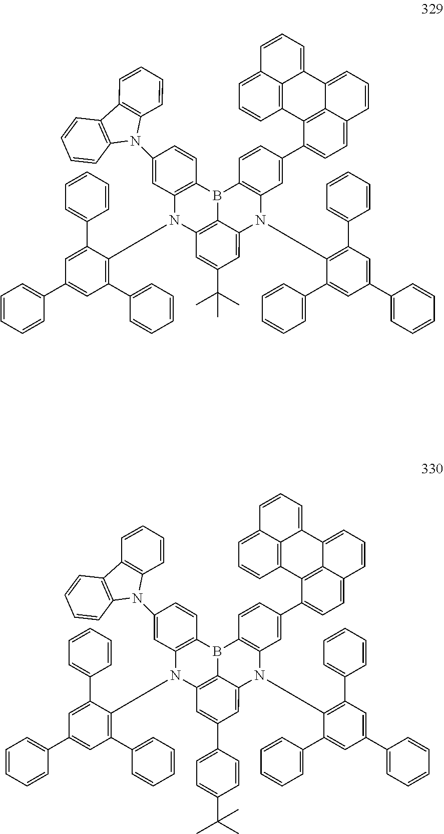 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc(-c3ccc4cccc5c6cccc7cccc(c3c45)c76)cc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2ccc(-c4ccc5cccc6c7cccc8cccc(c4c56)c87)cc2N3c2c(-c3ccccc3)cc(-c3ccccc3)cc2-c2ccccc2)cc1]

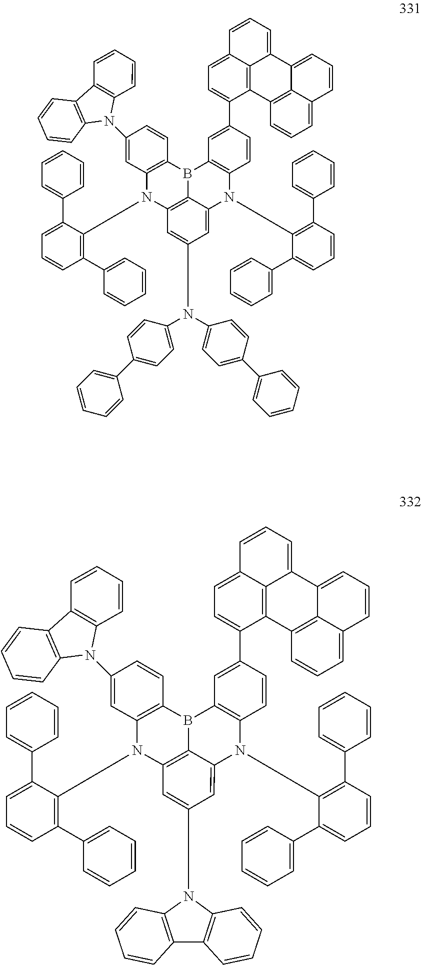 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3cc(-c5ccc6cccc7c8cccc9cccc(c5c67)c98)ccc3N4c3c(-c4ccccc4)cccc3-c3ccccc3)cc2)cc1 ; c1ccc(-c2cccc(-c3ccccc3)c2N2c3ccc(-c4ccc5cccc6c7cccc8cccc(c4c56)c87)cc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1]

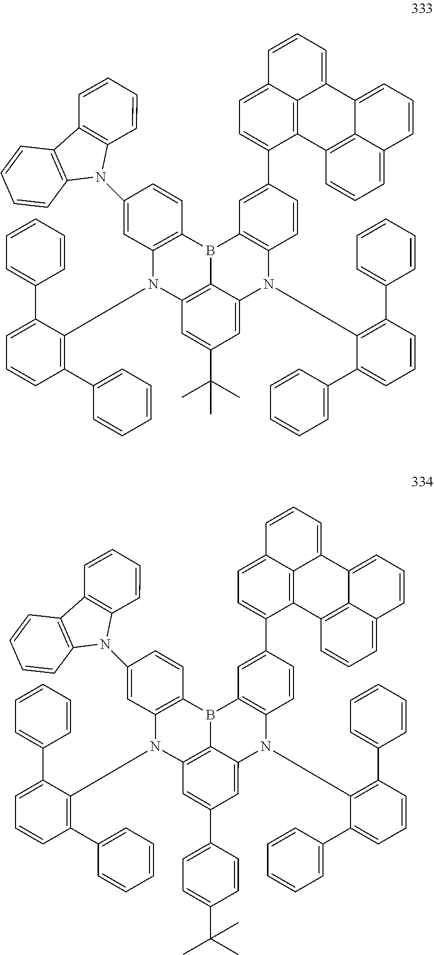 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccc4cccc5c6cccc7cccc(c3c45)c76)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4ccc5cccc6c7cccc8cccc(c4c56)c87)ccc2N3c2c(-c3ccccc3)cccc2-c2ccccc2)cc1]

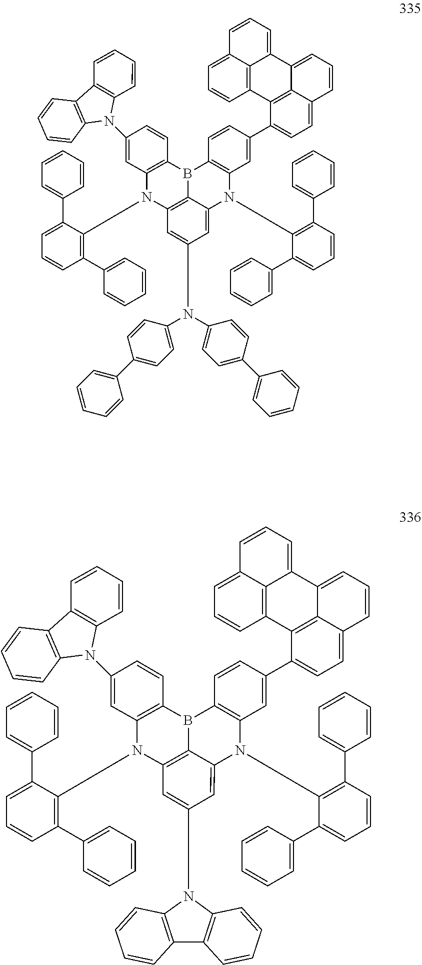 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3ccc(-c5ccc6cccc7c8cccc9cccc(c5c67)c98)cc3N4c3c(-c4ccccc4)cccc3-c3ccccc3)cc2)cc1 ; c1ccc(-c2cccc(-c3ccccc3)c2N2c3cc(-c4ccc5cccc6c7cccc8cccc(c4c56)c87)ccc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1]

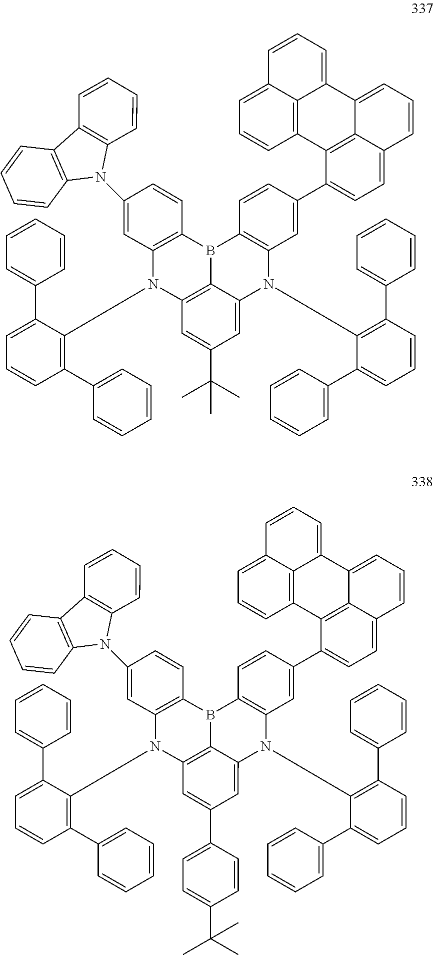 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-c3ccc4cccc5c6cccc7cccc(c3c45)c76)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4ccc5cccc6c7cccc8cccc(c4c56)c87)cc2N3c2c(-c3ccccc3)cccc2-c2ccccc2)cc1]

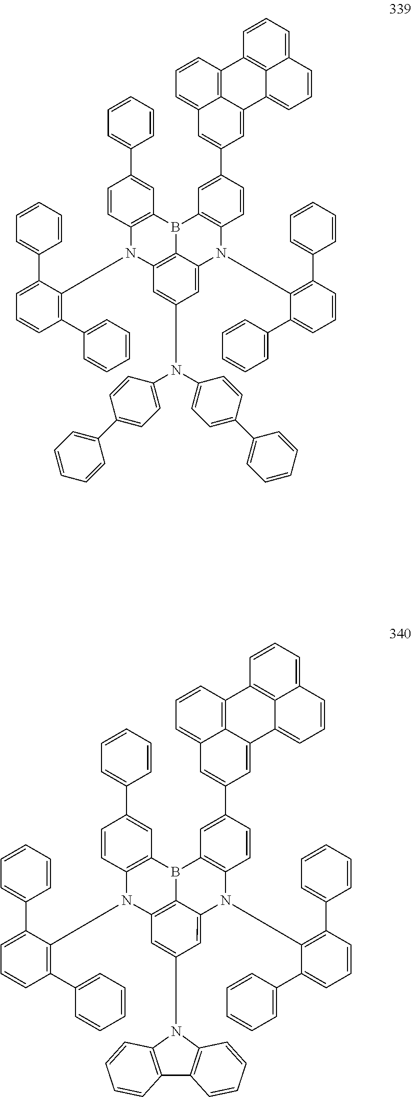 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6cc7cccc8c9cccc%10cccc(c(c6)c78)c%109)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5cc6cccc7c8cccc9cccc(c(c5)c67)c98)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1]

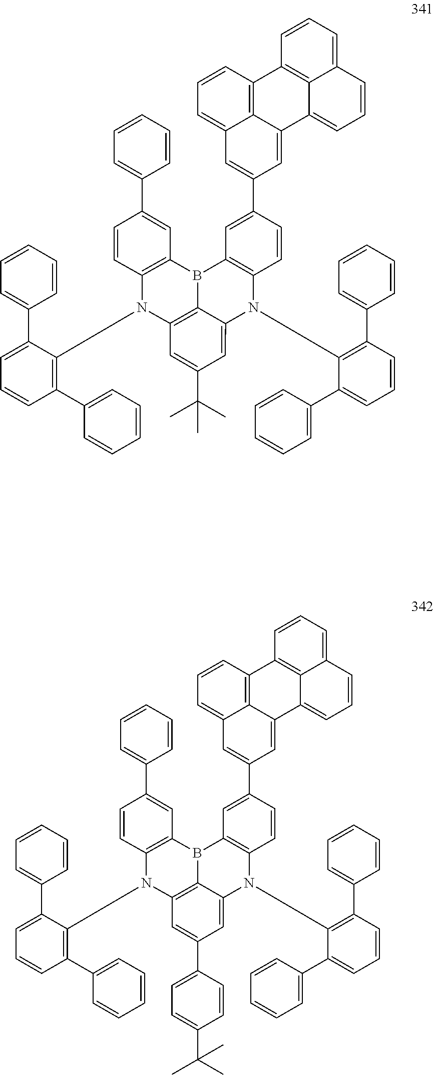 [SMILES: CC(C)(C)c1cc2c3c(c1)N(c1c(-c4ccccc4)cccc1-c1ccccc1)c1ccc(-c4cc5cccc6c7cccc8cccc(c(c4)c56)c87)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6cccc7c8cccc9cccc(c(c5)c67)c98)cc2B4c2cc(-c4ccccc4)ccc2N3c2c(-c3ccccc3)cccc2-c2ccccc2)cc1]

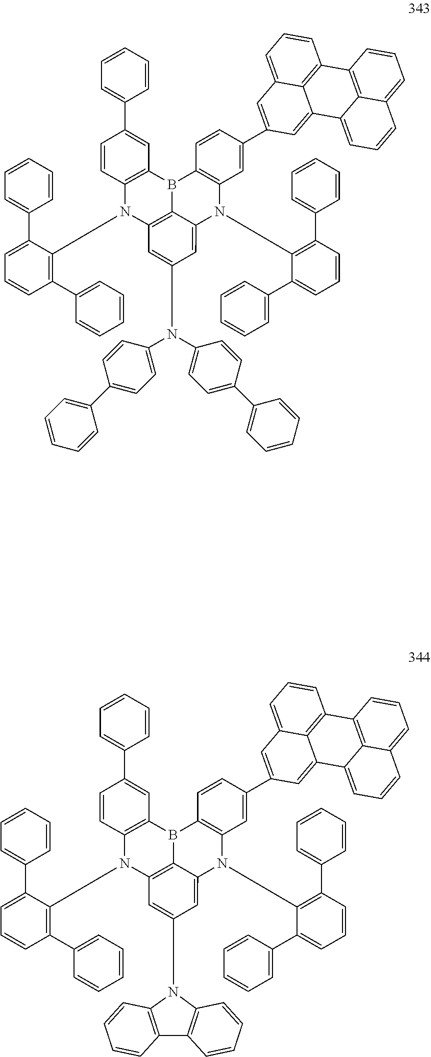 [SMILES: c1ccc(-c2ccc(N(c3ccc(-c4ccccc4)cc3)c3cc4c5c(c3)N(c3c(-c6ccccc6)cccc3-c3ccccc3)c3cc(-c6cc7cccc8c9cccc%10cccc(c(c6)c78)c%109)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5cc6cccc7c8cccc9cccc(c(c5)c67)c98)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1]

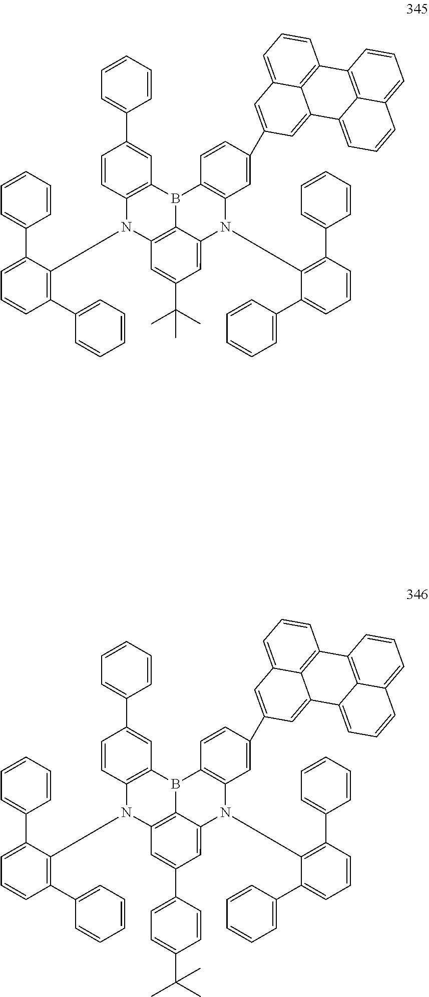 [SMILES: CC(C)(C)c1cc2c3c(c1)N(c1c(-c4ccccc4)cccc1-c1ccccc1)c1cc(-c4cc5cccc6c7cccc8cccc(c(c4)c56)c87)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5cc6cccc7c8cccc9cccc(c(c5)c67)c98)ccc2B4c2cc(-c4ccccc4)ccc2N3c2c(-c3ccccc3)cccc2-c2ccccc2)cc1]

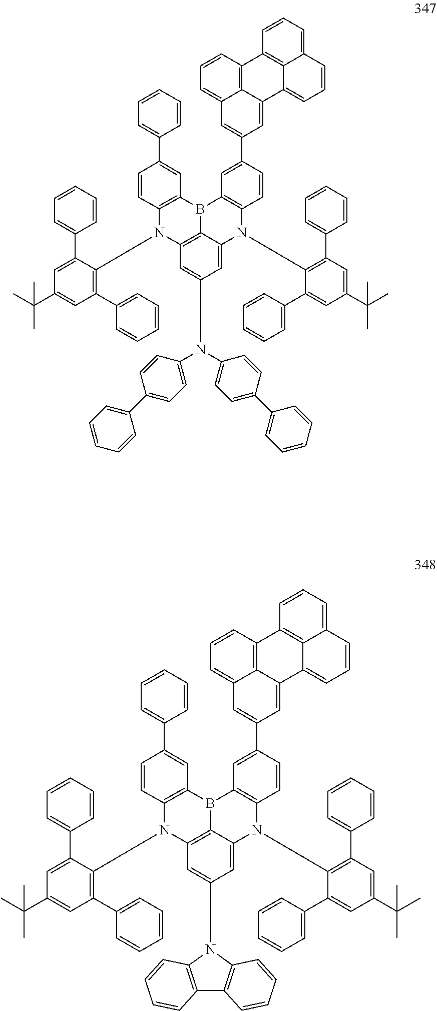

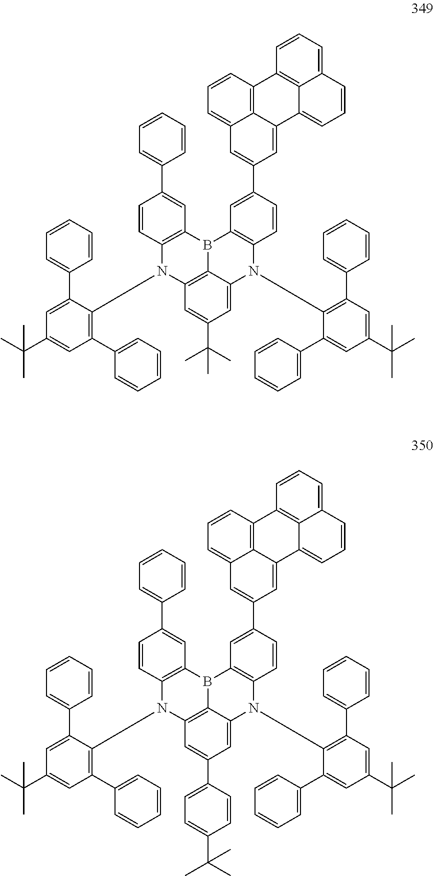

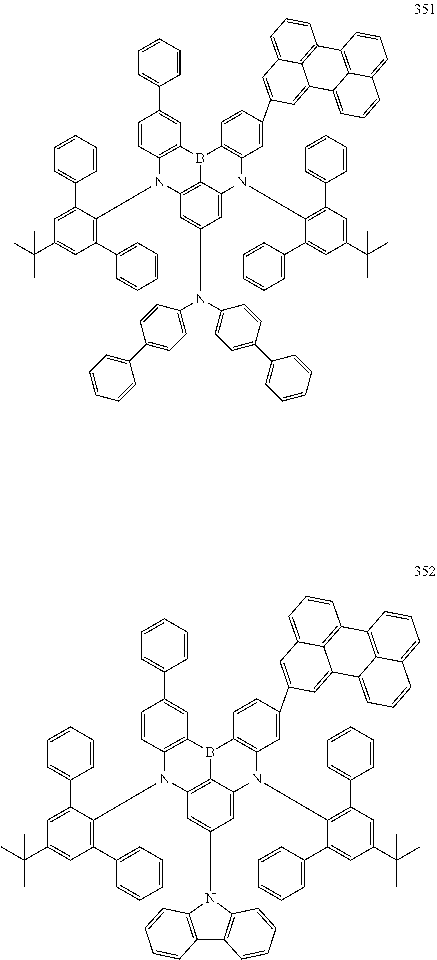

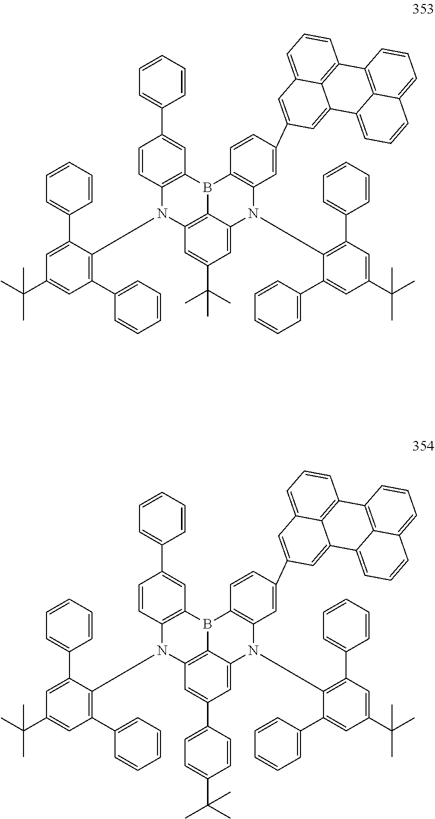 [SMILES: CC(C)(C)c1cc(-c2ccccc2)c(N2c3ccc(-c4ccccc4)cc3B3c4ccc(-c5cc6cccc7c8cccc9cccc(c(c5)c67)c98)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(-c2cc3c4c(c2)N(c2c(-c5ccccc5)cc(C(C)(C)C)cc2-c2ccccc2)c2cc(-c5cc6cccc7c8cccc9cccc(c(c5)c67)c98)ccc2B4c2cc(-c4ccccc4)ccc2N3c2c(-c3ccccc3)cc(C(C)(C)C)cc2-c2ccccc2)cc1]

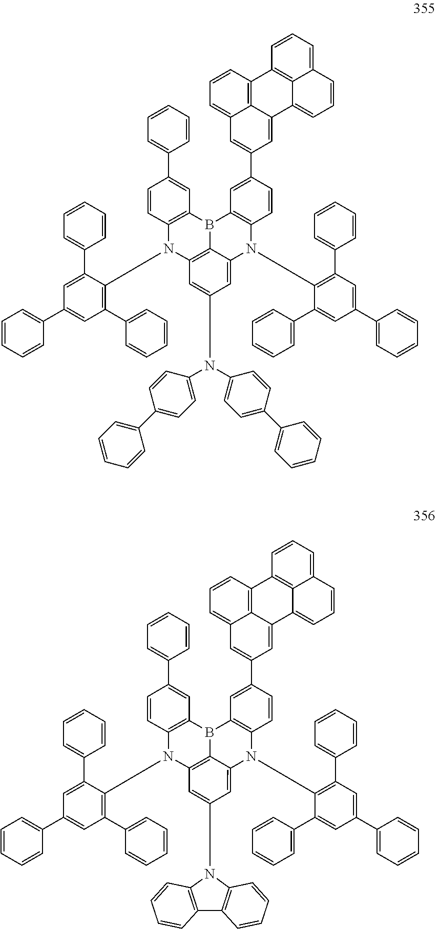 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6cc7cccc8c9cccc%10cccc(c(c6)c78)c%109)cc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4cc(-c5cc6cccc7c8cccc9cccc(c(c5)c67)c98)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1]

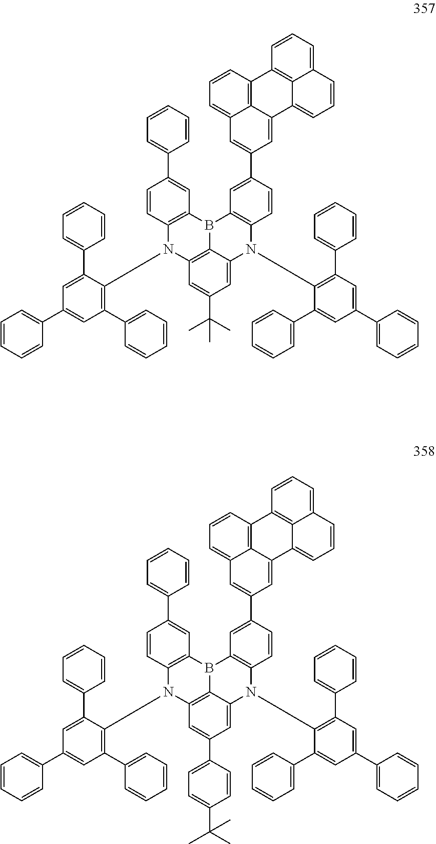 [SMILES: CC(C)(C)c1cc2c3c(c1)N(c1c(-c4ccccc4)cc(-c4ccccc4)cc1-c1ccccc1)c1ccc(-c4cc5cccc6c7cccc8cccc(c(c4)c56)c87)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5cc6cccc7c8cccc9cccc(c(c5)c67)c98)cc2B4c2cc(-c4ccccc4)ccc2N3c2c(-c3ccccc3)cc(-c3ccccc3)cc2-c2ccccc2)cc1]

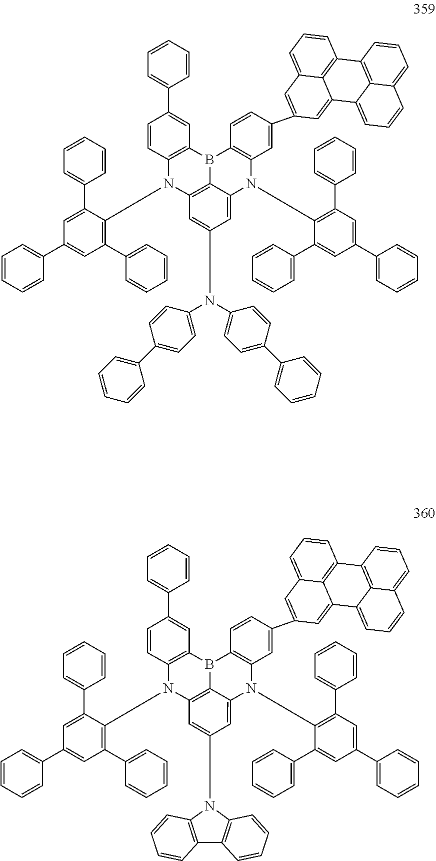 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-c6cc7cccc8c9cccc%10cccc(c(c6)c78)c%109)ccc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4ccc(-c5cc6cccc7c8cccc9cccc(c(c5)c67)c98)cc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1]

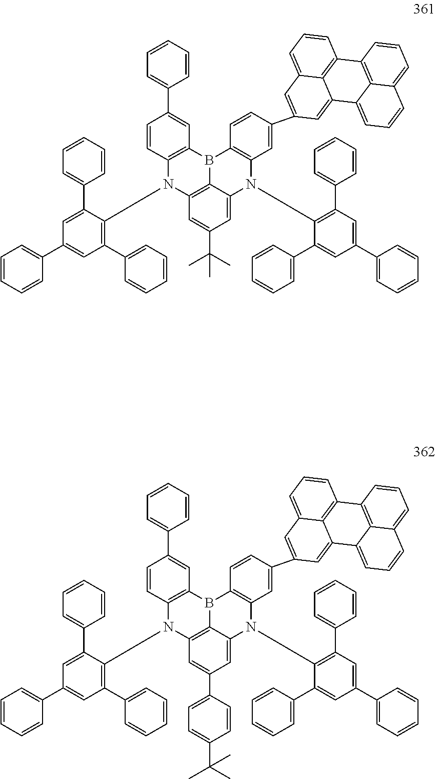 [SMILES: CC(C)(C)c1cc2c3c(c1)N(c1c(-c4ccccc4)cc(-c4ccccc4)cc1-c1ccccc1)c1cc(-c4cc5cccc6c7cccc8cccc(c(c4)c56)c87)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5cc6cccc7c8cccc9cccc(c(c5)c67)c98)ccc2B4c2cc(-c4ccccc4)ccc2N3c2c(-c3ccccc3)cc(-c3ccccc3)cc2-c2ccccc2)cc1]

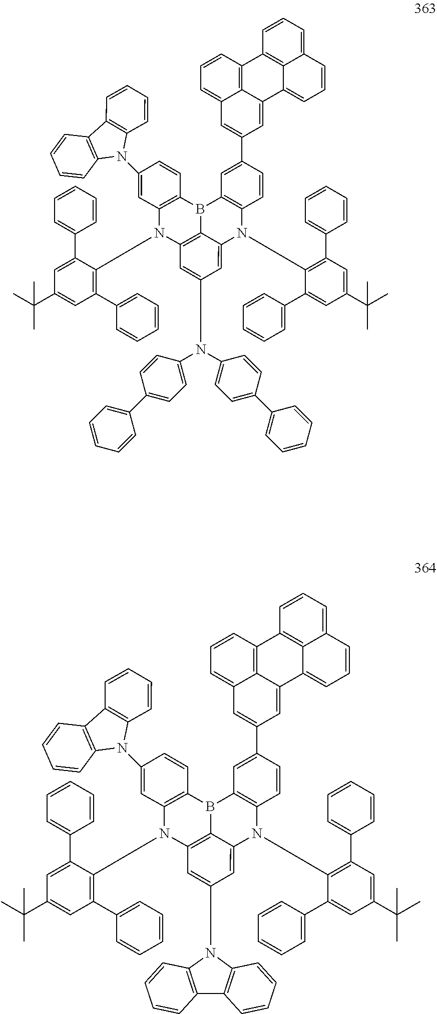

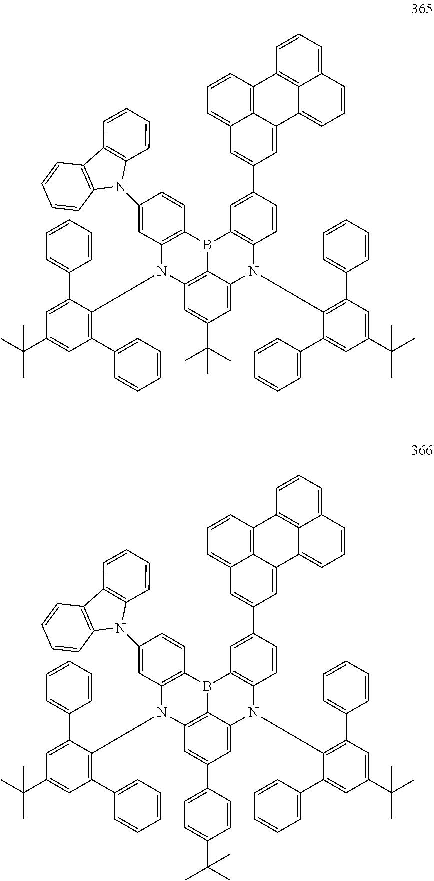

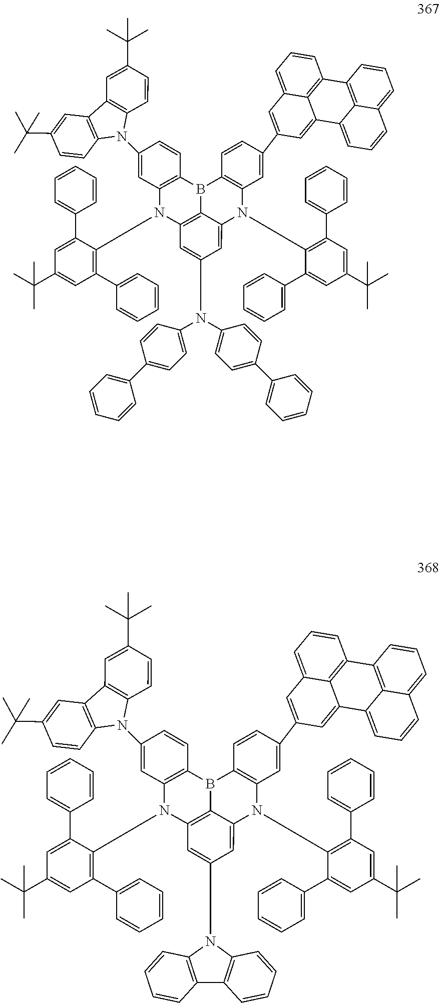 [SMILES: CC(C)(C)c1cc(-c2ccccc2)c(N2c3cc(-c4cc5cccc6c7cccc8cccc(c(c4)c56)c87)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(N(c5ccc(-c6ccccc6)cc5)c5ccc(-c6ccccc6)cc5)cc2c43)c(-c2ccccc2)c1 ; CC(C)(C)c1cc(-c2ccccc2)c(N2c3cc(-c4cc5cccc6c7cccc8cccc(c(c4)c56)c87)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-n5c6ccccc6c6ccccc65)cc2c43)c(-c2ccccc2)c1]

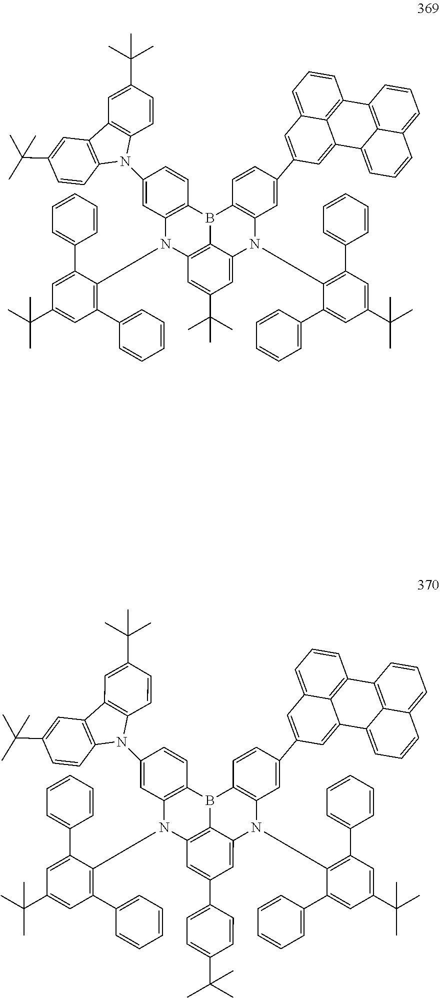 [SMILES: CC(C)(C)c1cc(-c2ccccc2)c(N2c3cc(-c4cc5cccc6c7cccc8cccc(c(c4)c56)c87)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(-c2cc3c4c(c2)N(c2c(-c5ccccc5)cc(C(C)(C)C)cc2-c2ccccc2)c2cc(-n5c6ccc(C(C)(C)C)cc6c6cc(C(C)(C)C)ccc65)ccc2B4c2ccc(-c4cc5cccc6c7cccc8cccc(c(c4)c56)c87)cc2N3c2c(-c3ccccc3)cc(C(C)(C)C)cc2-c2ccccc2)cc1]

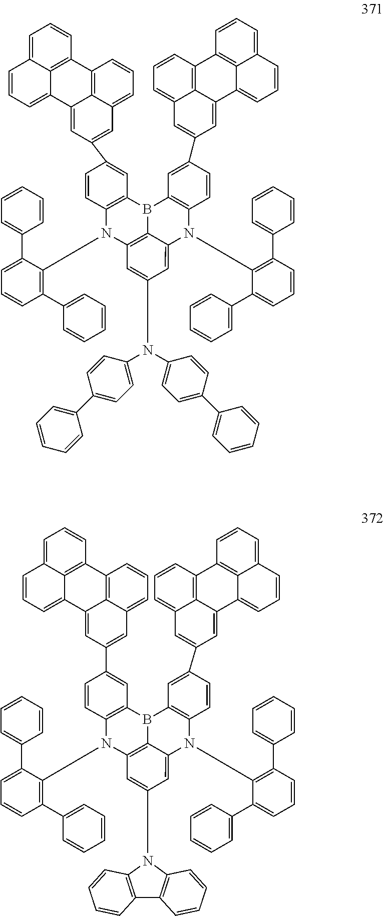 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6cc7cccc8c9cccc%10cccc(c(c6)c78)c%109)cc3B5c3cc(-c5cc6cccc7c8cccc9cccc(c(c5)c67)c98)ccc3N4c3c(-c4ccccc4)cccc3-c3ccccc3)cc2)cc1 ; c1ccc(-c2cccc(-c3ccccc3)c2N2c3ccc(-c4cc5cccc6c7cccc8cccc(c(c4)c56)c87)cc3B3c4cc(-c5cc6cccc7c8cccc9cccc(c(c5)c67)c98)ccc4N(c4c(-c5ccccc5)cccc4-c4ccccc4)c4cc(-n5c6ccccc6c6ccccc65)cc2c43)cc1]

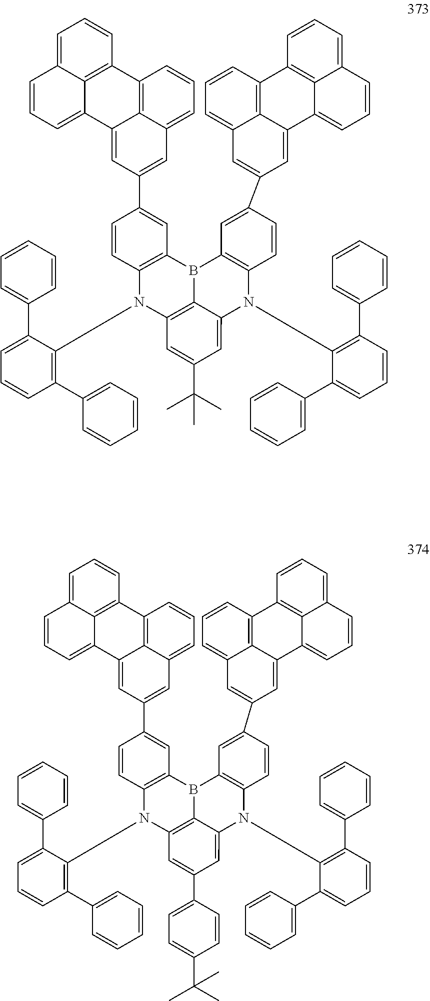 [SMILES: CC(C)(C)c1cc2c3c(c1)N(c1c(-c4ccccc4)cccc1-c1ccccc1)c1ccc(-c4cc5cccc6c7cccc8cccc(c(c4)c56)c87)cc1B3c1cc(-c3cc4cccc5c6cccc7cccc(c(c3)c45)c76)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6cccc7c8cccc9cccc(c(c5)c67)c98)cc2B4c2cc(-c4cc5cccc6c7cccc8cccc(c(c4)c56)c87)ccc2N3c2c(-c3ccccc3)cccc2-c2ccccc2)cc1]

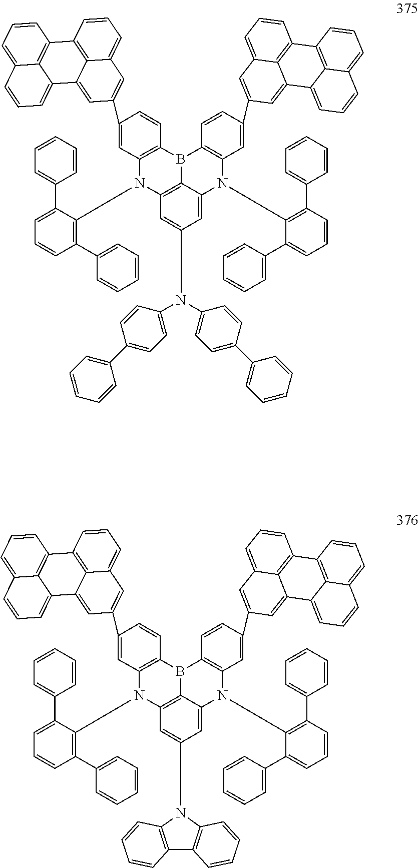 [SMILES: c1ccc(-c2ccc(N(c3ccc(-c4ccccc4)cc3)c3cc4c5c(c3)N(c3c(-c6ccccc6)cccc3-c3ccccc3)c3cc(-c6cc7cccc8c9cccc%10cccc(c(c6)c78)c%109)ccc3B5c3ccc(-c5cc6cccc7c8cccc9cccc(c(c5)c67)c98)cc3N4c3c(-c4ccccc4)cccc3-c3ccccc3)cc2)cc1 ; c1ccc(-c2cccc(-c3ccccc3)c2N2c3cc(-c4cc5cccc6c7cccc8cccc(c(c4)c56)c87)ccc3B3c4ccc(-c5cc6cccc7c8cccc9cccc(c(c5)c67)c98)cc4N(c4c(-c5ccccc5)cccc4-c4ccccc4)c4cc(-n5c6ccccc6c6ccccc65)cc2c43)cc1]

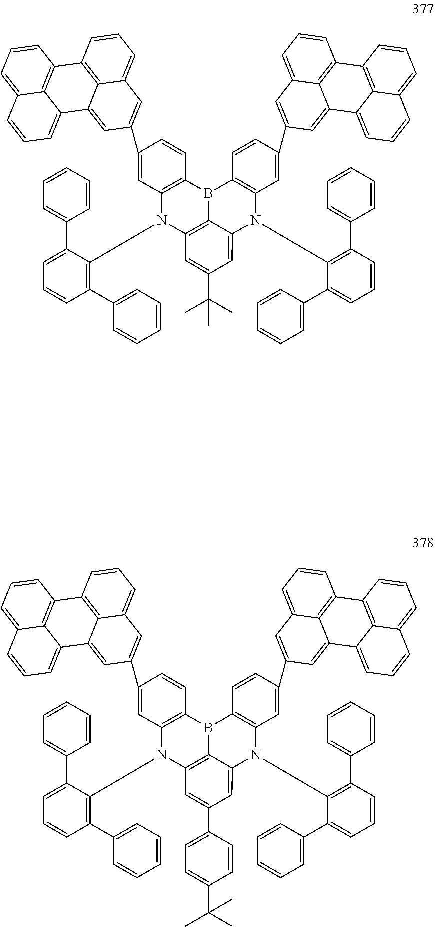 [SMILES: CC(C)(C)c1cc2c3c(c1)N(c1c(-c4ccccc4)cccc1-c1ccccc1)c1cc(-c4cc5cccc6c7cccc8cccc(c(c4)c56)c87)ccc1B3c1ccc(-c3cc4cccc5c6cccc7cccc(c(c3)c45)c76)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5cc6cccc7c8cccc9cccc(c(c5)c67)c98)ccc2B4c2ccc(-c4cc5cccc6c7cccc8cccc(c(c4)c56)c87)cc2N3c2c(-c3ccccc3)cccc2-c2ccccc2)cc1]

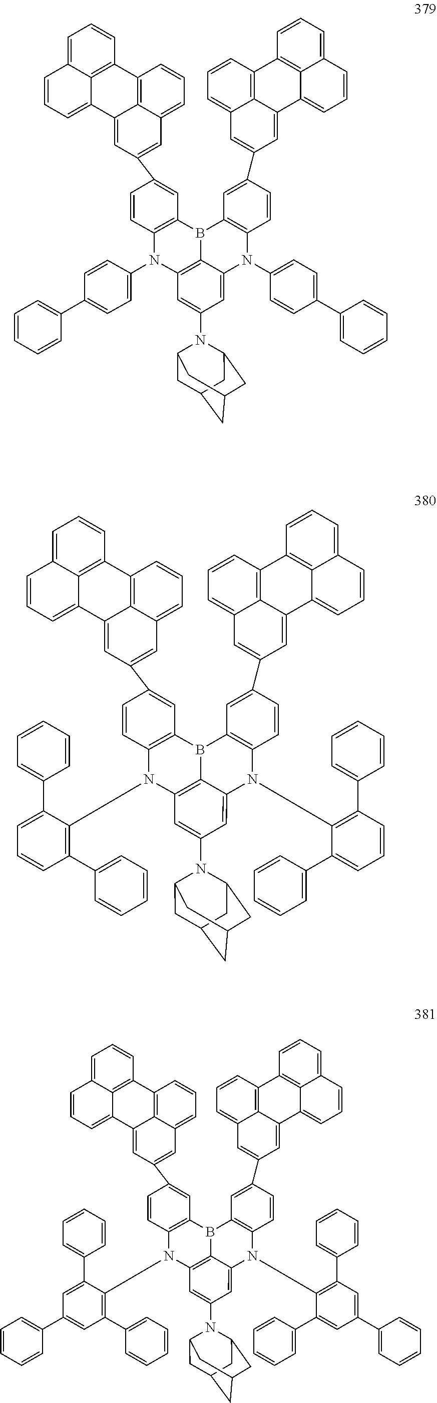

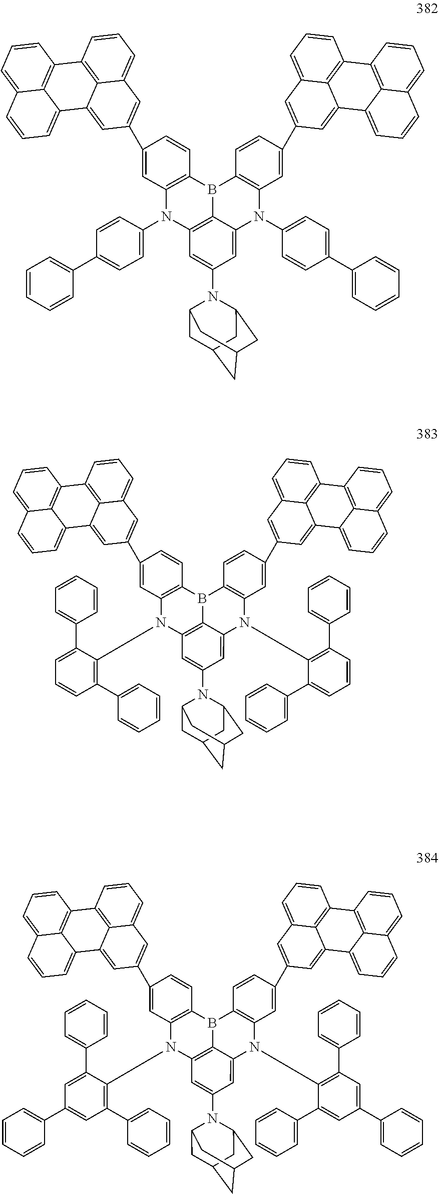

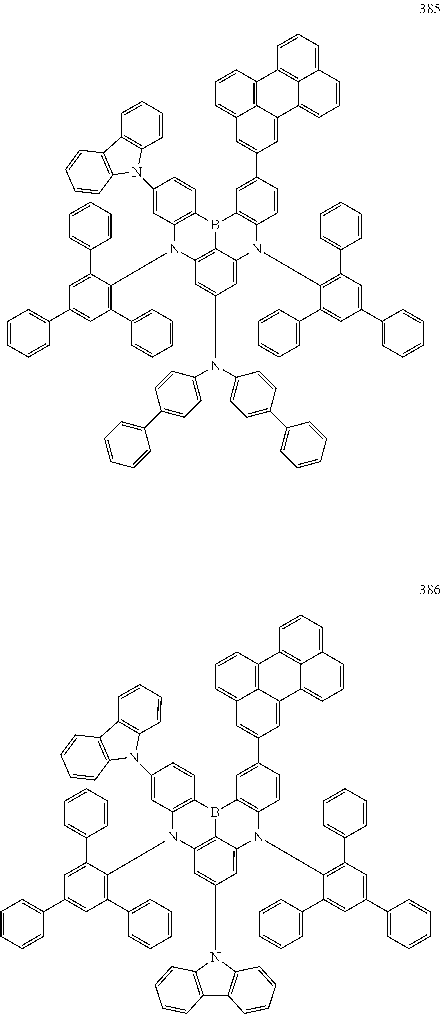 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3cc(-c5cc6cccc7c8cccc9cccc(c(c5)c67)c98)ccc3N4c3c(-c4ccccc4)cc(-c4ccccc4)cc3-c3ccccc3)cc2)cc1 ; c1ccc(-c2cc(-c3ccccc3)c(N3c4ccc(-c5cc6cccc7c8cccc9cccc(c(c5)c67)c98)cc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

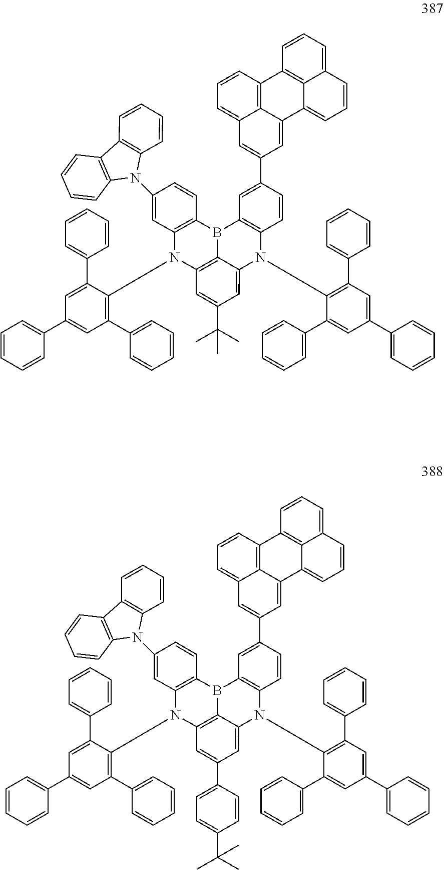 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1cc(-c3cc4cccc5c6cccc7cccc(c(c3)c45)c76)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4cc5cccc6c7cccc8cccc(c(c4)c56)c87)ccc2N3c2c(-c3ccccc3)cc(-c3ccccc3)cc2-c2ccccc2)cc1]

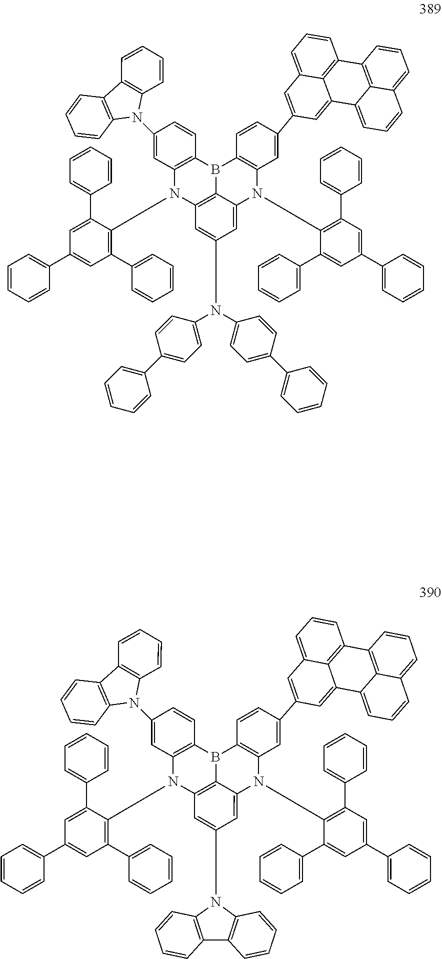 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3ccc(-c5cc6cccc7c8cccc9cccc(c(c5)c67)c98)cc3N4c3c(-c4ccccc4)cc(-c4ccccc4)cc3-c3ccccc3)cc2)cc1 ; c1ccc(-c2cc(-c3ccccc3)c(N3c4cc(-c5cc6cccc7c8cccc9cccc(c(c5)c67)c98)ccc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1]

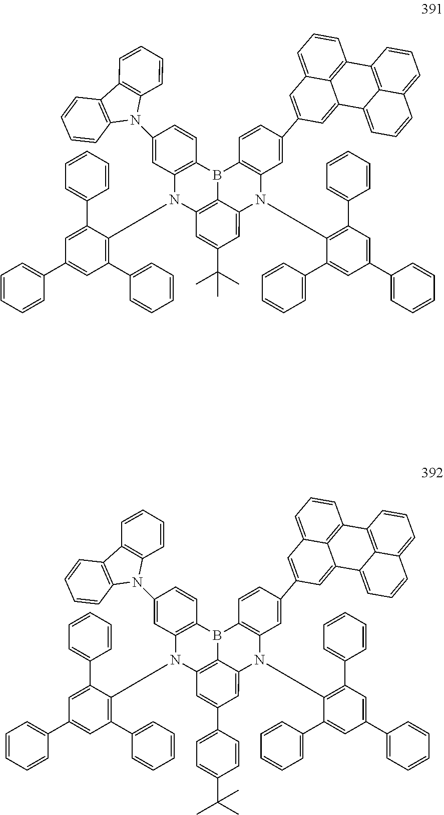 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc(-c3cc4cccc5c6cccc7cccc(c(c3)c45)c76)cc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2ccc(-c4cc5cccc6c7cccc8cccc(c(c4)c56)c87)cc2N3c2c(-c3ccccc3)cc(-c3ccccc3)cc2-c2ccccc2)cc1]

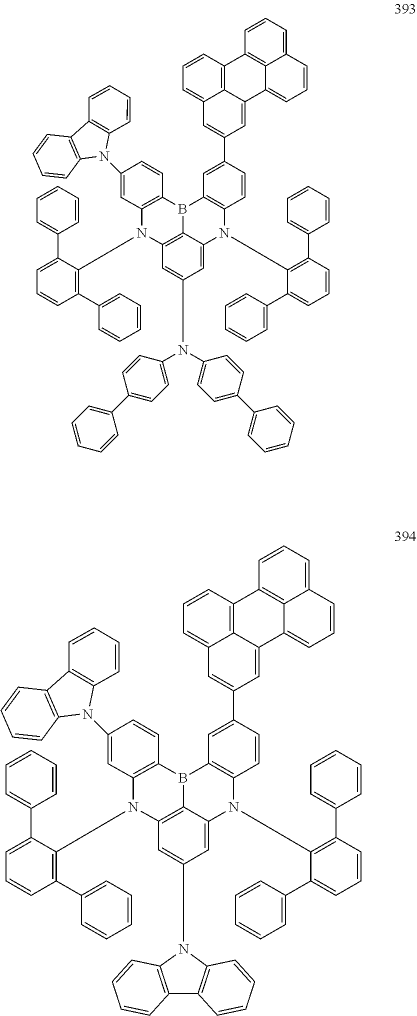 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3cc(-c5cc6cccc7c8cccc9cccc(c(c5)c67)c98)ccc3N4c3c(-c4ccccc4)cccc3-c3ccccc3)cc2)cc1 ; c1ccc(-c2cccc(-c3ccccc3)c2N2c3ccc(-c4cc5cccc6c7cccc8cccc(c(c4)c56)c87)cc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1]

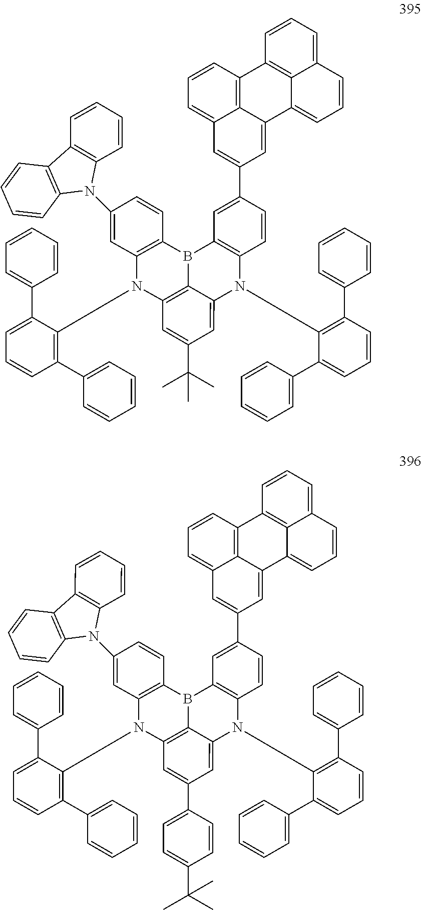 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3cc4cccc5c6cccc7cccc(c(c3)c45)c76)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4cc5cccc6c7cccc8cccc(c(c4)c56)c87)ccc2N3c2c(-c3ccccc3)cccc2-c2ccccc2)cc1]

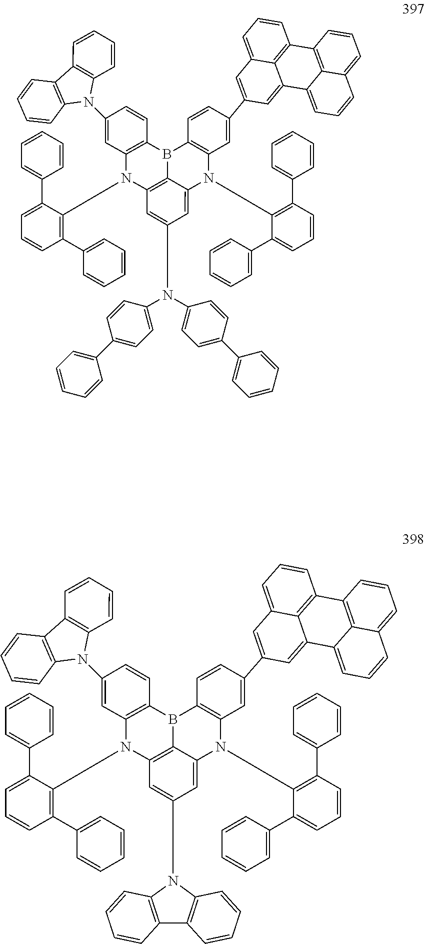 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3ccc(-c5cc6cccc7c8cccc9cccc(c(c5)c67)c98)cc3N4c3c(-c4ccccc4)cccc3-c3ccccc3)cc2)cc1 ; c1ccc(-c2cccc(-c3ccccc3)c2N2c3cc(-c4cc5cccc6c7cccc8cccc(c(c4)c56)c87)ccc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1]

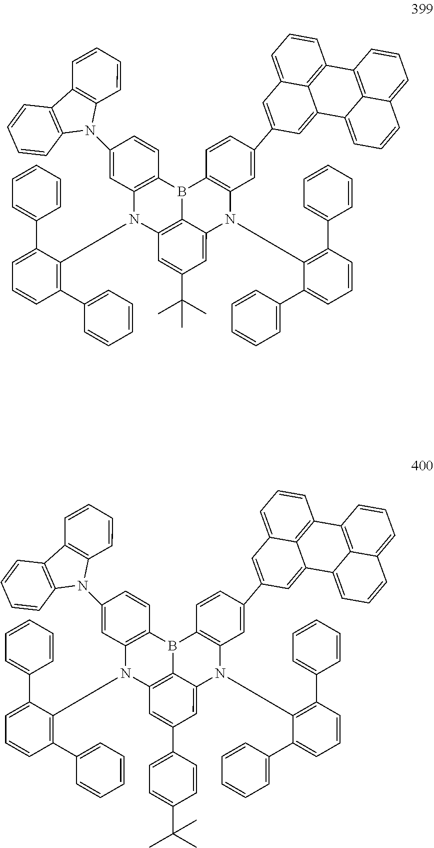 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-c3cc4cccc5c6cccc7cccc(c(c3)c45)c76)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4cc5cccc6c7cccc8cccc(c(c4)c56)c87)cc2N3c2c(-c3ccccc3)cccc2-c2ccccc2)cc1]

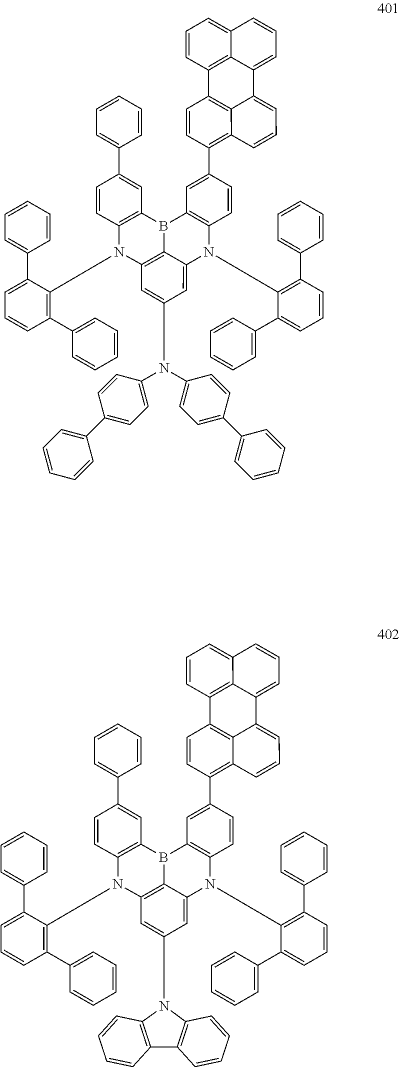 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7c8cccc9cccc(c%10cccc6c%107)c98)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5ccc6c7cccc8cccc(c9cccc5c96)c87)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1]

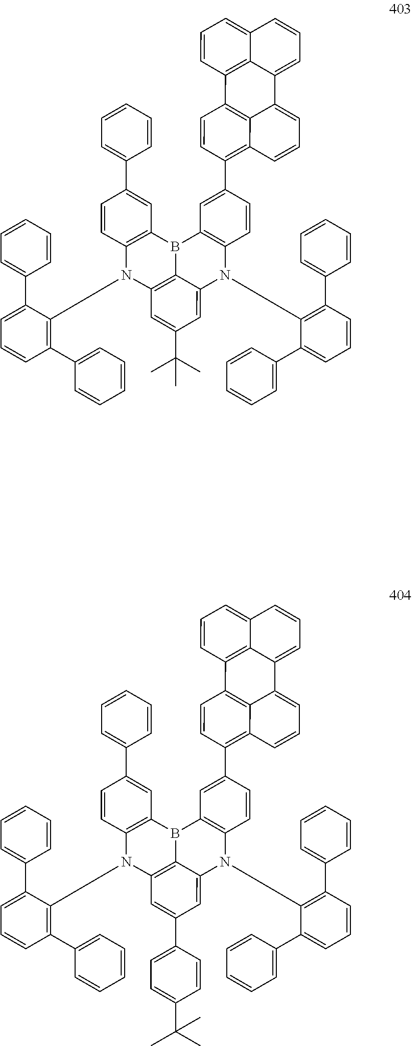 [SMILES: CC(C)(C)c1cc2c3c(c1)N(c1c(-c4ccccc4)cccc1-c1ccccc1)c1ccc(-c4ccc5c6cccc7cccc(c8cccc4c85)c76)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6c7cccc8cccc(c9cccc5c96)c87)cc2B4c2cc(-c4ccccc4)ccc2N3c2c(-c3ccccc3)cccc2-c2ccccc2)cc1]

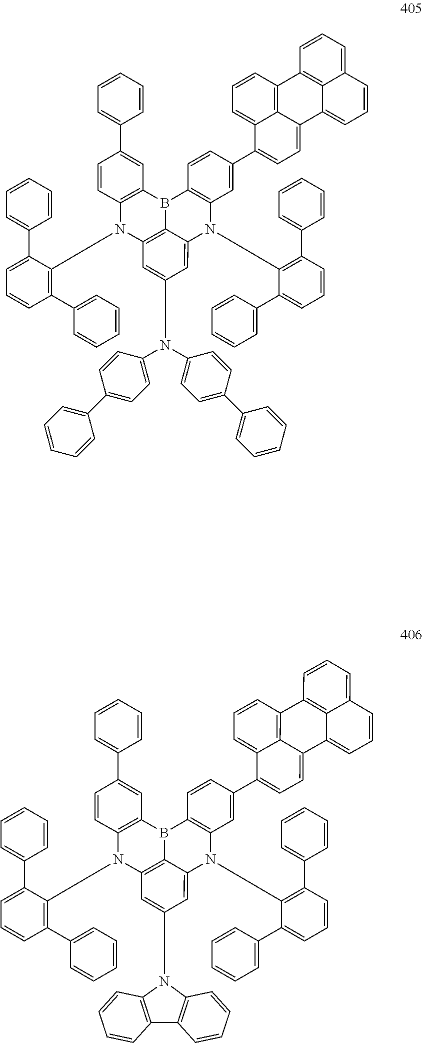 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7c8cccc9cccc(c%10cccc6c%107)c98)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5ccc6c7cccc8cccc(c9cccc5c96)c87)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1]

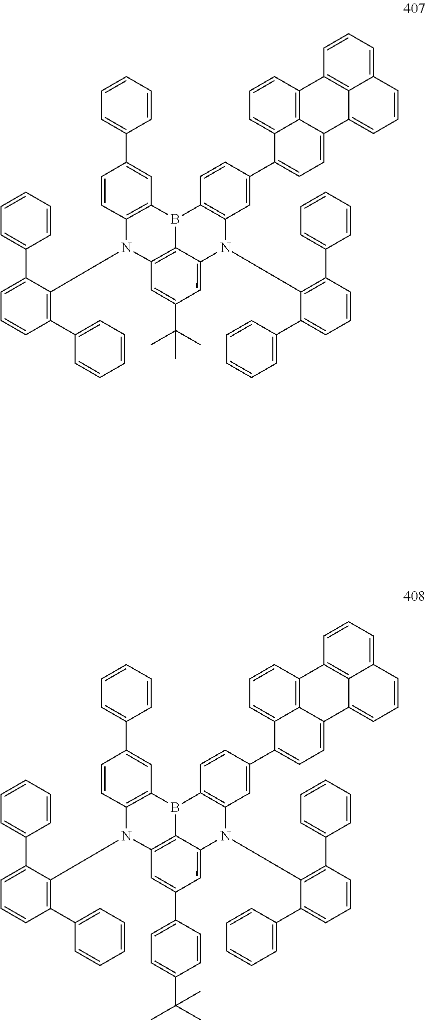 [SMILES: CC(C)(C)c1cc2c3c(c1)N(c1c(-c4ccccc4)cccc1-c1ccccc1)c1cc(-c4ccc5c6cccc7cccc(c8cccc4c85)c76)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6c7cccc8cccc(c9cccc5c96)c87)ccc2B4c2cc(-c4ccccc4)ccc2N3c2c(-c3ccccc3)cccc2-c2ccccc2)cc1]

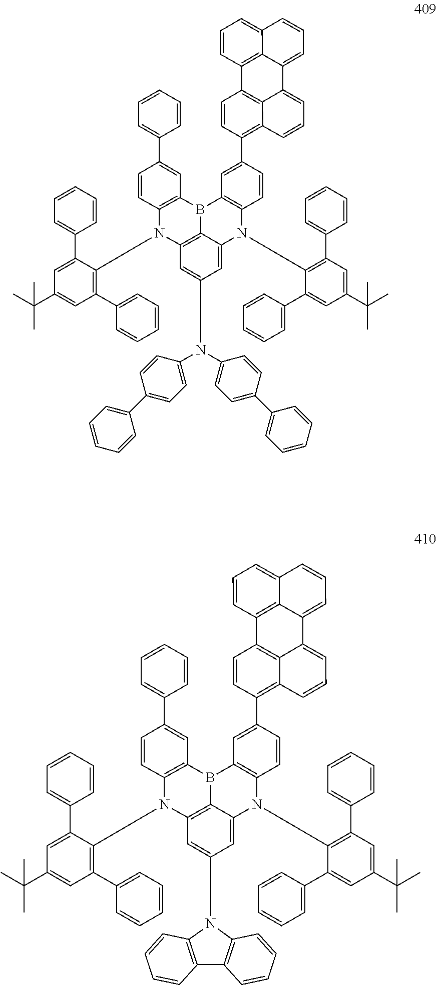

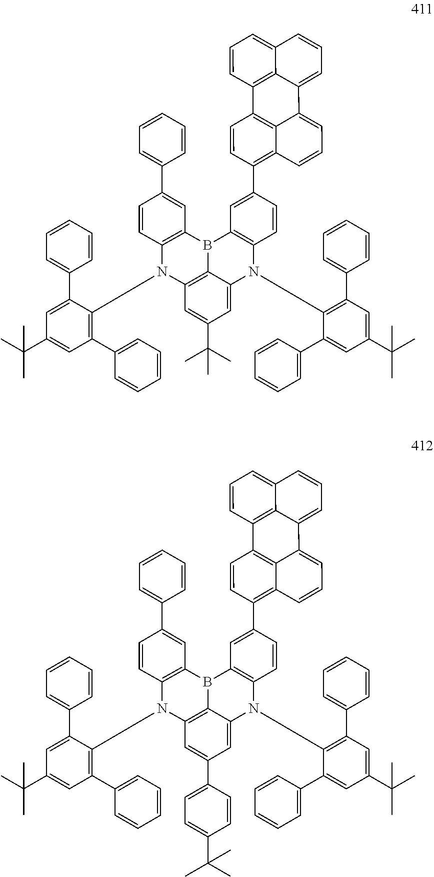

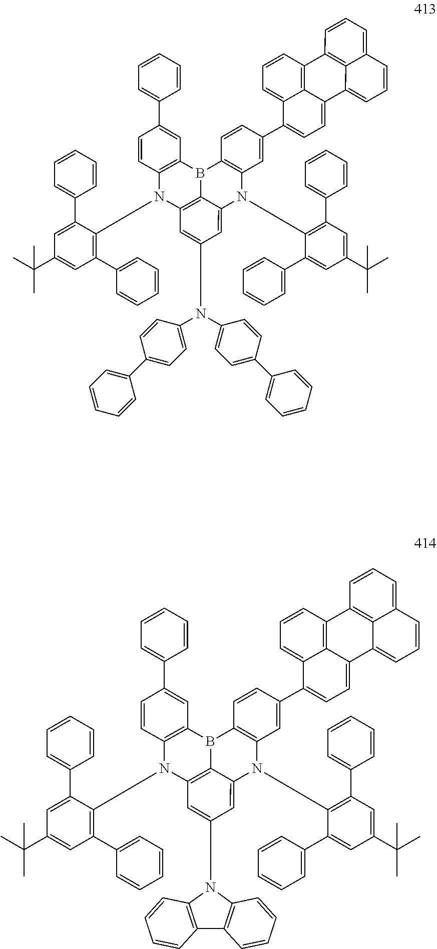

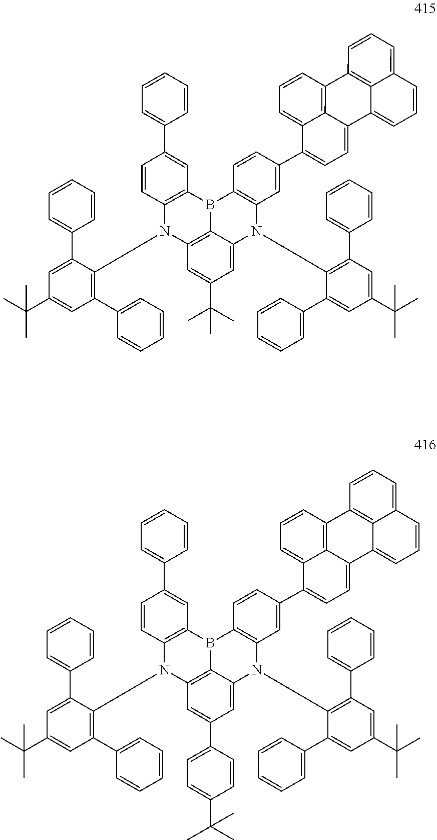

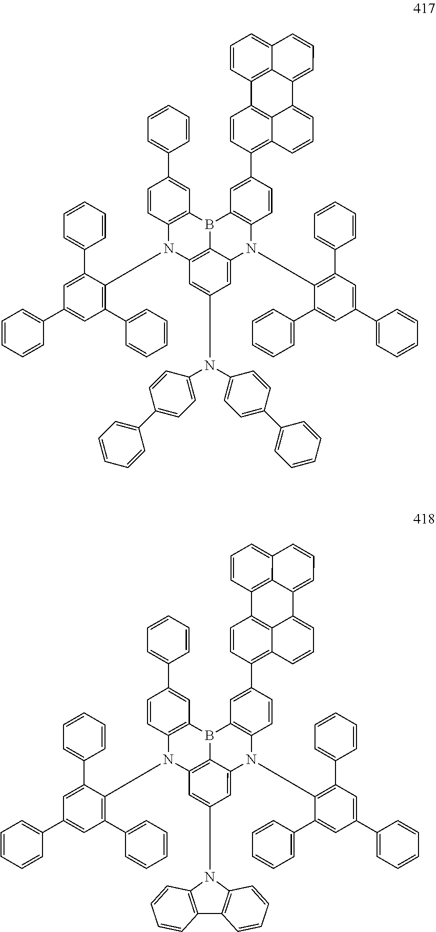 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccc7c8cccc9cccc(c%10cccc6c%107)c98)cc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4cc(-c5ccc6c7cccc8cccc(c9cccc5c96)c87)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1]

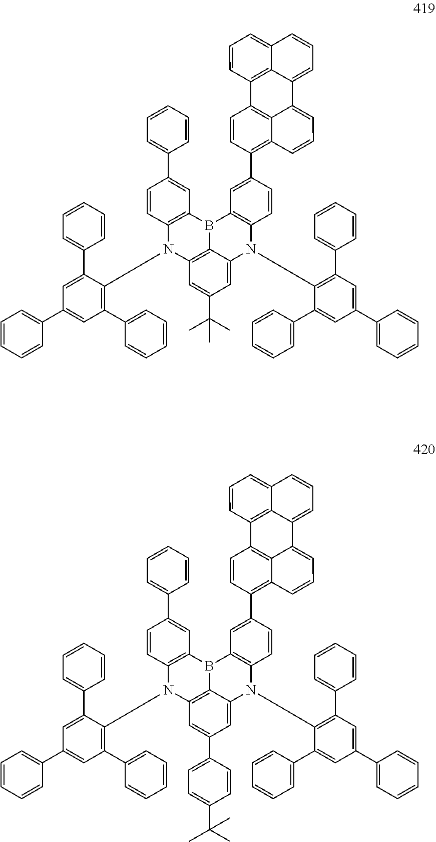 [SMILES: CC(C)(C)c1cc2c3c(c1)N(c1c(-c4ccccc4)cc(-c4ccccc4)cc1-c1ccccc1)c1ccc(-c4ccc5c6cccc7cccc(c8cccc4c85)c76)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5ccc6c7cccc8cccc(c9cccc5c96)c87)cc2B4c2cc(-c4ccccc4)ccc2N3c2c(-c3ccccc3)cc(-c3ccccc3)cc2-c2ccccc2)cc1]

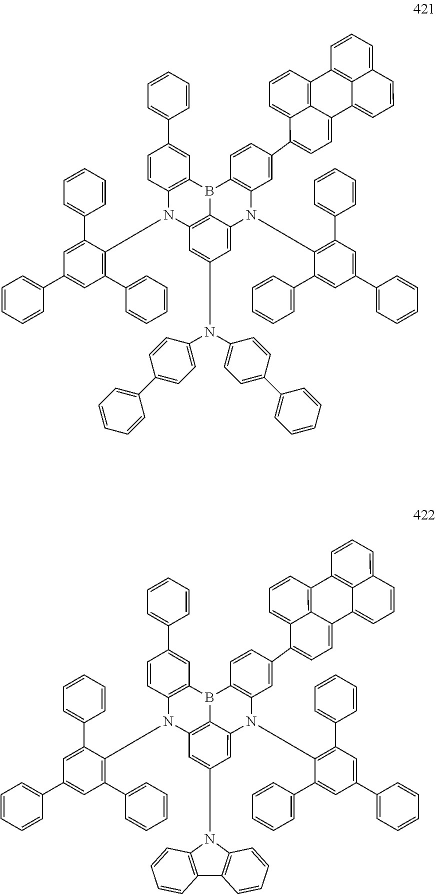 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-c6ccc7c8cccc9cccc(c%10cccc6c%107)c98)ccc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4ccc(-c5ccc6c7cccc8cccc(c9cccc5c96)c87)cc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1]

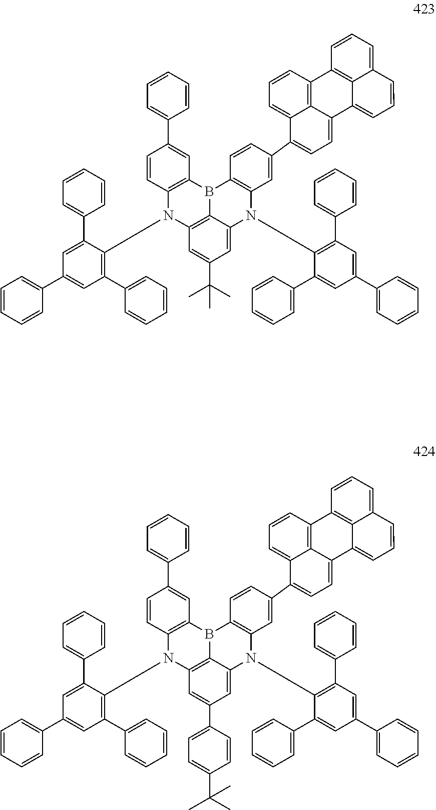 [SMILES: CC(C)(C)c1cc2c3c(c1)N(c1c(-c4ccccc4)cc(-c4ccccc4)cc1-c1ccccc1)c1cc(-c4ccc5c6cccc7cccc(c8cccc4c85)c76)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5ccc6c7cccc8cccc(c9cccc5c96)c87)ccc2B4c2cc(-c4ccccc4)ccc2N3c2c(-c3ccccc3)cc(-c3ccccc3)cc2-c2ccccc2)cc1]

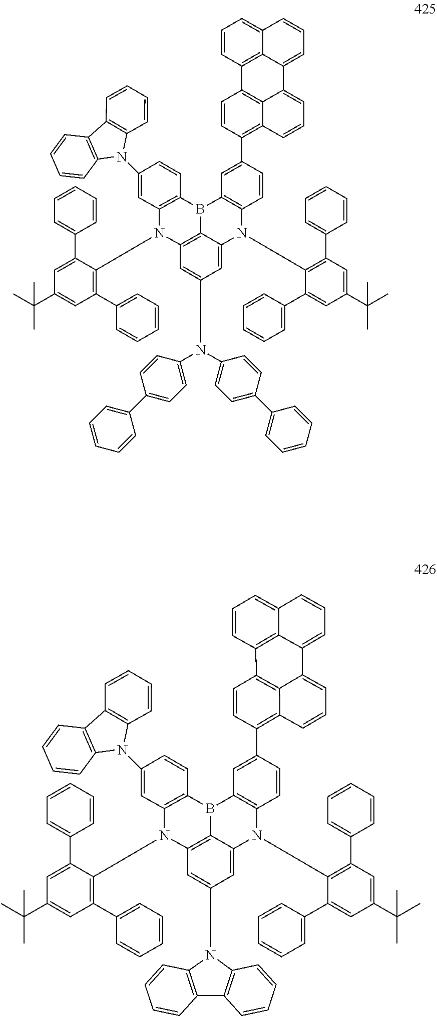

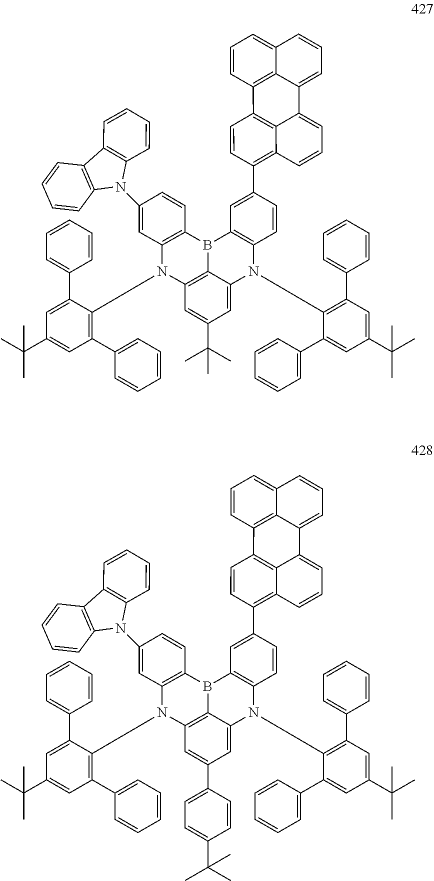

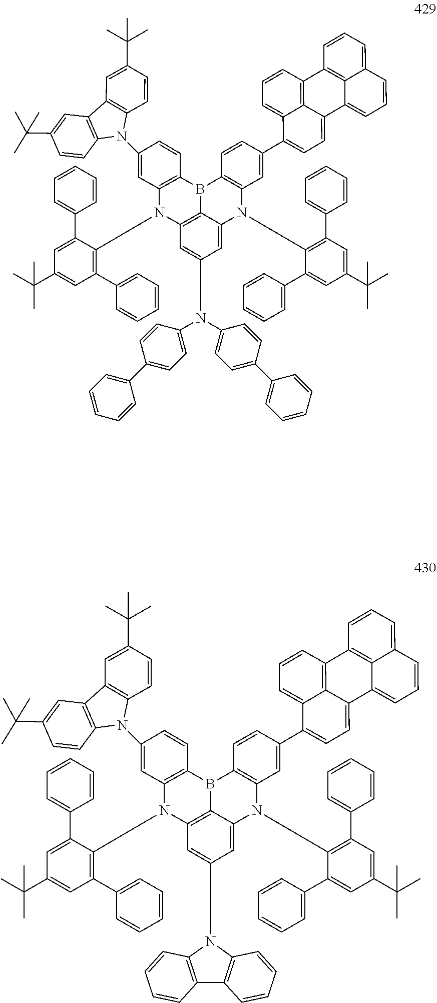

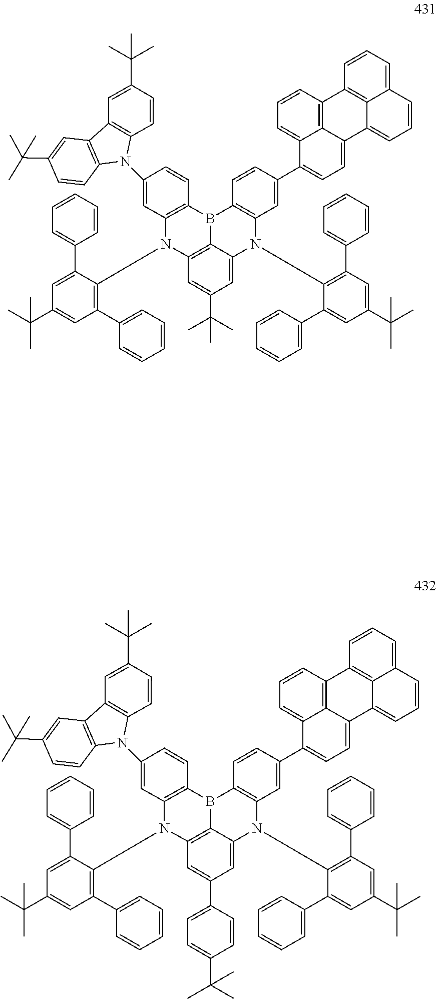

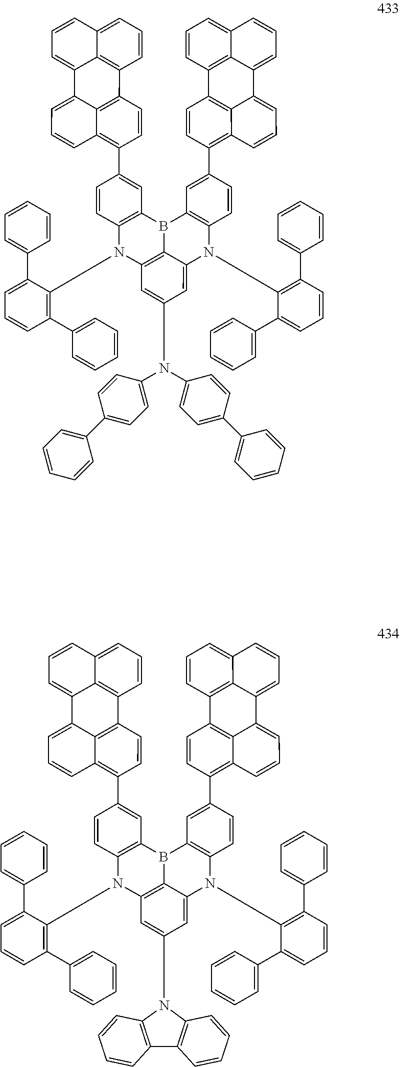 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7c8cccc9cccc(c%10cccc6c%107)c98)cc3B5c3cc(-c5ccc6c7cccc8cccc(c9cccc5c96)c87)ccc3N4c3c(-c4ccccc4)cccc3-c3ccccc3)cc2)cc1 ; c1ccc(-c2cccc(-c3ccccc3)c2N2c3ccc(-c4ccc5c6cccc7cccc(c8cccc4c85)c76)cc3B3c4cc(-c5ccc6c7cccc8cccc(c9cccc5c96)c87)ccc4N(c4c(-c5ccccc5)cccc4-c4ccccc4)c4cc(-n5c6ccccc6c6ccccc65)cc2c43)cc1]

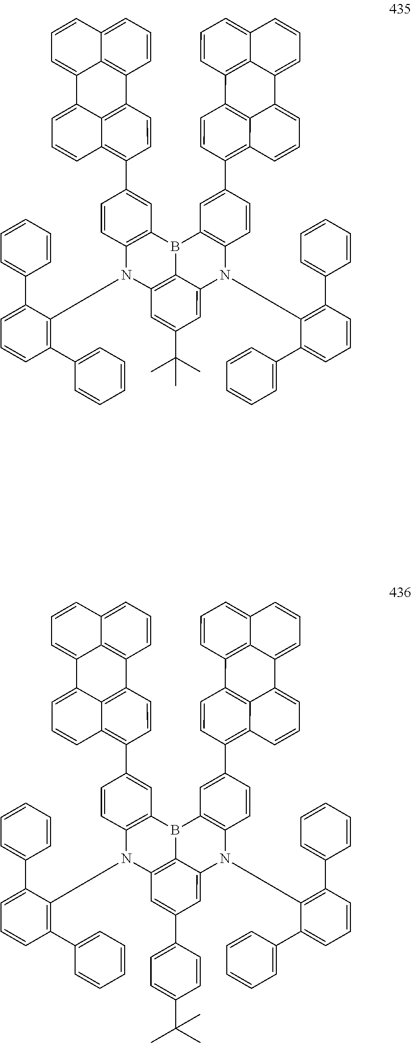 [SMILES: CC(C)(C)c1cc2c3c(c1)N(c1c(-c4ccccc4)cccc1-c1ccccc1)c1ccc(-c4ccc5c6cccc7cccc(c8cccc4c85)c76)cc1B3c1cc(-c3ccc4c5cccc6cccc(c7cccc3c74)c65)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6c7cccc8cccc(c9cccc5c96)c87)cc2B4c2cc(-c4ccc5c6cccc7cccc(c8cccc4c85)c76)ccc2N3c2c(-c3ccccc3)cccc2-c2ccccc2)cc1]

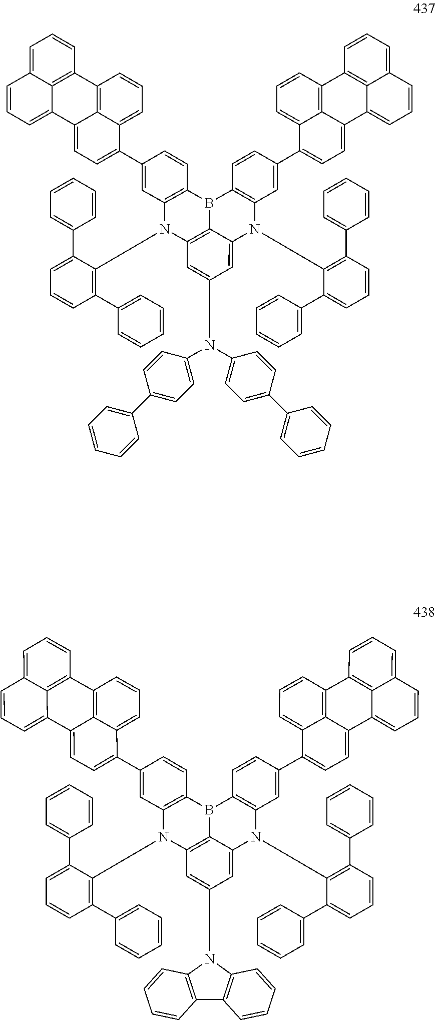 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7c8cccc9cccc(c%10cccc6c%107)c98)ccc3B5c3ccc(-c5ccc6c7cccc8cccc(c9cccc5c96)c87)cc3N4c3c(-c4ccccc4)cccc3-c3ccccc3)cc2)cc1 ; c1ccc(-c2cccc(-c3ccccc3)c2N2c3cc(-c4ccc5c6cccc7cccc(c8cccc4c85)c76)ccc3B3c4ccc(-c5ccc6c7cccc8cccc(c9cccc5c96)c87)cc4N(c4c(-c5ccccc5)cccc4-c4ccccc4)c4cc(-n5c6ccccc6c6ccccc65)cc2c43)cc1]

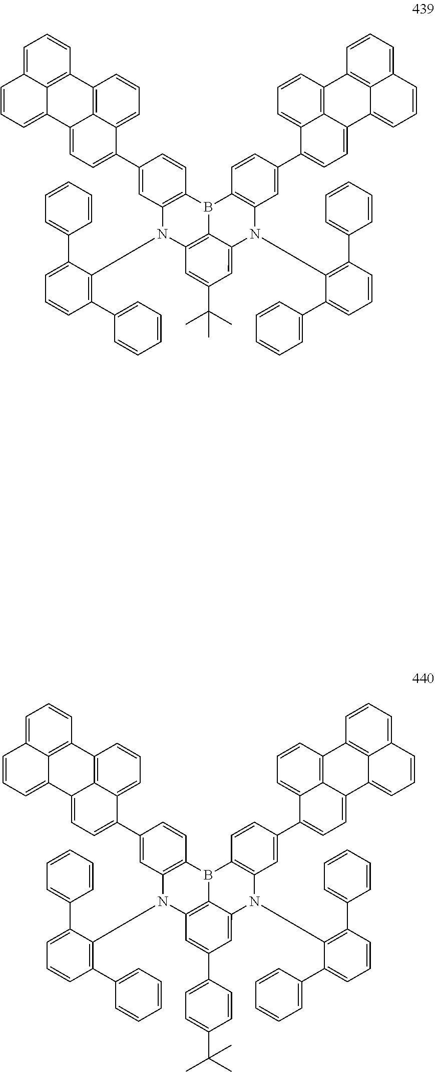 [SMILES: CC(C)(C)c1cc2c3c(c1)N(c1c(-c4ccccc4)cccc1-c1ccccc1)c1cc(-c4ccc5c6cccc7cccc(c8cccc4c85)c76)ccc1B3c1ccc(-c3ccc4c5cccc6cccc(c7cccc3c74)c65)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6c7cccc8cccc(c9cccc5c96)c87)ccc2B4c2ccc(-c4ccc5c6cccc7cccc(c8cccc4c85)c76)cc2N3c2c(-c3ccccc3)cccc2-c2ccccc2)cc1]

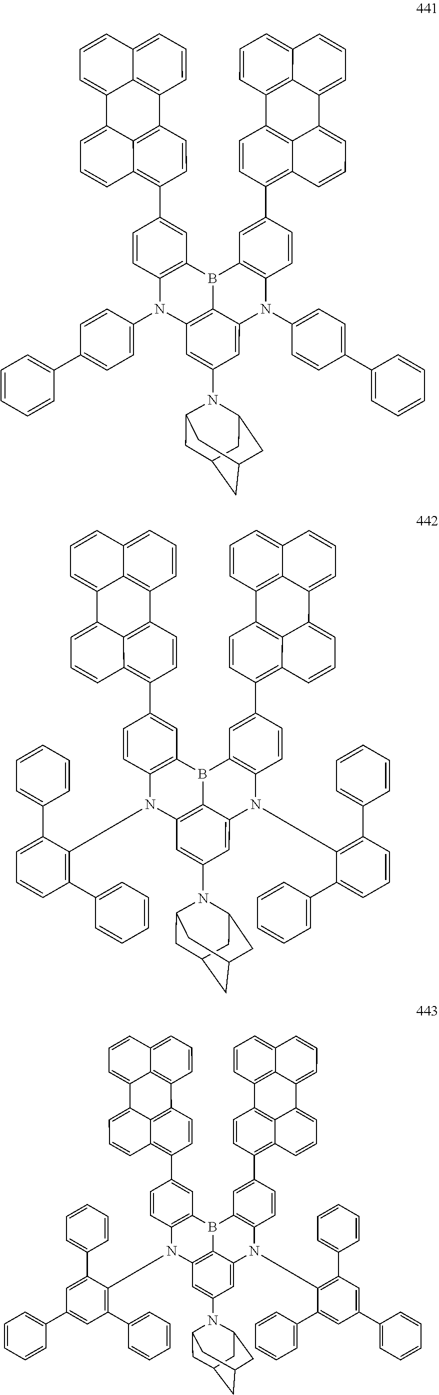

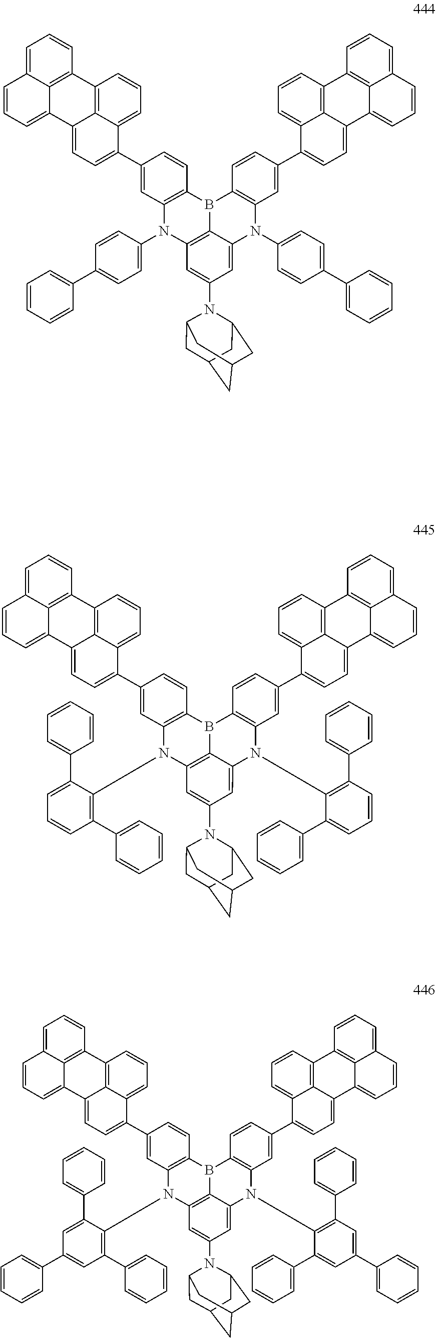

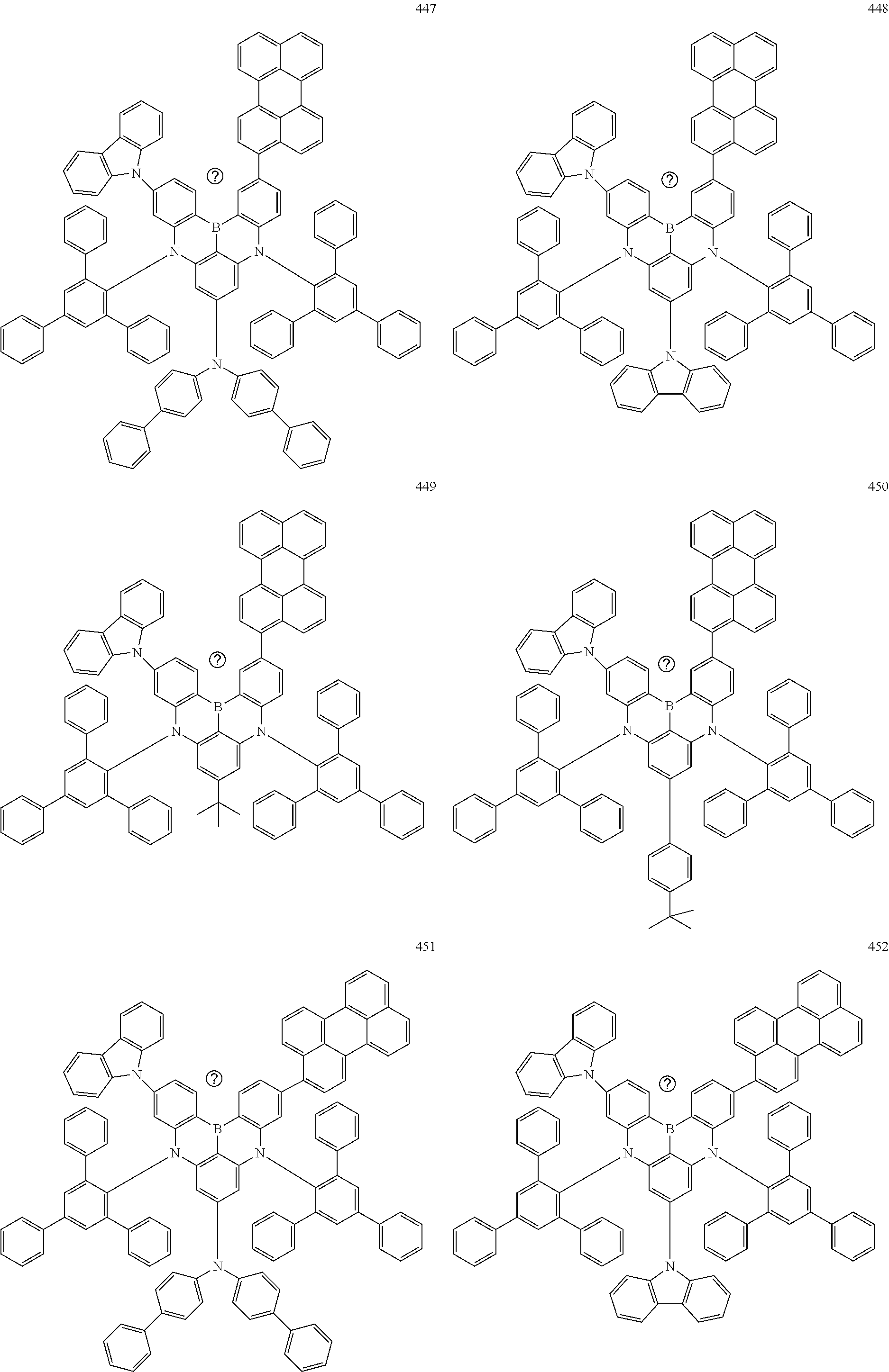

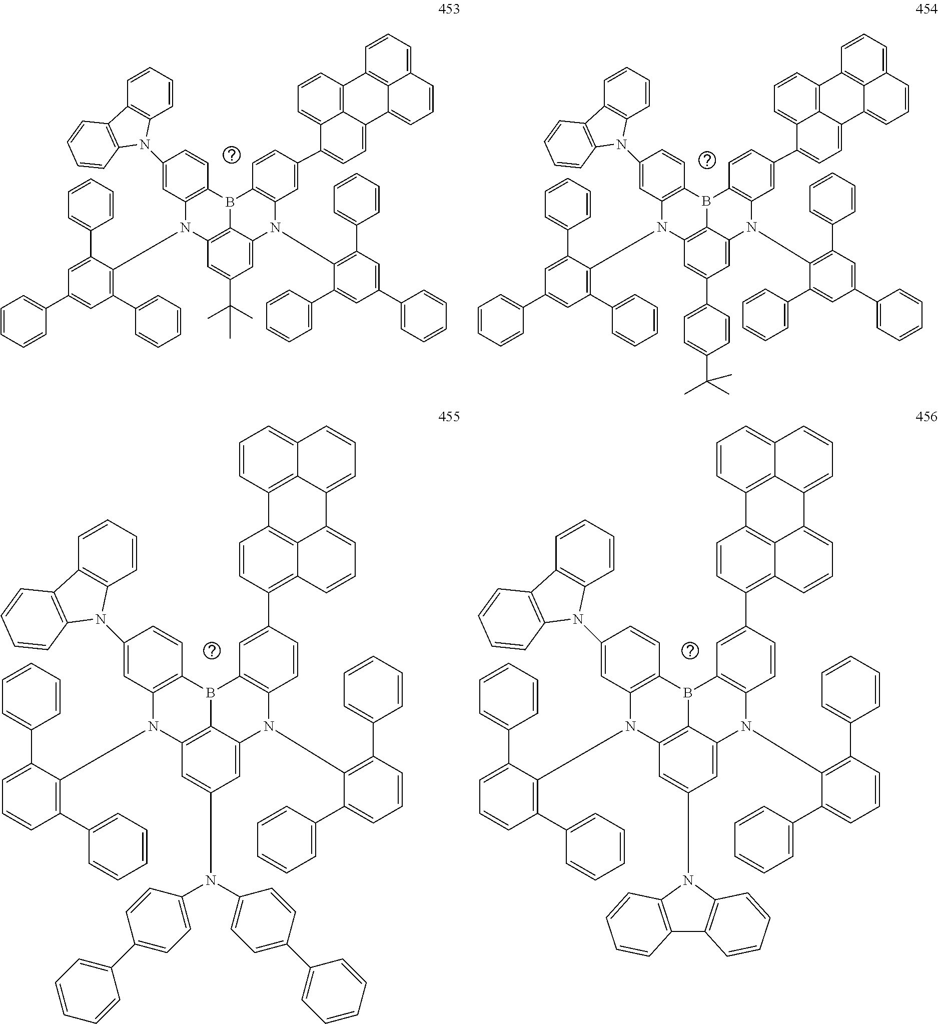

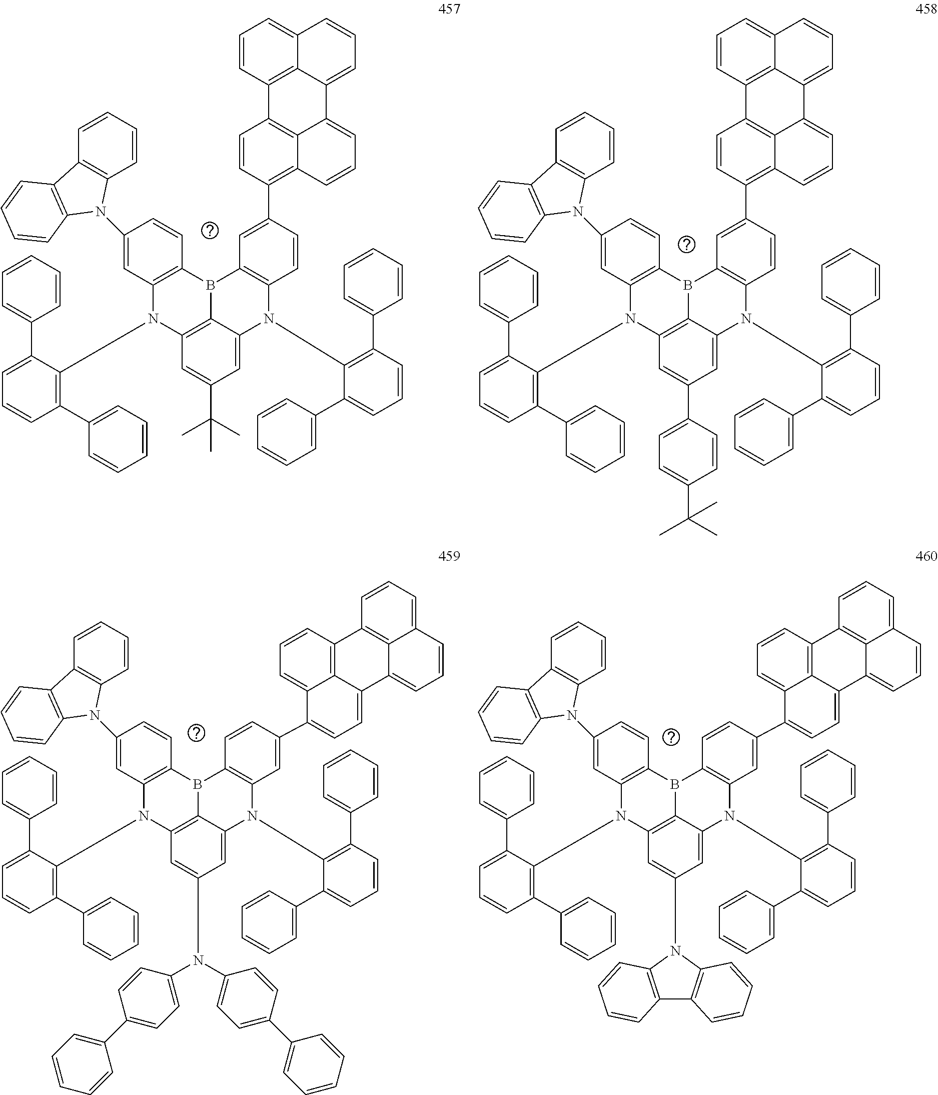

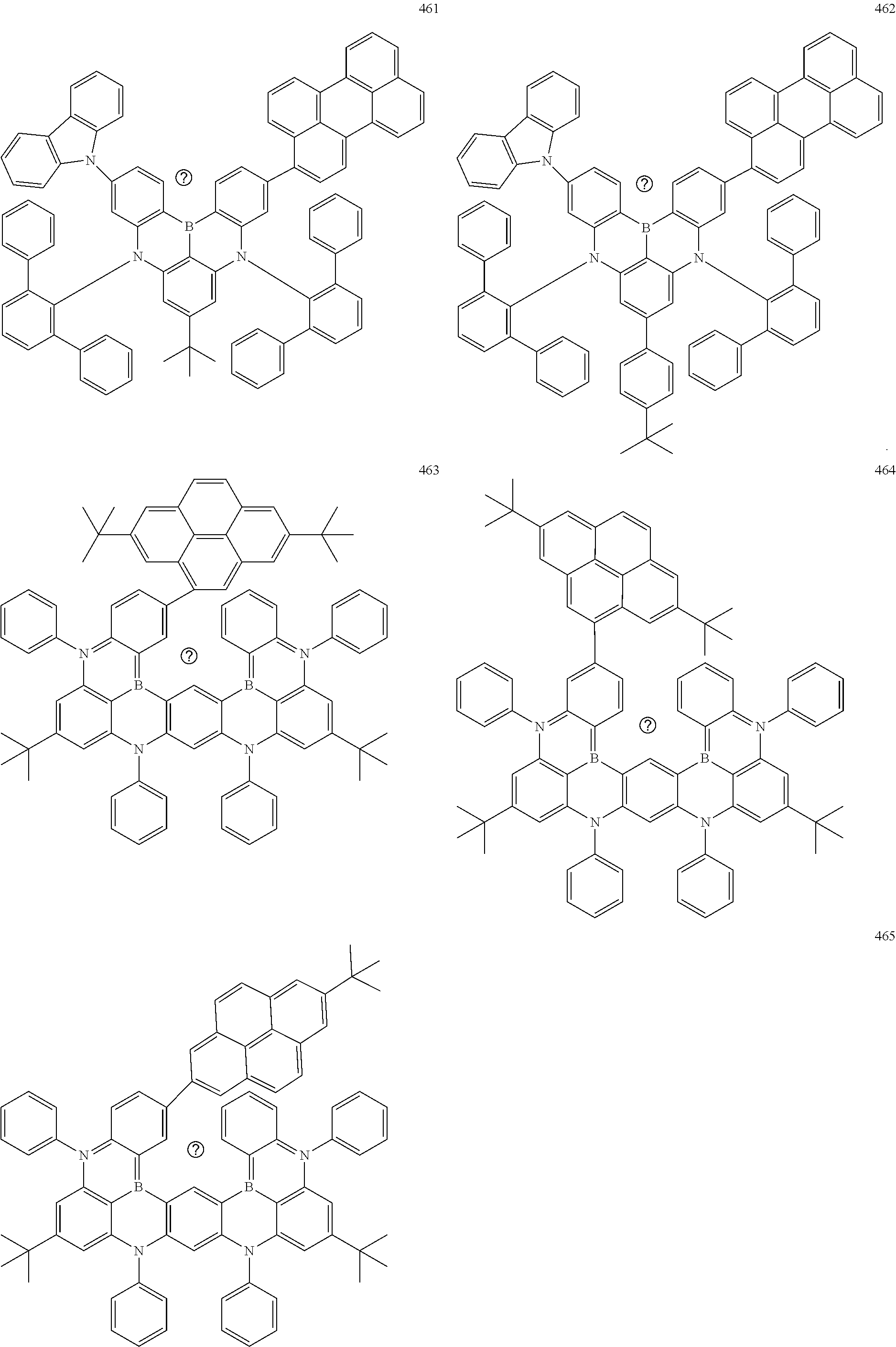

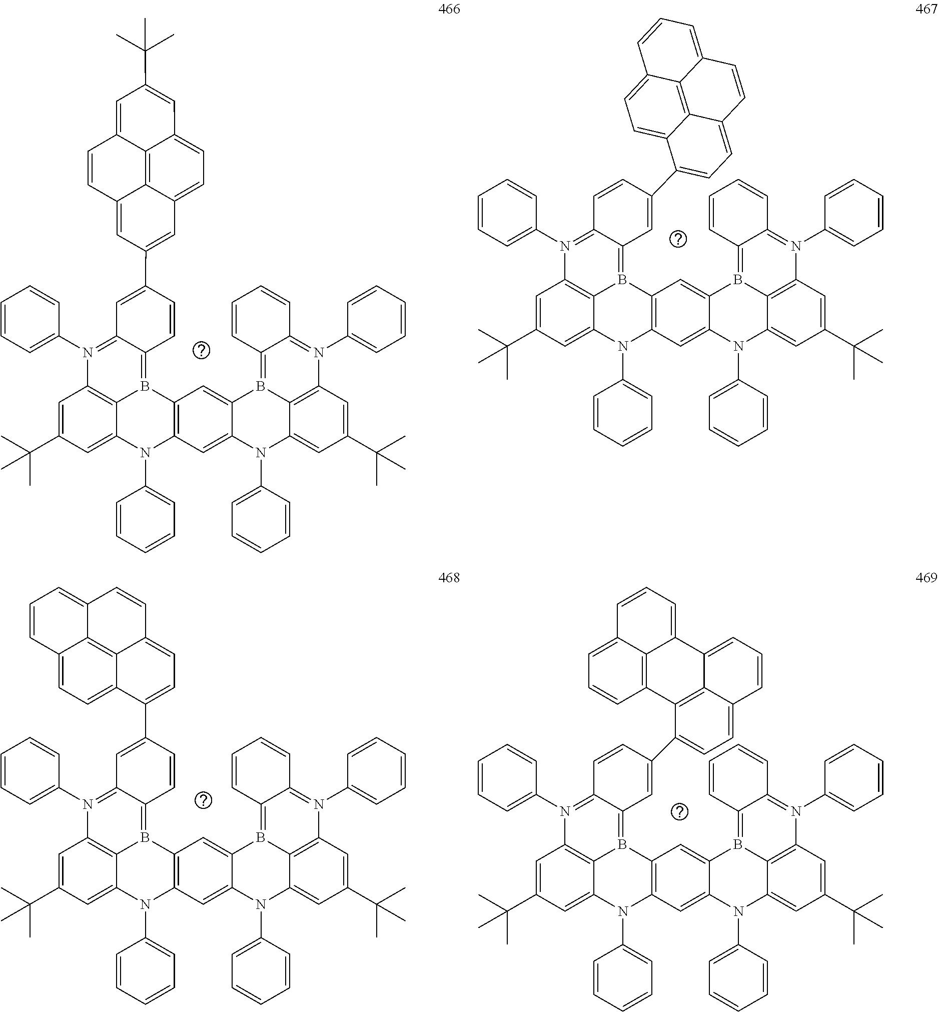

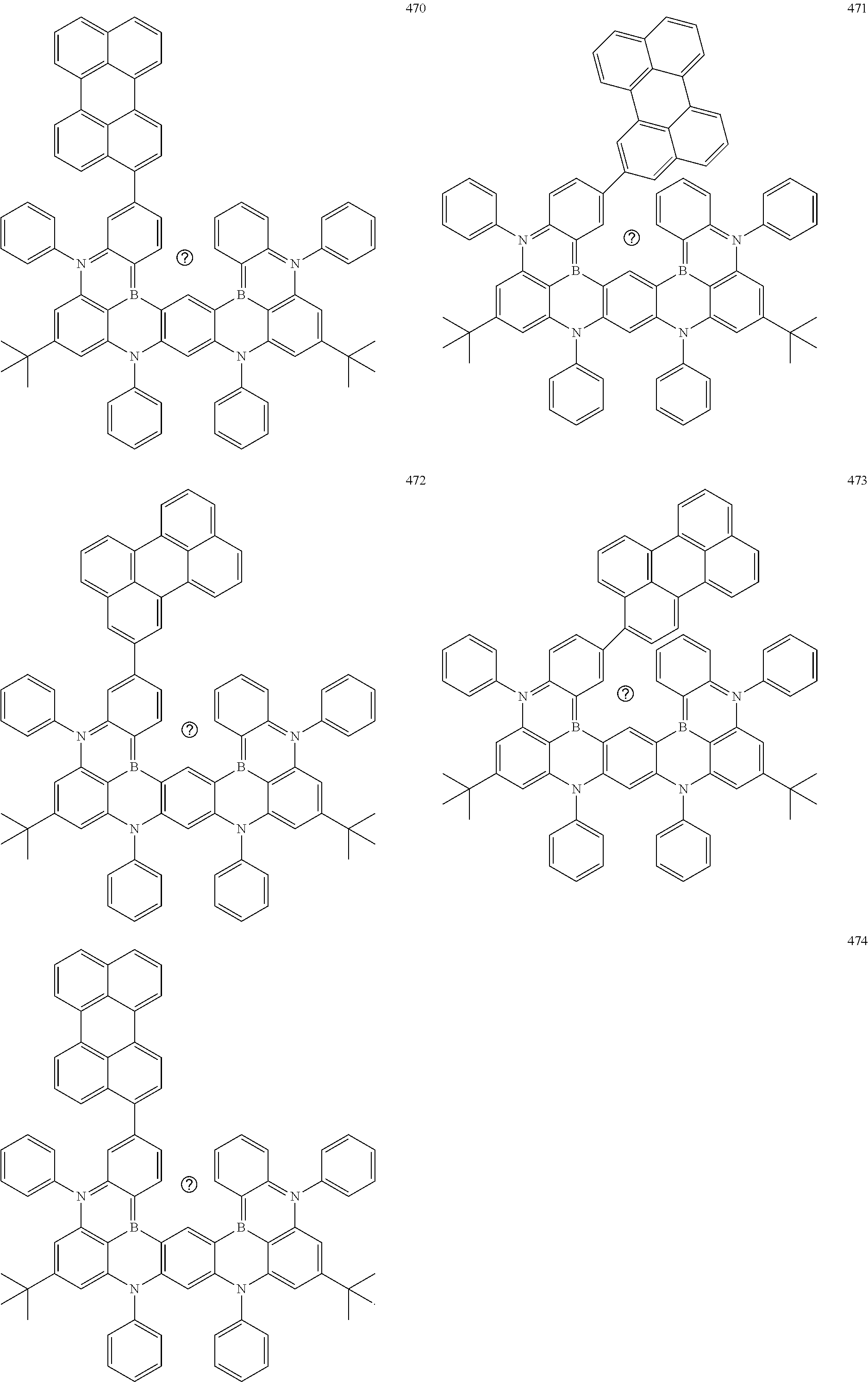

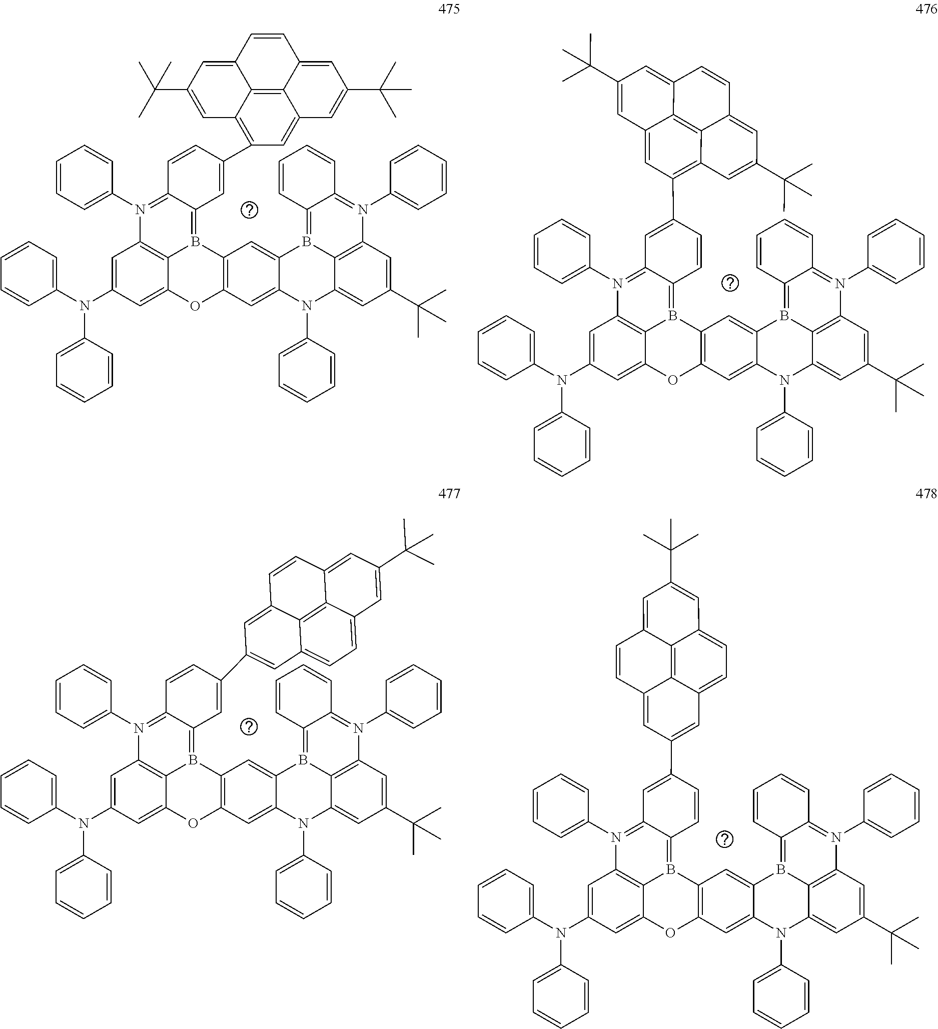

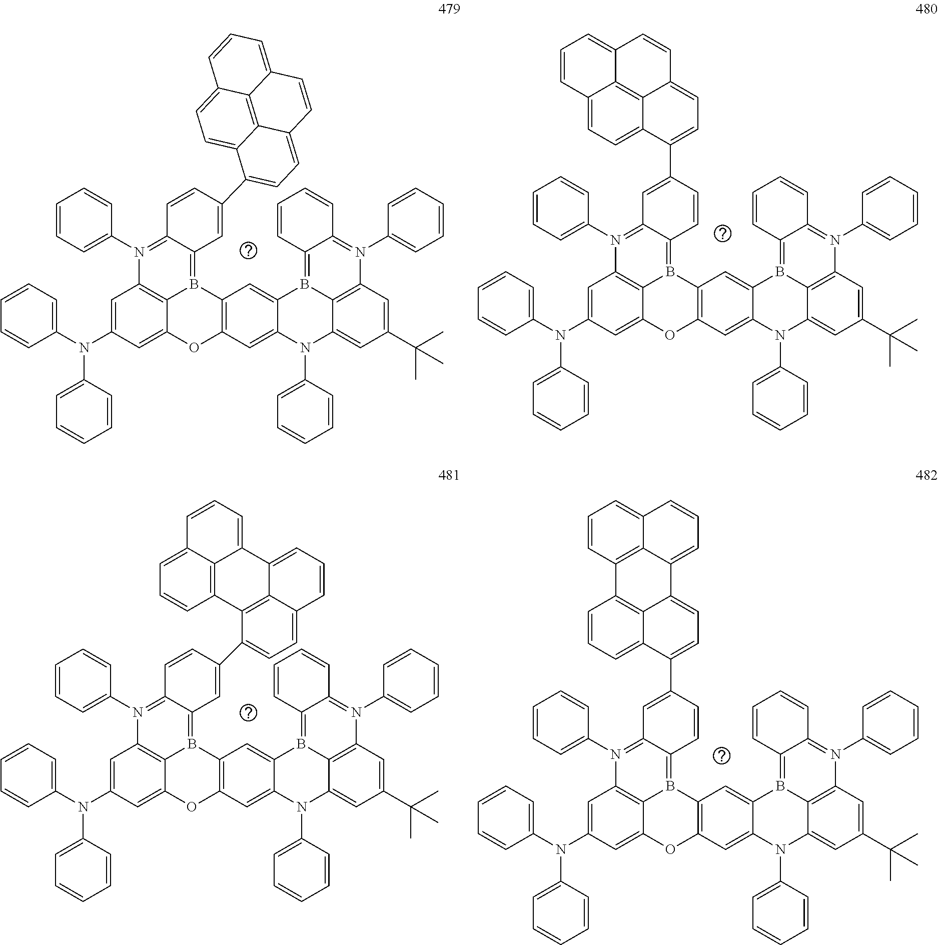

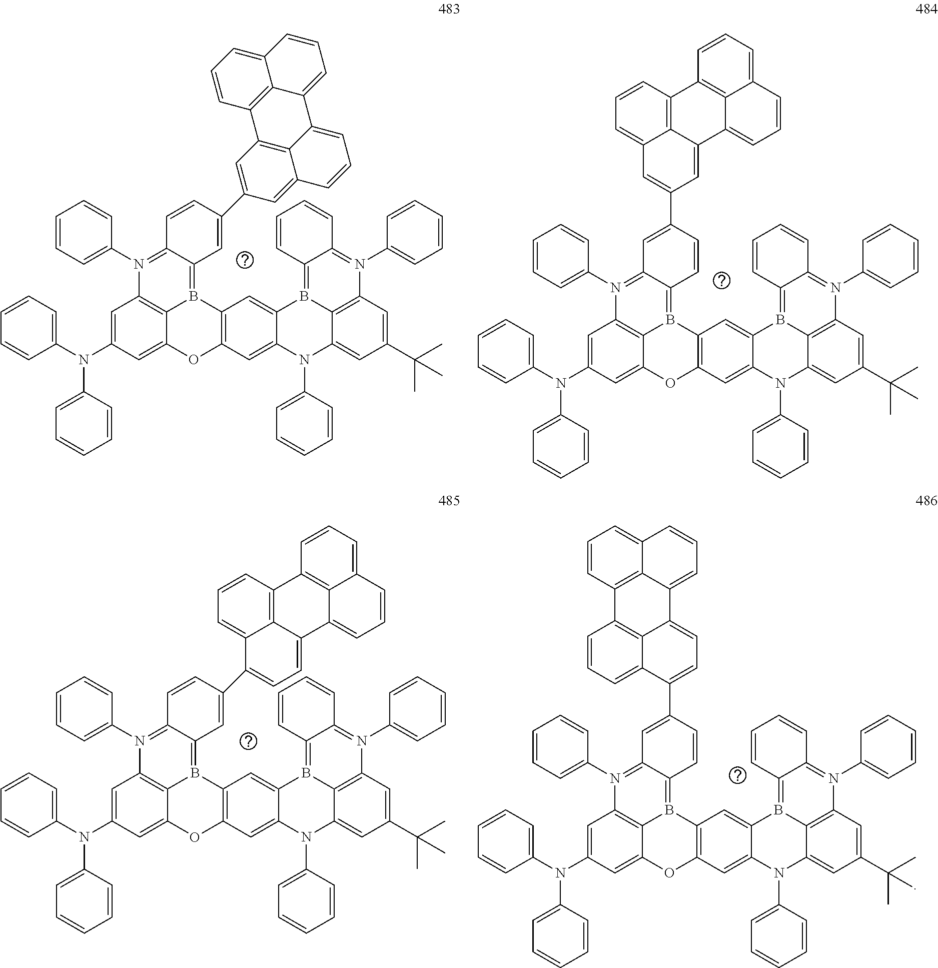

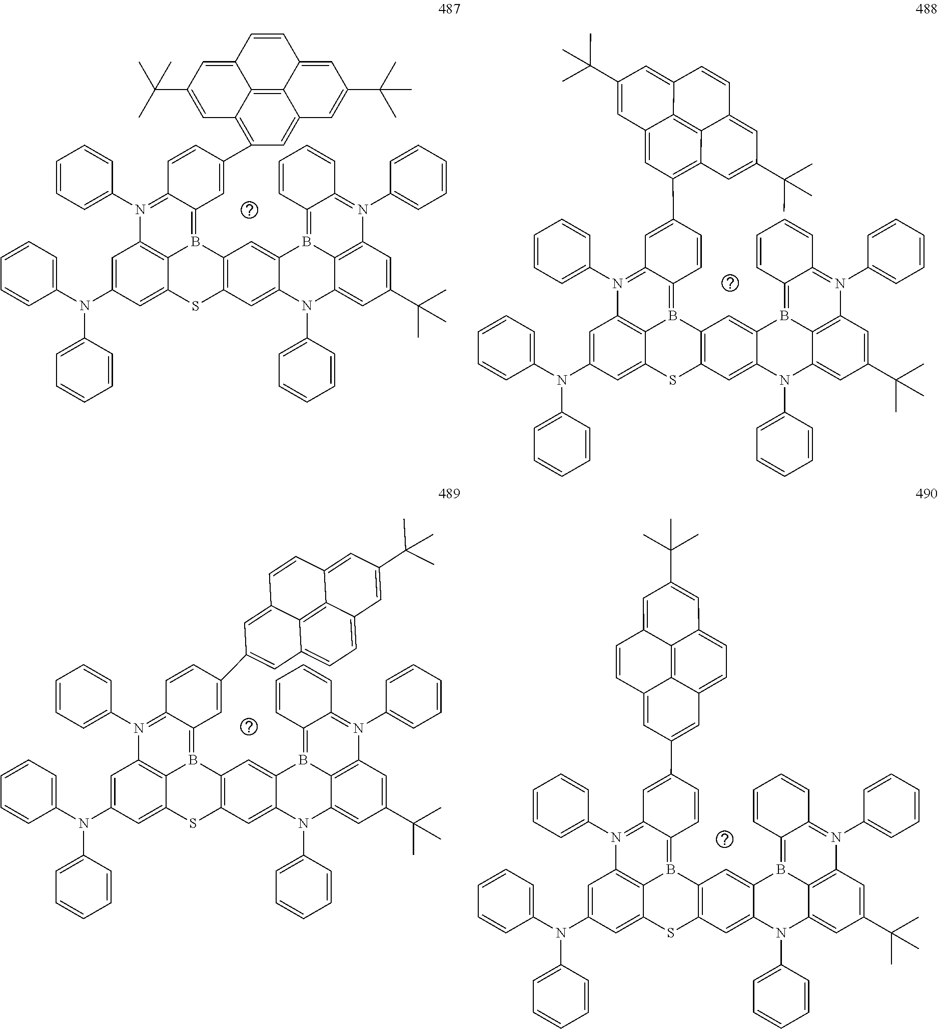

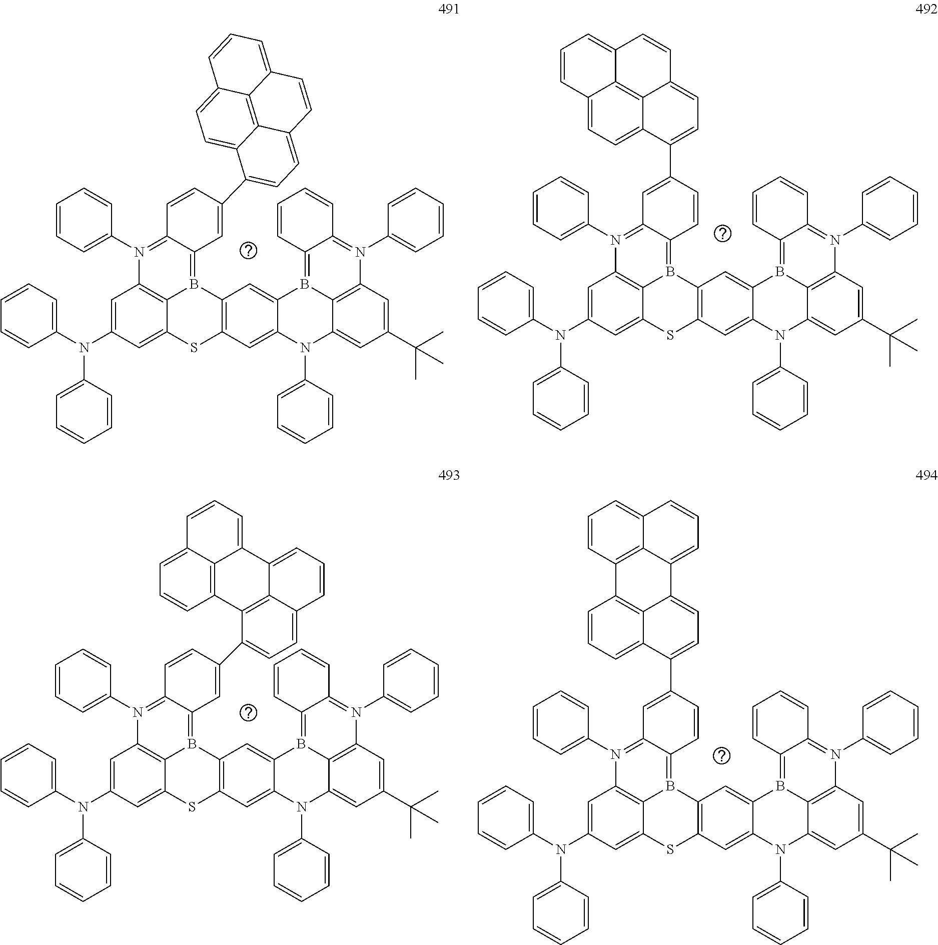

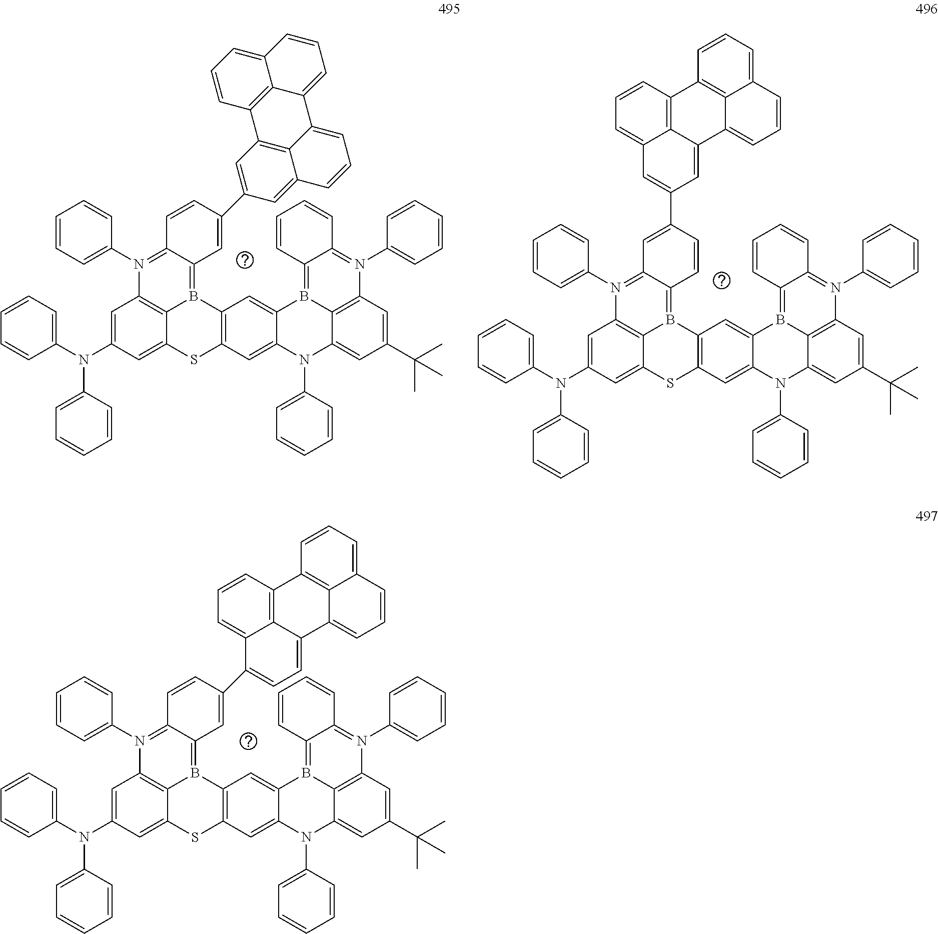

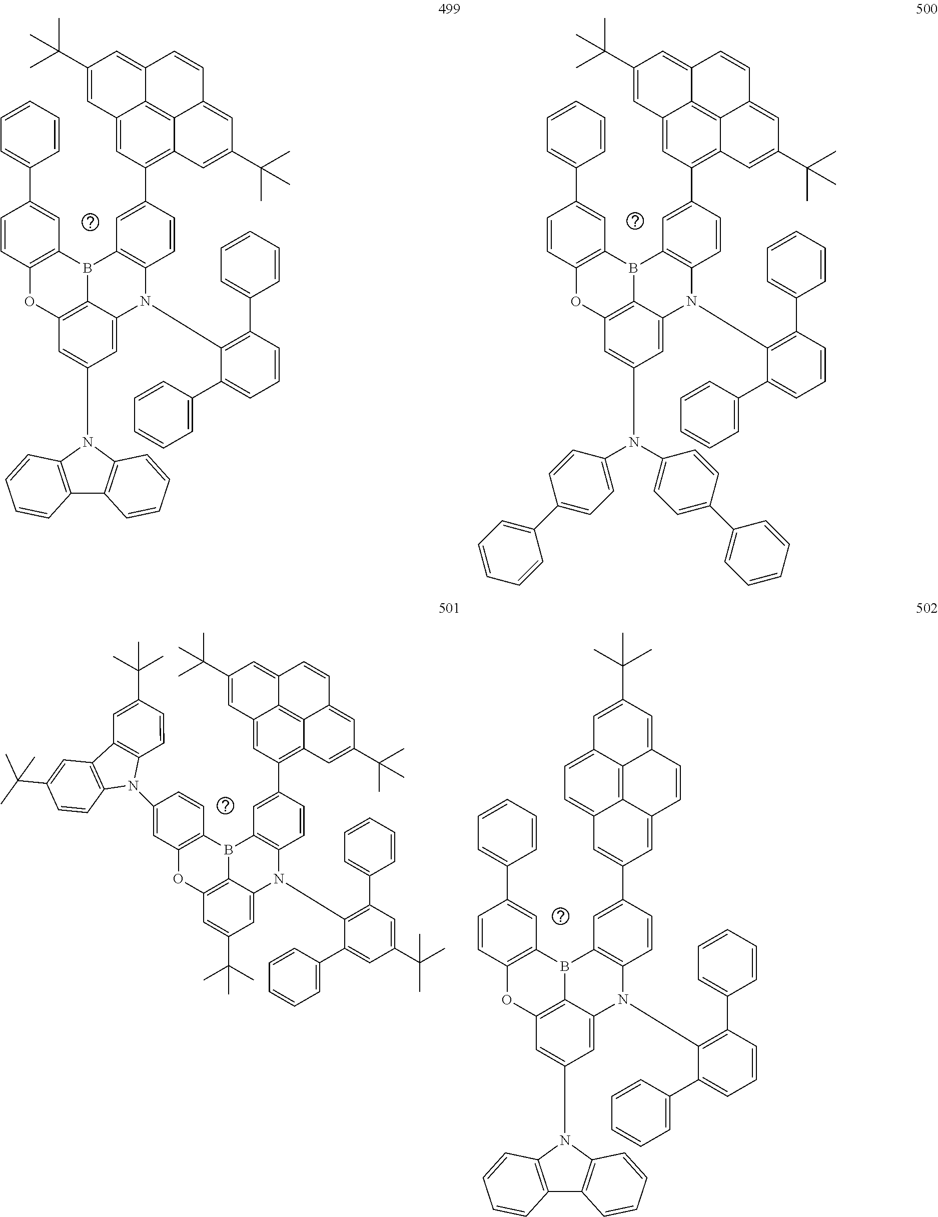

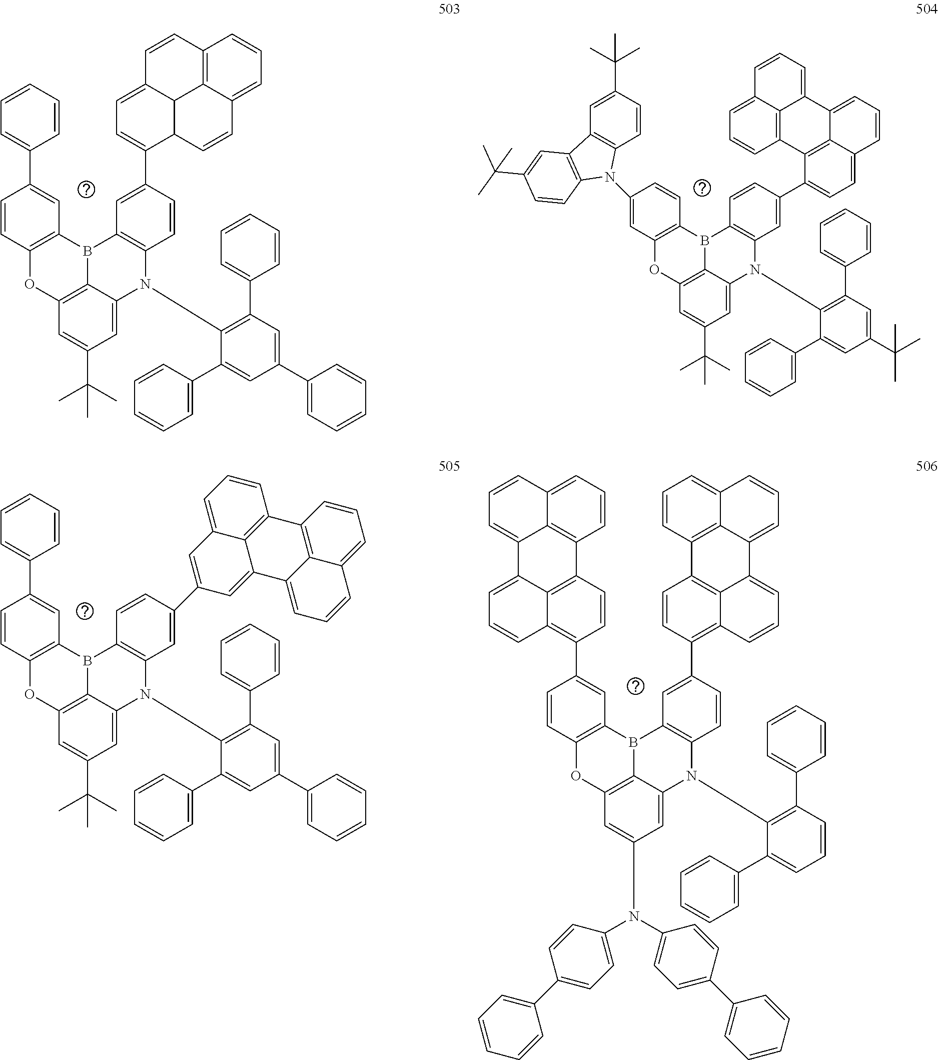

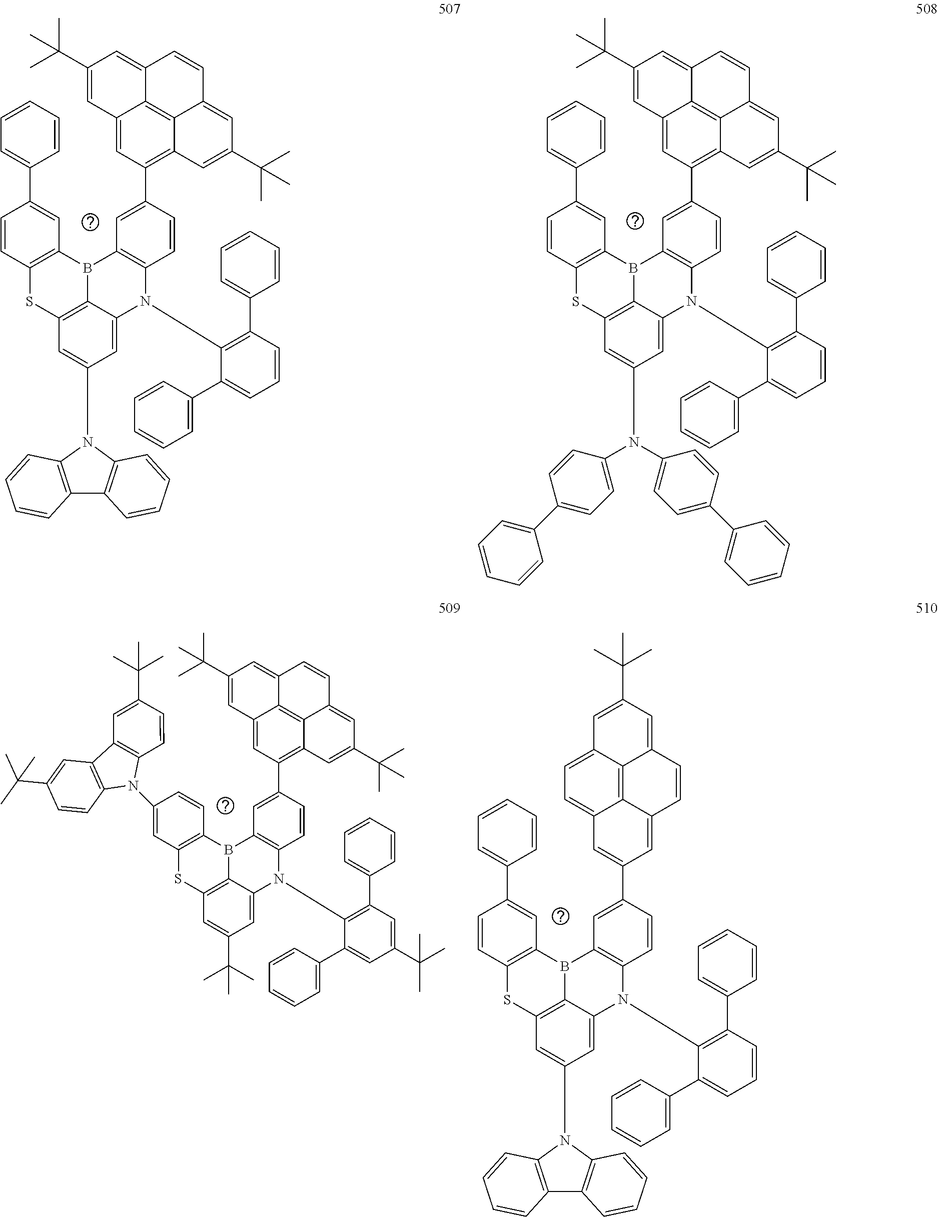

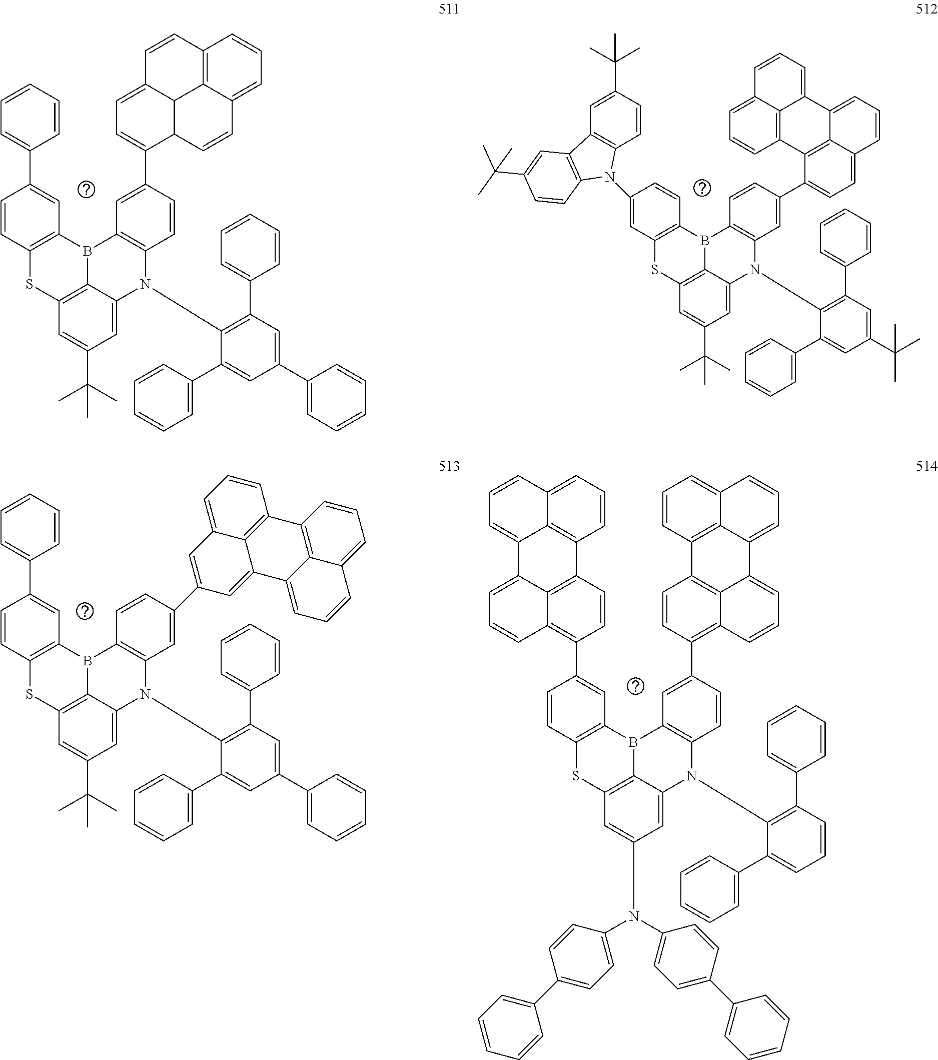

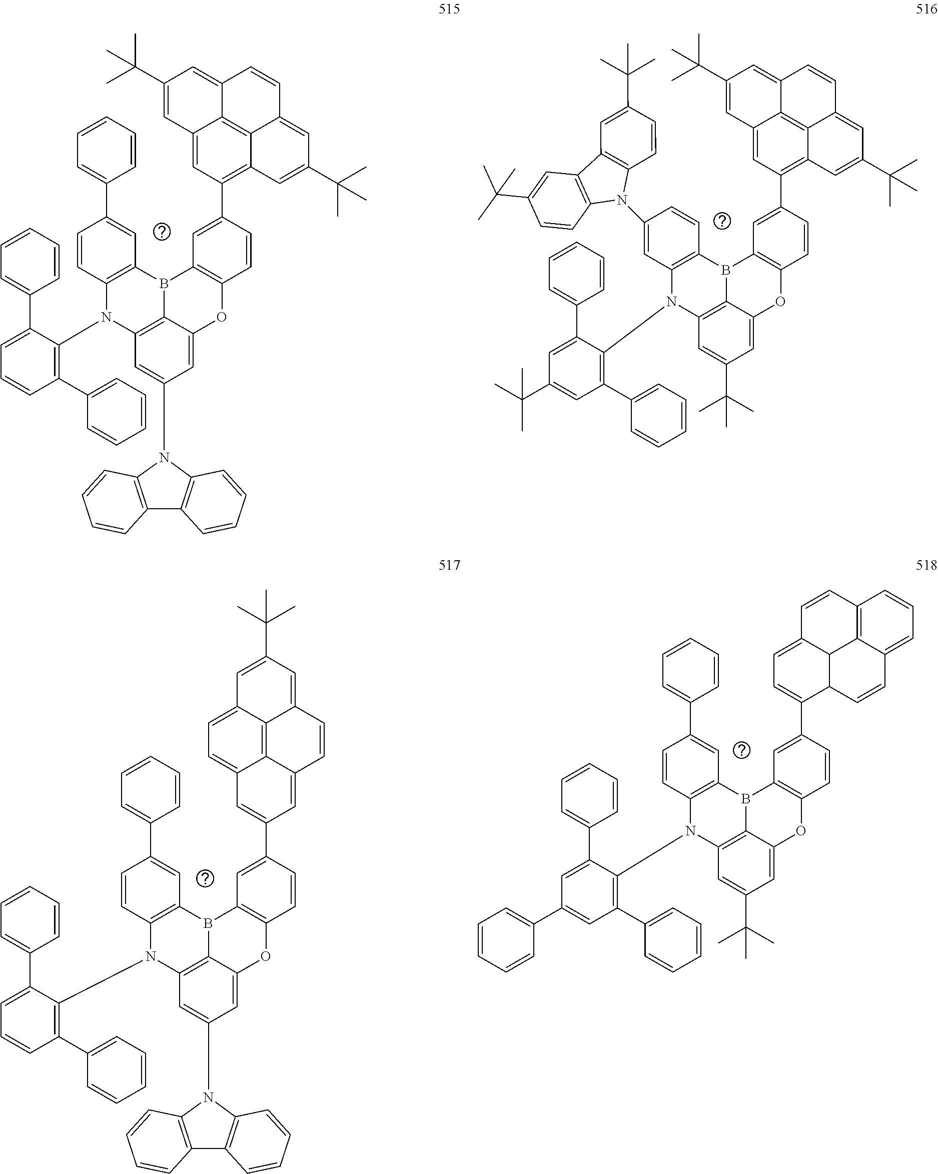

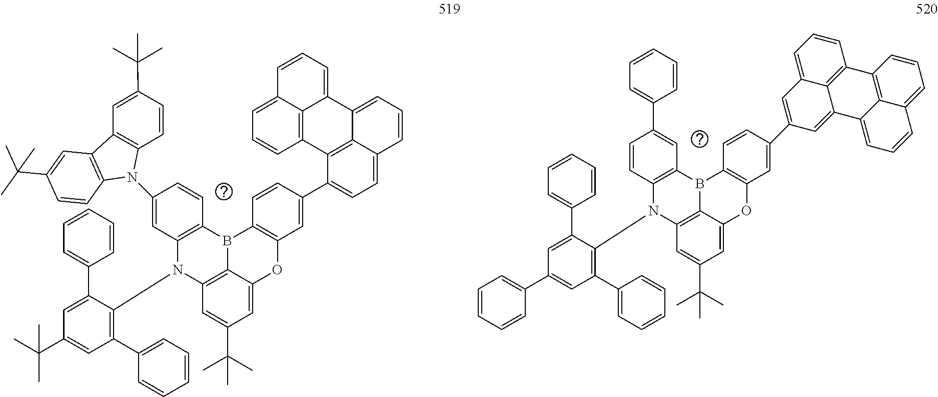 [SMILES: CC(C)(C)c1cc(-c2ccccc2)c(N2c3cc(-n4c5ccc(C(C)(C)C)cc5c5cc(C(C)(C)C)ccc54)ccc3B3c4ccc(-c5ccc6cccc7c8cccc9cccc(c5c67)c98)cc4Oc4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1ccc(-c4ccccc4)cc1B3c1ccc(-c3cc4cccc5c6cccc7cccc(c(c3)c45)c76)cc1O2]

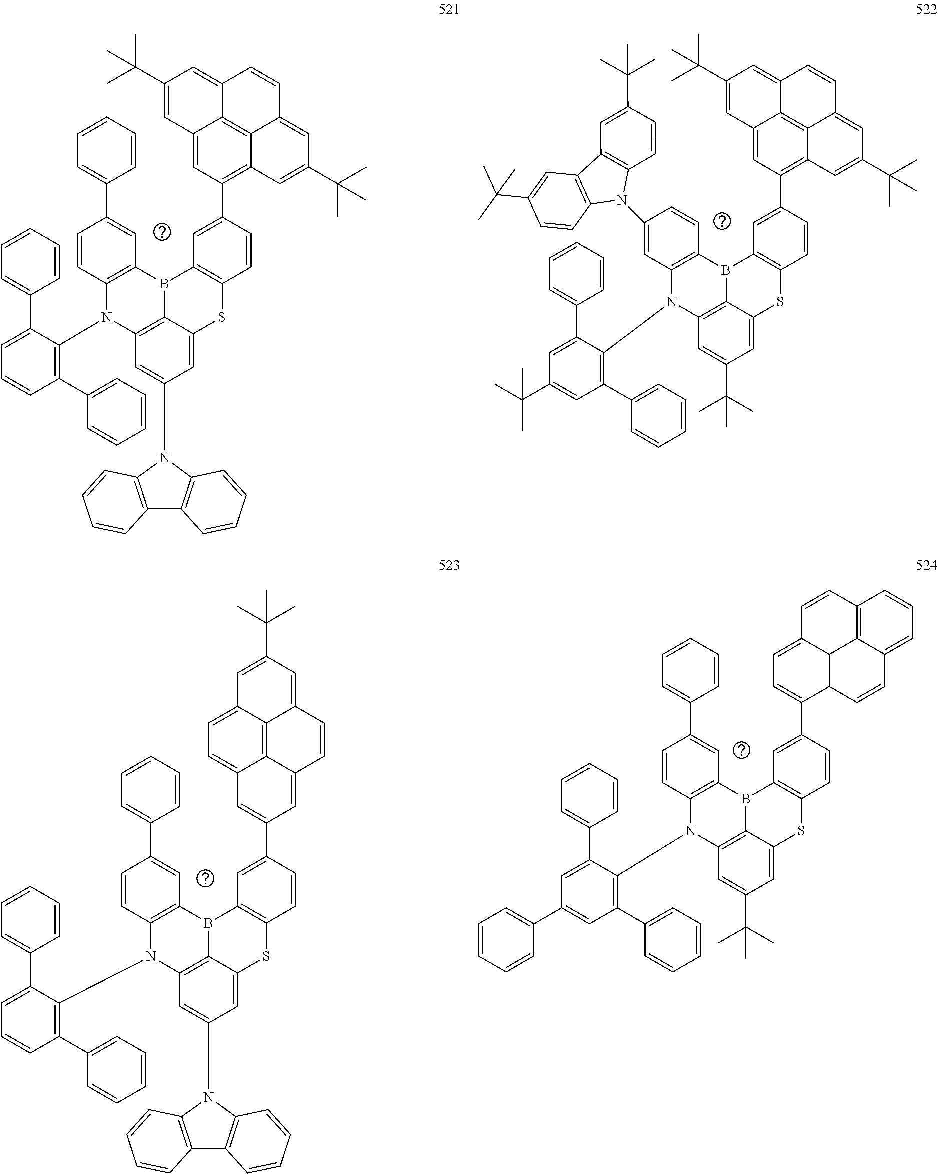

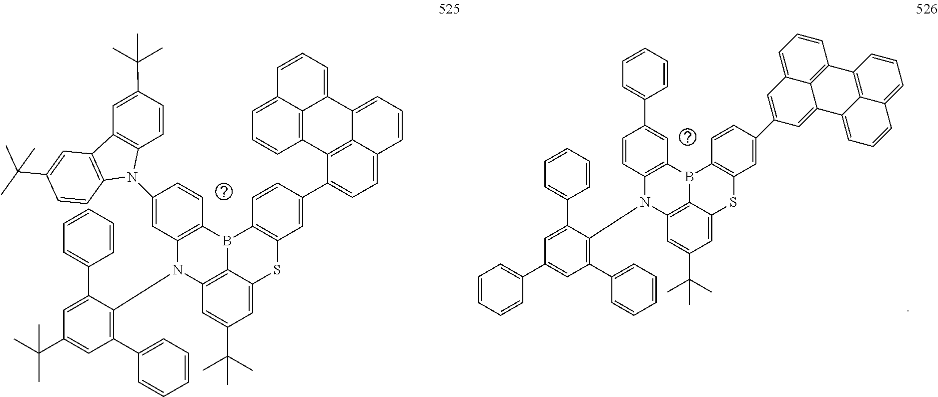 [SMILES: CC(C)(C)c1cc(-c2ccccc2)c(N2c3cc(-n4c5ccc(C(C)(C)C)cc5c5cc(C(C)(C)C)ccc54)ccc3B3c4ccc(-c5ccc6cccc7c8cccc9cccc(c5c67)c98)cc4Sc4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1ccc(-c4ccccc4)cc1B3c1ccc(-c3cc4cccc5c6cccc7cccc(c(c3)c45)c76)cc1S2]

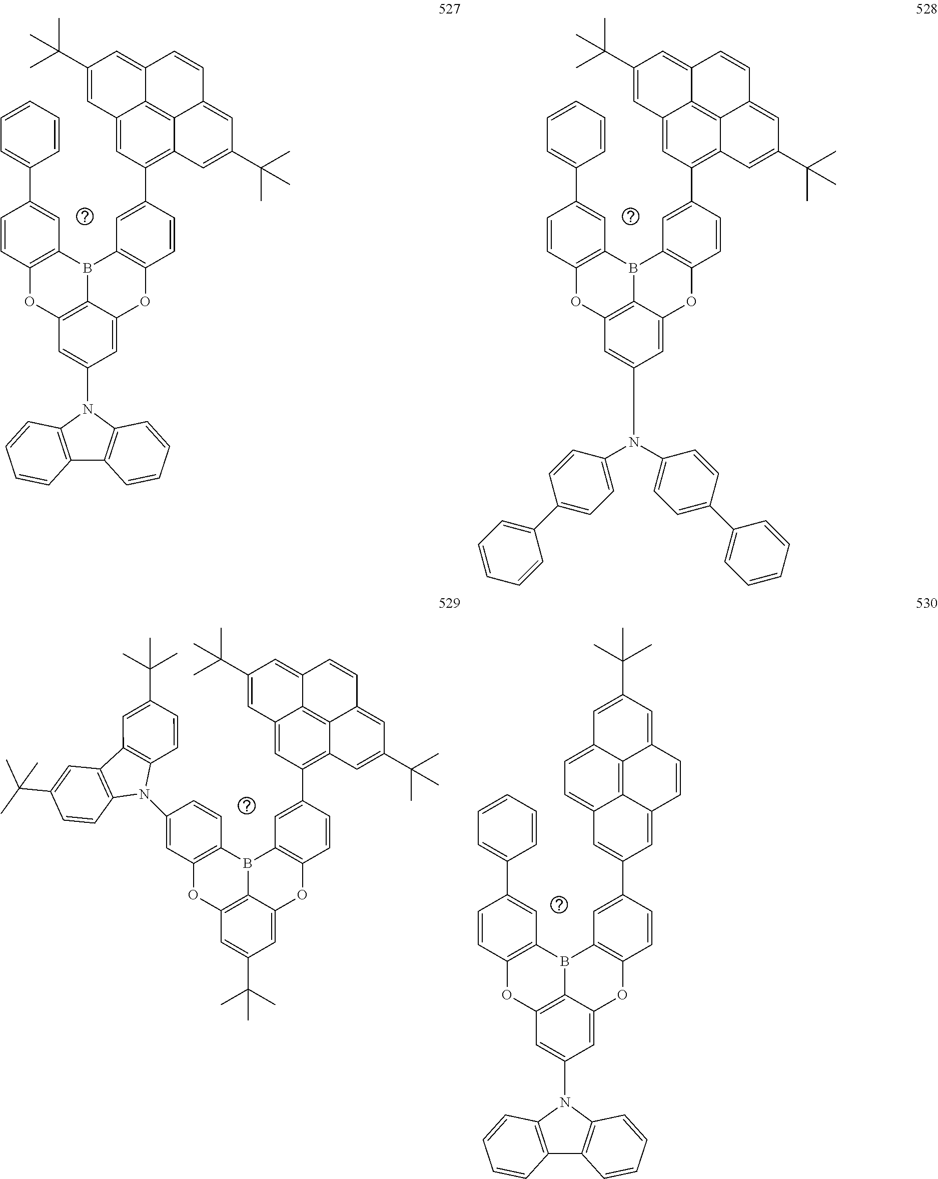 [SMILES: CC(C)(C)c1cc2ccc3cc(C(C)(C)C)cc4c(-c5ccc6c(c5)B5c7cc(-c8ccccc8)ccc7Oc7cc(-n8c9ccccc9c9ccccc98)cc(c75)O6)cc(c1)c2c34 ; CC(C)(C)c1cc2ccc3cc(C(C)(C)C)cc4c(-c5ccc6c(c5)B5c7cc(-c8ccccc8)ccc7Oc7cc(N(c8ccc(-c9ccccc9)cc8)c8ccc(-c9ccccc9)cc8)cc(c75)O6)cc(c1)c2c34 ; CC(C)(C)c1cc2c3c(c1)Oc1ccc(-c4cc5cc(C(C)(C)C)cc6ccc7cc(C(C)(C)C)cc4c7c65)cc1B3c1ccc(-n3c4ccc(C(C)(C)C)cc4c4cc(C(C)(C)C)ccc43)cc1O2 ; CC(C)(C)c1cc2ccc3cc(-c4ccc5c(c4)B4c6cc(-c7ccccc7)ccc6Oc6cc(-n7c8ccccc8c8ccccc87)cc(c64)O5)cc4ccc(c1)c2c34]

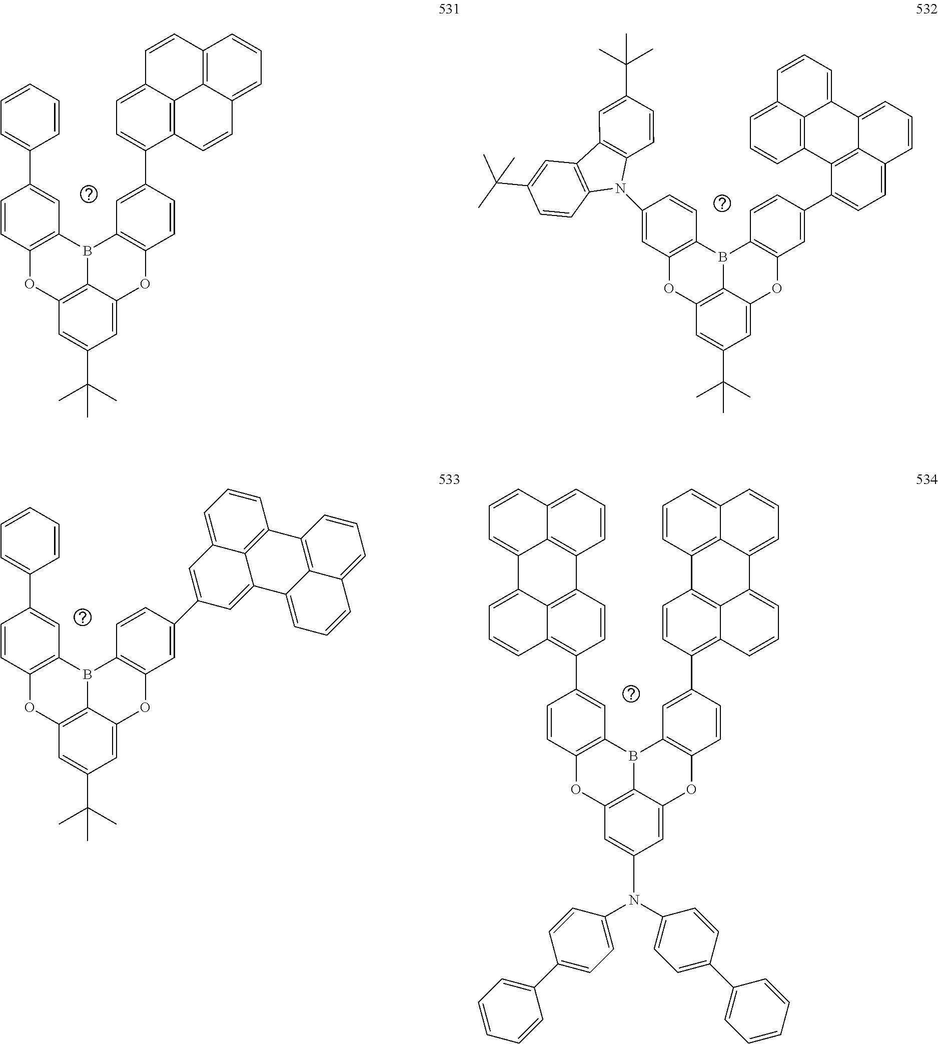 [SMILES: CC(C)(C)c1cc2c3c(c1)Oc1ccc(-c4ccc5ccc6cccc7ccc4c5c67)cc1B3c1cc(-c3ccccc3)ccc1O2 ; CC(C)(C)c1cc2c3c(c1)Oc1cc(-n4c5ccc(C(C)(C)C)cc5c5cc(C(C)(C)C)ccc54)ccc1B3c1ccc(-c3ccc4cccc5c6cccc7cccc(c3c45)c76)cc1O2 ; CC(C)(C)c1cc2c3c(c1)Oc1ccc(-c4ccccc4)cc1B3c1ccc(-c3cc4cccc5c6cccc7cccc(c(c3)c45)c76)cc1O2 ; c1ccc(-c2ccc(N(c3ccc(-c4ccccc4)cc3)c3cc4c5c(c3)Oc3ccc(-c6ccc7c8cccc9cccc(c%10cccc6c%107)c98)cc3B5c3cc(-c5ccc6c7cccc8cccc(c9cccc5c96)c87)ccc3O4)cc2)cc1]

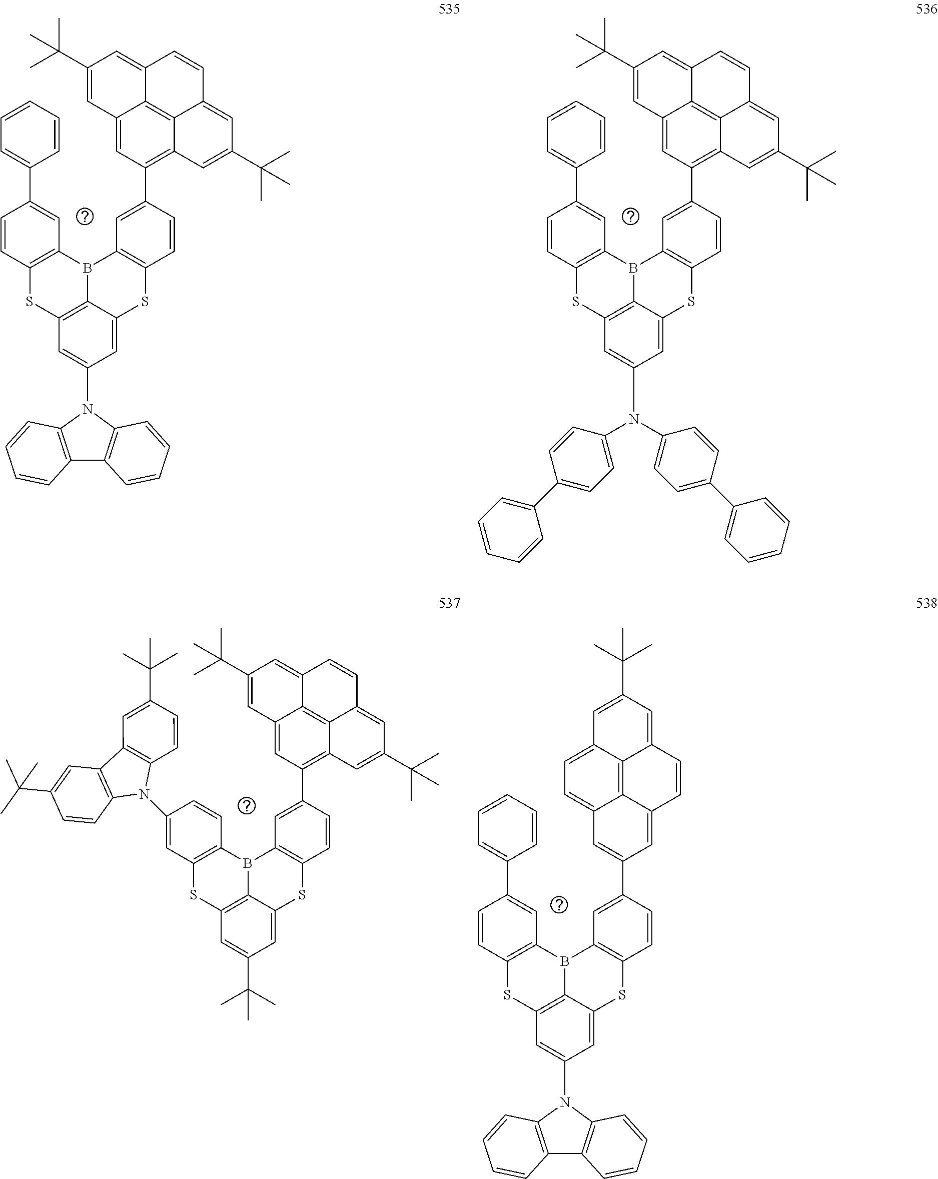 [SMILES: CC(C)(C)c1cc2ccc3cc(C(C)(C)C)cc4c(-c5ccc6c(c5)B5c7cc(-c8ccccc8)ccc7Sc7cc(-n8c9ccccc9c9ccccc98)cc(c75)S6)cc(c1)c2c34 ; CC(C)(C)c1cc2ccc3cc(C(C)(C)C)cc4c(-c5ccc6c(c5)B5c7cc(-c8ccccc8)ccc7Sc7cc(N(c8ccc(-c9ccccc9)cc8)c8ccc(-c9ccccc9)cc8)cc(c75)S6)cc(c1)c2c34 ; CC(C)(C)c1cc2c3c(c1)Sc1ccc(-c4cc5cc(C(C)(C)C)cc6ccc7cc(C(C)(C)C)cc4c7c65)cc1B3c1ccc(-n3c4ccc(C(C)(C)C)cc4c4cc(C(C)(C)C)ccc43)cc1S2 ; CC(C)(C)c1cc2ccc3cc(-c4ccc5c(c4)B4c6cc(-c7ccccc7)ccc6Sc6cc(-n7c8ccccc8c8ccccc87)cc(c64)S5)cc4ccc(c1)c2c34]

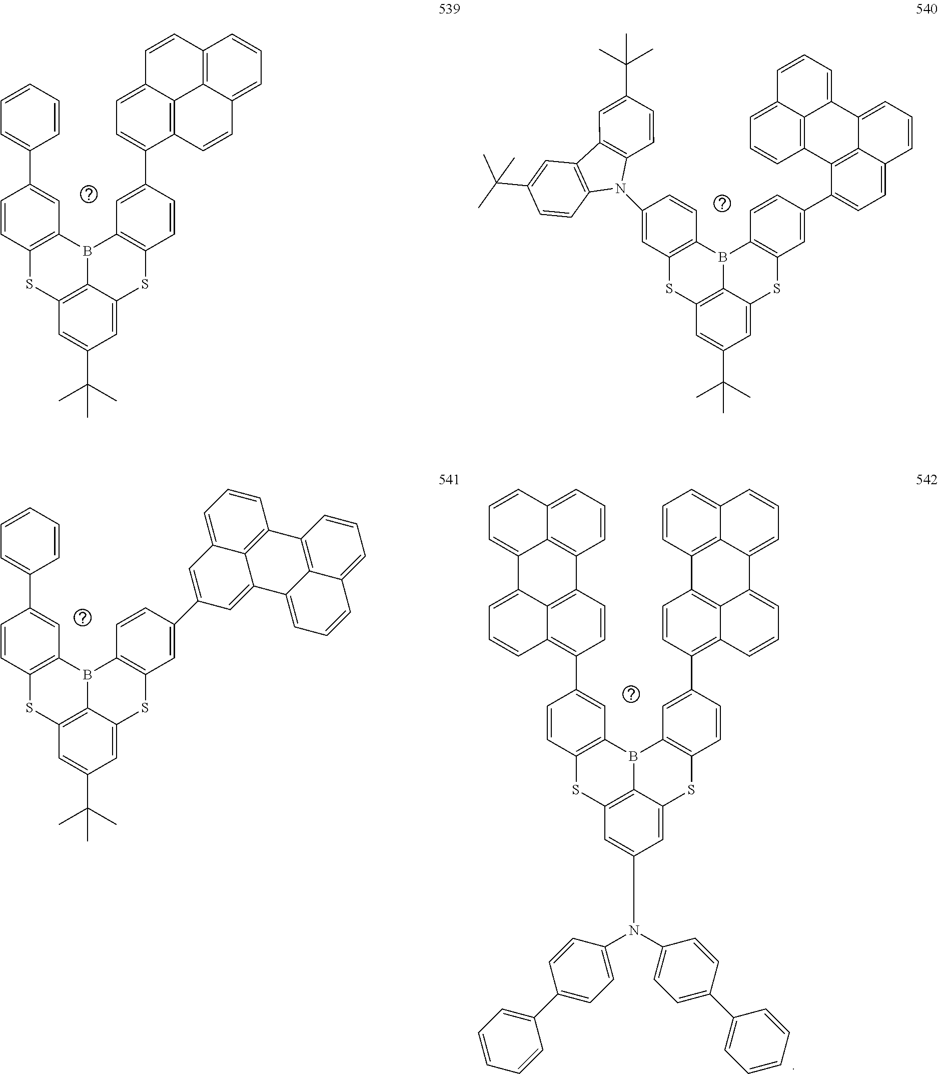 [SMILES: CC(C)(C)c1cc2c3c(c1)Sc1ccc(-c4ccc5ccc6cccc7ccc4c5c67)cc1B3c1cc(-c3ccccc3)ccc1S2 ; CC(C)(C)c1cc2c3c(c1)Sc1cc(-n4c5ccc(C(C)(C)C)cc5c5cc(C(C)(C)C)ccc54)ccc1B3c1ccc(-c3ccc4cccc5c6cccc7cccc(c3c45)c76)cc1S2 ; CC(C)(C)c1cc2c3c(c1)Sc1ccc(-c4ccccc4)cc1B3c1ccc(-c3cc4cccc5c6cccc7cccc(c(c3)c45)c76)cc1S2 ; c1ccc(-c2ccc(N(c3ccc(-c4ccccc4)cc3)c3cc4c5c(c3)Sc3ccc(-c6ccc7c8cccc9cccc(c%10cccc6c%107)c98)cc3B5c3cc(-c5ccc6c7cccc8cccc(c9cccc5c96)c87)ccc3S4)cc2)cc1]

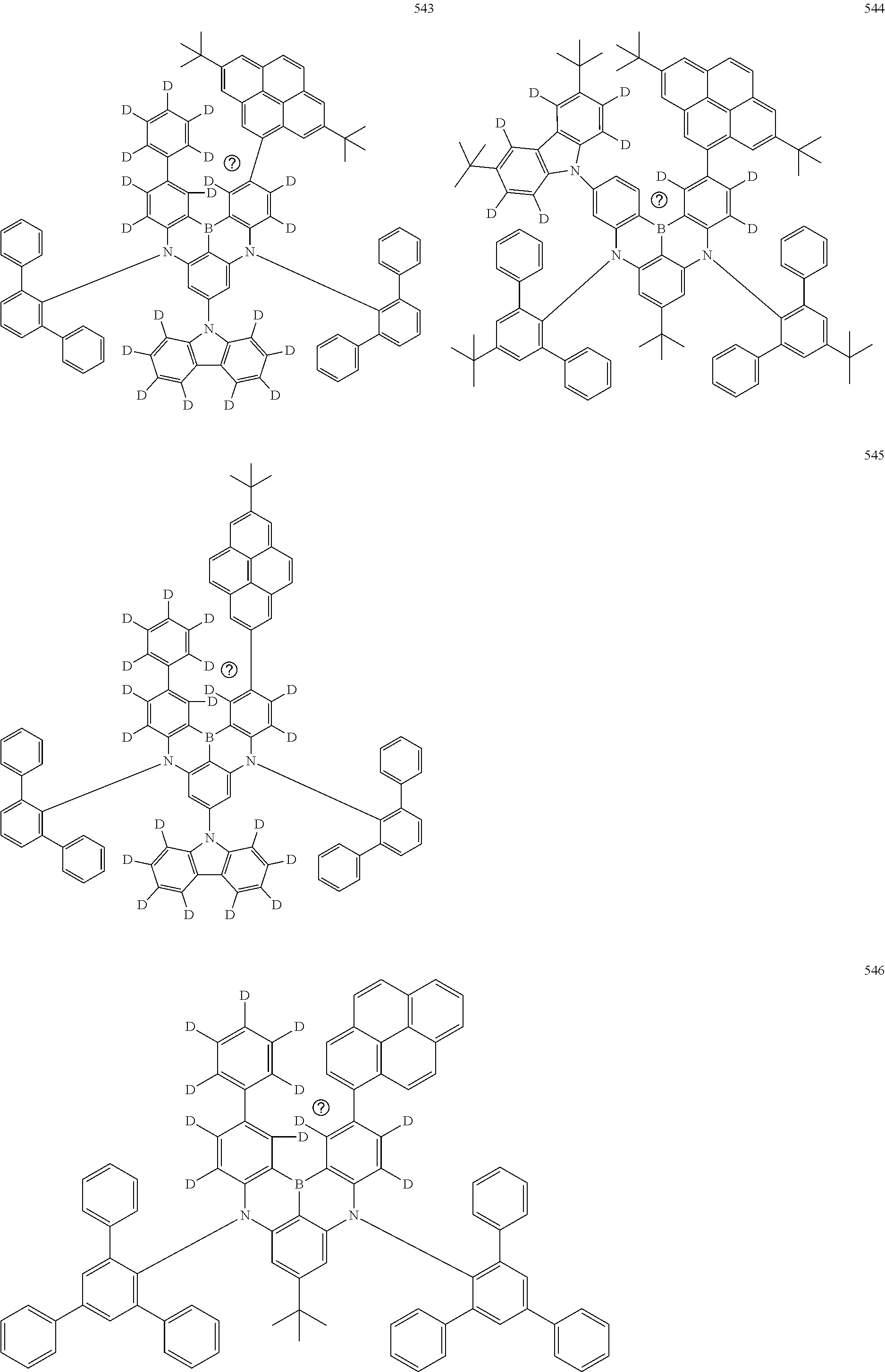

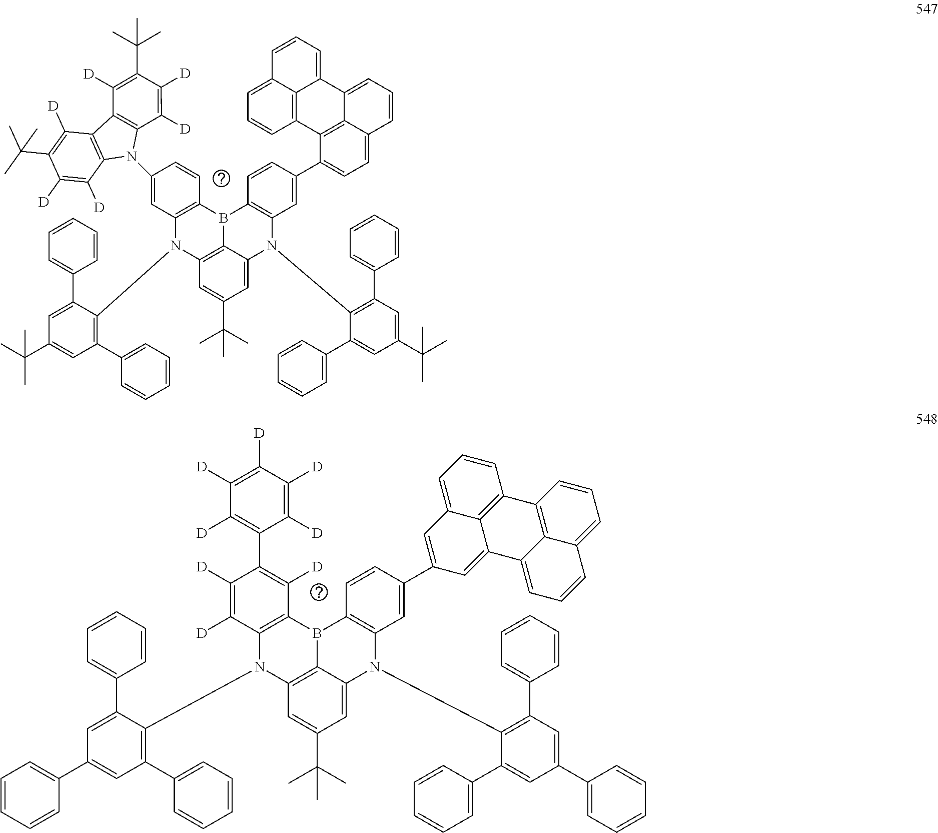 [SMILES: [2H]c1c(C(C)(C)C)c([2H])c2c3c([2H])c(C(C)(C)C)c([2H])c([2H])c3n(-c3ccc4c(c3)N(c3c(-c5ccccc5)cc(C(C)(C)C)cc3-c3ccccc3)c3cc(C(C)(C)C)cc5c3B4c3ccc(-c4ccc6cccc7c8cccc9cccc(c4c67)c98)cc3N5c3c(-c4ccccc4)cc(C(C)(C)C)cc3-c3ccccc3)c2c1[2H] ; [2H]c1c([2H])c([2H])c(-c2c([2H])c([2H])c3c(c2[2H])B2c4ccc(-c5cc6cccc7c8cccc9cccc(c(c5)c67)c98)cc4N(c4c(-c5ccccc5)cc(-c5ccccc5)cc4-c4ccccc4)c4cc(C(C)(C)C)cc(c42)N3c2c(-c3ccccc3)cc(-c3ccccc3)cc2-c2ccccc2)c([2H])c1[2H]]

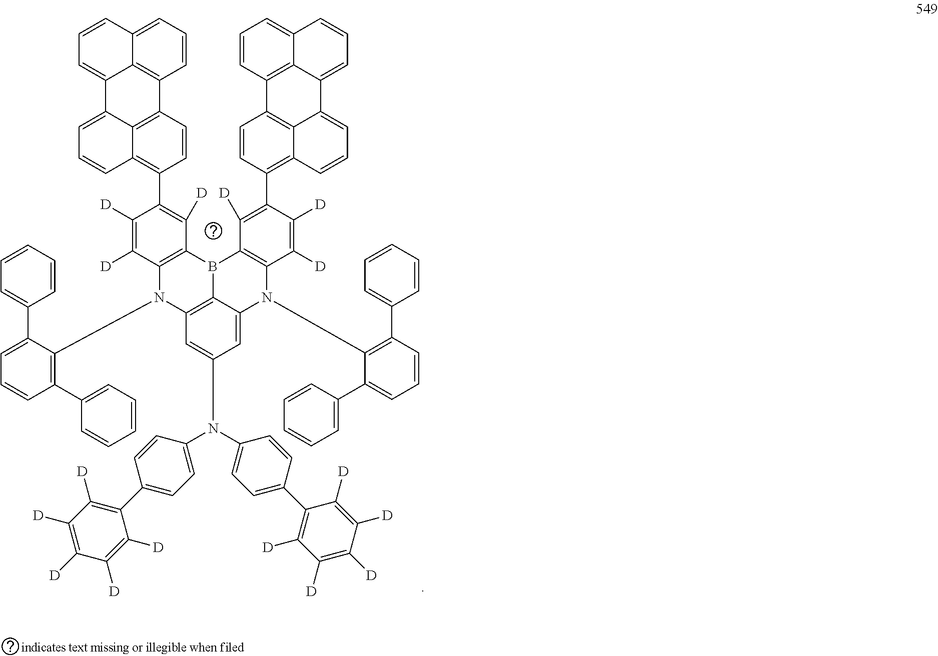 [SMILES: [2H]c1c([2H])c([2H])c(-c2ccc(N(c3ccc(-c4c([2H])c([2H])c([2H])c([2H])c4[2H])cc3)c3cc4c5c(c3)N(c3c(-c6ccccc6)cccc3-c3ccccc3)c3c([2H])c([2H])c(-c6ccc7c8cccc9cccc(c%10cccc6c%107)c98)c([2H])c3B5c3c([2H])c(-c5ccc6c7cccc8cccc(c9cccc5c96)c87)c([2H])c([2H])c3N4c3c(-c4ccccc4)cccc3-c3ccccc3)cc2)c([2H])c1[2H]]

In Compound Group 1, D represents a deuterium atom.

As described above, the emission layer EML may include the polycyclic compound. The emission layer EML may include the polycyclic compound as a dopant material. The polycyclic compound may be a thermally activated delayed fluorescent material. The polycyclic compound may be used as a thermally activated delayed fluorescent dopant. For example, in the light emitting element ED, the emission layer EML may include at least one polycyclic compound selected from Compound Group 1 as a thermally activated delayed fluorescence dopant. However, the use of the polycyclic compound is not limited thereto.

In an embodiment, the emission layer EML may include multiple compounds. In an embodiment, the emission layer EML may include the polycyclic compound represented by Formula 1, which may also be referred to as a first compound, and may also include at least one of a second compound represented by Formula HT-1 and a third compound represented by Formula ET-1. In an embodiment, the emission layer EML may include the polycyclic compound represented by Formula 1, which may also be referred to as a first compound, and may also include at least one of a second compound represented by Formula HT-1, a third compound represented by Formula ET-1, and a fourth compound represented by Formula D-1.

In an embodiment, the emission layer EML may further include a second compound represented by Formula HT-1. In an embodiment, the second compound may be used as a hole transporting host material in the emission layer EML.

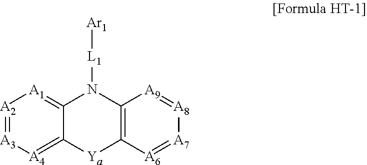

In Formula HT-1, A₁ to A₄ and A₆ to A₉ may each independently be N or C(R₄₁). For example, A₁ to A₄ and A₆ to A₉ may each independently be C(R₄₁). For example, any one of A₁ to A₄ and A₆ to A₉ may be N, and the remainder of A₁ to A₄ and A₆ to A₉ may each independently be C(R₄₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but embodiments are not limited thereto.

In Formula HT-1, Yₐ may be a direct linkage, C(R₄₂)(R₄₃), or Si(R₄₄)(R₄₅). For example, the two benzene rings that are connected to the nitrogen atom of Formula HT-1 may be connected to each other through a direct linkage,

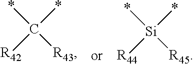

In Formula HT-1, when Yₐ is a direct linkage, the second compound represented by Formula HT-1 may include a carbazole moiety.

In Formula HT-1, An may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, or the like, but embodiments are not limited thereto.

In Formula HT-1, R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₄₁ to R₄₅ may each independently be a hydrogen atom or a deuterium atom. For example, R₄₁ to R₄₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

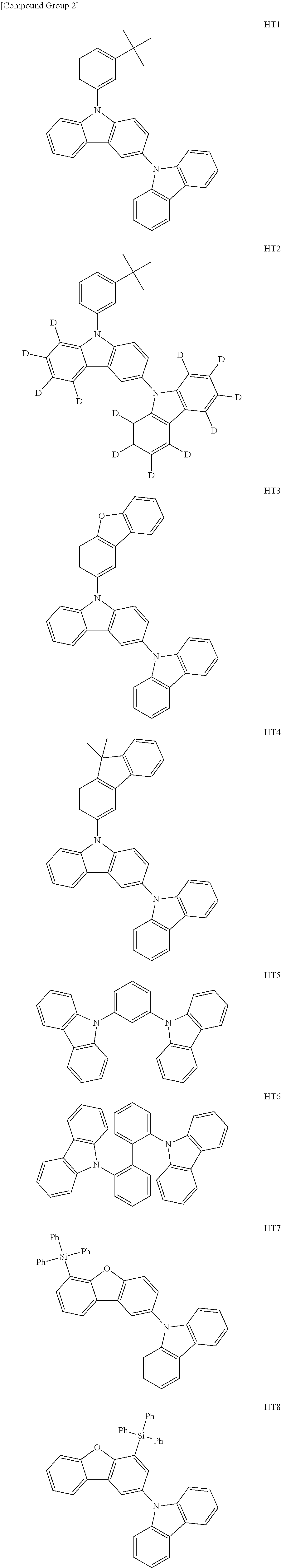

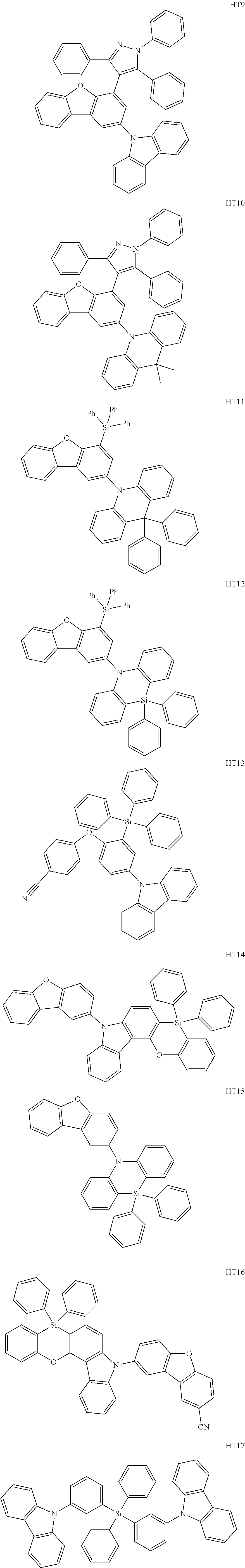

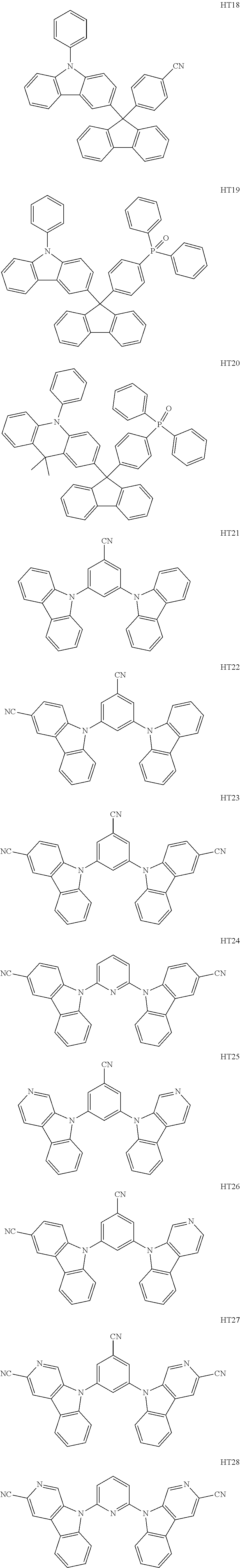

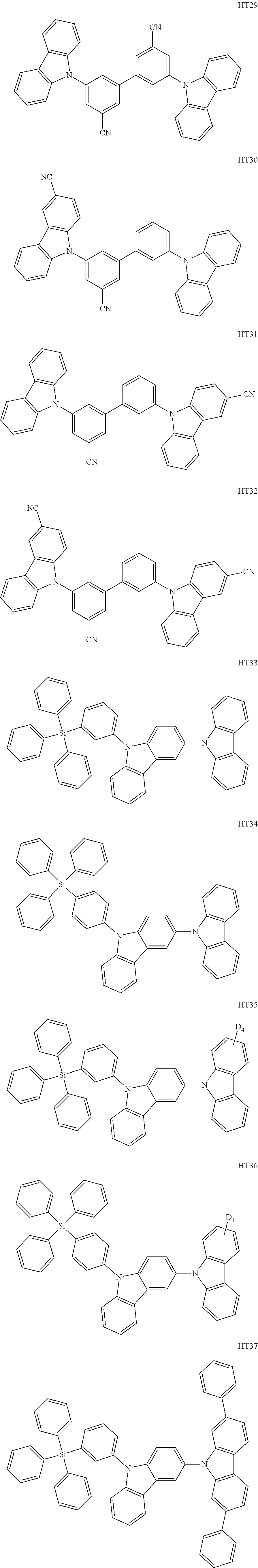

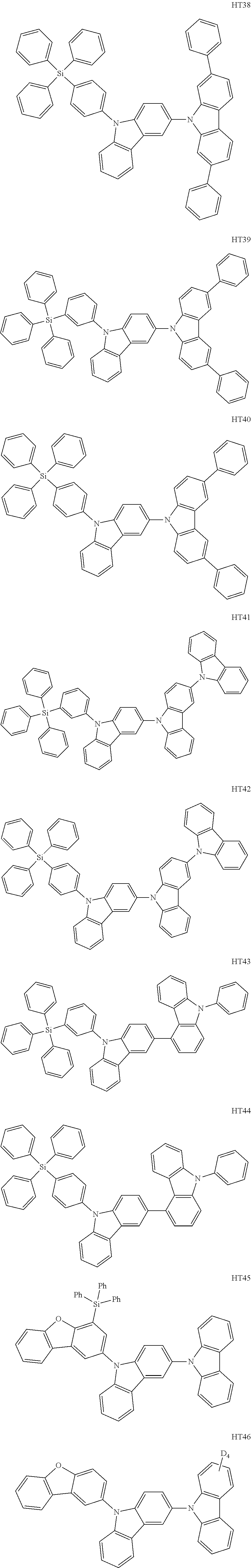

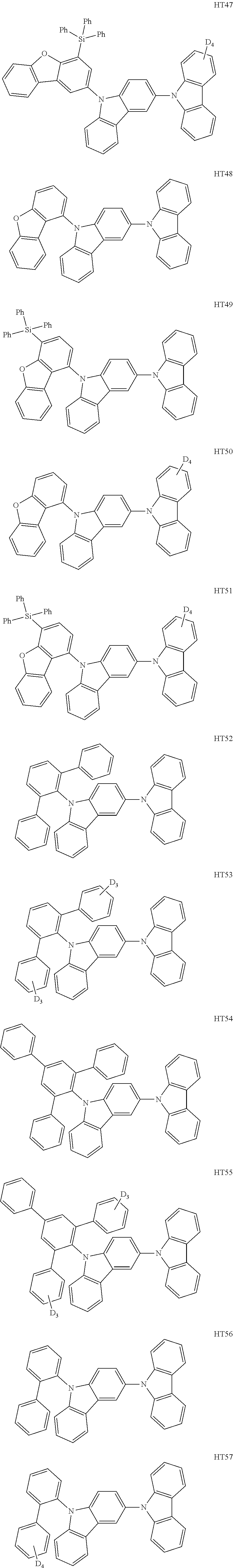

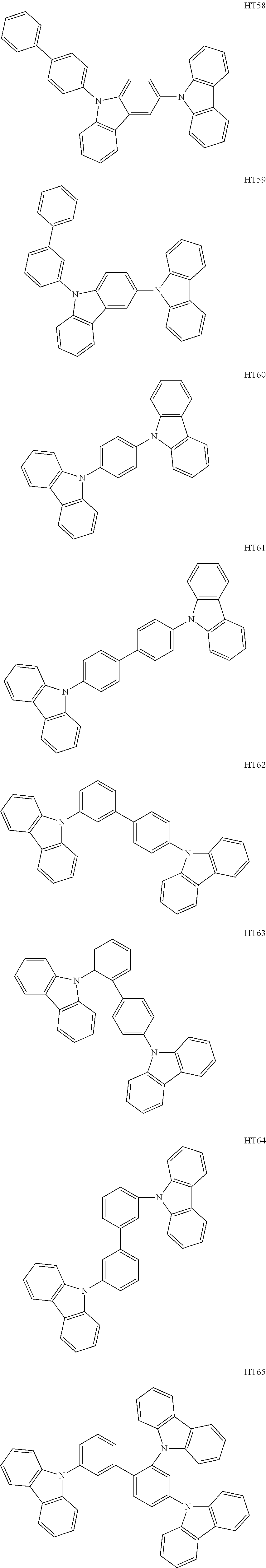

In Compound Group 2, D represents a deuterium atom, and Ph represents an unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transporting host material in the emission layer EML.

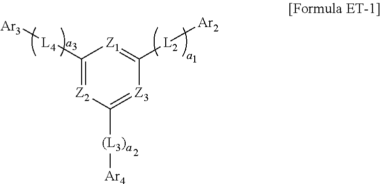

In Formula ET-1, at least one of Z₁ to Z₃ may each be N; the remainder of Z₁ to Z₃ may each independently be C(Rₐ₃); and R₃ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, a₁ to a₃ may each independently be an integer from 0 to 10.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When a₁ to a₃ are each 2 or greater, multiple groups of each of L₂ to L₄ may each independently be a substituted or unsubstituted arylene group having 6 to 30 ring-forming carbon atoms or a substituted or unsubstituted heteroarylene group having 2 to 30 ring-forming carbon atoms.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In an embodiment, the third compound represented by Formula ET-1 may be selected from Compound Group 3. In an embodiment, in the light emitting element ED, the third compound may include at least one compound selected from Compound Group 3.

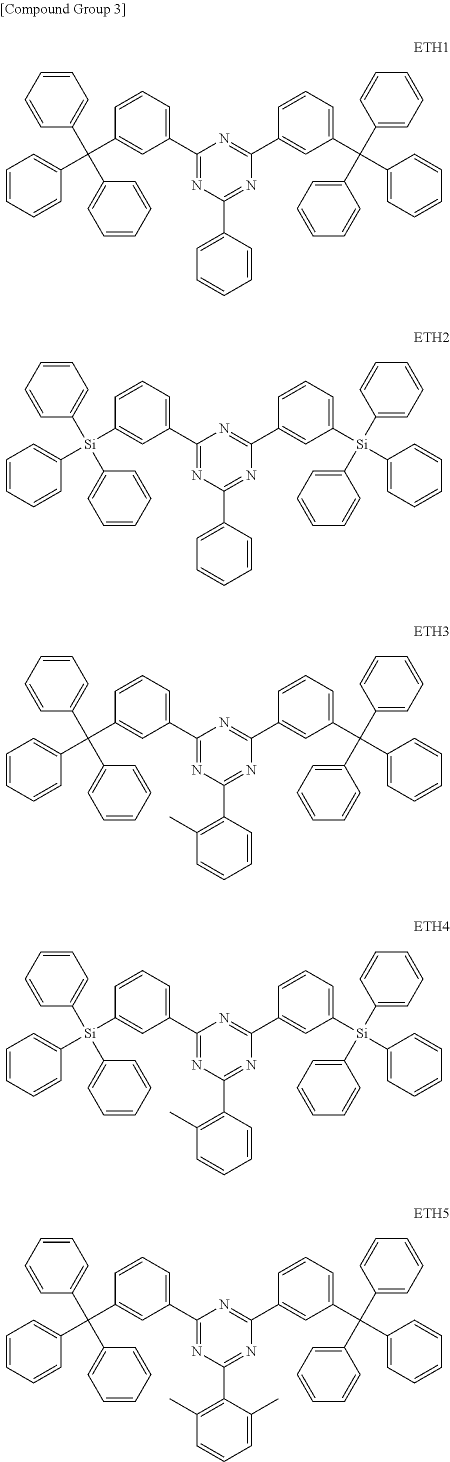

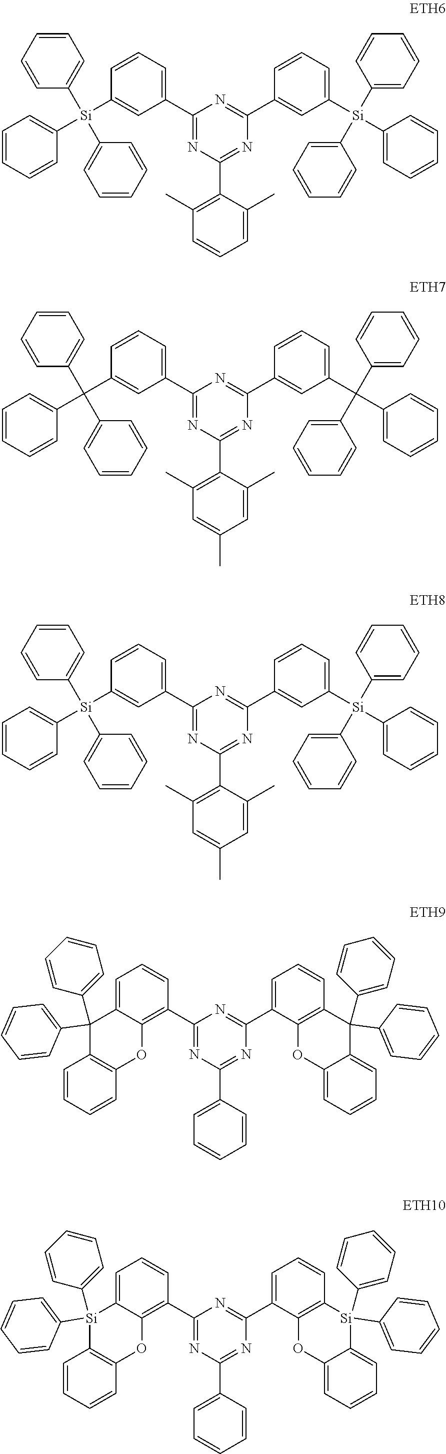

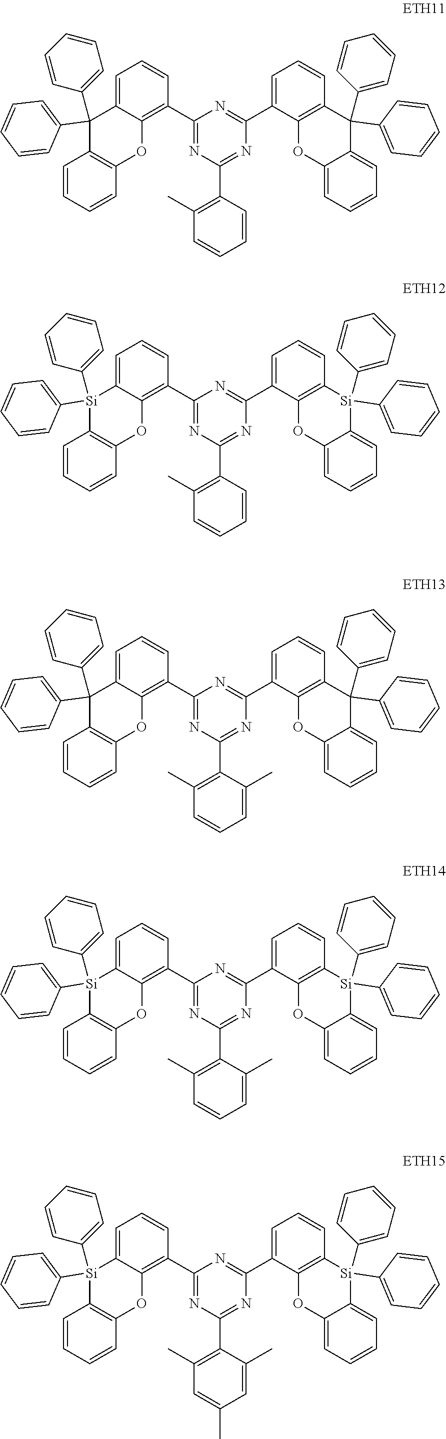

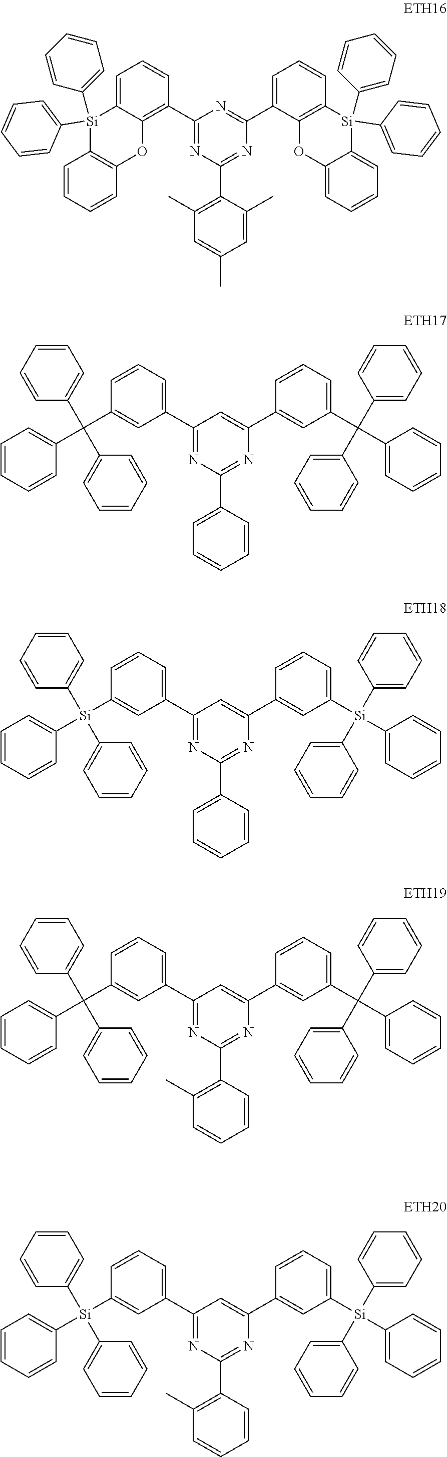

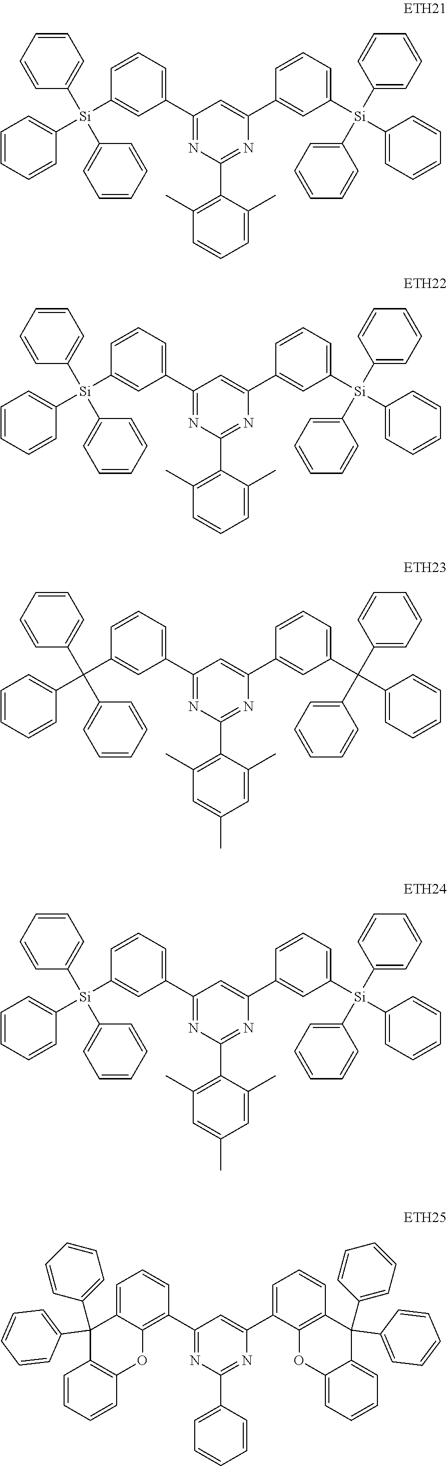

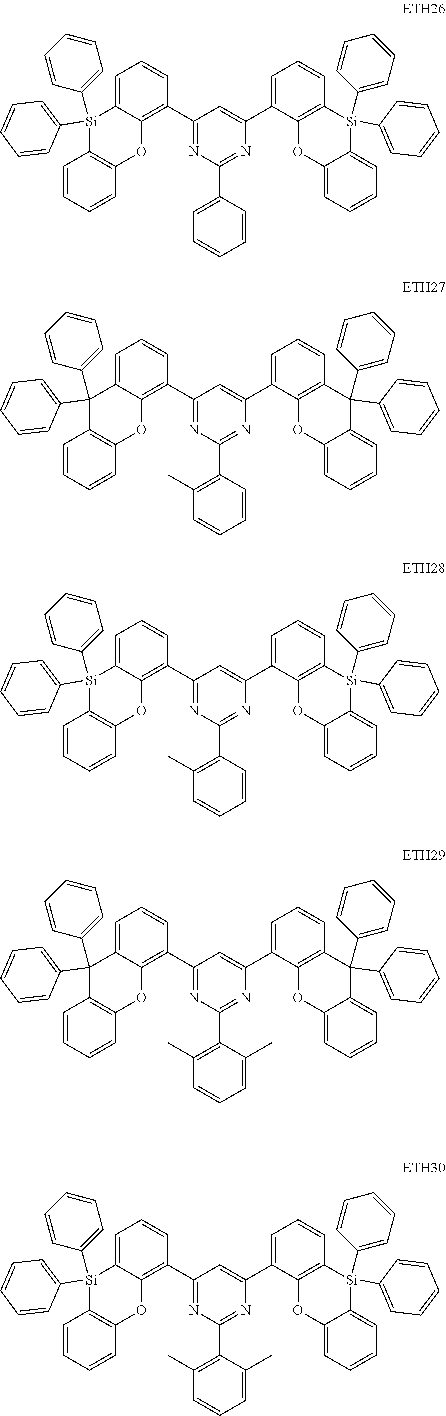

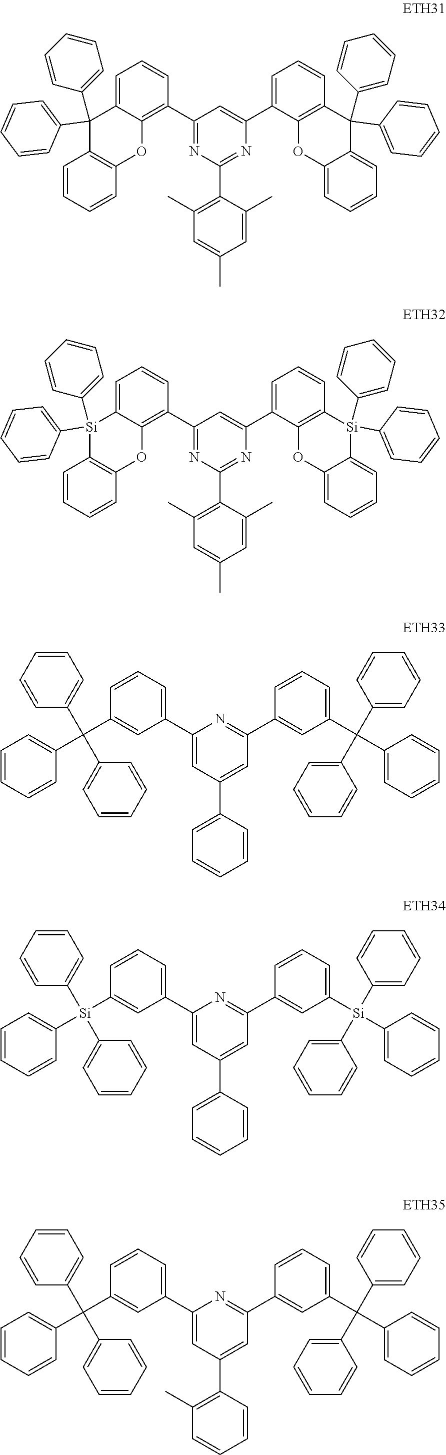

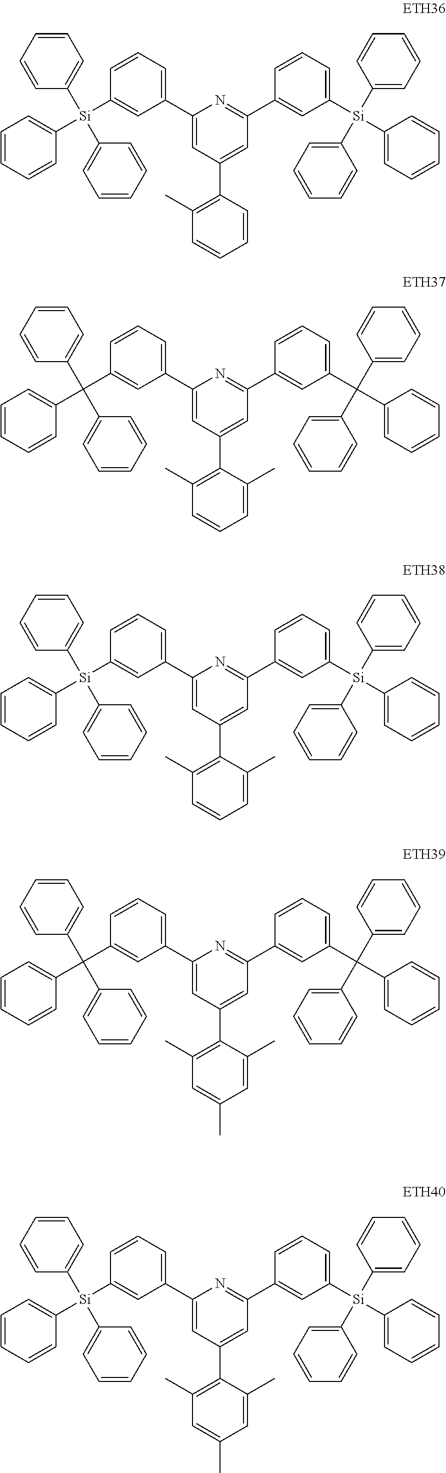

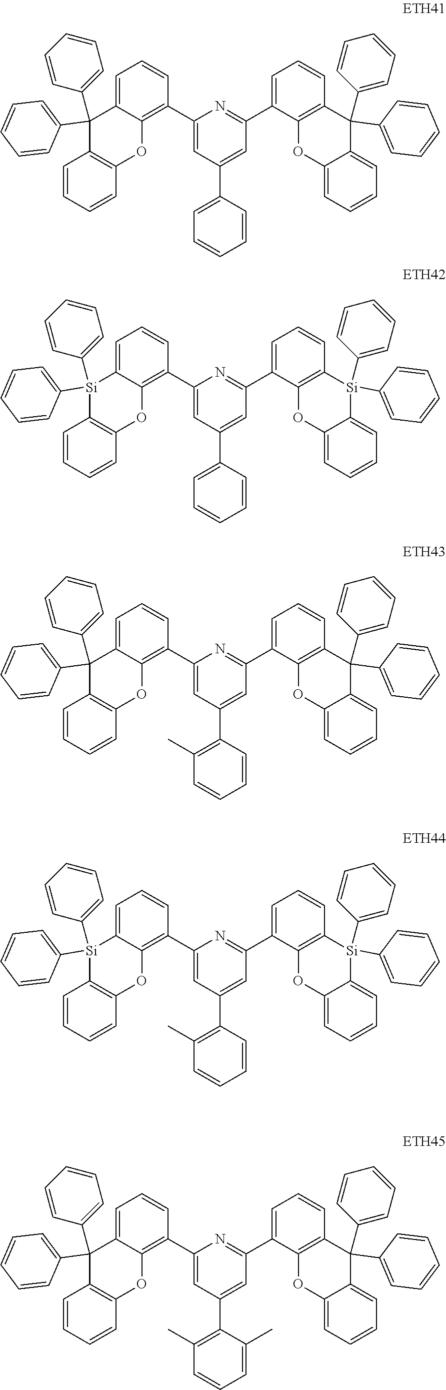

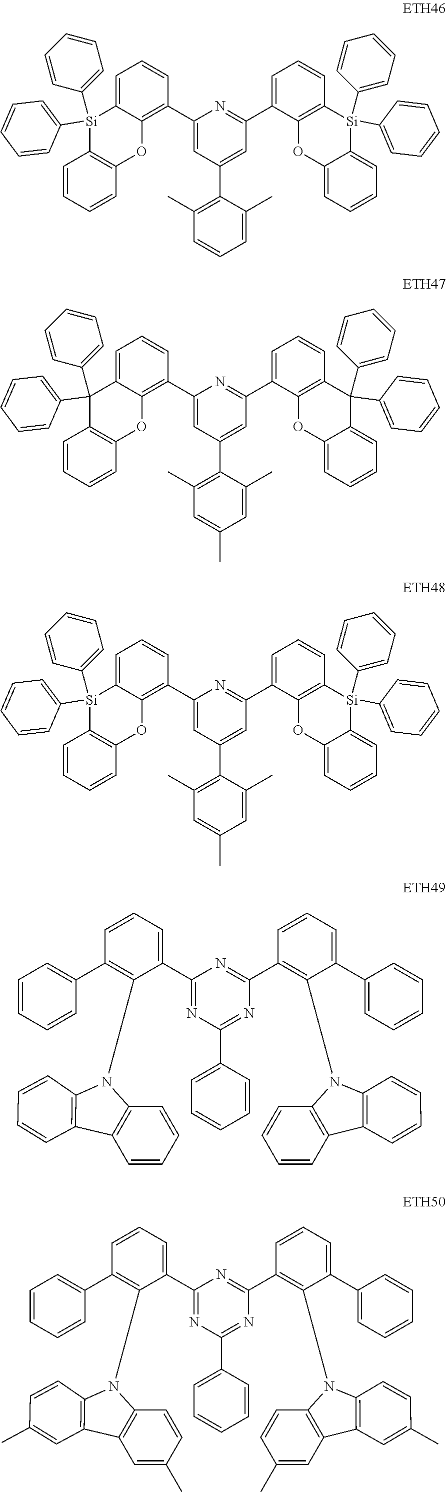

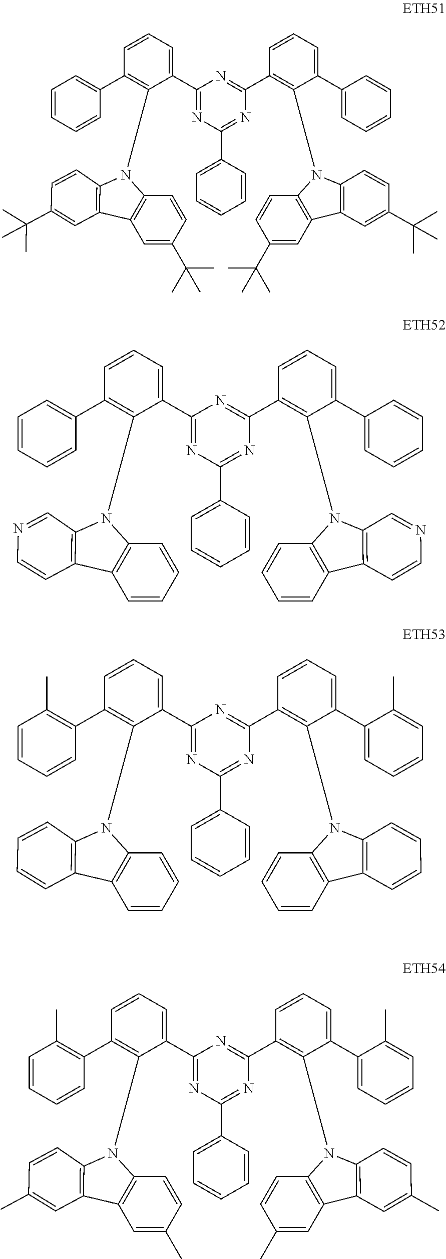

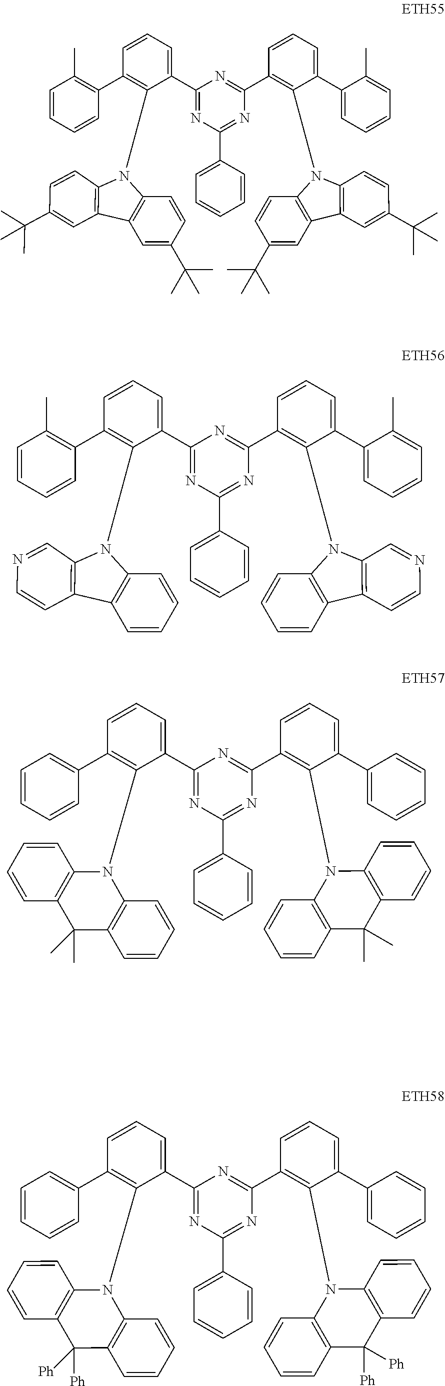

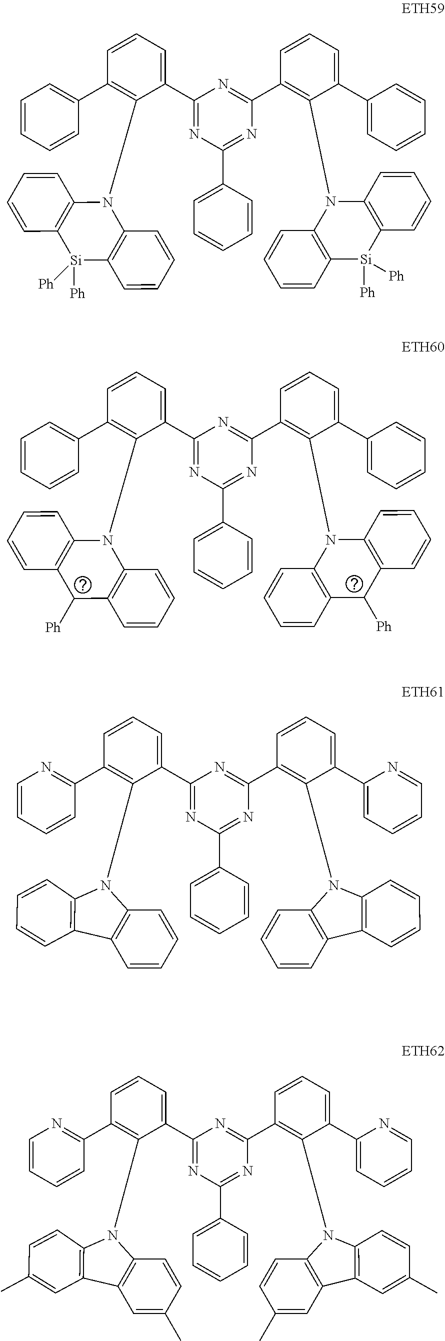

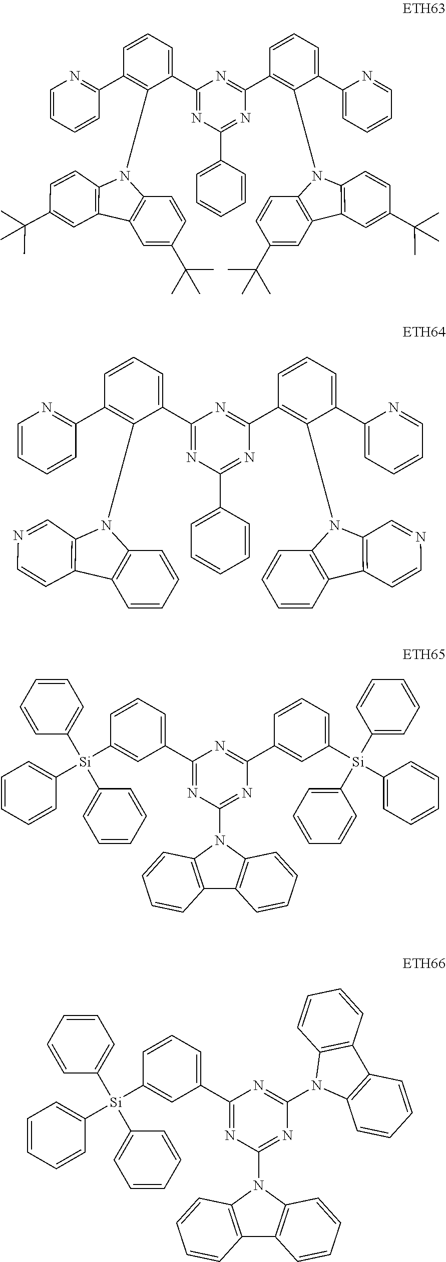 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

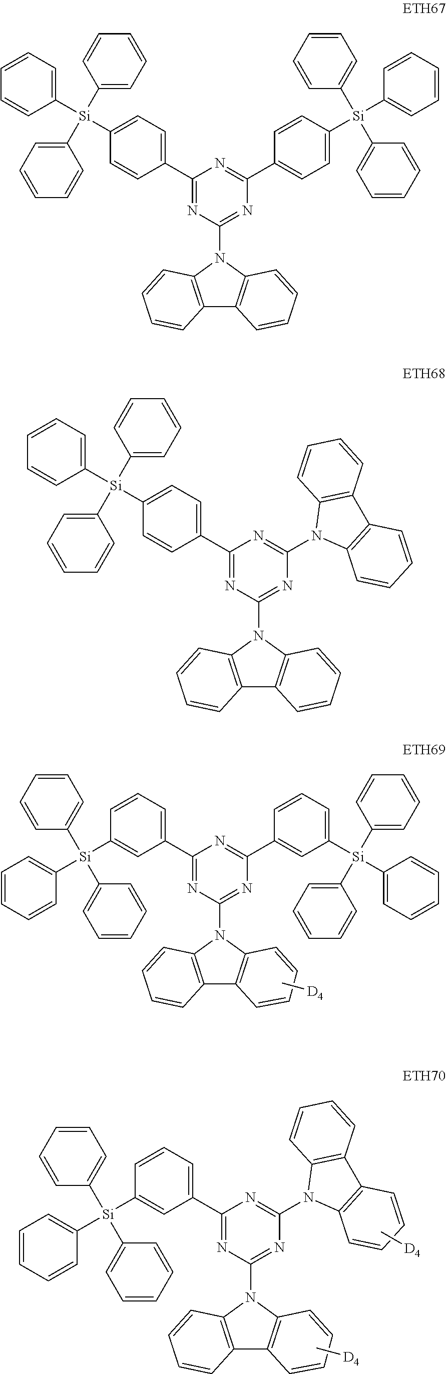

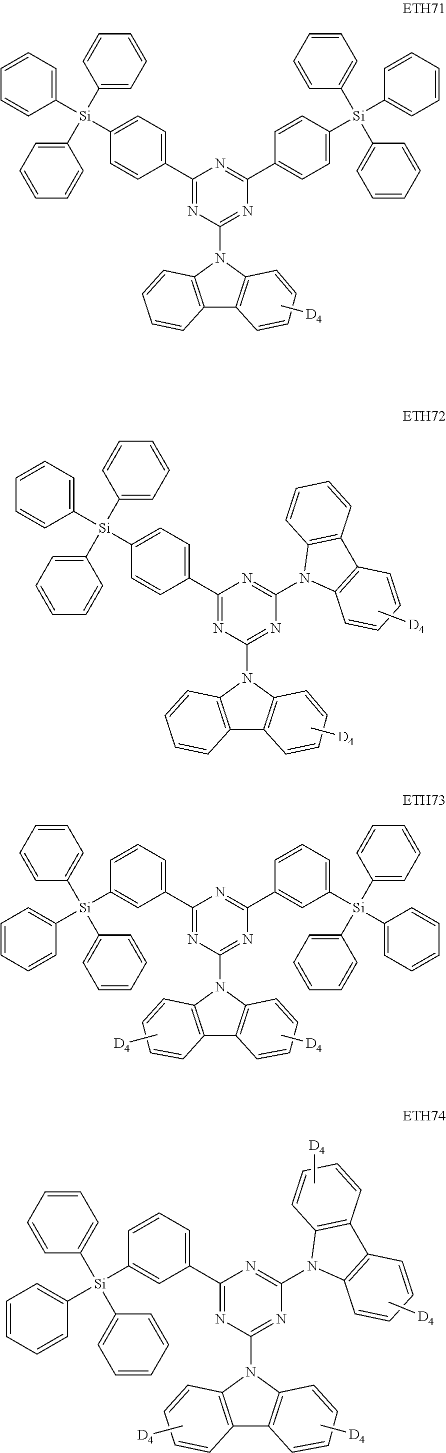

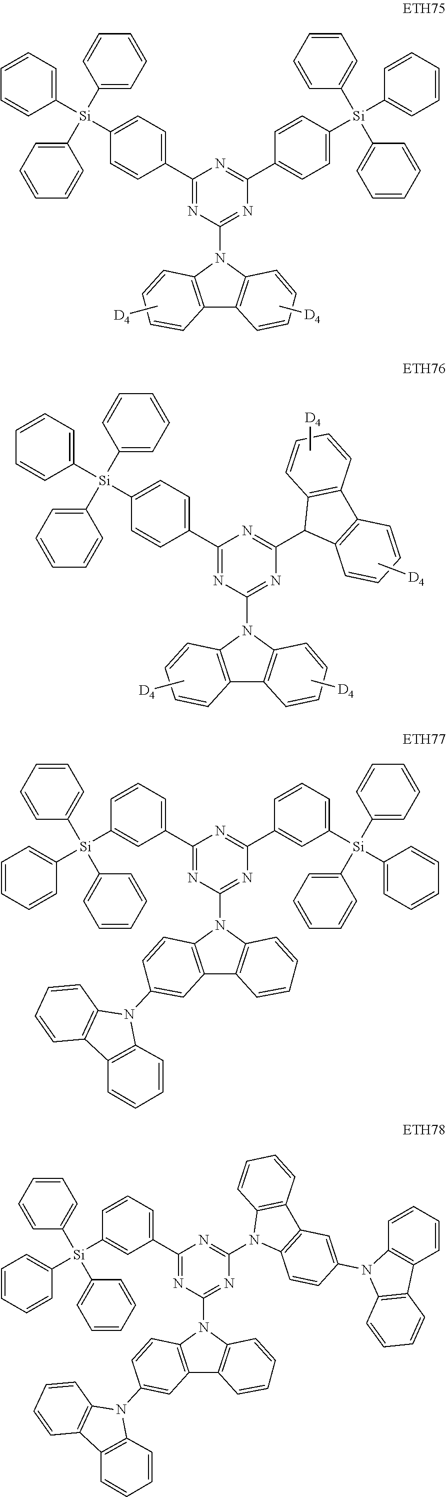

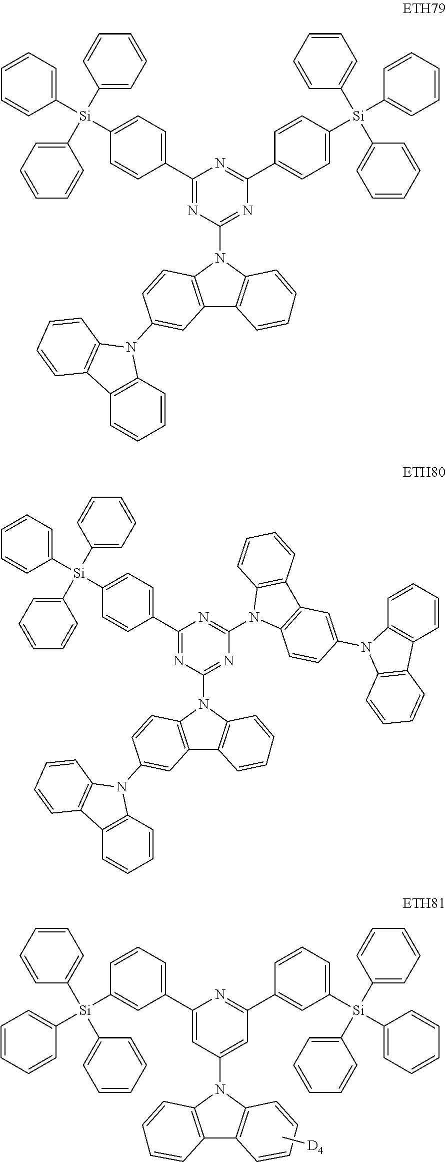

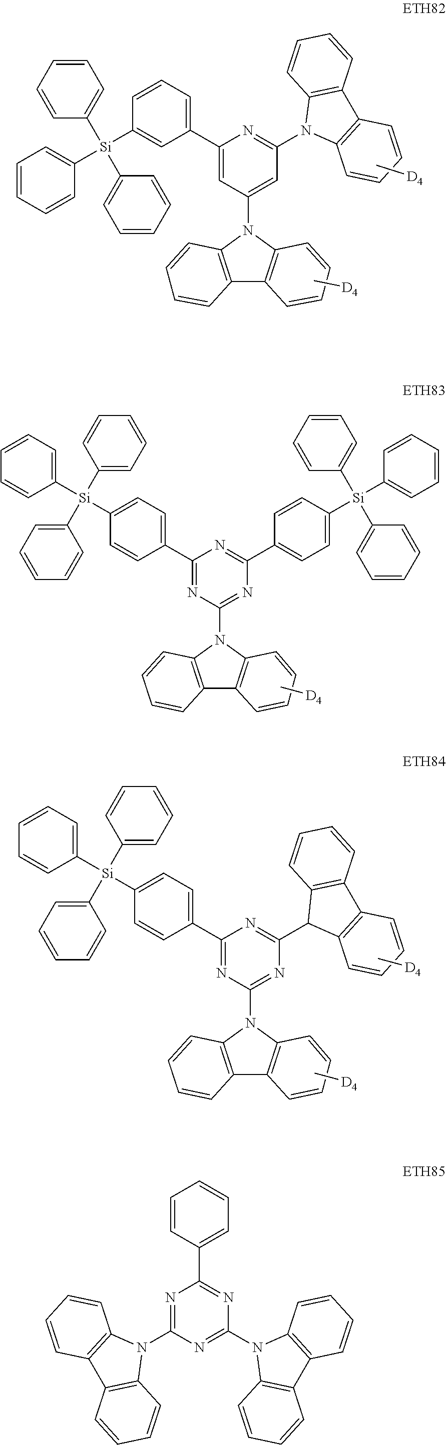

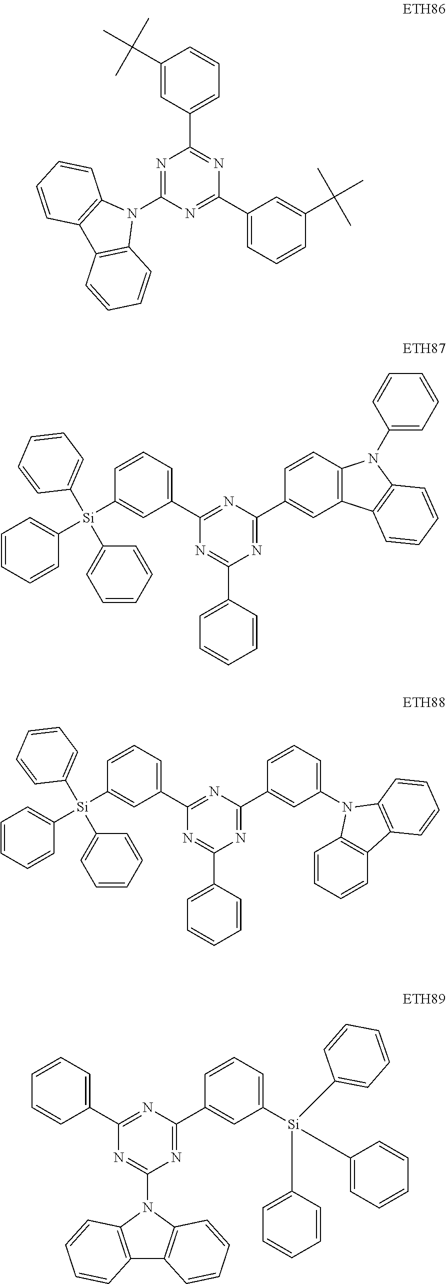 [SMILES: CC(C)(C)c1cccc(-c2nc(-c3cccc(C(C)(C)C)c3)nc(-n3c4ccccc4c4ccccc43)n2)c1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1 ; c1ccc(-c2nc(-c3cccc(-n4c5ccccc5c5ccccc54)c3)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-n3c4ccccc4c4ccccc43)n2)cc1]

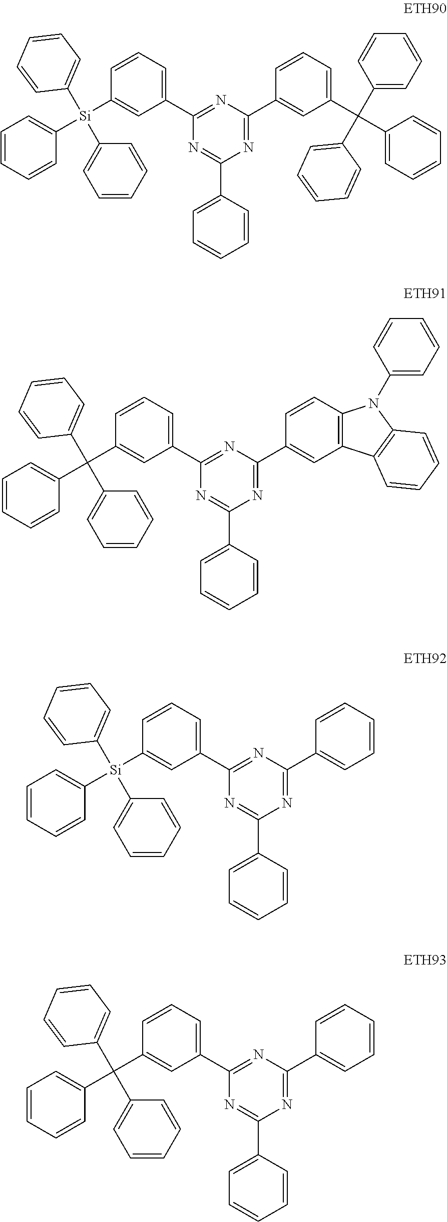 [SMILES: c1ccc(-c2nc(-c3cccc(C(c4ccccc4)(c4ccccc4)c4ccccc4)c3)nc(-c3cccc([Si](c4ccccc4)(c4ccccc4)c4ccccc4)c3)n2)cc1 ; c1ccc(-c2nc(-c3cccc(C(c4ccccc4)(c4ccccc4)c4ccccc4)c3)nc(-c3ccc4c(c3)c3ccccc3n4-c3ccccc3)n2)cc1 ; c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cccc(C(c4ccccc4)(c4ccccc4)c4ccccc4)c3)n2)cc1]

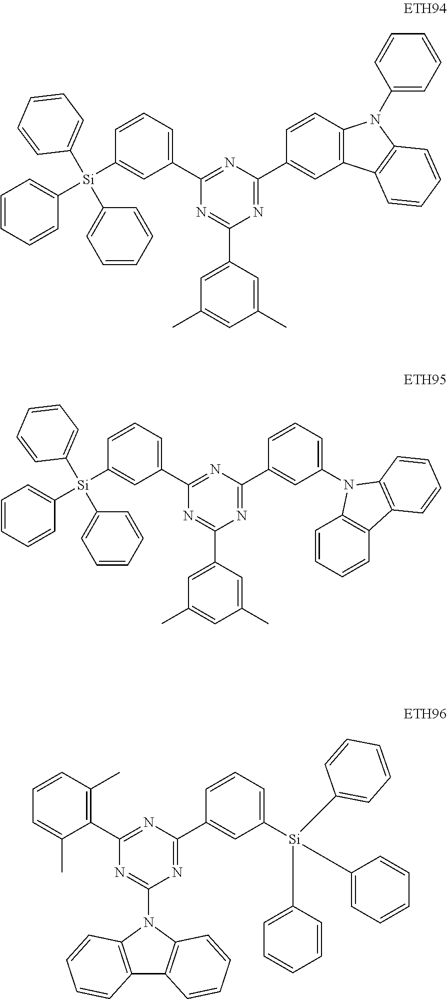 [SMILES: Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1 ; Cc1cccc(C)c1-c1nc(-c2cccc([Si](c3ccccc3)(c3ccccc3)c3ccccc3)c2)nc(-n2c3ccccc3c3ccccc32)n1]

In Compound Group 3, D represents a deuterium atom, and Ph represents an unsubstituted phenyl group.

In an embodiment, the emission layer EML may include a second compound and a third compound, and the second compound and the third compound may form an exciplex. In the emission layer EML, an exciplex may be formed by a hole transporting host and an electron transporting host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, a triplet energy level (Ti level) of the exciplex formed by the hole transporting host and the electron transporting host may have an absolute value in a range of about 2.4 eV to about 3.0 eV. The triplet energy level of the exciplex may have a value that is smaller than the energy gap of each host material. The exciplex may have a triplet energy level equal to or less than about 3.0 eV, which is an energy gap between the hole transporting host and the electron transporting host.

In an embodiment, the emission layer EML may further include a fourth compound, in addition to the first compound, the second compound, and the third compound as described above. The fourth compound may be used as a sensitizer in the emission layer EML. Energy may be transferred from the fourth compound to the first compound to emit light.

The emission layer EML may include a fourth compound that is an organometallic complex containing platinum (Pt) as a central metal atom and ligands bound to the central metal atom. In the light emitting element ED according to an embodiment, the emission layer EML may include a fourth compound represented by Formula D-1.

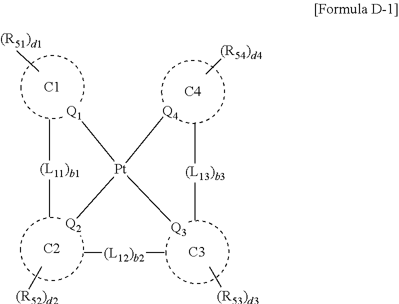

In Formula D-1, Q₁ to Q₄ may each independently be C or N.

In Formula D-1, C1 to C4 may each independently be a substituted or unsubstituted hydrocarbon ring having ring-forming 5 to 30 carbon atoms or a substituted or unsubstituted heterocycle having 2 to 30 ring-forming carbon atoms.

In Formula D-1, L₁₁ to L₁₃ may each independently be a direct linkage,

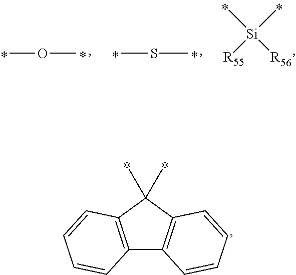

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 [symbol] ring-forming carbon atoms, wherein in L₁₁ to L₁₃, [symbol] represents a bond to one of C1 to C4.

In Formula D-1, b1 to b3 may each independently be 0 or 1. When b1 is 0, C1 and C2 may not be directly connected to each other. When b2 is 0, C2 and C3 may not be directly connected to each other. When b3 is 0, C3 and C4 may not be directly connected to each other.

In Formula D-1, R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₅₁ to R₅₆ may each independently be a substituted or unsubstituted methyl group or a substituted or unsubstituted t-butyl group.

In Formula D-1, d1 to d4 may each independently be an integer from 0 to 4. In Formula D-1, when d1 to d4 are each 0, the fourth compound may not include R₅₁ to R₅₄ as substituents. A case where d1 to d4 are each 4 and R₅₁ to R₅₄ are each a hydrogen atom, may be the same as a case where d1 to d4 are each 0. When d1 to d4 are each 2 or greater, multiple groups of each of R₅₁ to R₅₄ may all be the same, or at least one group thereof may be different from the remainder.

In an embodiment, in Formula D-1, C1 to C4 may each independently be a substituted or unsubstituted hydrocarbon ring or a substituted or unsubstituted heterocycle that is represented by any one of Formula C-1 to Formula C-4.

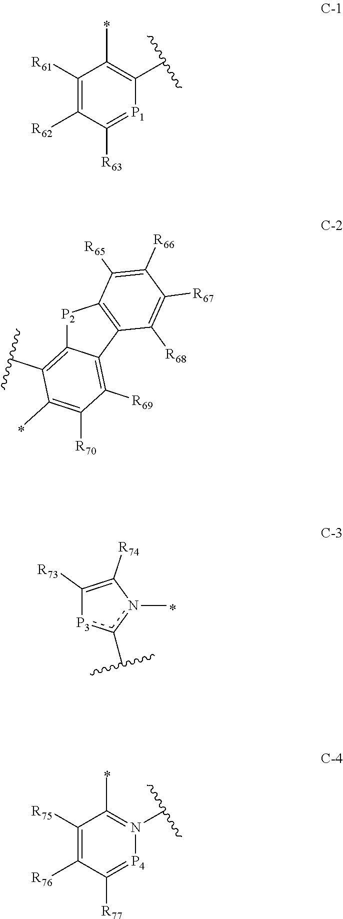

In Formula C-1 to Formula C-4, P₁ may be C—* or C(R₆₄), P₂ may be N—* or N(R₇₁), P₃ may be N—* or N(R₇₂), and P₄ may be C—* or C(R₇₈).

In Formula C-1 to Formula C-4, R₆₁ to R₇₈ may each independently be a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

In Formula C-1 to Formula C-4, [symbol] represents a bond to the central metal atom, which is Pt, and [symbol] represents a bond to a neighboring ring group (C1 to C4) or to a linker (L₁₁ to L₁₃).

In an embodiment, the fourth compound represented by Formula D-1 may be selected from Compound Group 4. In an embodiment, in the light emitting element ED, the fourth compound may include at least one compound selected from Compound Group 4.

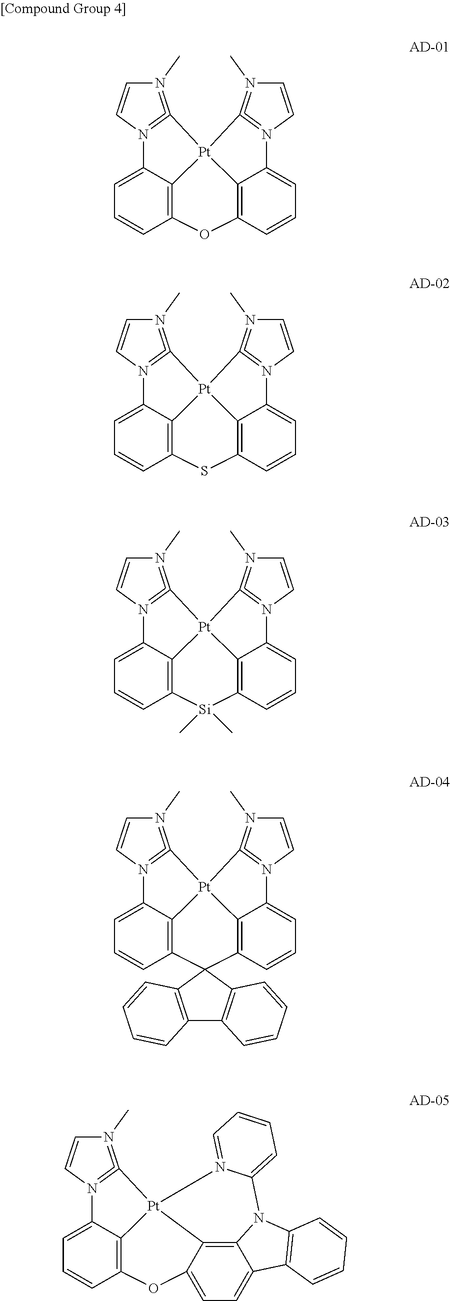

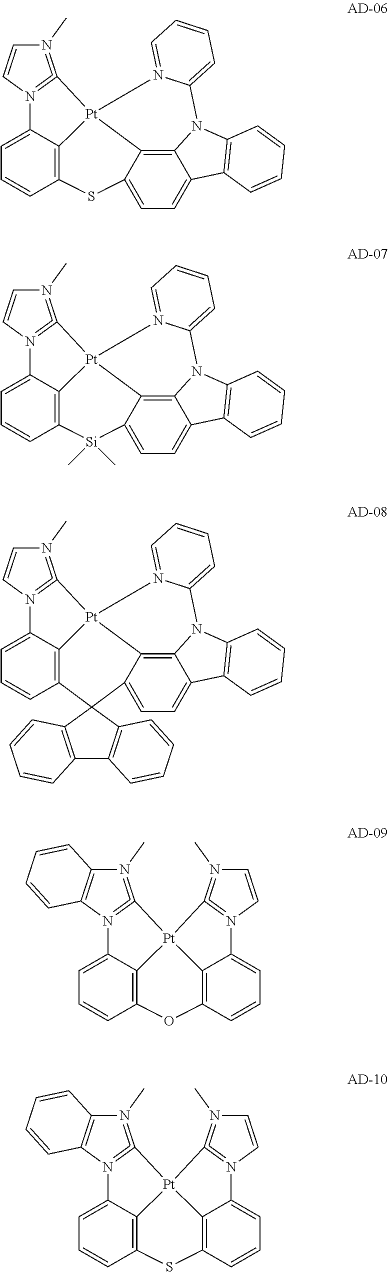

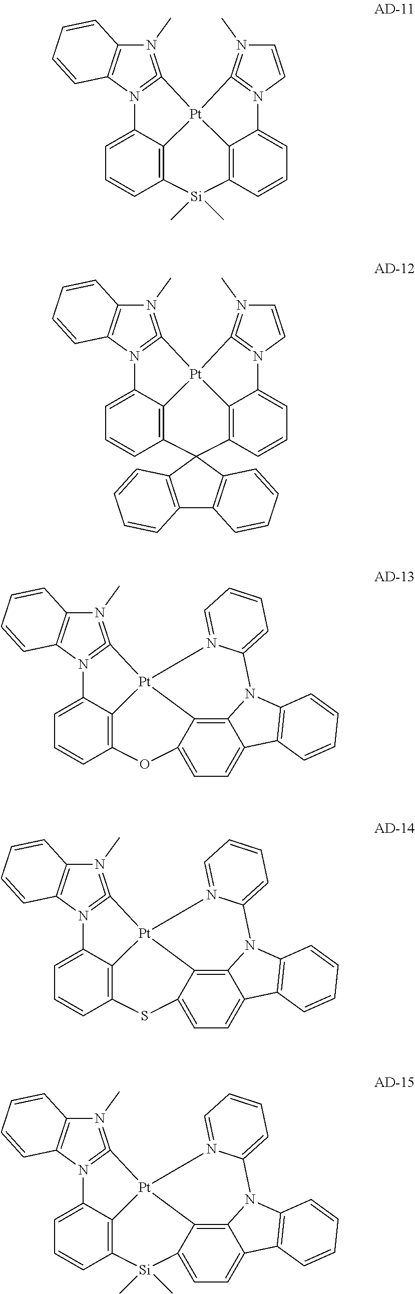

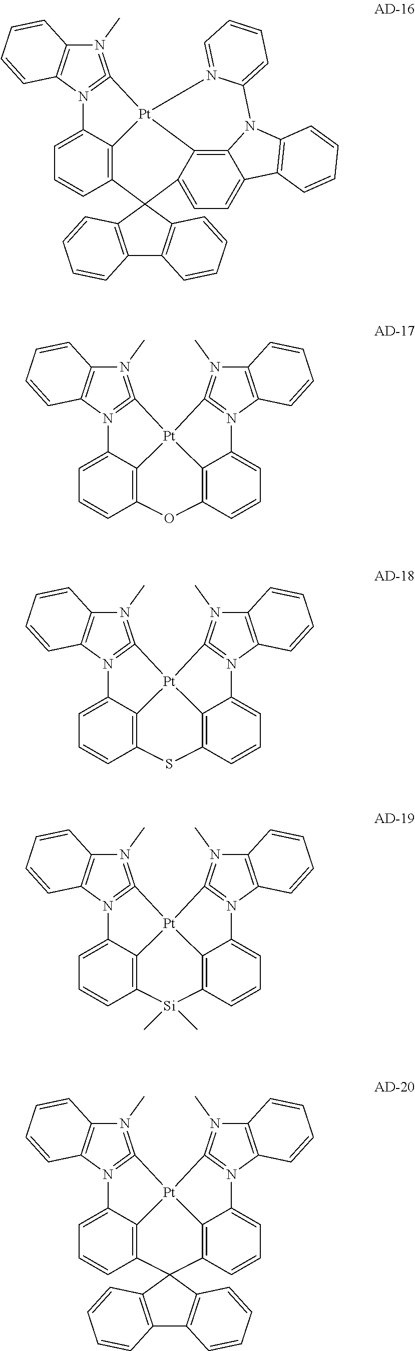

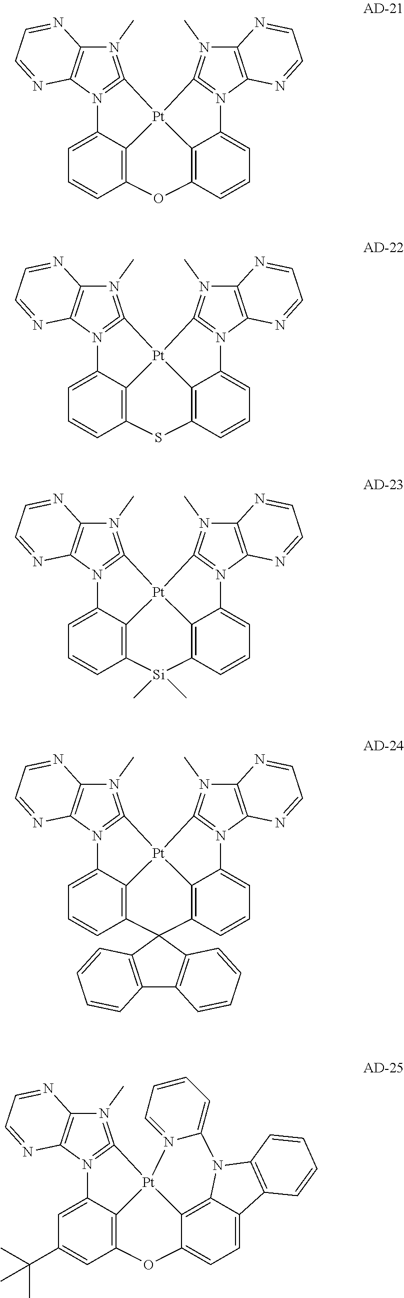

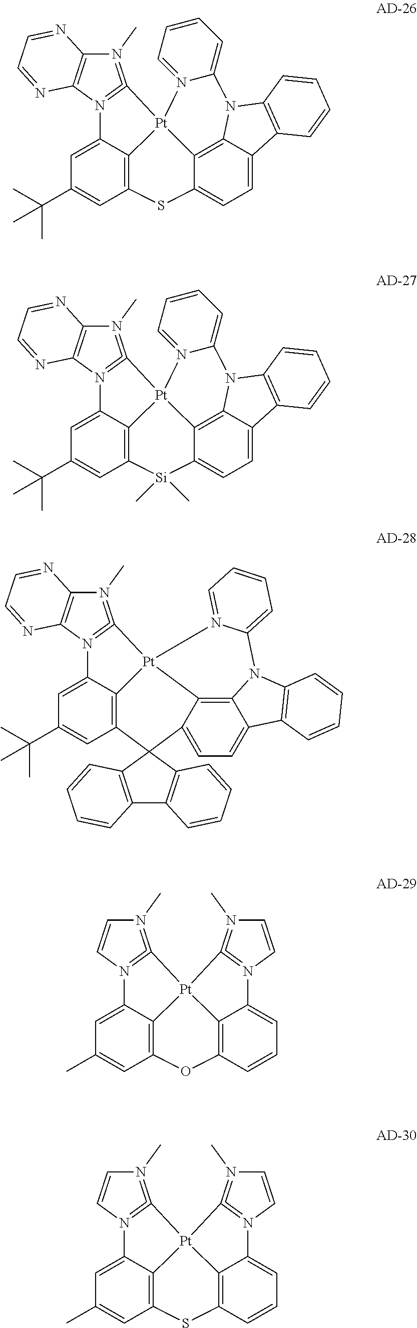

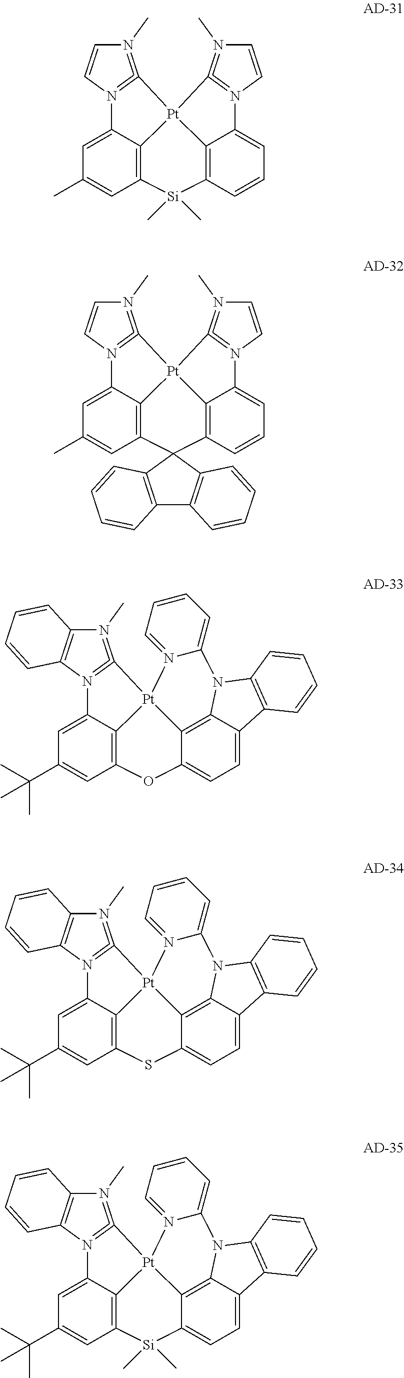

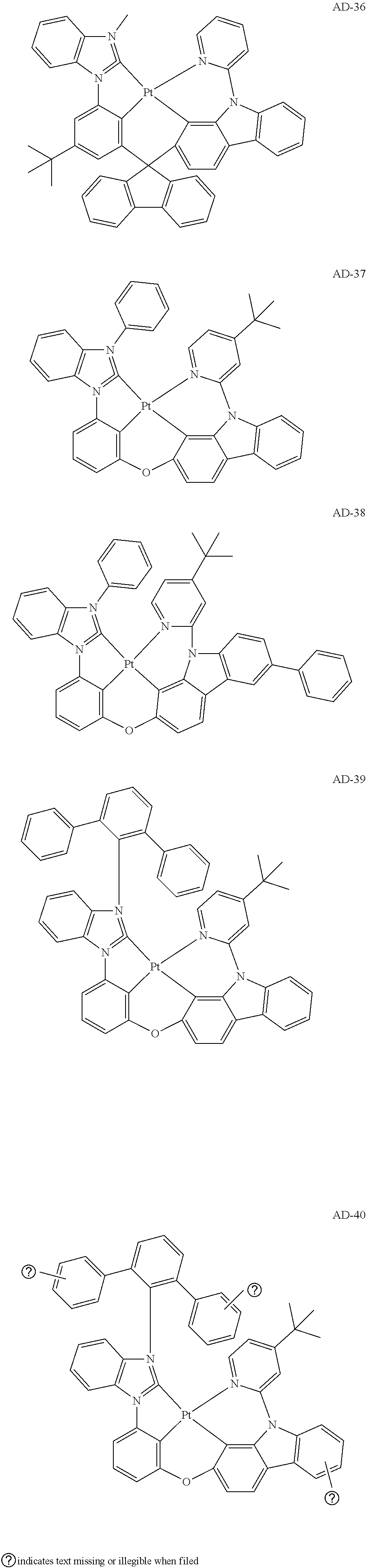

In Compound Group 4, D represents a deuterium atom.

In an embodiment, the emission layer EML may include the first compound represented by Formula 1, and at least one of the second compound, the third compound, and the fourth compound. For example, the emission layer EML may include the first compound, the second compound, and the third compound. In the emission layer EML, the second compound and the third compound may form an exciplex, and energy may be transferred from the exciplex to the first compound to emit light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound to emit light. In an embodiment, the fourth compound may be a sensitizer. In the light emitting element ED, the fourth compound included in the emission layer EML may serve as a sensitizer to transfer energy from a host to the first compound, which is a light emitting dopant. For example, the fourth compound, which serves as an auxiliary dopant, may accelerate energy transfer to the first compound, which serves as a light emitting dopant, thereby increasing an emission ratio of the first compound. Accordingly, the emission layer EML may have increased light emitting efficiency. When energy transfer to the first compound increases, excitons formed in the emission layer EML may not accumulate in the emission layer EML and may emit light rapidly, thereby reducing deterioration of a light emitting element ED. Accordingly, the light emitting element ED may have increased service life.

The light emitting element ED may include a first compound, a second compound, a third compound, and a fourth compound, and the emission layer EML may thus include a combination of two host materials and two dopant materials. In the light emitting element ED, the emission layer EML includes the second compound and the third compound that are two different hosts, the first compound which emits delayed fluorescence, and the fourth compound which includes an organometallic complex, and thus, the light emitting element ED may exhibit excellent light emitting efficiency.

In an embodiment, the light emitting element ED may include multiple emission layers. The emission layers may be provided as a stack of emission layers, so that the light emitting element ED including multiple emission layers may emit white light. The light emitting element ED including multiple emission layers may be a light emitting element having a tandem structure. When the light emitting element ED includes multiple emission layers, at least one emission layer EML may include the first compound represented by Formula 1. In an embodiment, when the light emitting element ED includes multiple emission layers, at least one emission layer EML may include the first compound, the second compound, the third compound, and the fourth compound as described above.

The emission layer EML may further include a host of the related art and a dopant of the related art, in addition to the polycyclic compound described above and the second to fourth compounds. In an embodiment, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In an embodiment, the emission layer EML may include a compound represented by Formula E-1. The compound represented by Formula E-1 may be used as a fluorescent host material.

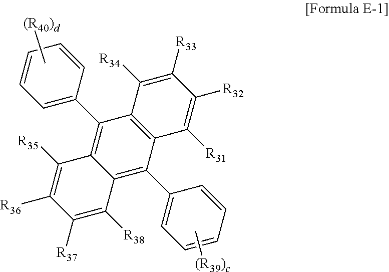

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19.

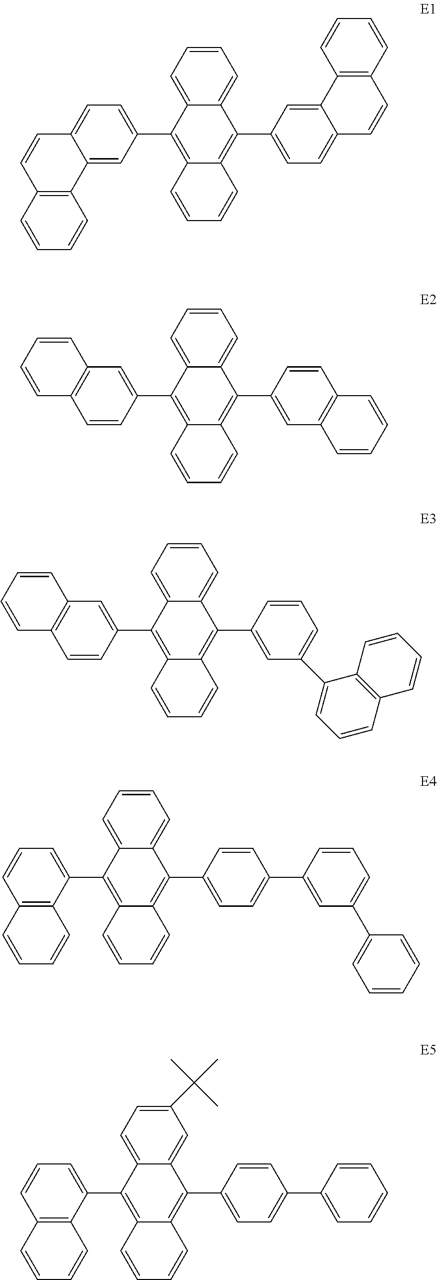

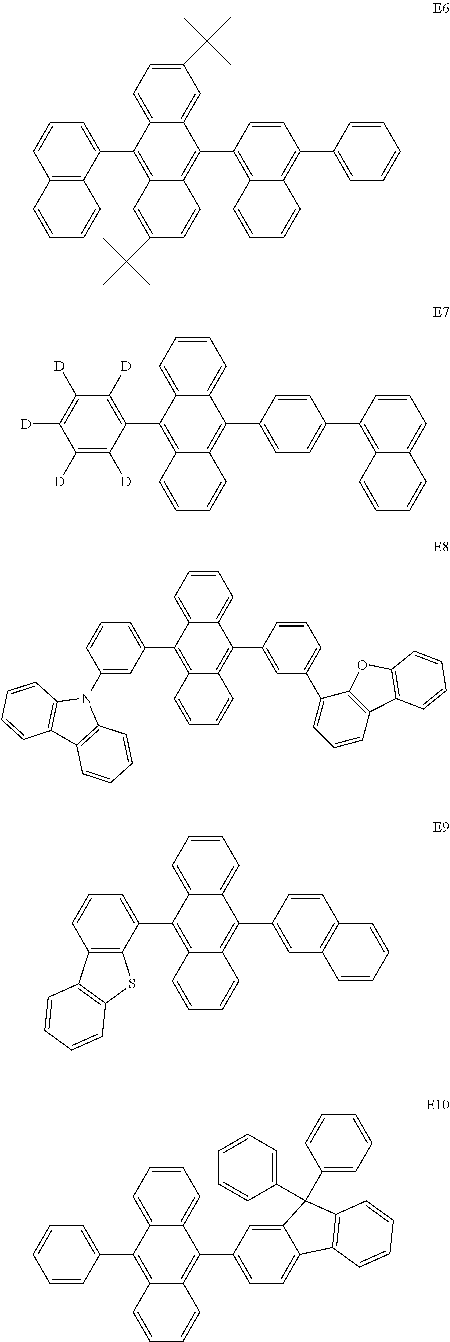

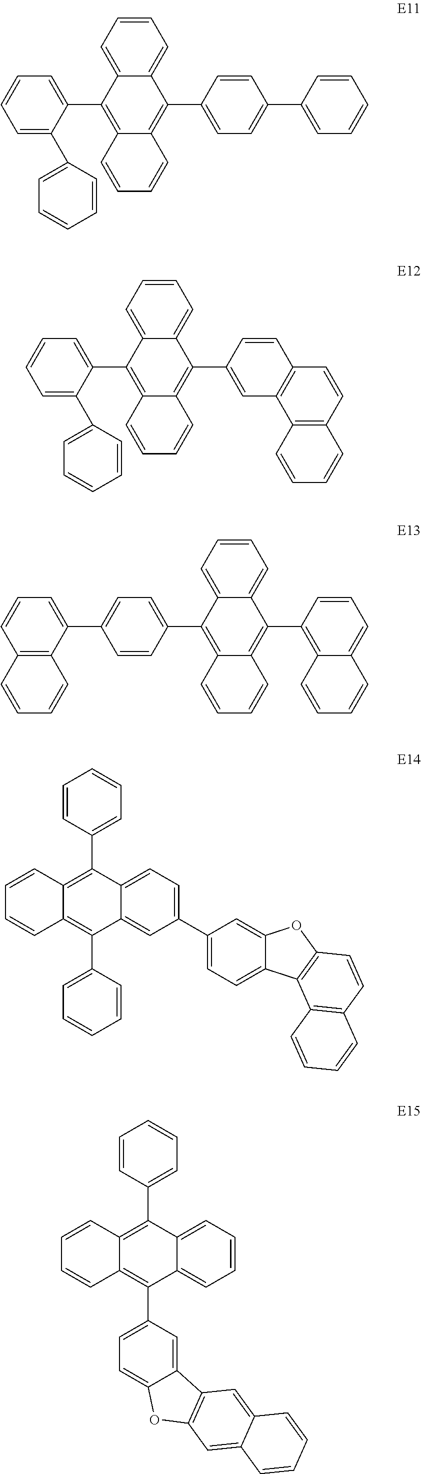

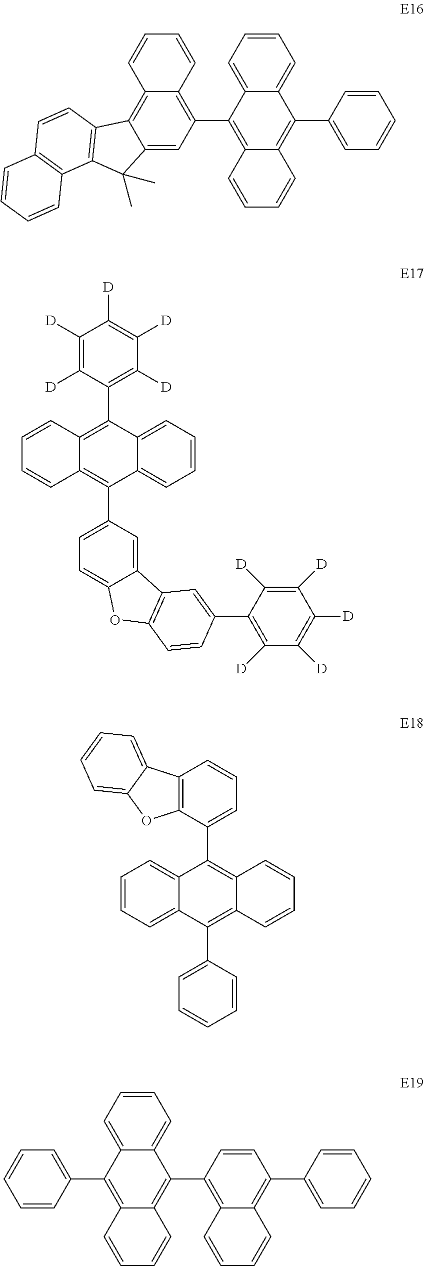

In an embodiment, the emission layer EML may include a first compound represented by Formula 1, and at least one of a second compound represented by Formula HT-1, a third compound represented by Formula ET-1, and a fourth compound represented by Formula D-1, which will be explained below.

In an embodiment, the emission layer EML may include a compound represented by Formula E-2a or Formula E-2b. The compound represented by Formula E-2a or Formula E-2b may be used as a phosphorescent host material.

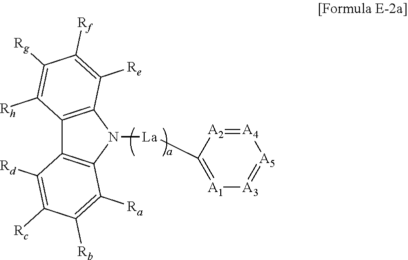

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple La groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, and the like as a ring-forming atom.

In Formula E-2a, two or three of A₁ to A₅ may each be N, and the remainder of A₁ to A₅ may each independently be C(Rᵢ).

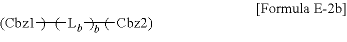

In Formula E-2b, Cbz1 and Cbz2 may each independently be an unsubstituted carbazole group or a carbazole group substituted with an aryl group having 6 to 30 ring-forming carbon atoms. In Formula E-2b, Le may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or greater, multiple Le groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

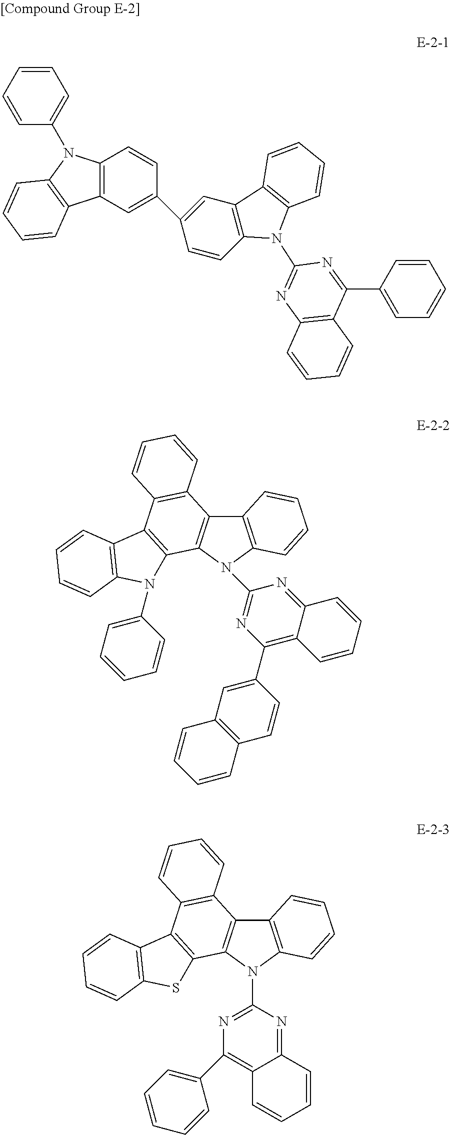 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

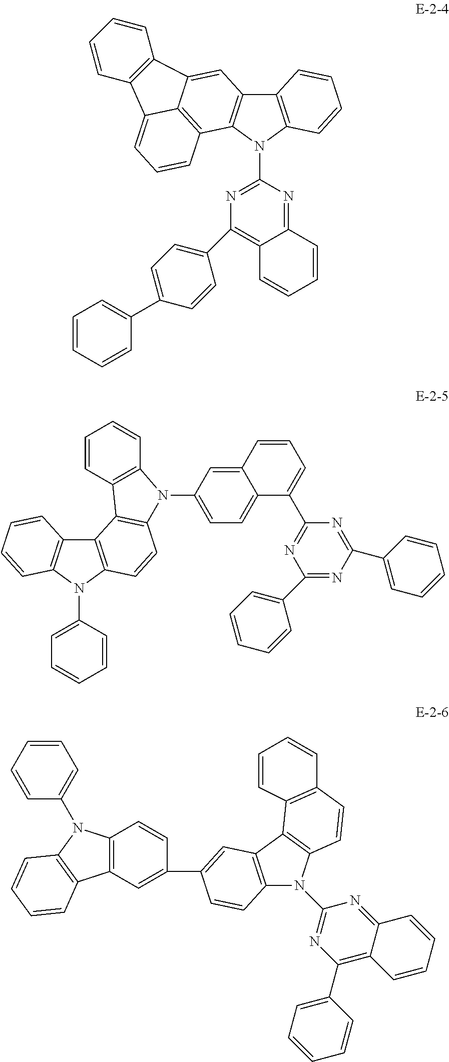 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

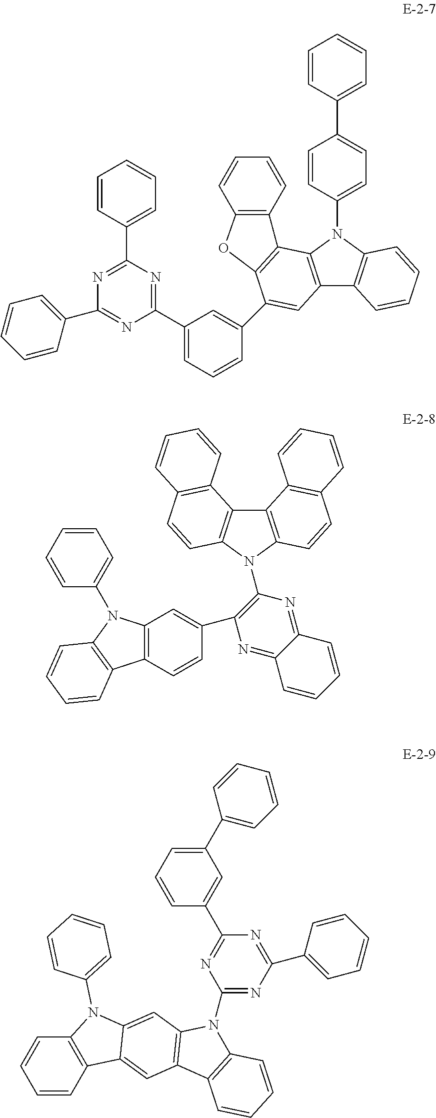 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

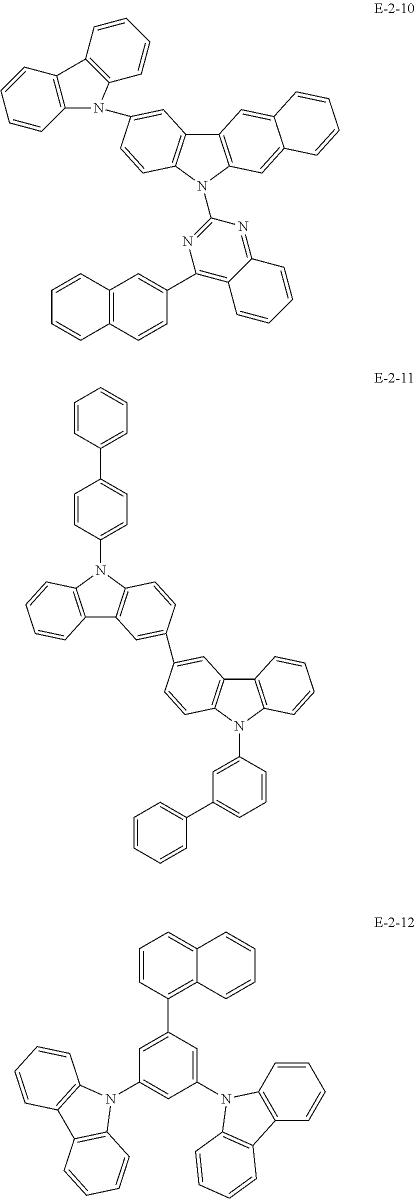 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

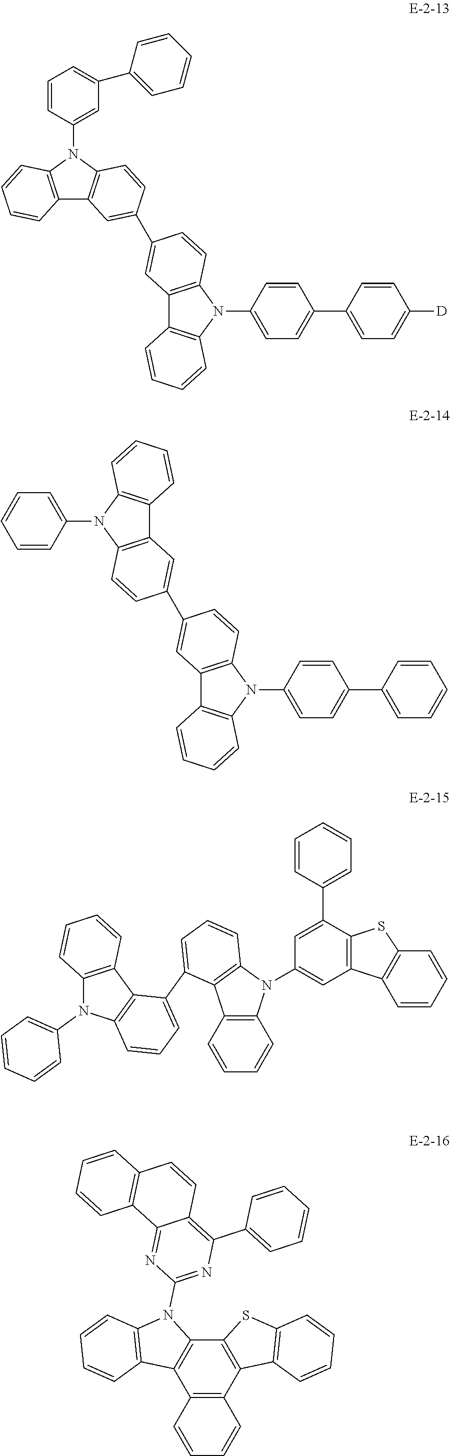

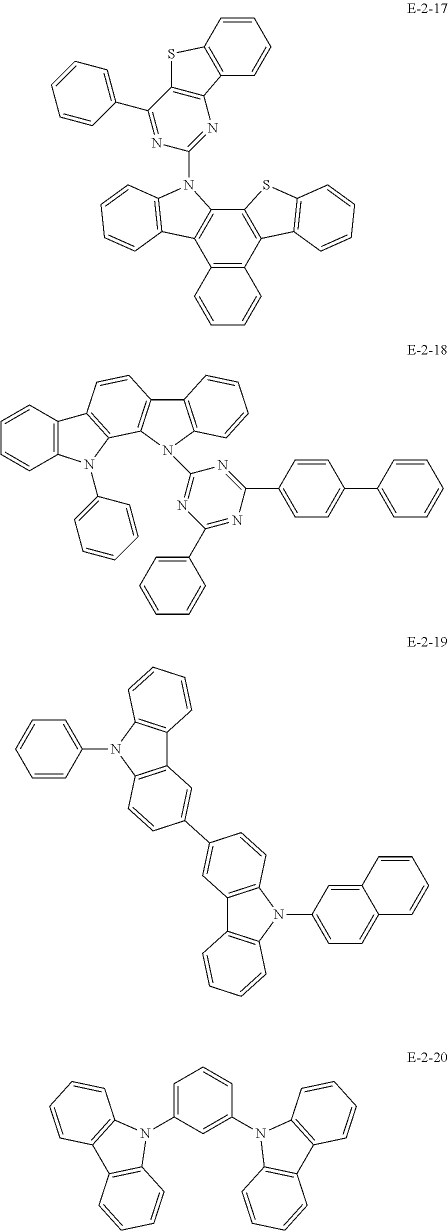 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

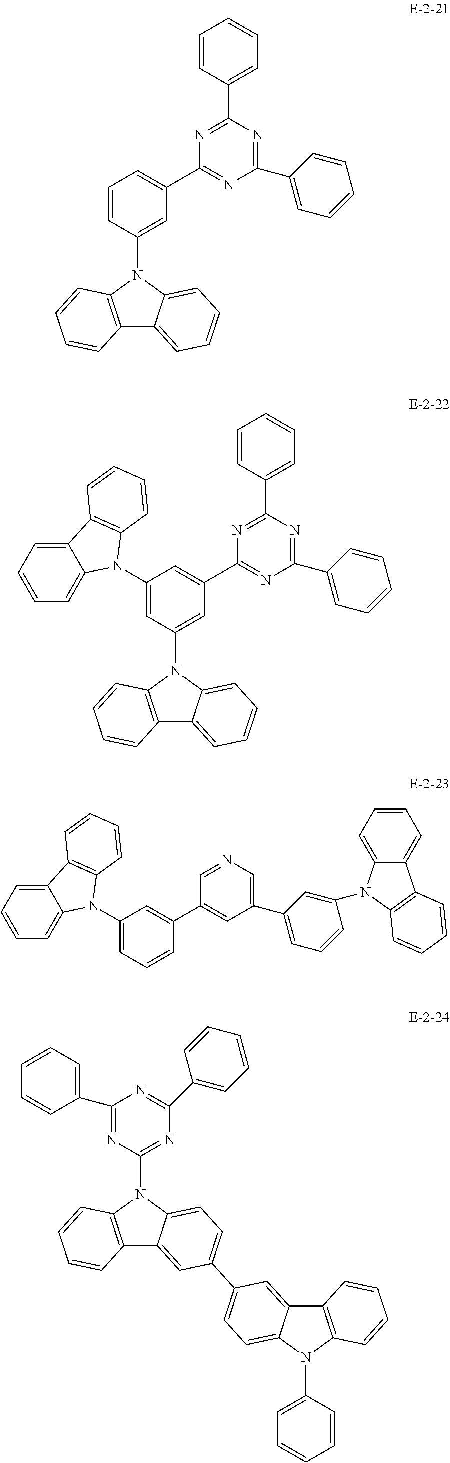 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, embodiments are not limited thereto. For example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and the like may be used as a host material.

The emission layer EML may include a compound represented by Formula M-a or Formula M-b. The compound represented by Formula M-a or Formula M-b may be used as a phosphorescent dopant material.

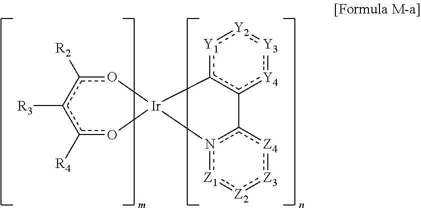

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be used as a phosphorescent dopant.

The compound represented by Formula M-a may be any compound selected from Compound M-a1 to Compound M-a25. However, Compound M-a1 to Compound M-a25 are only examples, and the compound represented by Formula M-a is not limited to Compound M-a1 to Compound M-a25.

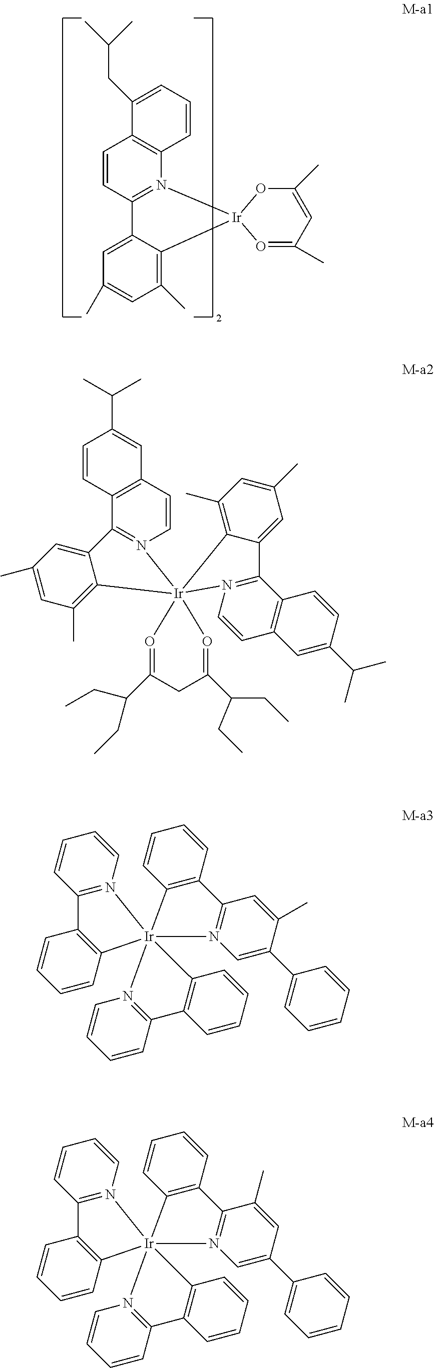

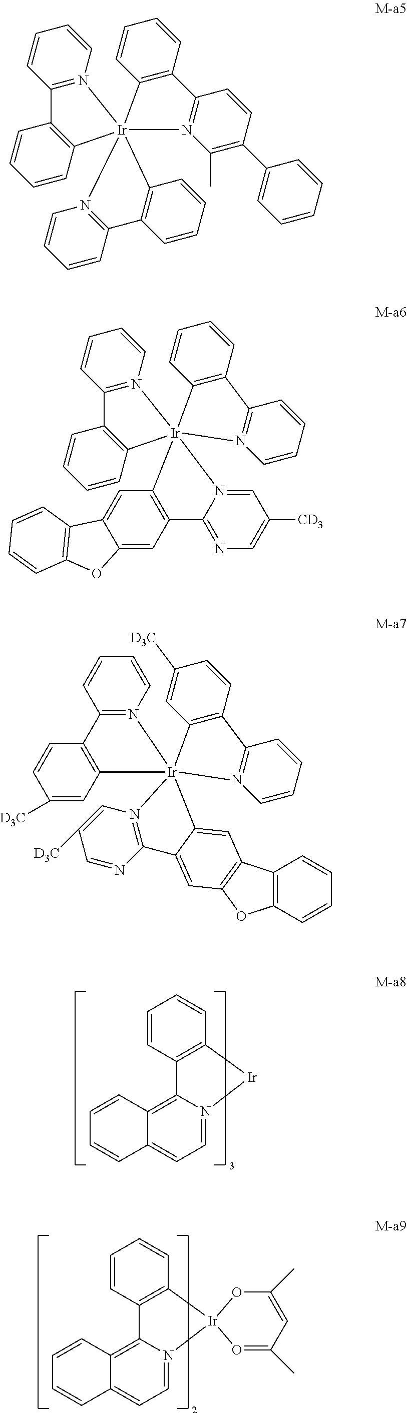

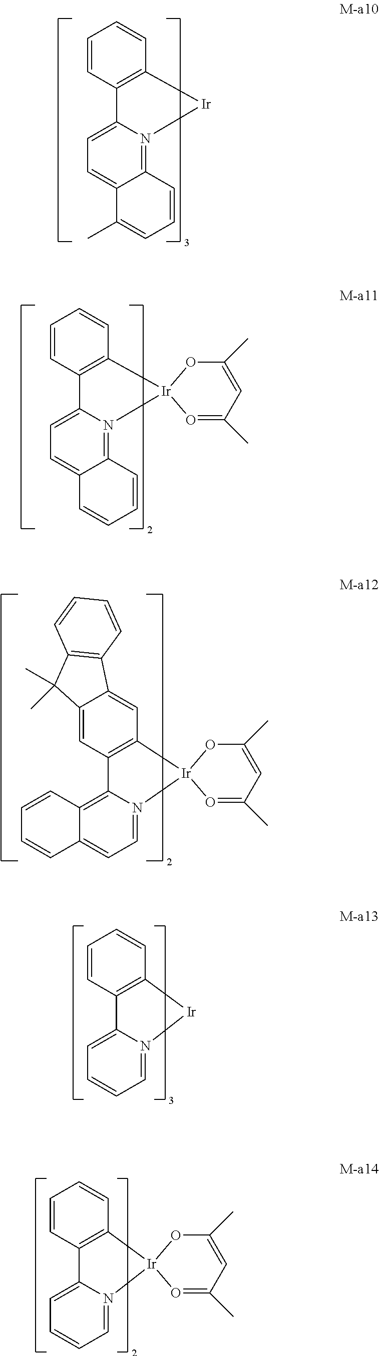

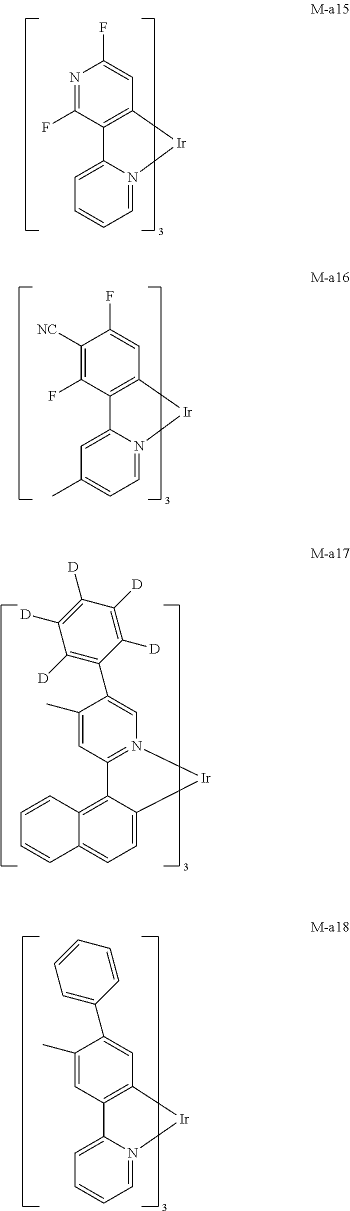

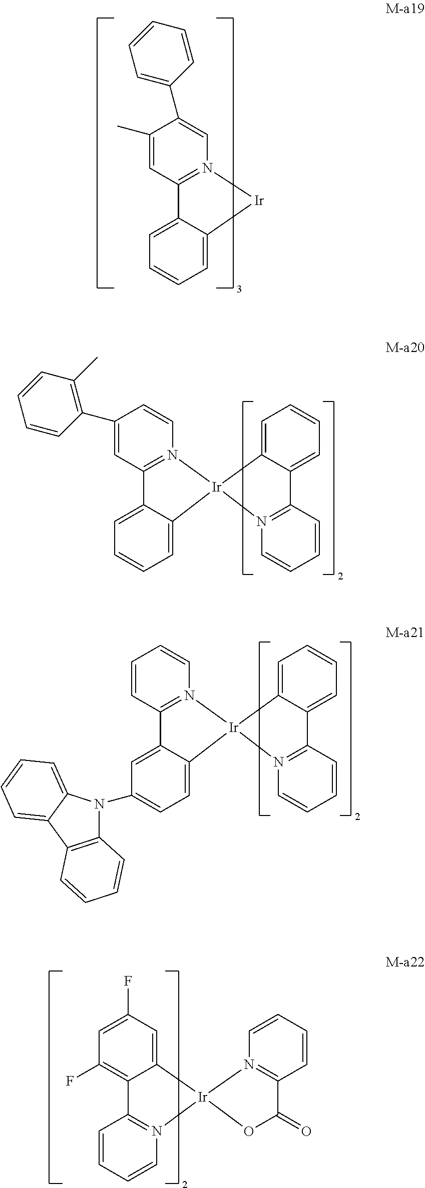

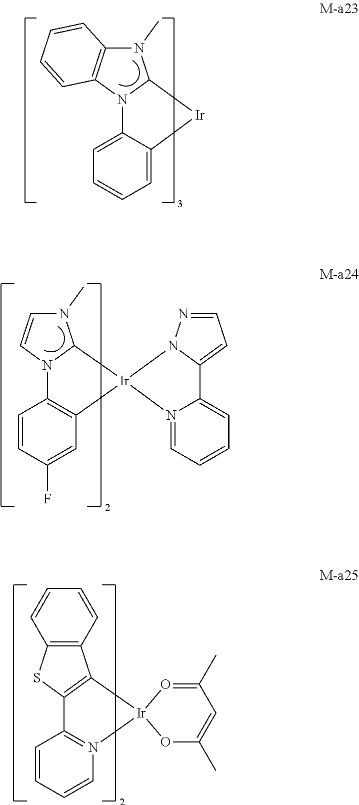

Compound M-a1 and Compound M-a2 may be used as a red dopant material, and Compound M-a3 to Compound M-a7 may be used as a green dopant material.

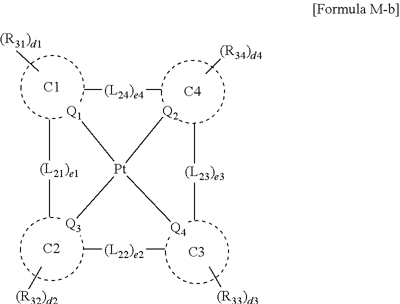

In Formula M-b, Q₁ to Q₄ may each independently be C or N; and C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula M-b, L₂₁ to L₂₄ may each independently be a direct linkage,

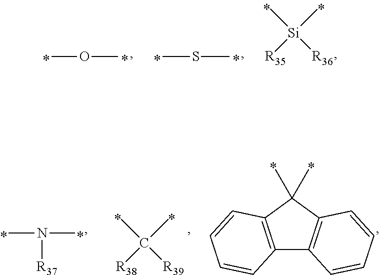

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, wherein in L₂₁ to L₂₄, [symbol] represents a bond linked to one of C1 to C4; and e1 to e4 may each independently be 0 or 1.

In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring; and d1 to d4 may each independently be an integer from 0 to 4.

The compound represented by Formula M-b may be used as a blue phosphorescent dopant or as a green phosphorescent dopant.

The compound represented by Formula M-b may be any compound selected from Compound M-b-1 to Compound M-b-11. However, Compound M-b-1 to Compound M-b-11 are only examples, and the compound represented by Formula M-b is not limited to Compound M-b-1 to Compound M-b-11.

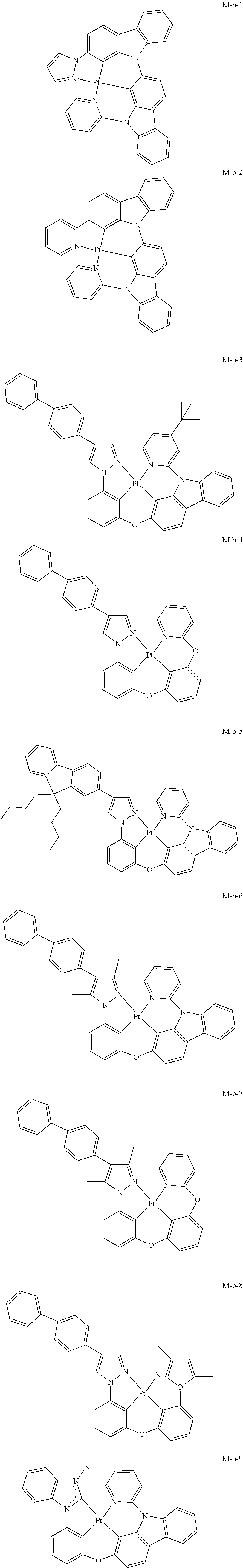

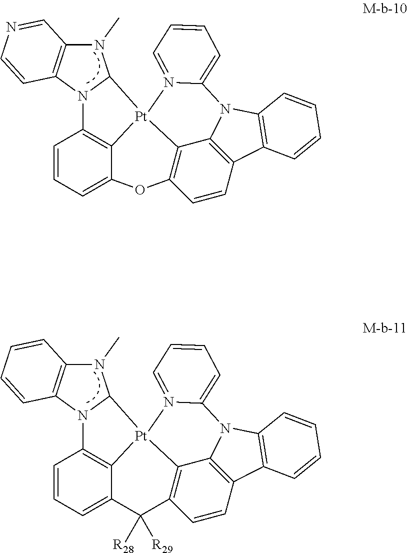

In Compound M-b-1 to Compound M-b-11, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by any one of Formulas F-a to F-c. The compound represented by one of Formulas F-a to F-c may be used as a fluorescence dopant material.

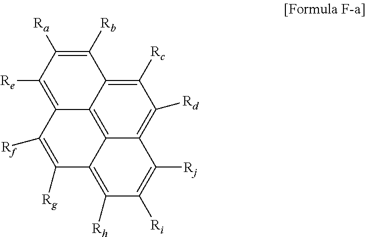

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may each independently be a heteroaryl group containing O or S as a ring-forming atom.

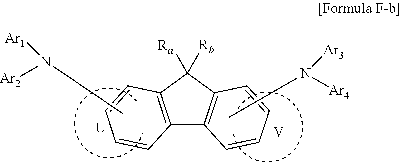

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be respectively present at a portion indicated by U or V. When the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

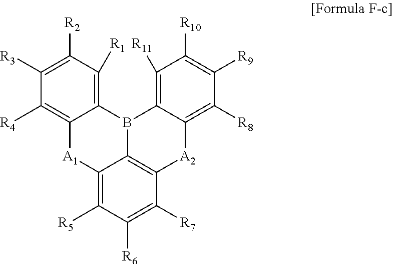

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to a substituent of a neighboring ring to form a fused ring. For example, when A₁ and A₂ are each independently N(Rₘ), A₁ may be bonded to R₄ or R₅ to form a ring. For example, A₂ may be bonded to R₇ or R₈ to form a ring.

The emission layer EML may include, as a dopant material of the related art, styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and the like.

The emission layer EML may include a phosphorescent dopant material of the related art. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′) picolate (FIrpic), bis(2,4-difluorophenylpyridinato)-tetrakis(1-pyrazolyl)borate iridium(III) (FIr6), platinum octaethyl porphyrin (PtOEP), and the like may be used as a phosphorescent dopant. However, embodiments are not limited thereto.

The emission layer EML may include a quantum dot material. In the specification, a quantum dot may be a crystal of a semiconductor compound. The quantum dot may emit light of various emission wavelengths depending on a size of the crystal. The quantum dot may emit light of various emission wavelengths by adjusting a ratio of elements in the quantum dot material.

The quantum dot may have a diameter in a range of about 1 nm to about 10 nm.

The quantum dot may be synthesized through a wet chemical process, a metal organic chemical vapor deposition (MOCVD) process, a molecular beam epitaxy (MBE) process, or a process similar thereto.

The wet chemical process is a method of mixing an organic solvent and a precursor material and then growing a quantum dot particle crystal. When the crystal grows, the organic solvent naturally serves as a dispersant coordinated to a surface of the quantum dot crystal and may control the growth of the crystal. Therefore, the wet chemical process may be more readily performed than vapor deposition methods such as metal organic chemical vapor deposition or molecular beam epitaxy, and may control the growth of quantum dot particles through a low-cost process.

The quantum dot may be a Group II-VI compound, a Group III-VI compound, a Group 1-III-VI compound, a Group III-V compound, a Group III-II-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof.

Examples of a Group III-VI compound may include: a binary compound such as In₂S₂ and In₂Se₃; a ternary compound such as InGaS₃ and InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, or a mixture thereof; a quaternary compound such as AgInGaS₂ and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II element. For example, InZnP or the like may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof.

Examples of a Group IV element may include Si, Ge, or a mixture thereof. Examples of a Group IV compound may include a binary compound selected from the group consisting of SiC, SiGe, and a mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which a quantum dot surrounds another quantum dot. A quantum dot having a core/shell structure may have a concentration gradient in which the concentration of a material that is present in the shell decreases towards the core.

In embodiments, a quantum dot may have a core/shell structure that includes a core having nano-crystals and a shell surrounding the core, as described herein. The shell of the quantum dot may serve as a protection layer to prevent the chemical deformation of the core so as to keep semiconductor properties, and/or may serve as a charging layer to impart electrophoresis properties to the quantum dot. The shell may be a single layer or multiple layers. Examples of a shell of the quantum dot may include a metal oxide, a non-metal oxide, a semiconductor compound, or a combination thereof.

Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited, and may be any form used in the related art. For example, a quantum dot may have a spherical shape, a pyramidal shape, a multi-arm shape, or a cubic shape, or a quantum dot may be the form of nanoparticles, nanotubes, nanowires, nanofibers, nanoplatelets, or the like.

As a size of the quantum dot or a ratio of elements in the quantum dot compound is adjusted, an energy band gap may be accordingly controlled to obtain light of various wavelengths from a quantum dot emission layer. Therefore, by using quantum dots of different sizes or having different elemental ratios, a light emitting element that emits light of various wavelengths may be implemented. For example, the size of the quantum dots or the ratio of elements in the quantum dot may be adjusted to emit red light, green light, and/or blue light. In an embodiment, the quantum dots may be configured to emit white light by combining light of various colors.

In the light emitting element ED according to an embodiment as shown in each of FIGS. 3 to 6, an electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from an emission layer EML, but embodiments are not limited thereto. The electron transport region ETR may have a thickness in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2.

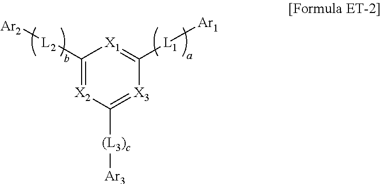

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or greater, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36.

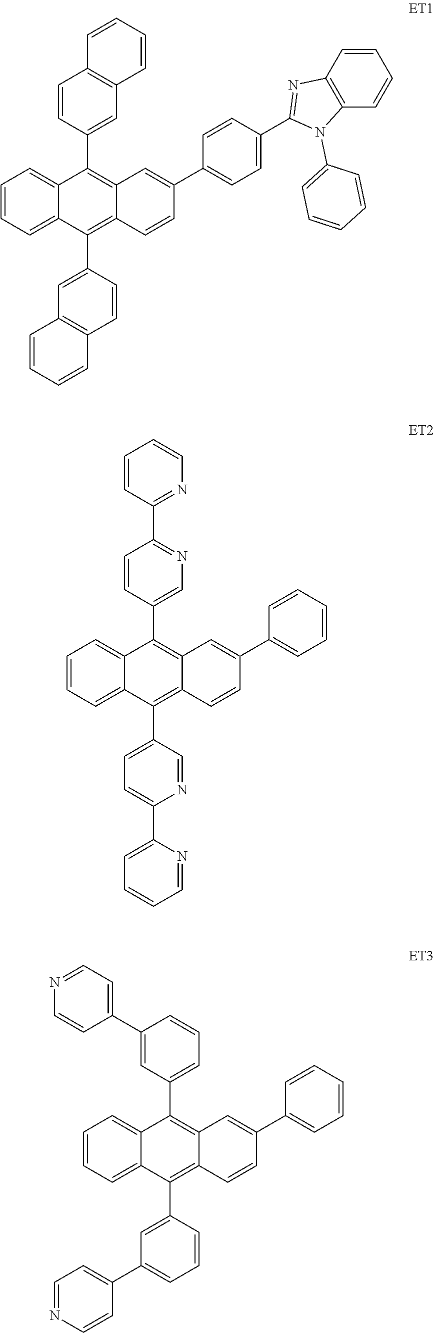 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

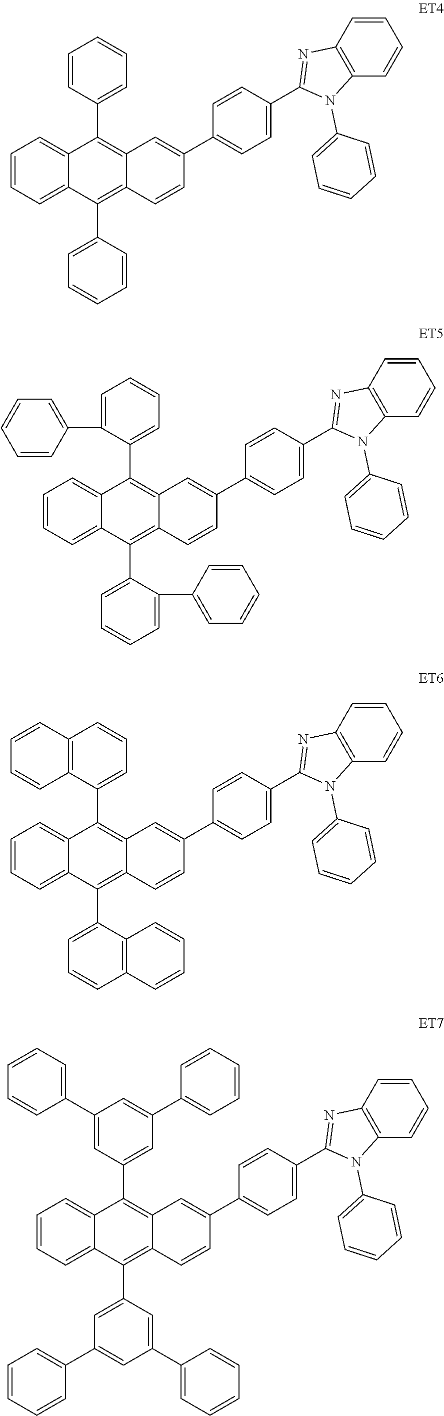 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

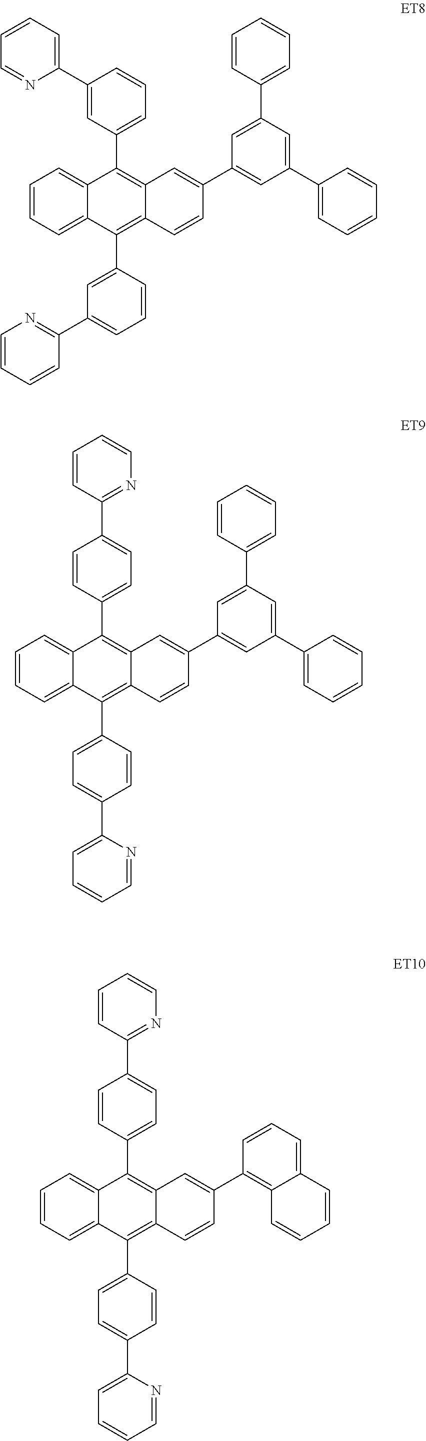 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

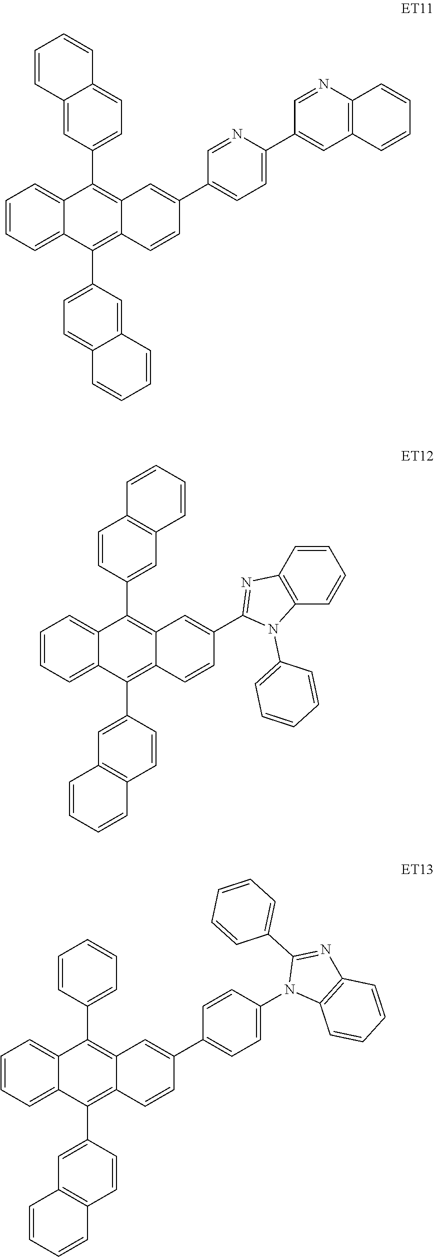 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

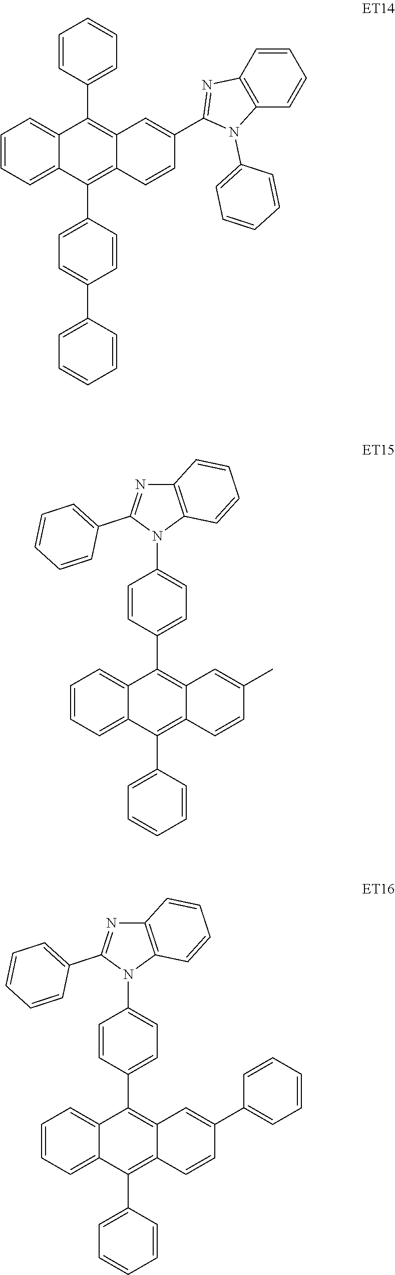 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

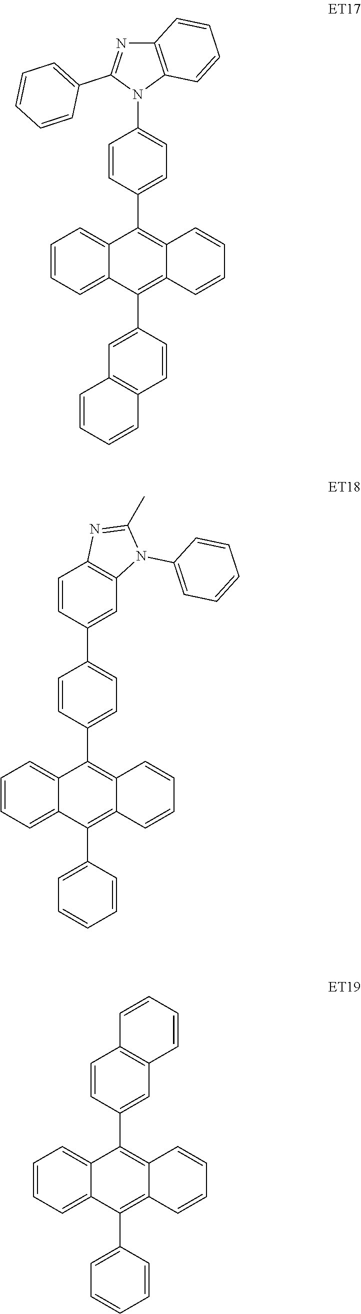

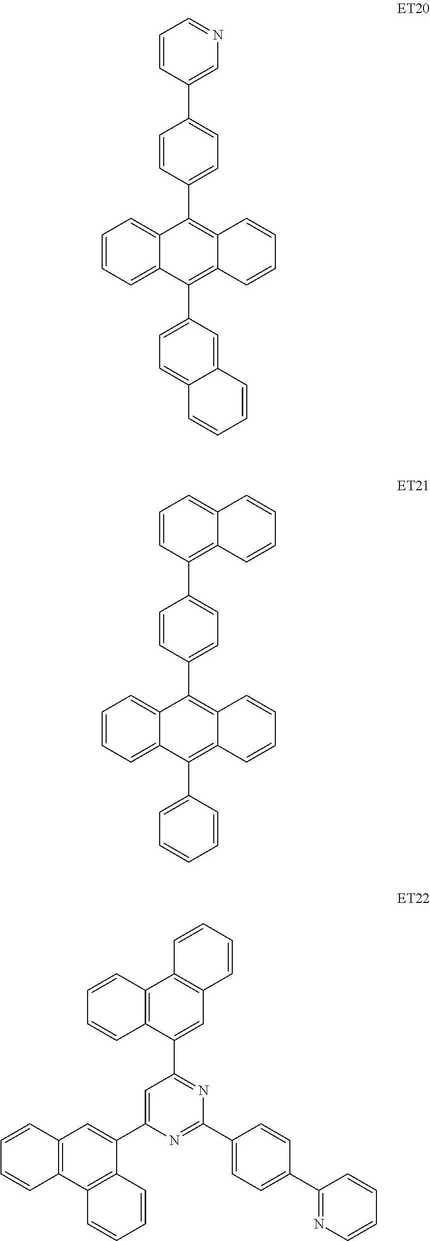

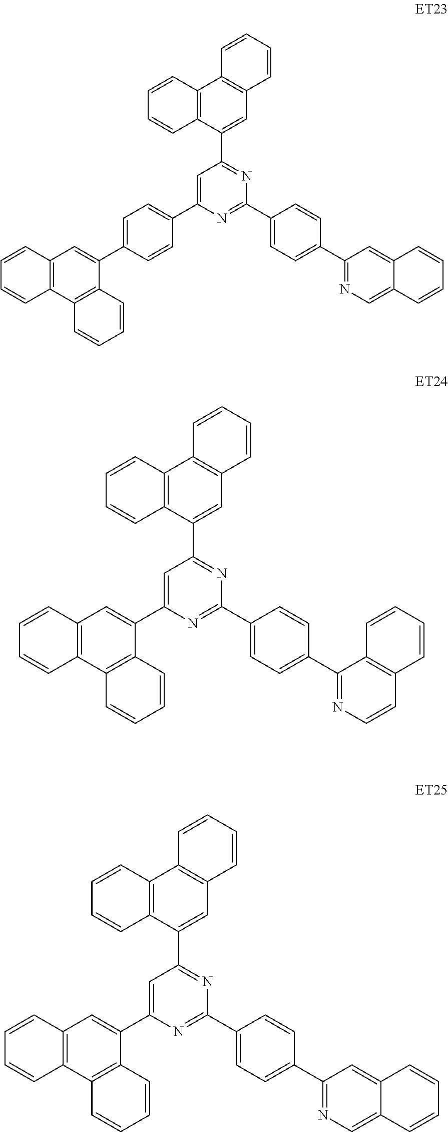 [SMILES: c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2cc(-c3ccc(-c4nc(-c5cc6ccccc6c6ccccc56)cc(-c5cc6ccccc6c6ccccc56)n4)cc3)ncc2c1]

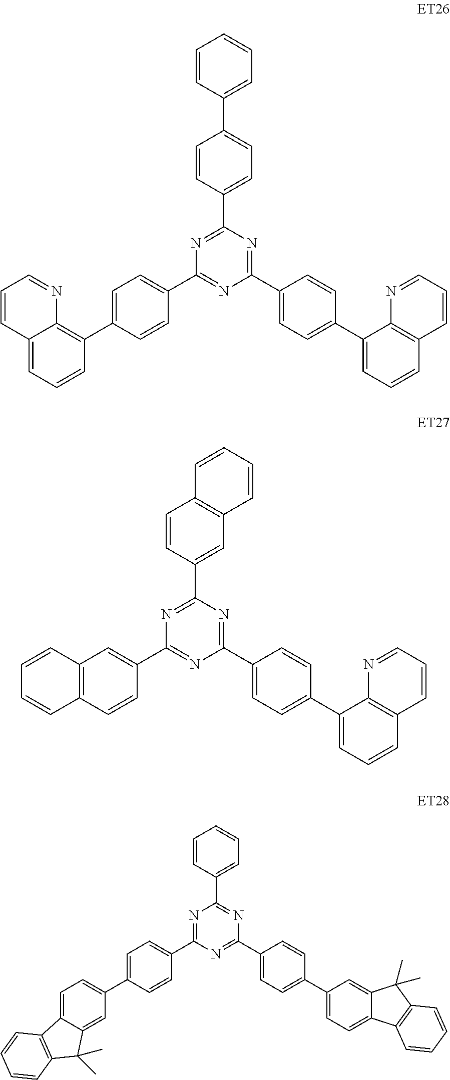 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

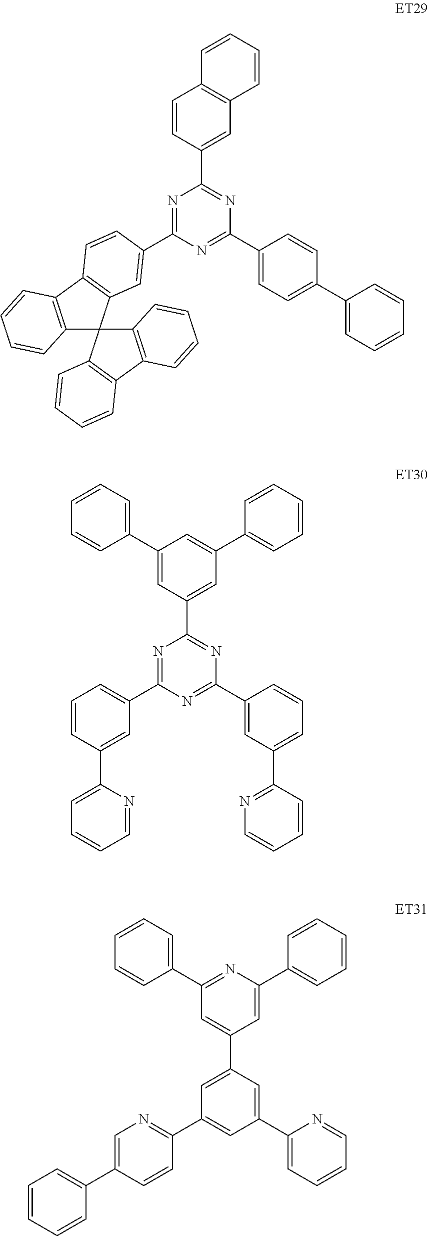 [SMILES: c1ccc(-c2ccc(-c3nc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

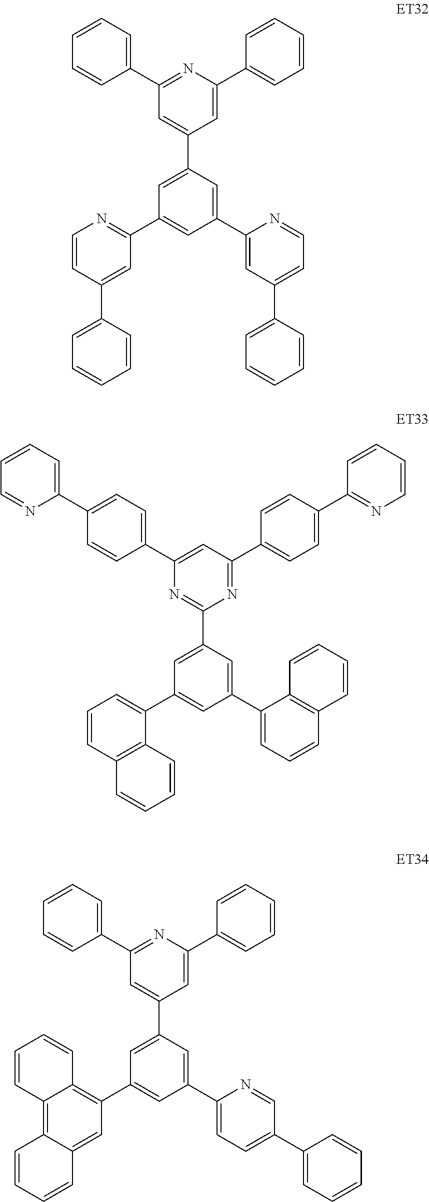 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

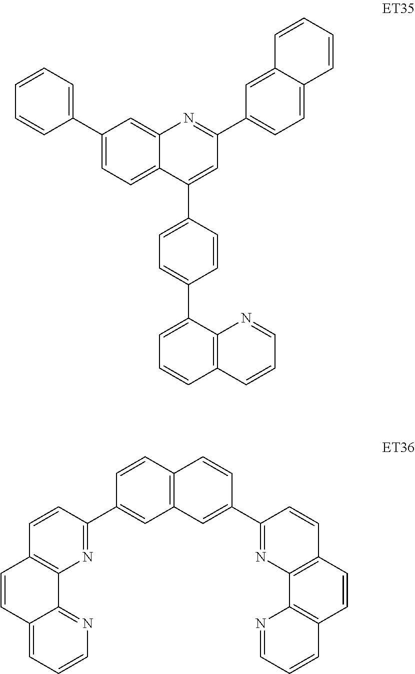 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a halogenated metal such as LiF, NaCl, CsF, RbCl, RbI, CuI, and KI; a lanthanide metal such as Yb; or a co-deposited material of a halogenated metal and a lanthanide metal. For example, the electron transport region ETR may include KI:Yb, RbI:Yb, LiF:Yb, or the like as a co-deposited material. The electron transport region ETR may include a metal oxide such as Li₂O and BaO, or 8-hydroxyl-lithium quinolate (Liq), or the like, but embodiments are not limited thereto. In another embodiment, the electron transport region ETR may be formed of a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the materials described above, but embodiments are not limited thereto.

The electron transport region ETR may include the compounds of the electron transport region ETR as described above in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. When the thickness of the electron transport layer ETL satisfies any of the above-described ranges, satisfactory electron transport properties may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. When the thickness of the electron injection layer EIL satisfies any of the above-described ranges, satisfactory electron injection properties may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode may include Ag, Mg, Cu, A1, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), or the like.

When the second electrode EL2 is a transflective electrode or a reflective electrode, the second electrode EL2 may include Ag, Mg, Cu, A1, Pt, Pd, Au, Ni, Nd, Ir, Cr, Li, Ca, LiF/Ca, LiF/A1, Mo, Ti, Yb, W, a compound thereof, or a mixture thereof (e.g., AgMg, AgYb, or MgYb). In an embodiment, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), or the like. For example, the second electrode EL2 may include the above-described metal materials, a combination of two or more metal materials selected from the above-described metal materials, or oxides of the above-described metal materials.

Although not shown in the drawings, the second electrode EL2 may be electrically connected to an auxiliary electrode. When the second electrode EL2 is electrically connected to an auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, or the like.

For example, when the capping layer CPL includes an organic material, the organic material may include a-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), or the like, or may include an epoxy resin or an acrylate such as a methacrylate. However, embodiments are not limited thereto, and the capping layer CPL may include at least one of Compound P1 to Compound P5.

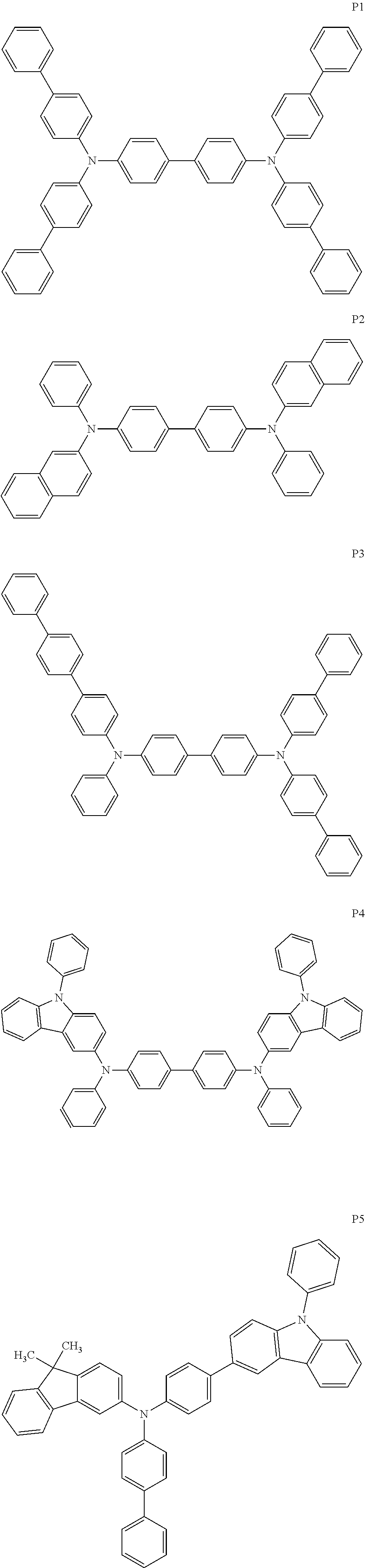 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index equal to or greater than about 1.6. For example, the capping layer CPL may have a refractive index equal to or greater than about 1.6 in a wavelength range of about 550 nm to about 600 nm.

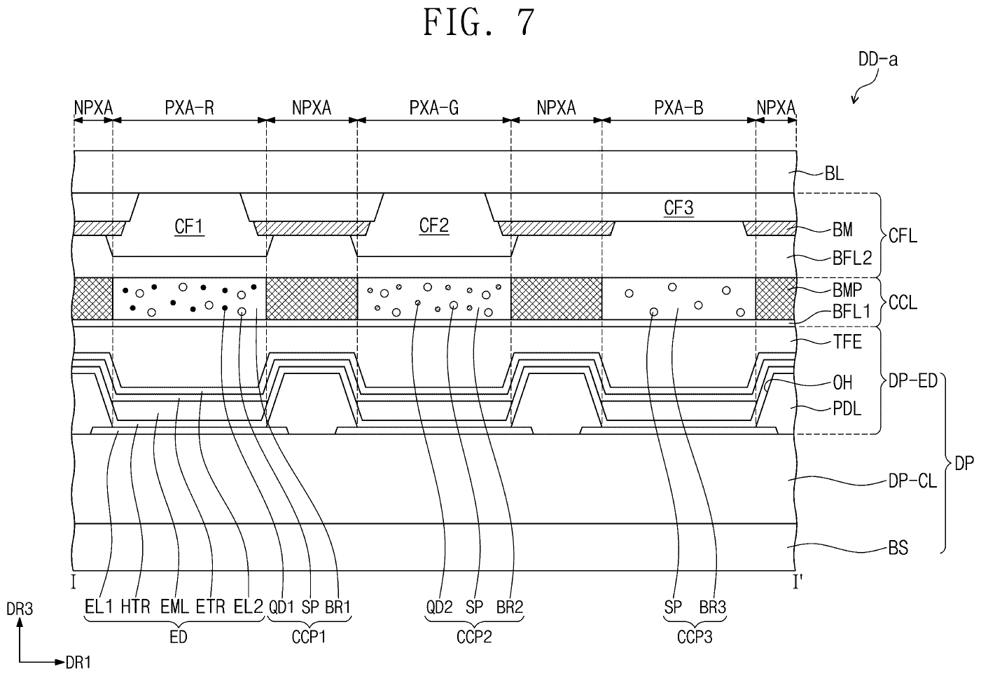

FIGS. 7 to 10 are each a schematic cross-sectional view of a display device according to an embodiment. In the descriptions of the display devices according to embodiments as shown in FIGS. 7 to 10, the features which have been described above with respect to FIGS. 1 to 6 will not be explained again, and the differing features will be described.

Referring to FIG. 7, a display device DD-a according to an embodiment may include a display panel DP having a display element layer DP-ED, a light control layer CCL disposed on the display panel DP, and a color filter layer CFL.

In an embodiment shown in FIG. 7, the display panel DP may include a base layer BS, a circuit layer DP-CL provided on the base layer BS, and a display element layer DP-ED, and the element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element ED according to one of FIGS. 3 to 6 as described above.

Referring to FIG. 7, the emission layer EML may be disposed in openings OH defined in the pixel defining films PDL. For example, the emission layer EML, which is separated by the pixel defining films PDL and correspondingly provided to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light converter. The light converter may be a quantum dot or a phosphor. The light converter may convert the wavelength of a provided light and may emit the resulting light. For example, the light control layer CCL may be a layer containing quantum dots or phosphors.

The light control layer CCL may include light control units CCP1, CCP2, and CCP3. The light control units CCP1, CCP2, and CCP3 may be spaced apart from each other.

Referring to FIG. 7, a division pattern BMP may be disposed between the light control units CCP1, CCP2, and CCP3, which are spaced apart from each other, but embodiments are not limited thereto. In FIG. 7, it is shown that the division pattern BMP does not overlap the light control units CCP1, CCP2, and CCP3, but the edges of the light control units CCP1, CCP2, and CCP3 may overlap at least a portion of the division pattern BMP.

The light control layer CCL may include a first light control unit CCP1 including a first quantum dot QD1 that converts first color light provided from the light emitting element ED into second color light, a second light control unit CCP2 including a second quantum dot QD2 that converts the first color light into third color light, and a third light control unit CCP3 that transmits the first color light.

In an embodiment, the first light control unit CCP1 may provide red light, which is the second color light, and the second light control unit CCP2 may provide green light, which is the third color light. The third light control unit CCP3 may transmit and provide blue light, which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include a quantum dot but may include the scatterers SP.

The scatterers SP may be inorganic particles. For example, the scatterers SP may include at least one of TiO₂, ZnO, Al₂O₃, SiO₂, and hollow silica. The scatterers SP may include any of TiO₂, ZnO, Al₂O₃, SiO₂, or hollow silica, or the scatterers SP may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3.

The base resins BR1, BR2, and BR3 are each a medium in which the quantum dots QD1 and QD2 and the scatterers SP are dispersed, and may be formed of various resin compositions, which may be generally referred to as a binder. For example, the base resins BR1, BR2, and BR3 may be an acrylic-based resin, a urethane-based resin, a silicone-based resin, an epoxy-based resin, or the like. The base resins BR1, BR2, and BR3 may each be a transparent resin. In an embodiment, the first base resin BR1, the second base resin BR2, and the third base resin BR3 may each be the same as or different from each other.

The light control layer CCL may include a barrier layer BFL1. The barrier layer BFL1 may prevent the permeation of moisture and/or oxygen (hereinafter referred to as “moisture/oxygen”) into the display panel DP. The barrier layer BFL1 may be disposed on the light control units CCP1, CCP2, and CCP3 to prevent the light control units CCP1, CCP2, and CCP3 from being exposed to moisture/oxygen. The barrier layer BFL1 may cover the light control units CCP1, CCP2, and CCP3. A barrier layer BFL2 may be provided between the light control units CCP1, CCP2, and CCP3, and filters CF1, CF2, and CF3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film in which light transmittance is secured, or the like. The barrier layers BFL1 and BFL2 may each independently further include an organic film. The barrier layers BFL1 and BFL2 may each be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include alight blocking unit BM and filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin, and a pigment or a dye. The first filter CF1 may include a red pigment or a red dye, the second filter CF2 may include a green pigment or a green dye, and the third filter CF3 may include a blue pigment or a blue dye. However, embodiments are not limited thereto, and the third filter CF3 may not include a pigment or a dye. The third filter CF3 may include a polymer photosensitive resin, and may not include a pigment or a dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated and may be provided as a single body.

The light blocking unit BM may be a black matrix. The light blocking unit BM may include an organic light blocking material or an inorganic light blocking material, each including a black pigment or a black dye. The light blocking unit BM may prevent light leakage, and may separate boundaries between the adjacent filters CF1, CF2, and CF3. In an embodiment, the light blocking unit BM may be formed of a blue filter.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL and the light control layer CCL are disposed. The base substrate BL may be a glass substrate, a metal substrate, a plastic substrate, or the like. However, embodiments are not limited thereto, and the base substrate BL may include an inorganic layer, an organic layer, or a composite material layer. Although not shown in the drawings, in an embodiment, the base substrate BL may be omitted.

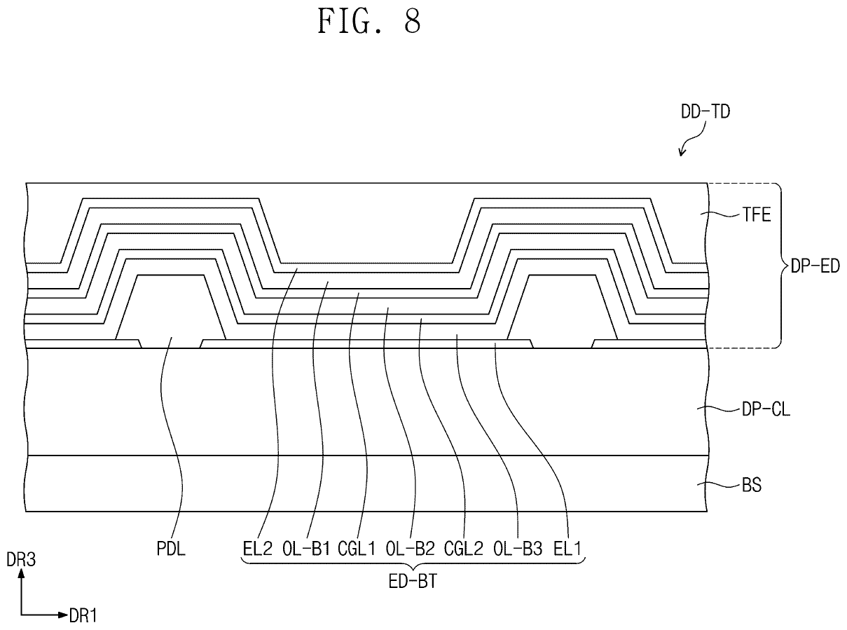

FIG. 8 is a schematic cross-sectional view showing a portion of a display device according to an embodiment. In a display device DD-TD according to an embodiment, a light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3, which are stacked in a thickness direction between the first electrode EL1 and the second electrode EL2. The light emitting structures OL-B1, OL-B2, and OL-B3 may each include an emission layer EML (see FIG. 7), and a hole transport region HTR and an electron transport region ETR disposed with the emission layer EML (see FIG. 7) therebetween.

For example, the light emitting element ED-BT included in the display device DD-TD may be a light emitting element having a tandem structure that includes multiple emission layers.

In an embodiment shown in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT including the light emitting structures OL-B1, OL-B2, and OL-B3, which each emit light in different wavelength ranges, may emit white light.

Charge generation layers CGL1 and CGL2 may be disposed between neighboring structures among light emitting structures OL-B1, OL-B2, and OL-B3. Charge generation layers CGL1 and CGL2 may each independently include a p-type charge generation layer and/or an n-type charge generation layer.

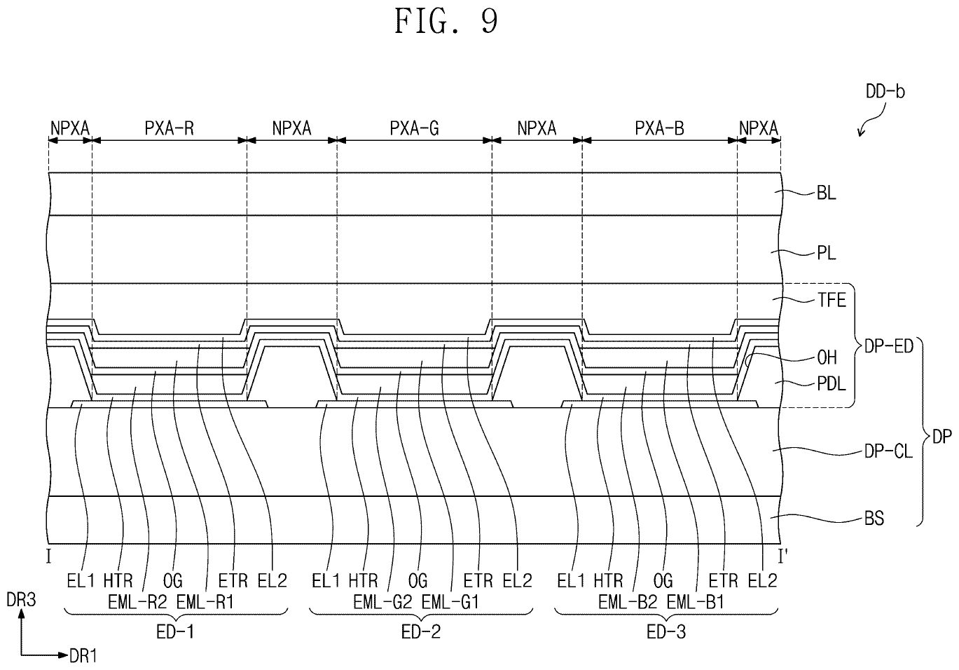

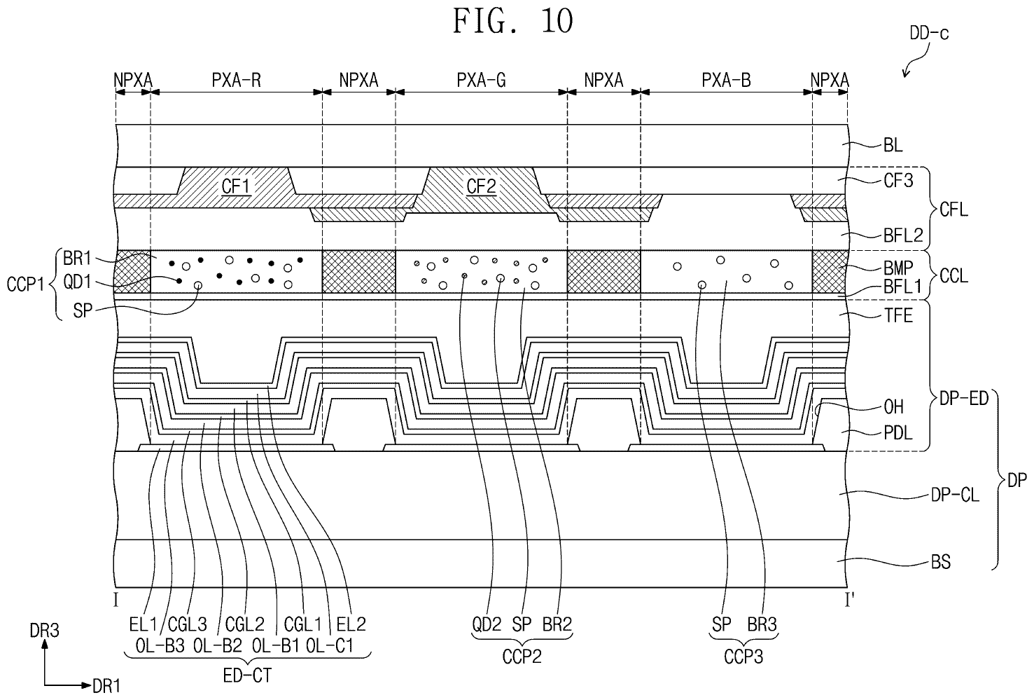

Referring to FIG. 9, a display device DD-b according to an embodiment may include light emitting elements ED-1, ED-2, and ED-3, which each include two emission layers that are stacked. In comparison to the display device DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength range.

The first light emitting element ED-1 may include a first red emission layer EML-R₁ and a second red emission layer EML-R₂. The second light emitting element ED-2 may include a first green emission layer EML-G1 and a second green emission layer EML-G2. The third light emitting element ED-3 may include a first blue emission layer EML-B1 and a second blue emission layer EML-B2. A light emitting auxiliary portion OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The light emitting auxiliary portion OG may be a single layer or multiple layers. The light emitting auxiliary portion OG may include a charge generation layer. For example, the light emitting auxiliary portion OG may include an electron transport region, a charge generation layer, and a hole transport region, which may be stacked in that order. The light emitting auxiliary portion OG may be provided as a common layer throughout all of the first to third light emitting elements ED-1, ED-2, and ED-3. However, embodiments are not limited thereto, and the light emitting auxiliary portion OG may be provided by being patterned inside the openings OH defined in the pixel defining films PDL.

The first red emission layer EML-R₁, the first green emission layer EML-G1, and the first blue emission layer EML-B1 may each be disposed between the electron transport region ETR and the light emitting auxiliary portion OG. The second red emission layer EML-R₂, the second green emission layer EML-G2, and the second blue emission layer EML-B2 may each be disposed between the light emitting auxiliary portion OG and the hole transport region HTR.

For example, the first light emitting element ED-1 may include the first electrode EL1, the hole transport region HTR, the second red emission layer EML-R₂, the light emitting auxiliary portion OG, the first red emission layer EML-R₁, the electron transport region ETR, and the second electrode EL2, which are stacked in that order. The second light emitting element ED-2 may include the first electrode EL1, the hole transport region HTR, the second green emission layer EML-G2, the light emitting auxiliary portion OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the light emitting auxiliary portion OG, the first blue emission layer EML-B1, the electron transport region ETR, and the second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

In contrast to FIGS. 8 and 9, the display device DD-c shown in FIG. 10 is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Light emitting structures OL-C1, OL-B1, OL-B2, and OL-B3 may be stacked in this stated order, charge generation layer CGL1 may be disposed between light emitting structures OL-B1 and OL-C1, charge generation layer CGL2 may be disposed between light emitting structures OL-B1 and OL-B2, and charge generation layer CGL3 may be disposed between light emitting structures OL-B2 and OL-B3. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may each emit light having wavelength ranges that are different from each other.

The charge generation layers CGL1, CGL2, and CGL3 which are disposed between neighboring light emitting structures OL-C1, OL-B1, OL-B2, and OL-B3 may each independently include a p-type charge generation layer and/or an n-type charge generation layer.

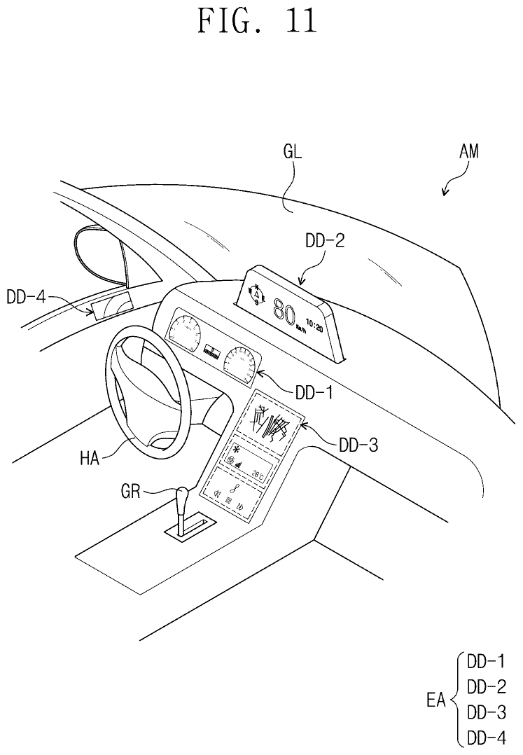

FIG. 11 is a schematic perspective view of an electronic device including a display device according to an embodiment. FIG. 11 shows a portion of a vehicle AM as an example of an electronic device EA that includes a display device.

Referring to FIG. 11, the electronic device EA according to an embodiment may include display devices DD-1, DD-2, DD-3, and DD-4 for a vehicle AM. FIG. 11 shows first to fourth display devices DD-1, DD-2, DD-3, and DD-4 as display devices for the electronic device EA disposed inside the vehicle AM. FIG. 11 shows an automobile, but this is presented only as an example, and the first to fourth display devices DD-1, DD-2, DD-3, and DD-4 may be disposed in various means of transportation, such as bicycles, motorcycles, trains, ships, and airplanes. At least one of the first to fourth display devices DD-1, DD-2, DD-3, and DD-4 may have a structure according to one of the display devices DD, DD-a, DD-TD, DD-b, and DD-c as described in reference to FIGS. 1, 2, and 7 to 10.

In an embodiment, at least one of the first to fourth display devices DD-1, DD-2, DD-3, and DD-4 may include a light emitting element ED according to an embodiment as described in reference to one of FIGS. 3 to 6. The first to fourth display devices DD-1, DD-2, DD-3, and DD-4 may each independently include multiple light emitting elements ED. Each of the light emitting elements ED may include a first electrode EL1, a hole transport region HTL disposed on the first electrode EL1, an emission layer EML disposed on the hole transport region HTL, an electron transport region ETL disposed on the emission layer EML, and a second electrode EL2 disposed on the electron transport region ETL. The emission layer EML may include a polycyclic compound represented by Formula 1 according to an embodiment described above. Thus, the electronic device EA may exhibit improved image quality.

Referring to FIG. 11, the vehicle AM may include a steering wheel HA and a gearshift GR for operating the vehicle AM. The vehicle AM may have a front window GL that is disposed so as to face a driver.

The first display device DD-1 may be disposed in a first region overlapping the steering wheel HA. For example, the first display device DD-1 may be a digital cluster that displays first information of the vehicle AM. The first information may include a first scale that indicates driving speed of the vehicle AM, a second scale that indicates a rate of engine rotation (for example, as revolutions per minute (RPM)), a fuel gauge, and the like. The first scale and the second scale may each be represented as digital images.

The second display device DD-2 may be disposed in a second region facing a driver's seat and overlapping the front window GL. The driver's seat may be a seat where the steering wheel HA is disposed. For example, the second display device DD-2 may be a head up display HUD that displays second information of the vehicle AM. The second display device DD-2 may be optically transparent. The second information may include digital numbers that indicate a driving speed of the vehicle AM and may further include information such as the current time.

The third display device DD-3 may be disposed in a third region adjacent to the gearshift GR. For example, the third display device DD-3 may be a center information display (CID) for a vehicle AM, which is disposed between a driver's seat and a front passenger seat and displays third information. The passenger seat may be a seat that is spaced apart from the driver's seat with the gearshift GR disposed therebetween. The third information may include information about road conditions (e.g., navigation information), music or radio play, dynamic video play, temperature inside the vehicle AM, and the like.

The fourth display device DD-4 may be disposed in a fourth region spaced apart from the steering wheel HA and the gearshift GR and adjacent to a side of the vehicle AM. For example, the fourth display device DD-4 may be a digital side mirror that displays fourth information. The fourth display device DD-4 may display images of conditions outside the vehicle AM, which are taken by a camera module (CM) disposed outside the vehicle AM. The fourth information may include images of conditions outside the vehicle AM.

The first to fourth information as described above are only presented as examples, and the first to fourth display devices DD-1, DD-2, DD-3, and DD-4 may further display information about the interior or the exterior of a vehicle AM. The first to fourth information may include information that are different from each other. However, embodiments are not limited thereto, and some of the first to fourth information may include the same information.

Hereinafter, a polycyclic compound according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### Examples

### 1. Synthesis of Polycyclic Compounds

A method of synthesizing polycyclic compounds will be described in detail by providing a method of synthesizing Compounds 18, 147, 154, 233, 307, 361, 433, 463, 475, 487, 516, and 520 as examples. A process of synthesizing polycyclic compounds, which will be described hereinafter, is provided only as an example, and thus a process of synthesizing compounds according to embodiments is not limited to the Examples below.

### (1) Synthesis of Compound 18

Compound 18 according to an embodiment may be synthesized by, for example, processes of Reaction Formula 1 below.

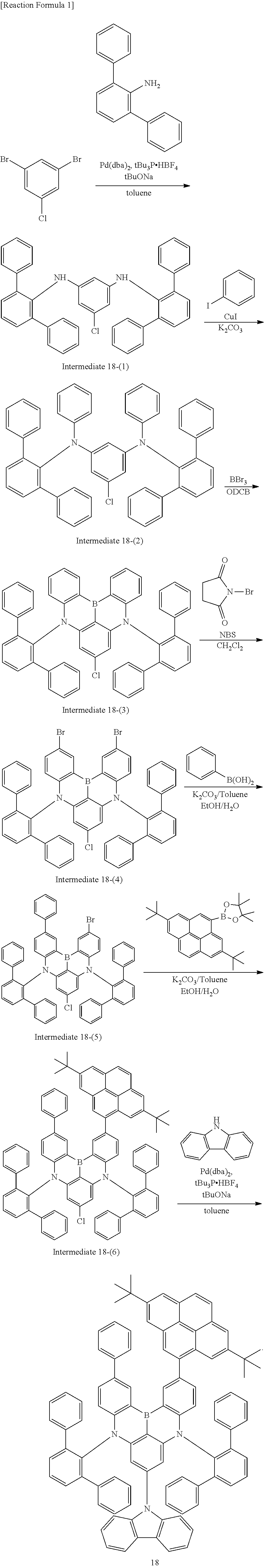

### 1) Synthesis of Intermediate Compound 18-(1)

In an Ar atmosphere, 1,3-dibromo-5-chlorobenzene (15 g, 55.48 mmol), [1,1′:3′,1″-terphenyl]-2′-amine (28.58 g, 116.52 mmol), Pd(dba)₂ (3.19 g, 5.55 mmol), tBu₃P·HBF₄ (3.22 g, 11.1 mmol), and tBuONa (12.26 g, 127.61 mmol) were added to toluene (277 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 18-(1) (29.25 g, yield: 88%). The FAB MS measurement shows that Intermediate 18-(1) had a molecular weight of 599.

### 2) Synthesis of Intermediate Compound 18-(2)

Intermediate 18-(1) (28.0 g, 46.73 mmol), iodobenzene (143 g, 700.97 mmol), CuI (18.69 g, 98.14 mmol), and K₂CO₃ (51.67 g, 373.85 mmol) were added to a small amount of toluene (about 10 ml), and the mixture was heated at a constant outside temperature of 215° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 18-(2) (21.77 g, yield: 62%). The FAB MS measurement shows that Intermediate 18-(2) had a molecular weight of 751.

### 3) Synthesis of Intermediate Compound 18-(3)

In an Ar atmosphere, Intermediate 18-(2) (20.0 g, 26.62 mmol) was dissolved in ODCB (266 ml) and BBr₃ (16.67 g, 66.55 mmol) was added, and the mixture was heated and stirred at 170° C. for 10 hours. The mixture was cooled at room temperature, and N,N-diisopropylethylamine (DIPEA, 41.2 g, 319.42 mmol) was added, and water was added, and then the mixture was subjected to celite filtering and liquid separation to concentrate an organic layer. The resulting product was purified through silica gel column chromatography to obtain Intermediate 18-(3) (10.51 g, yield: 52%). The FAB MS measurement shows that Intermediate 18-(3) had a molecular weight of 759.

### 4) Synthesis of Intermediate Compound 18-(4)

In an Ar atmosphere, Intermediate 18-(3) (10.0 g, 13.17 mmol) was dissolved in CH₂C₁₂ (132 ml), and NBS (4.81 g, 27 mmol) was added, and then the mixture was stirred at room temperature for 24 hours. Water was added, and the mixture was subjected to celite filtering and liquid separation to concentrate an organic layer. The resulting product was purified through silica gel column chromatography to obtain Intermediate 18-(4) (10.27 g, yield: 85%). The FAB MS measurement shows that Intermediate 18-(4) had a molecular weight of 917.

### 5) Synthesis of Intermediate Compound 18-(5)

In an Ar atmosphere, Intermediate 18-(4) (8.00 g, 8.72 mmol), phenylboronic acid (1.06 g, 8.72 mmol), K₂CO₃ (3.7 g, 17.45 mmol), Pd(Ph₃P)₄ (1.01 g, 0.87 mmol), and toluene (64 ml) were added to a 1:1 mixture of EtOH and water (32 ml), and then the mixture was heated at a constant outside temperature of 80° C. for 24 hours. The mixture was subjected to celite filtering and liquid separation to concentrate an organic layer. The resulting product was purified through silica gel column chromatography to obtain Intermediate 18-(5) (6.22 g, yield: 78%). The FAB MS measurement shows that Intermediate 18-(5) had a molecular weight of 914.

### 6) Synthesis of Intermediate Compound 18-(6)

In an Ar atmosphere, Intermediate 18-(5) (5.00 g, 5.47 mmol), 2-(2,7-di-tert-butylpyren-4-yl)-4,4,5,5-tetramethyl-1,3,2-dioxaborolane (2.41 g, 5.47 mmol), K₂CO (2.32 g, 10.94 mmol), Pd(Ph₃P)₄ (0.63 g, 0.55 mmol), and toluene (40 ml) were added to a 1:1 mixture of EtOH and water (20 ml), and then the mixture was heated at a constant outside temperature of 80° C. for 24 hours. The mixture was subjected to celite filtering and liquid separation to concentrate an organic layer. The resulting product was purified through silica gel column chromatography to obtain Intermediate 18-(6) (3.01 g, yield: 48%). The FAB MS measurement shows that Intermediate 18-(6) had a molecular weight of 1148.

### 7) Synthesis of Compound 18

In an Ar atmosphere, Intermediate 18-(6) (2.50 g, 2.18 mmol), 9H-carbazole (1.09 g, 6.53 mmol), Pd(dba)₂ (0.13 g, 0.22 mmol), tBu₃P·HBF₄ (0.13 g, 0.44 mmol), and tBuONa (0.48 g, 5.01 mmol) were added to toluene (10 ml), and the mixture was heated and stirred at 100° C. for 8 hours. Water was added, and the mixture was subjected to celite filtering and liquid separation to concentrate an organic layer. The resulting product was purified through silica gel column chromatography to obtain Compound 18 (2.56 g, yield: 92%). The FAB MS measurement shows that Compound 18 had a molecular weight of 1278.

Compound 18 was subjected to sublimation purification (390° C., 2.8×10−3 Pa) to evaluate a device.

### (2) Synthesis of Compound 147

Compound 147 according to an embodiment may be synthesized by, for example, processes of Reaction Formula 2 below.

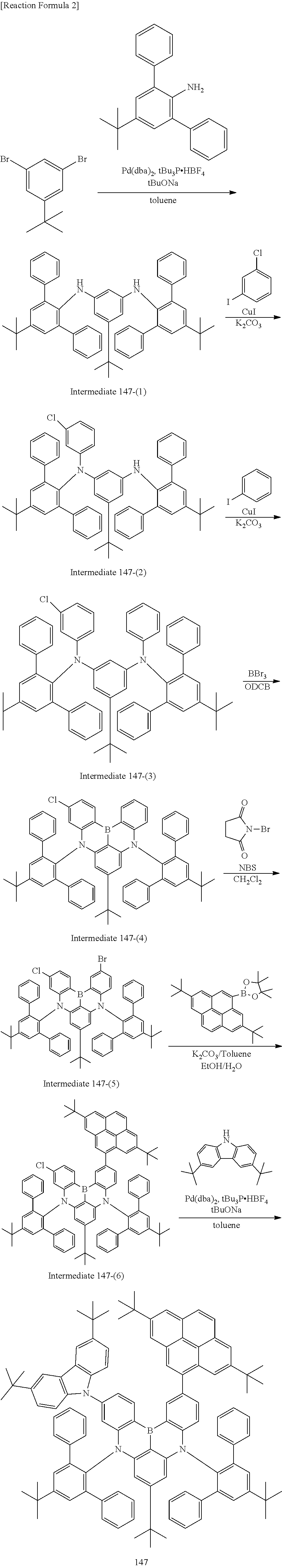

### 1) Synthesis of Intermediate Compound 147-(1)

In an Ar atmosphere, 1,3-dibromo-5-(tert-butyl)benzene (15.01 g, 51.4 mmol), 5′-(tert-butyl)-[1,1′:3′,1″-terphenyl]-2′-amine (31.76 g, 105.37 mmol), Pd(dba)₂ (2.96 g, 5.14 mmol), tBu₃P·HBF₄ (2.98 g, 10.28 mmol), and tBuONa (11.36 g, 118.23 mmol) were added to toluene (257 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 147-(1) (27.51 g, yield: 73%). The FAB MS measurement shows that Intermediate 147-(1) had a molecular weight of 733.

### 2) Synthesis of Intermediate Compound 147-(2)

Intermediate 147-(1) (27.0 g, 36.83 mmol), 1-chloro-3-iodobenzene (131.74 g, 552.48 mmol), CuI (14.73 g, 77.35 mmol), and K₂CO₃ (40.72 g, 294.66 mmol) were added to a small amount of toluene (about 10 ml), and the mixture was heated at a constant outside temperature of 215° C. for 10 hours. Water was added after the mixture was diluted with CH₂Cl₂, and the mixture was subjected to celite filtering and liquid separation to concentrate an organic layer. The resulting product was purified through silica gel column chromatography to obtain Intermediate 147-(2) (10.87 g, yield: 35%). The FAB MS measurement shows that Intermediate 147-(2) had a molecular weight of 844.

### 3) Synthesis of Intermediate Compound 147-(3)

Intermediate 147-(2) (10.0 g, 11.85 mmol), iodobenzene (36.27 g, 177.81 mmol), CuI (4.74 g, 24.89 mmol), and K₂CO₃ (13.11 g, 94.83 mmol) were added to a small amount of toluene (about 10 ml), and the mixture was heated at a constant outside temperature of 215° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 147-(3) (8.5 g, yield: 78%). The FAB MS measurement shows that Intermediate 147-(3) had a molecular weight of 920.

### 4) Synthesis of Intermediate Compound 147-(4)

In an Ar atmosphere, Intermediate 147-(3) (8 g, 8.7 mmol) was dissolved in ODCB (87 ml) and BBr₃ (5.45 g, 21.75 mmol) was added, and the mixture was heated and stirred at 170° C. for 10 hours. The mixture was cooled at room temperature, and N,N-diisopropylethylamine (DIPEA, 13.47 g, 104.38 mmol) was added, and water was added, and then the mixture was subjected to celite filtering and liquid separation to concentrate an organic layer. The resulting product was purified through silica gel column chromatography to obtain Intermediate 147-(4) (5.24 g, yield: 65%). The FAB MS measurement shows that Intermediate 147-(4) had a molecular weight of 927.

### 5) Synthesis of Intermediate Compound 147-(5)

In an Ar atmosphere, Intermediate 147-(4) (5.03 g, 5.42 mmol) was dissolved in CH₂C₁₂ (54 ml), and NBS (0.97 g, 5.42 mmol) was added, and then the mixture was stirred at room temperature for 24 hours. Water was added, and the mixture was subjected to celite filtering and liquid separation to concentrate an organic layer. The resulting product was purified through silica gel column chromatography to obtain Intermediate 147-(5) (5.02 g, yield: 92%). The FAB MS measurement shows that Intermediate 147-(5) had a molecular weight of 1006.

### 6) Synthesis of Intermediate Compound 147-(6)

In an Ar atmosphere, Intermediate 147-(5) (4.5 g, 4.47 mmol), 2-(2,7-di-tert-butylpyren-4-yl)-4,4,5,5-tetramethyl-1,3,2-dioxaborolane (1.97 g, 4.47 mmol), K₂CO₃ (1.9 g, 8.94 mmol), Pd(Ph3P)4 (0.52 g, 0.45 mmol), and toluene (36 ml) were added to a 1:1 mixture of EtOH and water (18 ml), and then the mixture was heated at a constant outside temperature of 80° C. for 24 hours. The mixture was subjected to celite filtering and liquid separation to concentrate an organic layer. The resulting product was purified through silica gel column chromatography to obtain Intermediate 147-(6) (4.27 g, yield: 77%). The FAB MS measurement shows that Intermediate 147-(6) had a molecular weight of 1240.

### 7) Synthesis of Compound 147

In an Ar atmosphere, Intermediate 147-(6), 3,6-di-tert-butyl-9H-carbazole (2.67 g, 9.56 mmol), Pd(dba)₂ (0.18 g, 0.32 mmol), tBu₃P·HBF₄ (0.18 g, 0.64 mmol), and tBuONa (0.7 g, 7.33 mmol) were added to toluene (15 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 147-(1) (4.02 g, yield: 85%). The FAB MS measurement shows that Compound 147 had a molecular weight of 1483.

Compound 147 was subjected to sublimation purification (330° C., 3.7×10−3 Pa) to evaluate a device.

### (3) Synthesis of Compound 154

Compound 154 according to an embodiment may be synthesized by, for example, a process of Reaction Formula 3 below.

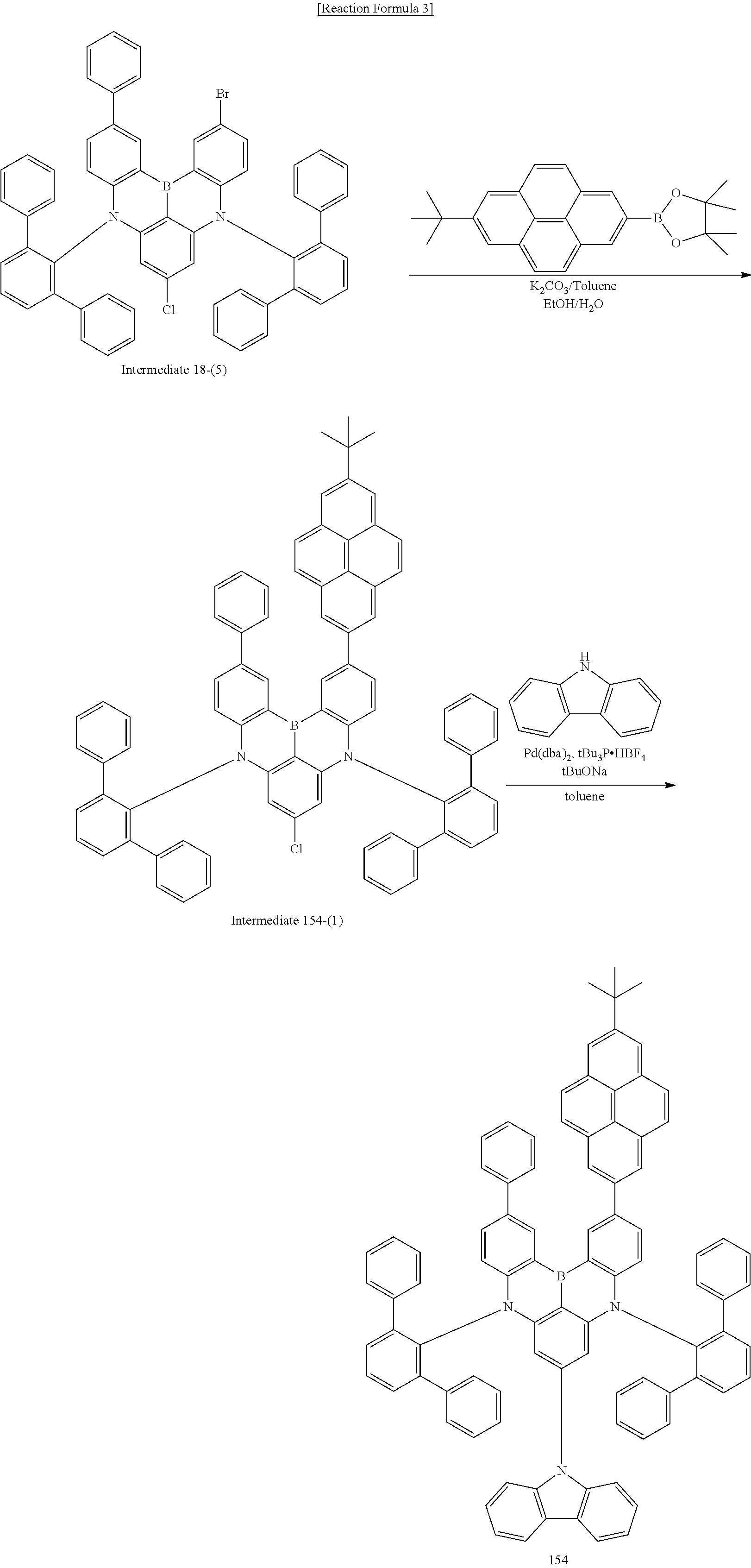

### 1) Synthesis of Intermediate Compound 154-(1)

In an Ar atmosphere, Intermediate 18-(5) (10.0 g, 10.94 mmol), 2-(7-(tert-butyl)pyren-2-yl)-4,4,5,5-tetramethyl-1,3,2-dioxaborolane (8.41 g, 21.88 mmol), K₂CO₃ (4.64 g, 21.88 mmol), and Pd(Ph₃P)₄ (1.26 g, 1.09 mmol), and toluene (80 ml) were added to a 1:1 mixture of EtOH and water (40 ml), and then the mixture was heated at a constant outside temperature of 80° C. for 24 hours. The mixture was subjected to celite filtering and liquid separation to concentrate an organic layer. The resulting product was purified through silica gel column chromatography to obtain Intermediate 154-(1) (9.91 g, yield: 83%). The FAB MS measurement shows that Intermediate 154-(1) had a molecular weight of 1092.

### 2) Synthesis of Compound 154

In an Ar atmosphere, Intermediate 154-(1) (6.21 g, 5.69 mmol), 9H-carbazole (2.85 g, 17.07 mmol), Pd(dba)₂ (0.33 g, 0.57 mmol), tBu₃P·HBF₄ (0.33 g, 1.14 mmol), and tBuONa (1.26 g, 13.08 mmol) were added to toluene (28 ml), and the mixture was heated and stirred at 100° C. for 8 hours. Water was added, and the mixture was subjected to celite filtering and liquid separation to concentrate an organic layer. The resulting product was purified through silica gel column chromatography to obtain Compound 154 (5.98 g, yield: 86%). The FAB MS measurement shows that Compound 154 had a molecular weight of 1222.

Compound 154 was subjected to sublimation purification (370° C., 2.8×10−3 Pa) to evaluate a device.

### (4) Synthesis of Compound 233

Compound 233 according to an embodiment may be synthesized by, for example, processes of Reaction Formula 4 below.

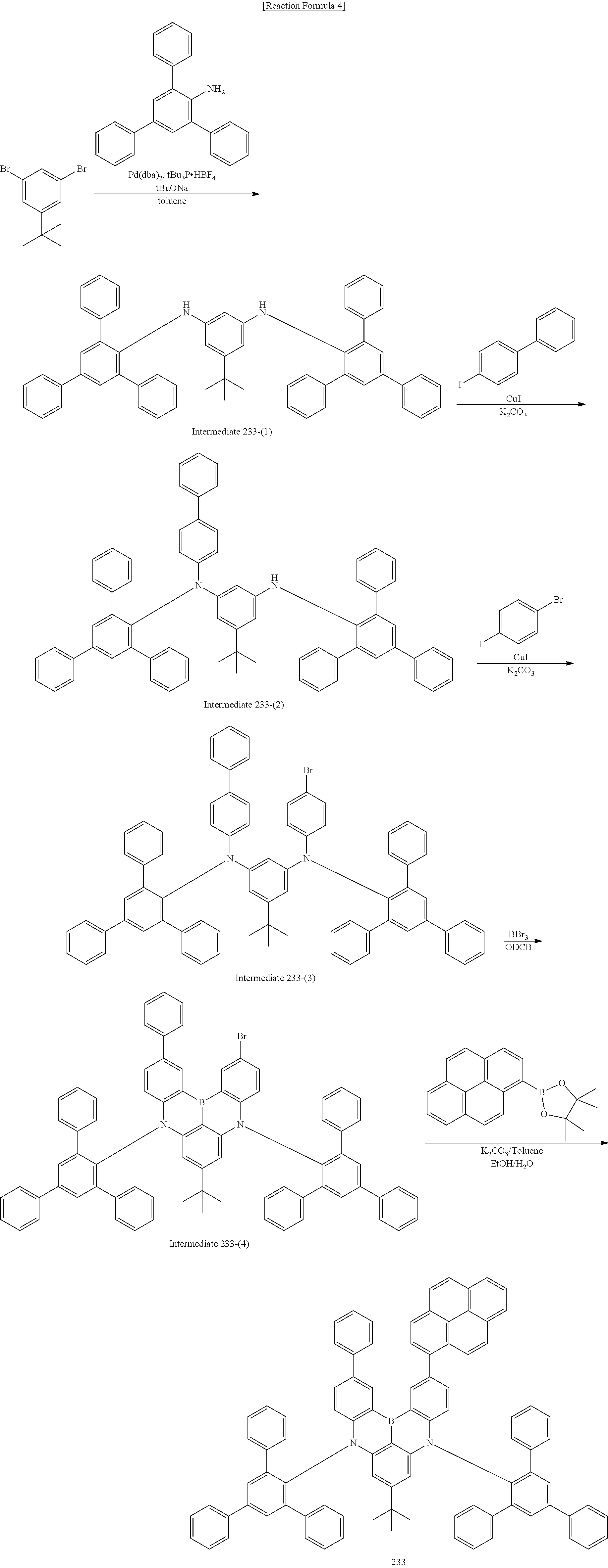

### 1) Synthesis of Intermediate Compound 233-(1)

In an Ar atmosphere, 1,3-dibromo-5-(tert-butyl)benzene (20.0 g, 68.49 mmol), 5′-phenyl-[1,1′:3′,1″-terphenyl]-2′-amine (46.23 g, 143.83 mmol), Pd(dba)₂ (3.94 g, 6.85 mmol), tBu₃P·HBF₄ (3.97 g, 13.7 mmol), and tBuONa (15.14 g, 157.53 mmol) were added to toluene (342 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 233-(1) (39.71 g, yield: 75%). The FAB MS measurement shows that Intermediate 233-(1) had a molecular weight of 773.

### 2) Synthesis of Intermediate Compound 233-(2)

Intermediate 233-(1) (36.05 g, 46.63 mmol), 4-iodo-1,1′-biphenyl (195.94 g, 699.51 mmol), CuI (18.65 g, 97.93 mmol), and K₂CO₃ (51.56 g, 373.07 mmol) were added to a small amount of toluene (about 10 ml), and the mixture was heated at a constant outside temperature of 215° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 233-(2) (14.24 g, yield: 33%). The FAB MS measurement shows that Intermediate 233-(2) had a molecular weight of 925.

### 3) Synthesis of Intermediate Compound 233-(3)

Intermediate 233-(2) (14 g, 15.13 mmol), 1-bromo-4-iodobenzene (64.21 g, 226.97 mmol), CuI (6.05 g, 31.78 mmol), and K₂CO₃ (16.73 g, 121.05 mmol) were added to a small amount of toluene (about 10 ml), and the mixture was heated at a constant outside temperature of 215° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 233-(3) (11.61 g, yield: 71%). The FAB MS measurement shows that Intermediate 233-(3) had a molecular weight of 1080.

### 4) Synthesis of Intermediate Compound 233-(4)

In an Ar atmosphere, Intermediate 233-(3) (11.5 g, 10.65 mmol) was dissolved in ODCB (106 ml) and BBr₃ (6.67 g, 26.61 mmol) was added, and the mixture was heated and stirred at 170° C. for 10 hours. The mixture was cooled at room temperature, and N,N-diisopropylethylamine (DIPEA, 16.48 g, 127.75 mmol) was added, and water was added, and then the mixture was subjected to celite filtering and liquid separation to concentrate an organic layer. The resulting product was purified through silica gel column chromatography to obtain Intermediate 233-(4) (3.71 g, yield: 32%). The FAB MS measurement shows that Intermediate 233-(4) had a molecular weight of 1088.

### 5) Synthesis of Compound 233

In an Ar atmosphere, Intermediate 233-(4) (3.5 g, 3.22 mmol), 2-4,4,5,5-tetramethyl-2-(pyren-1-yl)-1,3,2-dioxaborolane (2.11 g, 6.43 mmol), K₂CO₃ (1.37 g, 6.43 mmol), Pd(Ph₃P)₄ (0.37 g, 0.32 mmol), and toluene (28 ml) were added to a 1:1 mixture of EtOH and water (14 ml), and then the mixture was heated at a constant outside temperature of 80° C. for 24 hours. The mixture was subjected to celite filtering and liquid separation to concentrate an organic layer. The resulting product was purified through silica gel column chromatography to obtain Compound 233 (3.42 g, yield: 88%). The FAB MS measurement shows that Compound 233 had a molecular weight of 1209.

Compound 233 was subjected to sublimation purification (360° C., 2.7×10−3 Pa) to evaluate a device.

### (5) Synthesis of Compound 307

Compound 307 according to an embodiment may be synthesized by, for example, processes of Reaction Formula 5 below.

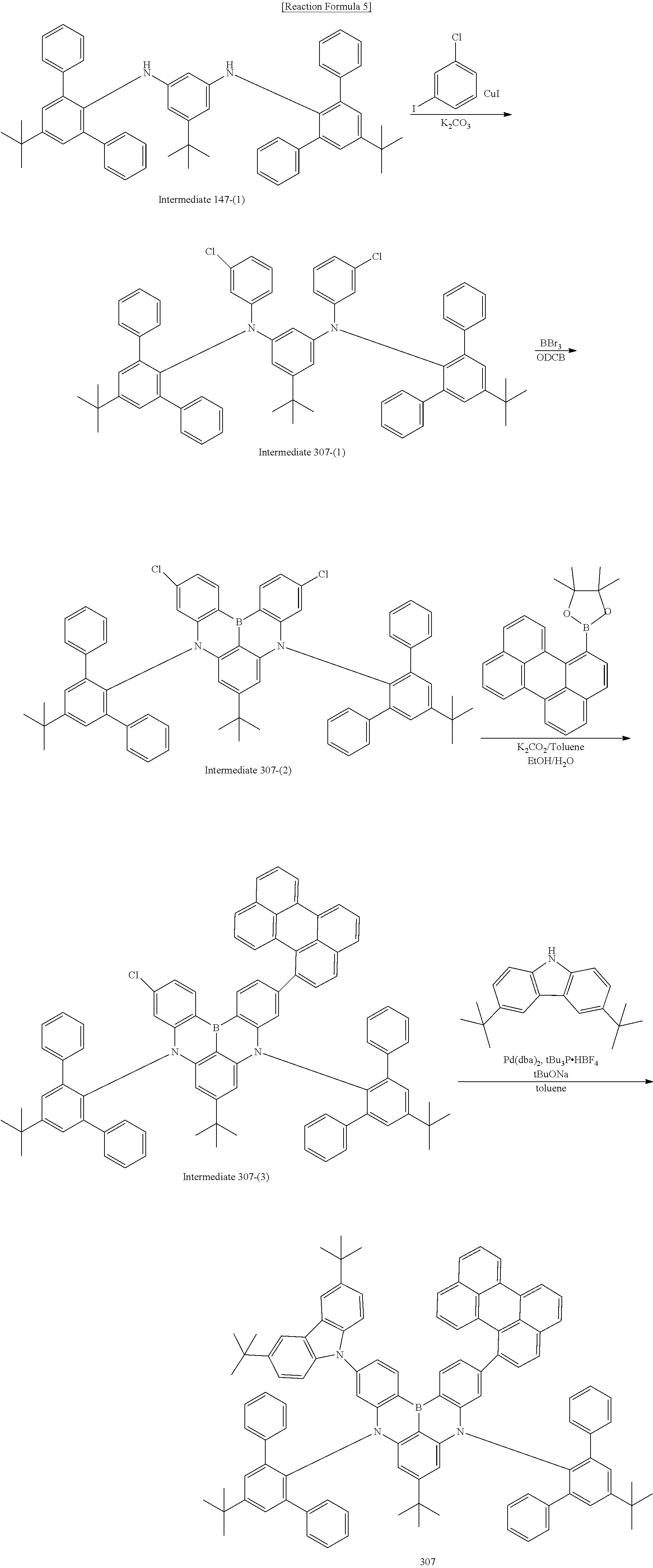

### 1) Synthesis of Intermediate Compound 307-(1)

Intermediate 147-(1) (20.0 g, 27.28 mmol), 1-chloro-3-iodobenzene (97.58 g, 409.24 mmol), CuI (10.91 g, 57.29 mmol), and K₂CO₃ (30.17 g, 218.26 mmol) were added to a small amount of toluene (about 10 ml), and the mixture was heated at a constant outside temperature of 215° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 307-(1) (21.87 g, yield: 84%). The FAB MS measurement shows that Intermediate 307-(1) had a molecular weight of 954.

### 2) Synthesis of Intermediate Compound 307-(2)

In an Ar atmosphere, Intermediate 307-(1) (21.22 g, 22.24 mmol) was dissolved in ODCB (222 ml) and BBr₃ (13.93 g, 55.6 mmol) was added, and the mixture was heated and stirred at 170° C. for 10 hours. The mixture was cooled at room temperature, and N,N-diisopropylethylamine (DIPEA, 34.43 g, 266.88 mmol) was added, and water was added, and then the mixture was subjected to celite filtering and liquid separation to concentrate an organic layer. The resulting product was purified through silica gel column chromatography to obtain Intermediate 307-(2) (10.27 g, yield: 48%). The FAB MS measurement shows that Intermediate 307-(2) had a molecular weight of 962.

### 3) Synthesis of Intermediate Compound 307-(3)

In an Ar atmosphere, Intermediate 307-(2) (10.03 g, 10.43 mmol), 4,4,5,5-tetramethyl-2-(perylen-1-yl)-1,3,2-dioxaborolane (7.89 g, 20.85 mmol), K₂CO₃ (4.43 g, 20.85 mmol), Pd(Ph₃P)₄ (1.2 g, 1.04 mmol), and toluene (80 ml) were added to a 1:1 mixture of EtOH and water (40 ml), and then the mixture was heated at a constant outside temperature of 80° C. for 24 hours. The mixture was subjected to celite filtering and liquid separation to concentrate an organic layer. The resulting product was purified through silica gel column chromatography to obtain Intermediate 307-(3) (4.67 g, yield: 38%). The FAB MS measurement shows that Intermediate 307-(3) had a molecular weight of 1178.

### 4) Synthesis of Compound 307

In an Ar atmosphere, Intermediate 307-(3) (4.12 g, 3.5 mmol), 3,6-di-tert-butyl-9H-carbazole (2.93 g, 10.49 mmol), Pd(dba)₂ (0.2 g, 0.35 mmol), tBu₃P·HBF₄ (0.2 g, 0.7 mmol), and tBuONa (0.77 g, 8.05 mmol) were added to toluene (17 ml), and the mixture was heated and stirred at 100° C. for 8 hours. Water was added, and the mixture was subjected to celite filtering and liquid separation to concentrate an organic layer. The resulting product was purified through silica gel column chromatography to obtain Compound 307 (3.68 g, yield: 74%). The FAB MS measurement shows that Compound 307 had a molecular weight of 1421.

Compound 307 was subjected to sublimation purification (390° C., 3.2×10−3 Pa) to evaluate a device.

### (6) Synthesis of Compound 361

Compound 361 according to an embodiment may be synthesized by, for example, processes of Reaction Formula 6 below.

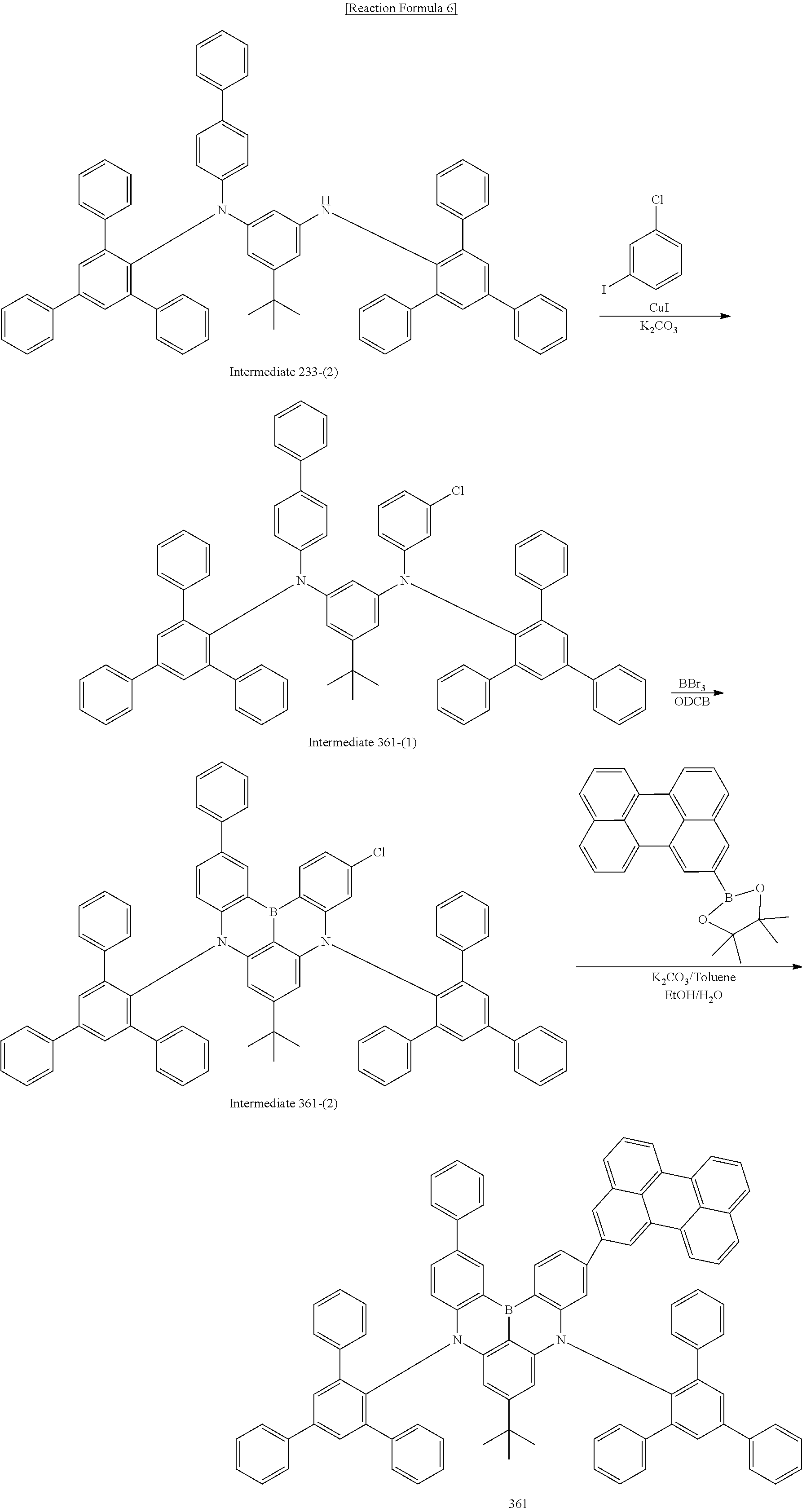

### 1) Synthesis of Intermediate Compound 361-(1)

Intermediate 233-(2) (15.05 g, 16.3 mmol), 1-chloro-3-iodobenzene (58.3 g, 244.48 mmol), CuI (6.52 g, 34.23 mmol), and K₂CO₃ (18.02 g, 130.39 mmol) were added to a small amount of toluene (about 10 ml), and the mixture was heated at a constant outside temperature of 215° C. for 24 hours. Water was added after the mixture was diluted with CH₂Cl₂ and the mixture was subjected to celite filtering and liquid separation to concentrate an organic layer. The resulting product was purified through silica gel column chromatography to obtain Intermediate 361-(1) (13.67 g, yield: 81%). The FAB MS measurement shows that Intermediate 361-(1) had a molecular weight of 1036.

### 2) Synthesis of Intermediate Compound 361-(2)

In an Ar atmosphere, Intermediate 361-(1) (12.04 g, 11.62 mmol) was dissolved in ODCB (116 ml) and BBr₃ (7.28 g, 29.06 mmol) was added, and the mixture was heated and stirred at 170° C. for 10 hours. The mixture was cooled at room temperature, and N,N-diisopropylethylamine (DIPEA, 17.99 g, 139.49 mmol) was added, and water was added, and then the mixture was subjected to celite filtering and liquid separation to concentrate an organic layer. The resulting product was purified through silica gel column chromatography to obtain Intermediate 361-(2) (6.55 g, yield: 54%). The FAB MS measurement shows that Intermediate 361-(2) had a molecular weight of 1044.

### 3) Synthesis of Compound 361

In an Ar atmosphere, Intermediate 361-(2) (6.21 g, 5.95 mmol), 4,4,5,5-tetramethyl-2-(perylen-2-yl)-1,3,2-dioxaborolane (4.5 g, 11.9 mmol), K₂CO₃ (2.53 g, 11.9 mmol), Pd(Ph₃P)₄ (0.69 g, 0.6 mmol), and toluene (49.68 ml) were added to a 1:1 mixture of EtOH and water (24.84 ml), and then the mixture was heated at a constant outside temperature of 80° C. for 24 hours. The mixture was subjected to celite filtering and liquid separation to concentrate an organic layer. The resulting product was purified through silica gel column chromatography to obtain Compound 361 (5.62 g, yield: 75%). The FAB MS measurement shows that Compound 361 had a molecular weight of 1259.

Compound 361 was subjected to sublimation purification (370° C., 3.2×10−3 Pa) to evaluate a device.

### (7) Synthesis of Compound 433

Compound 433 according to an embodiment may be synthesized by, for example, processes of Reaction Formula 7 below.

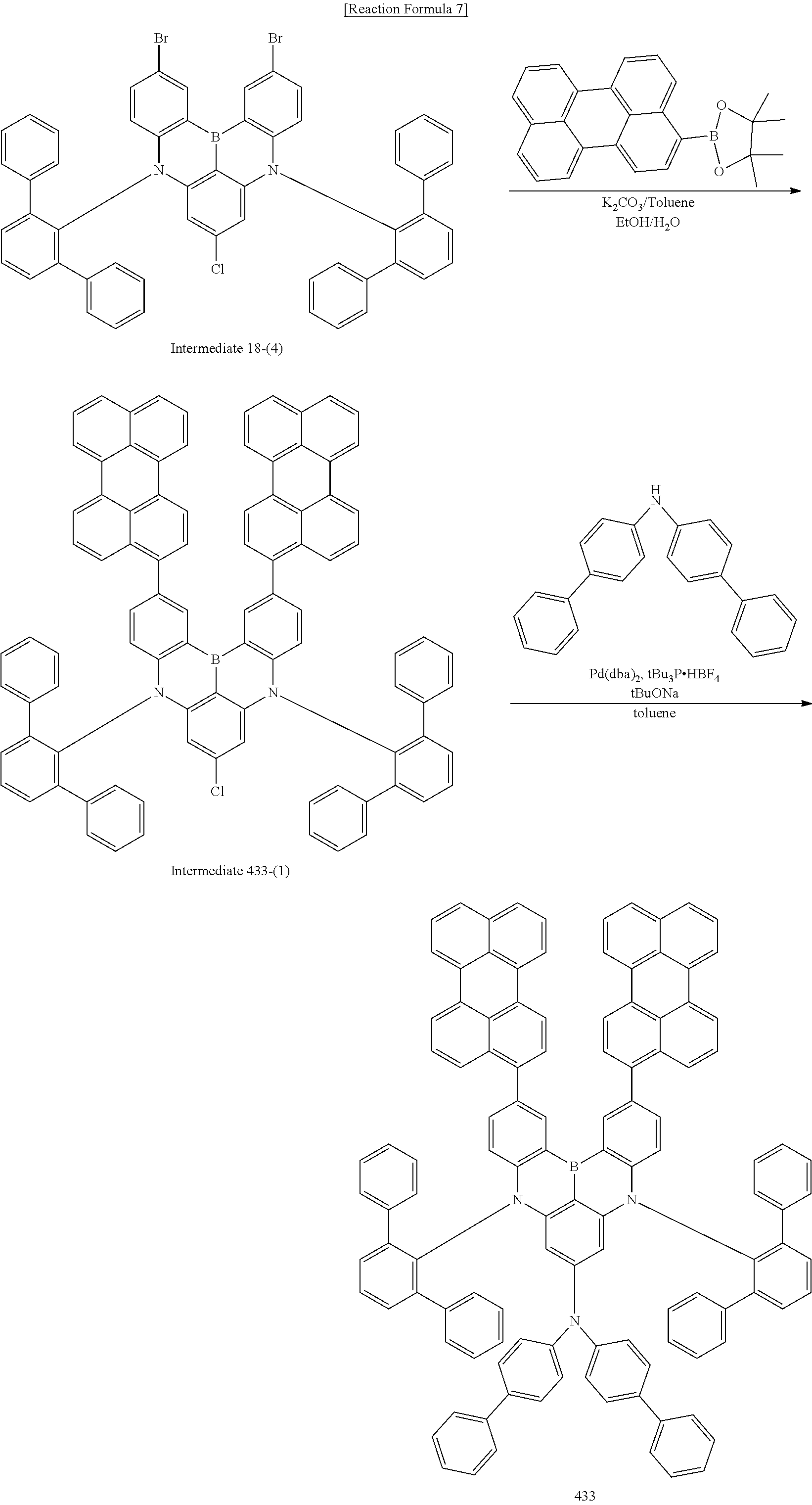

### 1) Synthesis of Intermediate Compound 433-(1)

In an Ar atmosphere, Intermediate 18-(4) (8.22 g, 8.96 mmol), 4,4,5,5-tetramethyl-2-(perylen-3-yl)-1,3,2-dioxaborolane (13.56 g, 35.86 mmol), K₂CO₃ (3.81 g, 17.93 mmol), Pd(Ph₃P)₄ (1.04 g, 0.9 mmol), and toluene (65.76 ml) were added to a 1:1 mixture of EtOH and water (32.88 ml), and then the mixture was heated at a constant outside temperature of 80° C. for 24 hours. The mixture was subjected to celite filtering and liquid separation to concentrate an organic layer. The resulting product was purified through silica gel column chromatography to obtain Intermediate 433-(1) (10.05 g, yield: 89%). The FAB MS measurement shows that Intermediate 433-(1) had a molecular weight of 1260.

### 2) Synthesis of Compound 433

In an Ar atmosphere, Intermediate 433-(1) (4.12 g, 3.27 mmol), di([1,1′-biphenyl]-4-yl)amine (1.58 g, 4.91 mmol), Pd(dba)₂ (0.19 g, 0.33 mmol), tBu₃P·HBF₄ (0.19 g, 0.65 mmol), and tBuONa (0.72 g, 7.52 mmol) were added to toluene (16 ml), and the mixture was heated and stirred at 100° C. for 8 hours. Water was added, and the mixture was subjected to celite filtering and liquid separation to concentrate an organic layer. The resulting product was purified through silica gel column chromatography to obtain Compound 433 (4.6 g, yield: 91%). The FAB MS measurement shows that Compound 433 had a molecular weight of 1545.

Compound 433 was subjected to sublimation purification (390° C., 2.2×10−3 Pa) to evaluate a device.

### (8) Synthesis of Compound 463

Compound 463 according to an embodiment may be synthesized by, for example, processes of Reaction Formula 8 below.

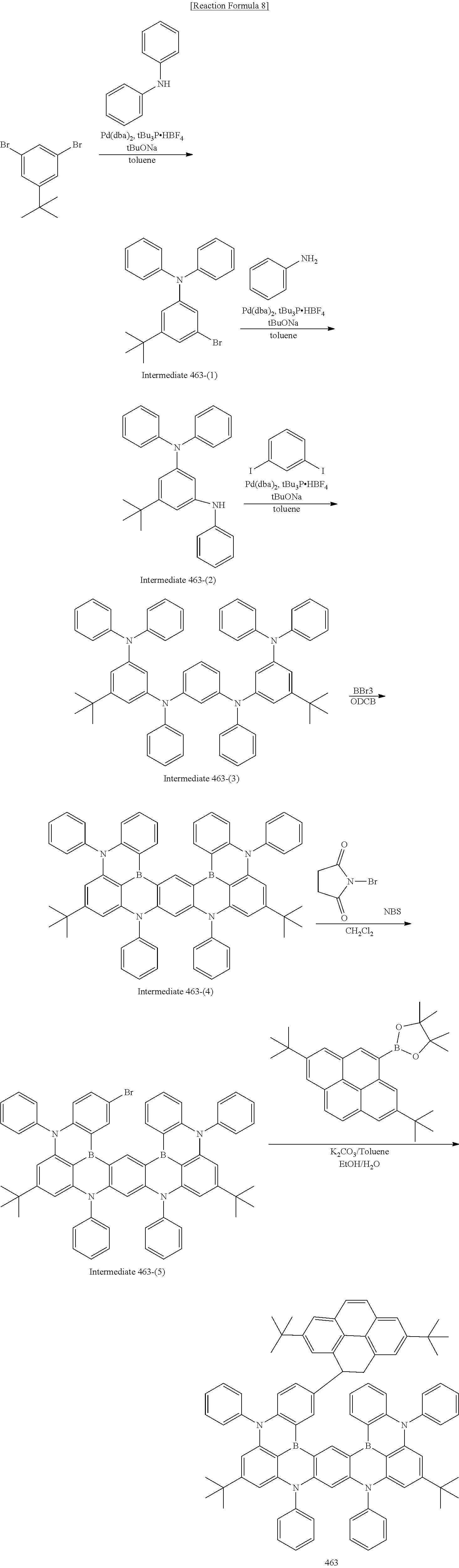

### 1) Synthesis of Intermediate Compound 463-(1)

In an Ar atmosphere, 1,3-dibromo-5-(tert-butyl)benzene (24.55 g, 84.07 mmol), diphenylamine (14.23 g, 84.07 mmol), Pd(dba)₂ (4.83 g, 8.41 mmol), tBu₃P·HBF₄ (4.88 g, 16.81 mmol), and tBuONa (18.58 g, 193.37 mmol) were added to toluene (420 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 463-(1) (16.95 g, yield: 53%). The FAB MS measurement shows that Intermediate 463-(1) had a molecular weight of 380.

### 2) Synthesis of Intermediate Compound 463-(2)

In an Ar atmosphere, Intermediate 463-(1) (16.03 g, 42.15 mmol), aniline (3.93 g, 42.15 mmol), Pd(dba)₂ (2.42 g, 4.21 mmol), tBu₃P·HBF₄ (2.45 g, 8.43 mmol), and tBuONa (9.32 g, 96.94 mmol) were added to toluene (210 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 463-(2) (13.57 g, yield: 82%). The FAB MS measurement shows that Intermediate 463-(2) had a molecular weight of 393.

### 3) Synthesis of Intermediate Compound 463-(3)

In an Ar atmosphere, 1,3-diiodobenzene (5.60 g, 16.97 mmol), Intermediate 463-(2) (13.33 g, 33.95 mmol), Pd(dba)₂ (0.98 g, 1.7 mmol), tBu₃P·HBF₄ (0.98 g, 3.39 mmol), and tBuONa (3.75 g, 39.04 mmol) were added to toluene (84 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 463-(3) (13.56 g, yield: 93%). The FAB MS measurement shows that Intermediate 463-(3) had a molecular weight of 859.

### 4) Synthesis of Intermediate Compound 463-(4)

In an Ar atmosphere, Intermediate 463-(3) (13.41 g, 15.61 mmol) was dissolved in ODCB (156 ml) and BBr₃ (9.78 g, 39.02 mmol) was added, and the mixture was heated and stirred at 170° C. for 10 hours. The mixture was cooled at room temperature, and N,N-diisopropylethylamine (DIPEA, 24.16 g, 187.3 mmol) was added, and water was added, and then the mixture was subjected to celite filtering and liquid separation to concentrate an organic layer. The resulting product was purified through silica gel column chromatography to obtain Intermediate 463-(4) (7.37 g, yield: 54%). The FAB MS measurement shows that Intermediate 463-(4) had a molecular weight of 875.

### 5) Synthesis of Intermediate Compound 463-(5)

In an Ar atmosphere, Intermediate 463-(4) (7.25 g, 8.29 mmol) was dissolved in CH₂C₁₂ (83 ml), and NBS (1.48 g, 8.29 mmol) was added, and then the mixture was stirred at room temperature for 24 hours. Water was added, and the mixture was subjected to celite filtering and liquid separation to concentrate an organic layer. The resulting product was purified through silica gel column chromatography to obtain Intermediate 463-(5) (4.11 g, yield: 52%). The FAB MS measurement shows that Intermediate 463-(5) had a molecular weight of 954.

### 6) Synthesis of Compound 463

In an Ar atmosphere, Intermediate 463-(5) (3.82 g, 4.17 mmol), 2-(2,7-di-tert-butylpyren-4-yl)-4,4,5,5-tetramethyl-1,3,2-dioxaborolane (6.30 g, 16.66 mmol), K₂CO₃ (1.77 g, 8.33 mmol), Pd(Ph₃P)₄ (0.48 g, 0.42 mmol), and toluene (30.56 ml) were added to a 1:1 mixture of EtOH and water (15.28 ml), and then the mixture was heated at a constant outside temperature of 80° C. for 24 hours. The mixture was subjected to celite filtering and liquid separation to concentrate an organic layer. The resulting product was purified through silica gel column chromatography to obtain Compound 463 (4.67 g, yield: 89%). The FAB MS measurement shows that Compound 463 had a molecular weight of 1260.

Compound 463 was subjected to sublimation purification (390° C., 2.6×10−3 Pa) to evaluate a device.

### (9) Synthesis of Compound 475

Compound 475 according to an embodiment may be synthesized by, for example, processes of Reaction Formula 9 below.

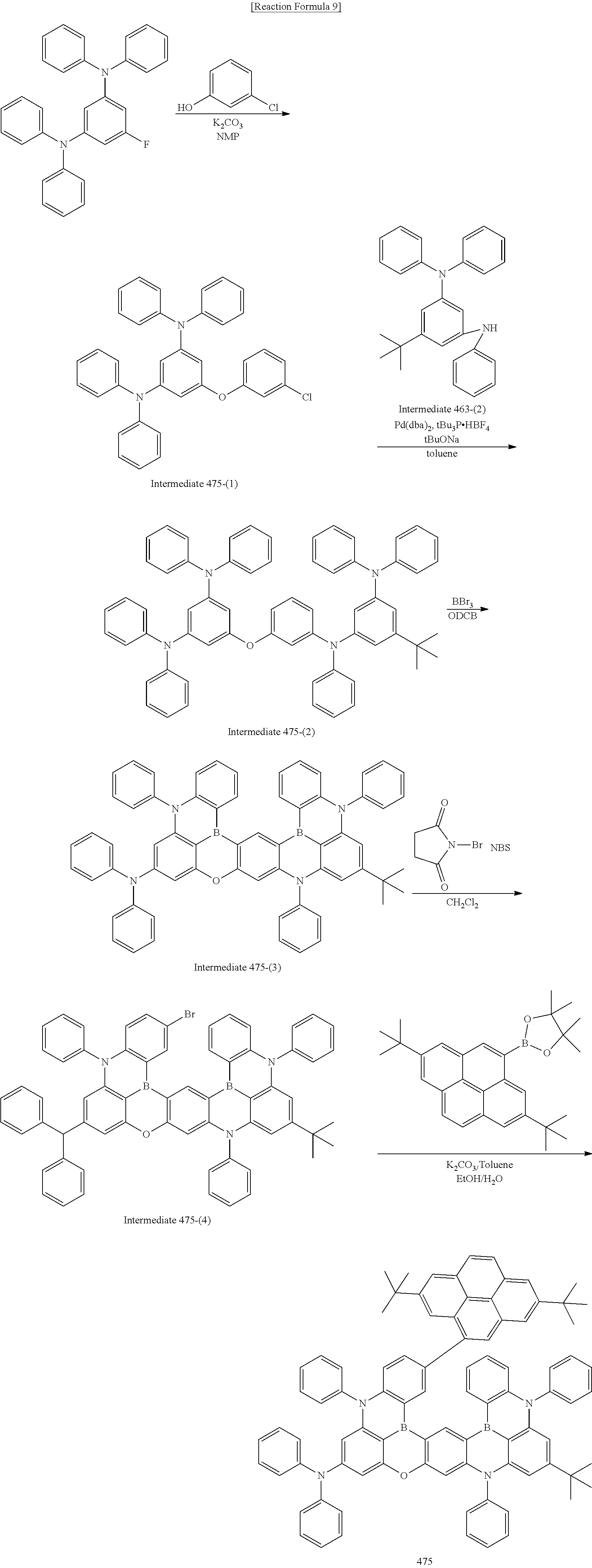

### 1) Synthesis of Intermediate Compound 475-(1)

In an Ar atmosphere, 5-fluoro-N1,N1,N3,N3-tetraphenylbenzene-1,3-diamine (15.5 g, 36 mmol), 3-chlorophenol (5.55 g, 43.2 mmol), and K₂CO₃ (22.39 g, 162.01 mmol) were added to NMP (155 ml) and the mixture was heated at a constant outside temperature of 180° C. for 24 hours. Water was added after the mixture was diluted with CH₂Cl₂, and the mixture was subjected to celite filtering and liquid separation to concentrate an organic layer. The resulting product was purified through silica gel column chromatography to obtain Intermediate 475-(1) (15.14 g, yield: 78%). The FAB MS measurement shows that Intermediate 475-(1) had a molecular weight of 539.

### 2) Synthesis of Intermediate Compound 475-(2)

In an Ar atmosphere, Intermediate 475-(1) (14.00 g, 25.97 mmol), Intermediate 463-(2) (10.19 g, 25.97 mmol), Pd(dba)₂ (1.49 g, 2.6 mmol), tBu₃P·HBF₄ (1.51 g, 5.19 mmol), and tBuONa (5.74 g, 59.73 mmol) were added to toluene (129 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 475-(2) (18.37 g, yield: 79%). The FAB MS measurement shows that Intermediate 475-(2) had a molecular weight of 895.

### 3) Synthesis of Intermediate Compound 475-(3)

In an Ar atmosphere, Intermediate 475-(2) (17.95 g, 20.05 mmol) was dissolved in ODCB (201 ml) and BBr₃ (12.56 g, 50.13 mmol) was added, and the mixture was heated and stirred at 170° C. for 10 hours. The mixture was cooled at room temperature, and N,N-diisopropylethylamine (DIPEA, 31.04 g, 240.63 mmol) was added, and water was added, and then the mixture was subjected to celite filtering and liquid separation to concentrate an organic layer. The resulting product was purified through silica gel column chromatography to obtain Intermediate 475-(3) (5.84 g, yield: 32%). The FAB MS measurement shows that Intermediate 475-(3) had a molecular weight of 911.

### 4) Synthesis of Intermediate Compound 475-(4)

In an Ar atmosphere, Intermediate 475-(3) (5.75 g, 6.31 mmol) was dissolved in CH₂C₁₂ (63 ml), and NBS (1.12 g, 6.31 mmol) was added, and then the mixture was stirred at room temperature for 24 hours. Water was added, and the mixture was subjected to celite filtering and liquid separation to concentrate an organic layer. The resulting product was purified through silica gel column chromatography to obtain Intermediate 475-(4) (4.69 g, yield: 75%). The FAB MS measurement shows that Intermediate 475-(4) had a molecular weight of 990.

### 5) Synthesis of Compound 475

In an Ar atmosphere, Intermediate 475-(4) (4.51 g, 4.56 mmol), 2-(2,7-di-tert-butylpyren-4-yl)-4,4,5,5-tetramethyl-1,3,2-dioxaborolane (6.9 g, 18.23 mmol), K₂CO₃ (1.93 g, 9.11 mmol), Pd(Ph₃P)₄ (0.53 g, 0.46 mmol), and toluene (36.08 ml) were added to a 1:1 mixture of EtOH and water (18.04 ml), and then the mixture was heated at a constant outside temperature of 80° C. for 24 hours. The mixture was subjected to celite filtering and liquid separation to concentrate an organic layer. The resulting product was purified through silica gel column chromatography to obtain Compound 475 (4.91 g, yield: 88%). The FAB MS measurement shows that Compound 475 had a molecular weight of 1223.

Compound 475 was subjected to sublimation purification (380° C., 2.3×10⁻³ Pa) to evaluate a device.

### (10) Synthesis of Compound 487

Compound 487 according to an embodiment may be synthesized by, for example, processes of Reaction Formula 10 below.

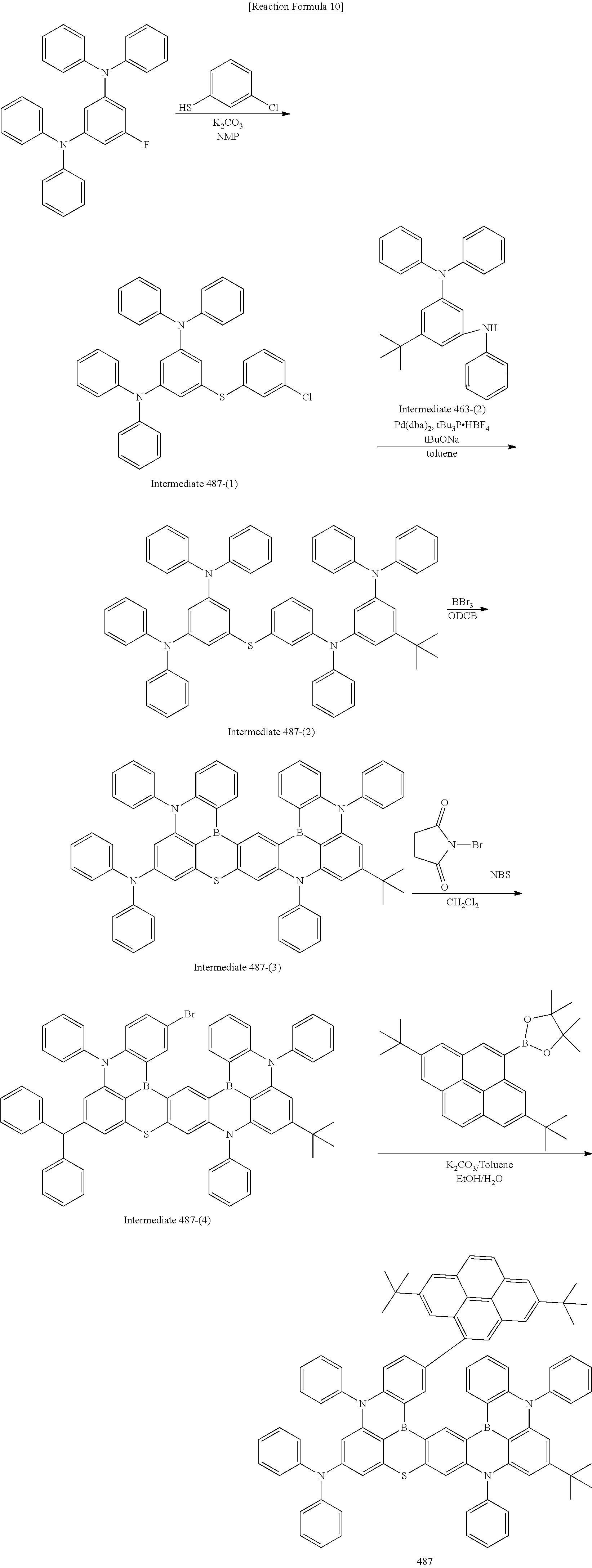

### 1) Synthesis of Intermediate Compound 487-(1)

In an Ar atmosphere, 5-fluoro-N1,N1,N3,N3-tetraphenylbenzene-1,3-diamine (15.08 g, 35.03 mmol), 3-chlorobenzenethiol (6.08 g, 42.03 mmol), and K₂CO₃ (21.78 g, 157.62 mmol) were added to NMP (150 ml) and the mixture was heated at a constant outside temperature of 180° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 487-(1) (15.75 g, yield: 81%). The FAB MS measurement shows that Intermediate 487-(1) had a molecular weight of 555.

### 2) Synthesis of Intermediate Compound 487-(2)

In an Ar atmosphere, Intermediate 487-(1) (14 g, 25.22 mmol), Intermediate 463-(2) (9.9 g, 25.22 mmol), Pd(dba)₂ (1.45 g, 2.52 mmol), tBu₃P·HBF₄ (1.46 g, 5.04 mmol), and tBuONa (5.57 g, 58 mmol) were added to toluene (126 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 487-(2) (19.3 g, yield: 84%). The FAB MS measurement shows that Intermediate 487-(2) had a molecular weight of 911.

### 3) Synthesis of Intermediate Compound 487-(3)

In an Ar atmosphere, Intermediate 487-(2) (17.95 g, 19.7 mmol) was dissolved in ODCB (197 ml) and BBr₃ (20.23 g, 80.77 mmol) was added, and the mixture was heated and stirred at 170° C. for 10 hours. The mixture was cooled at room temperature, and N,N-diisopropylethylamine (DIPEA, 30.49 g, 236.39 mmol) was added, and water was added, and then the mixture was subjected to celite filtering and liquid separation to concentrate an organic layer. The resulting product was purified through silica gel column chromatography to obtain Intermediate 487-(3) (4.93 g, yield: 27%). The FAB MS measurement shows that Intermediate 487-(3) had a molecular weight of 927.

### 4) Synthesis of Intermediate Compound 487-(4)

In an Ar atmosphere, Intermediate 487-(3) (4.81 g, 5.18 mmol) was dissolved in CH₂C₁₂ (52 ml), and NBS (0.92 g, 5.18 mmol) was added, and then the mixture was stirred at room temperature for 24 hours. Water was added, and the mixture was subjected to celite filtering and liquid separation to concentrate an organic layer. The resulting product was purified through silica gel column chromatography to obtain Intermediate 487-(4) (3.28 g, yield: 63%). The FAB MS measurement shows that Intermediate 487-(4) had a molecular weight of 1006.

### 5) Synthesis of Compound 487

In an Ar atmosphere, Intermediate 487-(4) (3.01 g, 2.99 mmol), 2-(2,7-di-tert-butylpyren-4-yl)-4,4,5,5-tetramethyl-1,3,2-dioxaborolane (4.53 g, 11.97 mmol), K₂CO₃ (1.27 g, 5.99 mmol), Pd(Ph₃P)₄ (0.35 g, 0.3 mmol), and toluene (24.08 ml) were added to a 1:1 mixture of EtOH and water (12.04 ml), and then the mixture was heated at a constant outside temperature of 80° C. for 24 hours. The mixture was subjected to celite filtering and liquid separation to concentrate an organic layer. The resulting product was purified through silica gel column chromatography to obtain Compound 487 (3 g, yield: 81%). The FAB MS measurement shows that Compound 487 had a molecular weight of 1239.

Compound 487 was subjected to sublimation purification (330° C., 2.5×10−3 Pa) to evaluate a device.

### (11) Synthesis of Compound 516

Compound 516 according to an embodiment may be synthesized by, for example, processes of Reaction Formula 11 below.

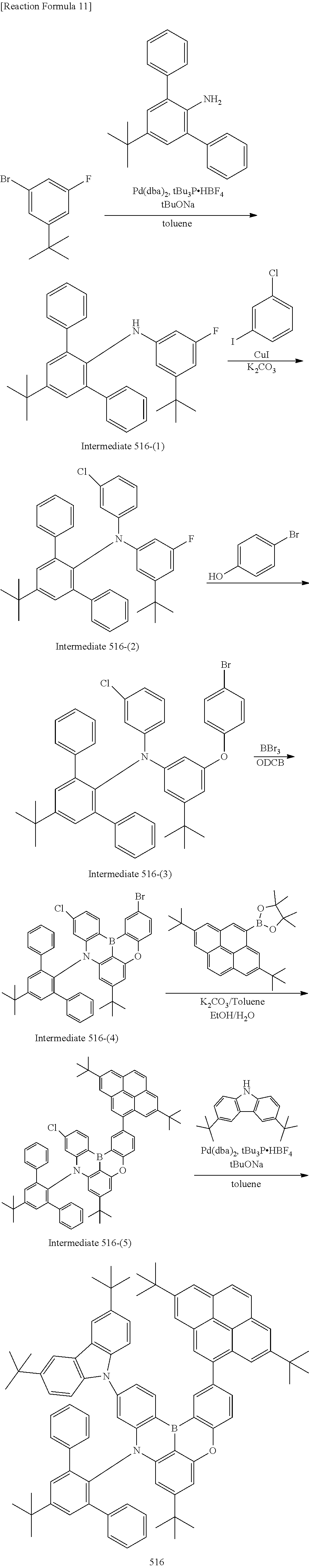

### 1) Synthesis of Intermediate Compound 516-(1)

In an Ar atmosphere, 1-bromo-3-(tert-butyl)-5-fluorobenzene (15.02 g, 64.99 mmol), 5′-(tert-butyl)-[1,1′:3′,1″-terphenyl]-2′-amine (19.59 g, 64.99 mmol), Pd(dba)₂ (3.74 g, 6.5 mmol), tBu₃P·HBF₄ (3.77 g, 13 mmol), and tBuONa (14.36 g, 149.48 mmol) were added to toluene (324 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 516-(1) (26.12 g, yield: 89%). The FAB MS measurement shows that Intermediate 516-(1) had a molecular weight of 452.

### 2) Synthesis of Intermediate Compound 516-(2)

Intermediate 516-(1) (25 g, 55.36 mmol), 1-chloro-3-iodobenzene (197.99 g, 830.33 mmol), CuI (22.14 g, 116.25 mmol), and K₂CO₃ (61.2 g, 442.84 mmol) were added to a small amount of toluene (about 10 ml), and the mixture was heated at a constant outside temperature of 215° C. for 24 hours. Water was added after the mixture was diluted with CH₂Cl₂, and the mixture was subjected to celite filtering and liquid separation to concentrate an organic layer. The resulting product was purified through silica gel column chromatography to obtain Intermediate 516-(2) (25.21 g, yield: 81%). The FAB MS measurement shows that Intermediate 516-(2) had a molecular weight of 562.

### 3) Synthesis of Intermediate Compound 516-(3)

In an Ar atmosphere, Intermediate 516-(2) (24.01 g, 42.71 mmol), 4-bromophenol (8.87 g, 51.25 mmol), and K₂CO₃ (26.56 g, 192.19 mmol) were added to NMP (240 ml) and the mixture was heated at a constant outside temperature of 180° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 516-(3) (19.85 g, yield: 65%). The FAB MS measurement shows that Intermediate 516-(3) had a molecular weight of 715.

### 4) Synthesis of Intermediate Compound 516-(4)

In an Ar atmosphere, Intermediate 516-(3) (18.32 g, 25.62 mmol) was dissolved in ODCB (256 ml) and BBr₃ (12.83 g, 51.23 mmol) was added, and the mixture was heated and stirred at 170° C. for 10 hours. The mixture was cooled at room temperature, and N,N-diisopropylethylamine (DIPEA, 39.65 g, 307.4 mmol) was added, and water was added, and then the mixture was subjected to celite filtering and liquid separation to concentrate an organic layer. The resulting product was purified through silica gel column chromatography to obtain Intermediate 516-(4) (8.33 g, yield: 45%). The FAB MS measurement shows that Intermediate 516-(4) had a molecular weight of 723.

### 5) Synthesis of Intermediate Compound 516-(5)

In an Ar atmosphere, Intermediate 516-(4) (5.2 g, 7.19 mmol), 2-(2,7-di-tert-butylpyren-4-yl)-4,4,5,5-tetramethyl-1,3,2-dioxaborolane (12.67 g, 28.77 mmol), K₂CO₃ (3.05 g, 14.39 mmol), Pd(Ph₃P)₄ (0.83 g, 0.72 mmol), and toluene (41.6 ml) were added to a 1:1 mixture of EtOH and water (20.8 ml), and then the mixture was heated at a constant outside temperature of 80° C. for 24 hours. The mixture was subjected to celite filtering and liquid separation to concentrate an organic layer. The resulting product was purified through silica gel column chromatography to obtain Intermediate 516-(5) (5.09 g, yield: 74%). The FAB MS measurement shows that Intermediate 516-(5) had a molecular weight of 957.

### 6) Synthesis of Compound 516

In an Ar atmosphere, Intermediate 516-(5) (4.12 g, 4.31 mmol), 3,6-di-tert-butyl-9H-carbazole (3.01 g, 10.77 mmol), Pd(dba)₂ (0.25 g, 0.43 mmol), tBu₃P·HBF₄ (0.25 g, 0.86 mmol), and tBuONa (0.95 g, 9.91 mmol) were added to toluene (21 ml), and the mixture was heated and stirred at 100° C. for 8 hours. Water was added, and the mixture was subjected to celite filtering and liquid separation to concentrate an organic layer. The resulting product was purified through silica gel column chromatography to obtain Compound 516 (3.87 g, yield: 75%). The FAB MS measurement shows that Compound 516 had a molecular weight of 1199.

Compound 516 was subjected to sublimation purification (340° C., 2.5×10−3 Pa) to evaluate a device.

### (12) Synthesis of Compound 520

Compound 520 according to an embodiment may be synthesized by, for example, processes of Reaction Formula 12 below.

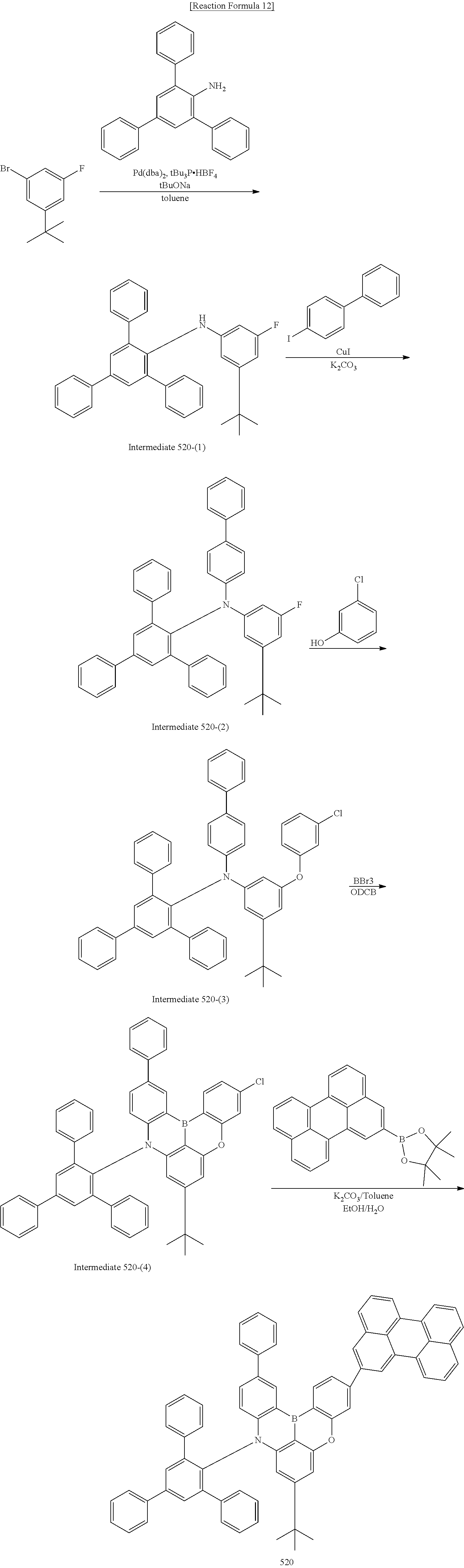

### 1) Synthesis of Intermediate Compound 520-(1)

In an Ar atmosphere, 1-bromo-3-(tert-butyl)-5-fluorobenzene (15 g, 64.9 mmol), 5′-phenyl-[1,1′:3′,1″-terphenyl]-2′-amine (52.15 g, 162.26 mmol), Pd(dba)₂ (3.73 g, 6.49 mmol), tBu₃P·HBF₄ (3.77 g, 12.98 mmol), and tBuONa (14.35 g, 149.28 mmol) were added to toluene (324 ml), and the mixture was heated and stirred at 100° C. for 8 hours. Water was added, and the mixture was subjected to celite filtering and liquid separation to concentrate an organic layer. The resulting product was purified through silica gel column chromatography to obtain Intermediate 520-(1) (20.81 g, yield: 68%). The FAB MS measurement shows that Intermediate 520-(1) had a molecular weight of 472.

### 2) Synthesis of Intermediate Compound 520-(2)

Intermediate 520-(1) (20.52 g, 43.51 mmol), 4-iodo-1,1′-biphenyl (182.81 g, 652.64 mmol), CuI (17.4 g, 91.37 mmol), and K₂CO₃ (48.11 g, 348.08 mmol) were added to a small amount of toluene (about 10 ml), and the mixture was heated at a constant outside temperature of 215° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 520-(2) (15.2 g, yield: 56%). The FAB MS measurement shows that Intermediate 520-(2) had a molecular weight of 624.

### 3) Synthesis of Intermediate Compound 520-(3)

In an Ar atmosphere, Intermediate 520-(2) (14.82 g, 23.76 mmol), 3-chlorophenol (3.67 g, 28.51 mmol), and K₂CO₃ (14.78 g, 106.91 mmol) were added to NMP (148 ml) and the mixture was heated at a constant outside temperature of 180° C. for 24 hours. Water was added after the mixture was diluted with CH₂C₁₂, and the mixture was subjected to celite filtering and liquid separation to concentrate an organic layer. The resulting product was purified through silica gel column chromatography to obtain Intermediate 520-(3) (12.87 g, yield: 74%). The FAB MS measurement shows that Intermediate 520-(3) had a molecular weight of 732.

### 4) Synthesis of Intermediate Compound 520-(4)

In an Ar atmosphere, Intermediate 520-(3) (12.11 g, 16.54 mmol) was dissolved in ODCB (165 ml) and BBr₃ (8.28 g, 33.07 mmol) was added, and the mixture was heated and stirred at 170° C. for 10 hours. The mixture was cooled at room temperature, and N,N-diisopropylethylamine (DIPEA, 25.6 g, 198.43 mmol) was added, and water was added, and then the mixture was subjected to celite filtering and liquid separation to concentrate an organic layer. The resulting product was purified through silica gel column chromatography to obtain Intermediate 520-(4) (4.65 g, yield: 38%). The FAB MS measurement shows that Intermediate 520-(4) had a molecular weight of 740.

### 5) Synthesis of Compound 520

In an Ar atmosphere, Intermediate 520-(4) (4.43 g, 5.99 mmol), 4,4,5,5-tetramethyl-2-(perylen-2-yl)-1,3,2-dioxaborolane (9.06 g, 23.94 mmol), K₂CO₃ (2.54 g, 11.97 mmol), Pd(Ph₃P)₄ (0.69 g, 0.6 mmol), and toluene (35.44 ml) were added to a 1:1 mixture of EtOH and water (17.72 ml), and then the mixture was heated at a constant outside temperature of 80° C. for 24 hours. The mixture was subjected to celite filtering and liquid separation to concentrate an organic layer. The resulting product was purified through silica gel column chromatography to obtain Compound 520 (4.23 g, yield: 74%). The FAB MS measurement shows that Compound 520 had a molecular weight of 956.

Compound 520 was subjected to sublimation purification (320° C., 2.4×10−3 Pa) to evaluate a device.

### 2. Preparation and Evaluation of Light Emitting Elements

### (1) Preparation of Light Emitting Elements

Light emitting elements including polycyclic compounds according to an Example Compound or a Comparative Example Compound were prepared through a method described below. Light emitting elements of Examples 1 to 12 were prepared respectively using Compounds 18, 147, 154, 233, 307, 361, 433, 463, 475, 487, 516, and 520 as a dopant material of an emission layer. Light emitting elements of Comparative Examples 1 to 9 were prepared using Comparative Example Compounds X₁ to X₉ as a dopant material of an emission layer.

As a first electrode, glass substrate, on which an ITO layer having a thickness of 150 nm was patterned, was subjected to ultrasonic cleaning using isopropyl alcohol and pure water each for 5 minutes. The glass substrate was irradiated with UV for 30 minutes, and treated with ozone. HAT-CN was deposited at a thickness of 10 nm, a-NPD was deposited at a thickness of 80 nm, and mCP was deposited at a thickness of 5 nm to form a hole transport region.

An Example Compound or a Comparative Example Compound, and mCBP were co-deposited to form an emission layer having a thickness of 20 nm. Example Compounds or Comparative Example Compounds, and mCBP were co-deposited at a weight ratio of 1:99. In the preparation of the light emitting elements, the Example Compounds or Comparative Example Compounds were used as a dopant material.

On the emission layer, TBPi was deposited at a thickness of 30 nm and LiF was deposited at a thickness of 0.5 nm to form an electron transport region.

Al was deposited on the electron transport region to form a second electrode having a thickness of 100 nm, thereby preparing a light emitting element.

In an embodiment, the hole transport region, the emission layer, the electron transport region, and the second electrode were formed using a vacuum deposition apparatus.

Example Compounds and Comparative Example Compounds used for preparing the light emitting elements are as follows.

### Example Compounds

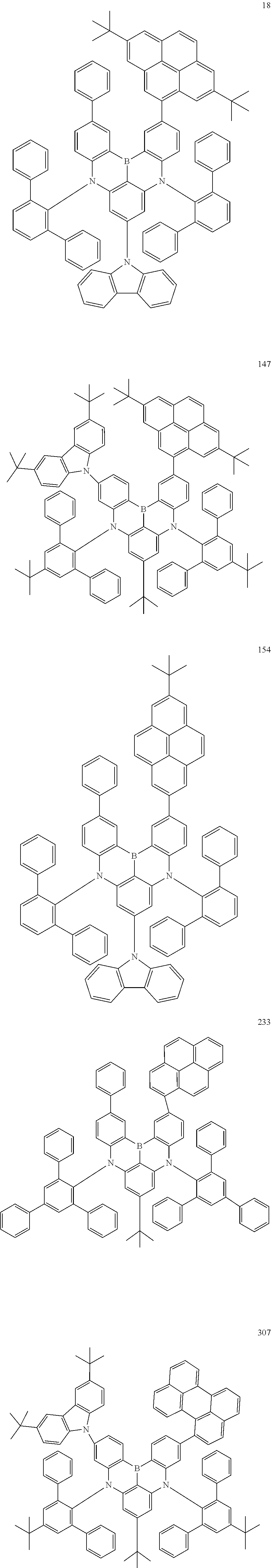

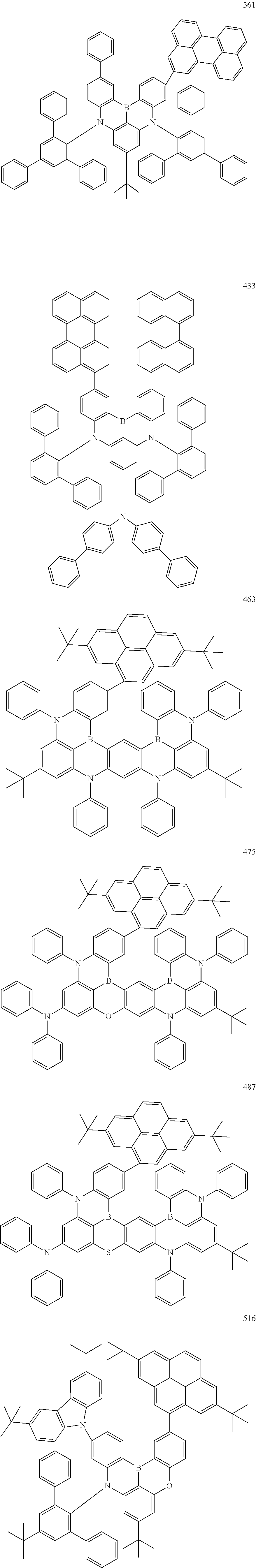

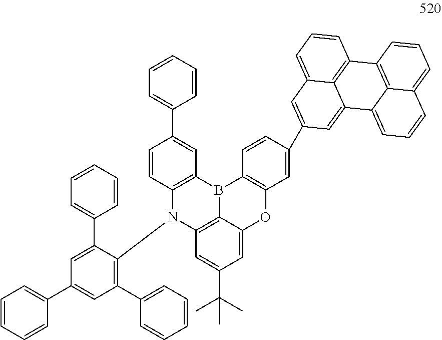 [SMILES: CC(C)(C)c1cc2c3c(c1)N(c1c(-c4ccccc4)cc(-c4ccccc4)cc1-c1ccccc1)c1ccc(-c4ccccc4)cc1B3c1ccc(-c3cc4cccc5c6cccc7cccc(c(c3)c45)c76)cc1O2]

### Comparative Example Compounds

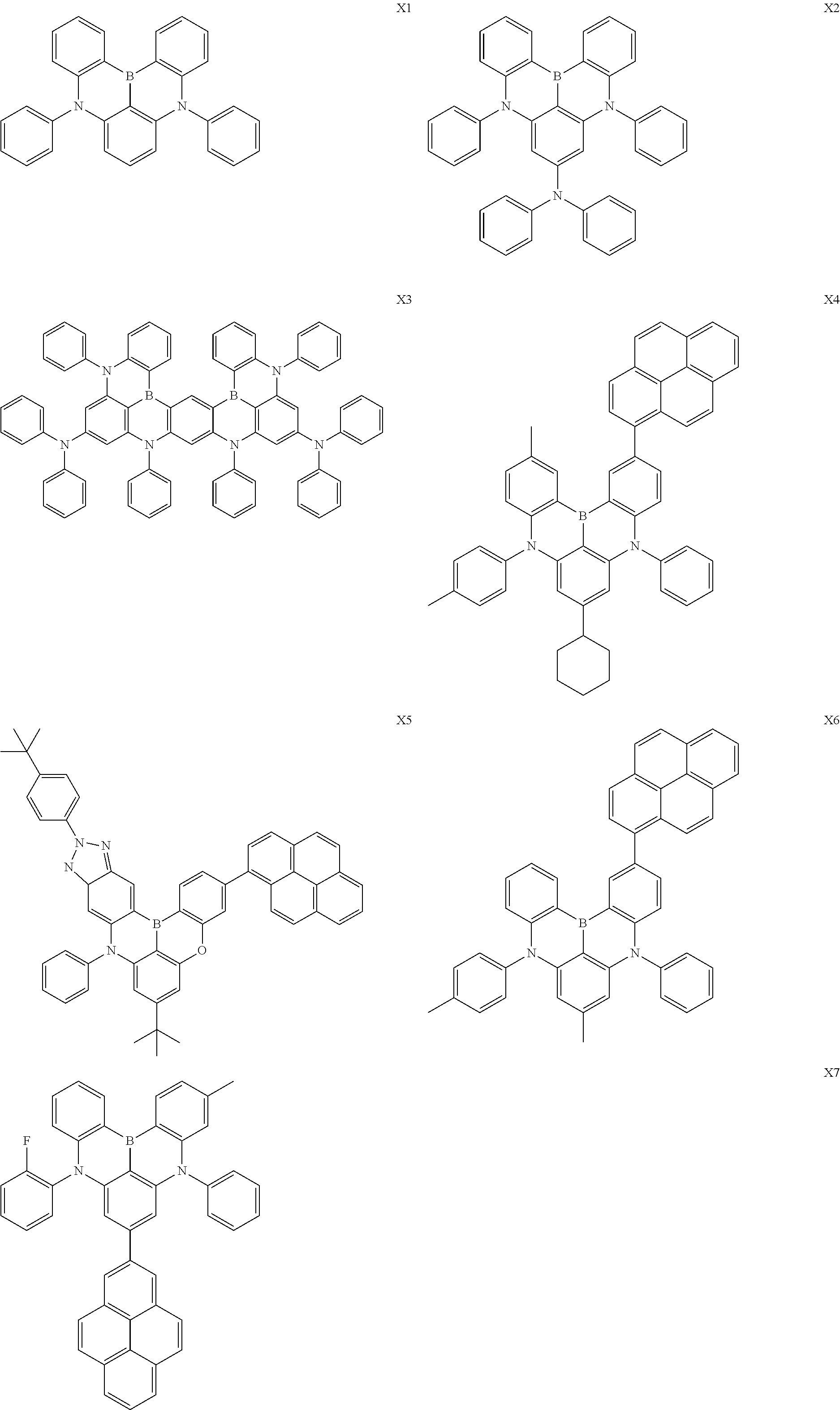

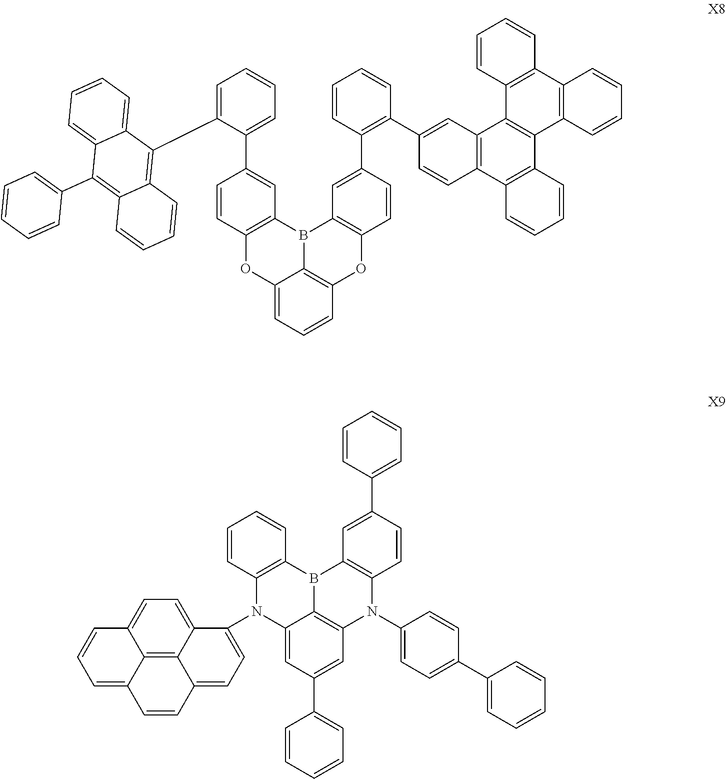 [SMILES: c1ccc(-c2c3ccccc3c(-c3ccccc3-c3ccc4c(c3)B3c5cc(-c6ccccc6-c6ccc7c8ccccc8c8c9ccccc9c9ccccc9c8c7c6)ccc5Oc5cccc(c53)O4)c3ccccc23)cc1 ; c1ccc(-c2ccc(N3c4ccc(-c5ccccc5)cc4B4c5ccccc5N(c5ccc6ccc7cccc8ccc5c6c78)c5cc(-c6ccccc6)cc3c54)cc2)cc1]

### (Other Materials Used Upon Preparation of Light Emitting Elements)

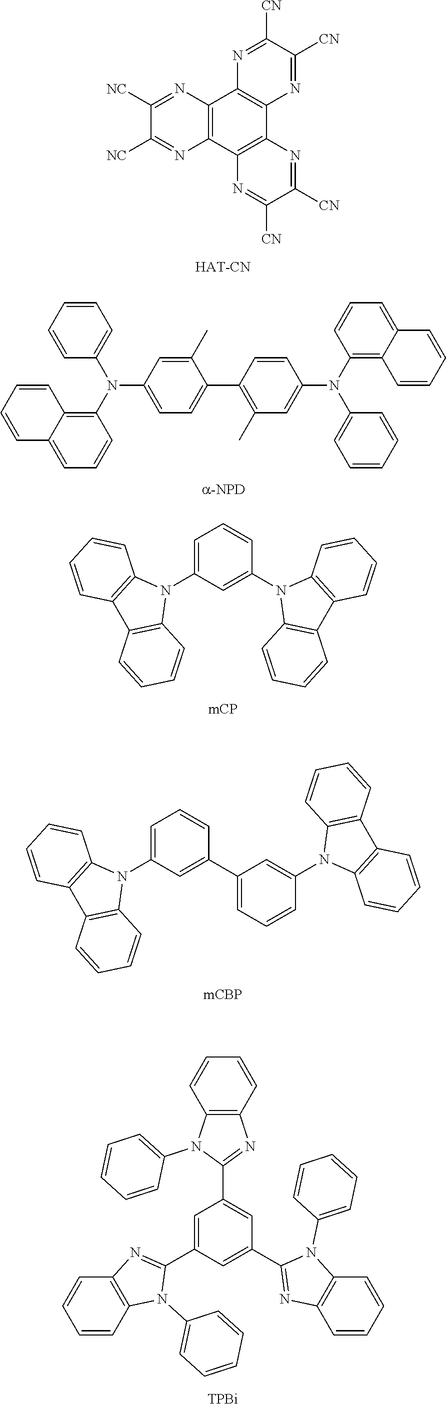

### (2) Evaluation of Light Emitting Elements

Table 1 shows evaluation results of light emitting elements for Examples 1 to 12 and Comparative Examples 1 to 9. In Table 1, maximum emission wavelength (λₘₐₓ), delayed fluorescence lifetime, roll-off, and relative lifetime (LT50) of the prepared light emitting elements are shown and compared. In the evaluation of the light emitting elements, the maximum emission wavelength (λₘₐₓ) indicates a maximum emission wavelength value in the emission spectrum of a light emitting element, and luminescence decay time (μS) indicates a value calculated from time-resolved photoluminescence (TRPL) spectra at room temperature for a 20 nm thick thin film formed of a dopant (1.0 wt %) and a host (mCBP, 99 wt %), with an Example Compound or a Comparative Example Compound as the dopant.

In the evaluation results for the Examples and the Comparative Examples shown in Table 1, the roll-off is indicated by [[(external quantum efficiency at 1 cd/m³)−(external quantum efficiency at 1000 cd/m³)]/(external quantum efficiency at 1 cd/m³)]×100. The relative lifetime is indicated by evaluating the luminance half-life at an initial luminance of 100 cd/m². The relative lifetime was shown to be relative with respect to the results of Comparative Example 3.

TABLE 1

| | | λₘₐₓ | Luminescence | | Relative lifetime |
|---|---|---|---|---|---|
| | Dopant | (nm) | decay time (μS) | Roll-off (%) | (LT50) |
| Example 1 | 18 | 463 | non | 10.3 | 4.0 |
| Example 2 | 147 | 460 | non | 10.5 | 5.9 |
| Example 3 | 154 | 459 | non | 11.9 | 4.1 |
| Example 4 | 233 | 462 | non | 13.0 | 4.8 |
| Example 5 | 307 | 459 | non | 10.1 | 6.0 |
| Example 6 | 361 | 458 | non | 8.2 | 4.6 |
| Example 7 | 433 | 458 | non | 8.3 | 3.5 |
| Example 8 | 463 | 458 | non | 7.4 | 6.5 |
| Example 9 | 475 | 461 | non | 9.3 | 7.2 |
| Example 10 | 487 | 460 | non | 6.3 | 7.5 |
| Example 11 | 516 | 455 | non | 10.2 | 4.5 |
| Example 12 | 520 | 460 | non | 12.2 | 4.1 |
| Comparative Example 1 | X1 | 457 | 130 | 33.2 | 0.3 |
| Comparative Example 2 | X2 | 446 | 11.2 | 30.5 | 0.2 |
| Comparative Example 3 | X3 | 467 | 5.5 | 13.5 | 1.0 |
| Comparative Example 4 | X4 | 463 | non | 52.5 | 0.31 |
| Comparative Example 5 | X5 | 470 | non | 82.1 | 0.05 |
| Comparative Example 6 | X6 | 460 | non | 48.1 | 0.35 |
| Comparative Example 7 | X7 | 468 | non | 45.2 | 0.25 |
| Comparative Example 8 | X8 | 472 | non | 55.2 | 0.15 |
| Comparative Example 9 | X9 | 470 | non | 65.2 | 0.03 |

Referring to Table 1, the light emitting elements of Examples 1 to 12 showed long service life compared to the light emitting elements of Comparative Examples 1 to 9. The polycyclic compound according to an embodiment has a structure in which, among the three benzene rings included in a core, a naphthyl group to which at least two benzene rings are fused is substituted on a benzene ring bonded to a boron atom, and an aryl group or a heteroaryl group is substituted in another benzene ring bonded to a boron atom. It can be seen that the light emitting element according to an embodiment including the polycyclic compound according to an embodiment as an emission layer material showed long service life compared to a light emitting element according to a Comparative Example, which has a structure in which, among the three benzene rings included in a core, a naphthyl group to which at least two benzene rings are fused is not substituted on any one benzene ring bonded to a boron atom, or an aryl group or a heteroaryl group is not substituted in another benzene ring bonded to a boron atom.

In Table 1, what is marked as “non” for the luminescence decay time has a specific value of 1 S or less, and thus is shown to be not observed through a time measurement in S units.

Referring to Table 1, the maximum emission wavelength (λₘₐₓ) of Examples 1 to 12 was about 460 nm and exhibited color purity close to pure blue. The service life of Examples 1 to 12 showed improved properties compared to Comparative Examples 1 to 9.

Examples 1 to 12 exhibit lower roll-off properties than Comparative Examples 1 to 9. For this reason, it is considered that Examples 1 to 12 show results of significantly improved service life as compared with Comparative Examples 1 to 9.

Comparative Example Compounds X1 to X3 are different from the Example Compounds in that the Compounds X1 to X3 do not include a naphthyl group to which at least two benzene rings are fused.

Comparative Example Compounds X4 to X6 are different from the Example Compounds in that a naphthyl group to which at least two benzene rings are fused is substituted on any one benzene ring bonded to a boron atom, but an aryl group or a heteroaryl group is not substituted in another benzene ring bonded to a boron atom.

Comparative Example Compound X7 is different from the Example Compounds in that a naphthyl group to which at least two benzene rings are fused is substituted on a benzene ring which is not bonded to a boron atom. Comparative Example Compound X9 is different from the Example Compounds in that a naphthyl group to which at least two benzene rings are fused is substituted on a nitrogen atom.

Comparative Example Compound X8 is different from the Example Compounds in which a naphthyl group to which at least two benzene rings are fused is directly bonded to a benzene ring bonded to a boron atom, in that a naphthyl group to which at least two benzene rings are fused is bonded to a benzene ring bonded to a boron atom through a linker.

Thus, the Example Compounds have a structure in which a naphthyl group to which at least two benzene rings are fused is substituted on any one benzene ring bonded to a boron atom, and an aryl group or a heteroaryl group is substituted in another benzene ring bonded to a boron atom, and are thus considered to have stable molecular structures. The light emitting elements of the Examples include the Example Compounds having a stable molecular structure as a material of an emission layer, and thus are considered to exhibit long service life.

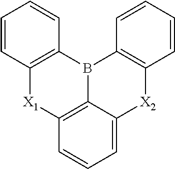

The polycyclic compound according to an embodiment has a structure in which a naphthyl group to which at least two benzene rings are fused is substituted on any one benzene ring bonded to a boron atom and a core portion of a fused ring containing boron and a hetero atom as a ring-forming atom, and an aryl group or a heteroaryl group is substituted in another benzene ring bonded to a boron atom, and may thus exhibit excellent molecular structure stability. A light emitting element including the polycyclic compound of an embodiment may exhibit long service life.

A light emitting element according to an embodiment includes a polycyclic compound according to an embodiment, and may thus exhibit long service life.

A polycyclic compound according to an embodiment may contribute to achieving greater light emitting efficiency and long service life of a light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein the emission layer includes:
a first compound represented by Formula 1; and
at least one of a second compound and a third compound: 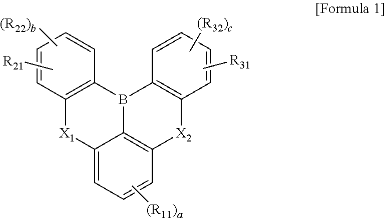
wherein in Formula 1,
a to c are each independently an integer from 0 to 3,
X₁ and X₂ are each independently O, S, or N(Rₐ),
at least one of R₂₁ and R₃₁ is each independently a group represented by Formula 2, and
the remainder of R₂₁ and R₃₁ is a substituted or unsubstituted aryl group having 6 to 30 ring-forming carbon atoms or a substituted or unsubstituted heteroaryl group having 2 to 30 ring-forming carbon atoms,
Rₐ is a substituted or unsubstituted aryl group having 6 to 30 ring-forming carbon atoms, or a substituted or unsubstituted heteroaryl group having 2 to 30 ring-forming carbon atoms, and is not a group represented by Formula 2,
R₁₁, R₂₂, and R₃₂ are each independently a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or are bonded to an adjacent group to form a ring, and
at least one hydrogen atom in Formula 1 is optionally substituted with a deuterium atom; and 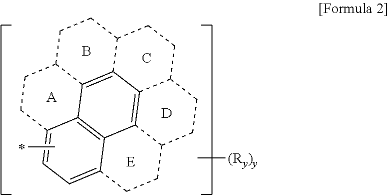
wherein in Formula 2,
at least two of A to E are each a benzene ring,
the remainder of A to E are not present,
y is an integer from 0 to 11,
R_{y} is a hydrogen atom, a deuterium atom, a halogen atom, or a substituted or unsubstituted alkyl group having 1 to 20 carbon atoms, [symbol]
represents a bond to a neighboring atom in Formula 1, and
at least one hydrogen atom in Formula 2 is optionally substituted with a deuterium atom.

2. The light emitting element of claim 1, wherein the first compound is represented by Formula 3-1 or Formula 3-2: 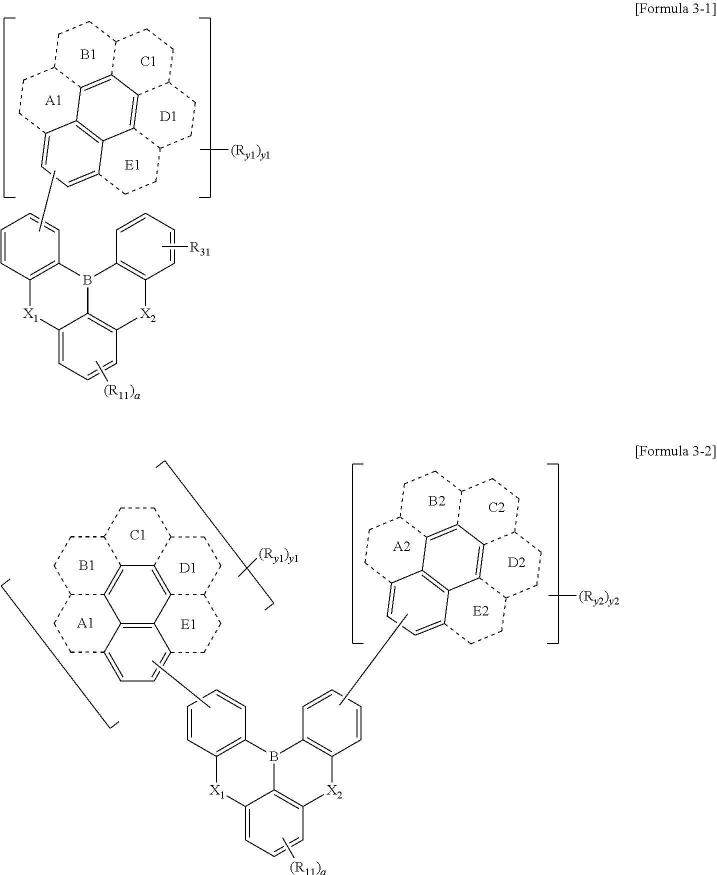
wherein in Formulas 3-1 and 3-2,
at least two of A1 to E1 are each a benzene ring,
the remainder of A1 to E1 are not present,
at least two of A2 to E2 are each a benzene ring,
the remainder of A2 to E2 are not present,
y1 and y2 are each independently an integer from 0 to 11,
R_{y1} and R_{y2} are each independently a hydrogen atom, a deuterium atom, a halogen atom, or a substituted or unsubstituted alkyl group having 1 to 20 carbon atoms,
a, R₁₁, R₃₁, X₁, and X₂ are the same as defined in Formula 1, and
at least one hydrogen atom in Formulas 3-1 and 3-2 is optionally substituted with a deuterium atom.

3. The light emitting element of claim 2, wherein in Formula 3-1, R₃₁ is a substituted or unsubstituted carbazole group or a substituted or unsubstituted phenyl group.

4. The light emitting element of claim 1, wherein the first compound is represented by one of Formulas 4-1 to 4-3: 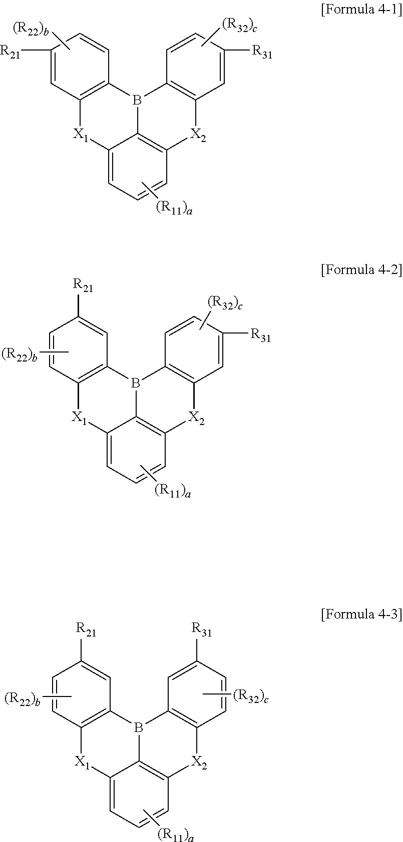
wherein in Formulas 4-1 to 4-3,
a, b, c, X₁, X₂, R₁₁, R₂₁, R₃₁, R₂₂, and R₃₂ are the same as defined in Formula 1, and
at least one hydrogen atom in Formulas 4-1 to 4-3 is optionally substituted with a deuterium atom.

5. The light emitting element of claim 1, wherein the first compound is represented by Formula 5: 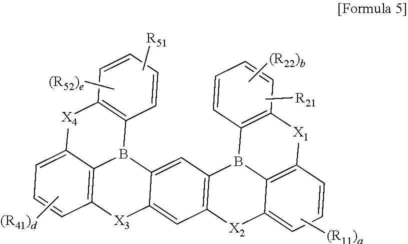
wherein in Formula 5,
at least one of R₂₁ and R₅₁ is each independently a group represented by Formula 2,
the remainder of R₂₁ and R₅₁ is a substituted or unsubstituted aryl group having 6 to 30 ring-forming carbon atoms or a substituted or unsubstituted heteroaryl group having 2 to 30 ring-forming carbon atoms,
X₃ and X₄ are each independently O, S, or N(R_{b}),
d and e are each independently an integer from 0 to 3,
R_{b} is a substituted or unsubstituted aryl group having 6 to 30 ring-forming carbon atoms or a substituted or unsubstituted heteroaryl group having 2 to 30 ring-forming carbon atoms, and is not a group represented by Formula 2,
R₄₁ and R₅₂ are each independently a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
a, b, R₁₁, R₂₂, X₁, and X₂ are the same as defined in Formula 1, and
at least one hydrogen atom in Formula 5 is optionally substituted with a deuterium atom.

6. The light emitting element of claim 1, wherein a group represented by Formula 2 is represented by one of Formulas D1 to D6: 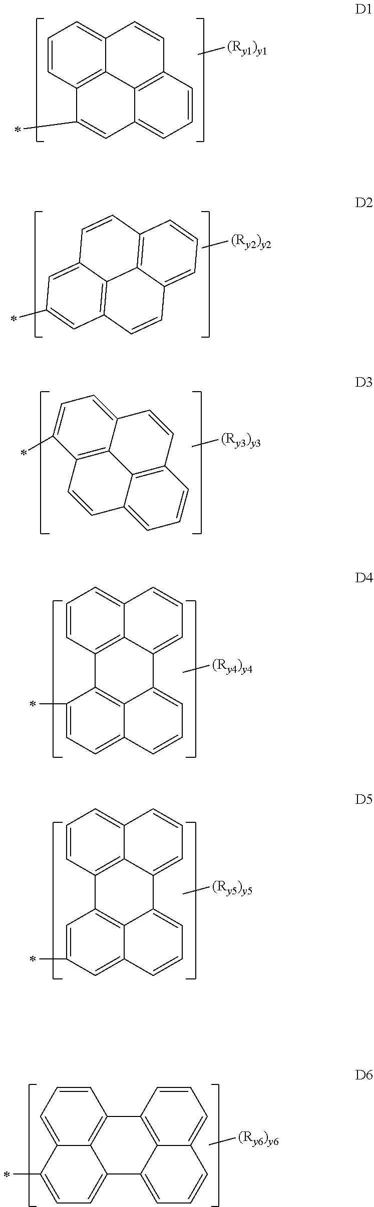
wherein in Formulas D1 to D6,
y1 to y3 are each independently an integer from 0 to 9,
y4 to y6 are each independently an integer from 0 to 11,
R_{y1} to R_{y6} are each independently a hydrogen atom, a deuterium atom, or an unsubstituted t-butyl group, [symbol]
represents a bond to a neighboring atom in Formula 1, and
at least one hydrogen atom in Formulas D1 to D6 is optionally substituted with a deuterium atom.

7. The light emitting element of claim 1, wherein the second compound is represented by Formula HT-1: 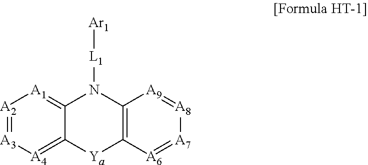
wherein in Formula HT-1,
A₁ to A₄ and A₆ to A₉ are each independently N or C(R₄₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₄₂)(R₄₃), or Si(R₄₄)(R₄₅),
Ar₁ is a substituted or unsubstituted aryl group having 6 to 30 ring-forming carbon atoms or a substituted or unsubstituted heteroaryl group having 2 to 30 ring-forming carbon atoms, and
R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring.

8. The light emitting element of claim 1, wherein the third compound is represented by Formula ET-1: 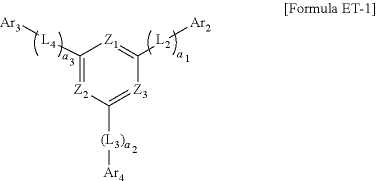
wherein in Formula ET-1,
at least one of Z₁ to Z₃ is each N,
the remainder of Z₁ to Z₃ are each independently C(R₃),
Rₐ₃ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
a₁ to a₃ are each independently an integer from 0 to 10,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

9. The light emitting element of claim 1, wherein
the emission layer further comprises a fourth compound, and
the fourth compound is represented by Formula D-1: 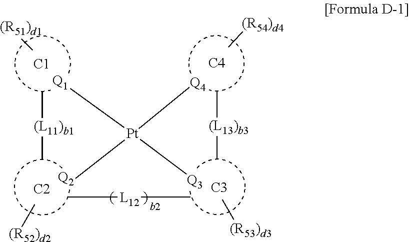
wherein in Formula D-1,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, 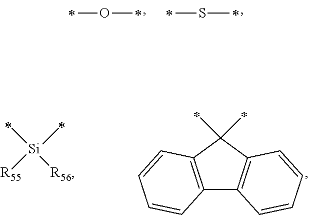
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
in L₁₁ to L₁₃, [symbol] represents a bond to one of C1 to C4,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer from 0 to 4.

10. The light emitting element of claim 9, wherein the emission layer comprises the first compound, the second compound, the third compound, and the fourth compound.

11. The light emitting element of claim 1, wherein the emission layer emits blue light.

12. The light emitting element of claim 1, wherein the emission layer emits thermally activated delayed fluorescence.

13. The light emitting element of claim 1, wherein the emission layer comprises at least one compound selected from Compound Group 1: 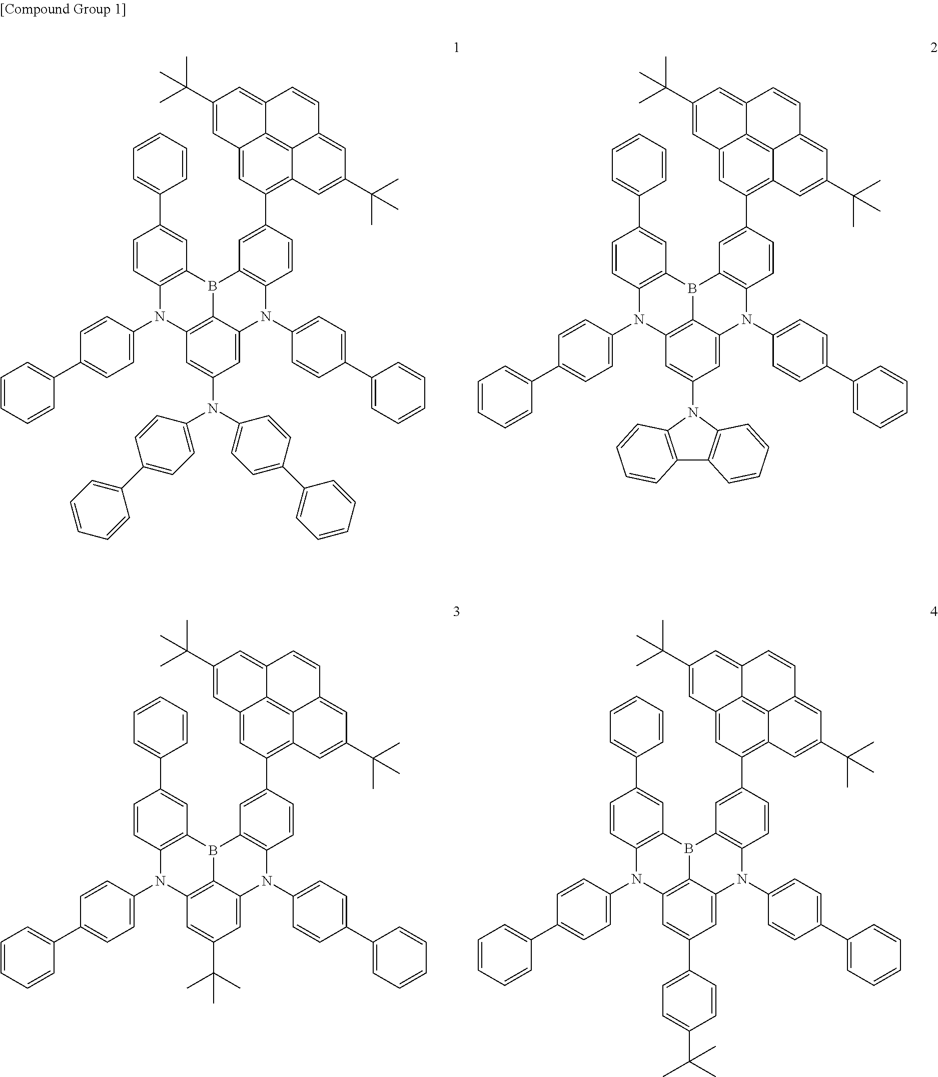 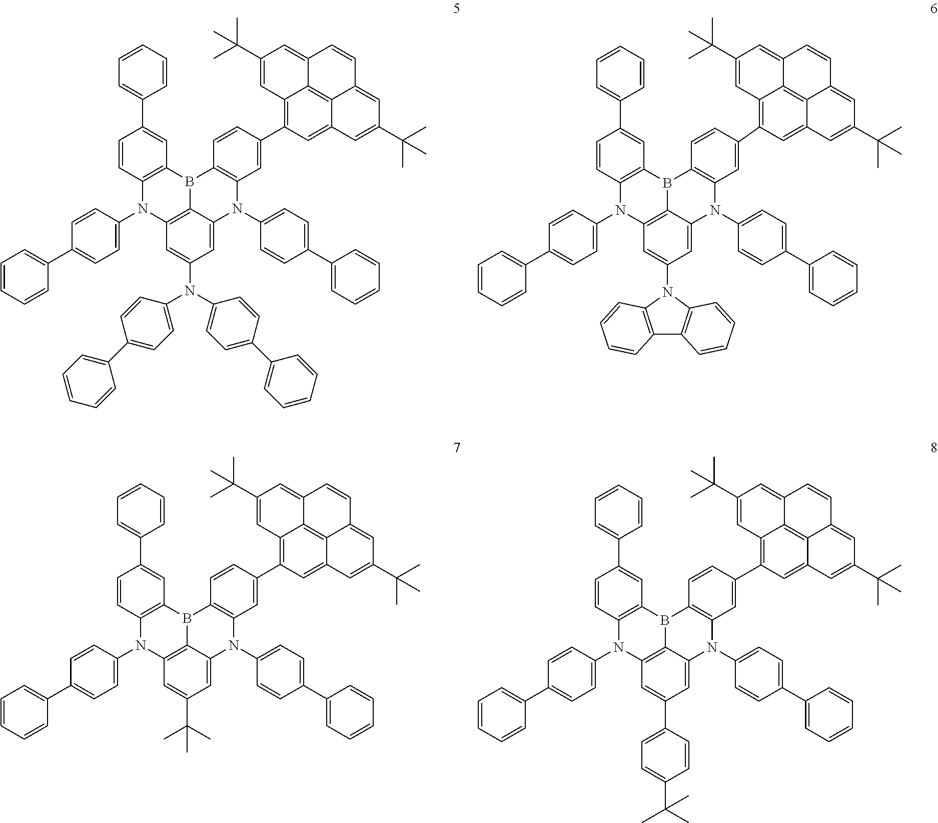 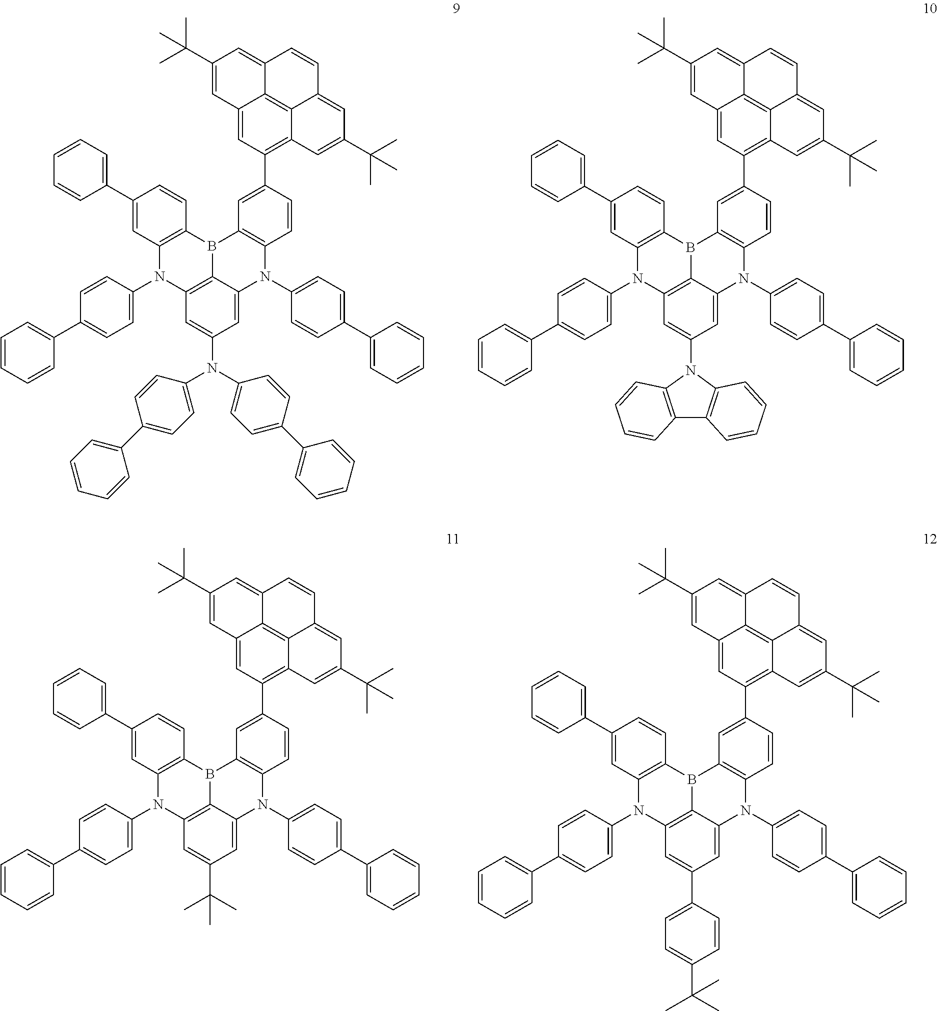 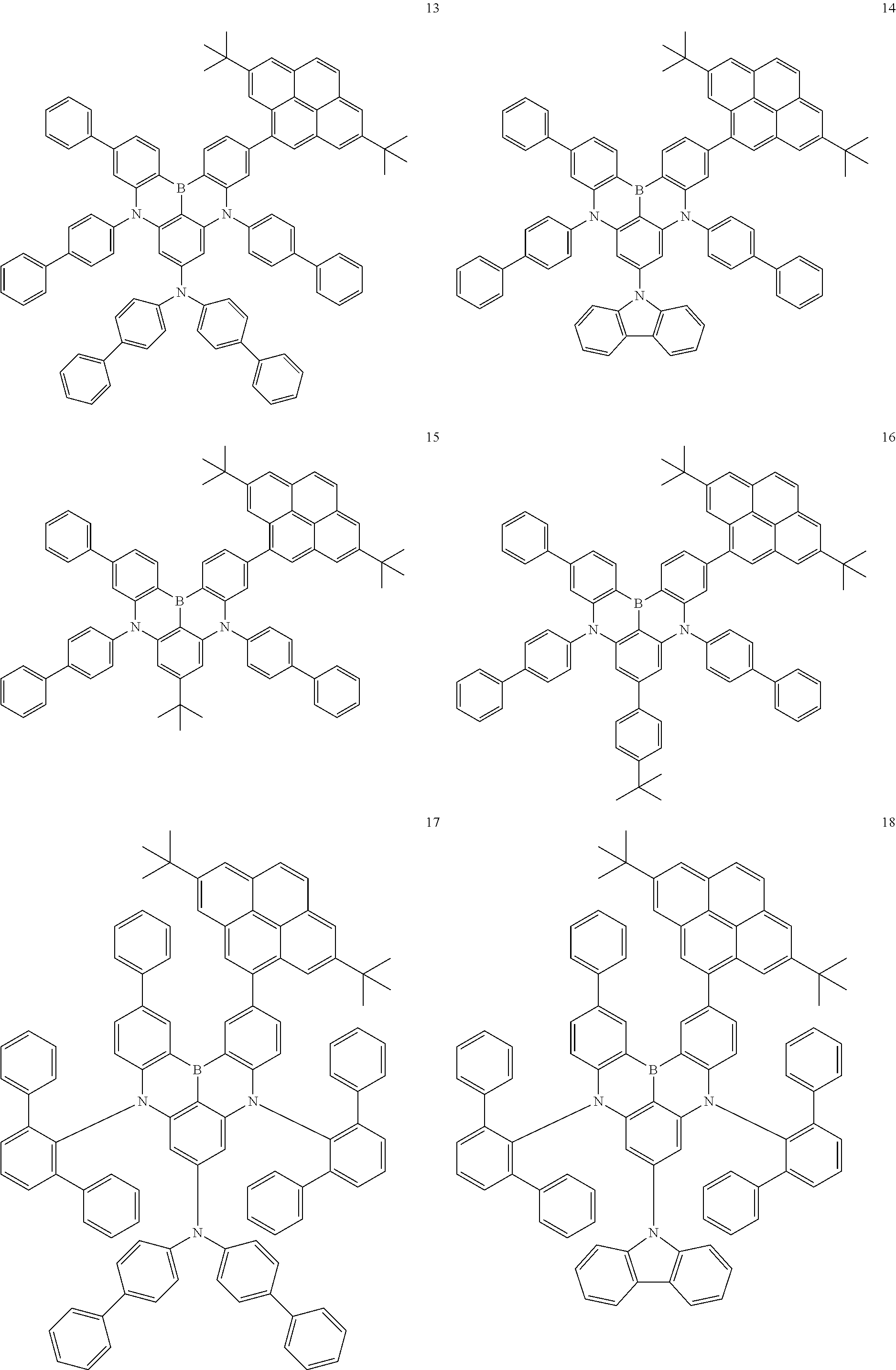 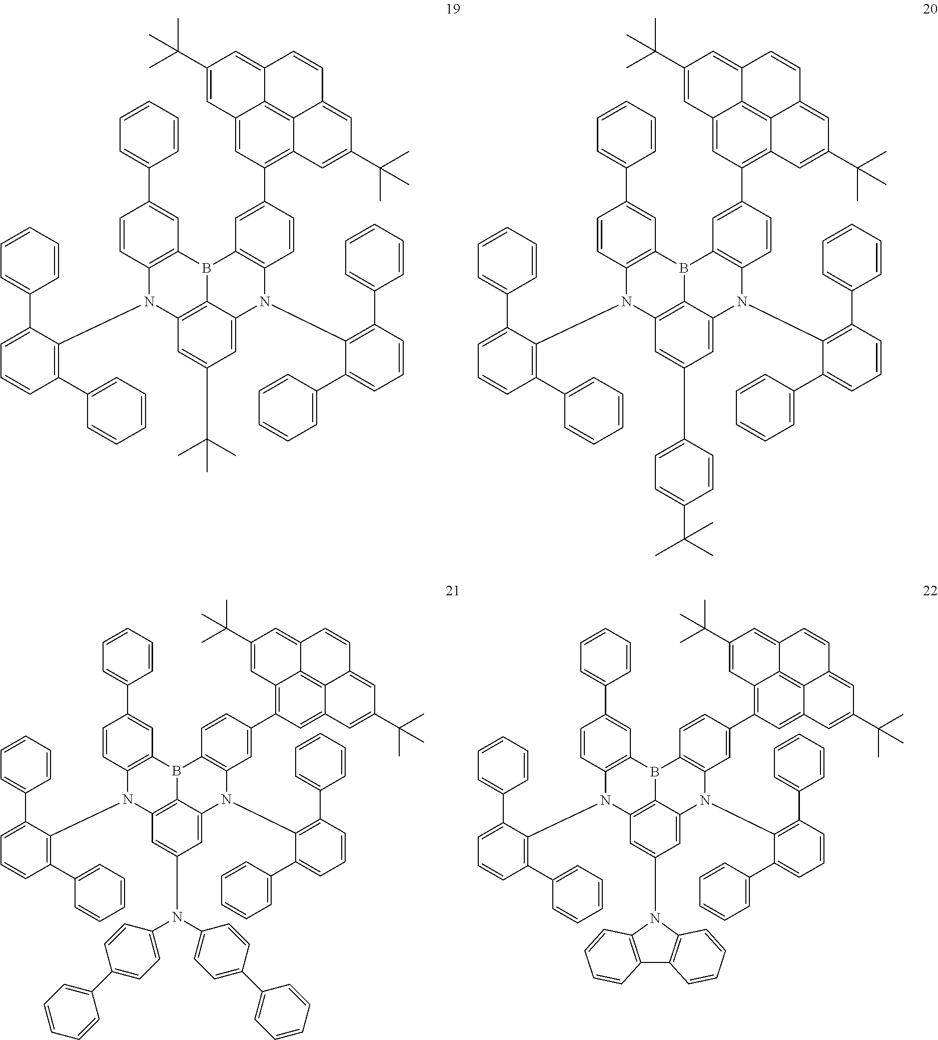 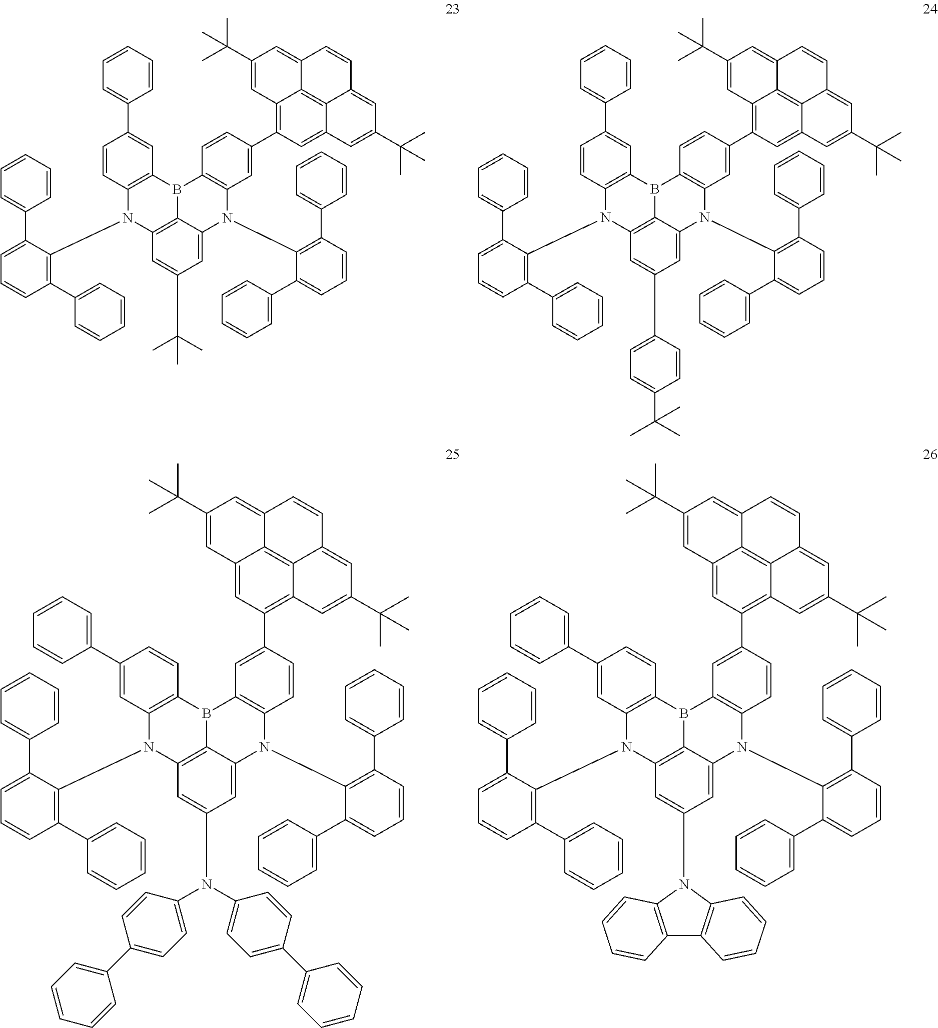 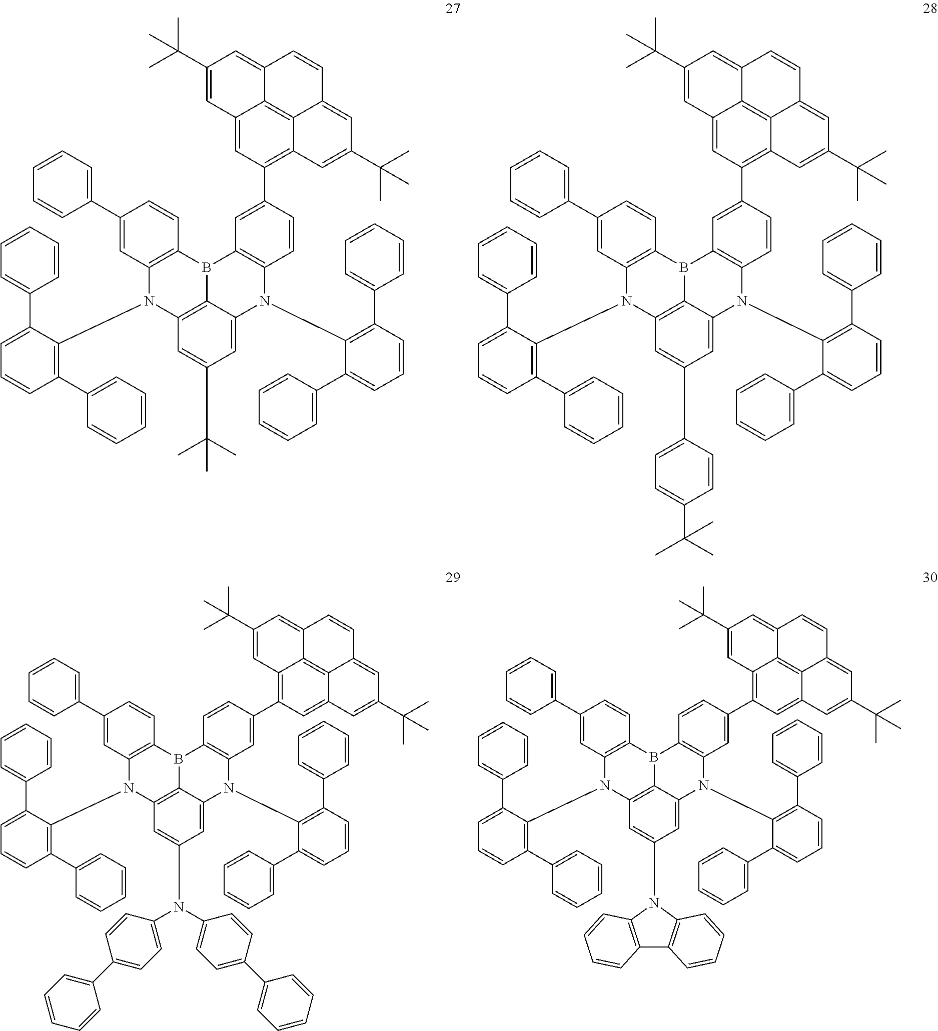 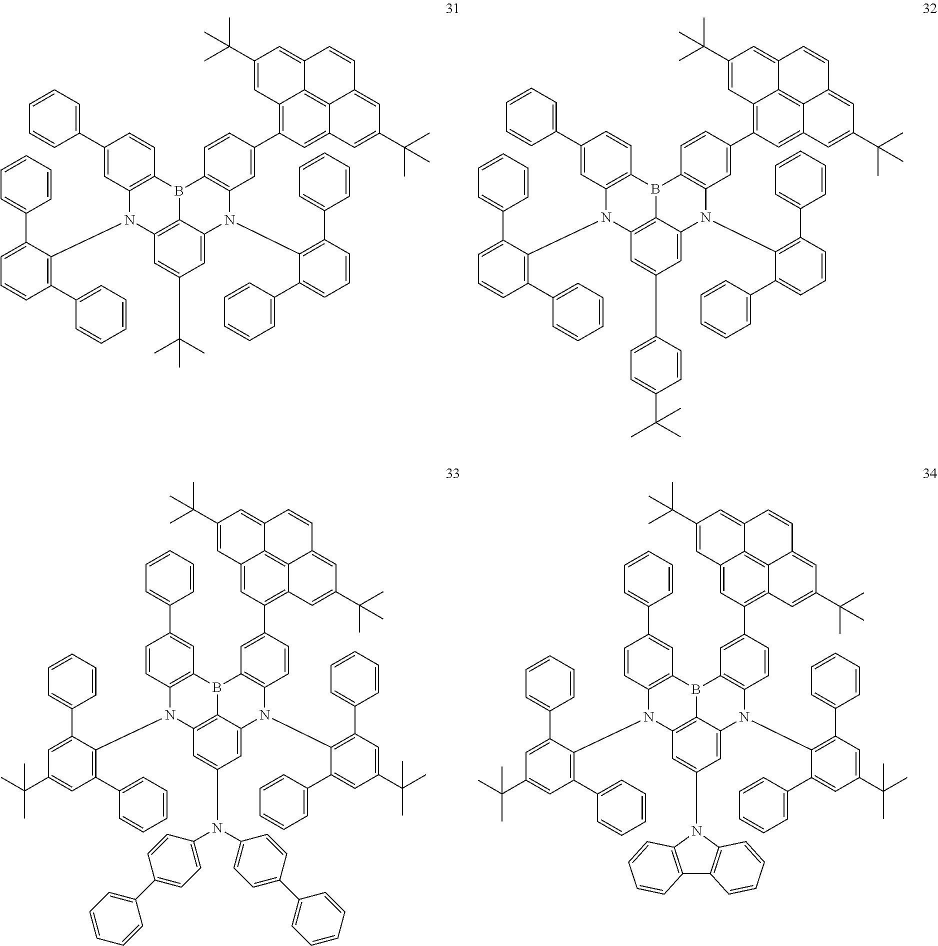 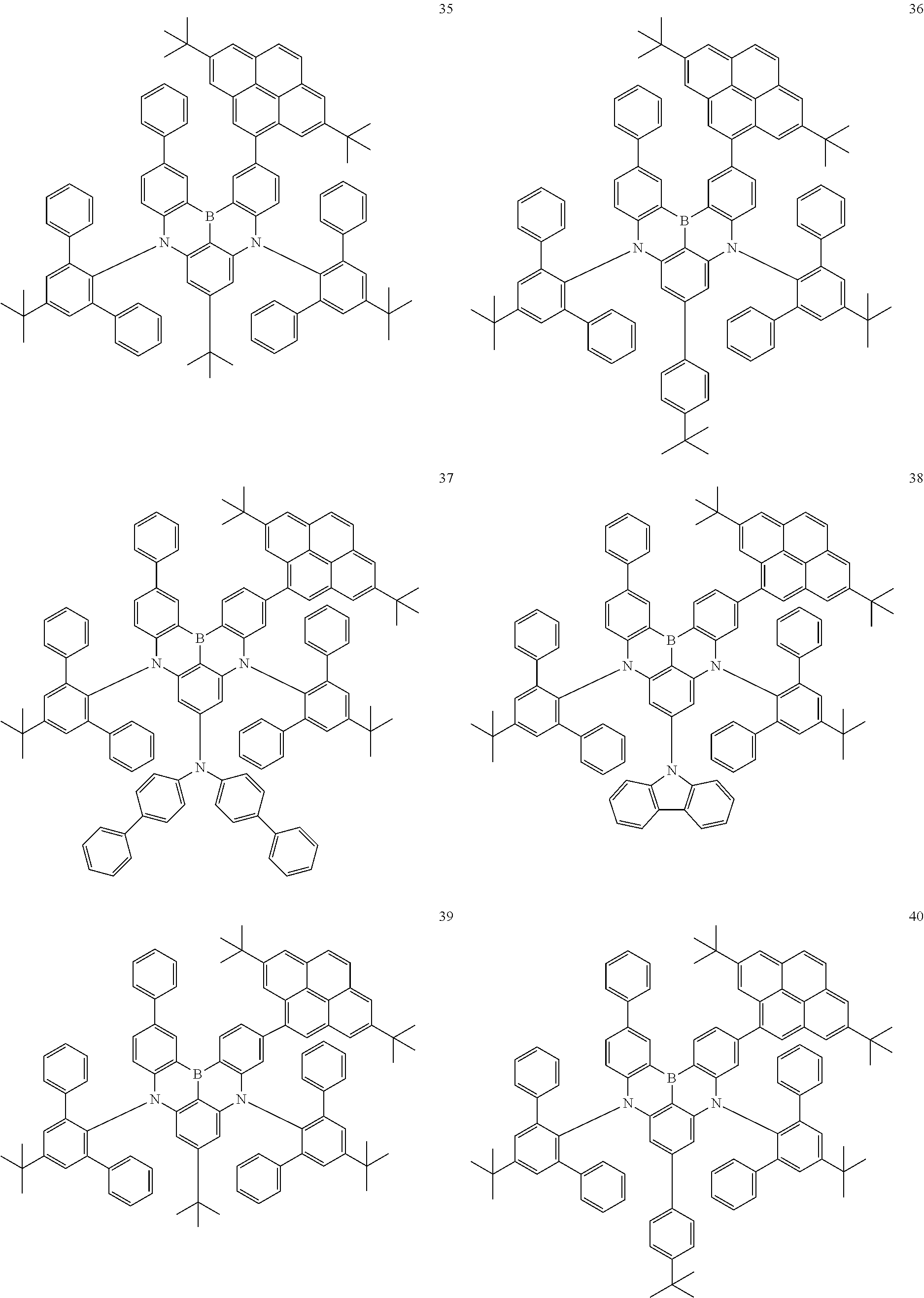 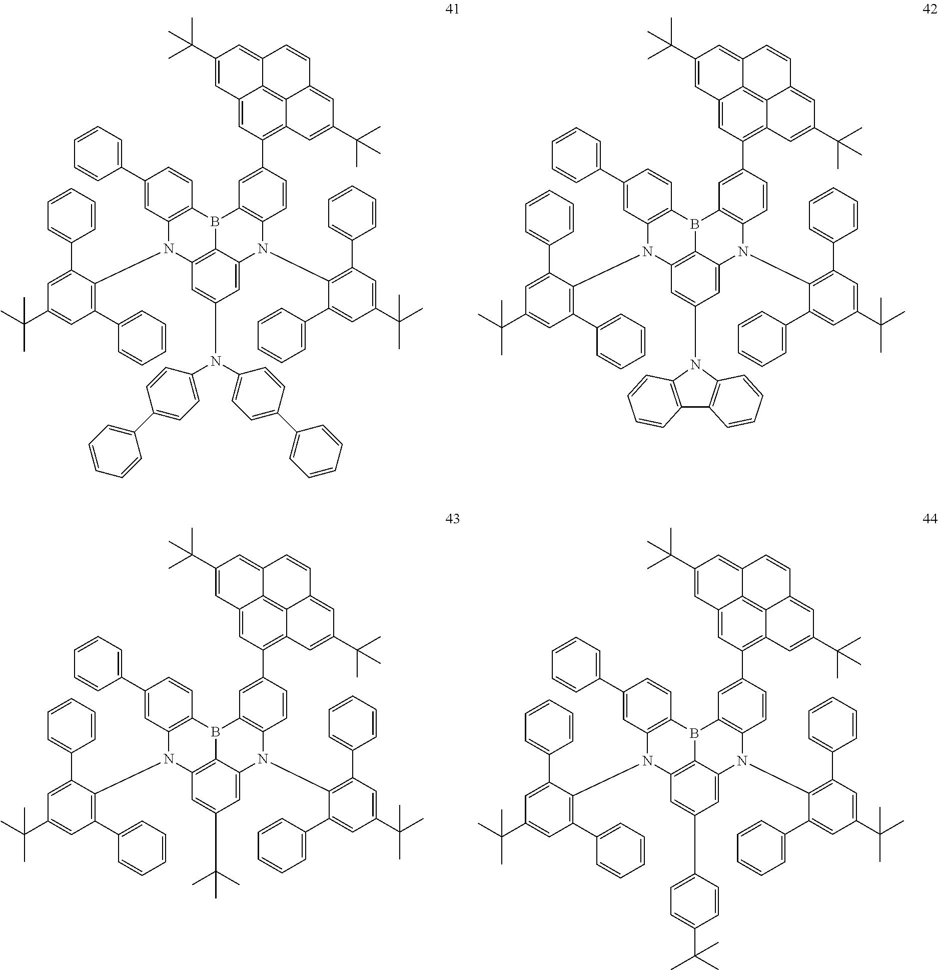 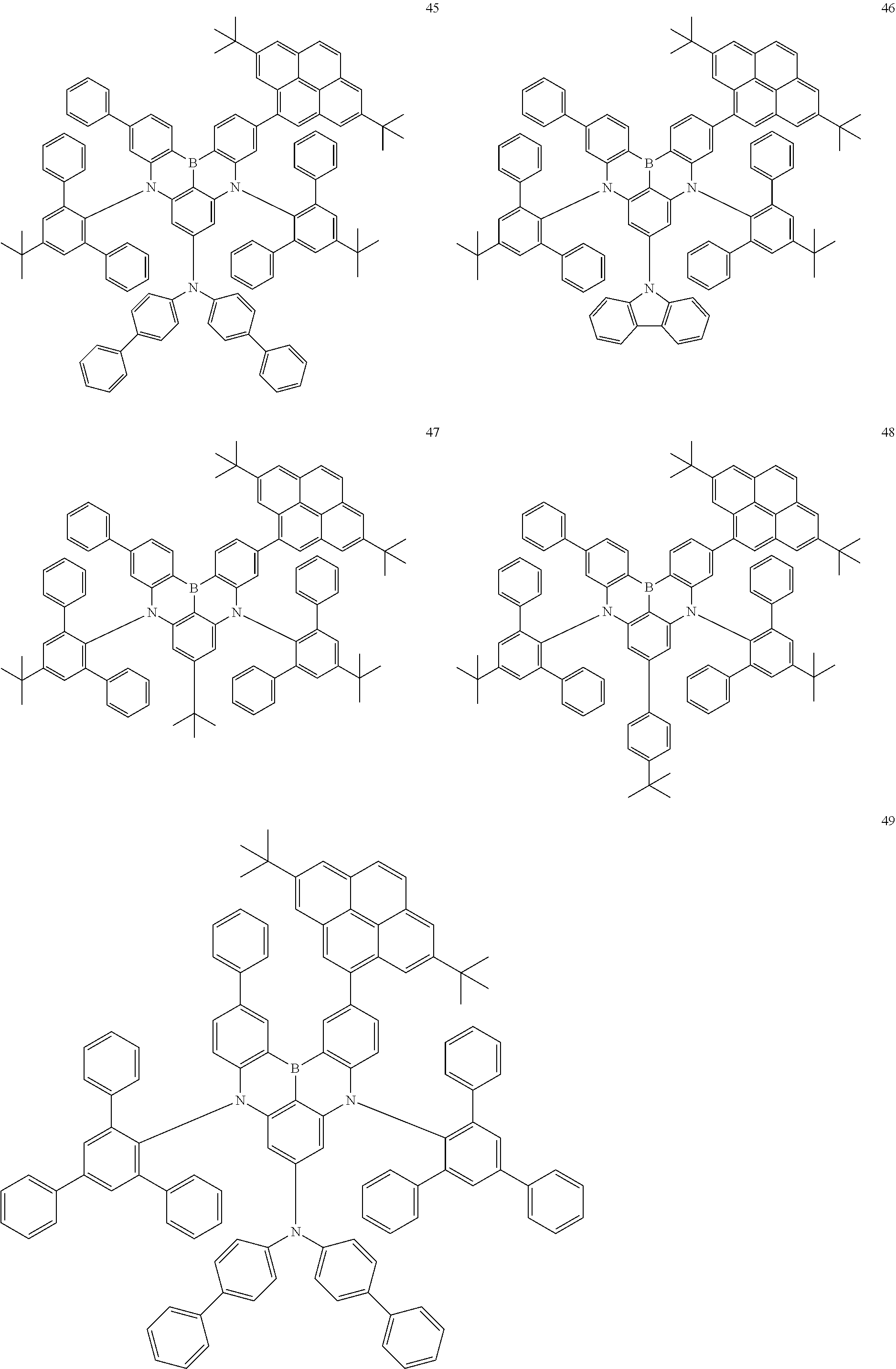 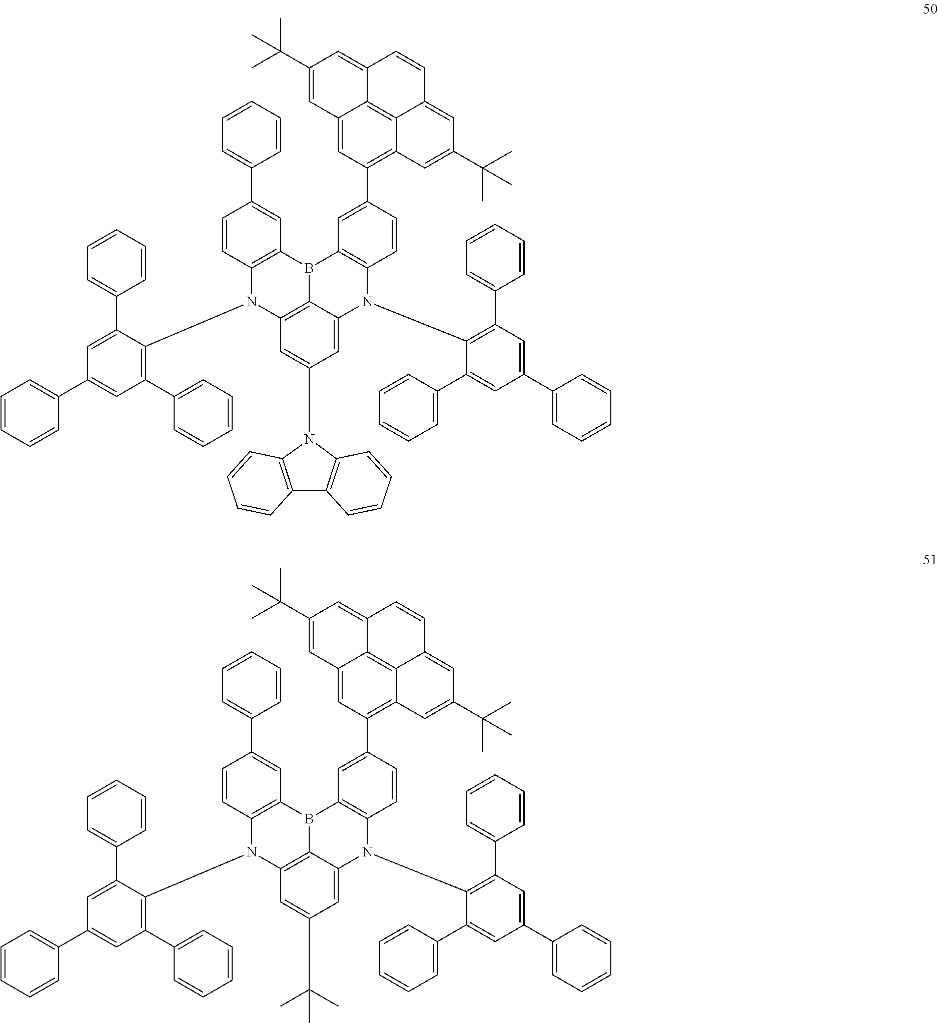 [SMILES: CC(C)(C)c1cc2ccc3cc(C(C)(C)C)cc4c(-c5ccc6c(c5)B5c7cc(-c8ccccc8)ccc7N(c7c(-c8ccccc8)cc(-c8ccccc8)cc7-c7ccccc7)c7cc(-n8c9ccccc9c9ccccc98)cc(c75)N6c5c(-c6ccccc6)cc(-c6ccccc6)cc5-c5ccccc5)cc(c1)c2c34 ; CC(C)(C)c1cc2c3c(c1)N(c1c(-c4ccccc4)cc(-c4ccccc4)cc1-c1ccccc1)c1ccc(-c4cc5cc(C(C)(C)C)cc6ccc7cc(C(C)(C)C)cc4c7c65)cc1B3c1cc(-c3ccccc3)ccc1N2c1c(-c2ccccc2)cc(-c2ccccc2)cc1-c1ccccc1] 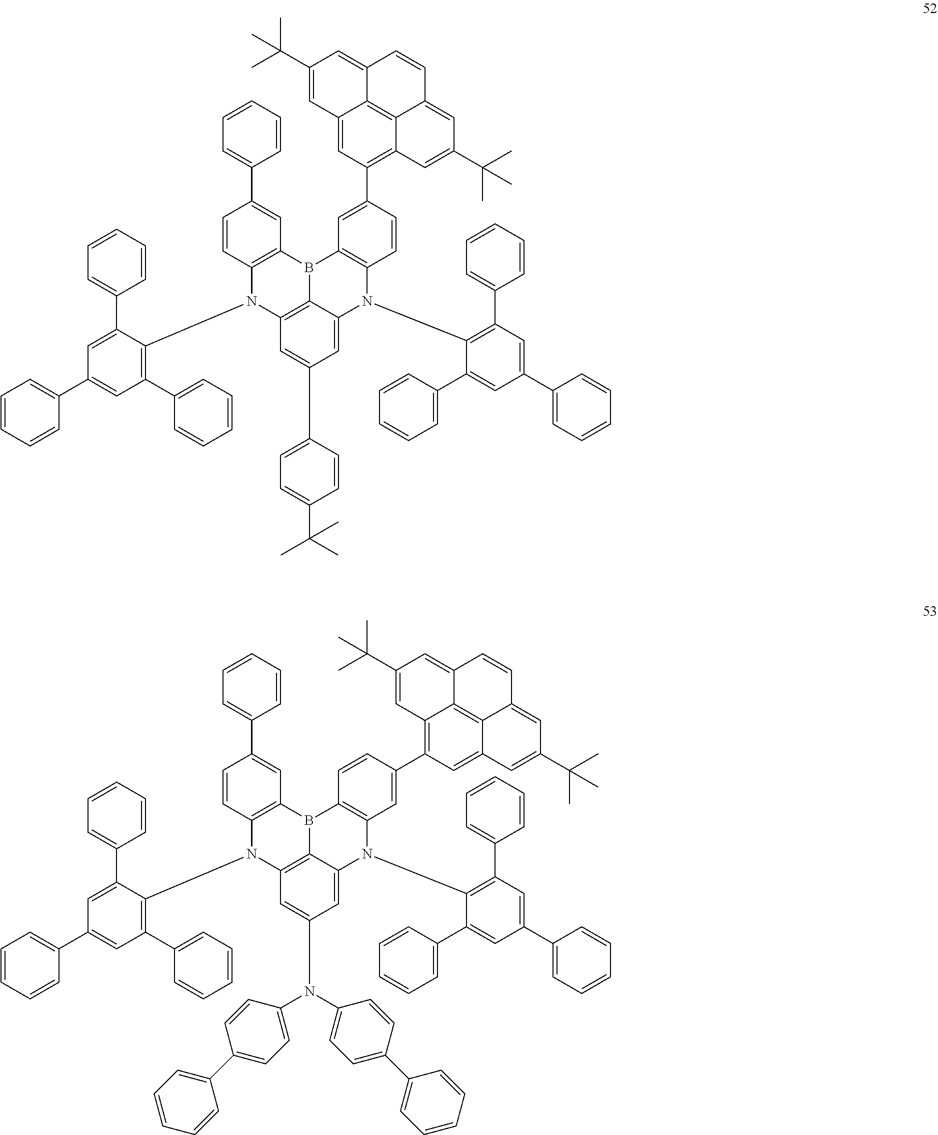 [SMILES: CC(C)(C)c1ccc(-c2cc3c4c(c2)N(c2c(-c5ccccc5)cc(-c5ccccc5)cc2-c2ccccc2)c2ccc(-c5cc6cc(C(C)(C)C)cc7ccc8cc(C(C)(C)C)cc5c8c76)cc2B4c2cc(-c4ccccc4)ccc2N3c2c(-c3ccccc3)cc(-c3ccccc3)cc2-c2ccccc2)cc1 ; CC(C)(C)c1cc2ccc3cc(C(C)(C)C)cc4c(-c5ccc6c(c5)N(c5c(-c7ccccc7)cc(-c7ccccc7)cc5-c5ccccc5)c5cc(N(c7ccc(-c8ccccc8)cc7)c7ccc(-c8ccccc8)cc7)cc7c5B6c5cc(-c6ccccc6)ccc5N7c5c(-c6ccccc6)cc(-c6ccccc6)cc5-c5ccccc5)cc(c1)c2c34] 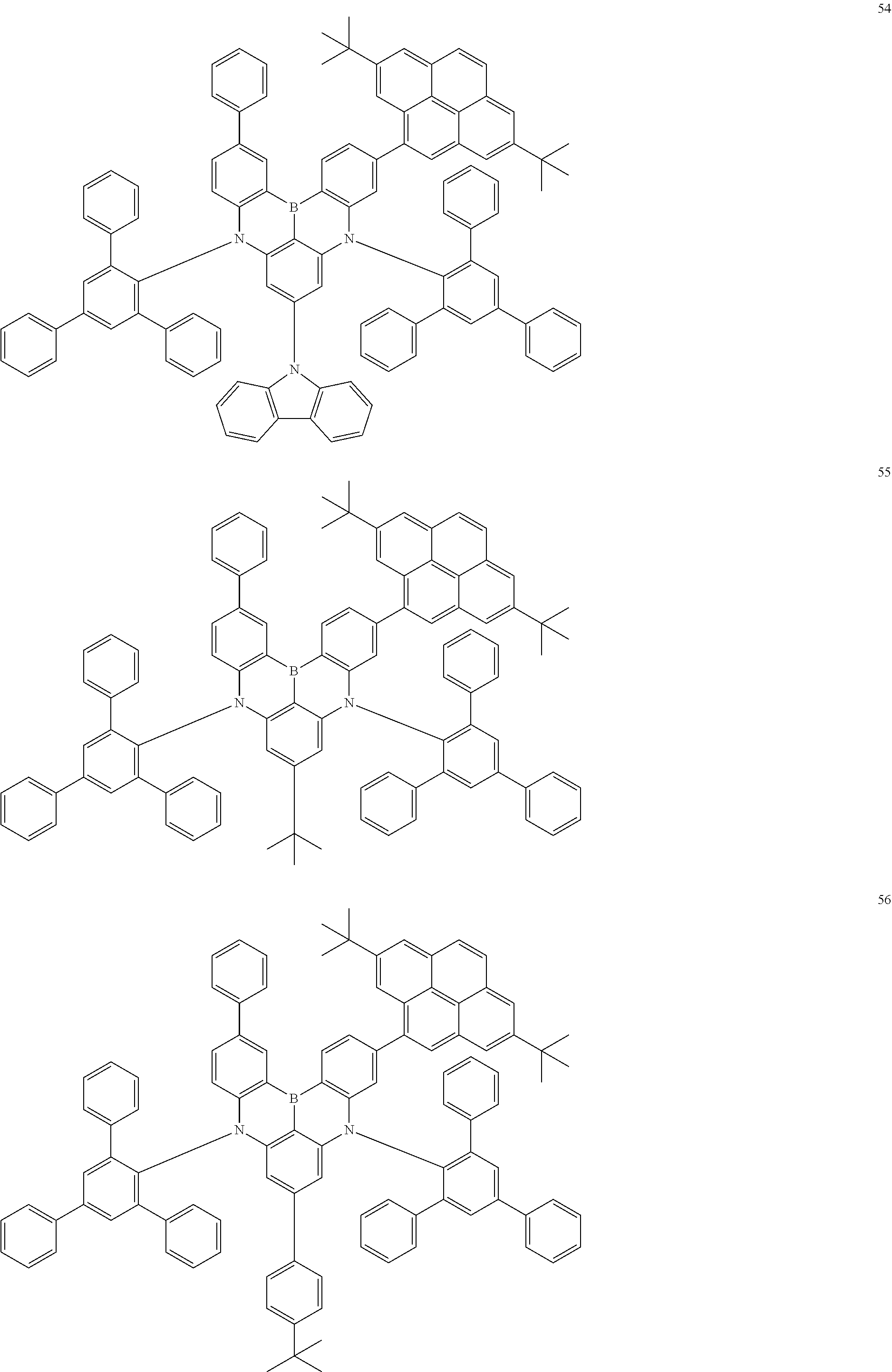 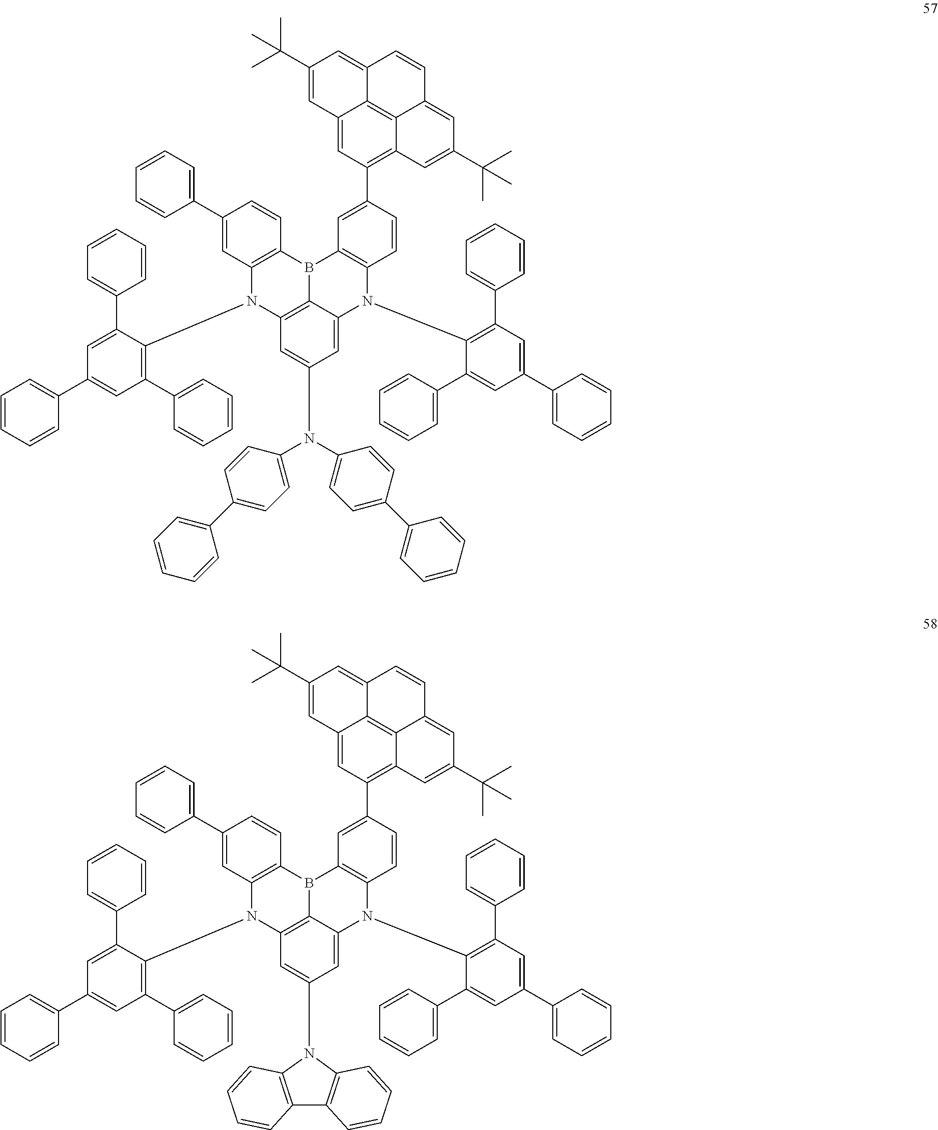 [SMILES: CC(C)(C)c1cc2ccc3cc(C(C)(C)C)cc4c(-c5ccc6c(c5)B5c7ccc(-c8ccccc8)cc7N(c7c(-c8ccccc8)cc(-c8ccccc8)cc7-c7ccccc7)c7cc(N(c8ccc(-c9ccccc9)cc8)c8ccc(-c9ccccc9)cc8)cc(c75)N6c5c(-c6ccccc6)cc(-c6ccccc6)cc5-c5ccccc5)cc(c1)c2c34 ; CC(C)(C)c1cc2ccc3cc(C(C)(C)C)cc4c(-c5ccc6c(c5)B5c7ccc(-c8ccccc8)cc7N(c7c(-c8ccccc8)cc(-c8ccccc8)cc7-c7ccccc7)c7cc(-n8c9ccccc9c9ccccc98)cc(c75)N6c5c(-c6ccccc6)cc(-c6ccccc6)cc5-c5ccccc5)cc(c1)c2c34] 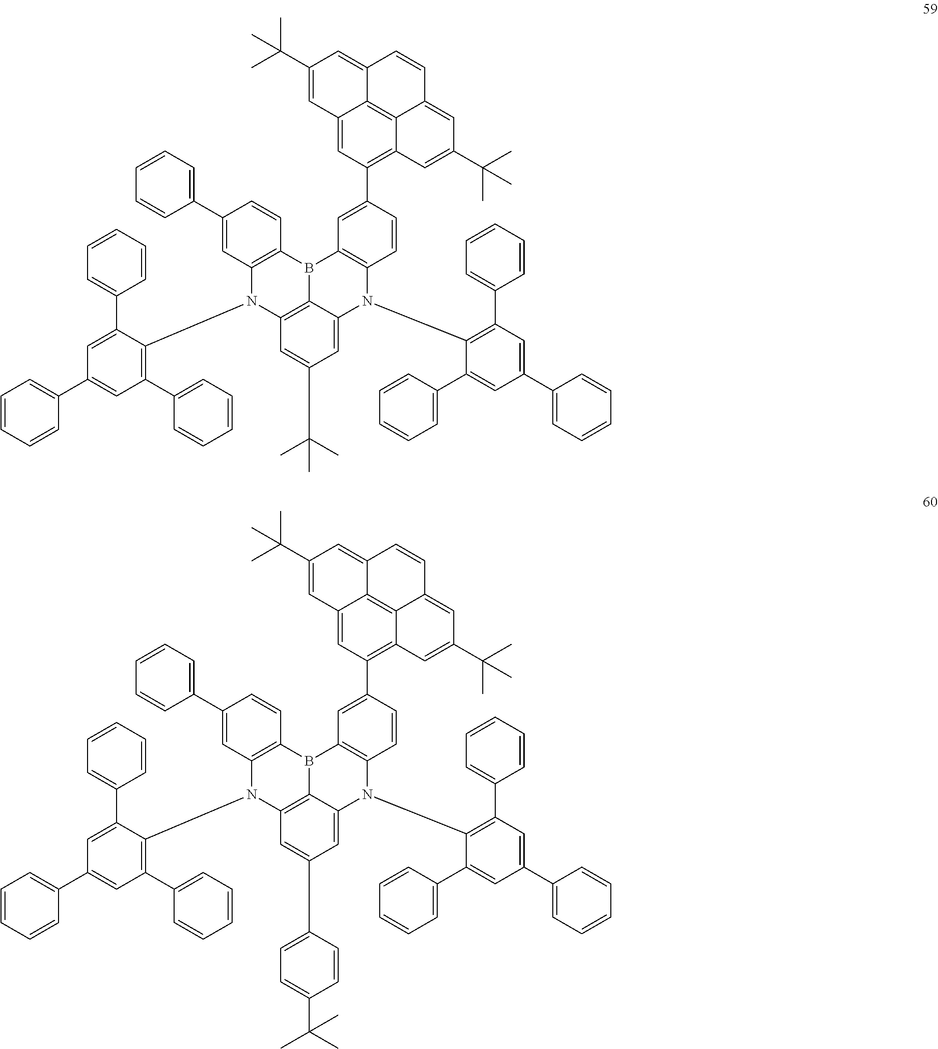 [SMILES: CC(C)(C)c1cc2c3c(c1)N(c1c(-c4ccccc4)cc(-c4ccccc4)cc1-c1ccccc1)c1cc(-c4ccccc4)ccc1B3c1cc(-c3cc4cc(C(C)(C)C)cc5ccc6cc(C(C)(C)C)cc3c6c54)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5ccccc5)ccc2B4c2cc(-c4cc5cc(C(C)(C)C)cc6ccc7cc(C(C)(C)C)cc4c7c65)ccc2N3c2c(-c3ccccc3)cc(-c3ccccc3)cc2-c2ccccc2)cc1] 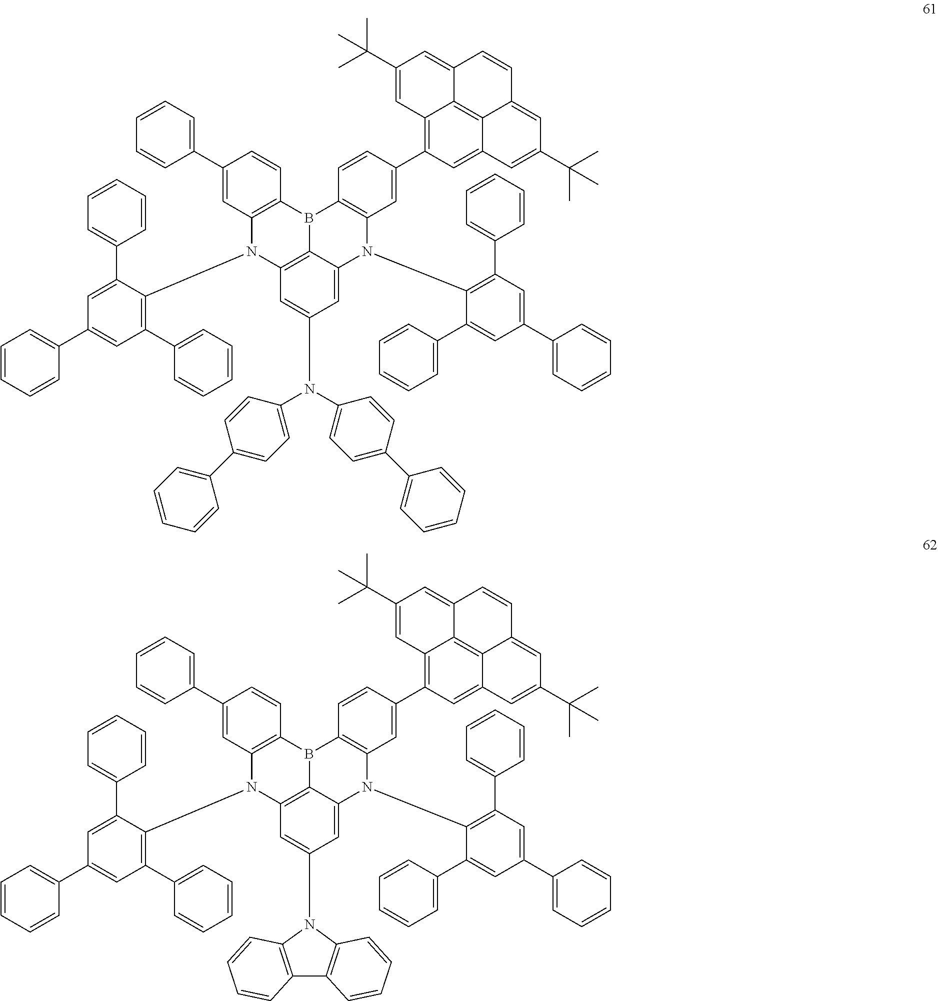 [SMILES: CC(C)(C)c1cc2ccc3cc(C(C)(C)C)cc4c(-c5ccc6c(c5)N(c5c(-c7ccccc7)cc(-c7ccccc7)cc5-c5ccccc5)c5cc(N(c7ccc(-c8ccccc8)cc7)c7ccc(-c8ccccc8)cc7)cc7c5B6c5ccc(-c6ccccc6)cc5N7c5c(-c6ccccc6)cc(-c6ccccc6)cc5-c5ccccc5)cc(c1)c2c34 ; CC(C)(C)c1cc2ccc3cc(C(C)(C)C)cc4c(-c5ccc6c(c5)N(c5c(-c7ccccc7)cc(-c7ccccc7)cc5-c5ccccc5)c5cc(-n7c8ccccc8c8ccccc87)cc7c5B6c5ccc(-c6ccccc6)cc5N7c5c(-c6ccccc6)cc(-c6ccccc6)cc5-c5ccccc5)cc(c1)c2c34] 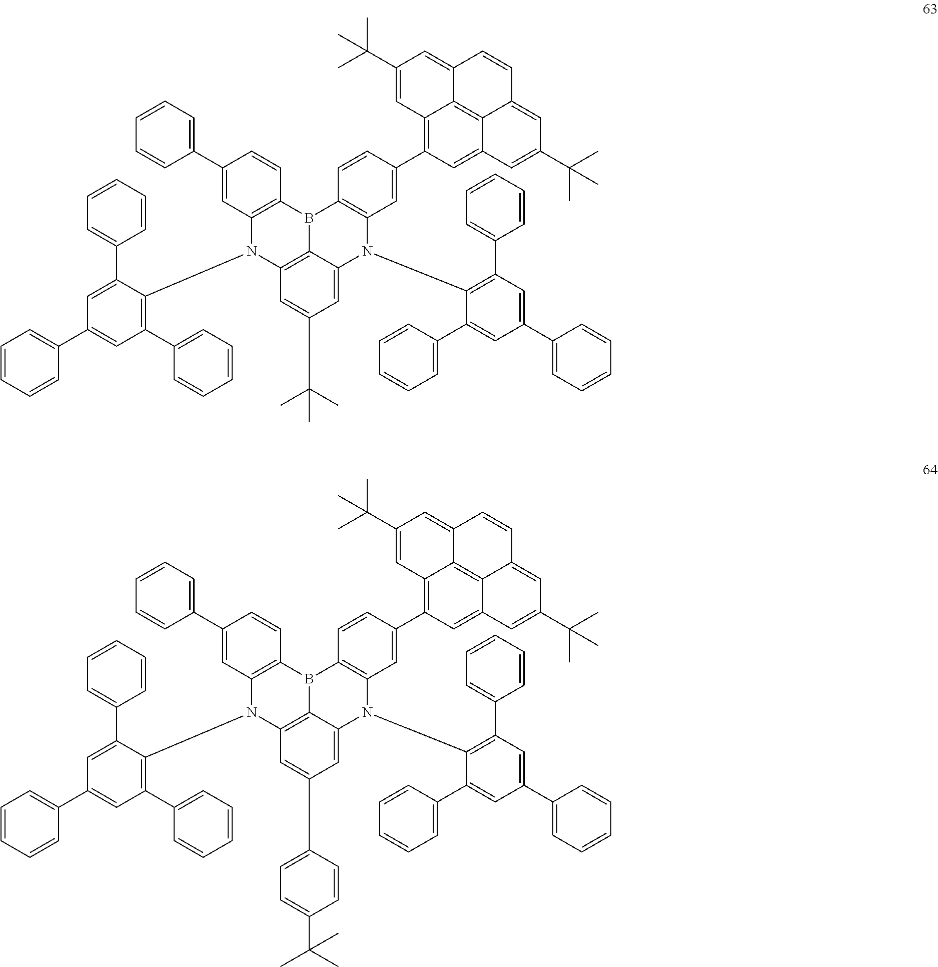 [SMILES: CC(C)(C)c1cc2c3c(c1)N(c1c(-c4ccccc4)cc(-c4ccccc4)cc1-c1ccccc1)c1cc(-c4cc5cc(C(C)(C)C)cc6ccc7cc(C(C)(C)C)cc4c7c65)ccc1B3c1ccc(-c3ccccc3)cc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5cc6cc(C(C)(C)C)cc7ccc8cc(C(C)(C)C)cc5c8c76)ccc2B4c2ccc(-c4ccccc4)cc2N3c2c(-c3ccccc3)cc(-c3ccccc3)cc2-c2ccccc2)cc1] 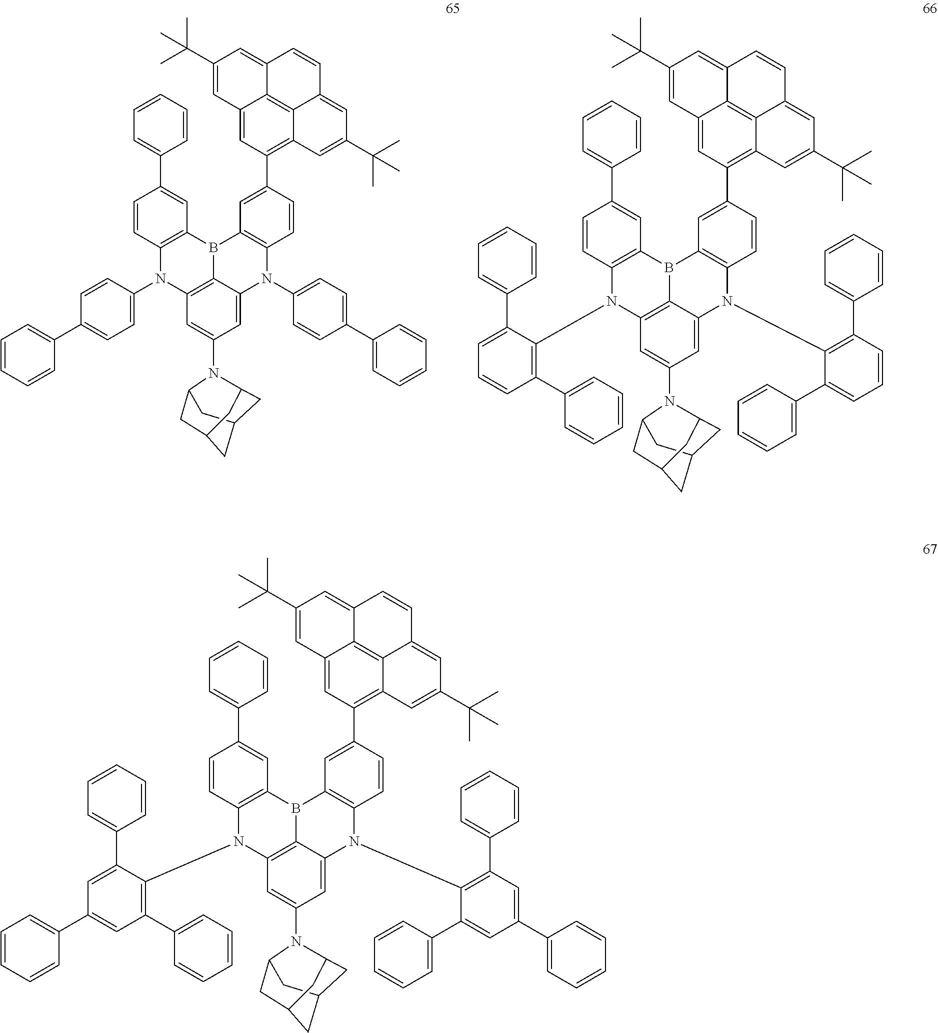 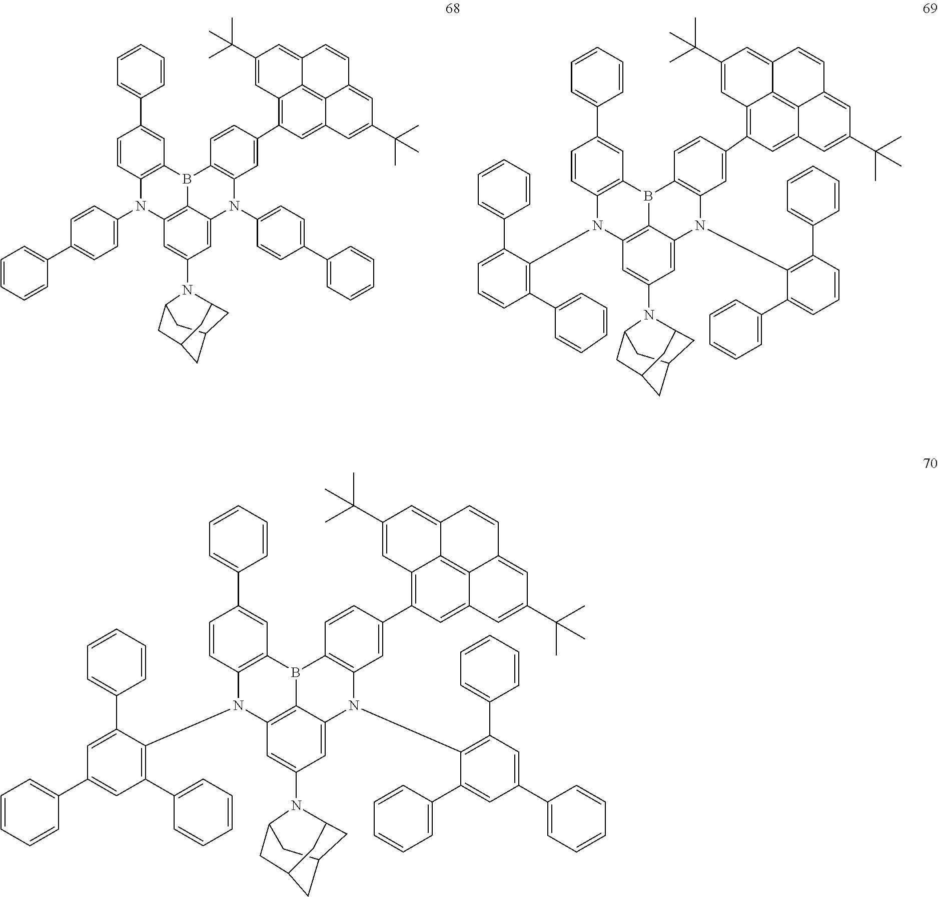 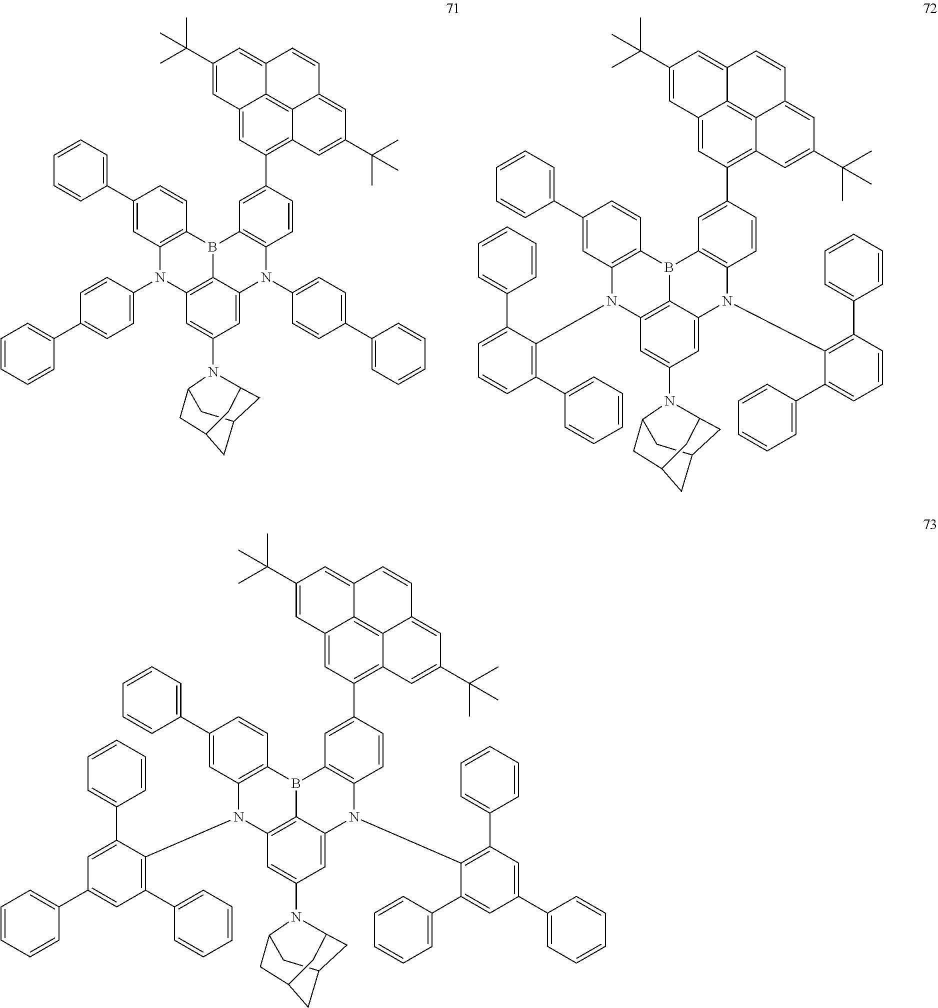 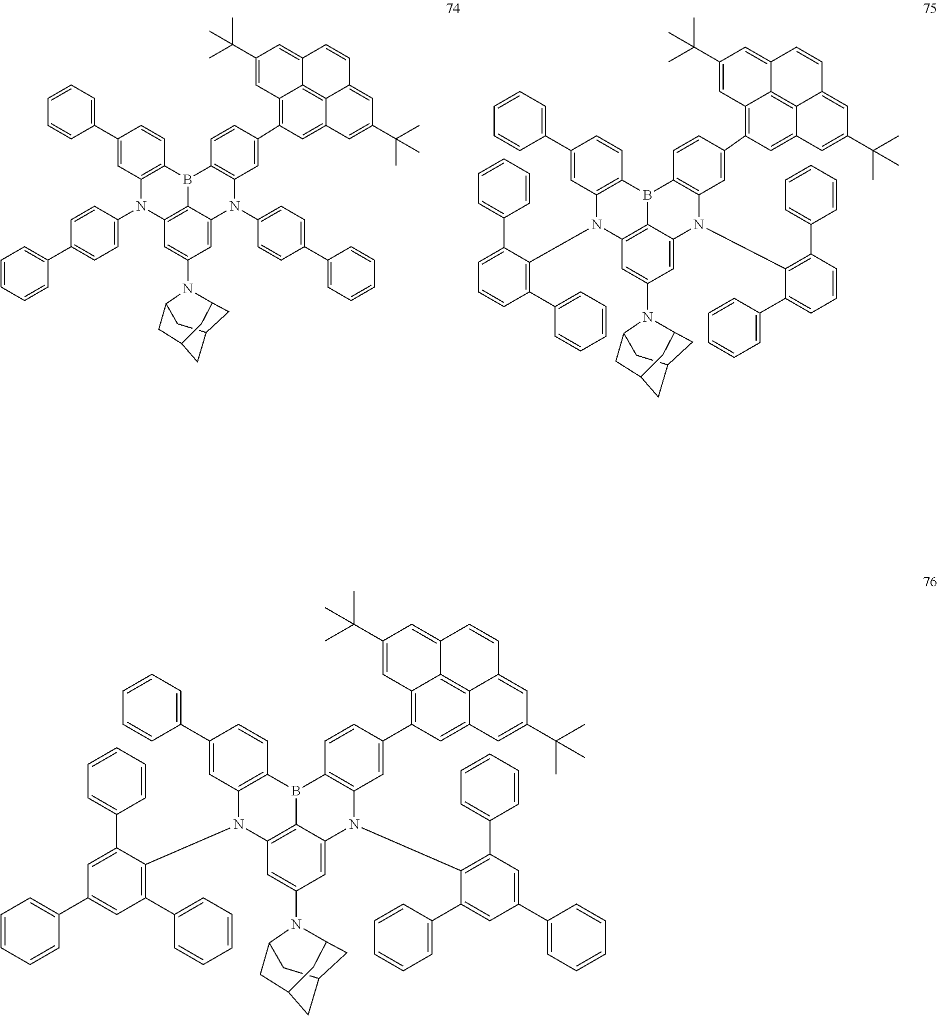 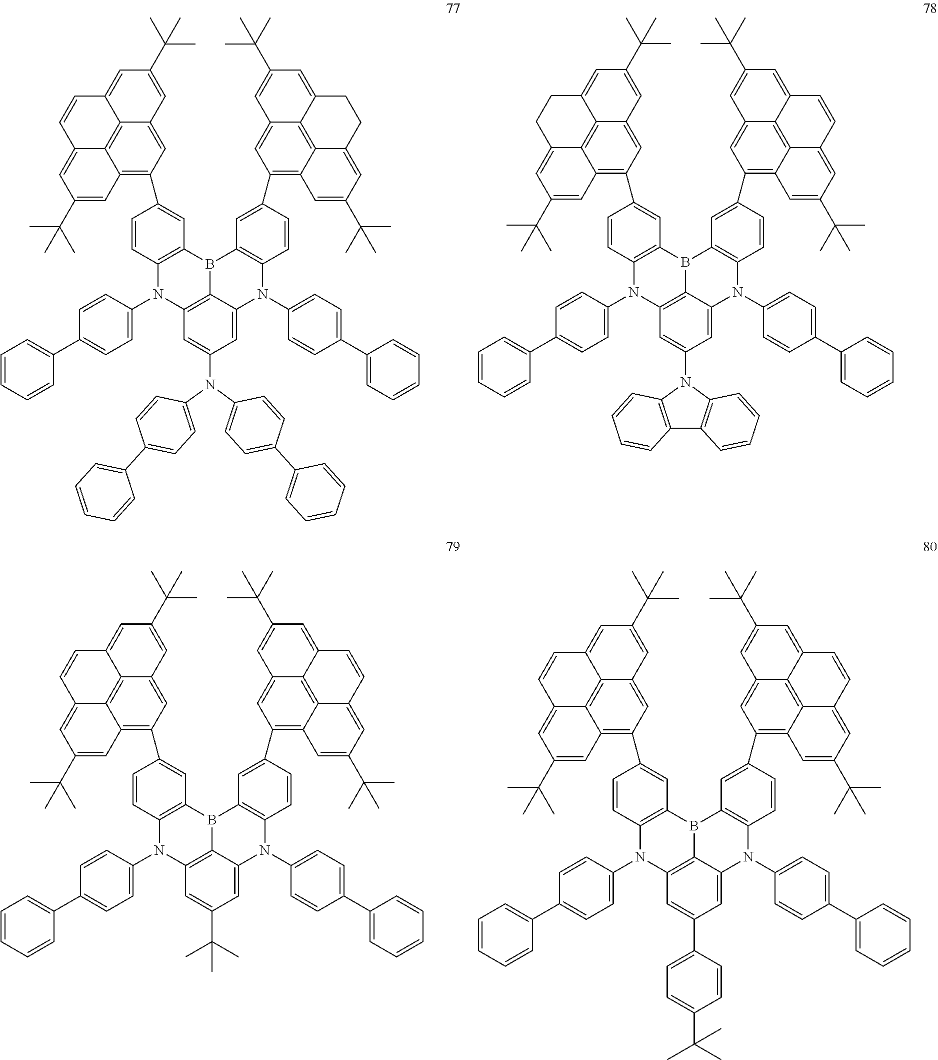 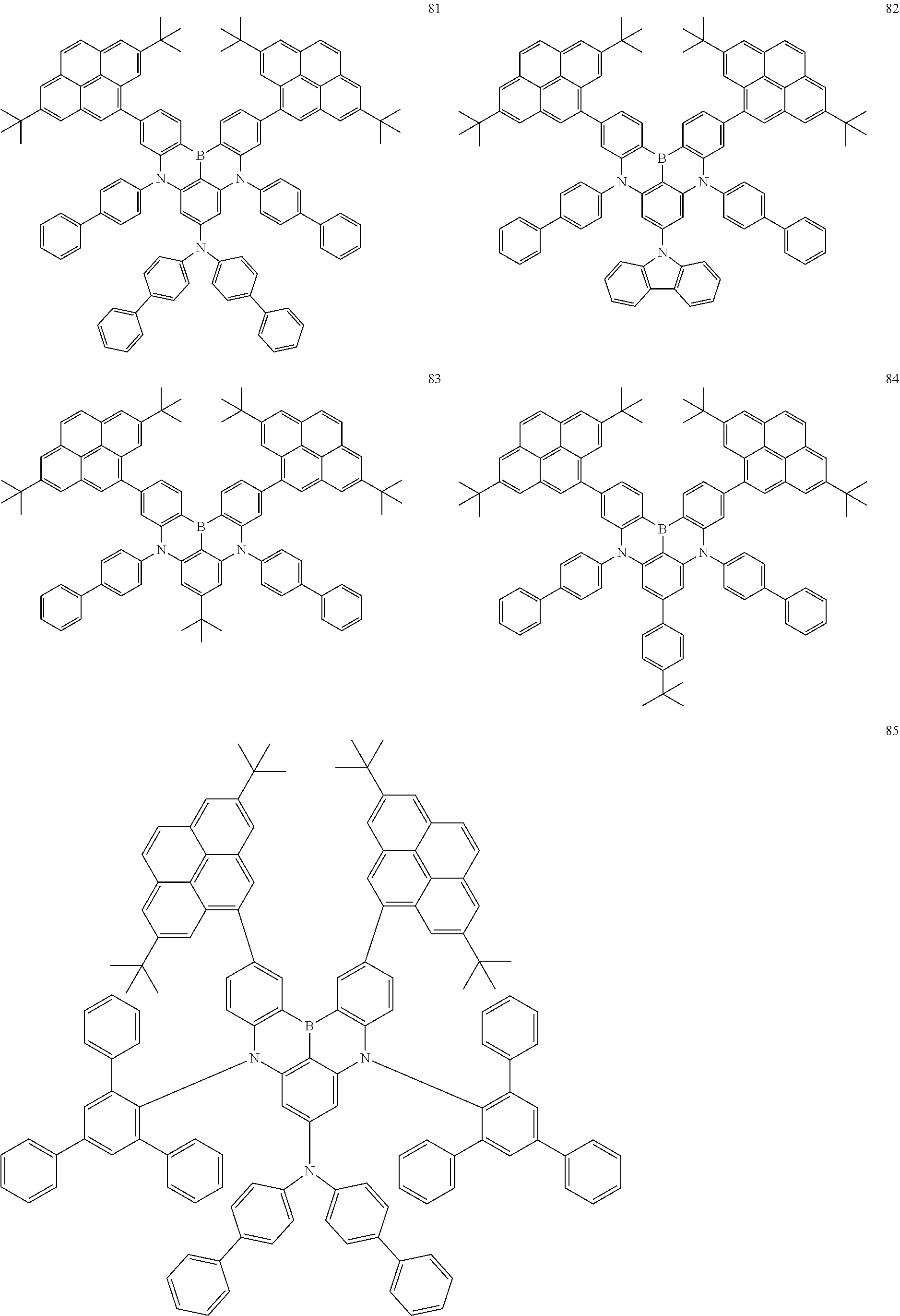 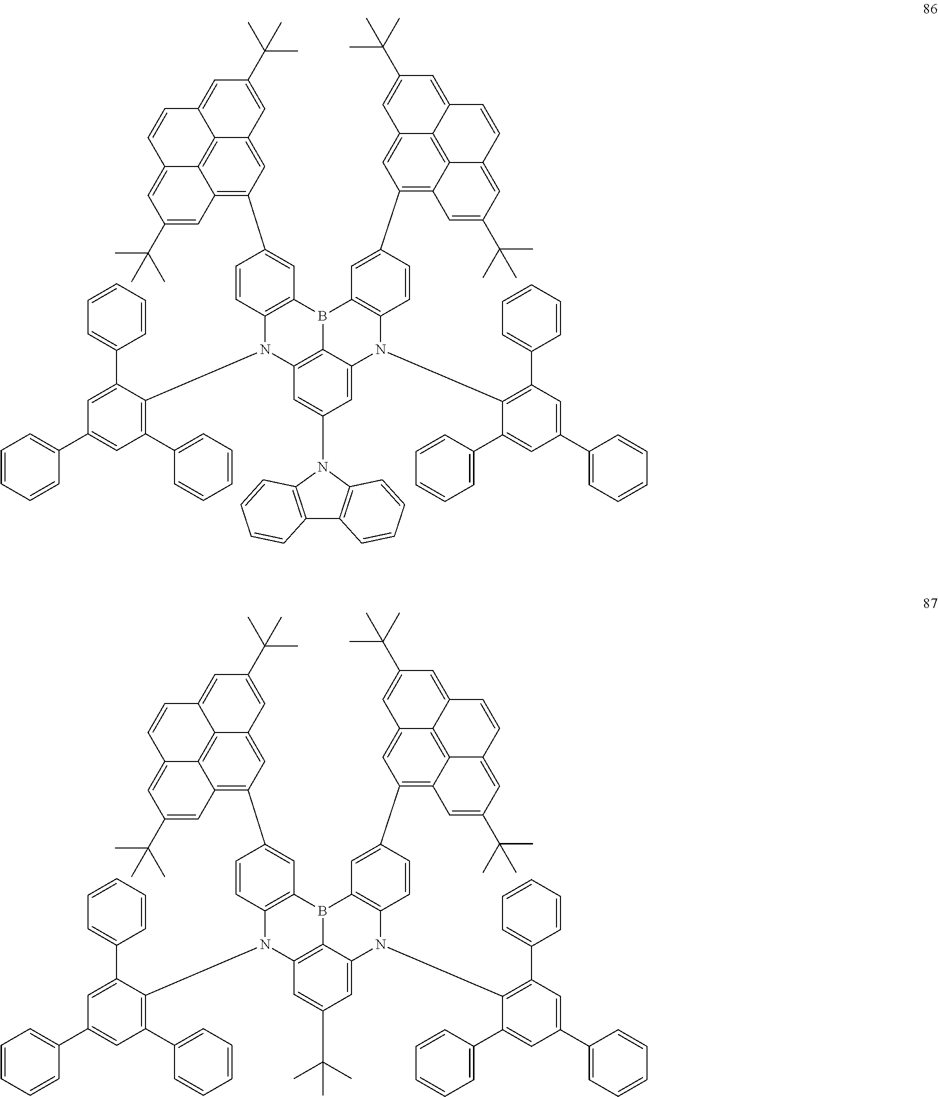 [SMILES: CC(C)(C)c1cc2ccc3cc(C(C)(C)C)cc4c(-c5ccc6c(c5)B5c7cc(-c8cc9cc(C(C)(C)C)cc%10ccc%11cc(C(C)(C)C)cc8c%11c%109)ccc7N(c7c(-c8ccccc8)cc(-c8ccccc8)cc7-c7ccccc7)c7cc(-n8c9ccccc9c9ccccc98)cc(c75)N6c5c(-c6ccccc6)cc(-c6ccccc6)cc5-c5ccccc5)cc(c1)c2c34 ; CC(C)(C)c1cc2c3c(c1)N(c1c(-c4ccccc4)cc(-c4ccccc4)cc1-c1ccccc1)c1ccc(-c4cc5cc(C(C)(C)C)cc6ccc7cc(C(C)(C)C)cc4c7c65)cc1B3c1cc(-c3cc4cc(C(C)(C)C)cc5ccc6cc(C(C)(C)C)cc3c6c54)ccc1N2c1c(-c2ccccc2)cc(-c2ccccc2)cc1-c1ccccc1] 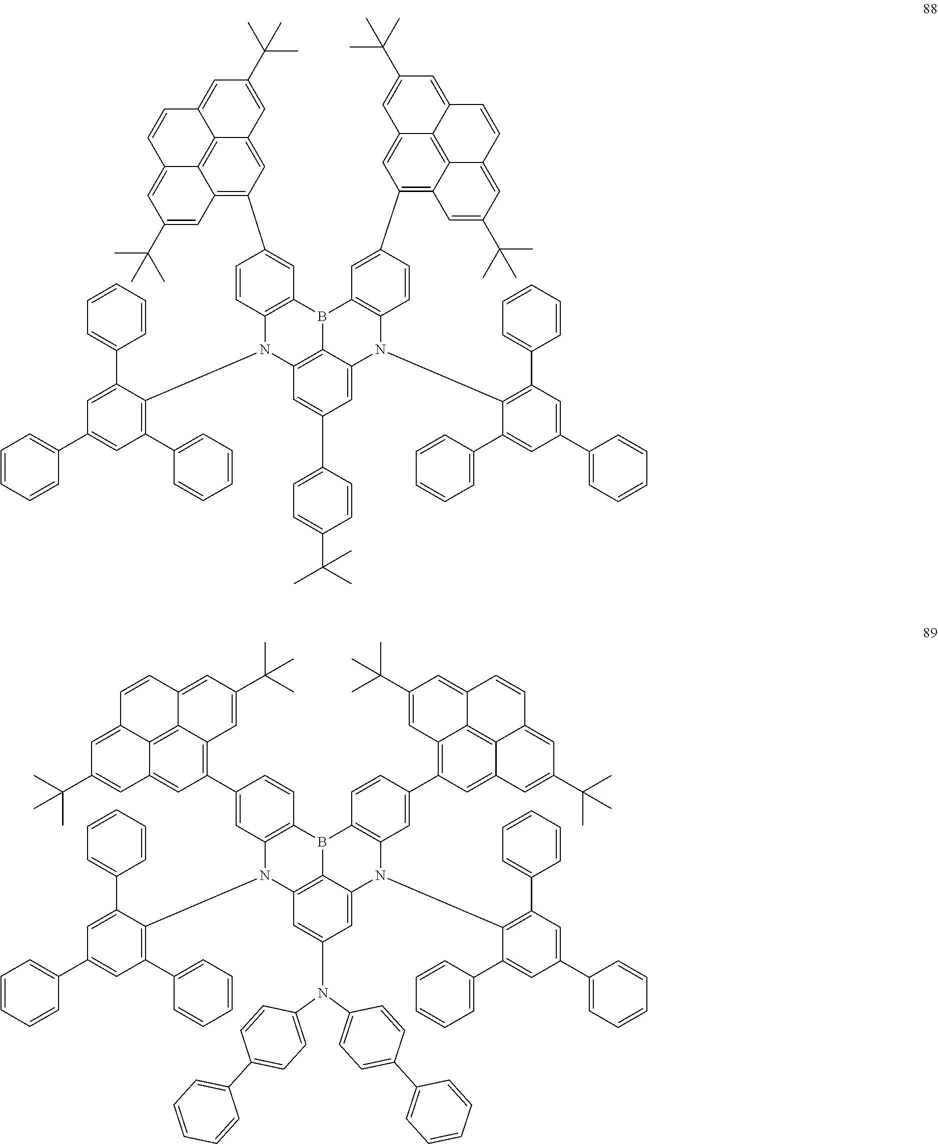 [SMILES: CC(C)(C)c1ccc(-c2cc3c4c(c2)N(c2c(-c5ccccc5)cc(-c5ccccc5)cc2-c2ccccc2)c2ccc(-c5cc6cc(C(C)(C)C)cc7ccc8cc(C(C)(C)C)cc5c8c76)cc2B4c2cc(-c4cc5cc(C(C)(C)C)cc6ccc7cc(C(C)(C)C)cc4c7c65)ccc2N3c2c(-c3ccccc3)cc(-c3ccccc3)cc2-c2ccccc2)cc1 ; CC(C)(C)c1cc2ccc3cc(C(C)(C)C)cc4c(-c5ccc6c(c5)N(c5c(-c7ccccc7)cc(-c7ccccc7)cc5-c5ccccc5)c5cc(N(c7ccc(-c8ccccc8)cc7)c7ccc(-c8ccccc8)cc7)cc7c5B6c5ccc(-c6cc8cc(C(C)(C)C)cc9ccc%10cc(C(C)(C)C)cc6c%10c98)cc5N7c5c(-c6ccccc6)cc(-c6ccccc6)cc5-c5ccccc5)cc(c1)c2c34] 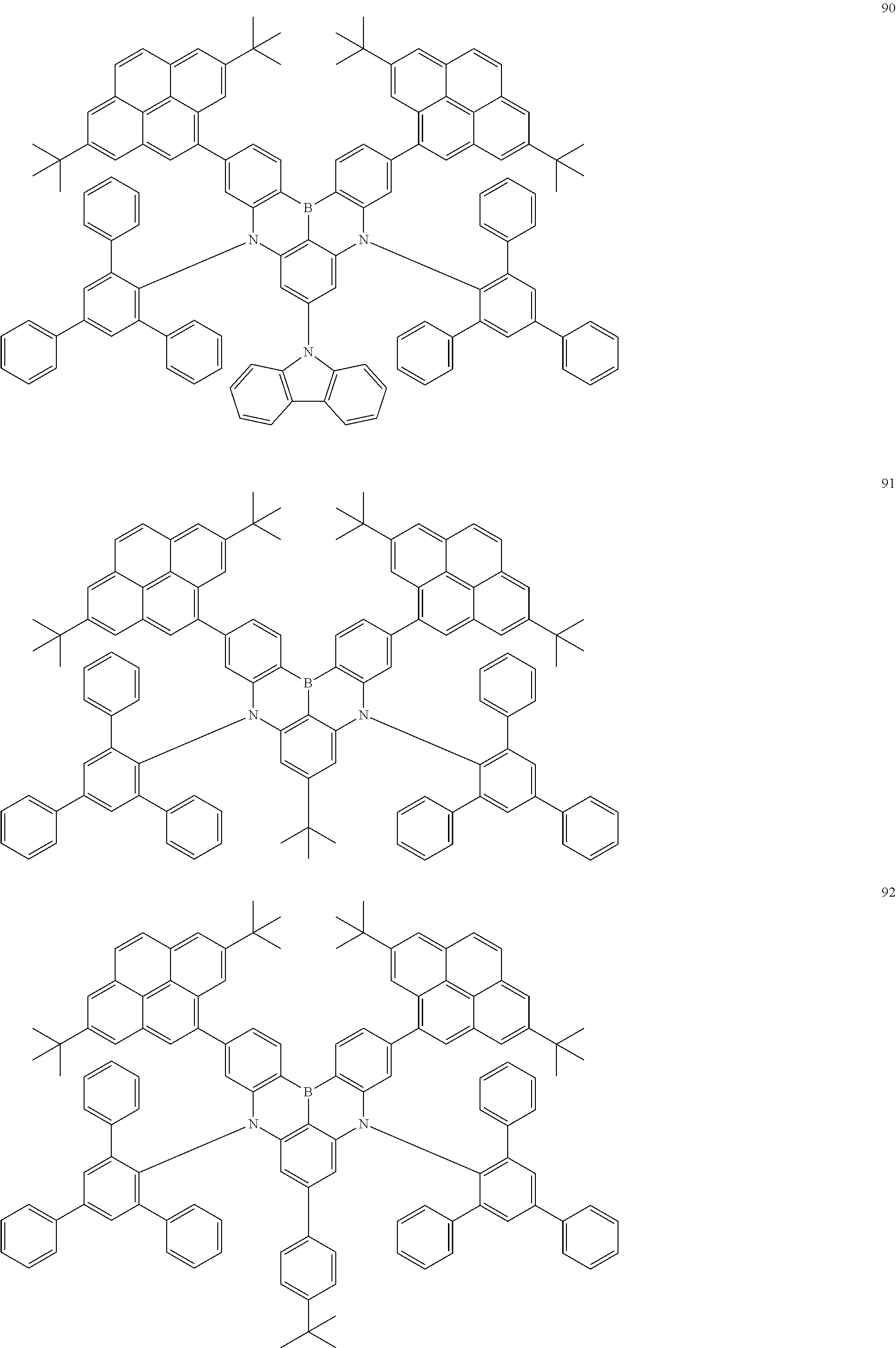 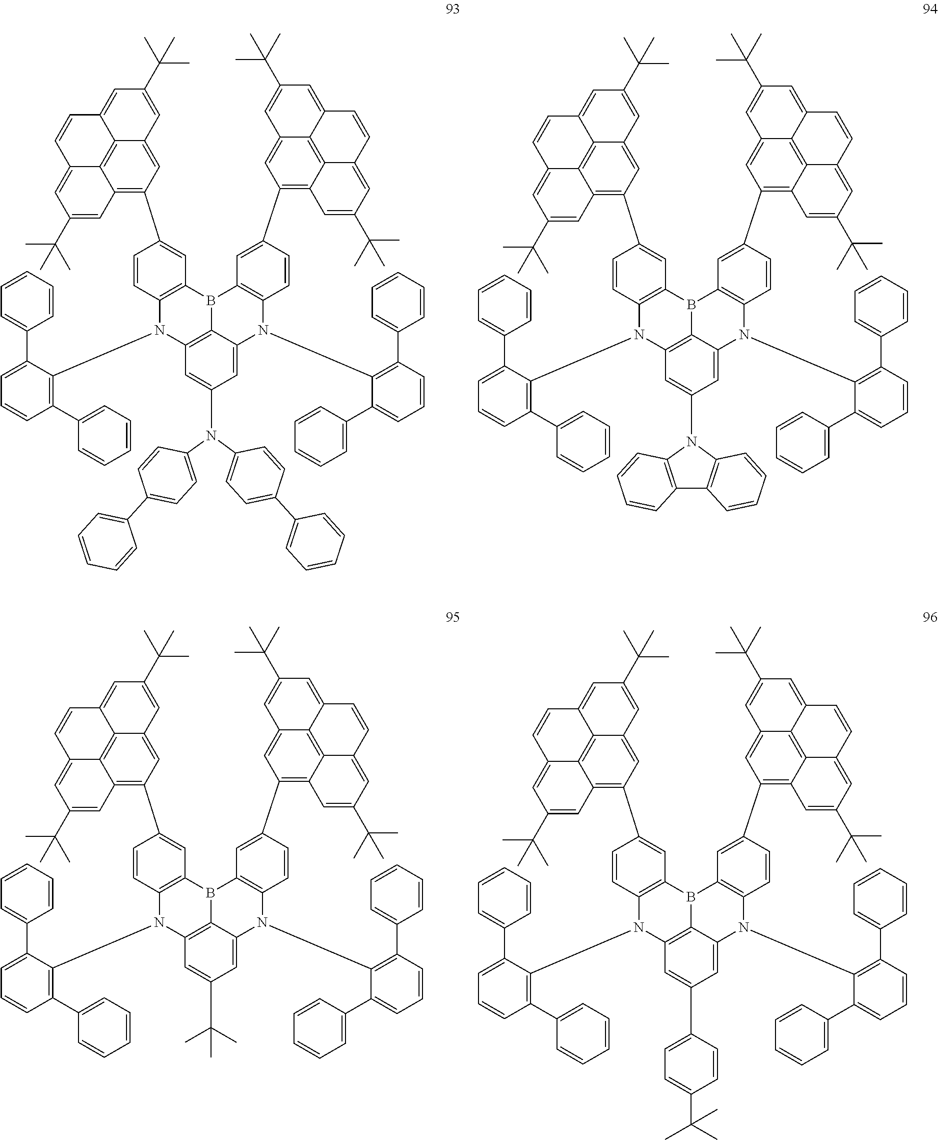 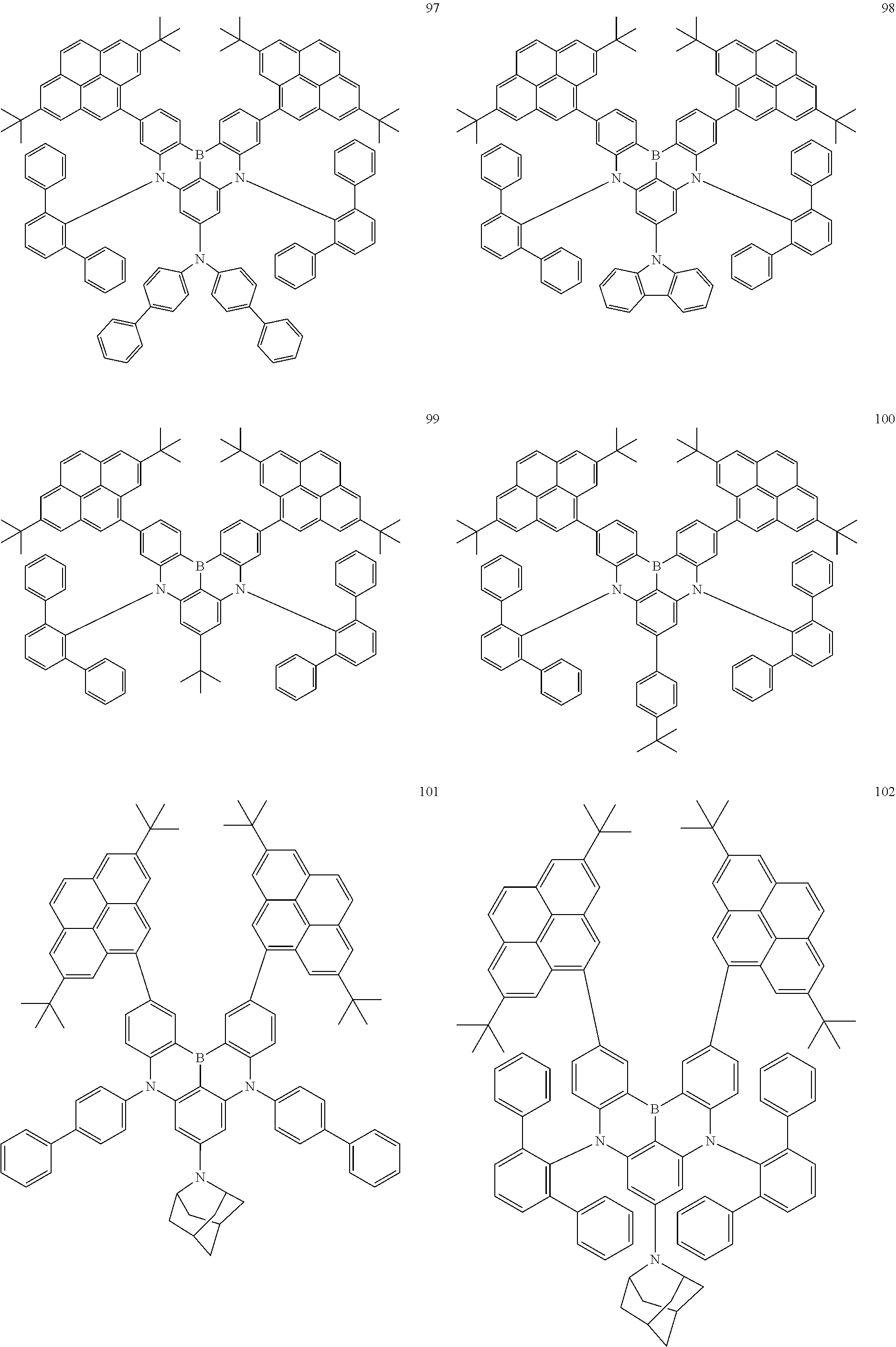 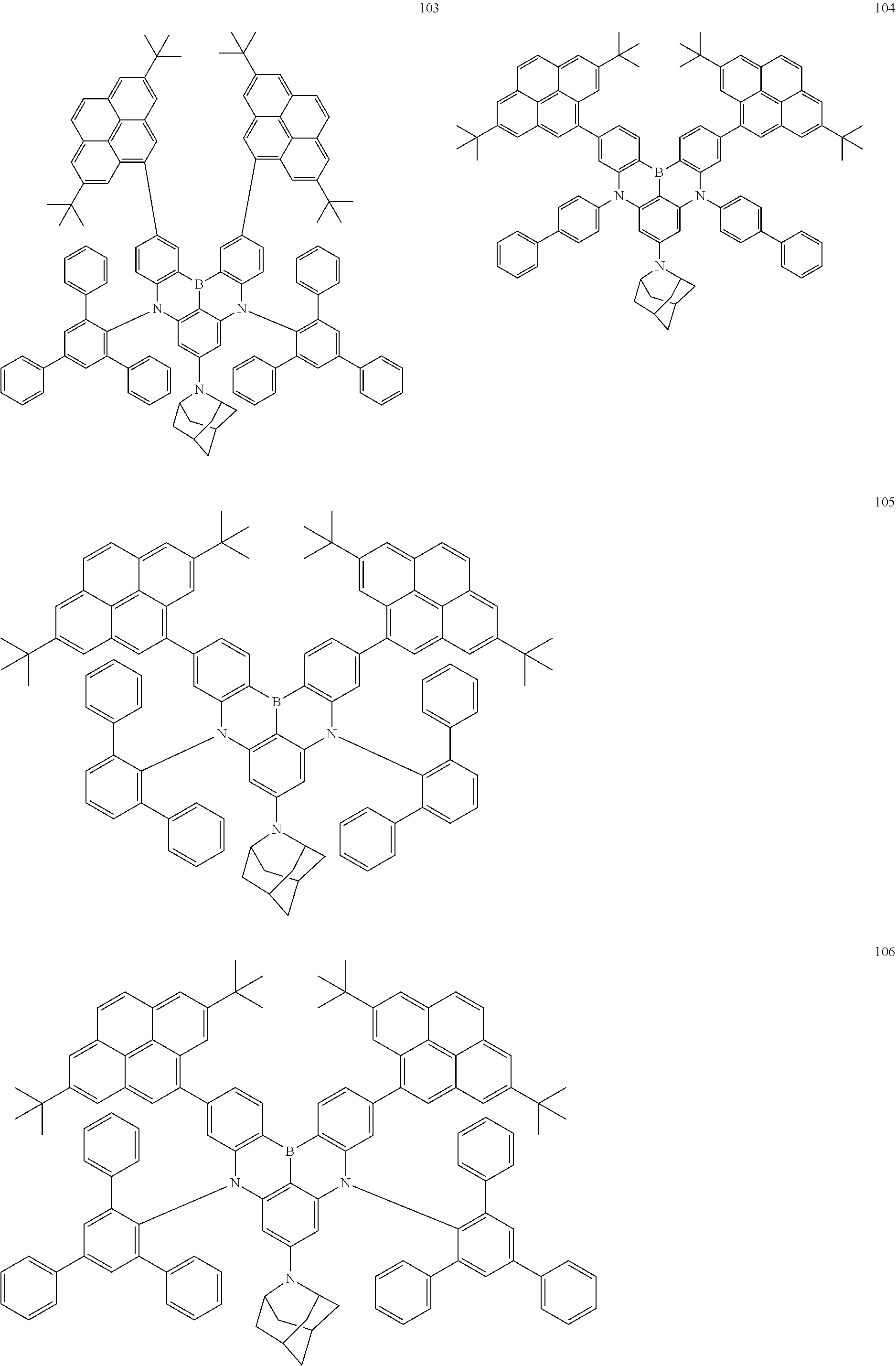 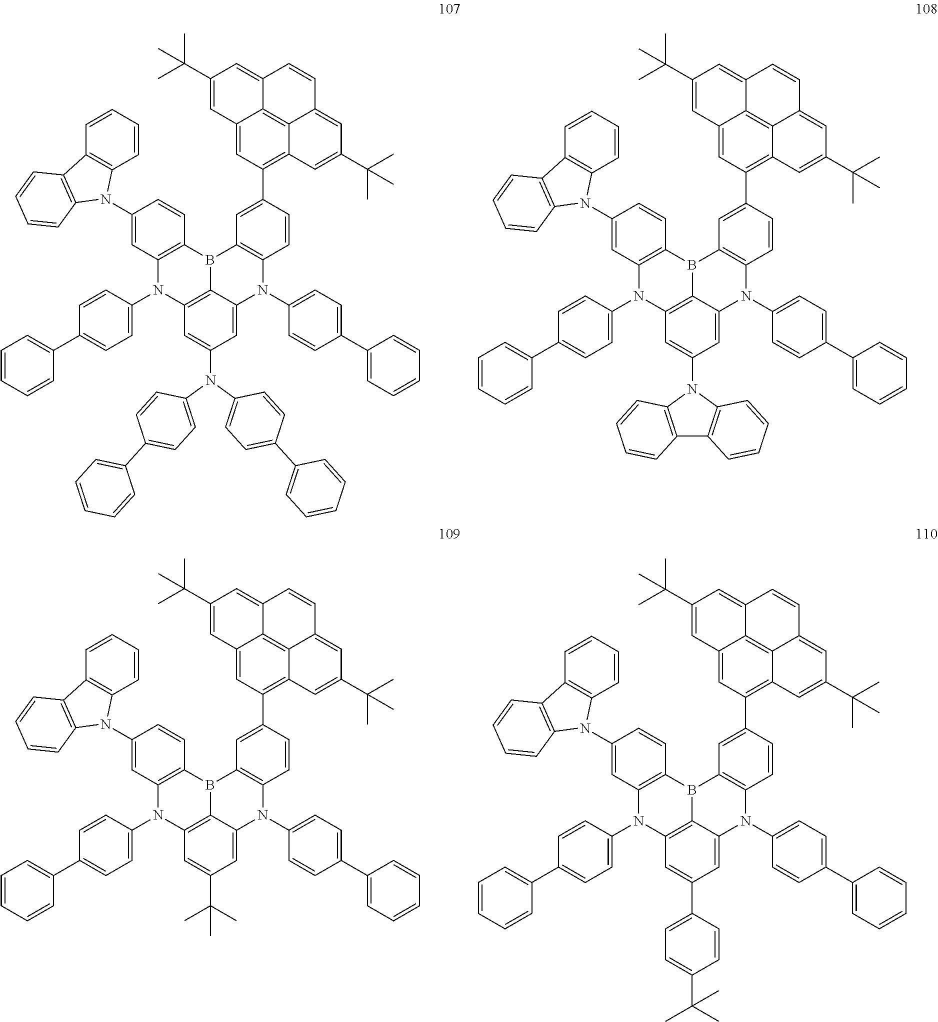 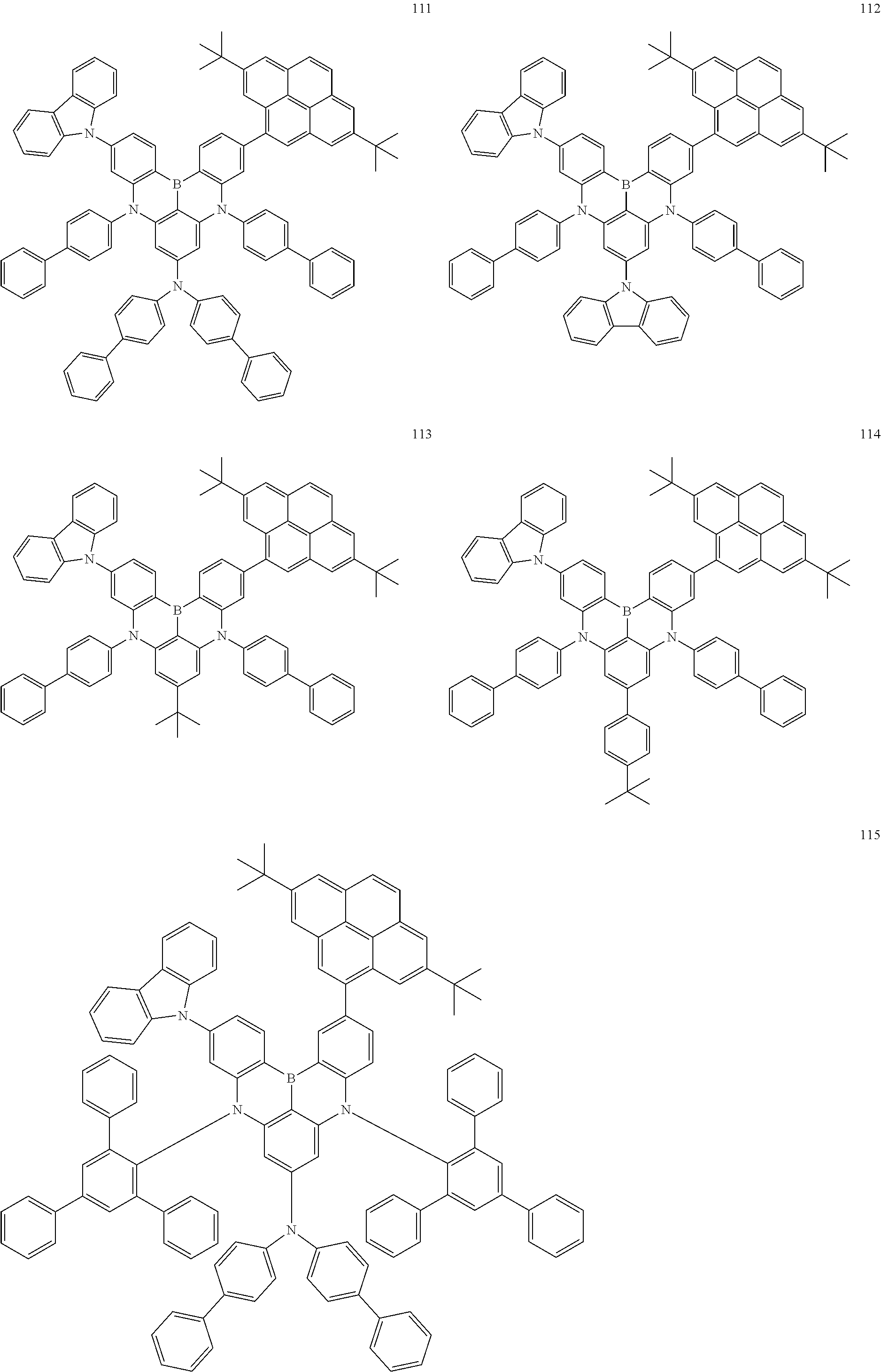 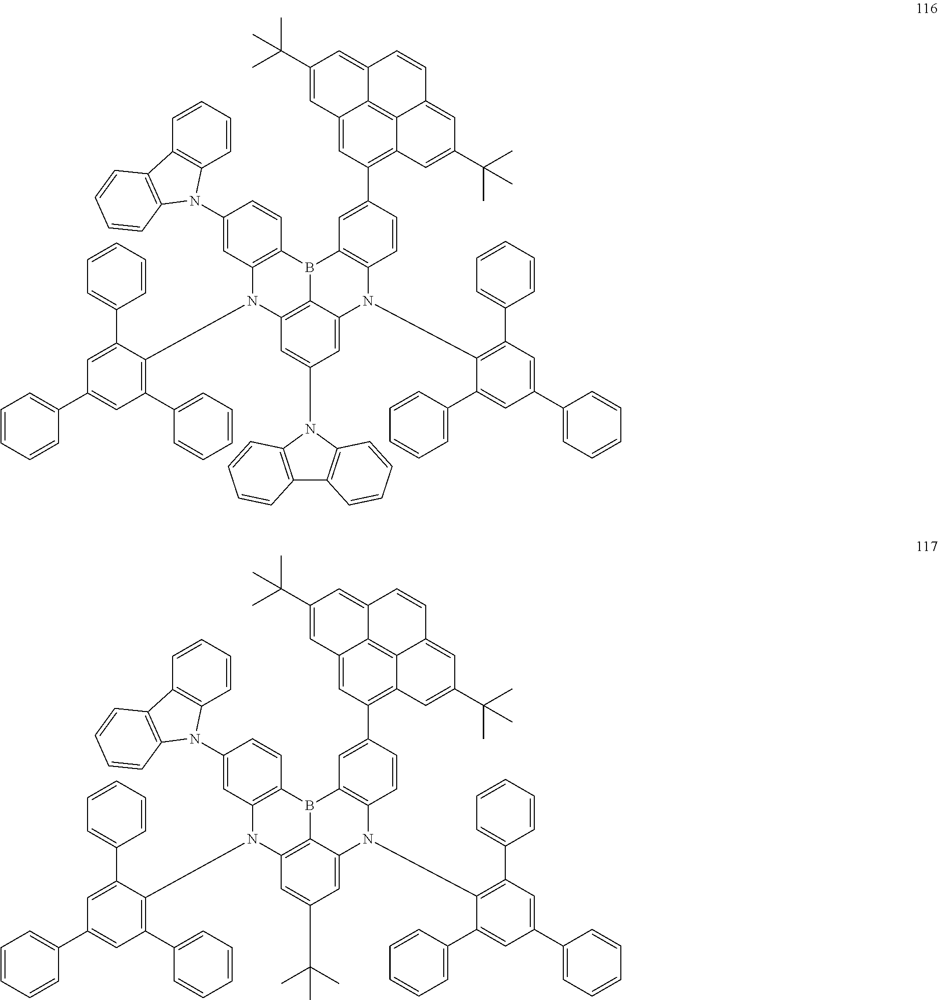 [SMILES: CC(C)(C)c1cc2ccc3cc(C(C)(C)C)cc4c(-c5ccc6c(c5)B5c7ccc(-n8c9ccccc9c9ccccc98)cc7N(c7c(-c8ccccc8)cc(-c8ccccc8)cc7-c7ccccc7)c7cc(-n8c9ccccc9c9ccccc98)cc(c75)N6c5c(-c6ccccc6)cc(-c6ccccc6)cc5-c5ccccc5)cc(c1)c2c34 ; CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1cc(-c3cc4cc(C(C)(C)C)cc5ccc6cc(C(C)(C)C)cc3c6c54)ccc1N2c1c(-c2ccccc2)cc(-c2ccccc2)cc1-c1ccccc1] 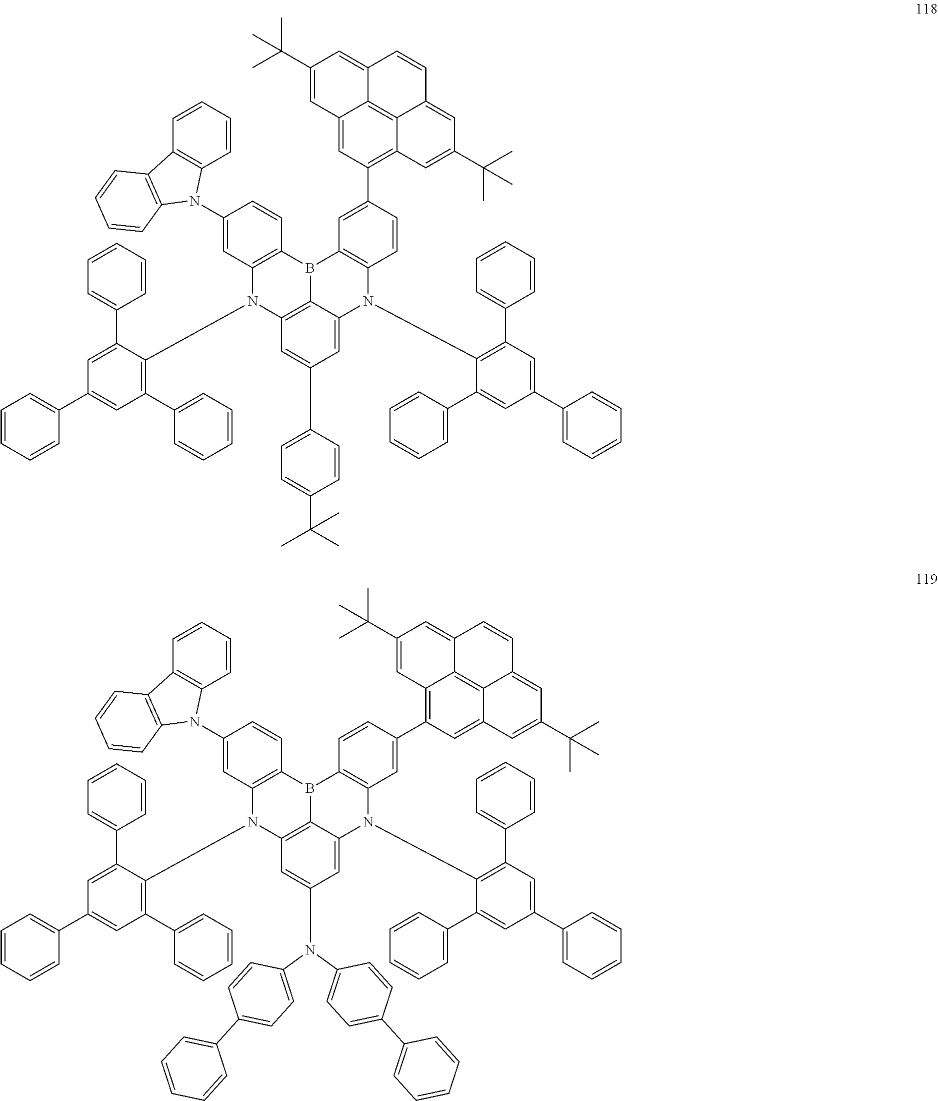 [SMILES: CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4cc5cc(C(C)(C)C)cc6ccc7cc(C(C)(C)C)cc4c7c65)ccc2N3c2c(-c3ccccc3)cc(-c3ccccc3)cc2-c2ccccc2)cc1 ; CC(C)(C)c1cc2ccc3cc(C(C)(C)C)cc4c(-c5ccc6c(c5)N(c5c(-c7ccccc7)cc(-c7ccccc7)cc5-c5ccccc5)c5cc(N(c7ccc(-c8ccccc8)cc7)c7ccc(-c8ccccc8)cc7)cc7c5B6c5ccc(-n6c8ccccc8c8ccccc86)cc5N7c5c(-c6ccccc6)cc(-c6ccccc6)cc5-c5ccccc5)cc(c1)c2c34] 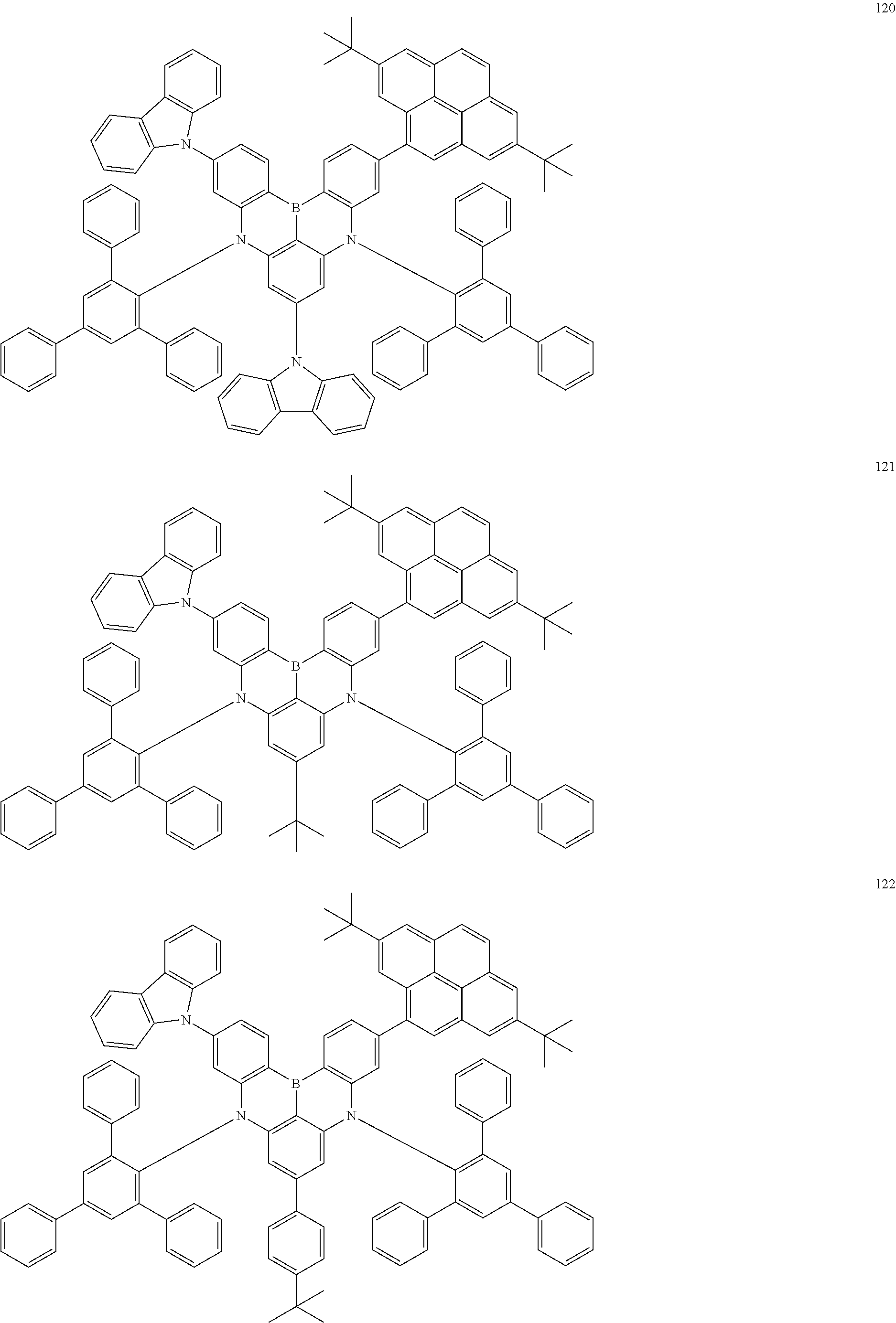 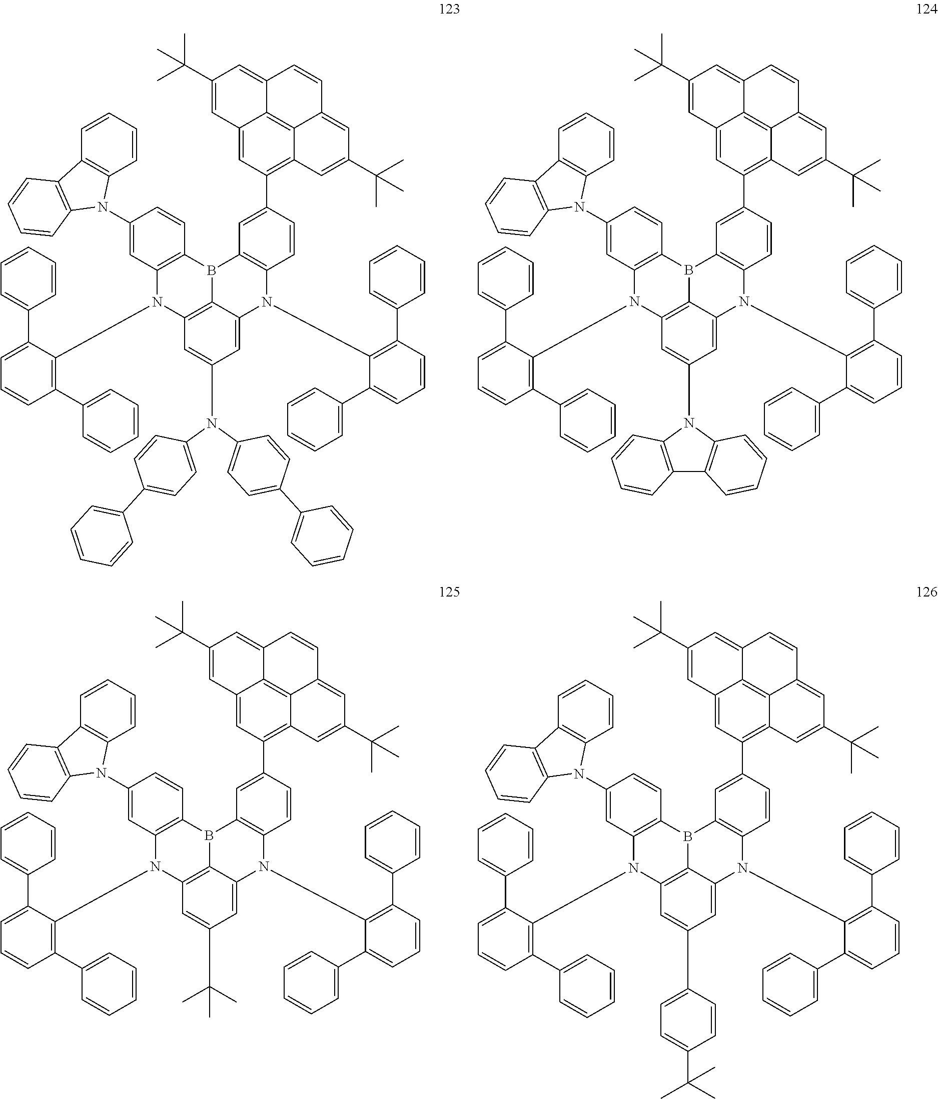 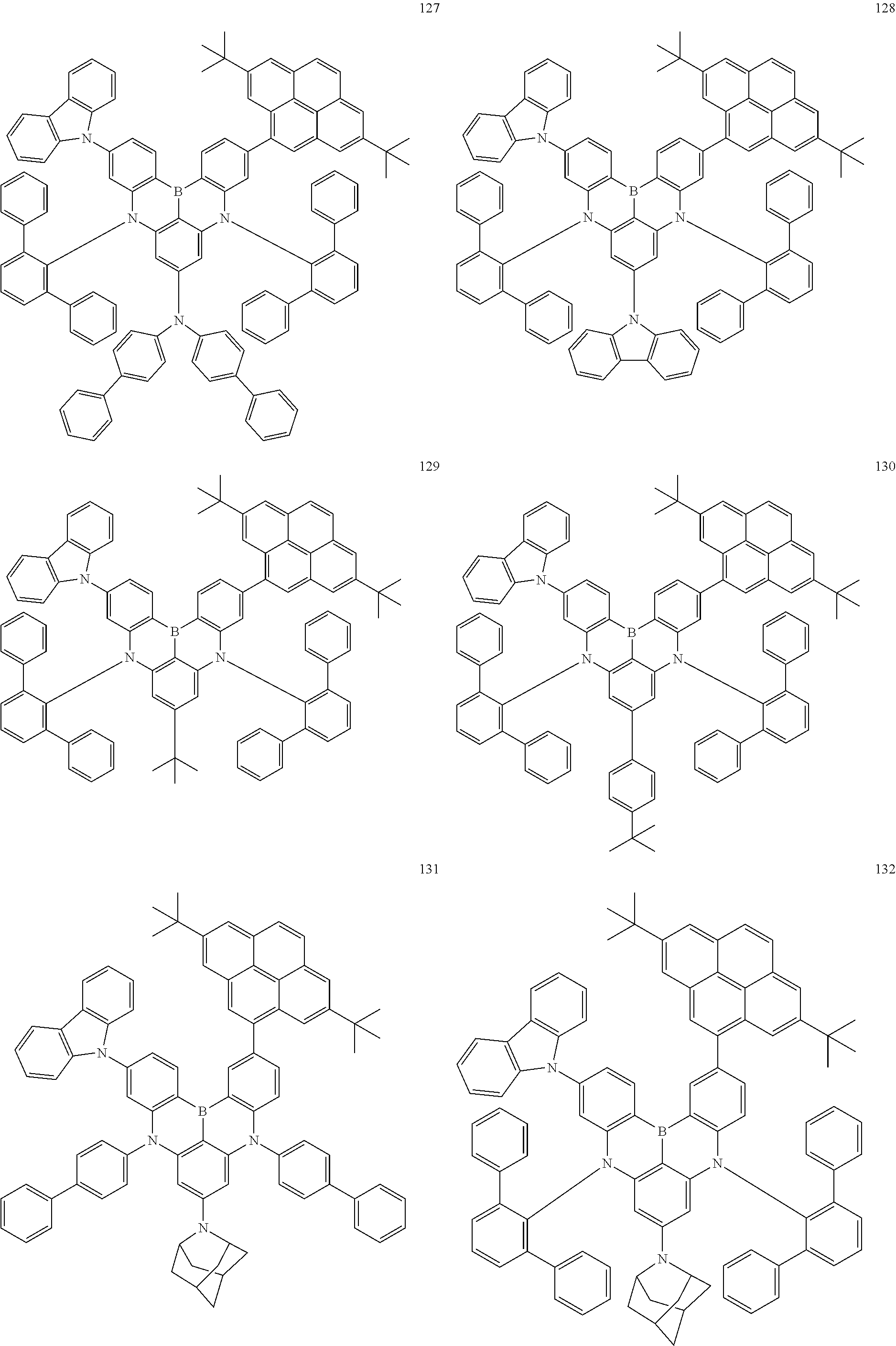 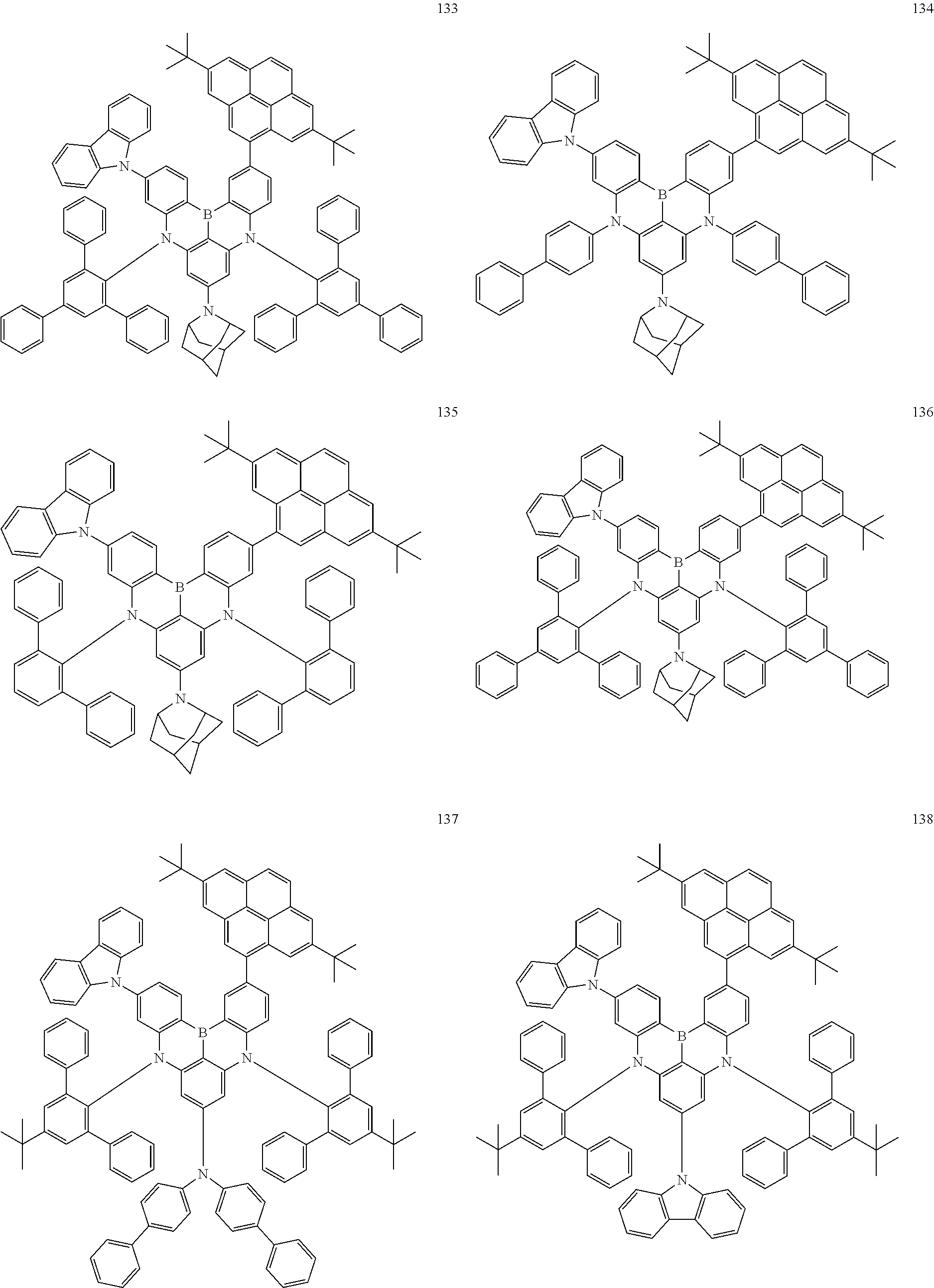 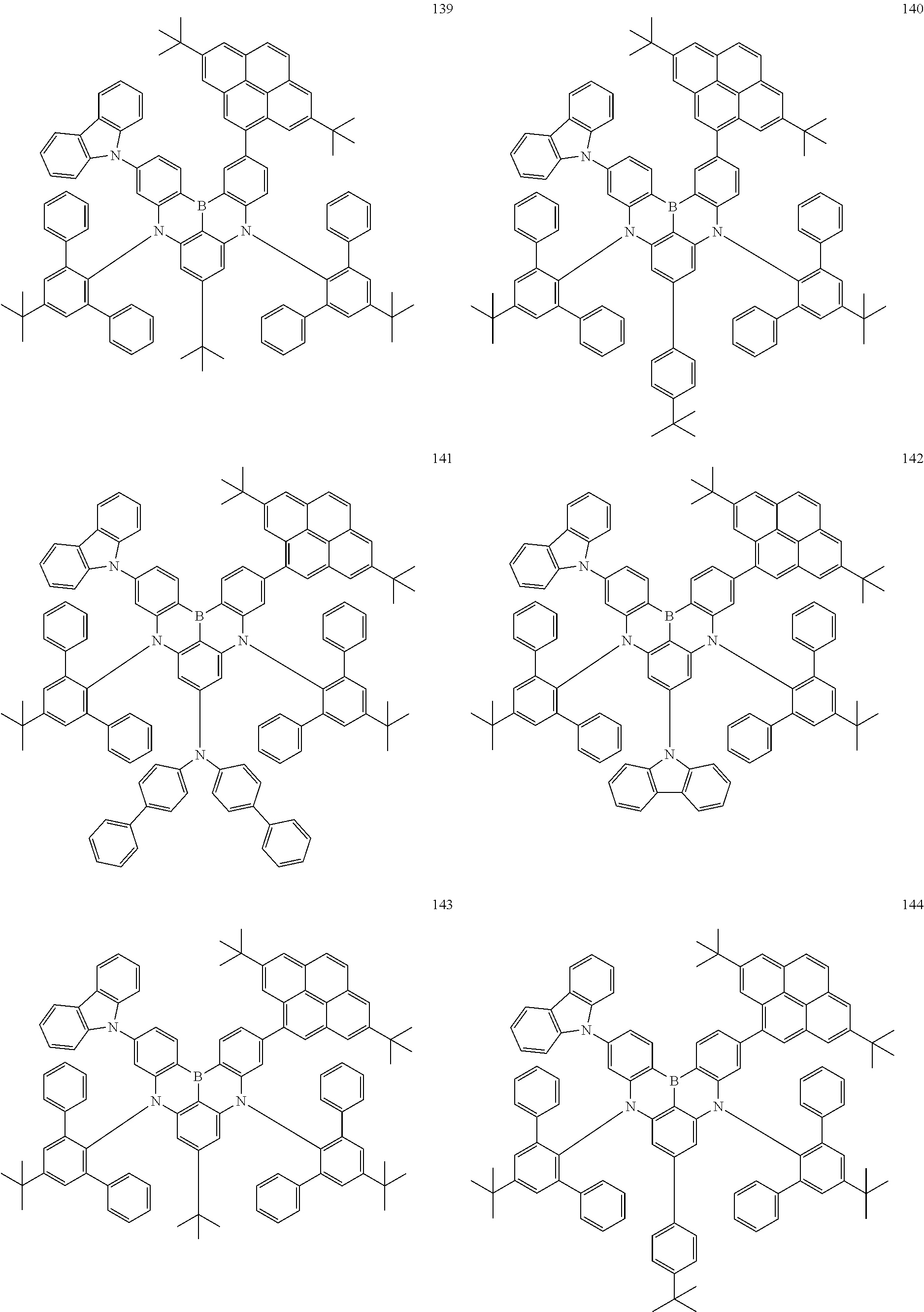 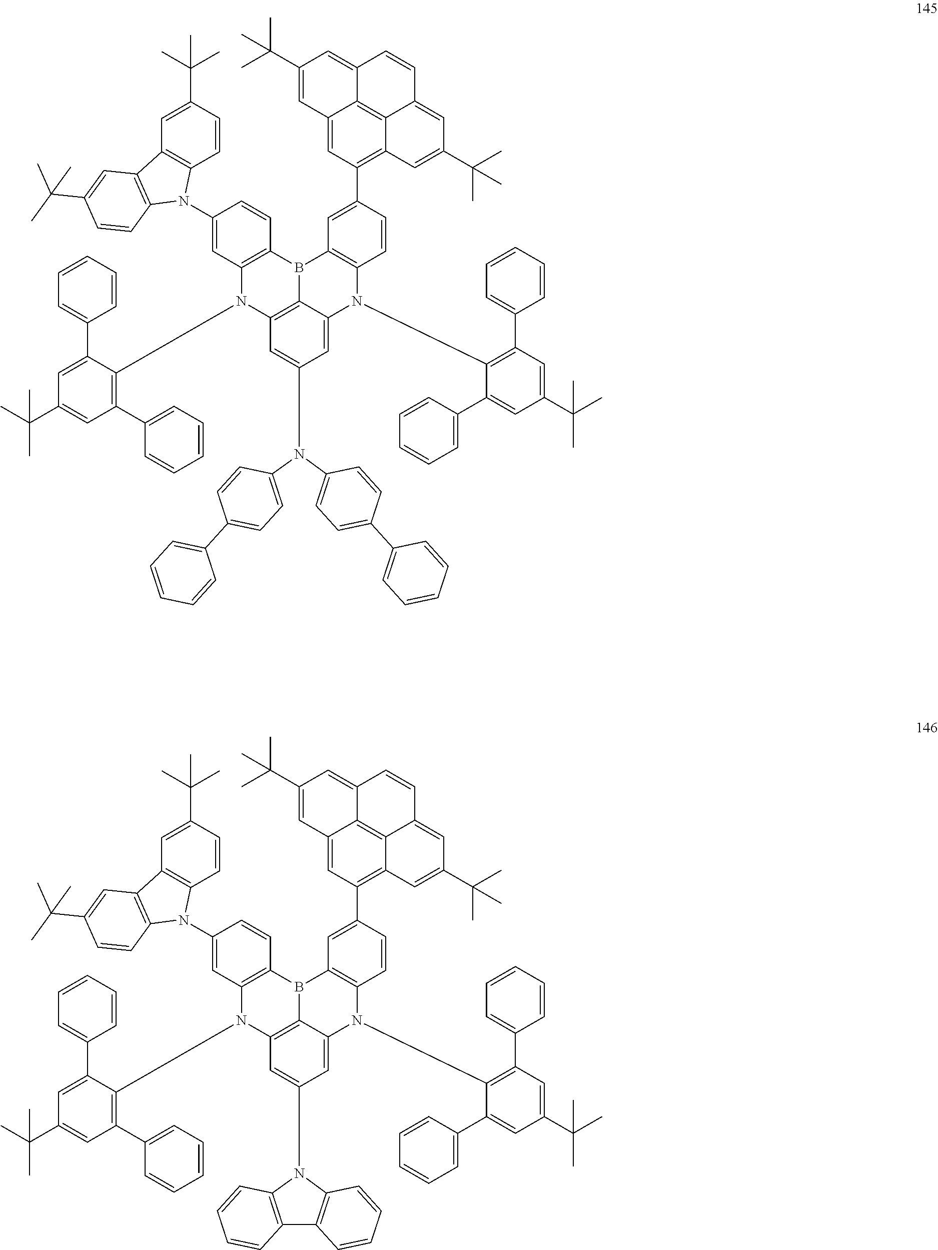 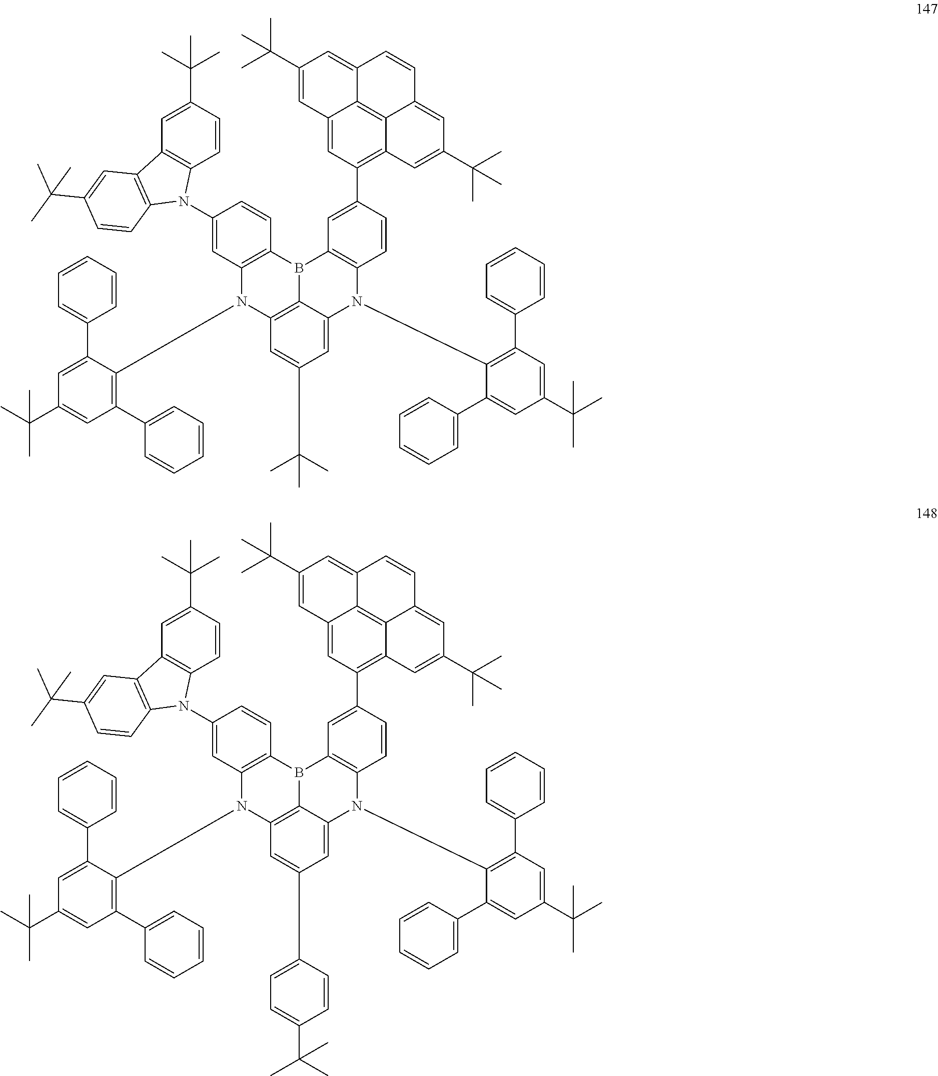 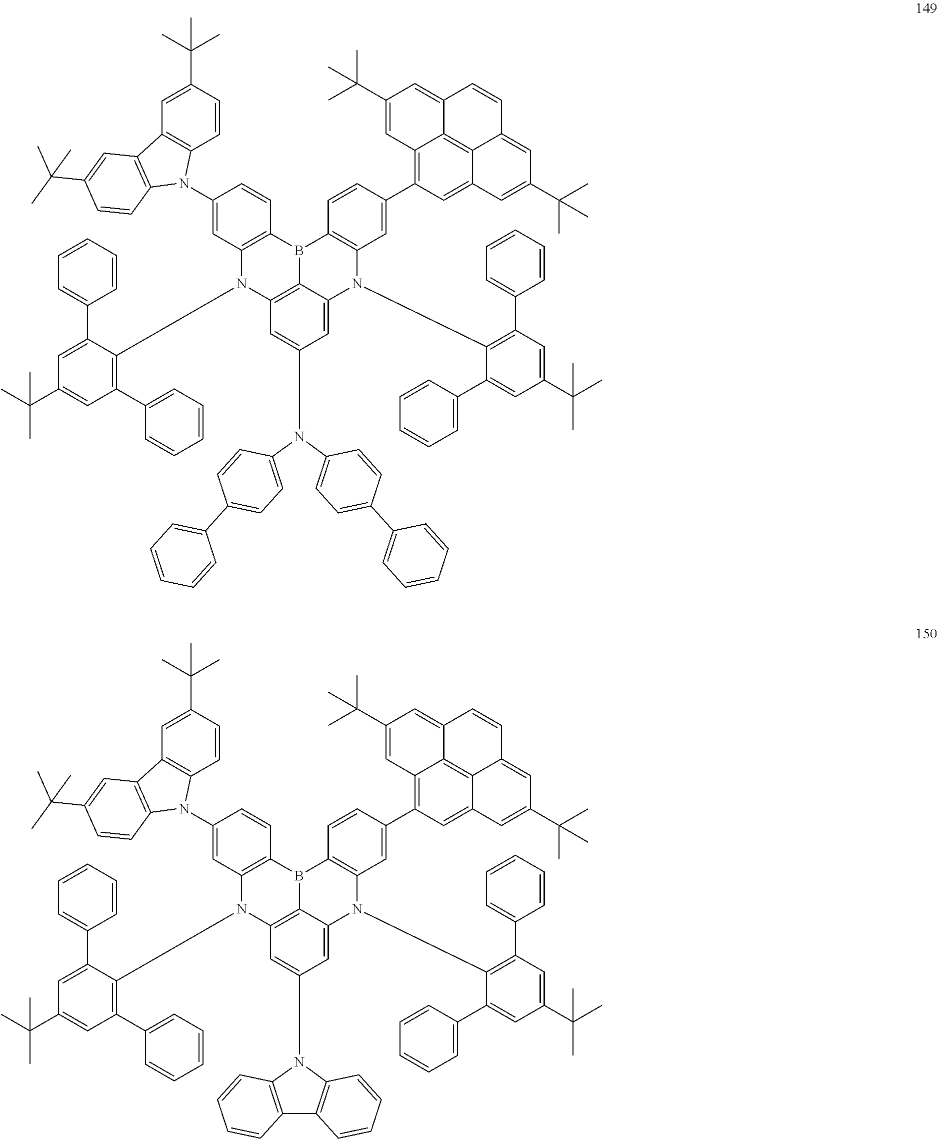 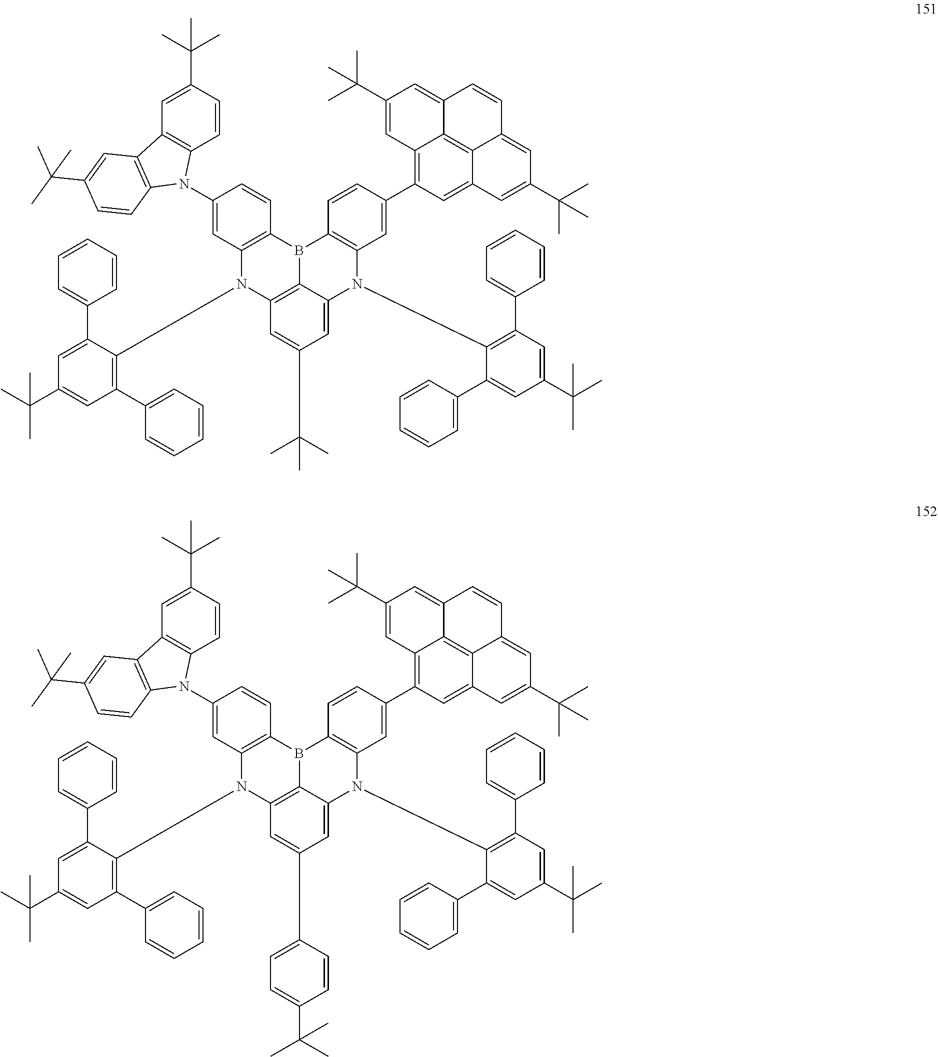 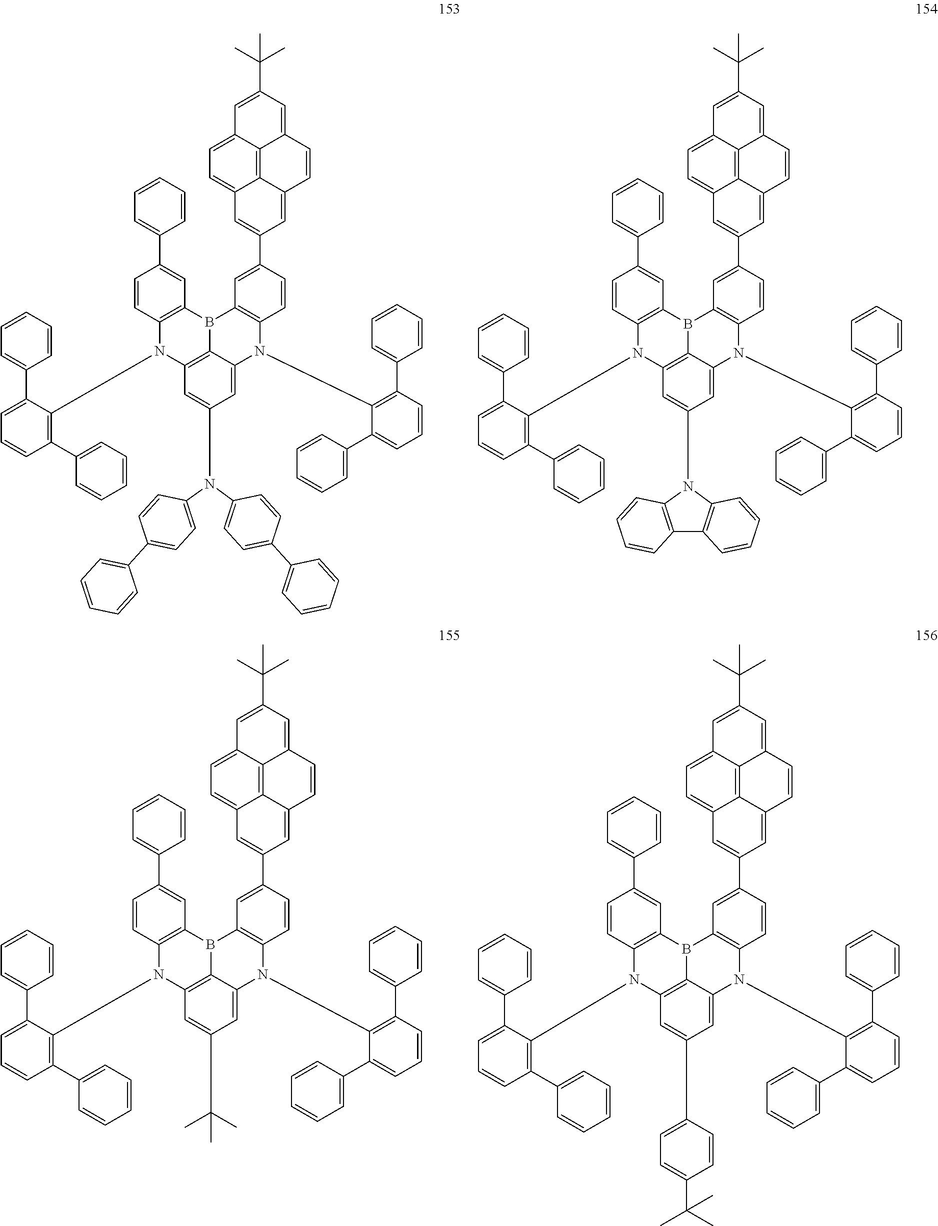 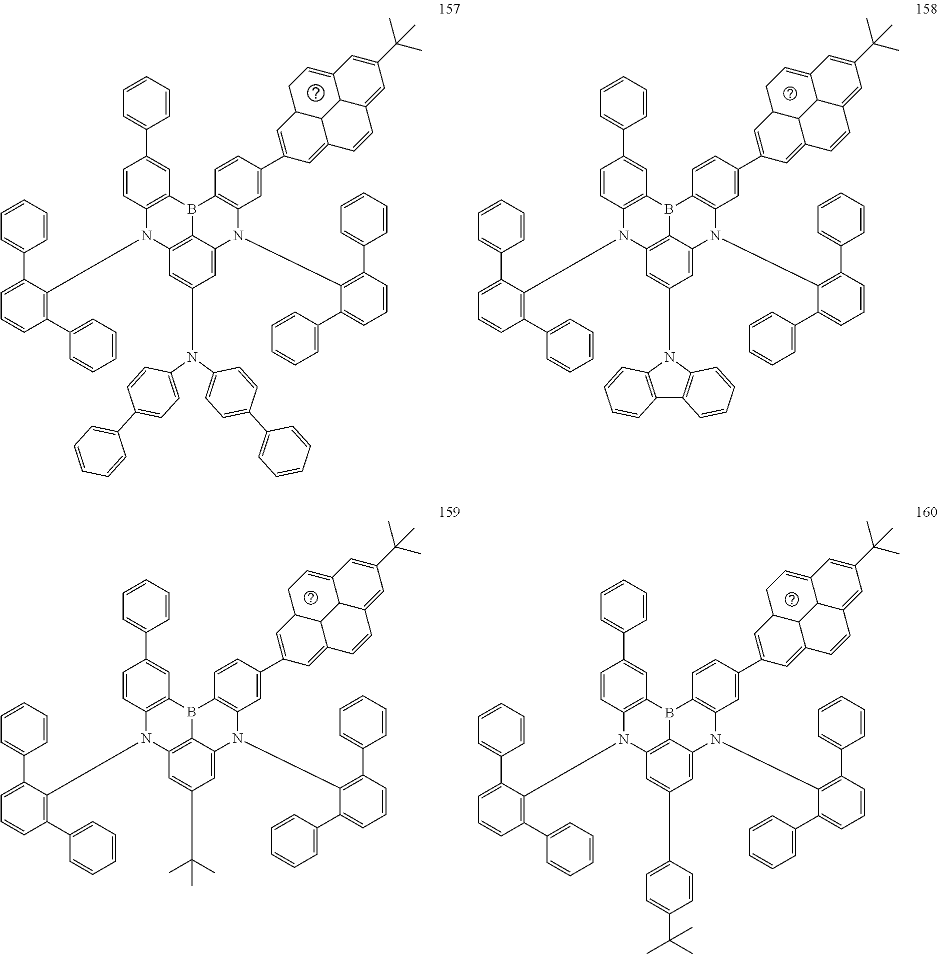 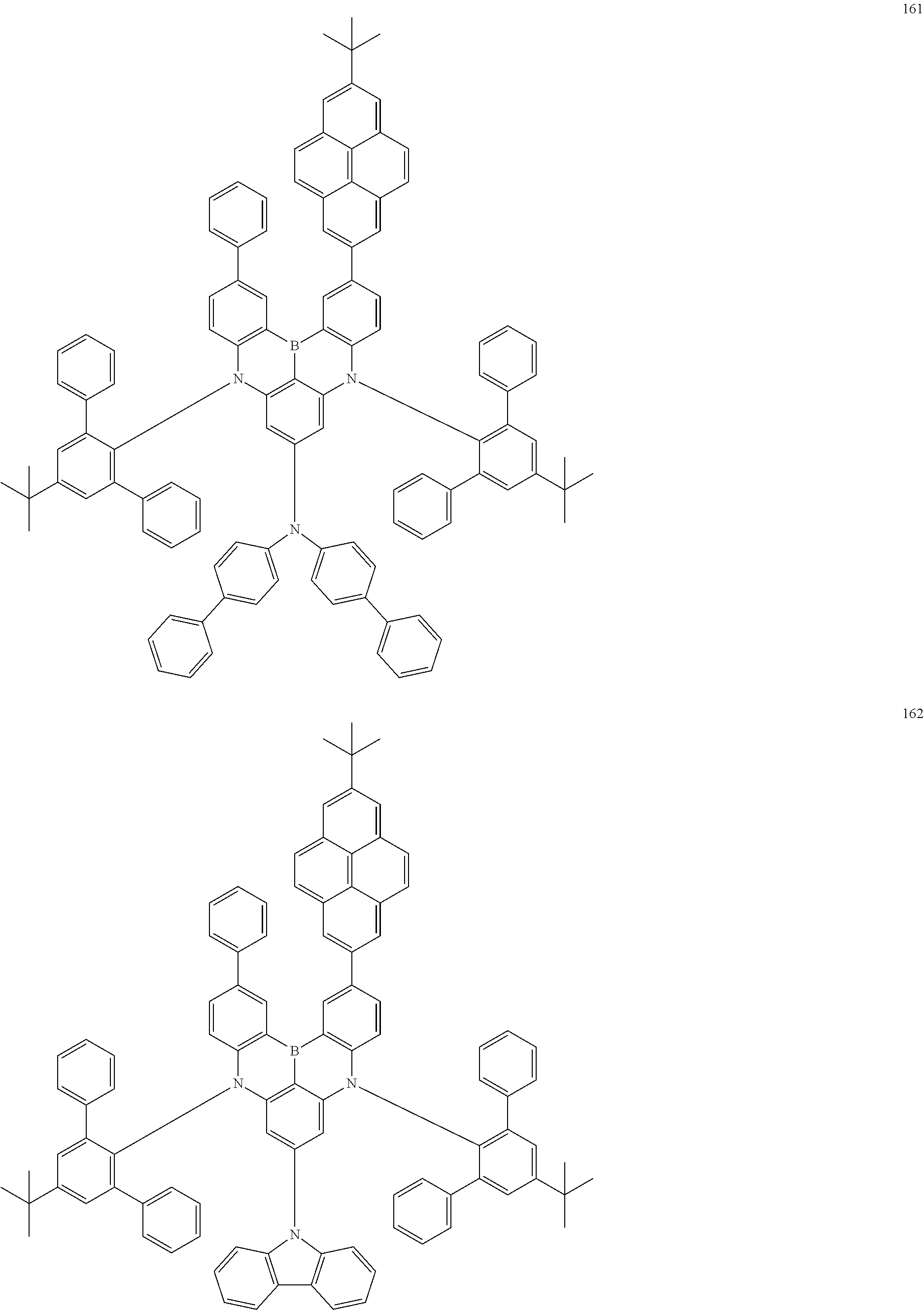 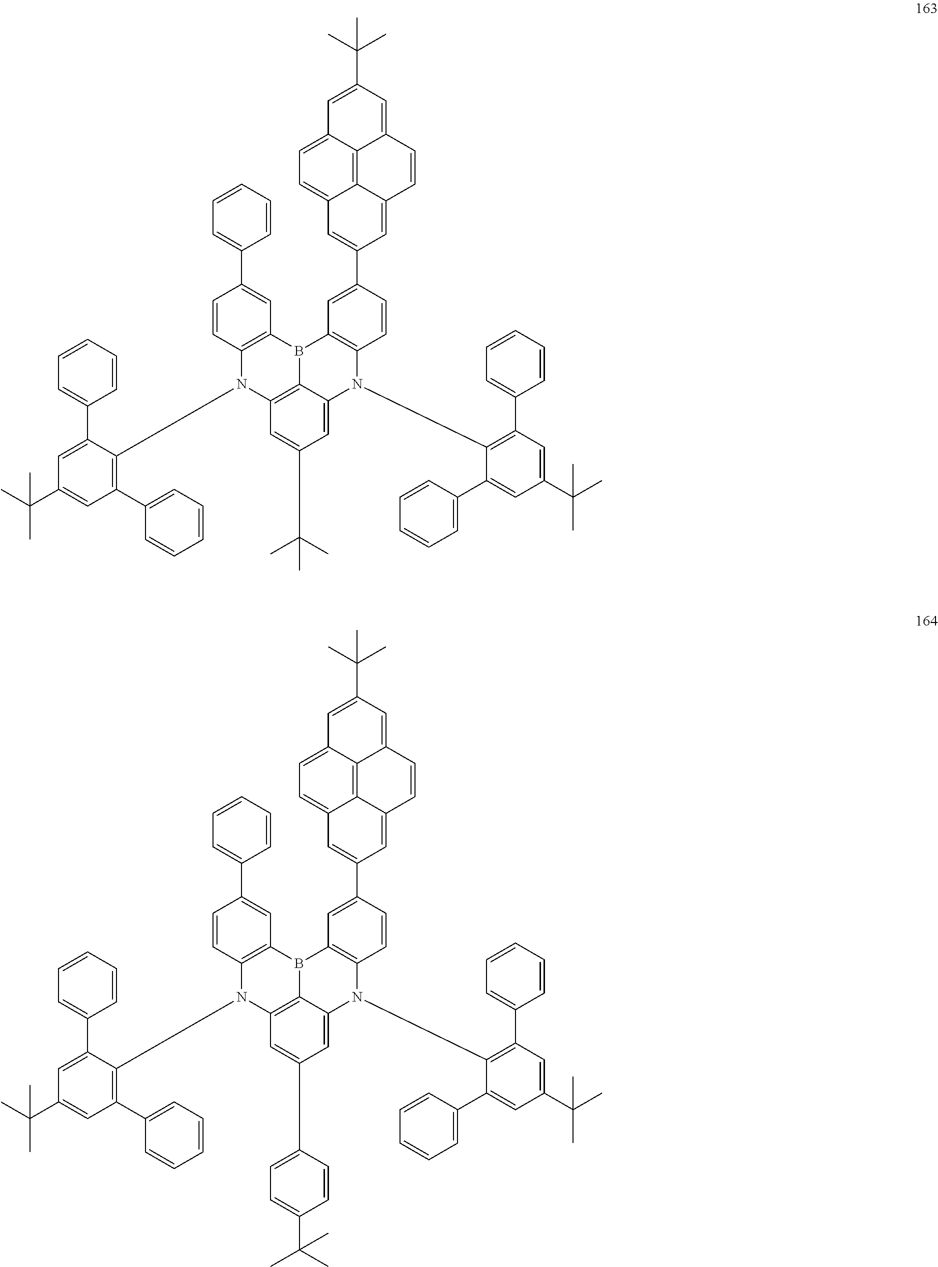 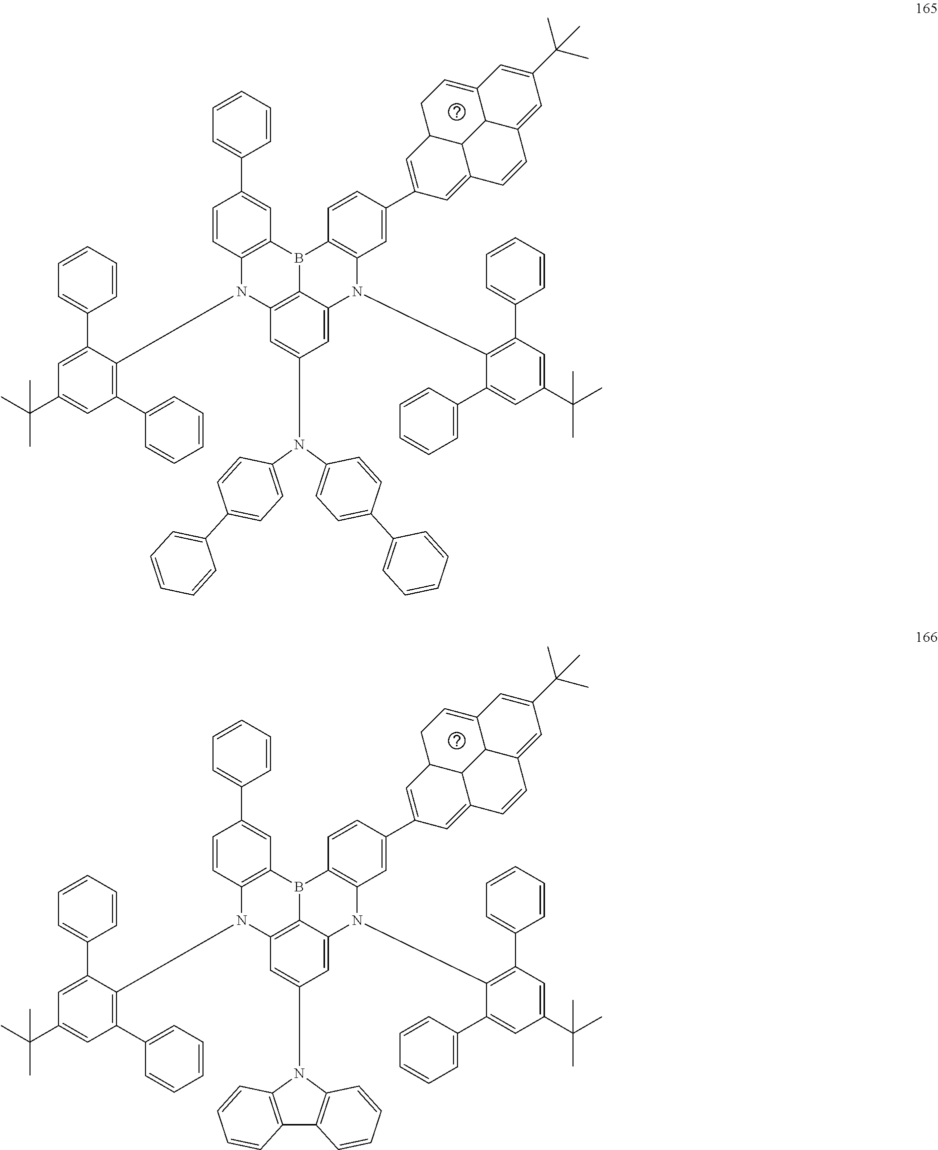 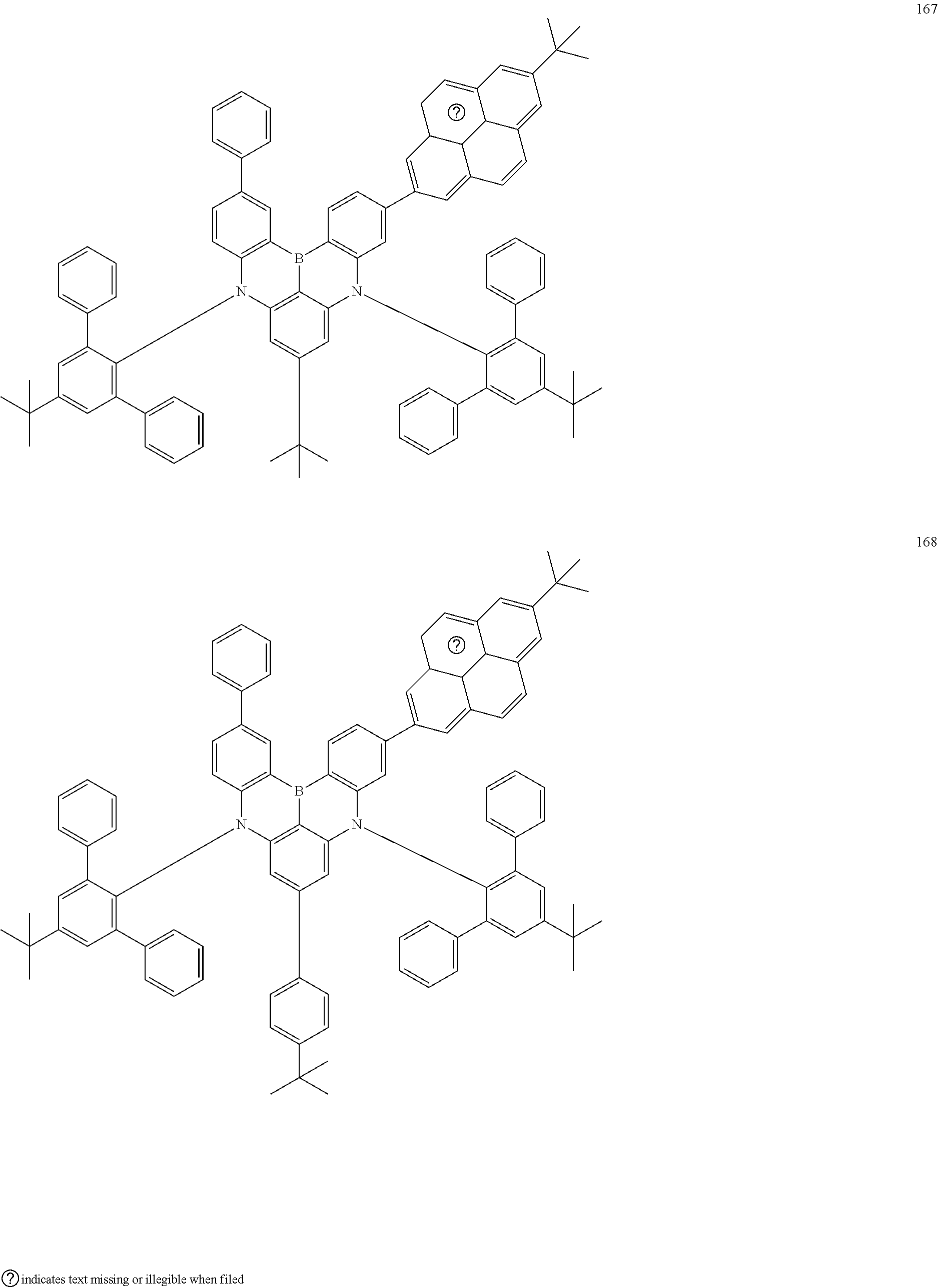 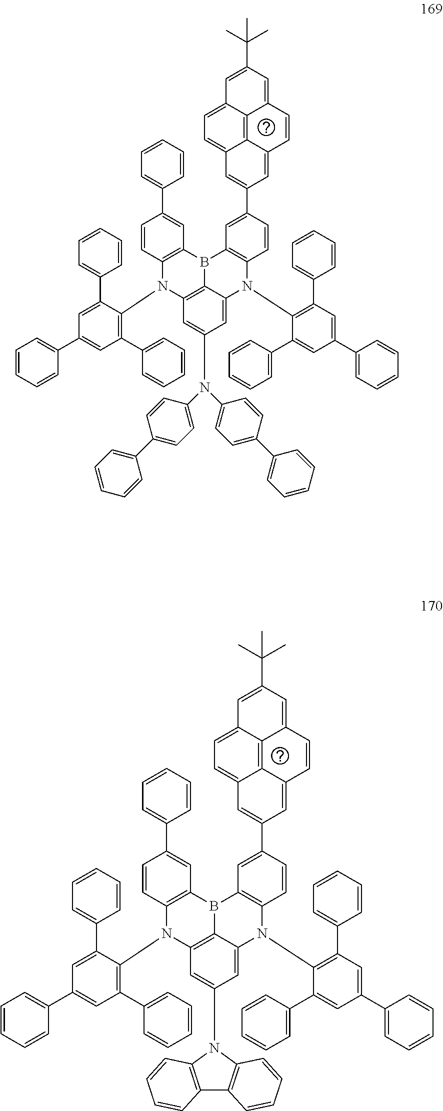 [SMILES: CC(C)(C)c1cc2ccc3cc(-c4ccc5c(c4)B4c6cc(-c7ccccc7)ccc6N(c6c(-c7ccccc7)cc(-c7ccccc7)cc6-c6ccccc6)c6cc(N(c7ccc(-c8ccccc8)cc7)c7ccc(-c8ccccc8)cc7)cc(c64)N5c4c(-c5ccccc5)cc(-c5ccccc5)cc4-c4ccccc4)cc4ccc(c1)c2c34 ; CC(C)(C)c1cc2ccc3cc(-c4ccc5c(c4)B4c6cc(-c7ccccc7)ccc6N(c6c(-c7ccccc7)cc(-c7ccccc7)cc6-c6ccccc6)c6cc(-n7c8ccccc8c8ccccc87)cc(c64)N5c4c(-c5ccccc5)cc(-c5ccccc5)cc4-c4ccccc4)cc4ccc(c1)c2c34] 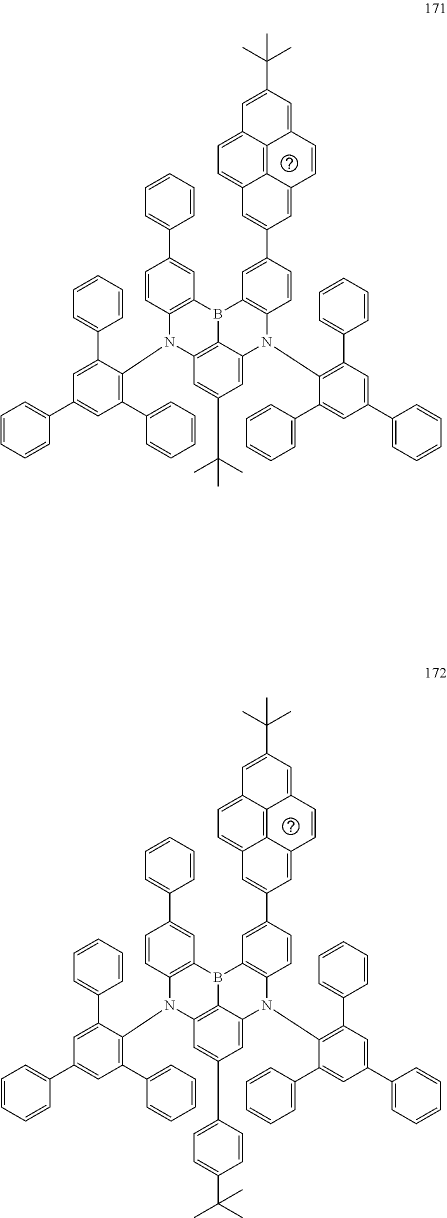 [SMILES: CC(C)(C)c1cc2c3c(c1)N(c1c(-c4ccccc4)cc(-c4ccccc4)cc1-c1ccccc1)c1ccc(-c4cc5ccc6cc(C(C)(C)C)cc7ccc(c4)c5c67)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5cc6ccc7cc(C(C)(C)C)cc8ccc(c5)c6c78)cc2B4c2cc(-c4ccccc4)ccc2N3c2c(-c3ccccc3)cc(-c3ccccc3)cc2-c2ccccc2)cc1] 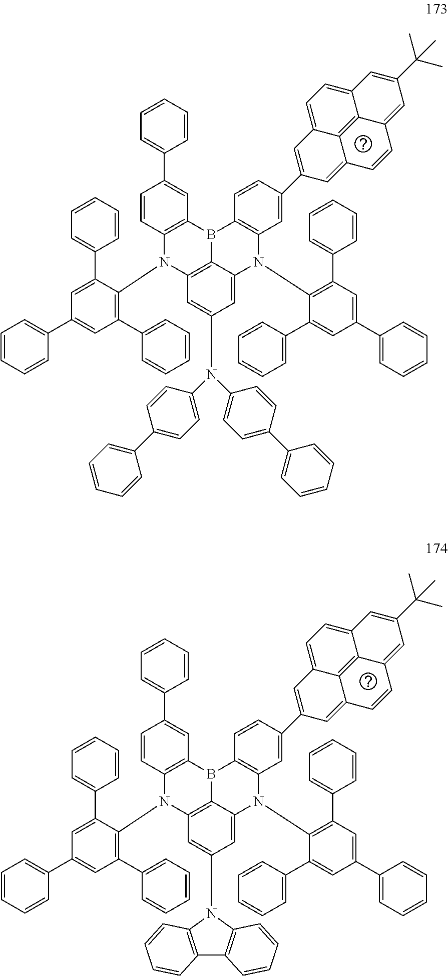 [SMILES: CC(C)(C)c1cc2ccc3cc(-c4ccc5c(c4)N(c4c(-c6ccccc6)cc(-c6ccccc6)cc4-c4ccccc4)c4cc(N(c6ccc(-c7ccccc7)cc6)c6ccc(-c7ccccc7)cc6)cc6c4B5c4cc(-c5ccccc5)ccc4N6c4c(-c5ccccc5)cc(-c5ccccc5)cc4-c4ccccc4)cc4ccc(c1)c2c34 ; CC(C)(C)c1cc2ccc3cc(-c4ccc5c(c4)N(c4c(-c6ccccc6)cc(-c6ccccc6)cc4-c4ccccc4)c4cc(-n6c7ccccc7c7ccccc76)cc6c4B5c4cc(-c5ccccc5)ccc4N6c4c(-c5ccccc5)cc(-c5ccccc5)cc4-c4ccccc4)cc4ccc(c1)c2c34] 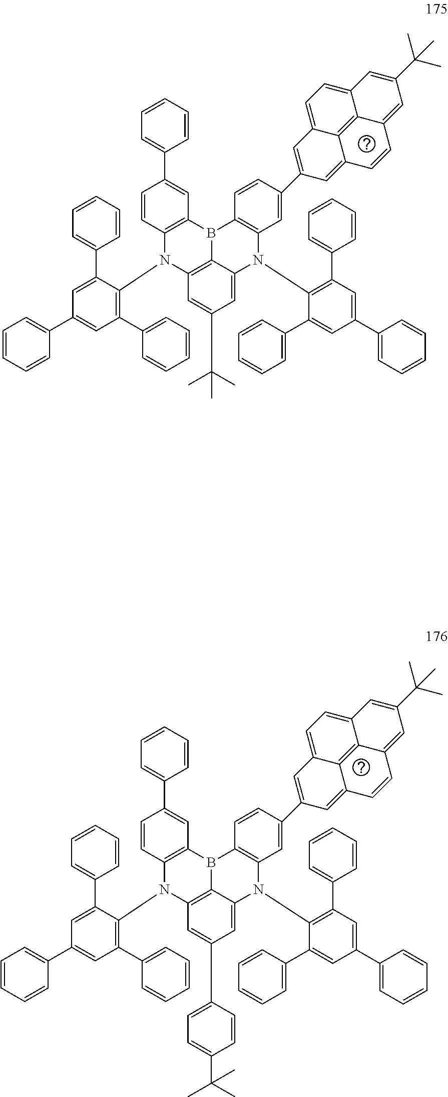 [SMILES: CC(C)(C)c1cc2c3c(c1)N(c1c(-c4ccccc4)cc(-c4ccccc4)cc1-c1ccccc1)c1cc(-c4cc5ccc6cc(C(C)(C)C)cc7ccc(c4)c5c67)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5cc6ccc7cc(C(C)(C)C)cc8ccc(c5)c6c78)ccc2B4c2cc(-c4ccccc4)ccc2N3c2c(-c3ccccc3)cc(-c3ccccc3)cc2-c2ccccc2)cc1] 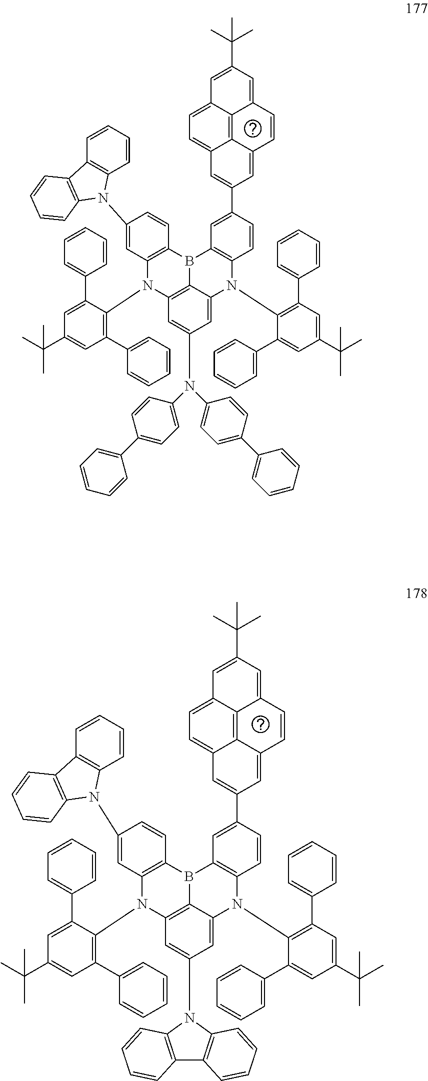 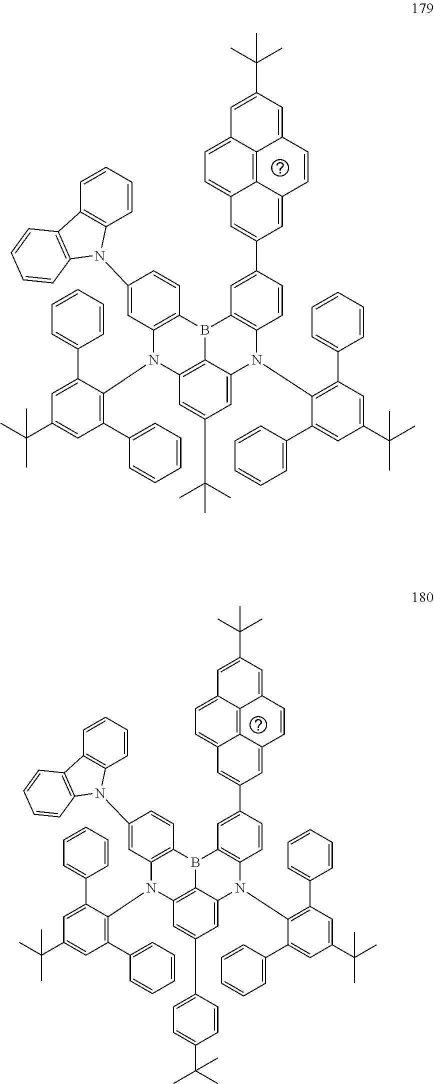 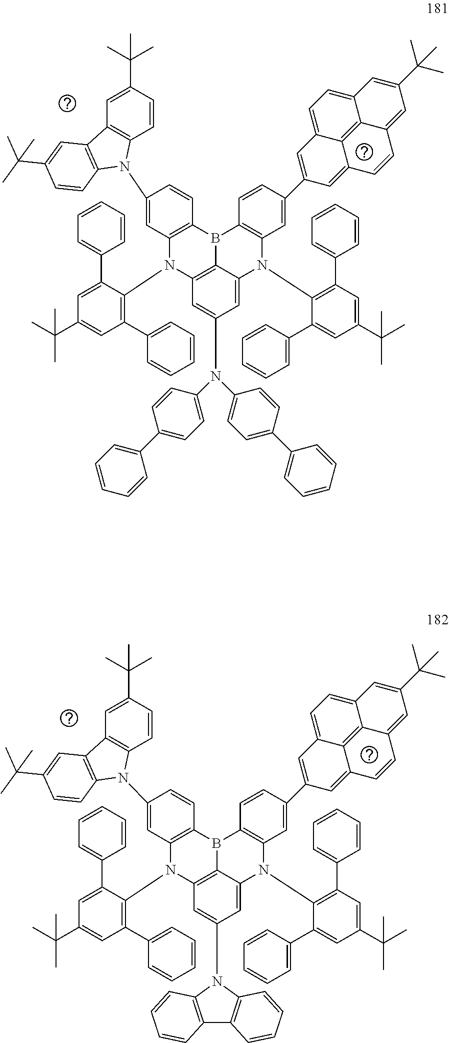 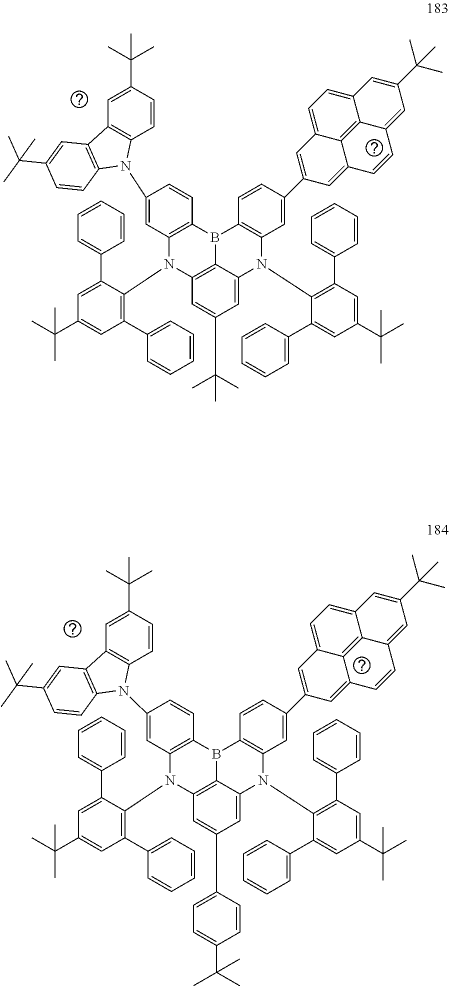 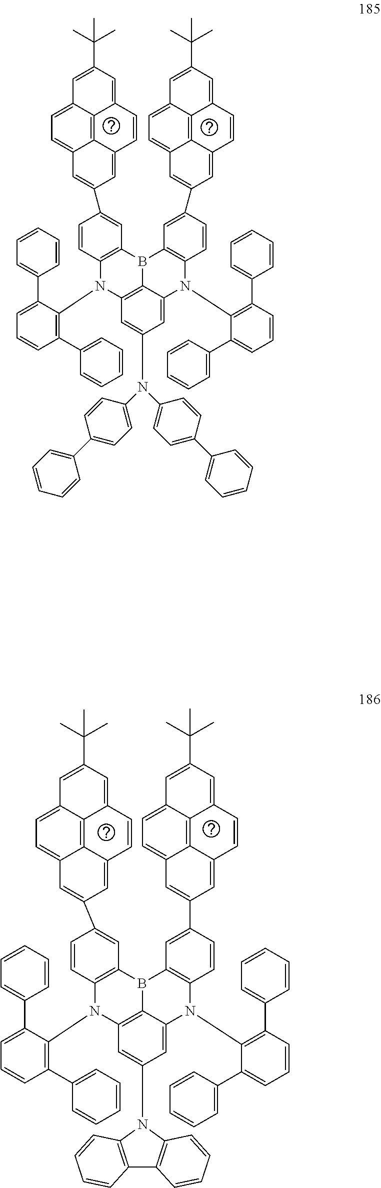 [SMILES: CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cccc6-c6ccccc6)c6cc(N(c7ccc(-c8ccccc8)cc7)c7ccc(-c8ccccc8)cc7)cc(c64)N5c4c(-c5ccccc5)cccc4-c4ccccc4)cc4ccc(c1)c2c34 ; CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cccc6-c6ccccc6)c6cc(-n7c8ccccc8c8ccccc87)cc(c64)N5c4c(-c5ccccc5)cccc4-c4ccccc4)cc4ccc(c1)c2c34] 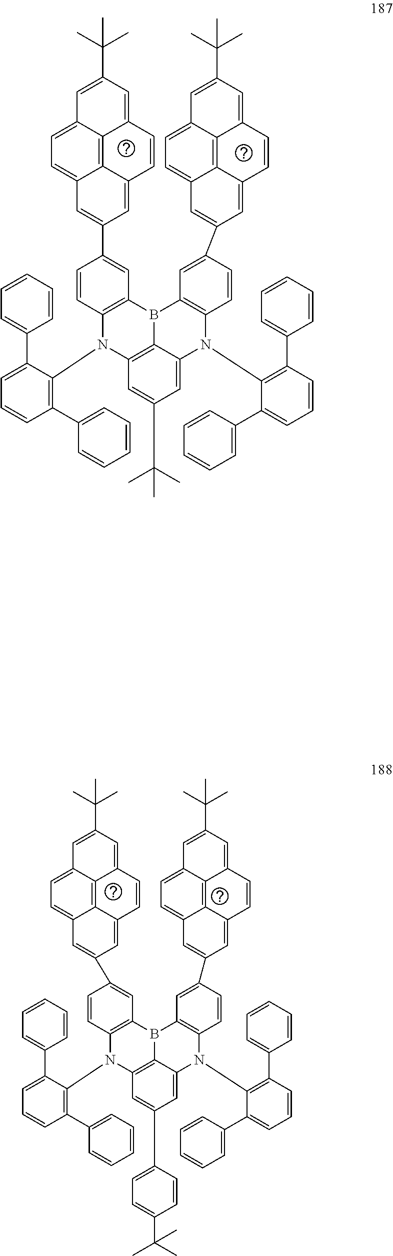 [SMILES: CC(C)(C)c1cc2c3c(c1)N(c1c(-c4ccccc4)cccc1-c1ccccc1)c1ccc(-c4cc5ccc6cc(C(C)(C)C)cc7ccc(c4)c5c67)cc1B3c1cc(-c3cc4ccc5cc(C(C)(C)C)cc6ccc(c3)c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6ccc7cc(C(C)(C)C)cc8ccc(c5)c6c78)cc2B4c2cc(-c4cc5ccc6cc(C(C)(C)C)cc7ccc(c4)c5c67)ccc2N3c2c(-c3ccccc3)cccc2-c2ccccc2)cc1] 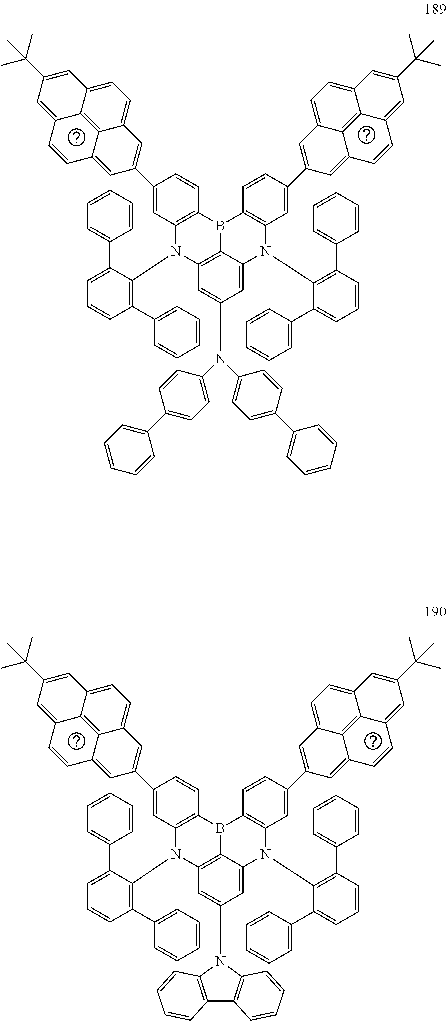 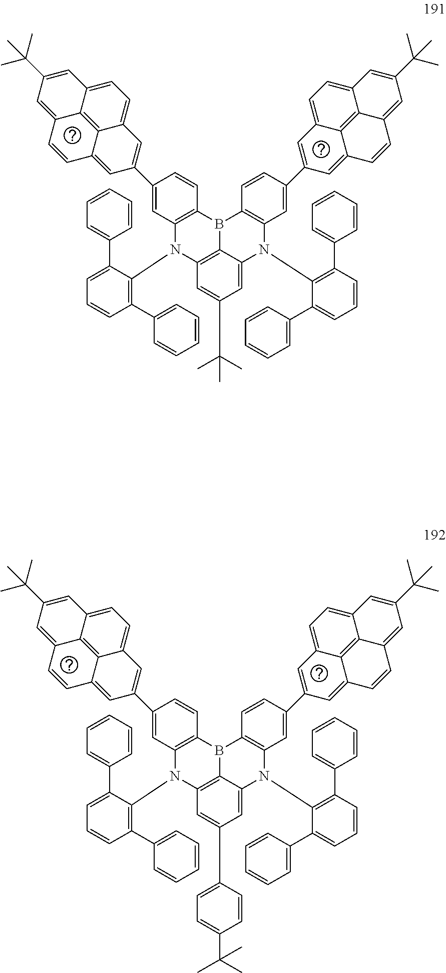 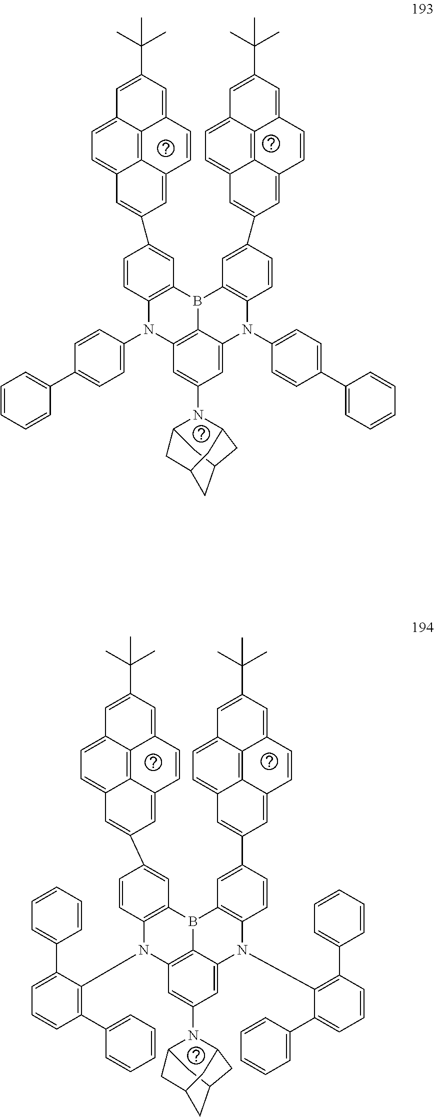 [SMILES: CC(C)(C)c1cc2ccc3cc(-c4ccc5c(c4)B4c6cc(-c7cc8ccc9cc(C(C)(C)C)cc%10ccc(c7)c8c9%10)ccc6N(c6ccc(-c7ccccc7)cc6)c6cc(N7C8CC9CC(C8)CC7C9)cc(c64)N5c4ccc(-c5ccccc5)cc4)cc4ccc(c1)c2c34 ; CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cccc6-c6ccccc6)c6cc(N7C8CC9CC(C8)CC7C9)cc(c64)N5c4c(-c5ccccc5)cccc4-c4ccccc4)cc4ccc(c1)c2c34] 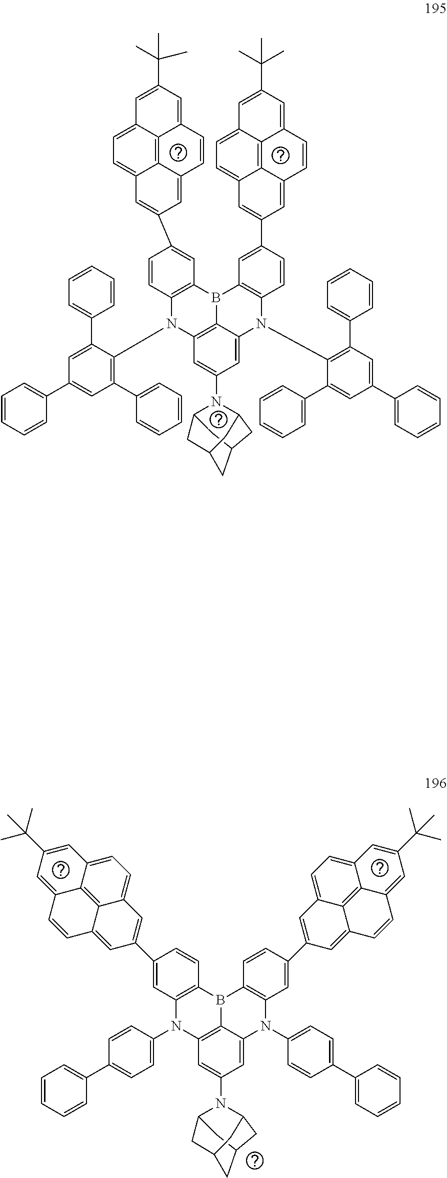 [SMILES: CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cc(-c7ccccc7)cc6-c6ccccc6)c6cc(N7C8CC9CC(C8)CC7C9)cc(c64)N5c4c(-c5ccccc5)cc(-c5ccccc5)cc4-c4ccccc4)cc4ccc(c1)c2c34 ; CC(C)(C)c1cc2ccc3cc(-c4ccc5c(c4)N(c4ccc(-c6ccccc6)cc4)c4cc(N6C7CC8CC(C7)CC6C8)cc6c4B5c4ccc(-c5cc7ccc8cc(C(C)(C)C)cc9ccc(c5)c7c89)cc4N6c4ccc(-c5ccccc5)cc4)cc4ccc(c1)c2c34] 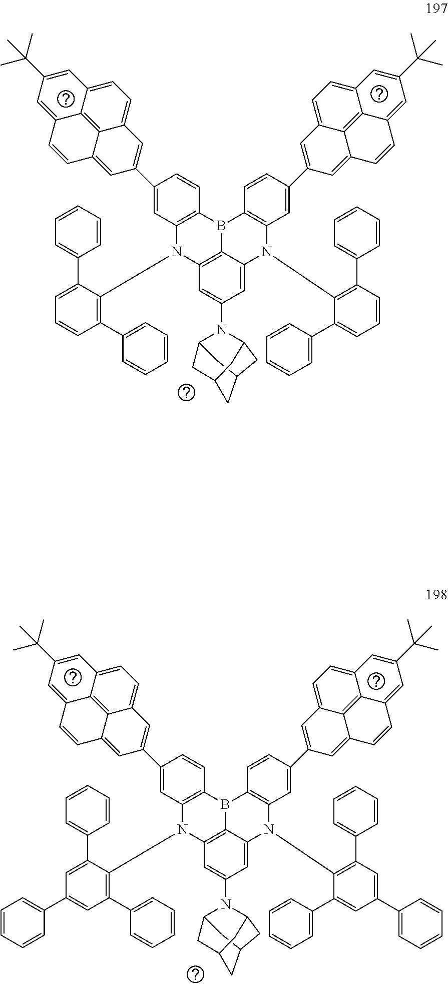 [SMILES: CC(C)(C)c1cc2ccc3cc(-c4ccc5c(c4)N(c4c(-c6ccccc6)cccc4-c4ccccc4)c4cc(N6C7CC8CC(C7)CC6C8)cc6c4B5c4ccc(-c5cc7ccc8cc(C(C)(C)C)cc9ccc(c5)c7c89)cc4N6c4c(-c5ccccc5)cccc4-c4ccccc4)cc4ccc(c1)c2c34 ; CC(C)(C)c1cc2ccc3cc(-c4ccc5c(c4)N(c4c(-c6ccccc6)cc(-c6ccccc6)cc4-c4ccccc4)c4cc(N6C7CC8CC(C7)CC6C8)cc6c4B5c4ccc(-c5cc7ccc8cc(C(C)(C)C)cc9ccc(c5)c7c89)cc4N6c4c(-c5ccccc5)cc(-c5ccccc5)cc4-c4ccccc4)cc4ccc(c1)c2c34] 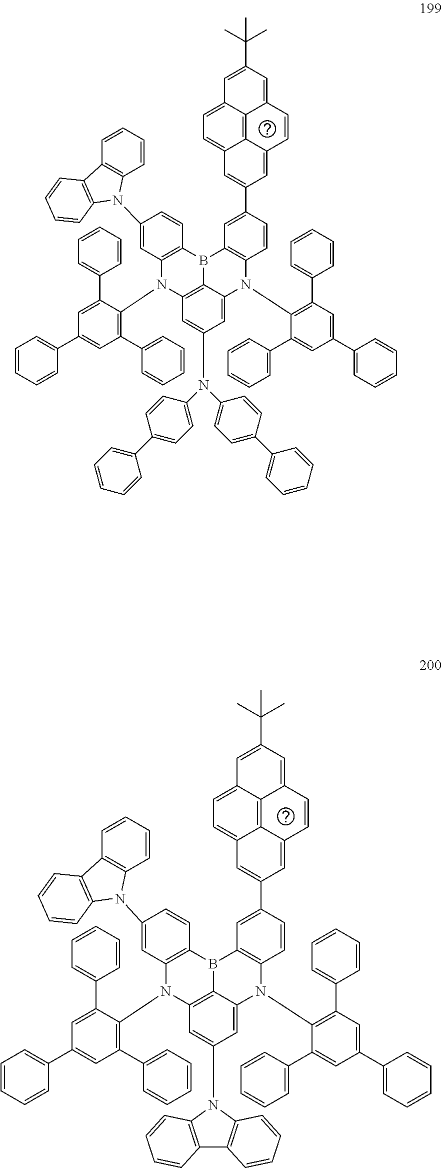 [SMILES: CC(C)(C)c1cc2ccc3cc(-c4ccc5c(c4)B4c6ccc(-n7c8ccccc8c8ccccc87)cc6N(c6c(-c7ccccc7)cc(-c7ccccc7)cc6-c6ccccc6)c6cc(N(c7ccc(-c8ccccc8)cc7)c7ccc(-c8ccccc8)cc7)cc(c64)N5c4c(-c5ccccc5)cc(-c5ccccc5)cc4-c4ccccc4)cc4ccc(c1)c2c34 ; CC(C)(C)c1cc2ccc3cc(-c4ccc5c(c4)B4c6ccc(-n7c8ccccc8c8ccccc87)cc6N(c6c(-c7ccccc7)cc(-c7ccccc7)cc6-c6ccccc6)c6cc(-n7c8ccccc8c8ccccc87)cc(c64)N5c4c(-c5ccccc5)cc(-c5ccccc5)cc4-c4ccccc4)cc4ccc(c1)c2c34] 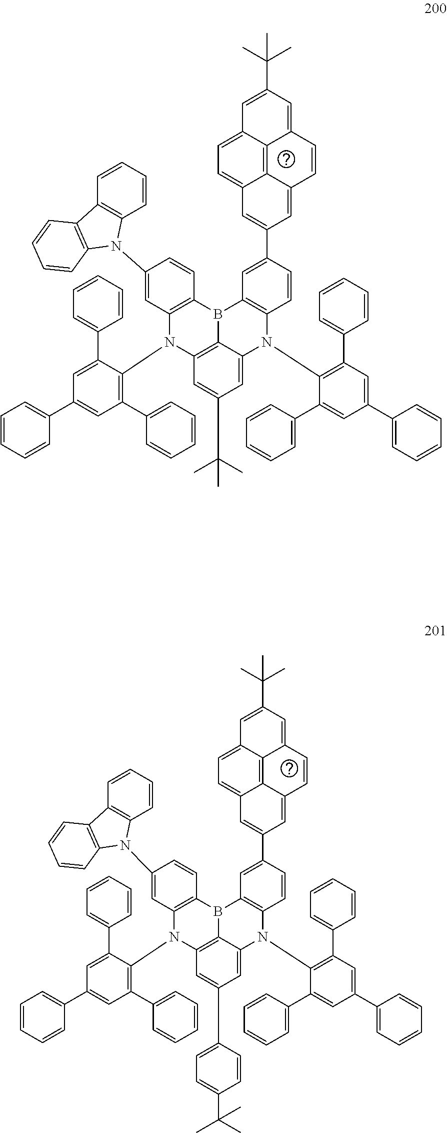 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1cc(-c3cc4ccc5cc(C(C)(C)C)cc6ccc(c3)c4c56)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4cc5ccc6cc(C(C)(C)C)cc7ccc(c4)c5c67)ccc2N3c2c(-c3ccccc3)cc(-c3ccccc3)cc2-c2ccccc2)cc1] 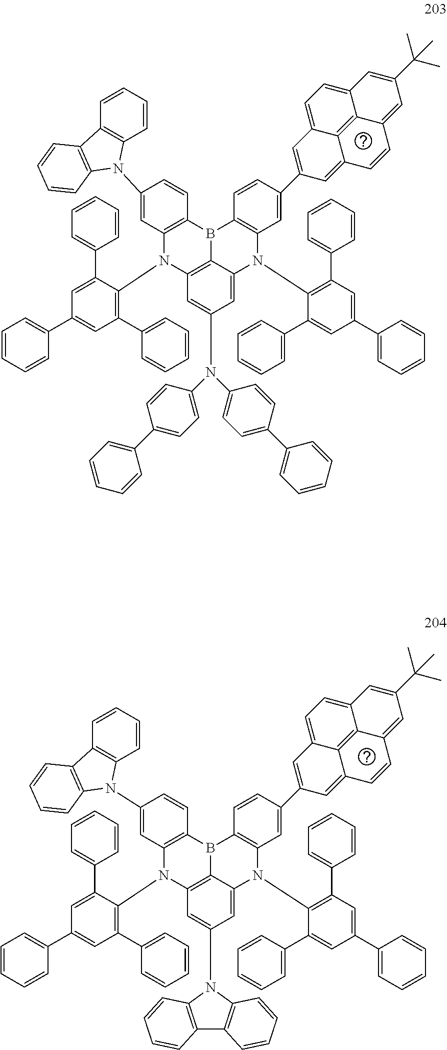 [SMILES: CC(C)(C)c1cc2ccc3cc(-c4ccc5c(c4)N(c4c(-c6ccccc6)cc(-c6ccccc6)cc4-c4ccccc4)c4cc(N(c6ccc(-c7ccccc7)cc6)c6ccc(-c7ccccc7)cc6)cc6c4B5c4ccc(-n5c7ccccc7c7ccccc75)cc4N6c4c(-c5ccccc5)cc(-c5ccccc5)cc4-c4ccccc4)cc4ccc(c1)c2c34 ; CC(C)(C)c1cc2ccc3cc(-c4ccc5c(c4)N(c4c(-c6ccccc6)cc(-c6ccccc6)cc4-c4ccccc4)c4cc(-n6c7ccccc7c7ccccc76)cc6c4B5c4ccc(-n5c7ccccc7c7ccccc75)cc4N6c4c(-c5ccccc5)cc(-c5ccccc5)cc4-c4ccccc4)cc4ccc(c1)c2c34] 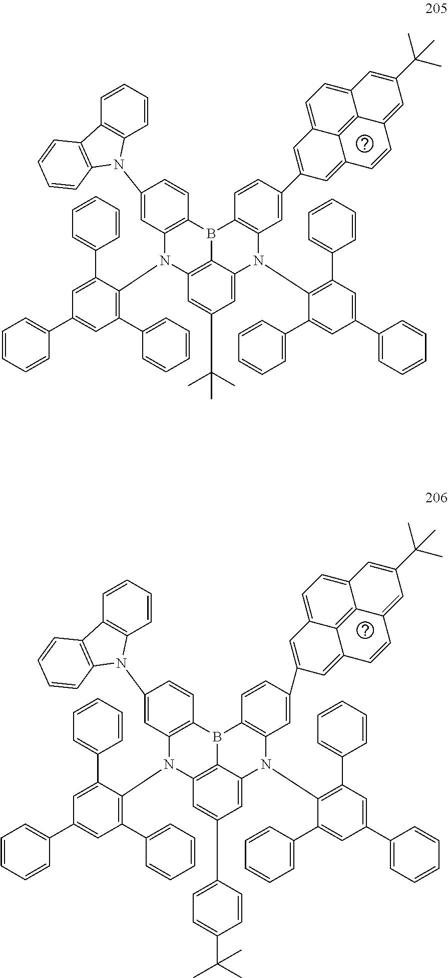 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc(-c3cc4ccc5cc(C(C)(C)C)cc6ccc(c3)c4c56)cc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2ccc(-c4cc5ccc6cc(C(C)(C)C)cc7ccc(c4)c5c67)cc2N3c2c(-c3ccccc3)cc(-c3ccccc3)cc2-c2ccccc2)cc1] 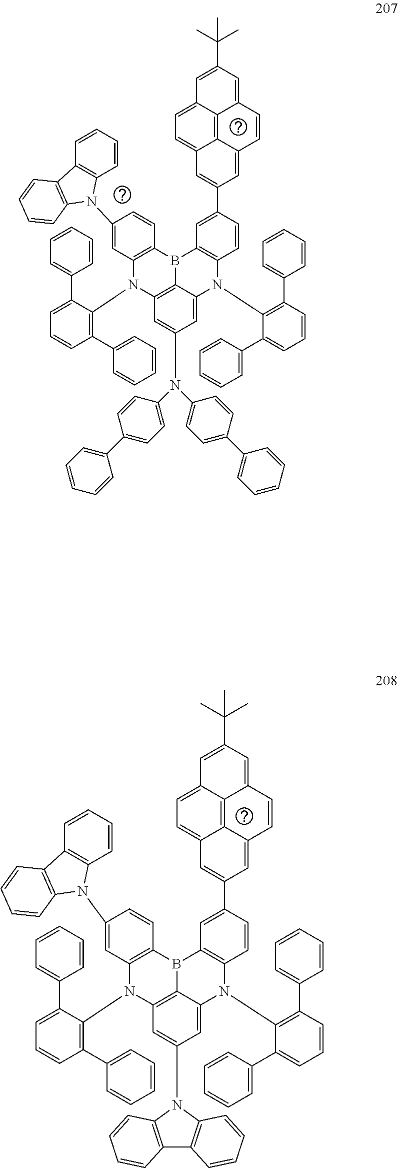 [SMILES: CC(C)(C)c1cc2ccc3cc(-c4ccc5c(c4)B4c6ccc(-n7c8ccccc8c8ccccc87)cc6N(c6c(-c7ccccc7)cccc6-c6ccccc6)c6cc(N(c7ccc(-c8ccccc8)cc7)c7ccc(-c8ccccc8)cc7)cc(c64)N5c4c(-c5ccccc5)cccc4-c4ccccc4)cc4ccc(c1)c2c34 ; CC(C)(C)c1cc2ccc3cc(-c4ccc5c(c4)B4c6ccc(-n7c8ccccc8c8ccccc87)cc6N(c6c(-c7ccccc7)cccc6-c6ccccc6)c6cc(-n7c8ccccc8c8ccccc87)cc(c64)N5c4c(-c5ccccc5)cccc4-c4ccccc4)cc4ccc(c1)c2c34] 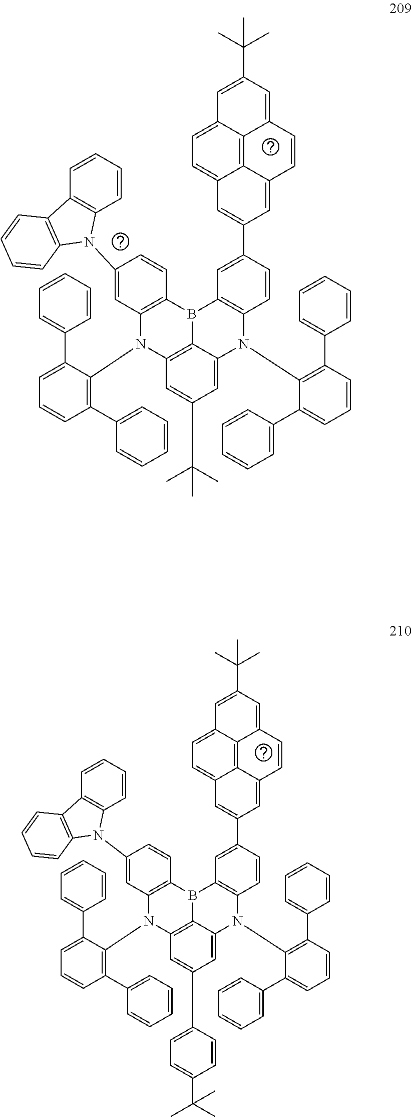 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3cc4ccc5cc(C(C)(C)C)cc6ccc(c3)c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4cc5ccc6cc(C(C)(C)C)cc7ccc(c4)c5c67)ccc2N3c2c(-c3ccccc3)cccc2-c2ccccc2)cc1] 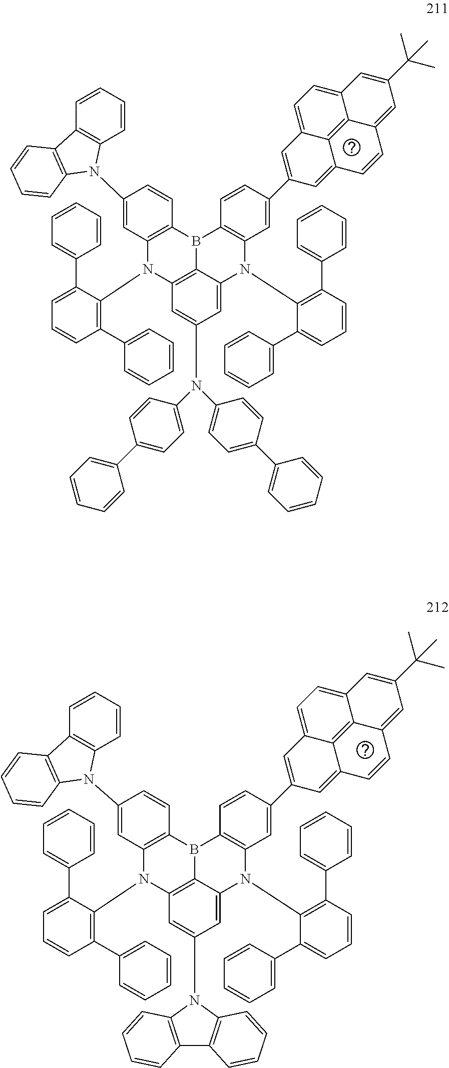 [SMILES: CC(C)(C)c1cc2ccc3cc(-c4ccc5c(c4)N(c4c(-c6ccccc6)cccc4-c4ccccc4)c4cc(N(c6ccc(-c7ccccc7)cc6)c6ccc(-c7ccccc7)cc6)cc6c4B5c4ccc(-n5c7ccccc7c7ccccc75)cc4N6c4c(-c5ccccc5)cccc4-c4ccccc4)cc4ccc(c1)c2c34 ; CC(C)(C)c1cc2ccc3cc(-c4ccc5c(c4)N(c4c(-c6ccccc6)cccc4-c4ccccc4)c4cc(-n6c7ccccc7c7ccccc76)cc6c4B5c4ccc(-n5c7ccccc7c7ccccc75)cc4N6c4c(-c5ccccc5)cccc4-c4ccccc4)cc4ccc(c1)c2c34] 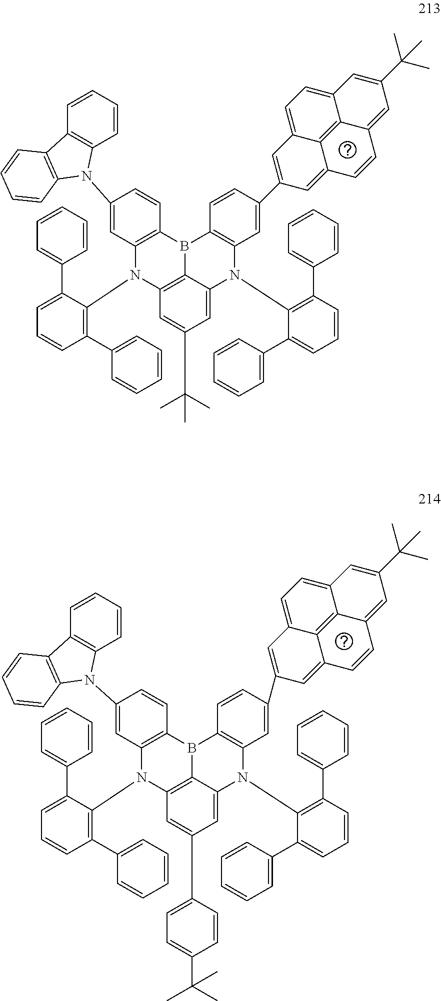 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-c3cc4ccc5cc(C(C)(C)C)cc6ccc(c3)c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4cc5ccc6cc(C(C)(C)C)cc7ccc(c4)c5c67)cc2N3c2c(-c3ccccc3)cccc2-c2ccccc2)cc1] 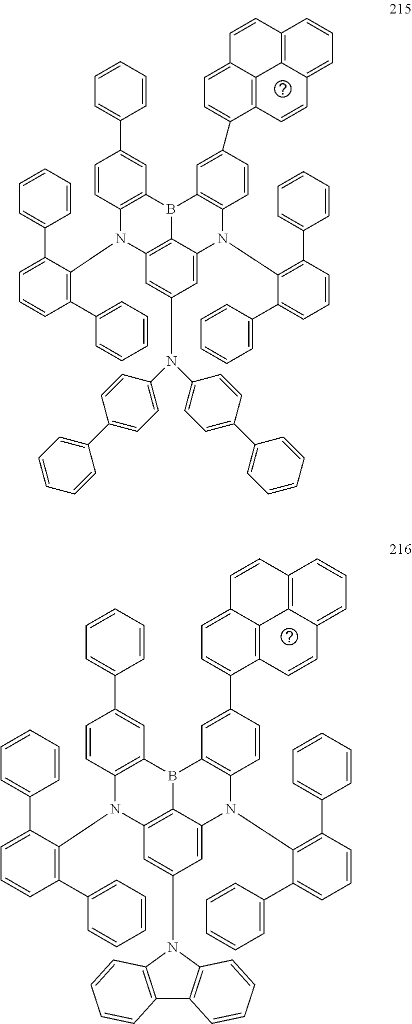 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7ccc8cccc9ccc6c7c89)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5ccc6ccc7cccc8ccc5c6c78)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 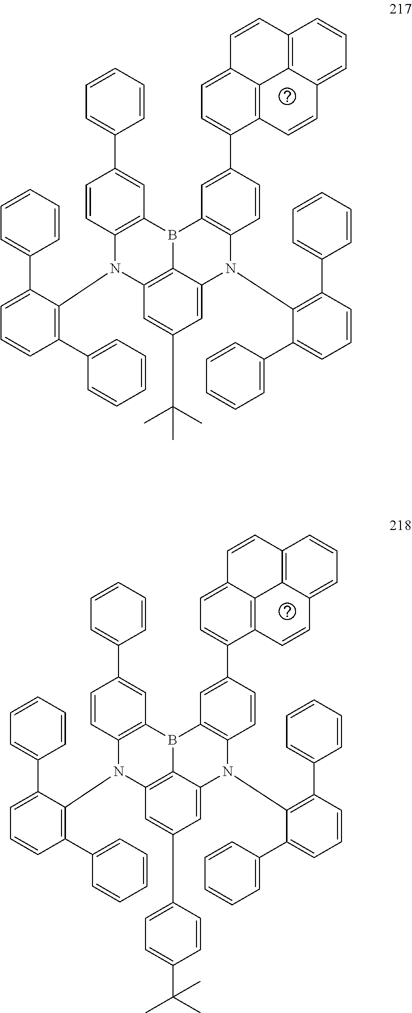 [SMILES: CC(C)(C)c1cc2c3c(c1)N(c1c(-c4ccccc4)cccc1-c1ccccc1)c1ccc(-c4ccc5ccc6cccc7ccc4c5c67)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6ccc7cccc8ccc5c6c78)cc2B4c2cc(-c4ccccc4)ccc2N3c2c(-c3ccccc3)cccc2-c2ccccc2)cc1] 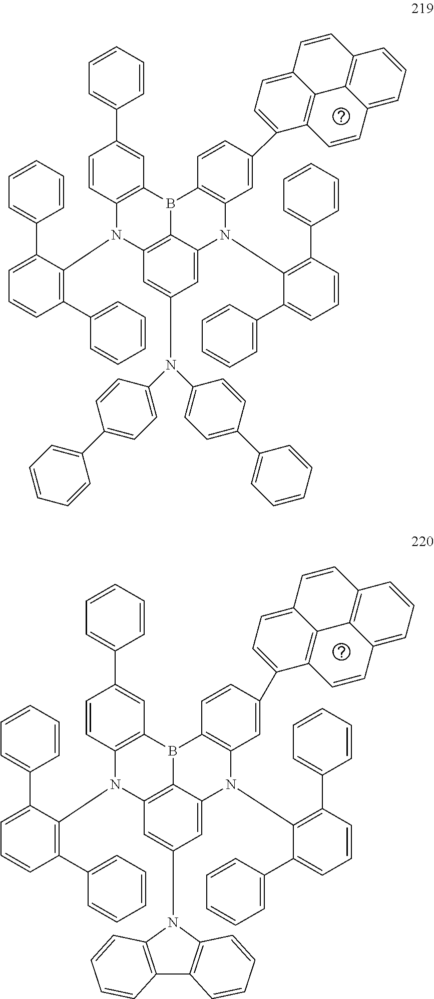 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7ccc8cccc9ccc6c7c89)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5ccc6ccc7cccc8ccc5c6c78)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 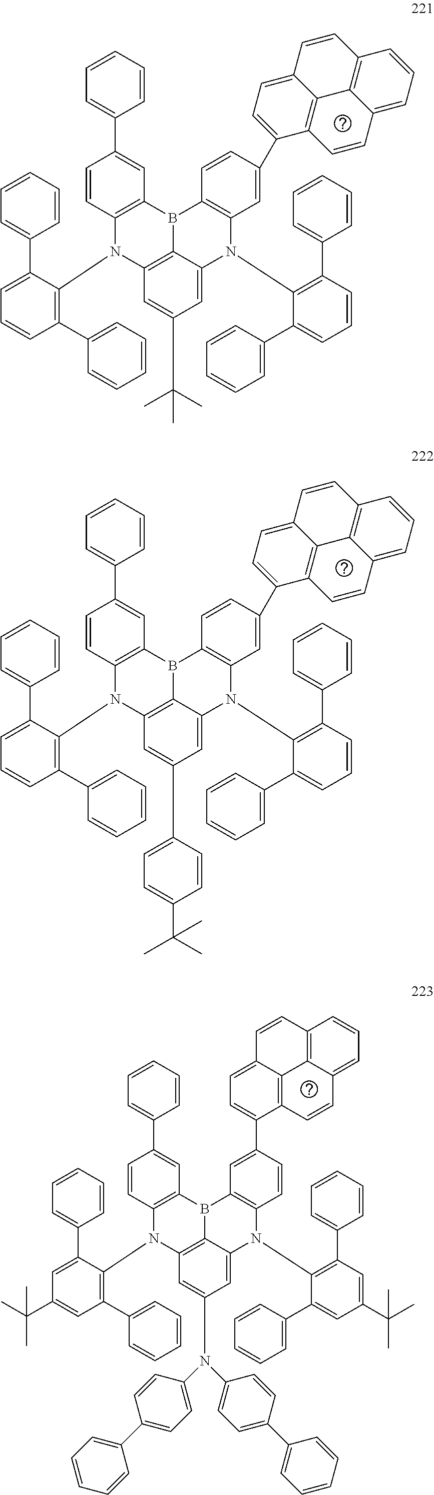 [SMILES: CC(C)(C)c1cc2c3c(c1)N(c1c(-c4ccccc4)cccc1-c1ccccc1)c1cc(-c4ccc5ccc6cccc7ccc4c5c67)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6ccc7cccc8ccc5c6c78)ccc2B4c2cc(-c4ccccc4)ccc2N3c2c(-c3ccccc3)cccc2-c2ccccc2)cc1 ; CC(C)(C)c1cc(-c2ccccc2)c(N2c3ccc(-c4ccccc4)cc3B3c4cc(-c5ccc6ccc7cccc8ccc5c6c78)ccc4N(c4c(-c5ccccc5)cc(C(C)(C)C)cc4-c4ccccc4)c4cc(N(c5ccc(-c6ccccc6)cc5)c5ccc(-c6ccccc6)cc5)cc2c43)c(-c2ccccc2)c1] 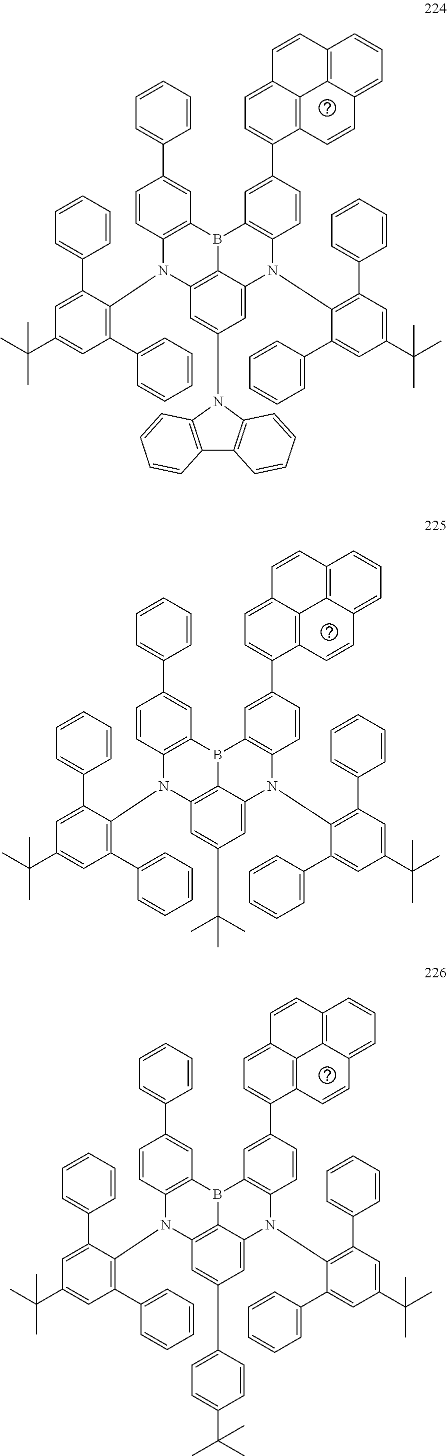 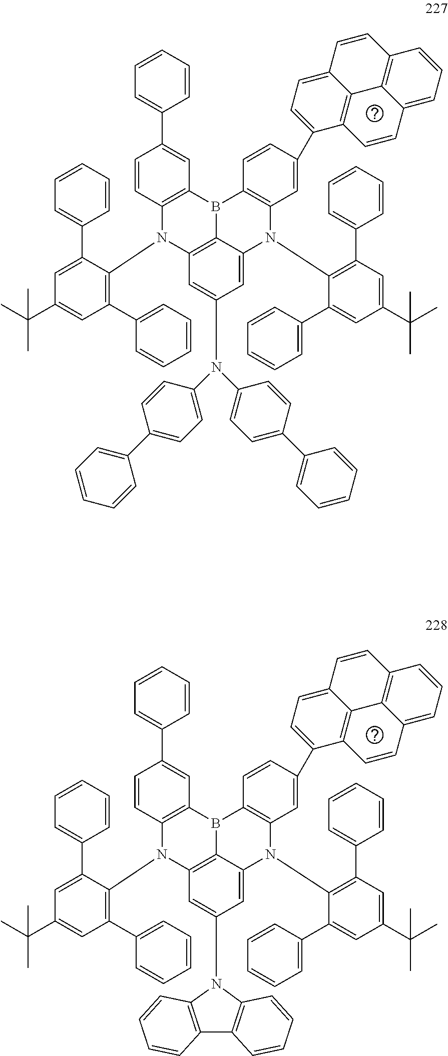 [SMILES: CC(C)(C)c1cc(-c2ccccc2)c(N2c3ccc(-c4ccccc4)cc3B3c4ccc(-c5ccc6ccc7cccc8ccc5c6c78)cc4N(c4c(-c5ccccc5)cc(C(C)(C)C)cc4-c4ccccc4)c4cc(N(c5ccc(-c6ccccc6)cc5)c5ccc(-c6ccccc6)cc5)cc2c43)c(-c2ccccc2)c1 ; CC(C)(C)c1cc(-c2ccccc2)c(N2c3ccc(-c4ccccc4)cc3B3c4ccc(-c5ccc6ccc7cccc8ccc5c6c78)cc4N(c4c(-c5ccccc5)cc(C(C)(C)C)cc4-c4ccccc4)c4cc(-n5c6ccccc6c6ccccc65)cc2c43)c(-c2ccccc2)c1] 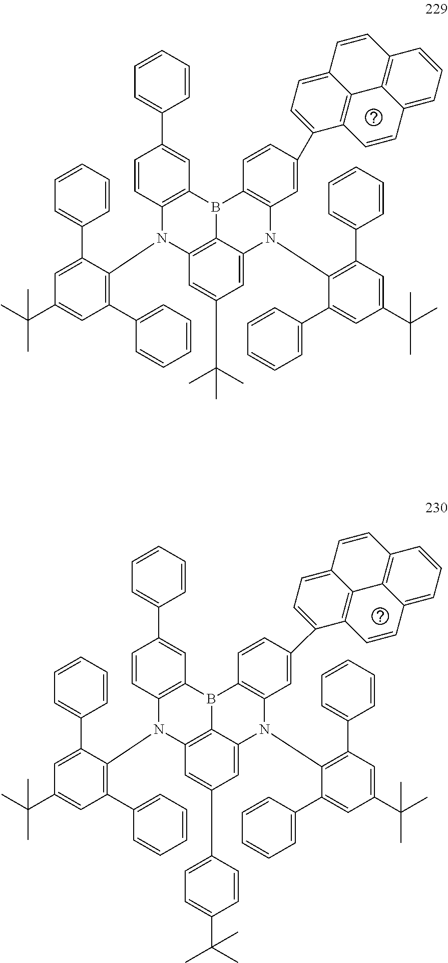 [SMILES: CC(C)(C)c1cc(-c2ccccc2)c(N2c3ccc(-c4ccccc4)cc3B3c4ccc(-c5ccc6ccc7cccc8ccc5c6c78)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(-c2cc3c4c(c2)N(c2c(-c5ccccc5)cc(C(C)(C)C)cc2-c2ccccc2)c2cc(-c5ccc6ccc7cccc8ccc5c6c78)ccc2B4c2cc(-c4ccccc4)ccc2N3c2c(-c3ccccc3)cc(C(C)(C)C)cc2-c2ccccc2)cc1] 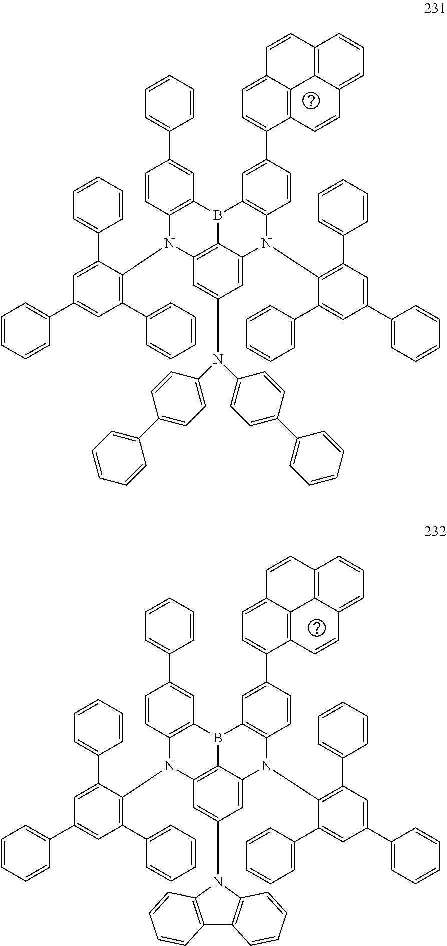 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccc7ccc8cccc9ccc6c7c89)cc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4cc(-c5ccc6ccc7cccc8ccc5c6c78)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1] 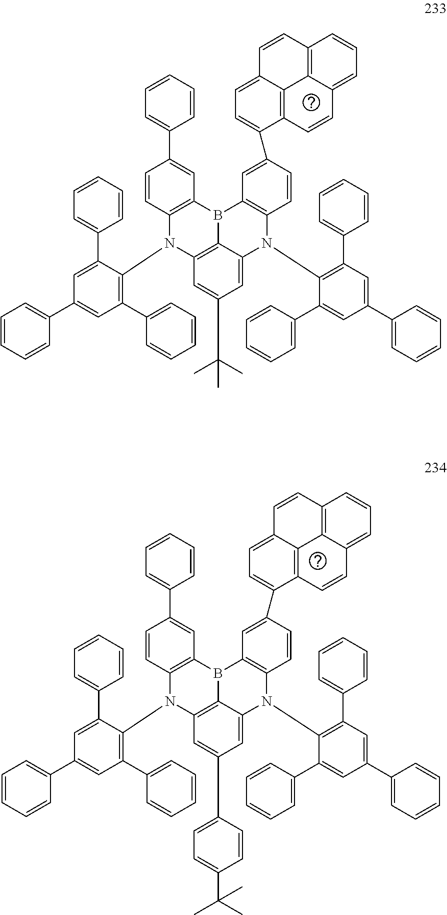 [SMILES: CC(C)(C)c1cc2c3c(c1)N(c1c(-c4ccccc4)cc(-c4ccccc4)cc1-c1ccccc1)c1ccc(-c4ccc5ccc6cccc7ccc4c5c67)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5ccc6ccc7cccc8ccc5c6c78)cc2B4c2cc(-c4ccccc4)ccc2N3c2c(-c3ccccc3)cc(-c3ccccc3)cc2-c2ccccc2)cc1] 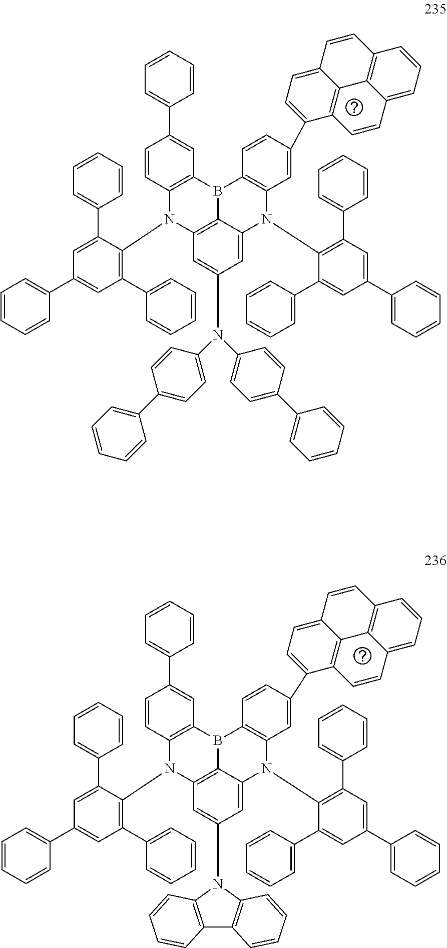 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-c6ccc7ccc8cccc9ccc6c7c89)ccc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4ccc(-c5ccc6ccc7cccc8ccc5c6c78)cc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1] 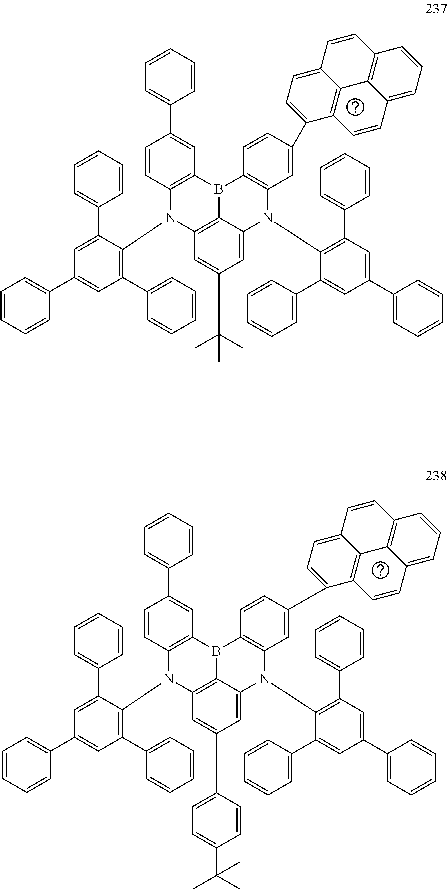 [SMILES: CC(C)(C)c1cc2c3c(c1)N(c1c(-c4ccccc4)cc(-c4ccccc4)cc1-c1ccccc1)c1cc(-c4ccc5ccc6cccc7ccc4c5c67)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5ccc6ccc7cccc8ccc5c6c78)ccc2B4c2cc(-c4ccccc4)ccc2N3c2c(-c3ccccc3)cc(-c3ccccc3)cc2-c2ccccc2)cc1] 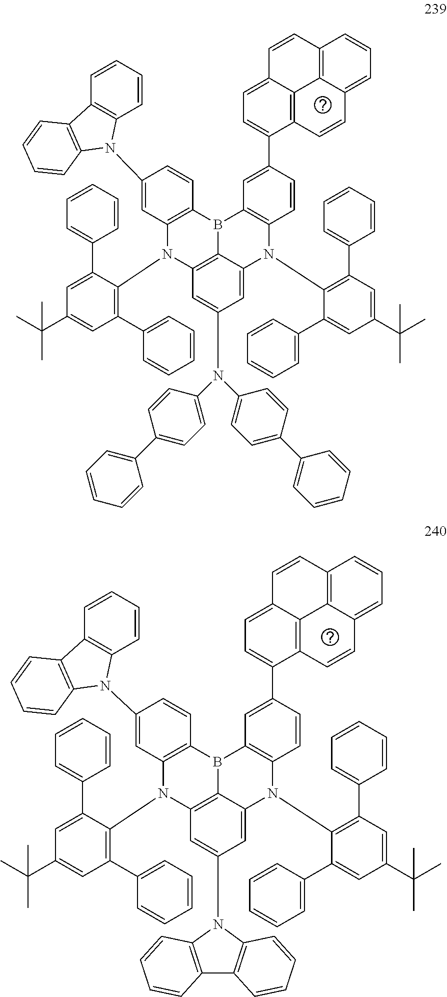 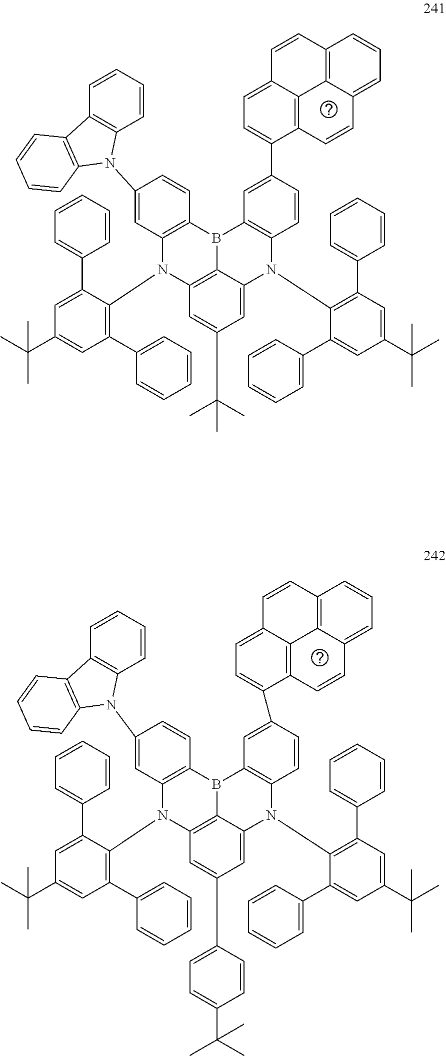 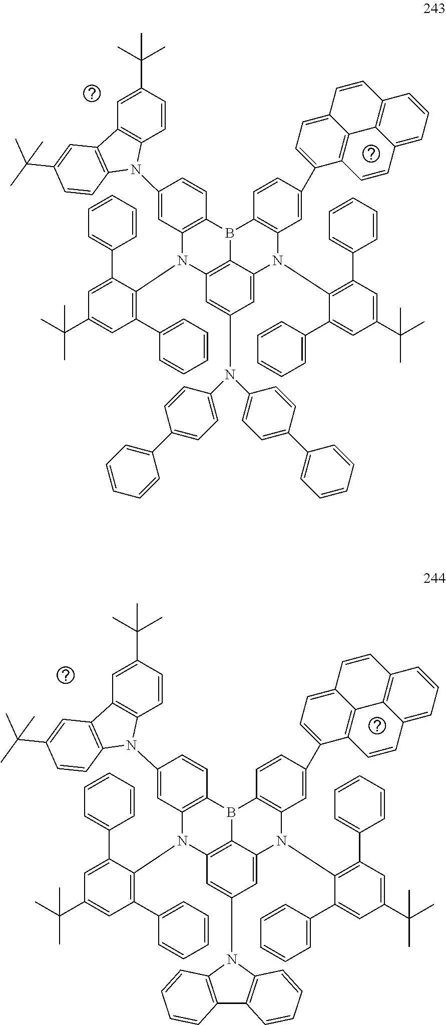 [SMILES: CC(C)(C)c1cc(-c2ccccc2)c(N2c3cc(-c4ccc5ccc6cccc7ccc4c5c67)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(N(c5ccc(-c6ccccc6)cc5)c5ccc(-c6ccccc6)cc5)cc2c43)c(-c2ccccc2)c1 ; CC(C)(C)c1cc(-c2ccccc2)c(N2c3cc(-c4ccc5ccc6cccc7ccc4c5c67)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(-n5c6ccccc6c6ccccc65)cc2c43)c(-c2ccccc2)c1] 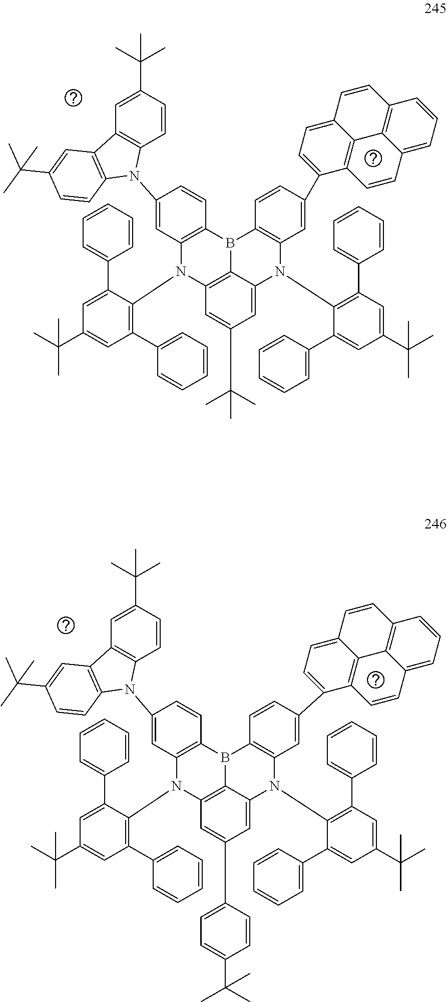 [SMILES: CC(C)(C)c1cc(-c2ccccc2)c(N2c3cc(-c4ccc5ccc6cccc7ccc4c5c67)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(-c2cc3c4c(c2)N(c2c(-c5ccccc5)cc(C(C)(C)C)cc2-c2ccccc2)c2cc(-n5c6ccc(C(C)(C)C)cc6c6cc(C(C)(C)C)ccc65)ccc2B4c2ccc(-c4ccc5ccc6cccc7ccc4c5c67)cc2N3c2c(-c3ccccc3)cc(C(C)(C)C)cc2-c2ccccc2)cc1] 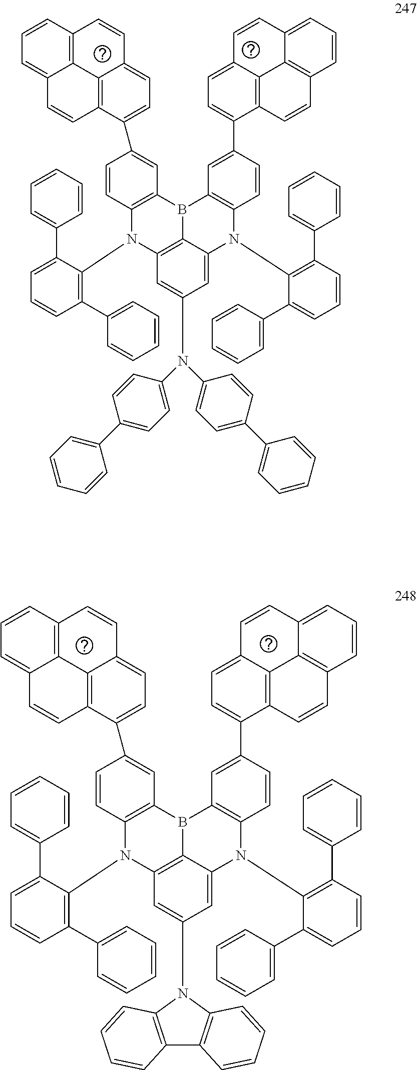 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7ccc8cccc9ccc6c7c89)cc3B5c3cc(-c5ccc6ccc7cccc8ccc5c6c78)ccc3N4c3c(-c4ccccc4)cccc3-c3ccccc3)cc2)cc1 ; c1ccc(-c2cccc(-c3ccccc3)c2N2c3ccc(-c4ccc5ccc6cccc7ccc4c5c67)cc3B3c4cc(-c5ccc6ccc7cccc8ccc5c6c78)ccc4N(c4c(-c5ccccc5)cccc4-c4ccccc4)c4cc(-n5c6ccccc6c6ccccc65)cc2c43)cc1] 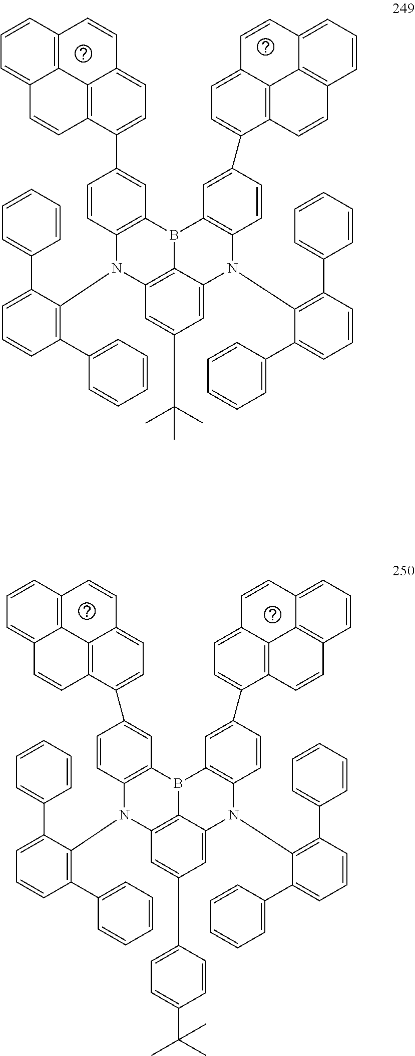 [SMILES: CC(C)(C)c1cc2c3c(c1)N(c1c(-c4ccccc4)cccc1-c1ccccc1)c1ccc(-c4ccc5ccc6cccc7ccc4c5c67)cc1B3c1cc(-c3ccc4ccc5cccc6ccc3c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6ccc7cccc8ccc5c6c78)cc2B4c2cc(-c4ccc5ccc6cccc7ccc4c5c67)ccc2N3c2c(-c3ccccc3)cccc2-c2ccccc2)cc1] 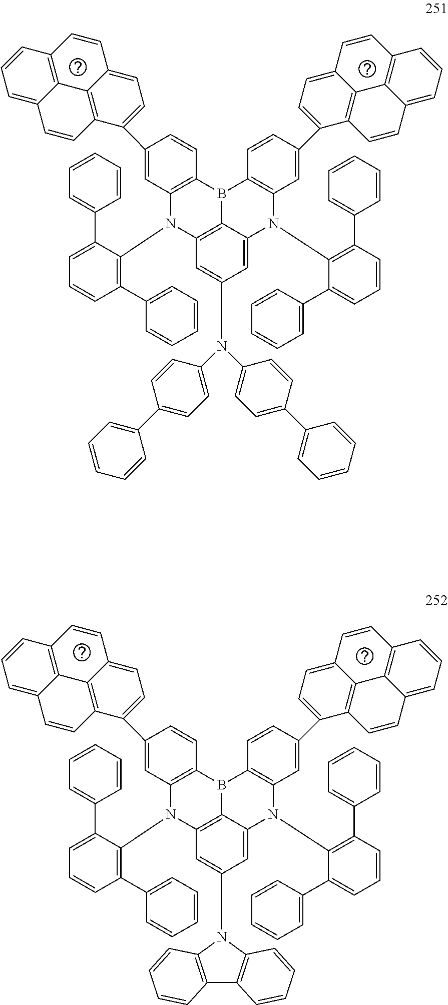 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7ccc8cccc9ccc6c7c89)ccc3B5c3ccc(-c5ccc6ccc7cccc8ccc5c6c78)cc3N4c3c(-c4ccccc4)cccc3-c3ccccc3)cc2)cc1 ; c1ccc(-c2cccc(-c3ccccc3)c2N2c3cc(-c4ccc5ccc6cccc7ccc4c5c67)ccc3B3c4ccc(-c5ccc6ccc7cccc8ccc5c6c78)cc4N(c4c(-c5ccccc5)cccc4-c4ccccc4)c4cc(-n5c6ccccc6c6ccccc65)cc2c43)cc1] 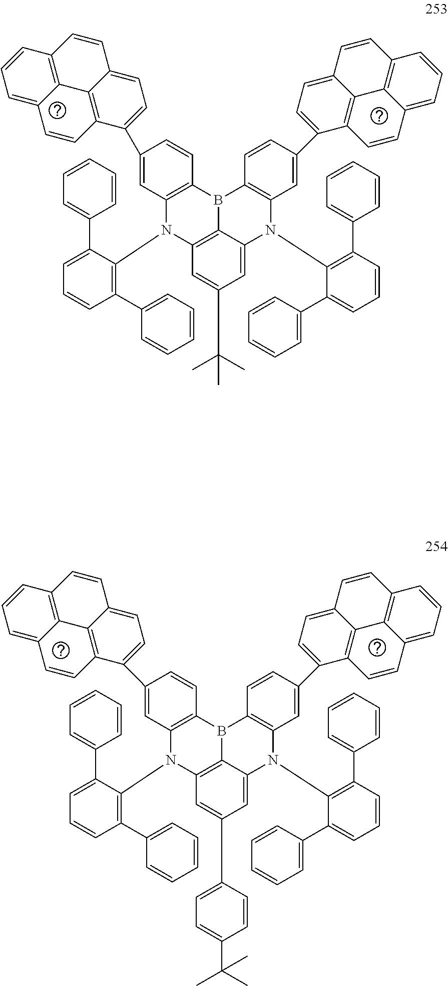 [SMILES: CC(C)(C)c1cc2c3c(c1)N(c1c(-c4ccccc4)cccc1-c1ccccc1)c1cc(-c4ccc5ccc6cccc7ccc4c5c67)ccc1B3c1ccc(-c3ccc4ccc5cccc6ccc3c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6ccc7cccc8ccc5c6c78)ccc2B4c2ccc(-c4ccc5ccc6cccc7ccc4c5c67)cc2N3c2c(-c3ccccc3)cccc2-c2ccccc2)cc1] 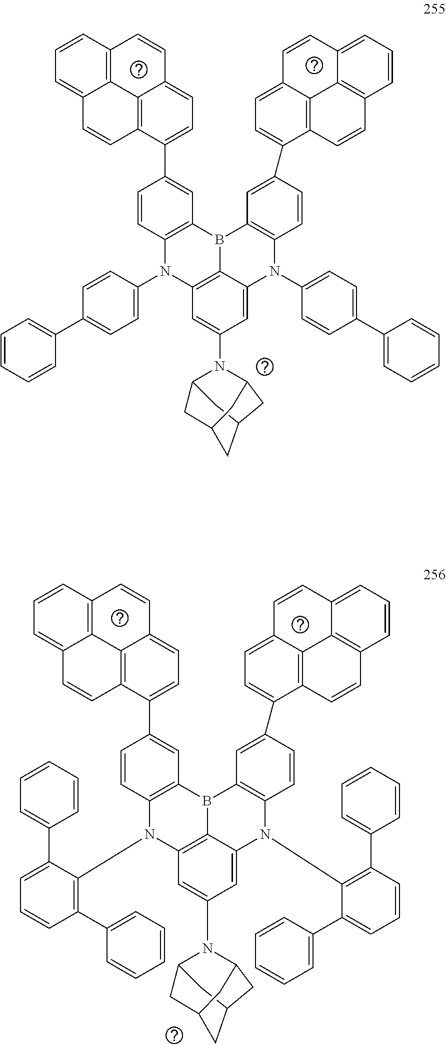 [SMILES: c1ccc(-c2ccc(N3c4ccc(-c5ccc6ccc7cccc8ccc5c6c78)cc4B4c5cc(-c6ccc7ccc8cccc9ccc6c7c89)ccc5N(c5ccc(-c6ccccc6)cc5)c5cc(N6C7CC8CC(C7)CC6C8)cc3c54)cc2)cc1 ; c1ccc(-c2cccc(-c3ccccc3)c2N2c3ccc(-c4ccc5ccc6cccc7ccc4c5c67)cc3B3c4cc(-c5ccc6ccc7cccc8ccc5c6c78)ccc4N(c4c(-c5ccccc5)cccc4-c4ccccc4)c4cc(N5C6CC7CC(C6)CC5C7)cc2c43)cc1] 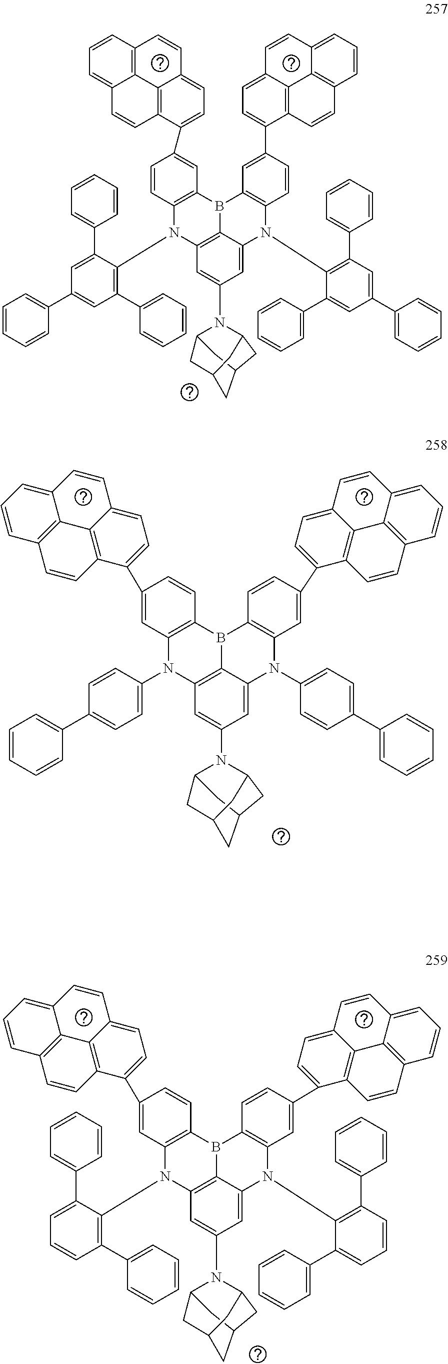 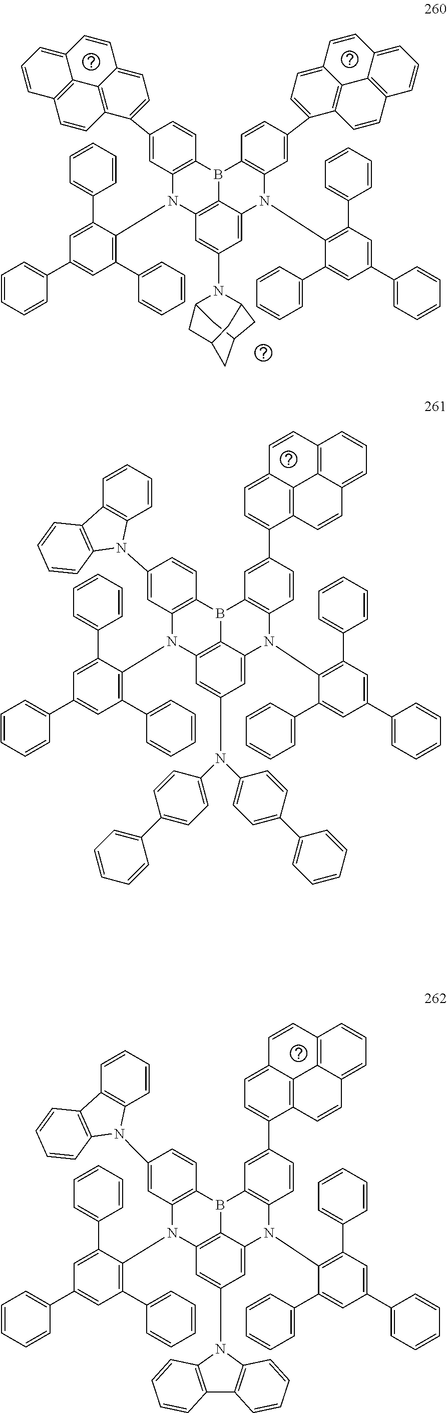 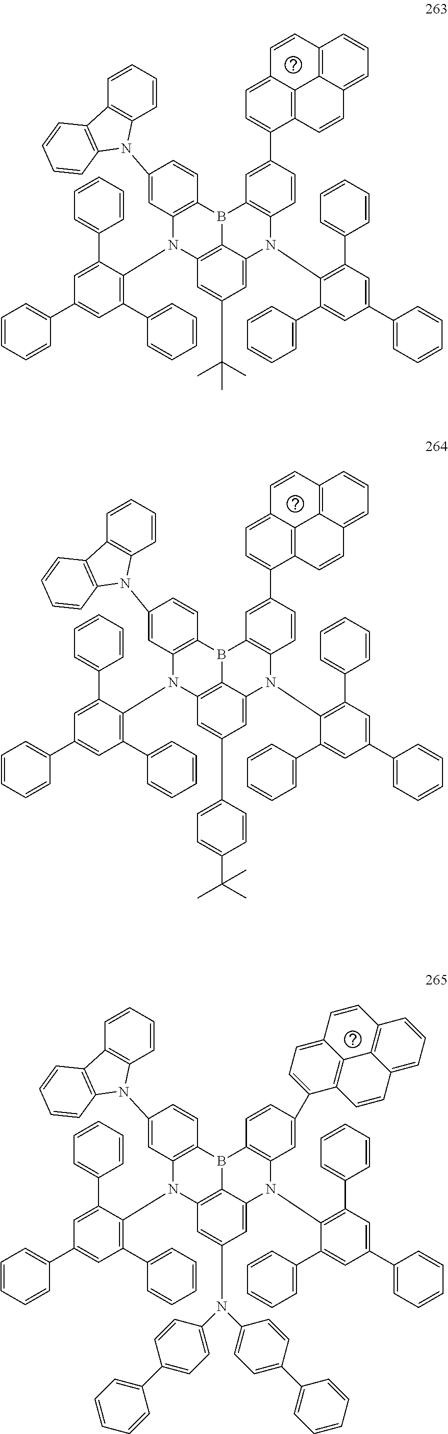 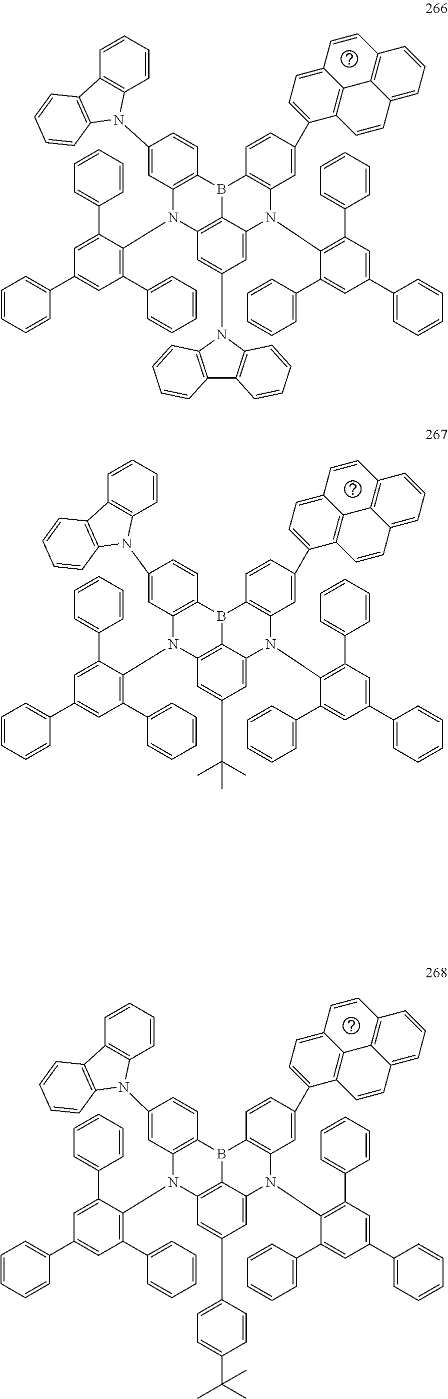 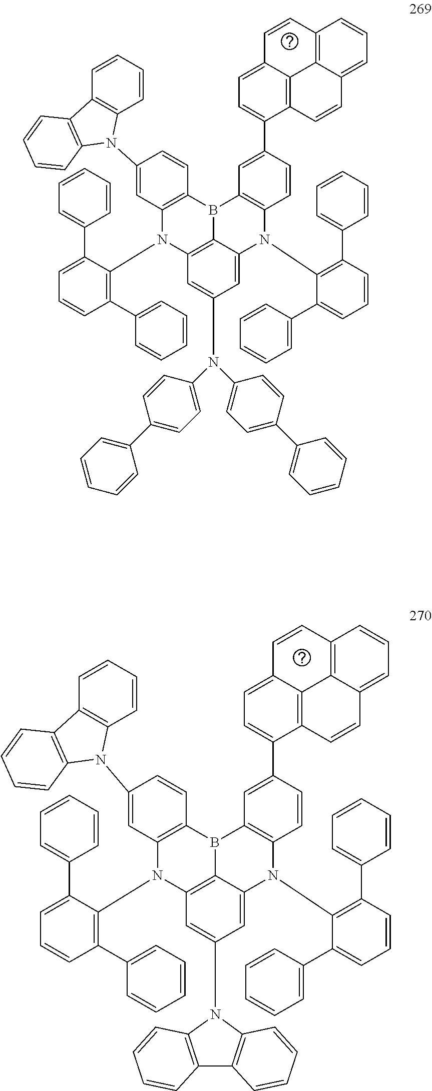 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3cc(-c5ccc6ccc7cccc8ccc5c6c78)ccc3N4c3c(-c4ccccc4)cccc3-c3ccccc3)cc2)cc1 ; c1ccc(-c2cccc(-c3ccccc3)c2N2c3ccc(-c4ccc5ccc6cccc7ccc4c5c67)cc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1] 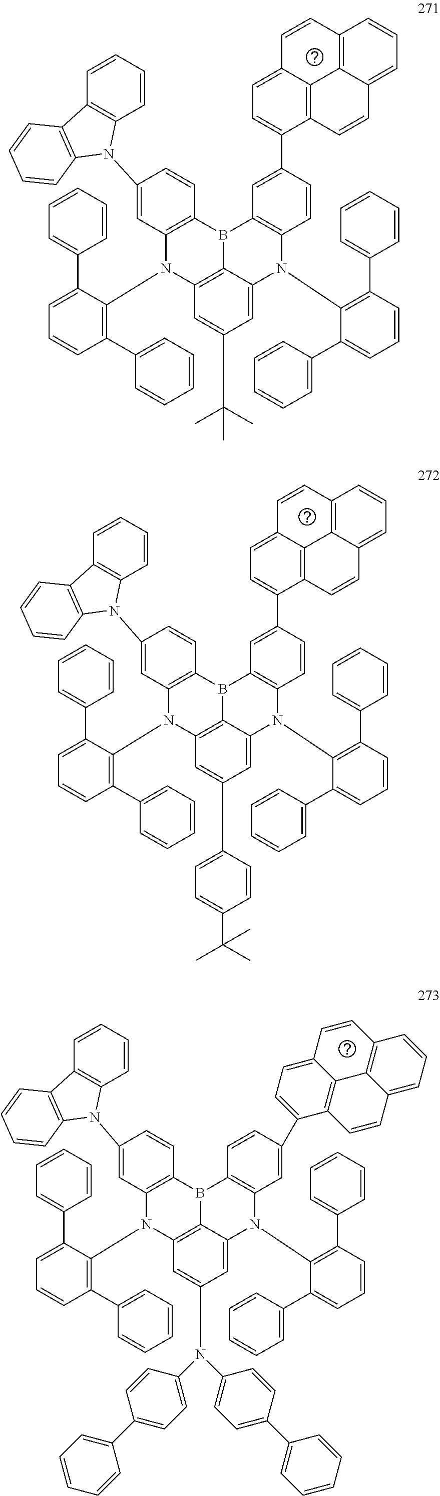 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccc4ccc5cccc6ccc3c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4ccc5ccc6cccc7ccc4c5c67)ccc2N3c2c(-c3ccccc3)cccc2-c2ccccc2)cc1 ; c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3ccc(-c5ccc6ccc7cccc8ccc5c6c78)cc3N4c3c(-c4ccccc4)cccc3-c3ccccc3)cc2)cc1] 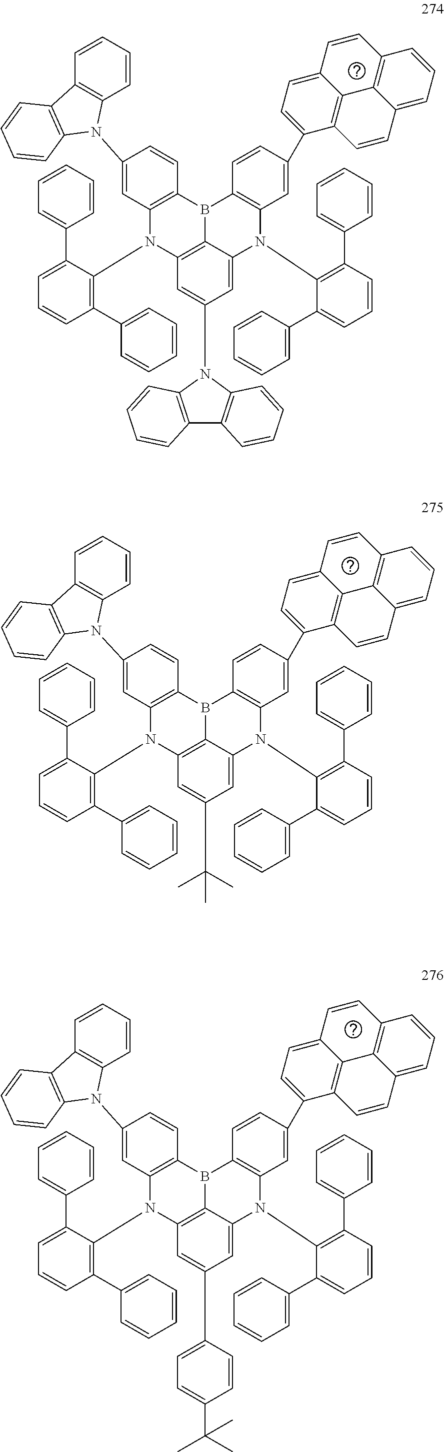 [SMILES: c1ccc(-c2cccc(-c3ccccc3)c2N2c3cc(-c4ccc5ccc6cccc7ccc4c5c67)ccc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1 ; CC(C)(C)c1cc2c3c(c1)N(c1c(-c4ccccc4)cccc1-c1ccccc1)c1cc(-n4c5ccccc5c5ccccc54)ccc1B3c1ccc(-c3ccc4ccc5cccc6ccc3c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4ccc5ccc6cccc7ccc4c5c67)cc2N3c2c(-c3ccccc3)cccc2-c2ccccc2)cc1] 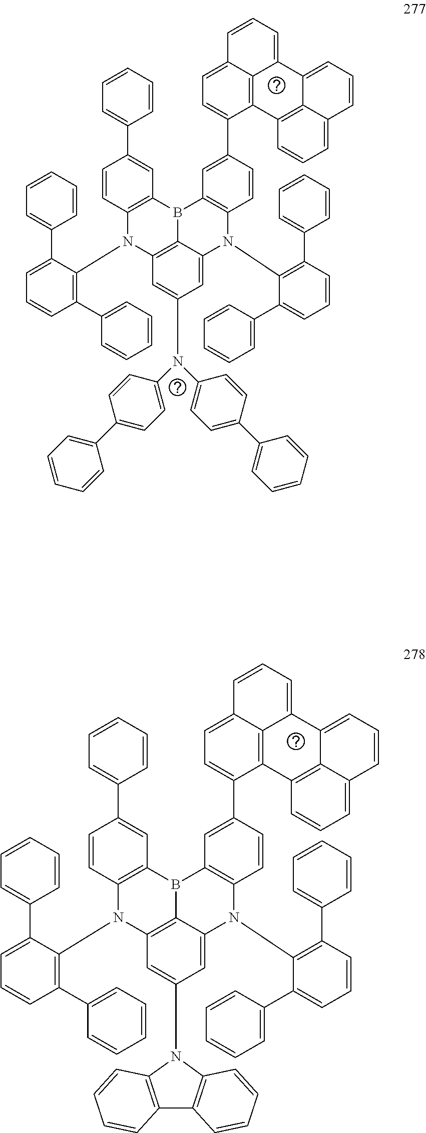 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7cccc8c9cccc%10cccc(c6c78)c%109)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5ccc6cccc7c8cccc9cccc(c5c67)c98)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 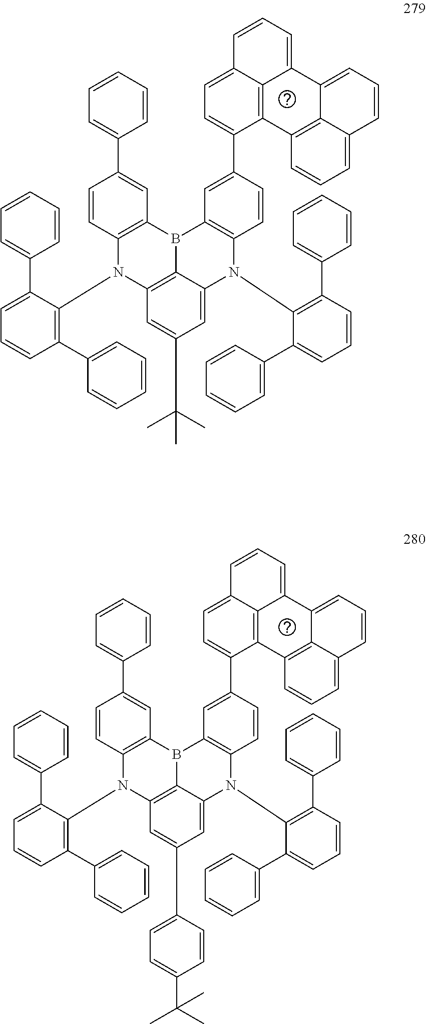 [SMILES: CC(C)(C)c1cc2c3c(c1)N(c1c(-c4ccccc4)cccc1-c1ccccc1)c1ccc(-c4ccc5cccc6c7cccc8cccc(c4c56)c87)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6cccc7c8cccc9cccc(c5c67)c98)cc2B4c2cc(-c4ccccc4)ccc2N3c2c(-c3ccccc3)cccc2-c2ccccc2)cc1] 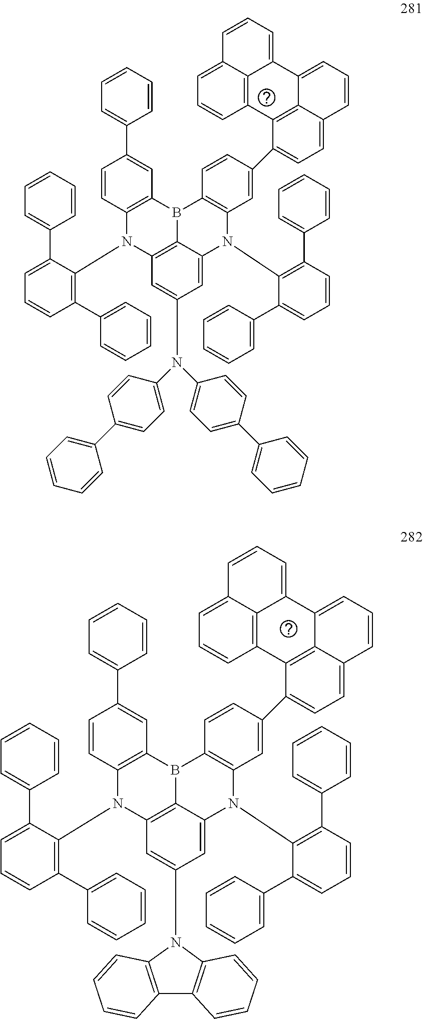 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7cccc8c9cccc%10cccc(c6c78)c%109)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5ccc6cccc7c8cccc9cccc(c5c67)c98)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 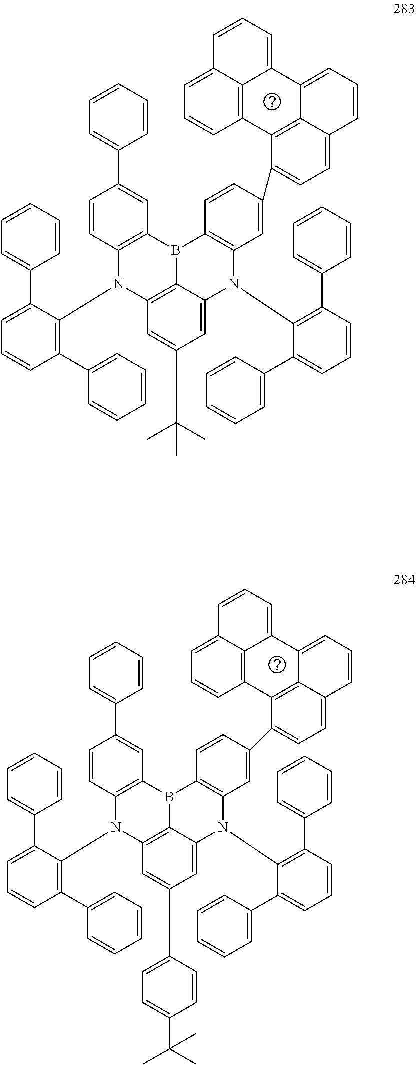 [SMILES: CC(C)(C)c1cc2c3c(c1)N(c1c(-c4ccccc4)cccc1-c1ccccc1)c1cc(-c4ccc5cccc6c7cccc8cccc(c4c56)c87)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6cccc7c8cccc9cccc(c5c67)c98)ccc2B4c2cc(-c4ccccc4)ccc2N3c2c(-c3ccccc3)cccc2-c2ccccc2)cc1] 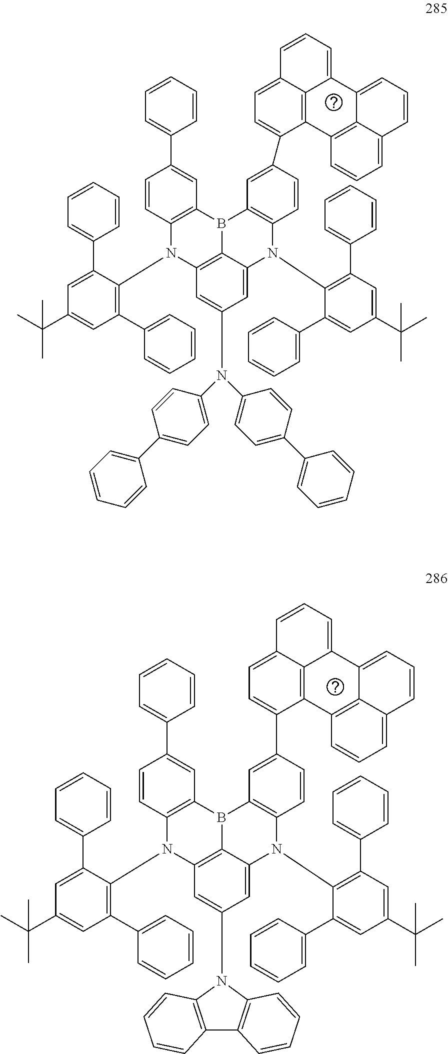 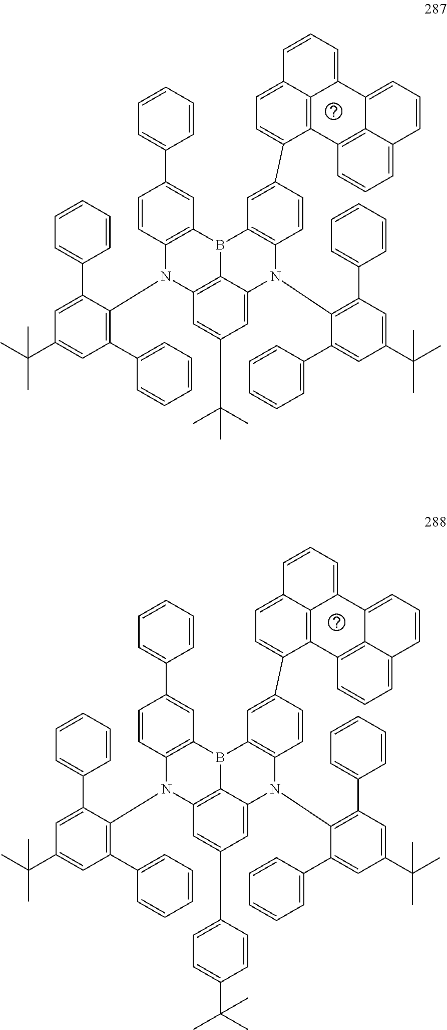 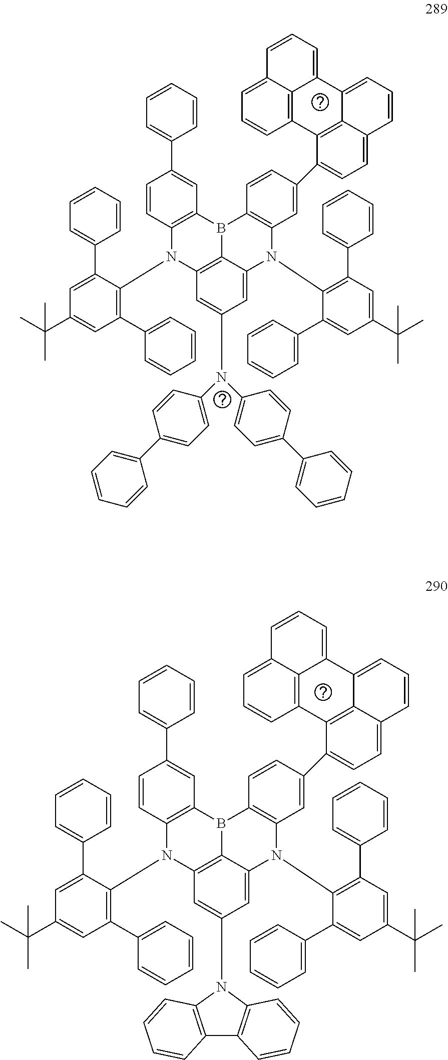 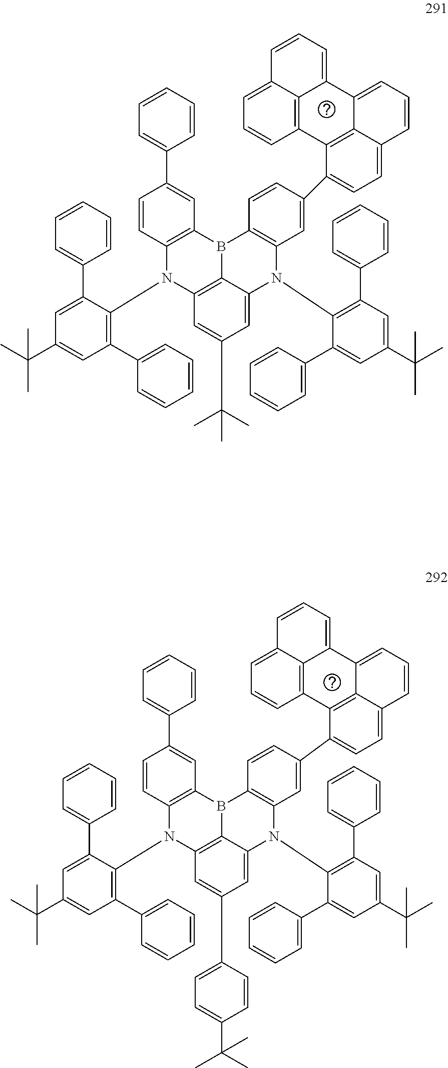 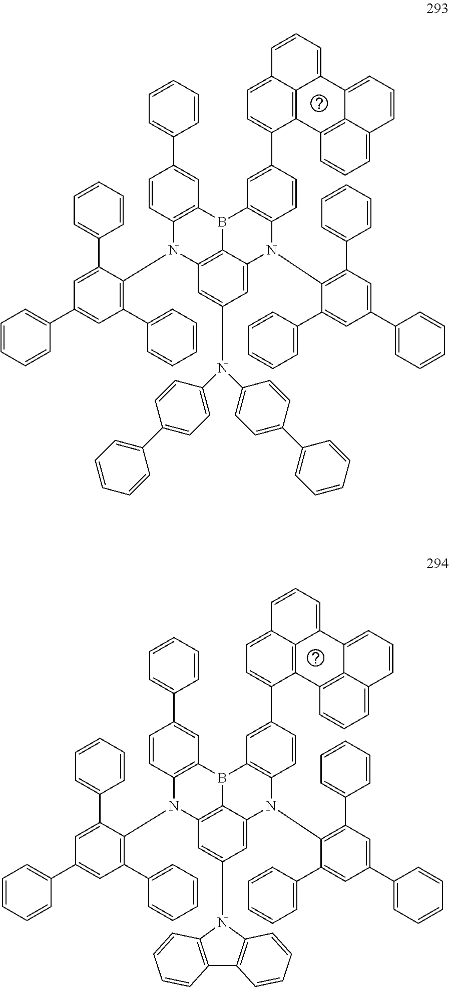 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccc7cccc8c9cccc%10cccc(c6c78)c%109)cc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4cc(-c5ccc6cccc7c8cccc9cccc(c5c67)c98)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1] 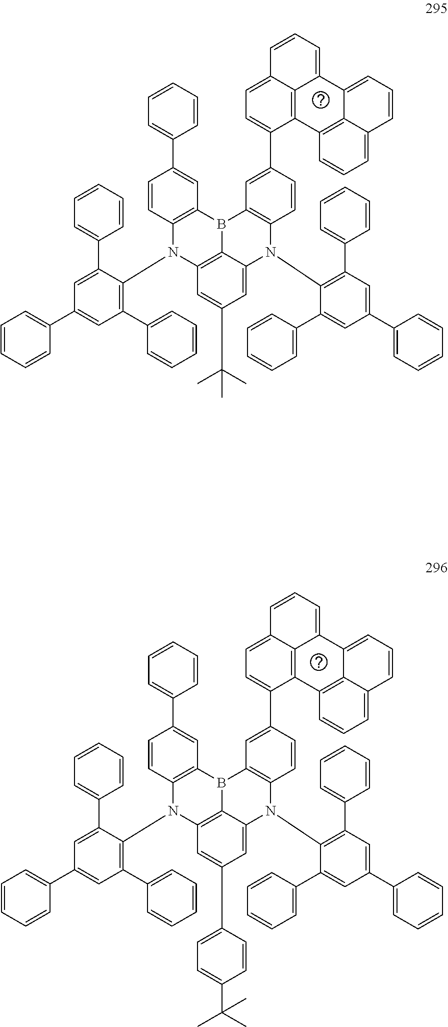 [SMILES: CC(C)(C)c1cc2c3c(c1)N(c1c(-c4ccccc4)cc(-c4ccccc4)cc1-c1ccccc1)c1ccc(-c4ccc5cccc6c7cccc8cccc(c4c56)c87)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5ccc6cccc7c8cccc9cccc(c5c67)c98)cc2B4c2cc(-c4ccccc4)ccc2N3c2c(-c3ccccc3)cc(-c3ccccc3)cc2-c2ccccc2)cc1] 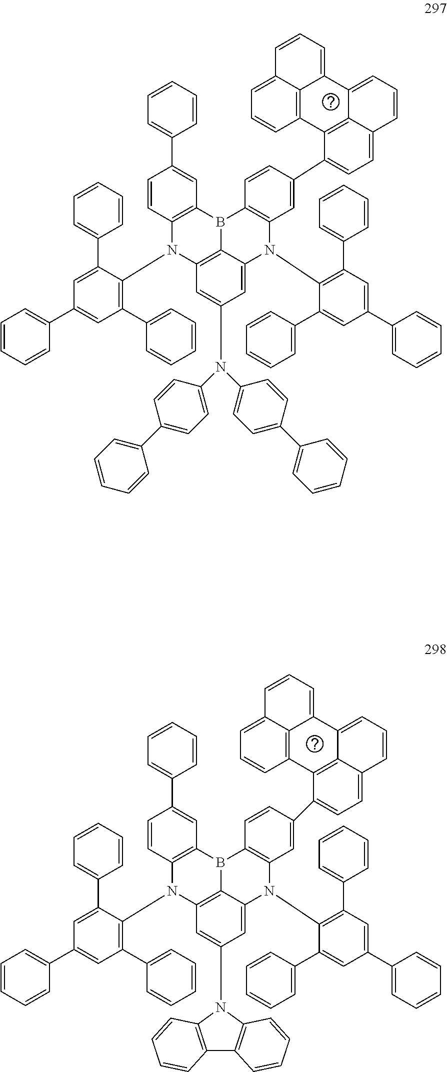 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-c6ccc7cccc8c9cccc%10cccc(c6c78)c%109)ccc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4ccc(-c5ccc6cccc7c8cccc9cccc(c5c67)c98)cc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1] 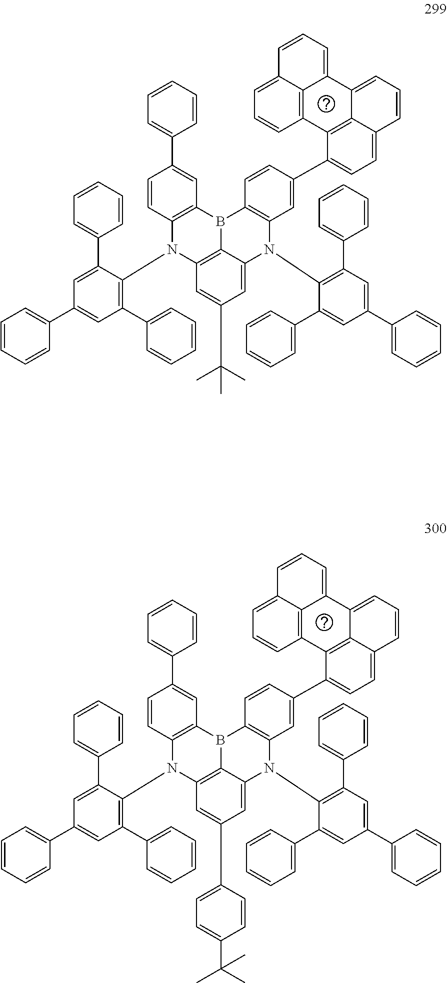 [SMILES: CC(C)(C)c1cc2c3c(c1)N(c1c(-c4ccccc4)cc(-c4ccccc4)cc1-c1ccccc1)c1cc(-c4ccc5cccc6c7cccc8cccc(c4c56)c87)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5ccc6cccc7c8cccc9cccc(c5c67)c98)ccc2B4c2cc(-c4ccccc4)ccc2N3c2c(-c3ccccc3)cc(-c3ccccc3)cc2-c2ccccc2)cc1] 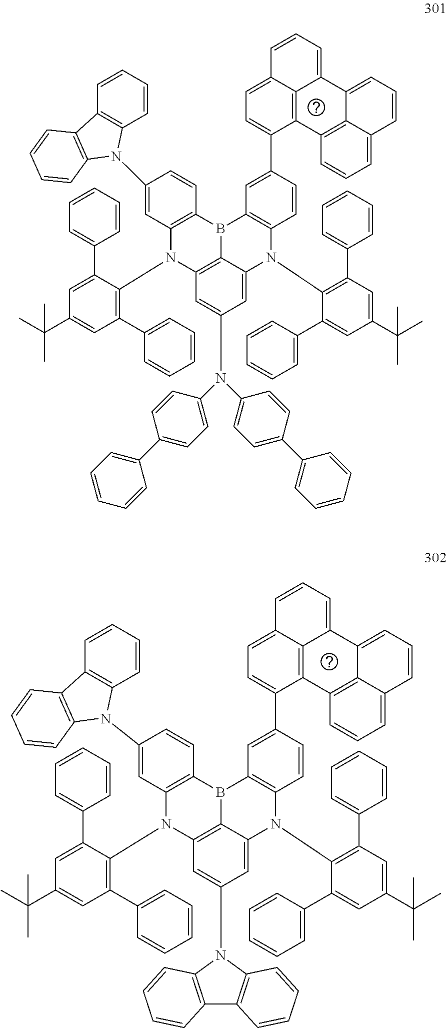 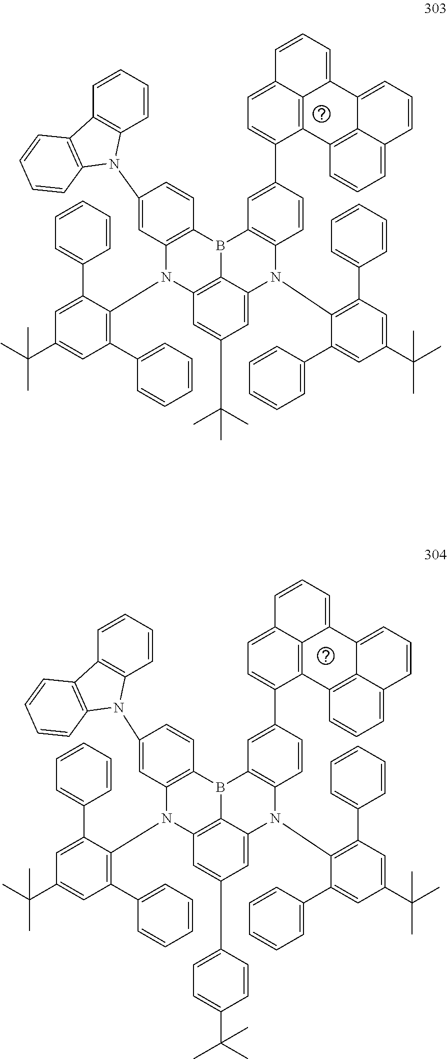 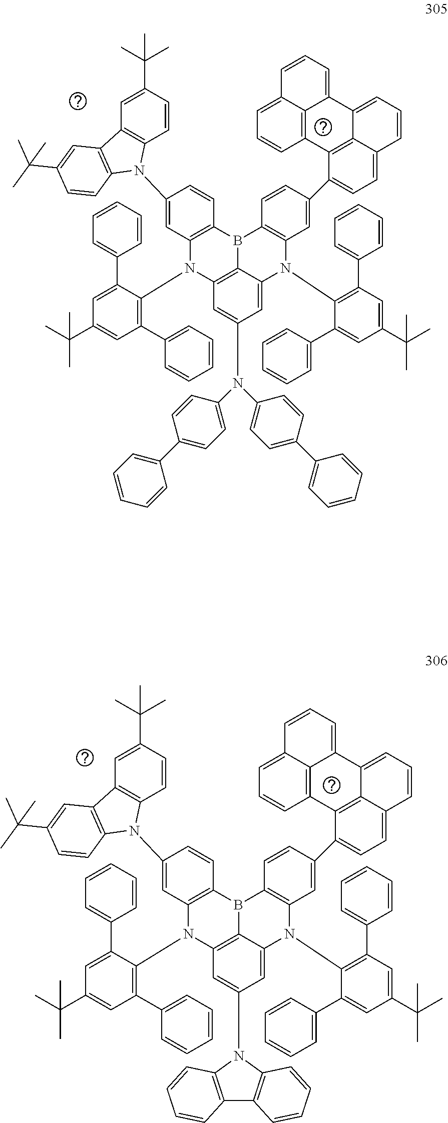 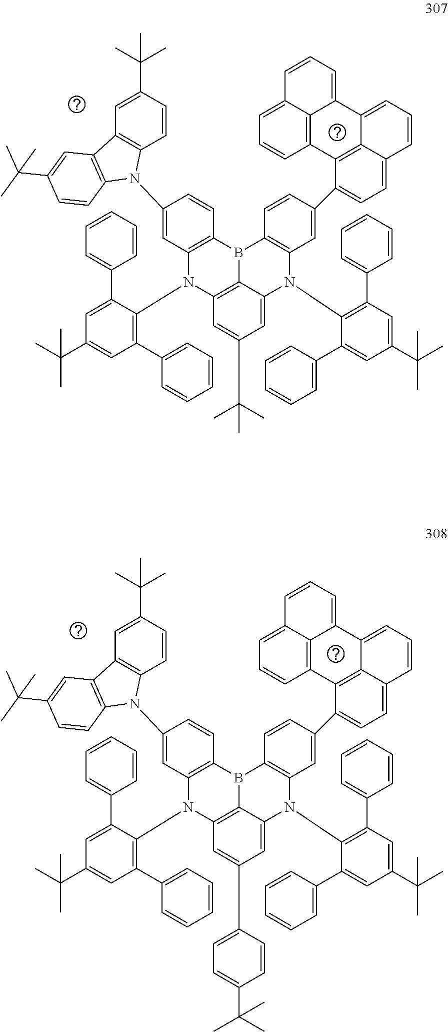 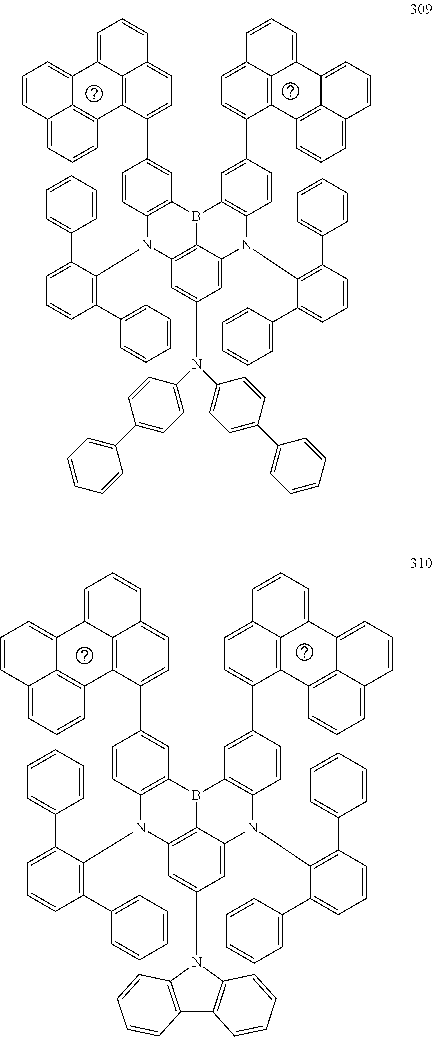 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7cccc8c9cccc%10cccc(c6c78)c%109)cc3B5c3cc(-c5ccc6cccc7c8cccc9cccc(c5c67)c98)ccc3N4c3c(-c4ccccc4)cccc3-c3ccccc3)cc2)cc1 ; c1ccc(-c2cccc(-c3ccccc3)c2N2c3ccc(-c4ccc5cccc6c7cccc8cccc(c4c56)c87)cc3B3c4cc(-c5ccc6cccc7c8cccc9cccc(c5c67)c98)ccc4N(c4c(-c5ccccc5)cccc4-c4ccccc4)c4cc(-n5c6ccccc6c6ccccc65)cc2c43)cc1] 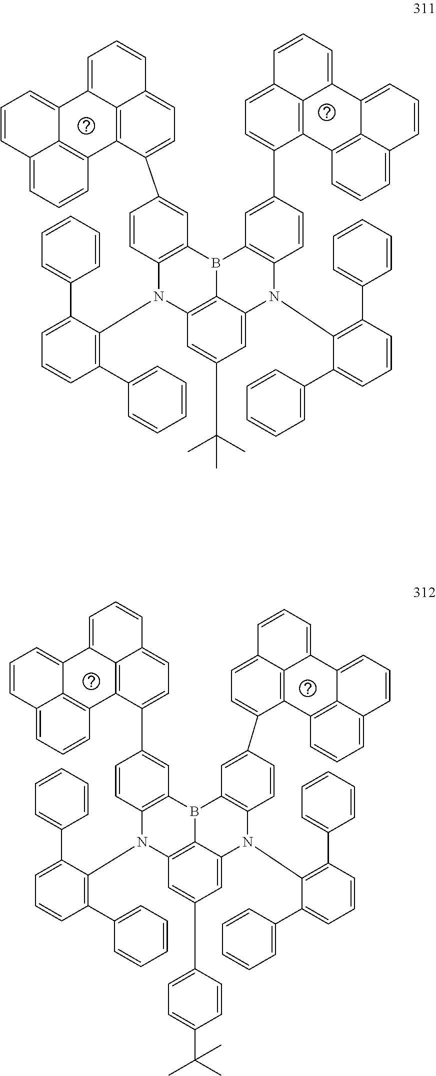 [SMILES: CC(C)(C)c1cc2c3c(c1)N(c1c(-c4ccccc4)cccc1-c1ccccc1)c1ccc(-c4ccc5cccc6c7cccc8cccc(c4c56)c87)cc1B3c1cc(-c3ccc4cccc5c6cccc7cccc(c3c45)c76)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6cccc7c8cccc9cccc(c5c67)c98)cc2B4c2cc(-c4ccc5cccc6c7cccc8cccc(c4c56)c87)ccc2N3c2c(-c3ccccc3)cccc2-c2ccccc2)cc1] 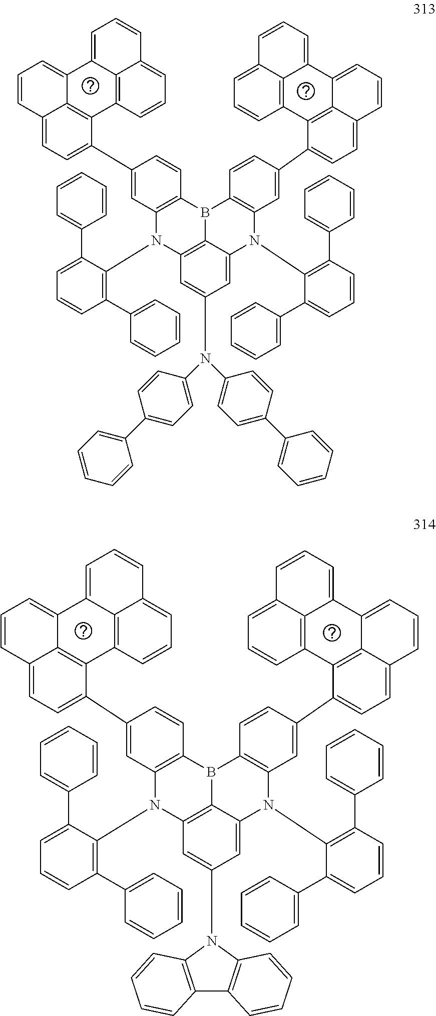 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7cccc8c9cccc%10cccc(c6c78)c%109)ccc3B5c3ccc(-c5ccc6cccc7c8cccc9cccc(c5c67)c98)cc3N4c3c(-c4ccccc4)cccc3-c3ccccc3)cc2)cc1 ; c1ccc(-c2cccc(-c3ccccc3)c2N2c3cc(-c4ccc5cccc6c7cccc8cccc(c4c56)c87)ccc3B3c4ccc(-c5ccc6cccc7c8cccc9cccc(c5c67)c98)cc4N(c4c(-c5ccccc5)cccc4-c4ccccc4)c4cc(-n5c6ccccc6c6ccccc65)cc2c43)cc1] 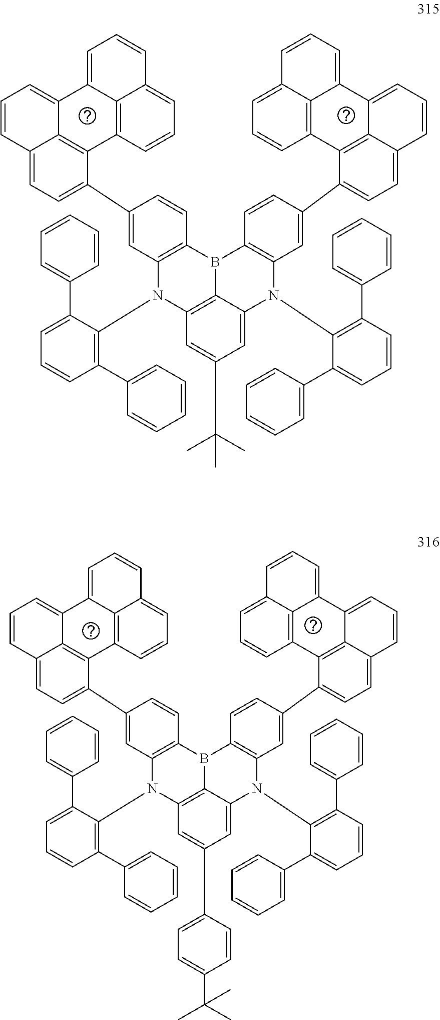 [SMILES: CC(C)(C)c1cc2c3c(c1)N(c1c(-c4ccccc4)cccc1-c1ccccc1)c1cc(-c4ccc5cccc6c7cccc8cccc(c4c56)c87)ccc1B3c1ccc(-c3ccc4cccc5c6cccc7cccc(c3c45)c76)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6cccc7c8cccc9cccc(c5c67)c98)ccc2B4c2ccc(-c4ccc5cccc6c7cccc8cccc(c4c56)c87)cc2N3c2c(-c3ccccc3)cccc2-c2ccccc2)cc1] 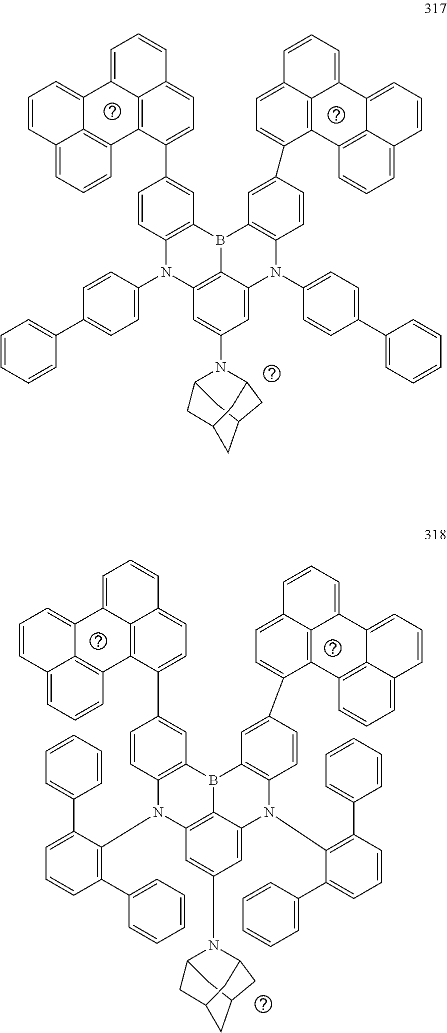 [SMILES: c1ccc(-c2ccc(N3c4ccc(-c5ccc6cccc7c8cccc9cccc(c5c67)c98)cc4B4c5cc(-c6ccc7cccc8c9cccc%10cccc(c6c78)c%109)ccc5N(c5ccc(-c6ccccc6)cc5)c5cc(N6C7CC8CC(C7)CC6C8)cc3c54)cc2)cc1 ; c1ccc(-c2cccc(-c3ccccc3)c2N2c3ccc(-c4ccc5cccc6c7cccc8cccc(c4c56)c87)cc3B3c4cc(-c5ccc6cccc7c8cccc9cccc(c5c67)c98)ccc4N(c4c(-c5ccccc5)cccc4-c4ccccc4)c4cc(N5C6CC7CC(C6)CC5C7)cc2c43)cc1] 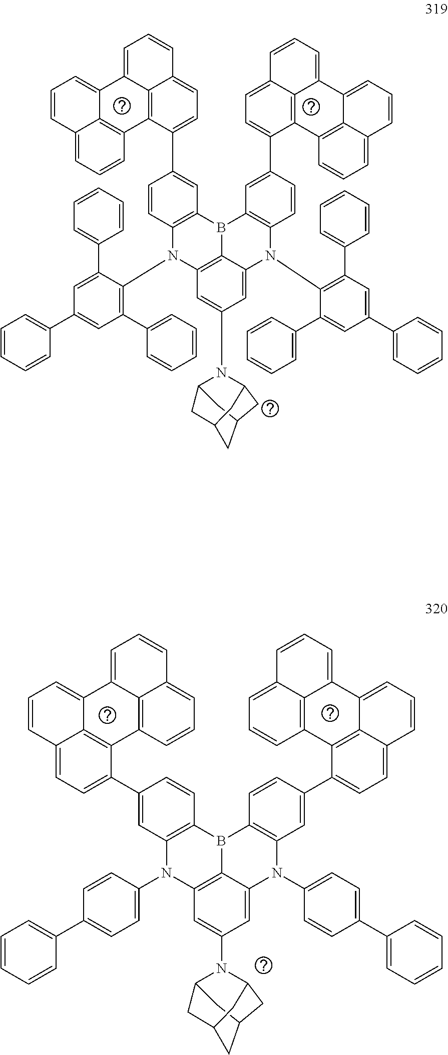 [SMILES: c1ccc(-c2cc(-c3ccccc3)c(N3c4ccc(-c5ccc6cccc7c8cccc9cccc(c5c67)c98)cc4B4c5cc(-c6ccc7cccc8c9cccc%10cccc(c6c78)c%109)ccc5N(c5c(-c6ccccc6)cc(-c6ccccc6)cc5-c5ccccc5)c5cc(N6C7CC8CC(C7)CC6C8)cc3c54)c(-c3ccccc3)c2)cc1 ; c1ccc(-c2ccc(N3c4cc(-c5ccc6cccc7c8cccc9cccc(c5c67)c98)ccc4B4c5ccc(-c6ccc7cccc8c9cccc%10cccc(c6c78)c%109)cc5N(c5ccc(-c6ccccc6)cc5)c5cc(N6C7CC8CC(C7)CC6C8)cc3c54)cc2)cc1] 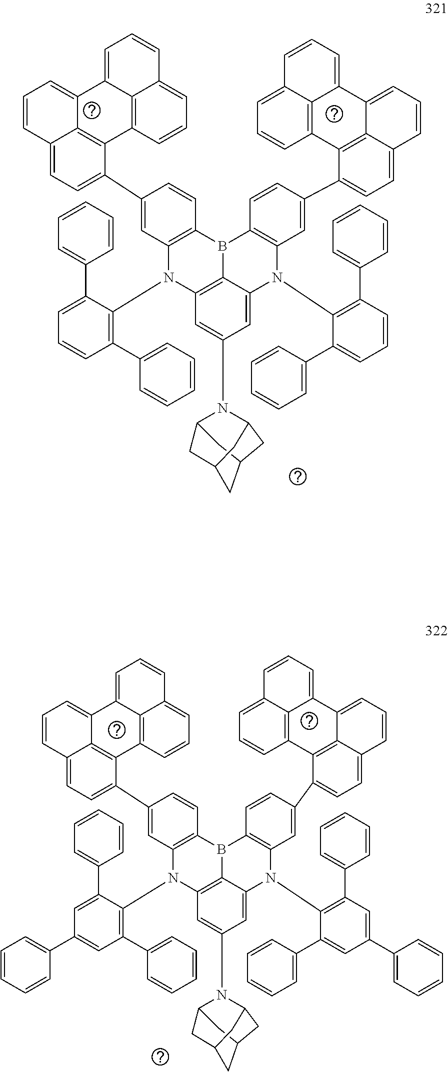 [SMILES: c1ccc(-c2cccc(-c3ccccc3)c2N2c3cc(-c4ccc5cccc6c7cccc8cccc(c4c56)c87)ccc3B3c4ccc(-c5ccc6cccc7c8cccc9cccc(c5c67)c98)cc4N(c4c(-c5ccccc5)cccc4-c4ccccc4)c4cc(N5C6CC7CC(C6)CC5C7)cc2c43)cc1 ; c1ccc(-c2cc(-c3ccccc3)c(N3c4cc(-c5ccc6cccc7c8cccc9cccc(c5c67)c98)ccc4B4c5ccc(-c6ccc7cccc8c9cccc%10cccc(c6c78)c%109)cc5N(c5c(-c6ccccc6)cc(-c6ccccc6)cc5-c5ccccc5)c5cc(N6C7CC8CC(C7)CC6C8)cc3c54)c(-c3ccccc3)c2)cc1] 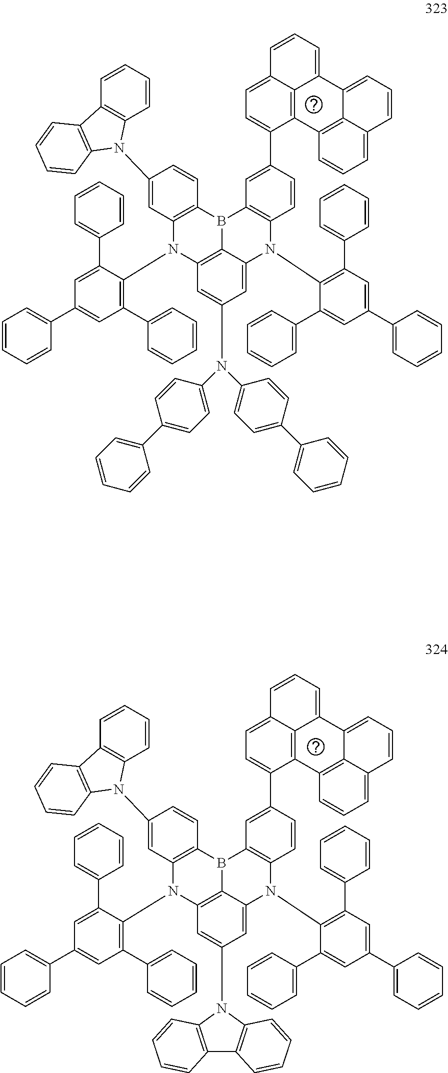 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3cc(-c5ccc6cccc7c8cccc9cccc(c5c67)c98)ccc3N4c3c(-c4ccccc4)cc(-c4ccccc4)cc3-c3ccccc3)cc2)cc1 ; c1ccc(-c2cc(-c3ccccc3)c(N3c4ccc(-c5ccc6cccc7c8cccc9cccc(c5c67)c98)cc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1] 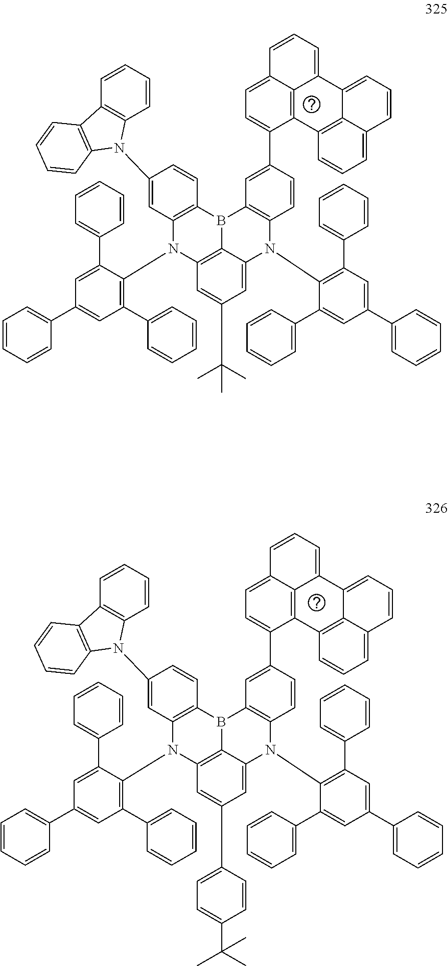 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1cc(-c3ccc4cccc5c6cccc7cccc(c3c45)c76)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4ccc5cccc6c7cccc8cccc(c4c56)c87)ccc2N3c2c(-c3ccccc3)cc(-c3ccccc3)cc2-c2ccccc2)cc1] 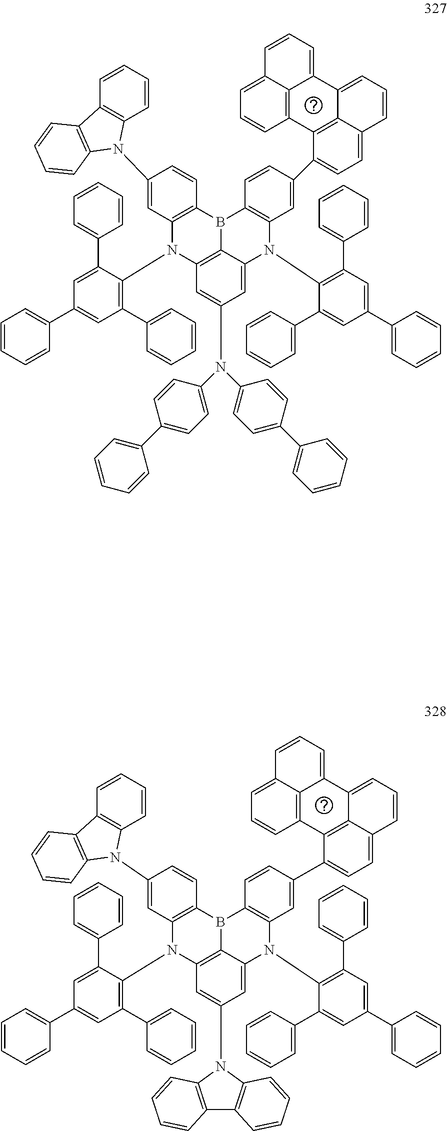 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3ccc(-c5ccc6cccc7c8cccc9cccc(c5c67)c98)cc3N4c3c(-c4ccccc4)cc(-c4ccccc4)cc3-c3ccccc3)cc2)cc1 ; c1ccc(-c2cc(-c3ccccc3)c(N3c4cc(-c5ccc6cccc7c8cccc9cccc(c5c67)c98)ccc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1] 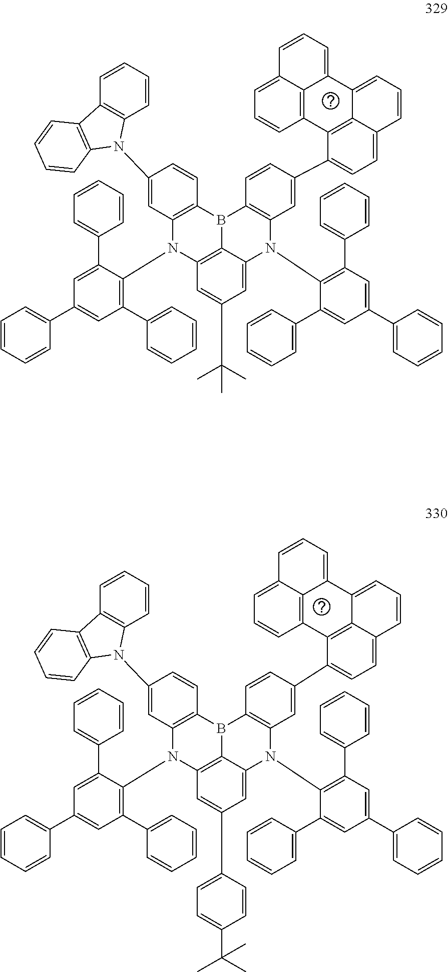 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc(-c3ccc4cccc5c6cccc7cccc(c3c45)c76)cc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2ccc(-c4ccc5cccc6c7cccc8cccc(c4c56)c87)cc2N3c2c(-c3ccccc3)cc(-c3ccccc3)cc2-c2ccccc2)cc1] 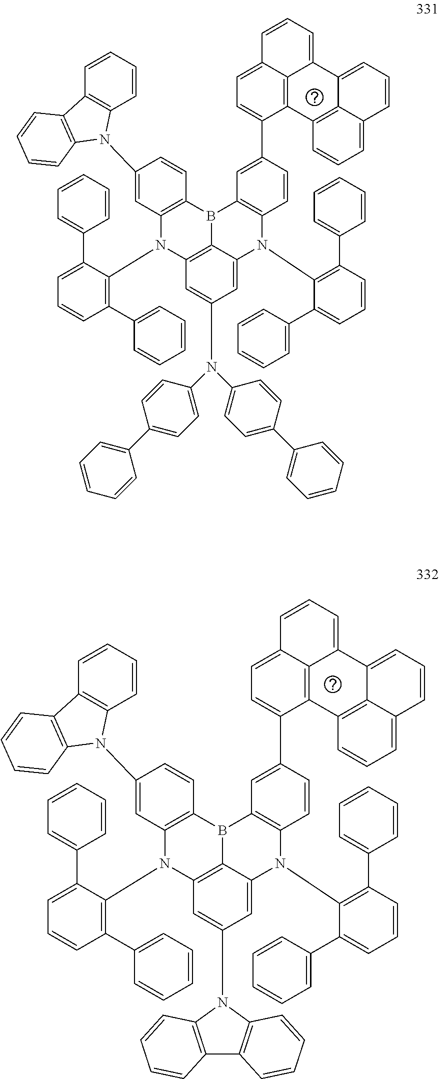 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3cc(-c5ccc6cccc7c8cccc9cccc(c5c67)c98)ccc3N4c3c(-c4ccccc4)cccc3-c3ccccc3)cc2)cc1 ; c1ccc(-c2cccc(-c3ccccc3)c2N2c3ccc(-c4ccc5cccc6c7cccc8cccc(c4c56)c87)cc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1] 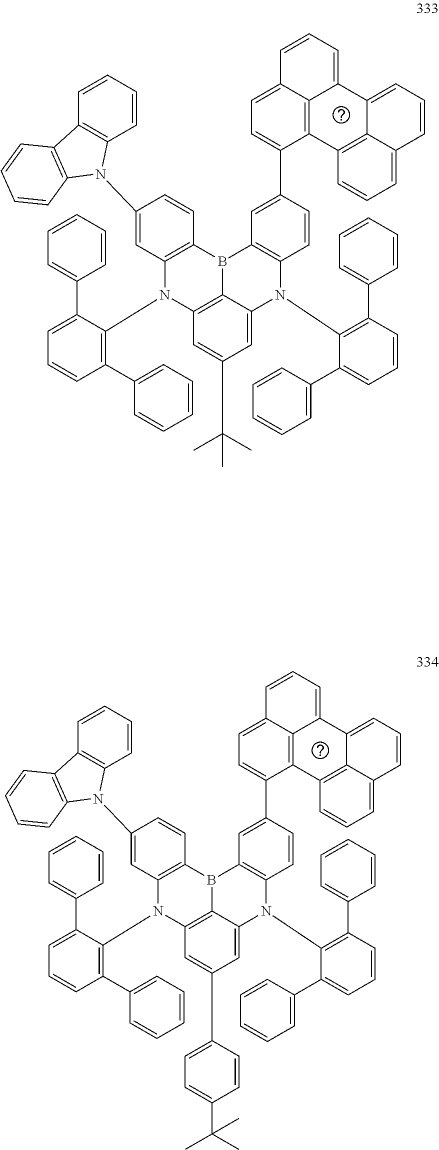 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccc4cccc5c6cccc7cccc(c3c45)c76)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4ccc5cccc6c7cccc8cccc(c4c56)c87)ccc2N3c2c(-c3ccccc3)cccc2-c2ccccc2)cc1] 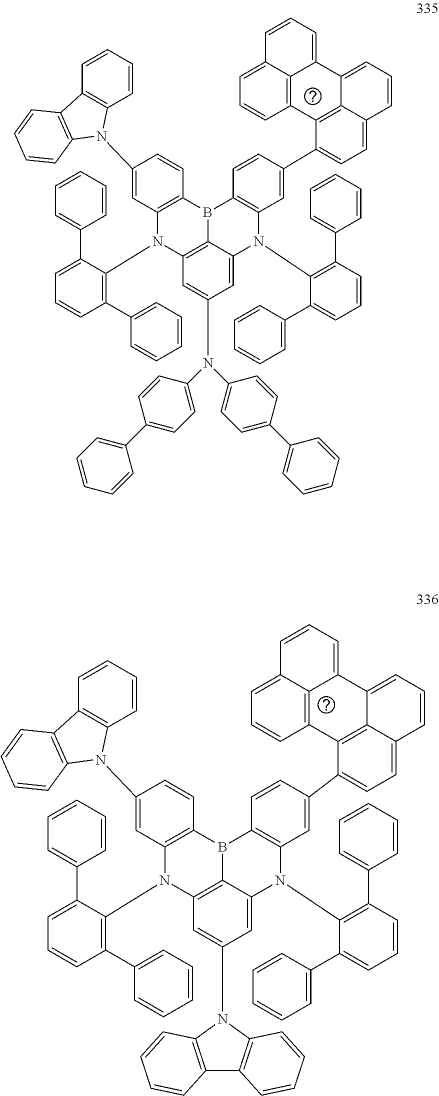 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3ccc(-c5ccc6cccc7c8cccc9cccc(c5c67)c98)cc3N4c3c(-c4ccccc4)cccc3-c3ccccc3)cc2)cc1 ; c1ccc(-c2cccc(-c3ccccc3)c2N2c3cc(-c4ccc5cccc6c7cccc8cccc(c4c56)c87)ccc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1] 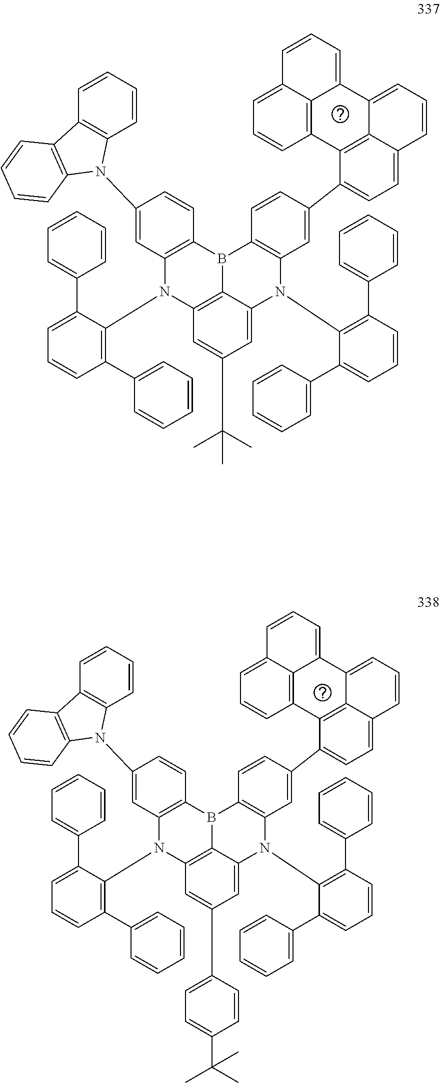 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-c3ccc4cccc5c6cccc7cccc(c3c45)c76)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4ccc5cccc6c7cccc8cccc(c4c56)c87)cc2N3c2c(-c3ccccc3)cccc2-c2ccccc2)cc1] 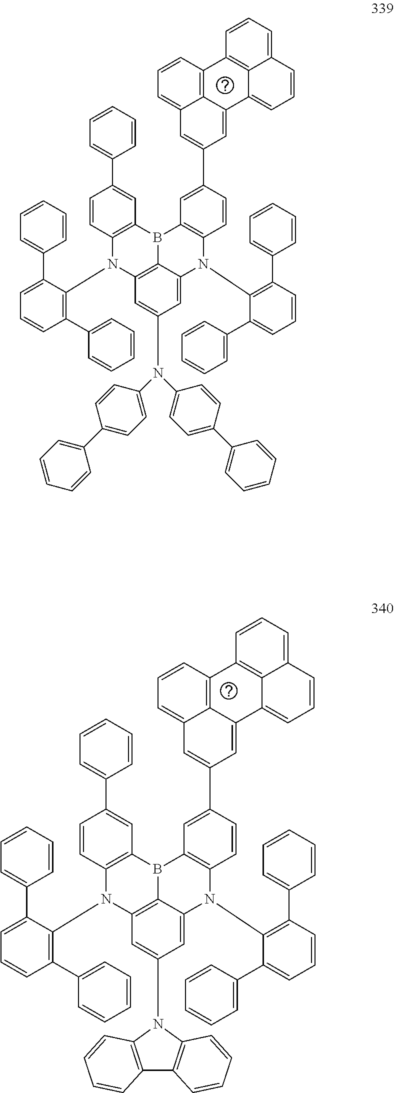 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6cc7cccc8c9cccc%10cccc(c(c6)c78)c%109)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5cc6cccc7c8cccc9cccc(c(c5)c67)c98)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 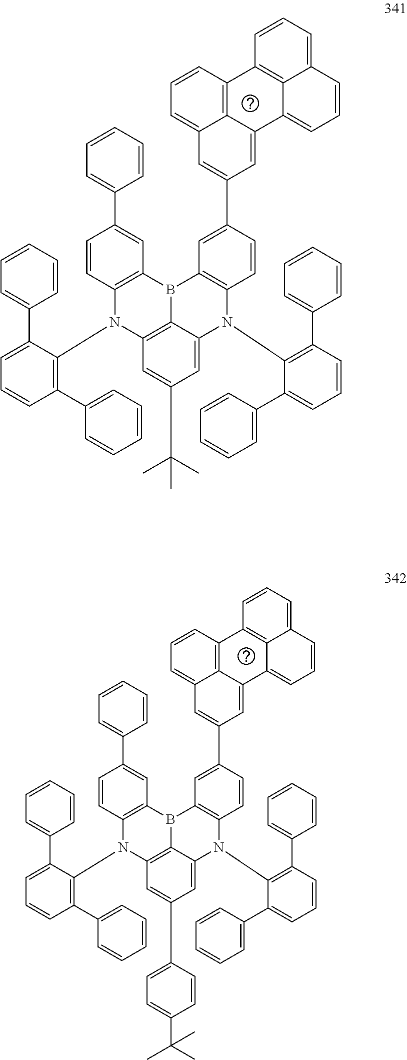 [SMILES: CC(C)(C)c1cc2c3c(c1)N(c1c(-c4ccccc4)cccc1-c1ccccc1)c1ccc(-c4cc5cccc6c7cccc8cccc(c(c4)c56)c87)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6cccc7c8cccc9cccc(c(c5)c67)c98)cc2B4c2cc(-c4ccccc4)ccc2N3c2c(-c3ccccc3)cccc2-c2ccccc2)cc1] 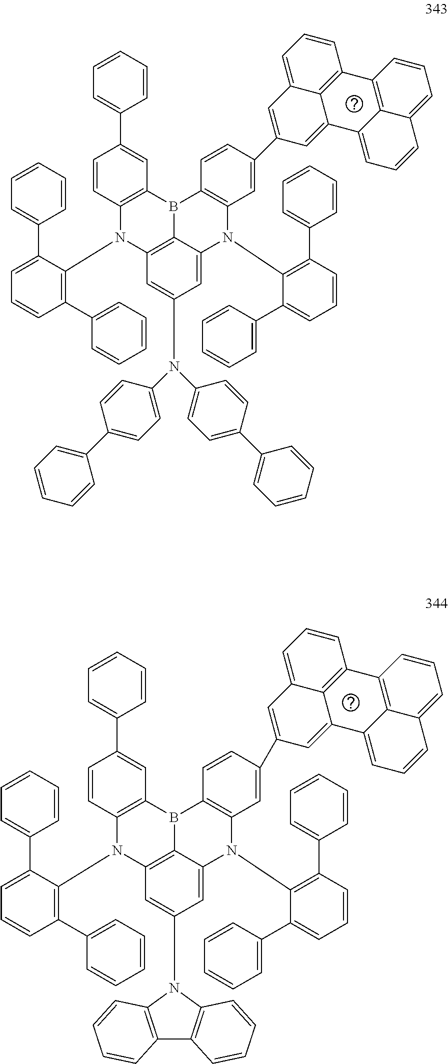 [SMILES: c1ccc(-c2ccc(N(c3ccc(-c4ccccc4)cc3)c3cc4c5c(c3)N(c3c(-c6ccccc6)cccc3-c3ccccc3)c3cc(-c6cc7cccc8c9cccc%10cccc(c(c6)c78)c%109)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5cc6cccc7c8cccc9cccc(c(c5)c67)c98)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 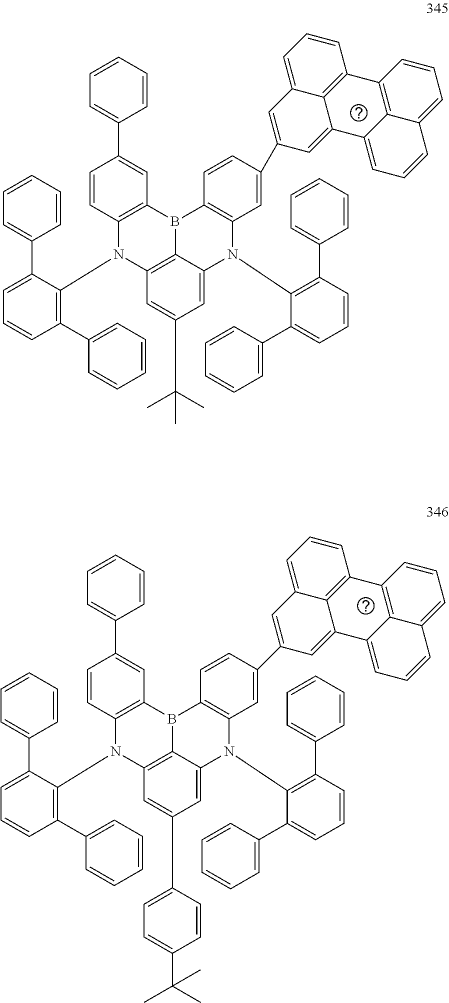 [SMILES: CC(C)(C)c1cc2c3c(c1)N(c1c(-c4ccccc4)cccc1-c1ccccc1)c1cc(-c4cc5cccc6c7cccc8cccc(c(c4)c56)c87)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5cc6cccc7c8cccc9cccc(c(c5)c67)c98)ccc2B4c2cc(-c4ccccc4)ccc2N3c2c(-c3ccccc3)cccc2-c2ccccc2)cc1] 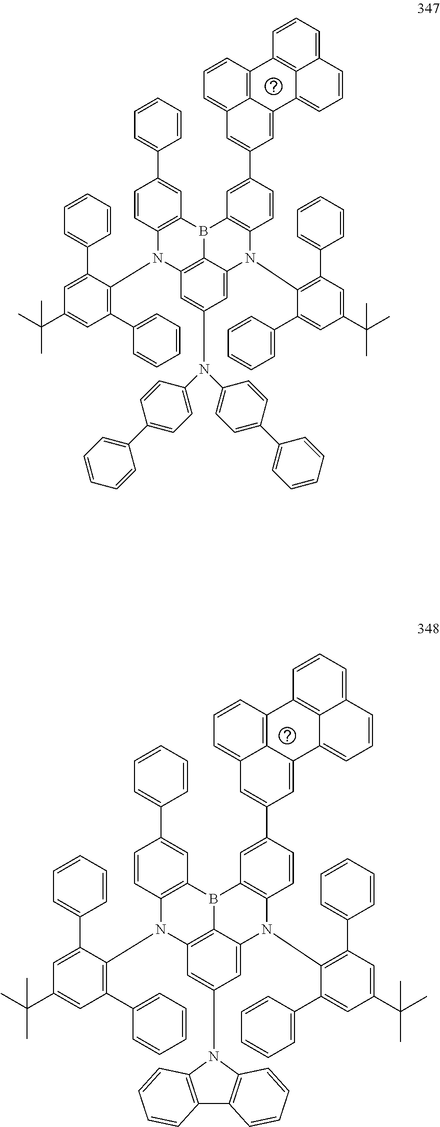 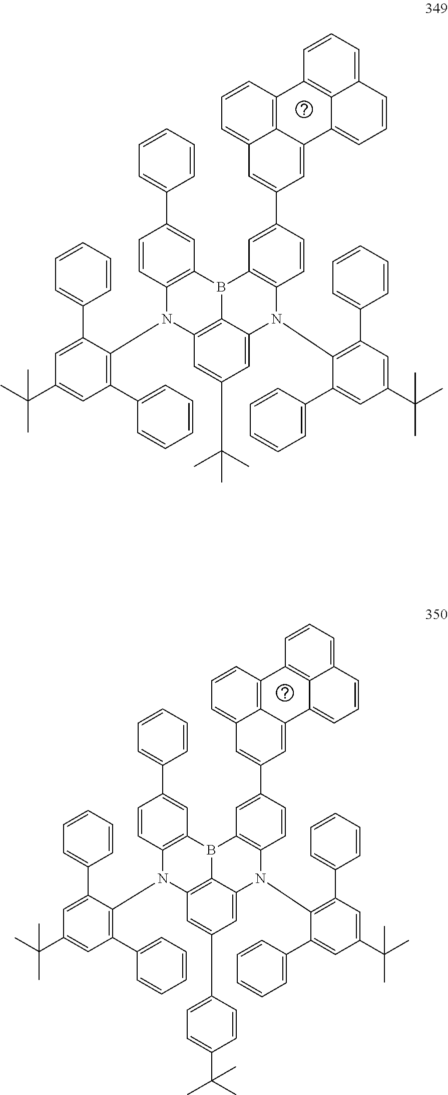 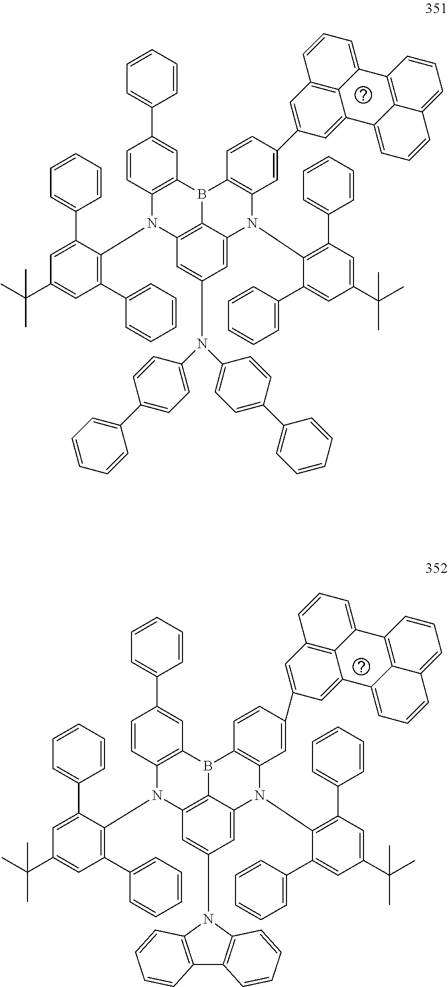 [SMILES: CC(C)(C)c1cc(-c2ccccc2)c(N2c3ccc(-c4ccccc4)cc3B3c4ccc(-c5cc6cccc7c8cccc9cccc(c(c5)c67)c98)cc4N(c4c(-c5ccccc5)cc(C(C)(C)C)cc4-c4ccccc4)c4cc(N(c5ccc(-c6ccccc6)cc5)c5ccc(-c6ccccc6)cc5)cc2c43)c(-c2ccccc2)c1 ; CC(C)(C)c1cc(-c2ccccc2)c(N2c3ccc(-c4ccccc4)cc3B3c4ccc(-c5cc6cccc7c8cccc9cccc(c(c5)c67)c98)cc4N(c4c(-c5ccccc5)cc(C(C)(C)C)cc4-c4ccccc4)c4cc(-n5c6ccccc6c6ccccc65)cc2c43)c(-c2ccccc2)c1] 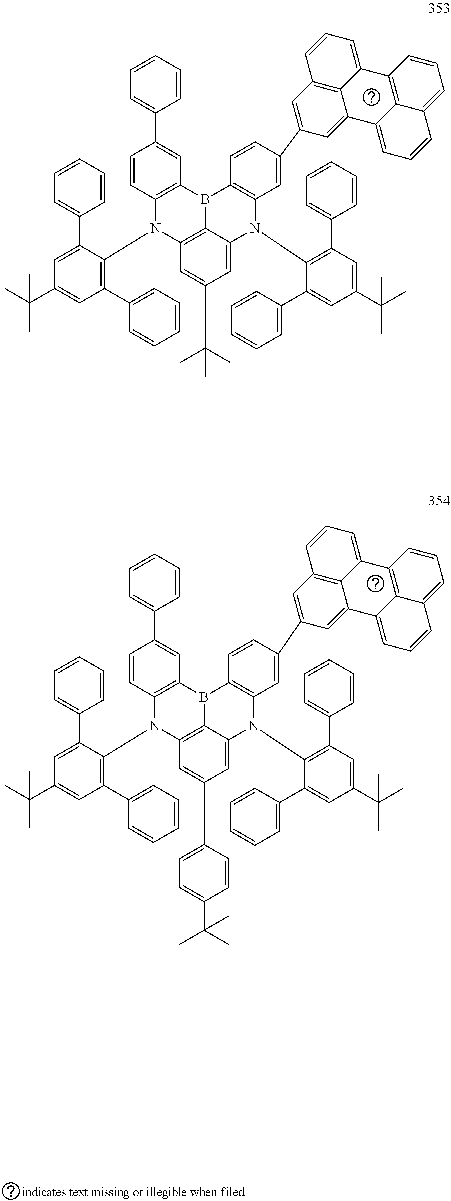 [SMILES: CC(C)(C)c1cc(-c2ccccc2)c(N2c3ccc(-c4ccccc4)cc3B3c4ccc(-c5cc6cccc7c8cccc9cccc(c(c5)c67)c98)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(-c2cc3c4c(c2)N(c2c(-c5ccccc5)cc(C(C)(C)C)cc2-c2ccccc2)c2cc(-c5cc6cccc7c8cccc9cccc(c(c5)c67)c98)ccc2B4c2cc(-c4ccccc4)ccc2N3c2c(-c3ccccc3)cc(C(C)(C)C)cc2-c2ccccc2)cc1] 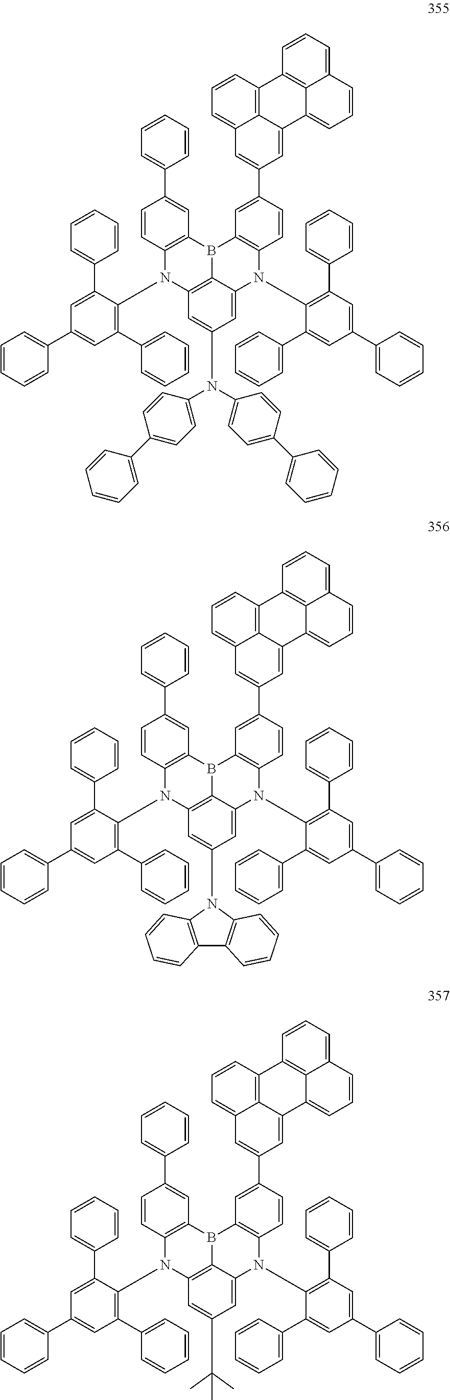 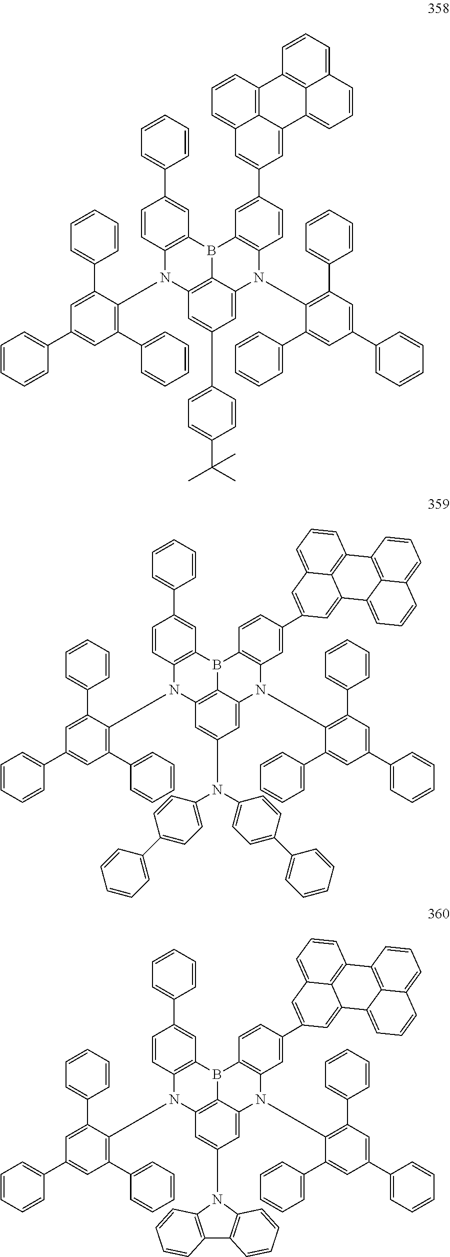 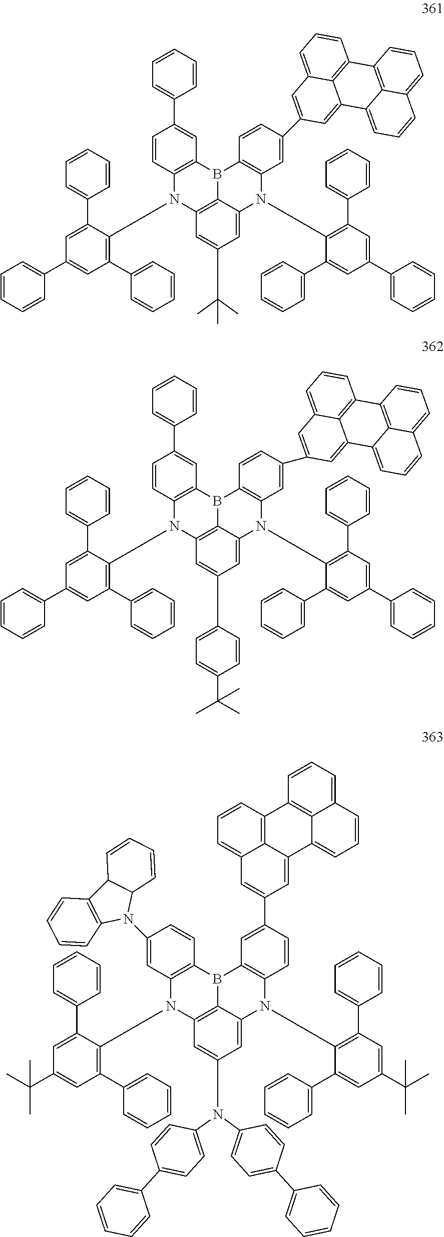 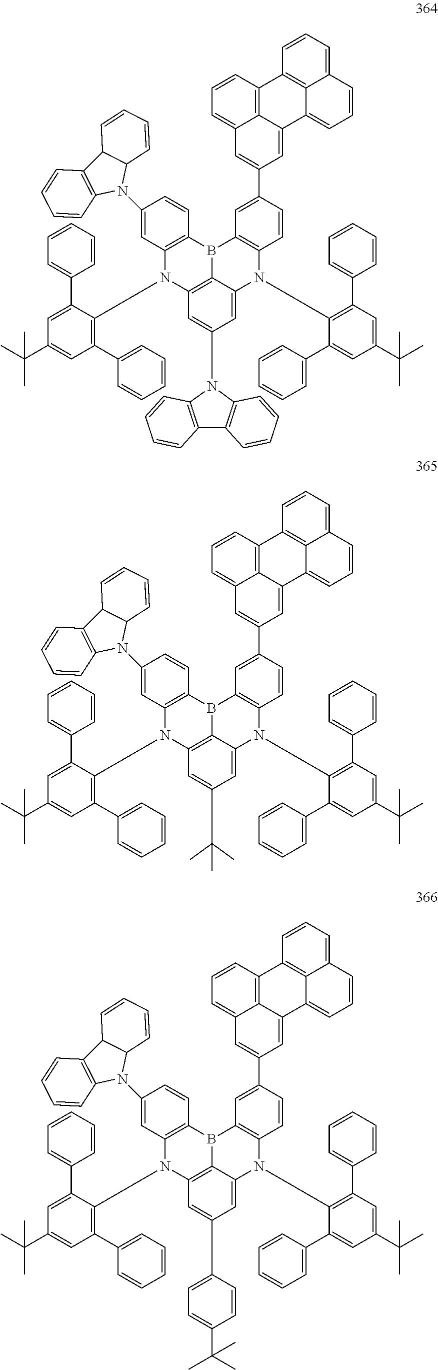 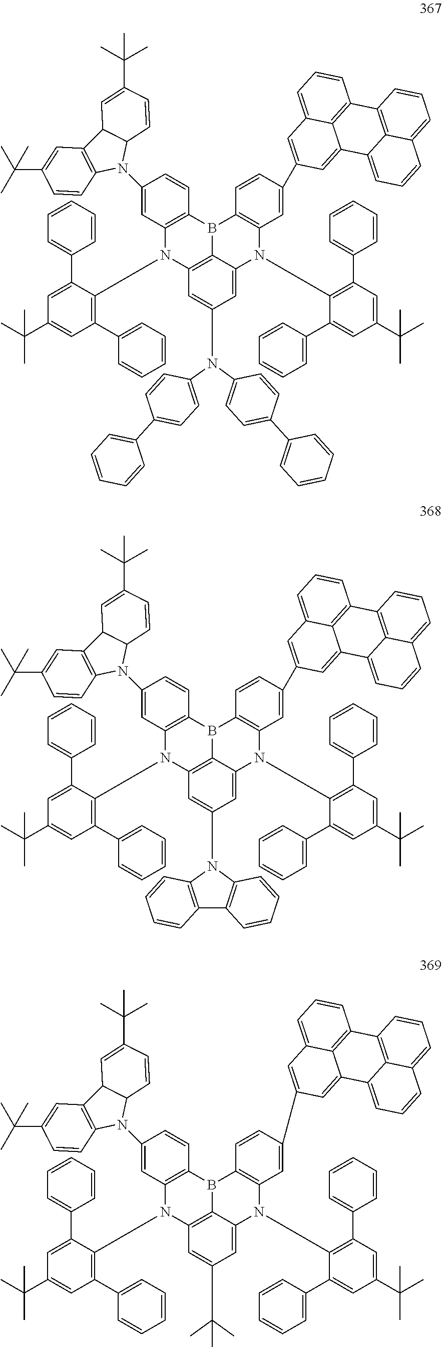 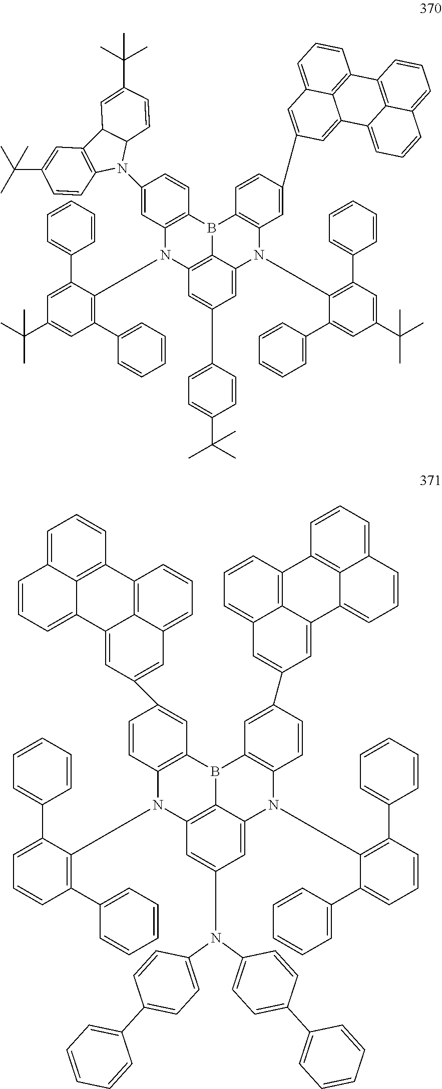 [SMILES: CC(C)(C)C1=CC2c3cc(C(C)(C)C)ccc3N(c3ccc4c(c3)N(CCc3c(-c5ccccc5)cc(C(C)(C)C)cc3-c3ccccc3)c3cc(Cc5ccc(C(C)(C)C)cc5)cc5c3B4c3ccc(Cc4cc6cccc7c8cccc9cccc(c(c4)c67)c98)cc3N5CCc3c(-c4ccccc4)cc(C(C)(C)C)cc3-c3ccccc3)C2C=C1 ; c1ccc(-c2ccc(N(Cc3cc4c5c(c3)N(CCc3c(-c6ccccc6)cccc3-c3ccccc3)c3ccc(-c6cc7cccc8c9cccc%10cccc(c(c6)c78)c%109)cc3B5c3cc(-c5cc6cccc7c8cccc9cccc(c(c5)c67)c98)ccc3N4CCc3c(-c4ccccc4)cccc3-c3ccccc3)c3ccc(-c4ccccc4)cc3)cc2)cc1] 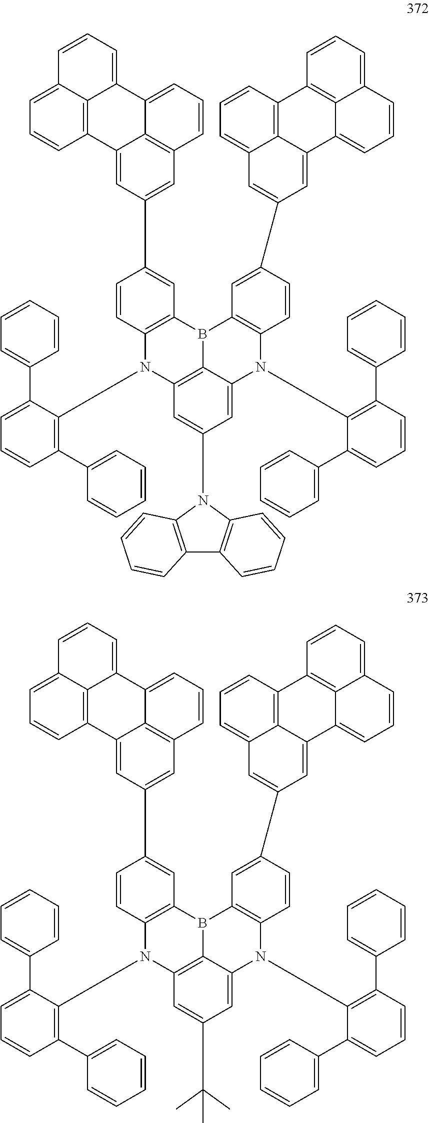 [SMILES: c1ccc(-c2cccc(-c3ccccc3)c2CCN2c3ccc(Cc4cc5cccc6c7cccc8cccc(c(c4)c56)c87)cc3B3c4cc(Cc5cc6cccc7c8cccc9cccc(c(c5)c67)c98)ccc4N(CCc4c(-c5ccccc5)cccc4-c4ccccc4)c4cc(Cn5c6ccccc6c6ccccc65)cc2c43)cc1 ; CC(C)(C)Cc1cc2c3c(c1)N(CCc1c(-c4ccccc4)cccc1-c1ccccc1)c1ccc(Cc4cc5cccc6c7cccc8cccc(c(c4)c56)c87)cc1B3c1cc(Cc3cc4cccc5c6cccc7cccc(c(c3)c45)c76)ccc1N2CCc1c(-c2ccccc2)cccc1-c1ccccc1] 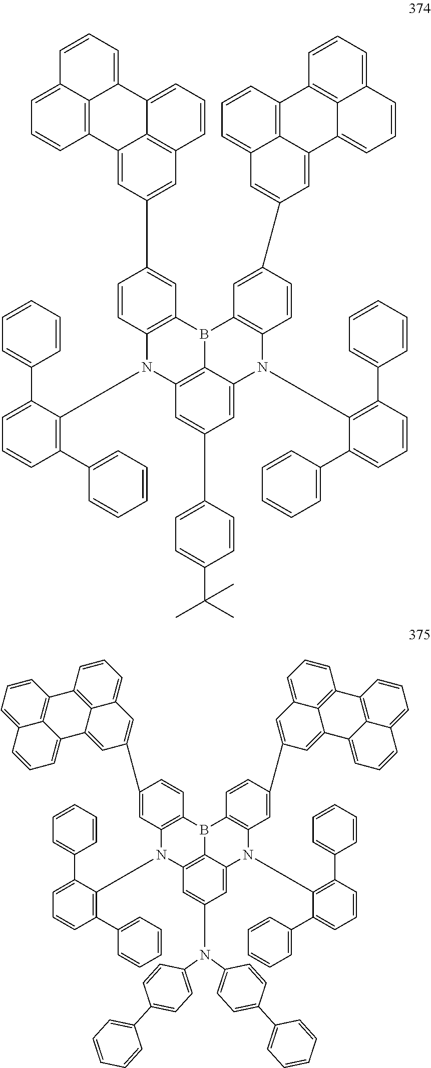 [SMILES: CC(C)(C)c1ccc(Cc2cc3c4c(c2)N(CCc2c(-c5ccccc5)cccc2-c2ccccc2)c2ccc(Cc5cc6cccc7c8cccc9cccc(c(c5)c67)c98)cc2B4c2cc(Cc4cc5cccc6c7cccc8cccc(c(c4)c56)c87)ccc2N3CCc2c(-c3ccccc3)cccc2-c2ccccc2)cc1 ; c1ccc(-c2ccc(N(Cc3cc4c5c(c3)N(CCc3c(-c6ccccc6)cccc3-c3ccccc3)c3cc(Cc6cc7cccc8c9cccc%10cccc(c(c6)c78)c%109)ccc3B5c3ccc(Cc5cc6cccc7c8cccc9cccc(c(c5)c67)c98)cc3N4CCc3c(-c4ccccc4)cccc3-c3ccccc3)c3ccc(-c4ccccc4)cc3)cc2)cc1] 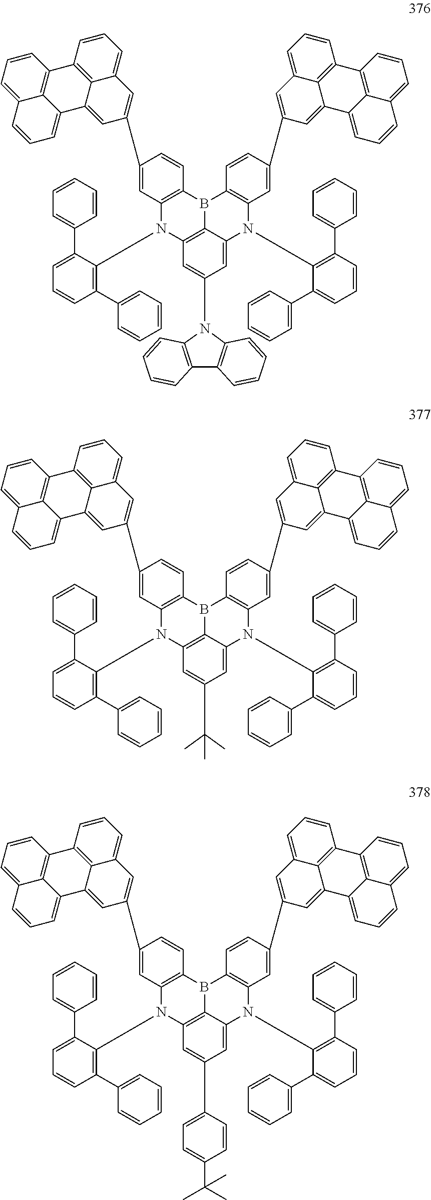 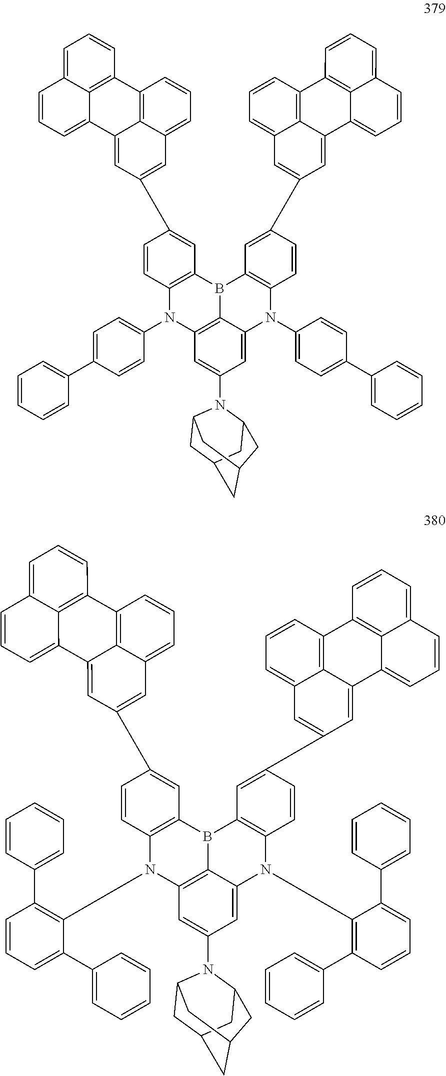 [SMILES: c1ccc(-c2ccc(N3c4ccc(Cc5cc6cccc7c8cccc9cccc(c(c5)c67)c98)cc4B4c5cc(Cc6cc7cccc8c9cccc%10cccc(c(c6)c78)c%109)ccc5N(c5ccc(-c6ccccc6)cc5)c5cc(N6C7CC8CC(C7)CC6C8)cc3c54)cc2)cc1 ; c1ccc(-c2cccc(-c3ccccc3)c2CCN2c3ccc(Cc4cc5cccc6c7cccc8cccc(c(c4)c56)c87)cc3B3c4cc(Cc5cc6cccc7c8cccc9cccc(c(c5)c67)c98)ccc4N(CCc4c(-c5ccccc5)cccc4-c4ccccc4)c4cc(N5C6CC7CC(C6)CC5C7)cc2c43)cc1] 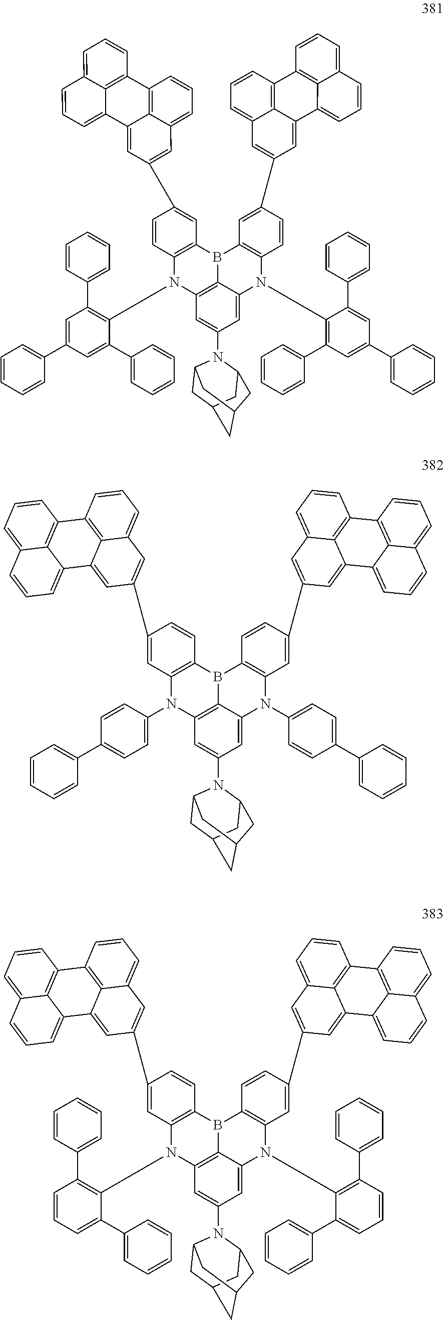 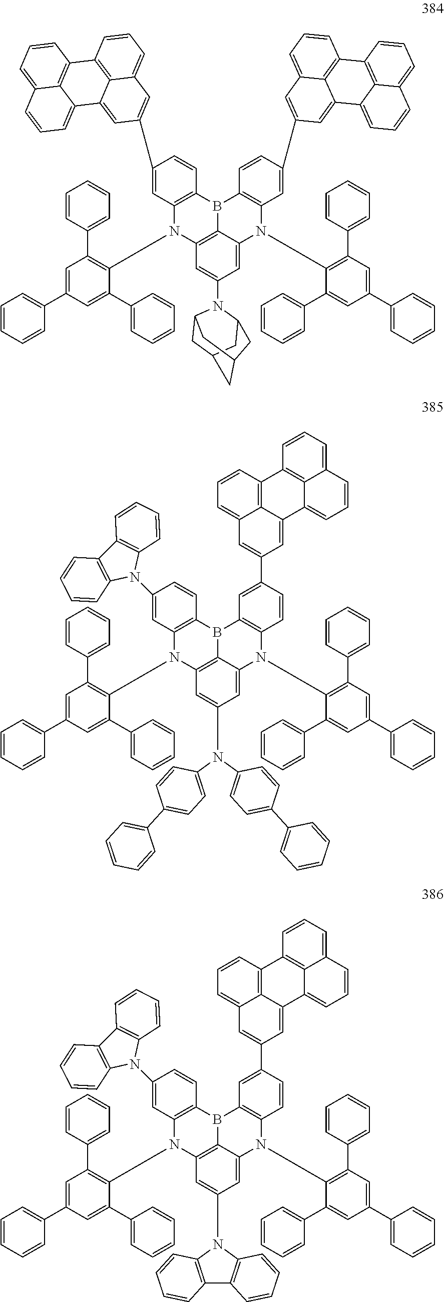 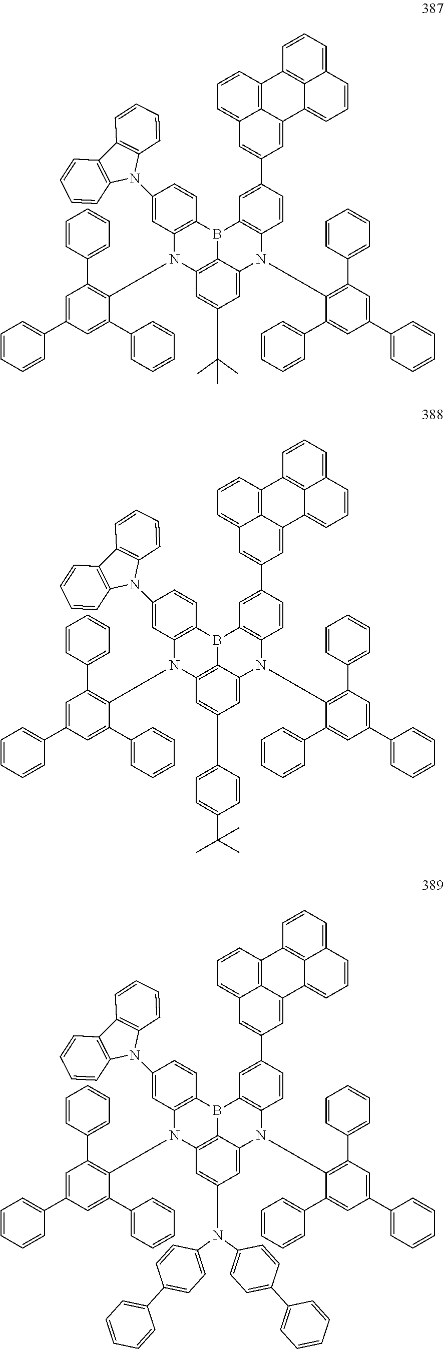 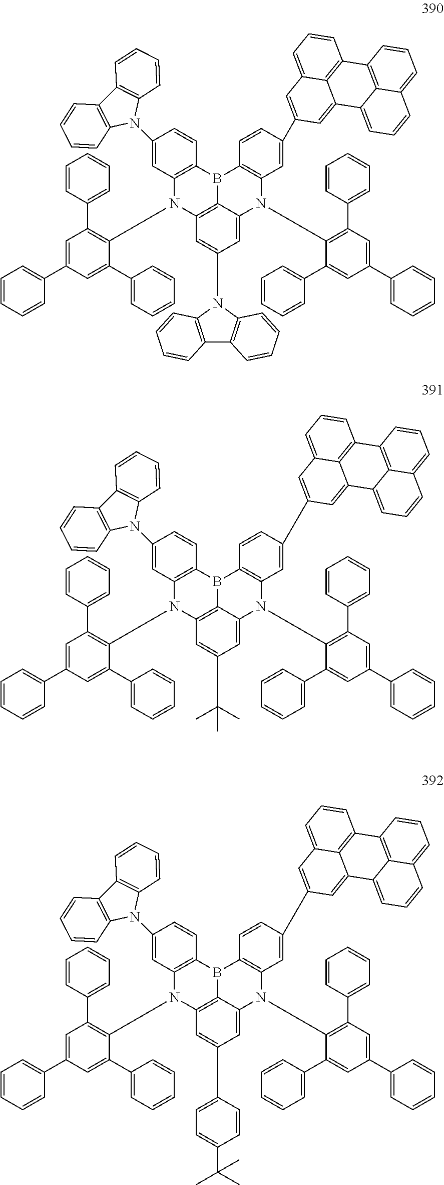 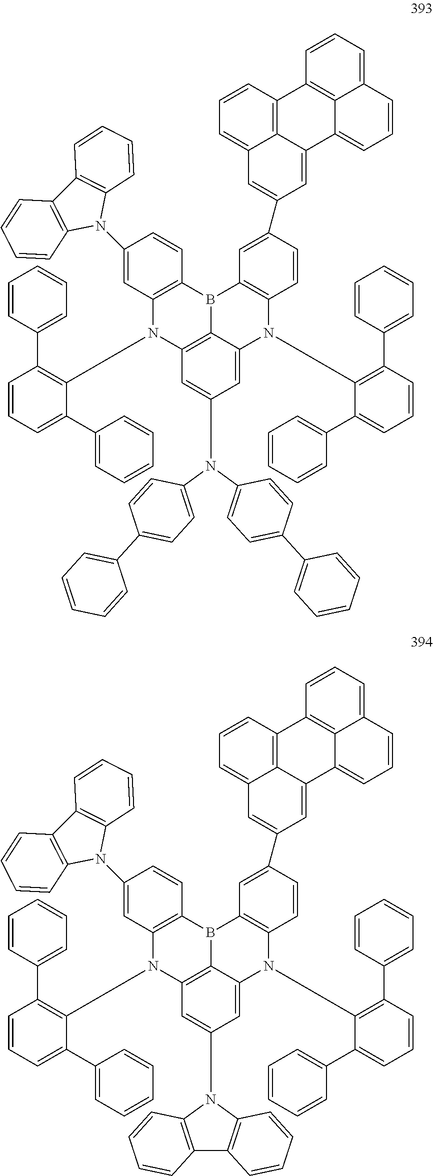 [SMILES: c1ccc(-c2ccc(N(Cc3cc4c5c(c3)N(CCc3c(-c6ccccc6)cccc3-c3ccccc3)c3cc(-n6c7ccccc7c7ccccc76)ccc3B5c3cc(-c5cc6cccc7c8cccc9cccc(c(c5)c67)c98)ccc3N4CCc3c(-c4ccccc4)cccc3-c3ccccc3)c3ccc(-c4ccccc4)cc3)cc2)cc1 ; c1ccc(-c2cccc(-c3ccccc3)c2CCN2c3ccc(-c4cc5cccc6c7cccc8cccc(c(c4)c56)c87)cc3B3c4ccc(-n5c6ccccc6c6ccccc65)cc4N(CCc4c(-c5ccccc5)cccc4-c4ccccc4)c4cc(Cn5c6ccccc6c6ccccc65)cc2c43)cc1] 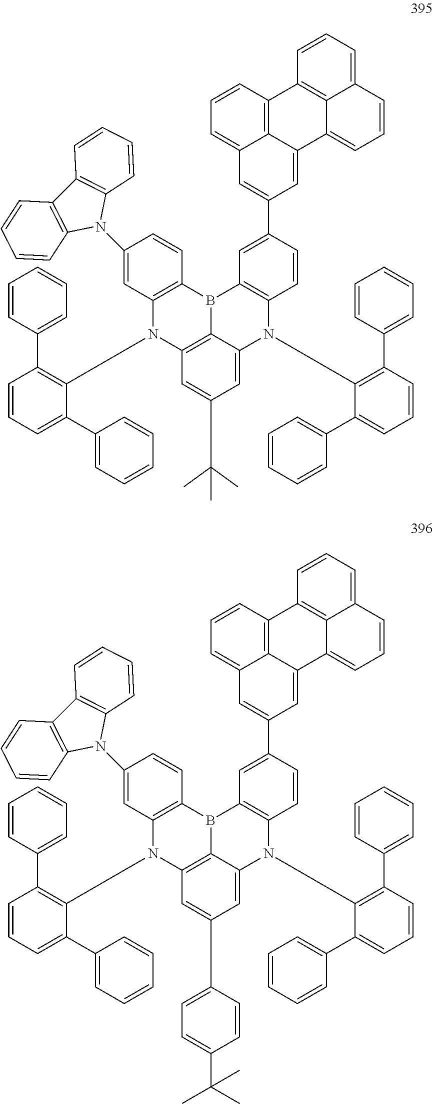 [SMILES: CC(C)(C)Cc1cc2c3c(c1)N(CCc1c(-c4ccccc4)cccc1-c1ccccc1)c1cc(-n4c5ccccc5c5ccccc54)ccc1B3c1cc(-c3cc4cccc5c6cccc7cccc(c(c3)c45)c76)ccc1N2CCc1c(-c2ccccc2)cccc1-c1ccccc1 ; CC(C)(C)c1ccc(Cc2cc3c4c(c2)N(CCc2c(-c5ccccc5)cccc2-c2ccccc2)c2cc(-n5c6ccccc6c6ccccc65)ccc2B4c2cc(-c4cc5cccc6c7cccc8cccc(c(c4)c56)c87)ccc2N3CCc2c(-c3ccccc3)cccc2-c2ccccc2)cc1] 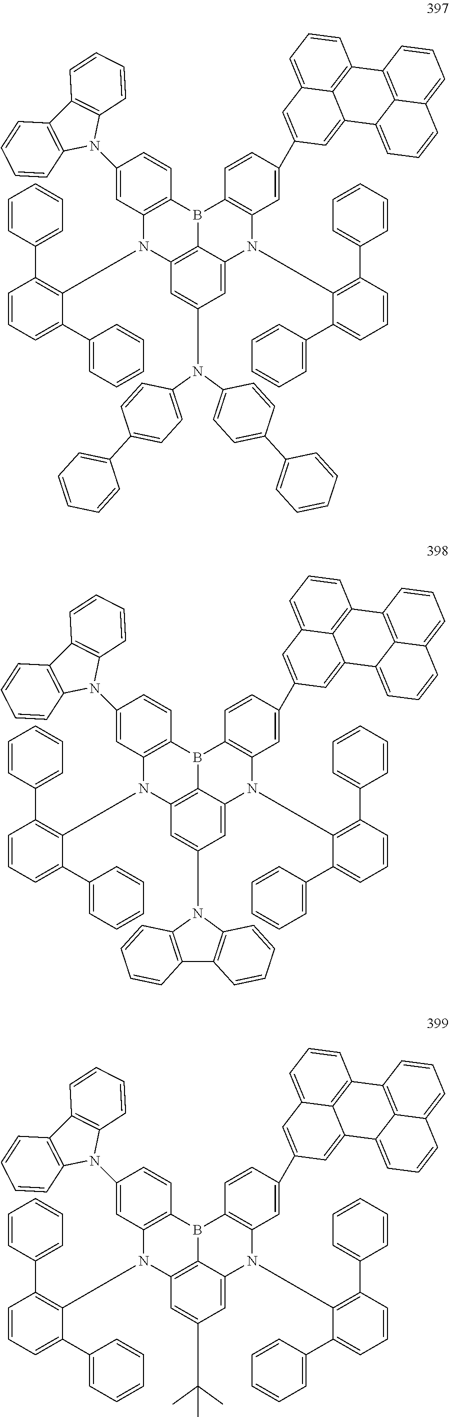 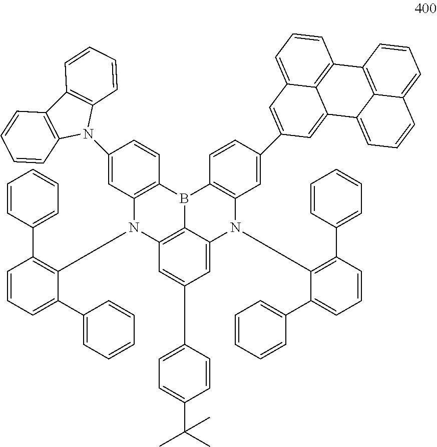 [SMILES: CC(C)(C)c1ccc(Cc2cc3c4c(c2)N(CCc2c(-c5ccccc5)cccc2-c2ccccc2)c2cc(-n5c6ccccc6c6ccccc65)ccc2B4c2ccc(-c4cc5cccc6c7cccc8cccc(c(c4)c56)c87)cc2N3CCc2c(-c3ccccc3)cccc2-c2ccccc2)cc1] 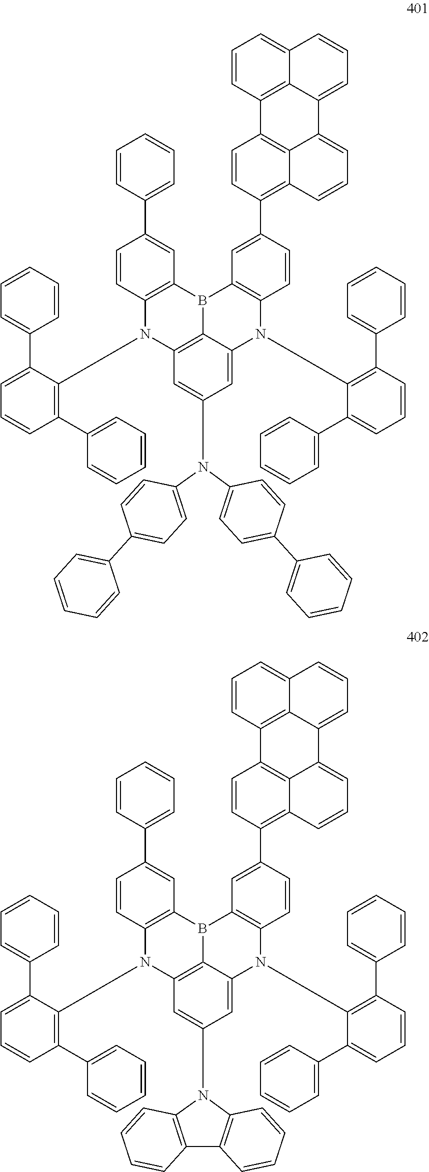 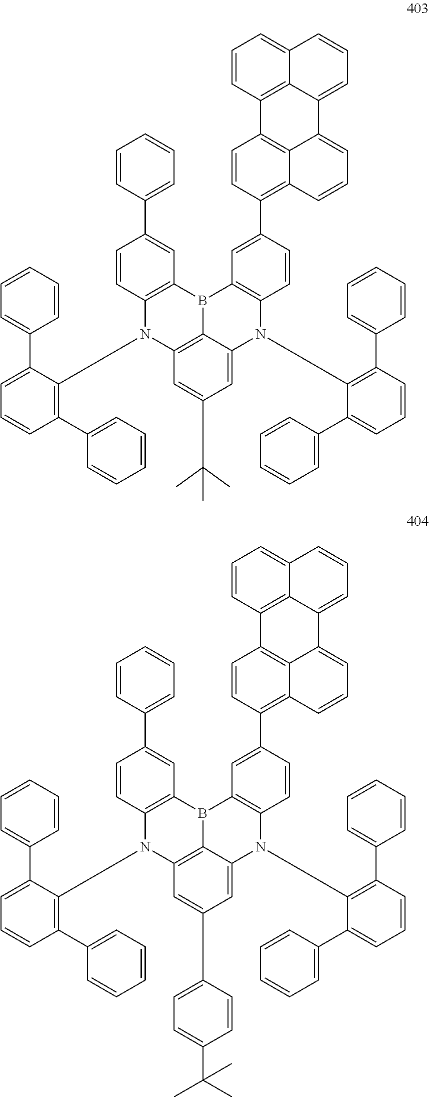 [SMILES: CC(C)(C)Cc1cc2c3c(c1)N(CCc1c(-c4ccccc4)cccc1-c1ccccc1)c1ccc(-c4ccc5c6cccc7cccc(c8cccc4c85)c76)cc1B3c1cc(-c3ccccc3)ccc1N2CCc1c(-c2ccccc2)cccc1-c1ccccc1 ; CC(C)(C)c1ccc(Cc2cc3c4c(c2)N(CCc2c(-c5ccccc5)cccc2-c2ccccc2)c2ccc(-c5ccc6c7cccc8cccc(c9cccc5c96)c87)cc2B4c2cc(-c4ccccc4)ccc2N3CCc2c(-c3ccccc3)cccc2-c2ccccc2)cc1] 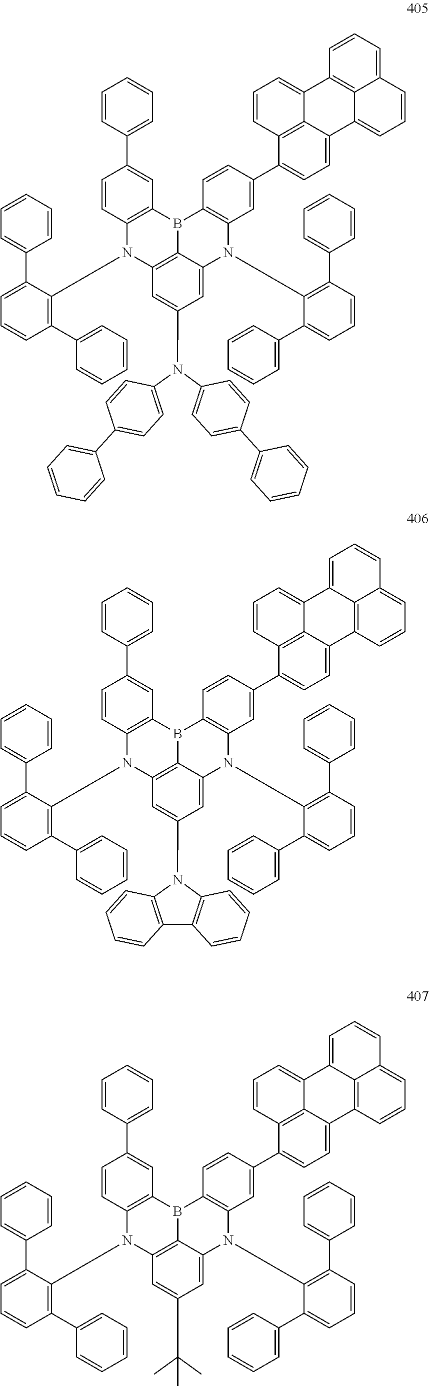 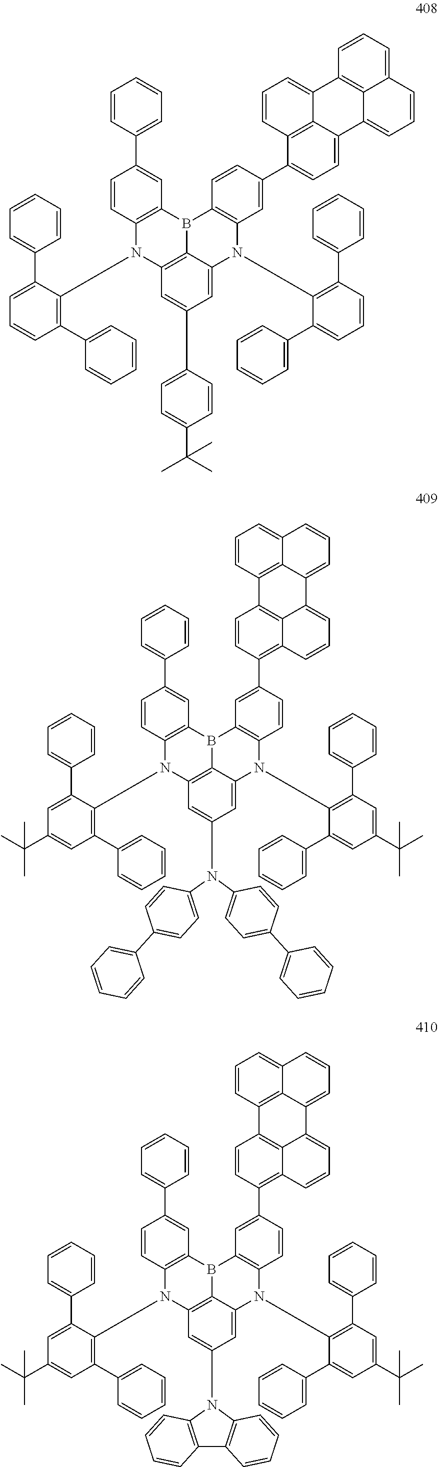 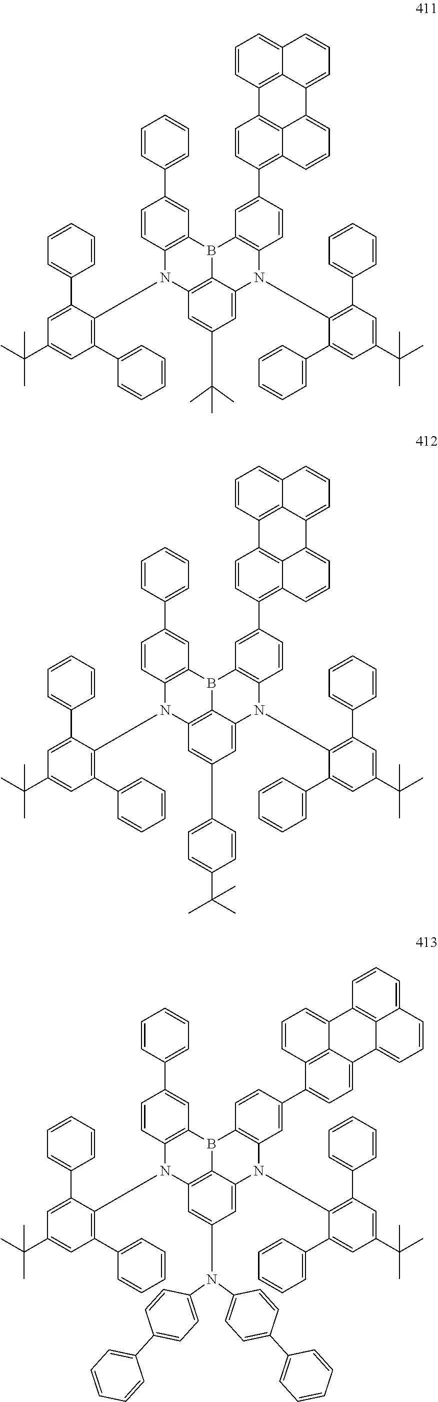 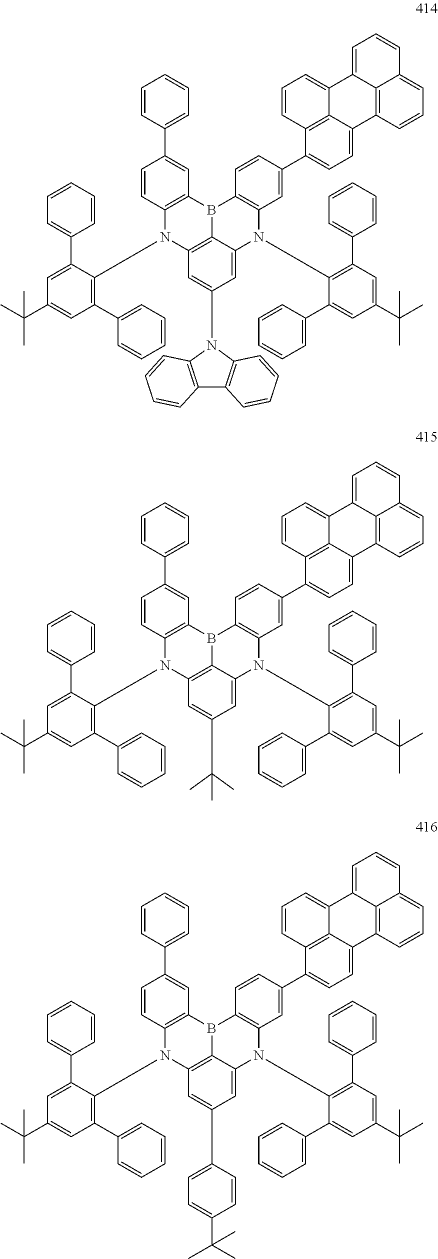 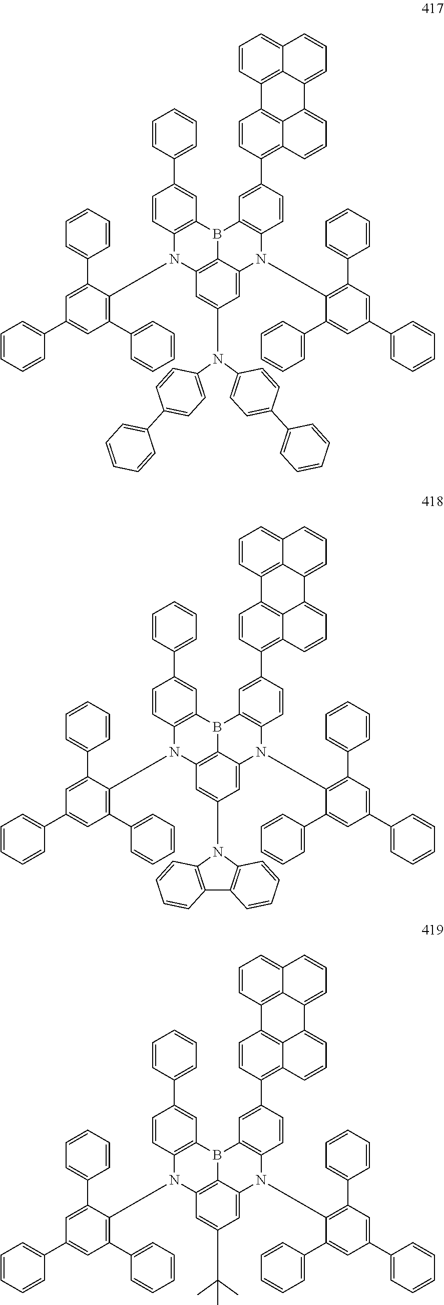 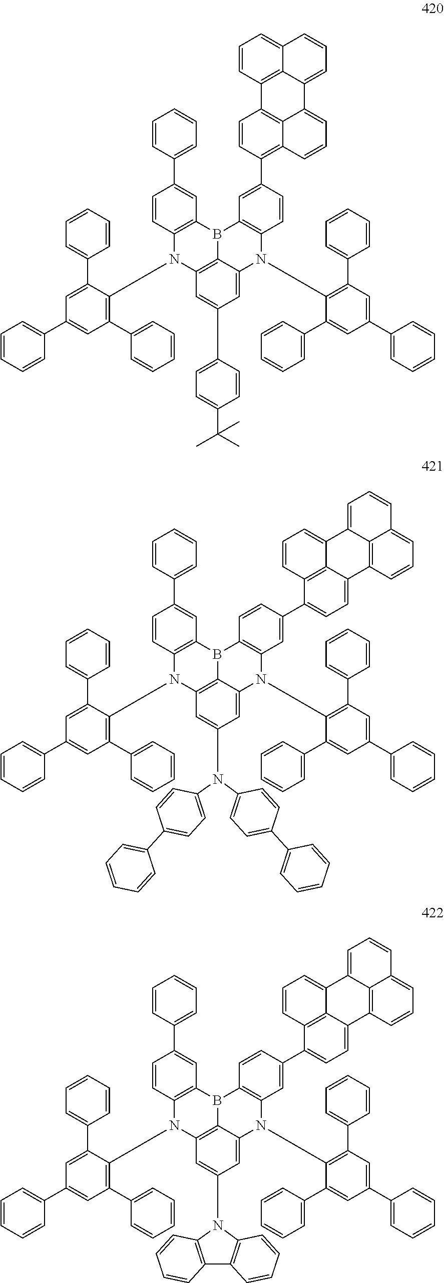 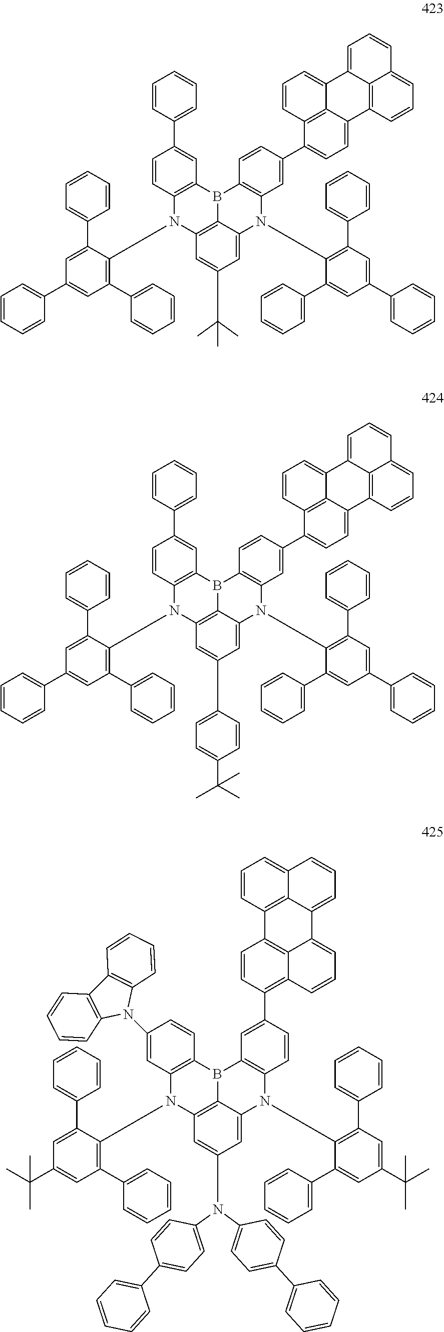 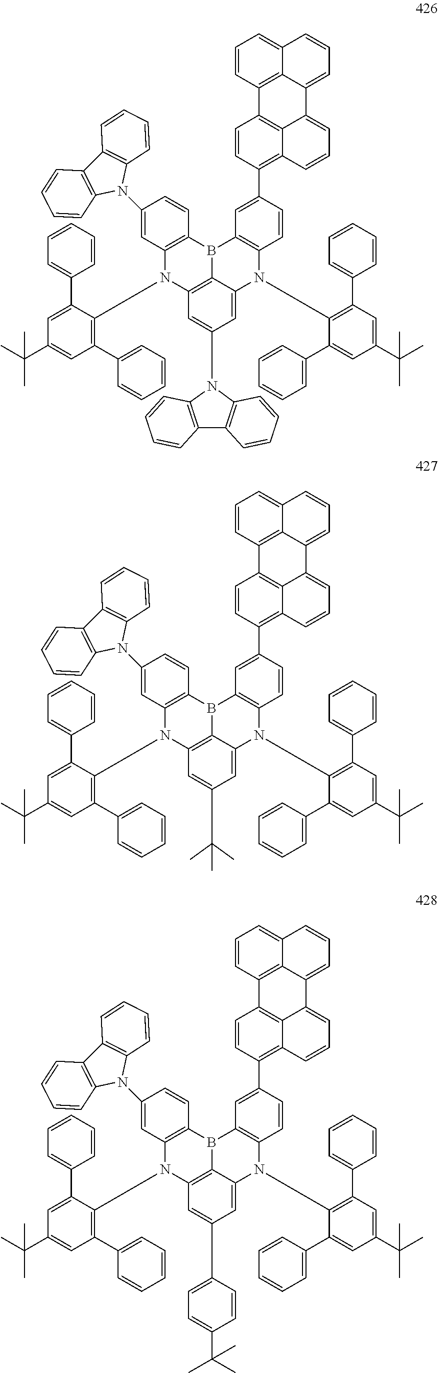 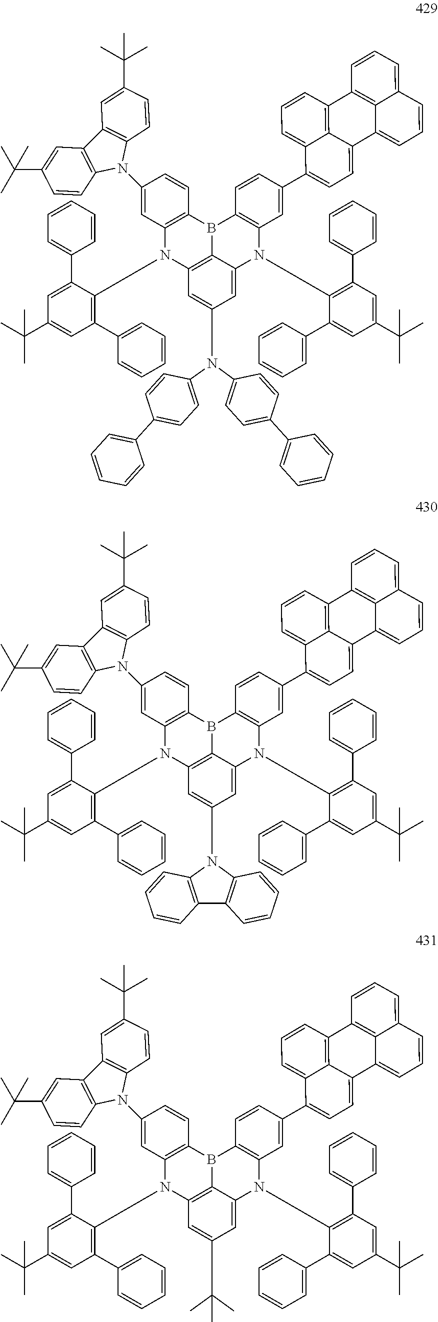 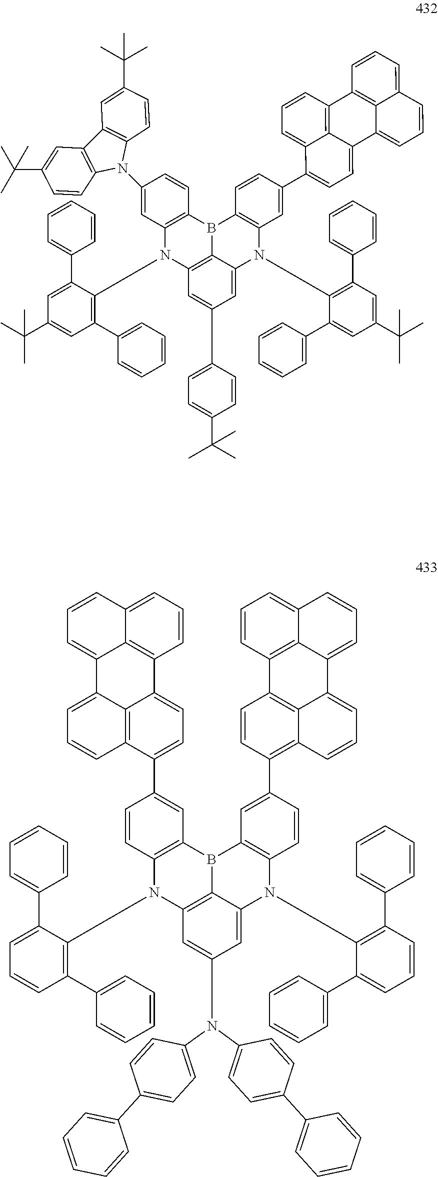 [SMILES: CC(C)(C)c1ccc(Cc2cc3c4c(c2)N(CCc2c(-c5ccccc5)cc(C(C)(C)C)cc2-c2ccccc2)c2cc(-n5c6ccc(C(C)(C)C)cc6c6cc(C(C)(C)C)ccc65)ccc2B4c2ccc(-c4ccc5c6cccc7cccc(c8cccc4c85)c76)cc2N3CCc2c(-c3ccccc3)cc(C(C)(C)C)cc2-c2ccccc2)cc1 ; c1ccc(-c2ccc(N(Cc3cc4c5c(c3)N(CCc3c(-c6ccccc6)cccc3-c3ccccc3)c3ccc(-c6ccc7c8cccc9cccc(c%10cccc6c%107)c98)cc3B5c3cc(-c5ccc6c7cccc8cccc(c9cccc5c96)c87)ccc3N4CCc3c(-c4ccccc4)cccc3-c3ccccc3)c3ccc(-c4ccccc4)cc3)cc2)cc1] 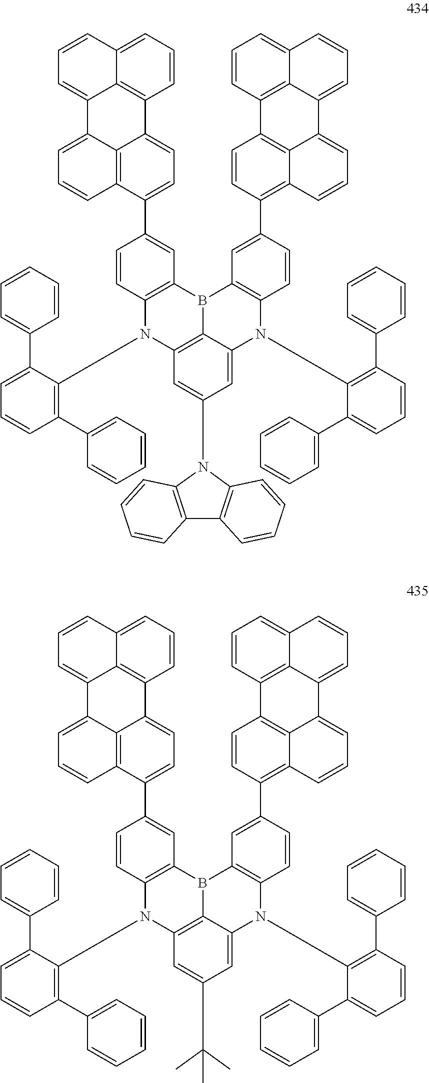 [SMILES: c1ccc(-c2cccc(-c3ccccc3)c2CCN2c3ccc(-c4ccc5c6cccc7cccc(c8cccc4c85)c76)cc3B3c4cc(-c5ccc6c7cccc8cccc(c9cccc5c96)c87)ccc4N(CCc4c(-c5ccccc5)cccc4-c4ccccc4)c4cc(Cn5c6ccccc6c6ccccc65)cc2c43)cc1 ; CC(C)(C)Cc1cc2c3c(c1)N(CCc1c(-c4ccccc4)cccc1-c1ccccc1)c1ccc(-c4ccc5c6cccc7cccc(c8cccc4c85)c76)cc1B3c1cc(-c3ccc4c5cccc6cccc(c7cccc3c74)c65)ccc1N2CCc1c(-c2ccccc2)cccc1-c1ccccc1] 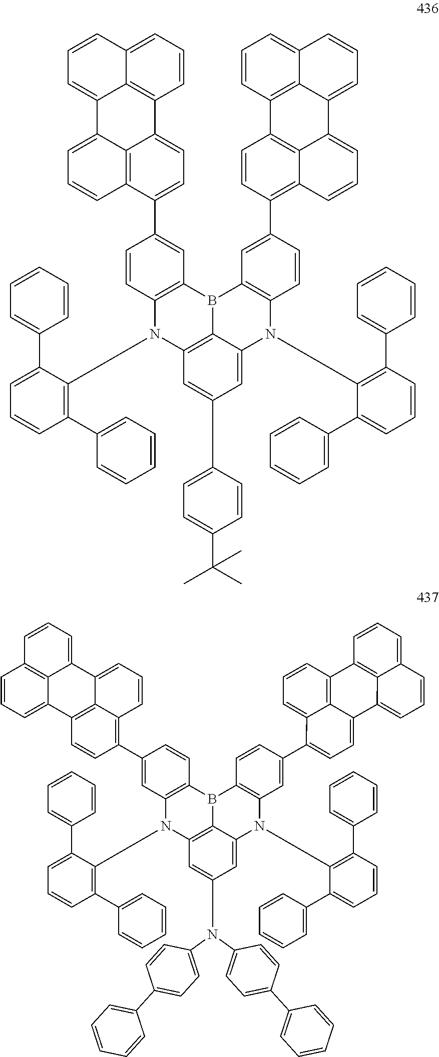 [SMILES: CC(C)(C)c1ccc(Cc2cc3c4c(c2)N(CCc2c(-c5ccccc5)cccc2-c2ccccc2)c2ccc(-c5ccc6c7cccc8cccc(c9cccc5c96)c87)cc2B4c2cc(-c4ccc5c6cccc7cccc(c8cccc4c85)c76)ccc2N3CCc2c(-c3ccccc3)cccc2-c2ccccc2)cc1 ; c1ccc(-c2ccc(N(Cc3cc4c5c(c3)N(CCc3c(-c6ccccc6)cccc3-c3ccccc3)c3cc(-c6ccc7c8cccc9cccc(c%10cccc6c%107)c98)ccc3B5c3ccc(-c5ccc6c7cccc8cccc(c9cccc5c96)c87)cc3N4CCc3c(-c4ccccc4)cccc3-c3ccccc3)c3ccc(-c4ccccc4)cc3)cc2)cc1] 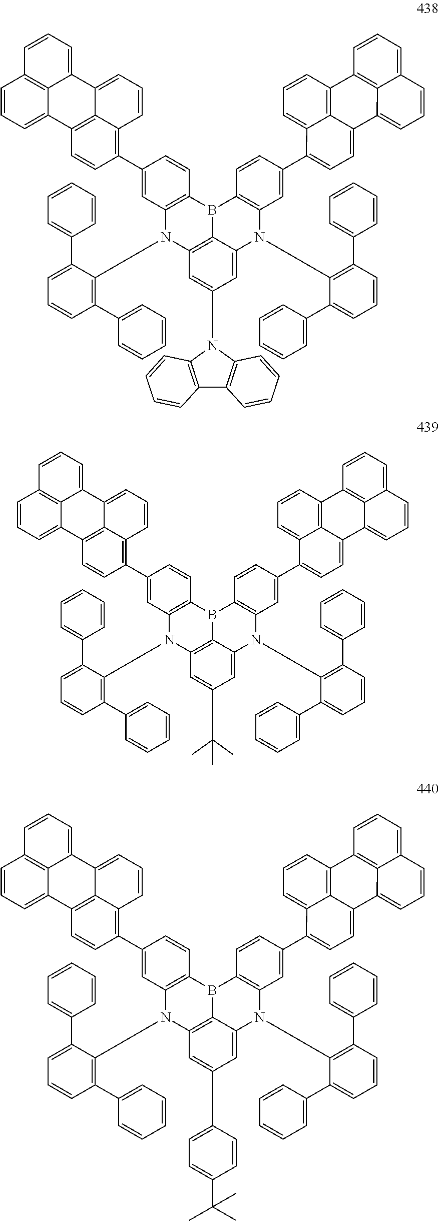 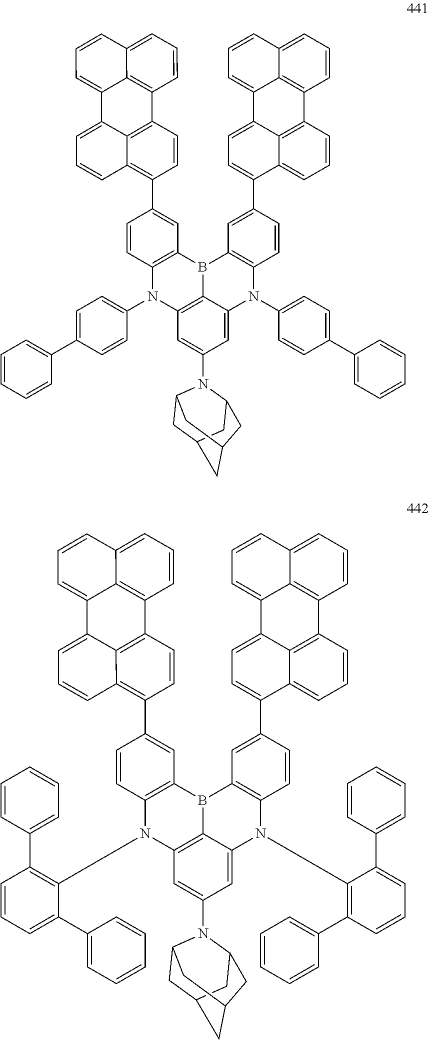 [SMILES: c1ccc(-c2ccc(N3c4ccc(-c5ccc6c7cccc8cccc(c9cccc5c96)c87)cc4B4c5cc(-c6ccc7c8cccc9cccc(c%10cccc6c%107)c98)ccc5N(c5ccc(-c6ccccc6)cc5)c5cc(N6C7CC8CC(C7)CC6C8)cc3c54)cc2)cc1 ; c1ccc(-c2cccc(-c3ccccc3)c2CCN2c3ccc(-c4ccc5c6cccc7cccc(c8cccc4c85)c76)cc3B3c4cc(-c5ccc6c7cccc8cccc(c9cccc5c96)c87)ccc4N(CCc4c(-c5ccccc5)cccc4-c4ccccc4)c4cc(N5C6CC7CC(C6)CC5C7)cc2c43)cc1] 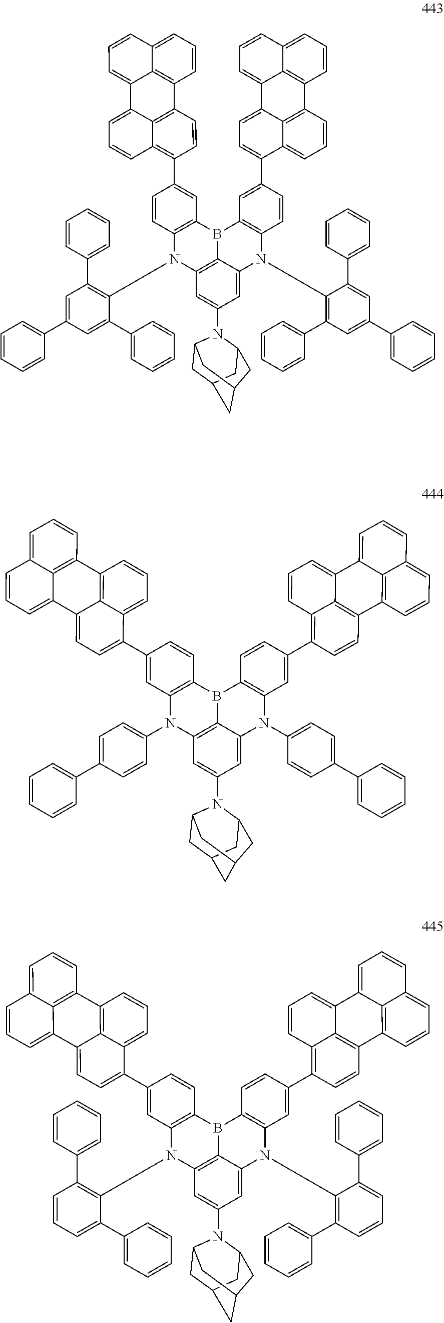 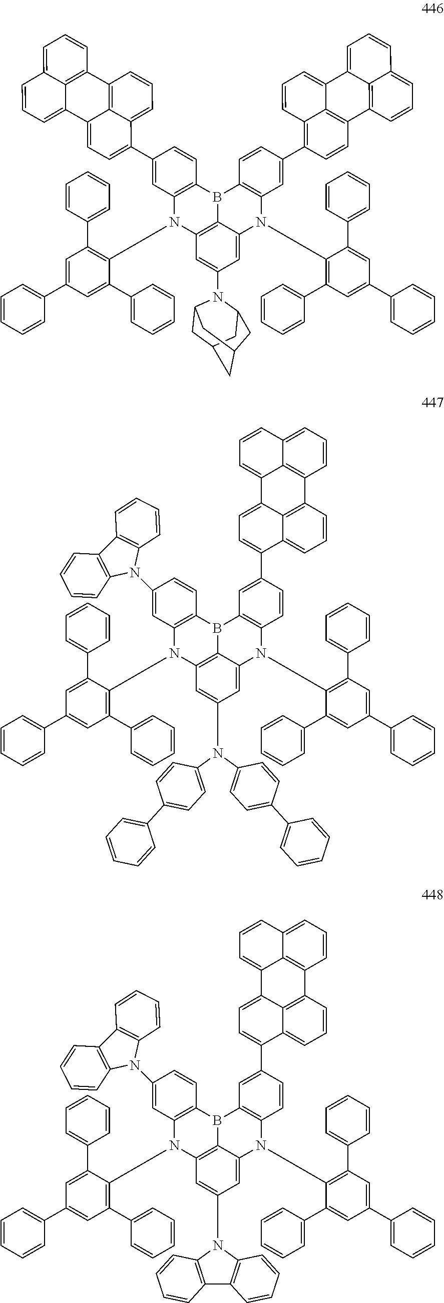 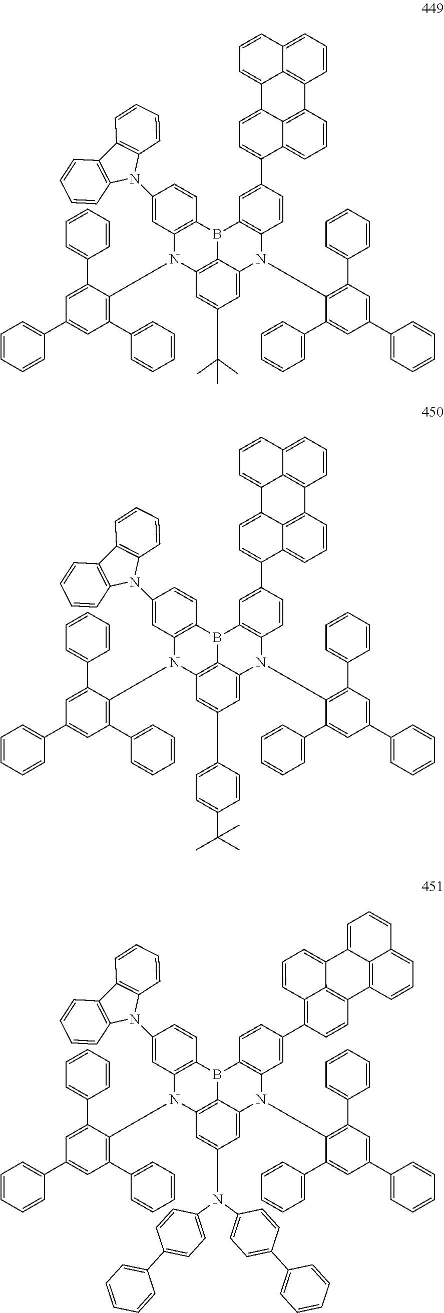 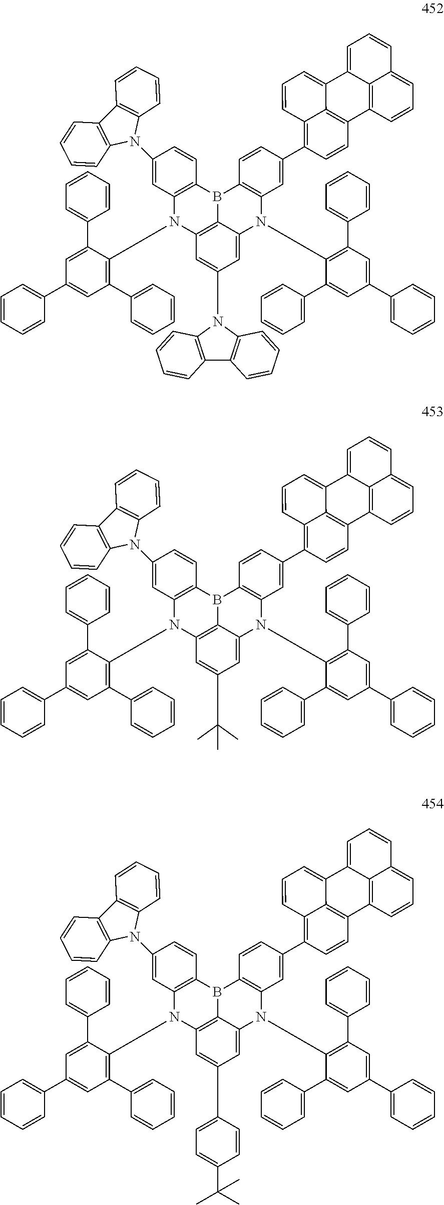 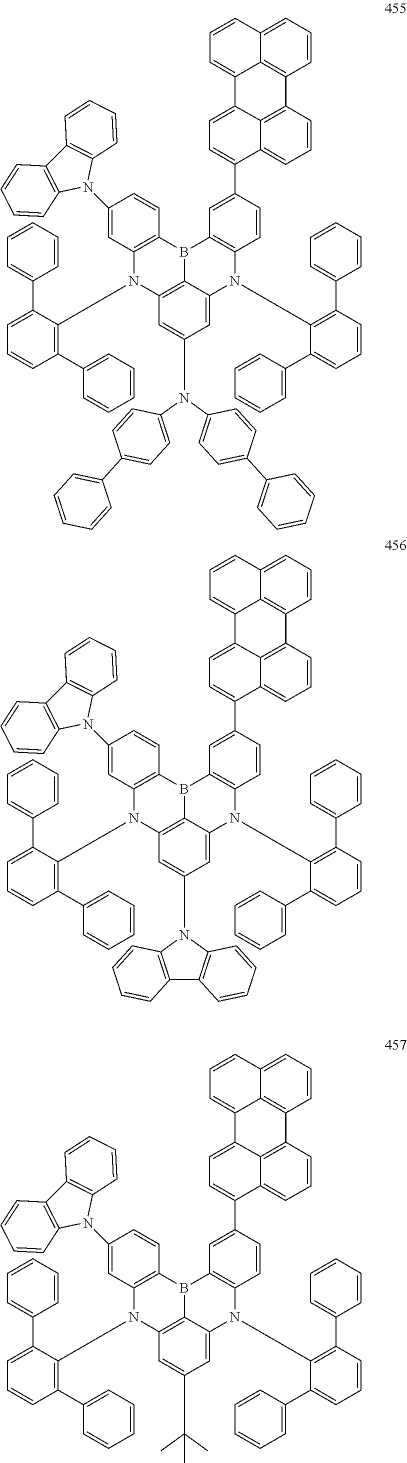 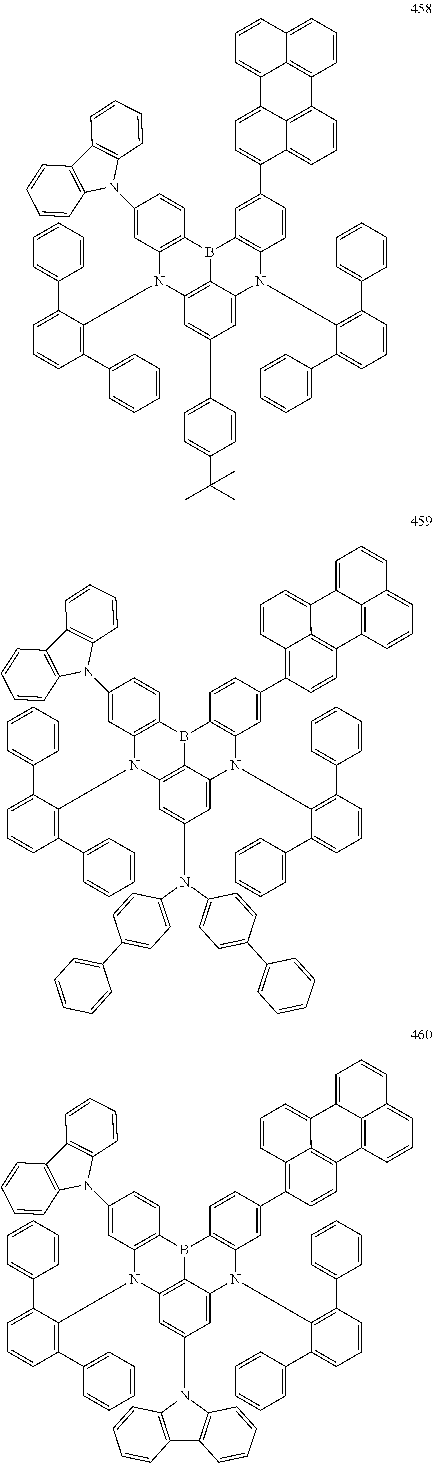 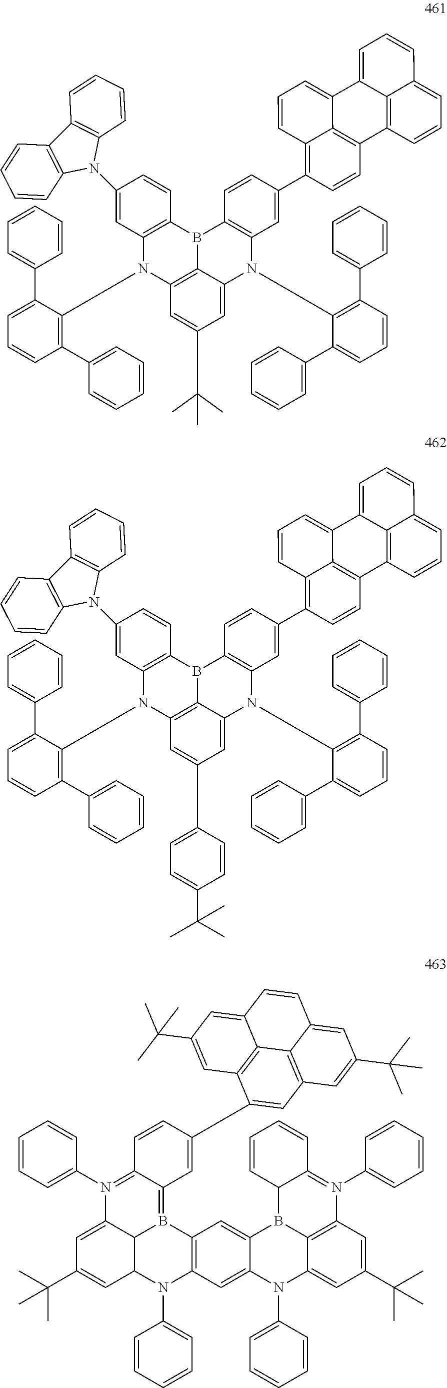 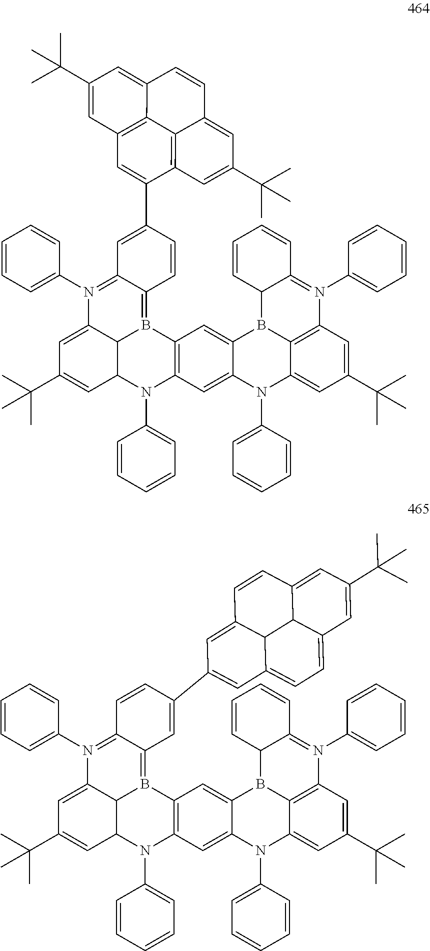 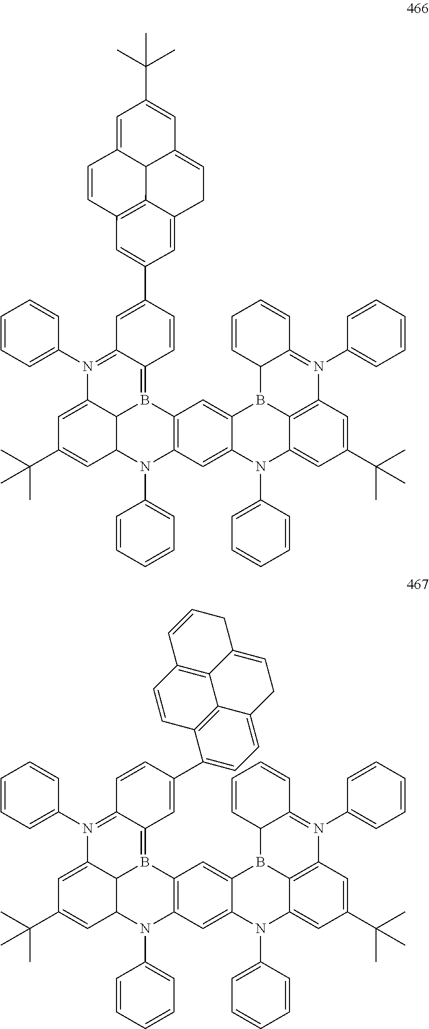 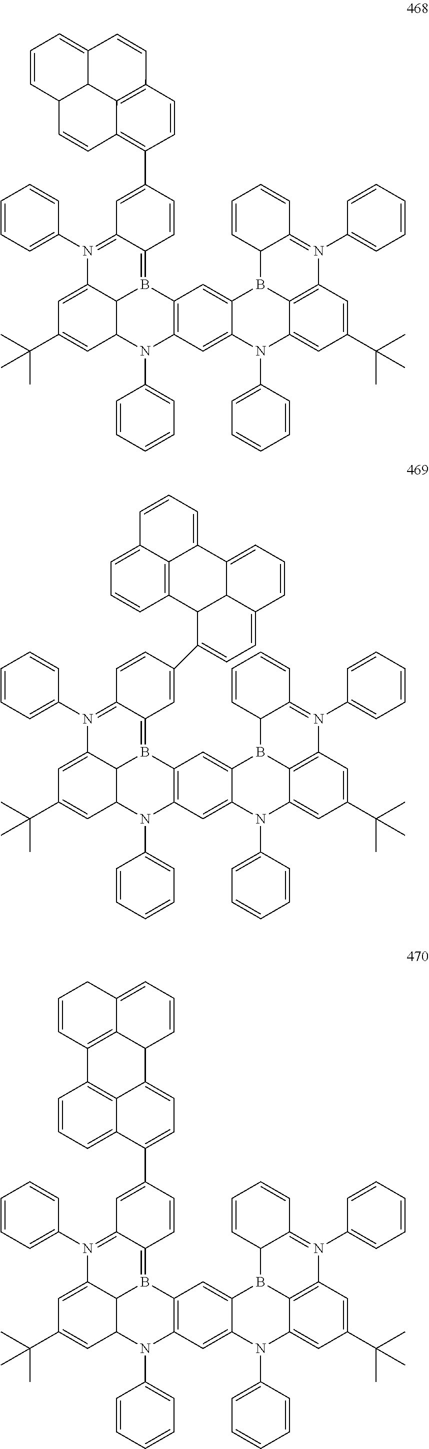 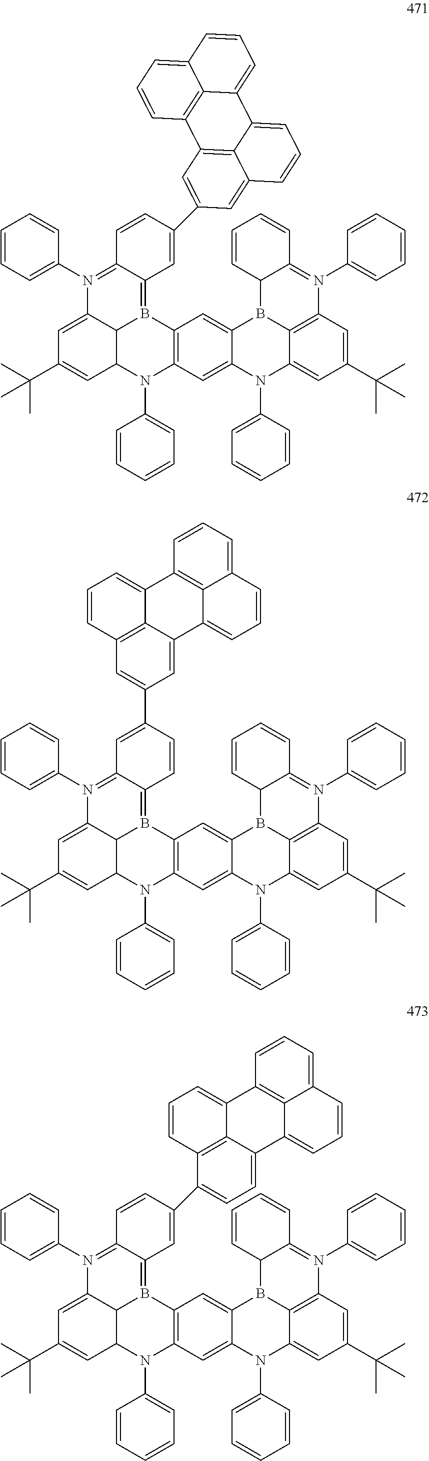 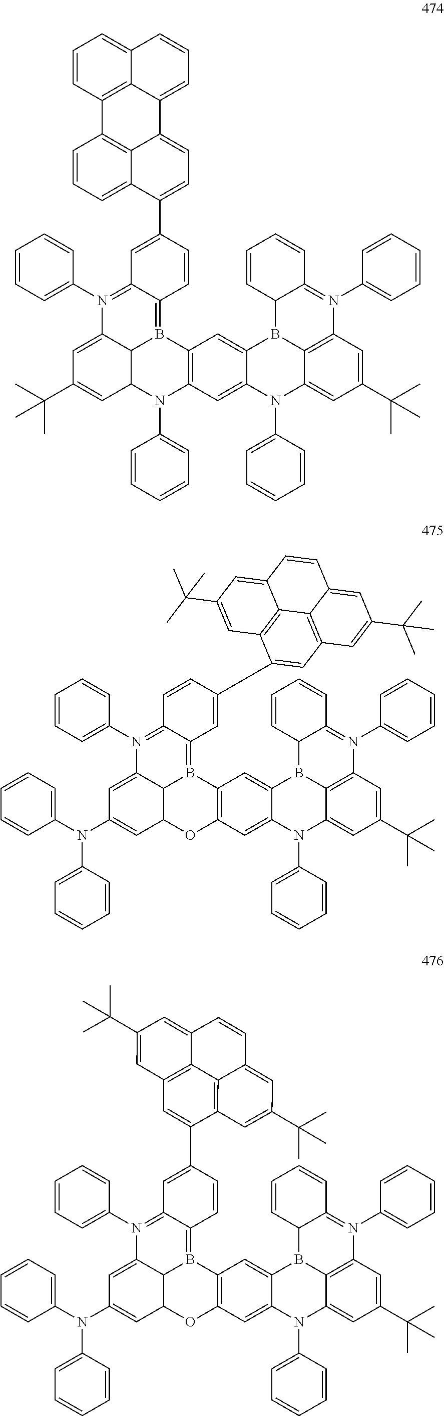 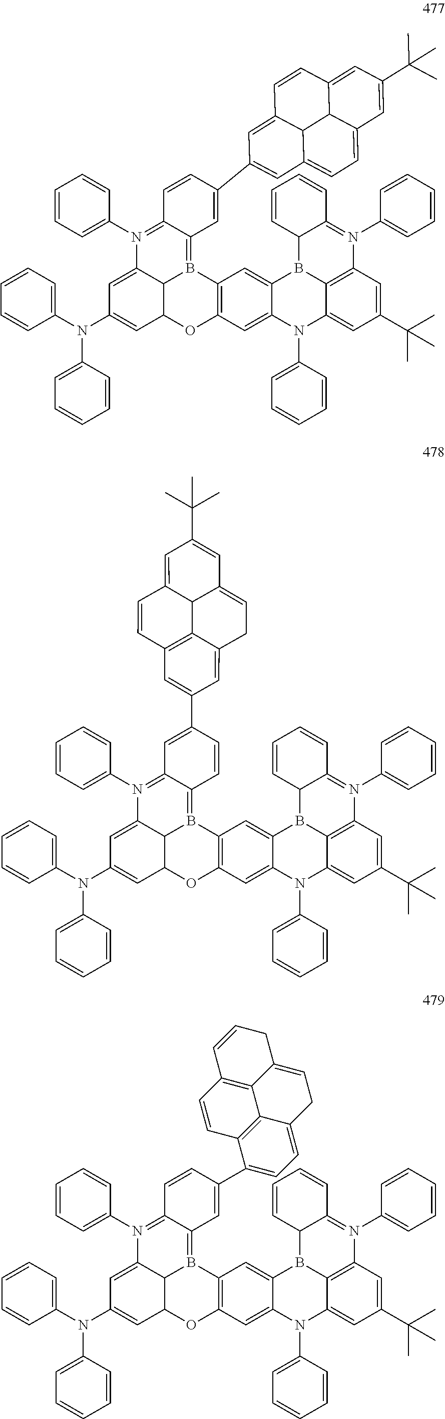 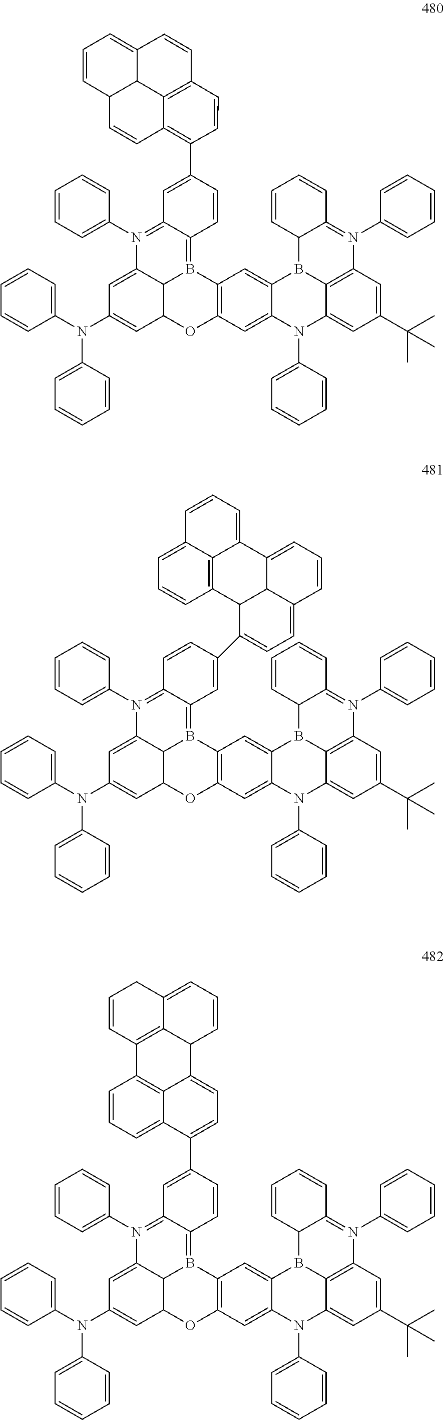 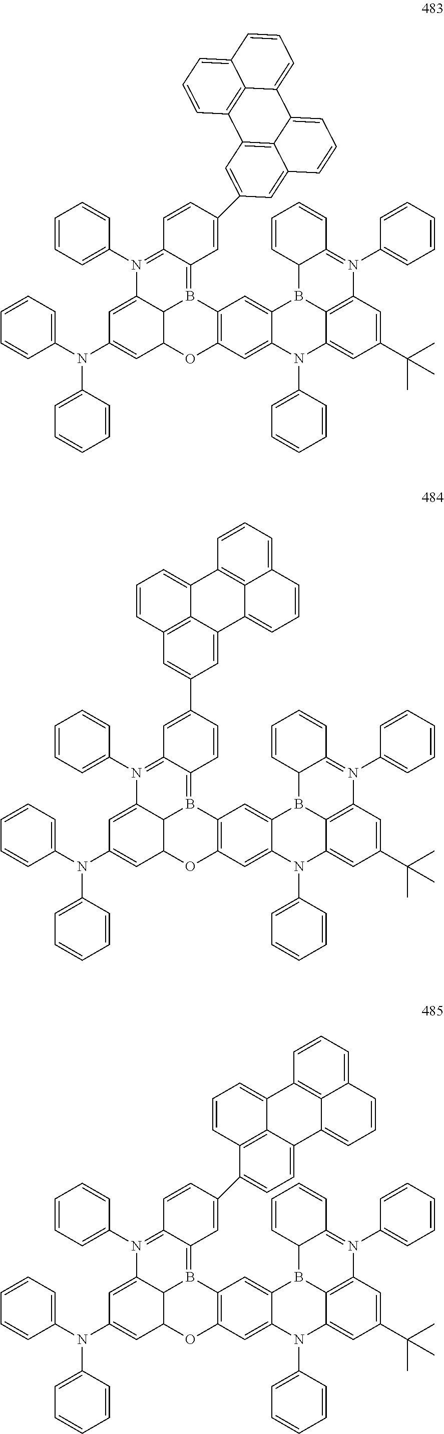 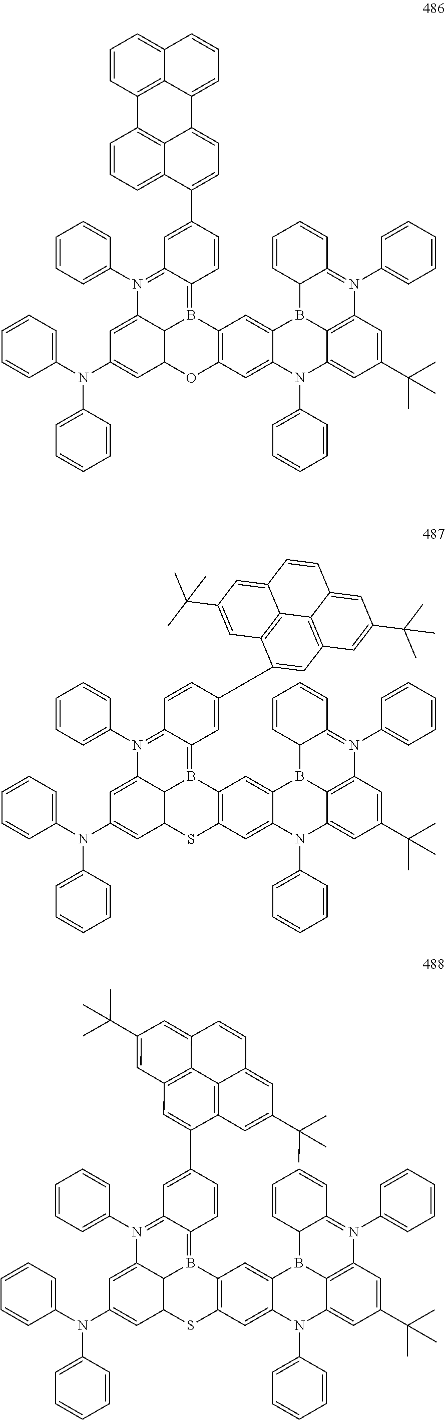 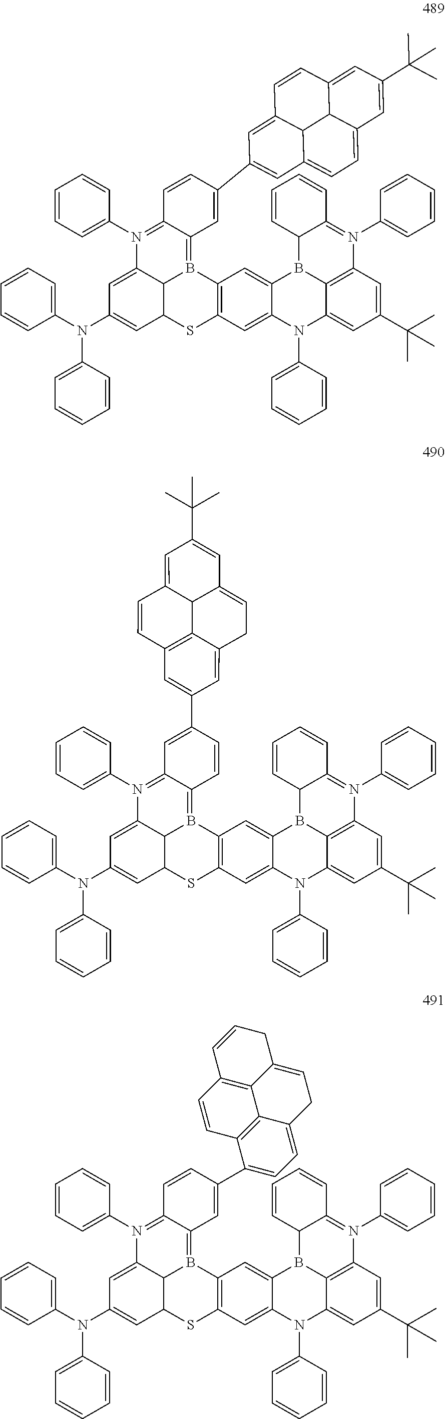 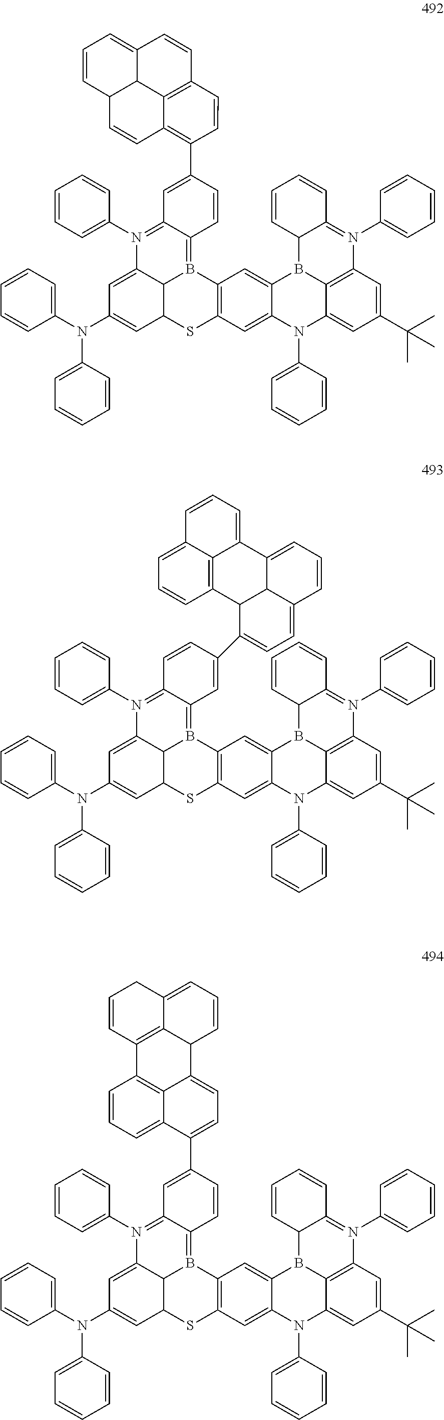 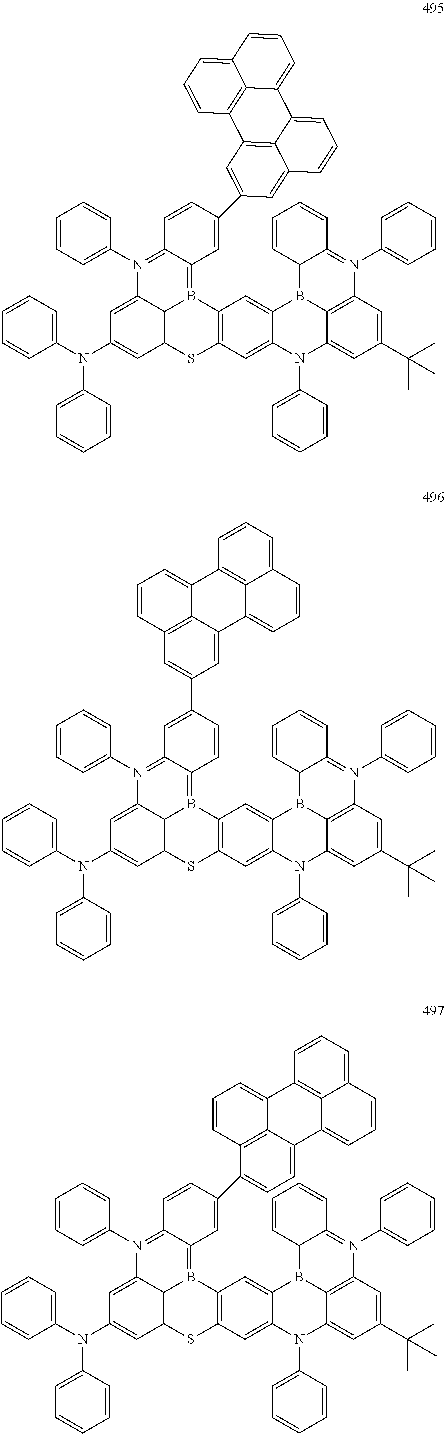 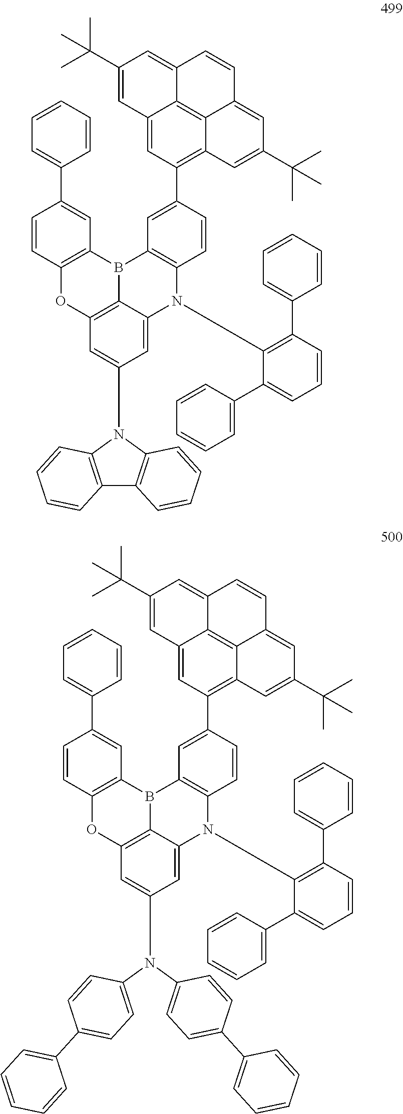 [SMILES: CC(C)(C)c1cc2ccc3cc(C(C)(C)C)cc4c(-c5ccc6c(c5)B5c7cc(-c8ccccc8)ccc7Oc7cc(Cn8c9ccccc9c9ccccc98)cc(c75)N6CCc5c(-c6ccccc6)cccc5-c5ccccc5)cc(c1)c2c34 ; CC(C)(C)c1cc2ccc3cc(C(C)(C)C)cc4c(-c5ccc6c(c5)B5c7cc(-c8ccccc8)ccc7Oc7cc(CN(c8ccc(-c9ccccc9)cc8)c8ccc(-c9ccccc9)cc8)cc(c75)N6CCc5c(-c6ccccc6)cccc5-c5ccccc5)cc(c1)c2c34] 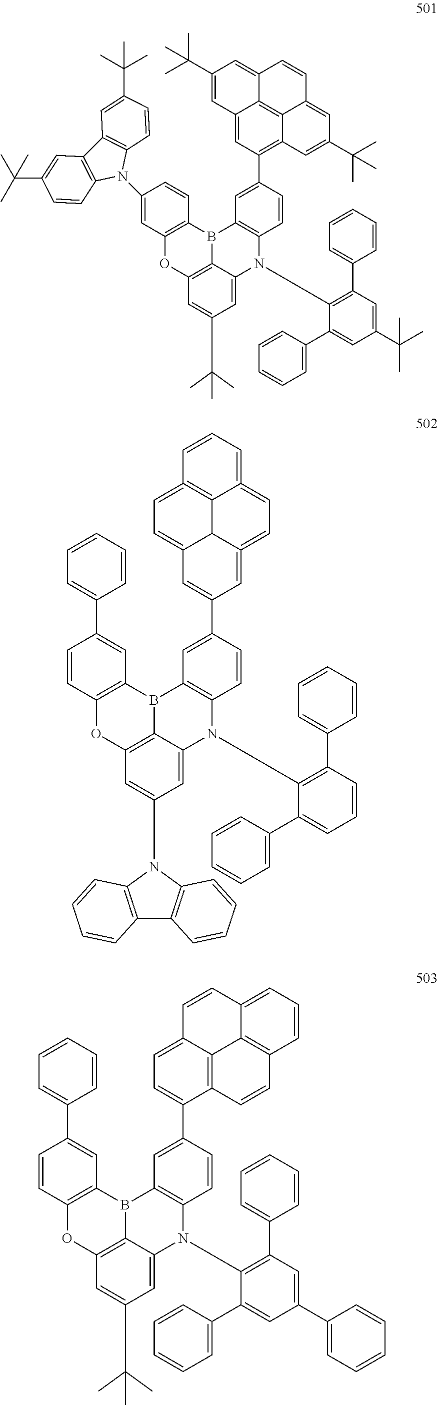 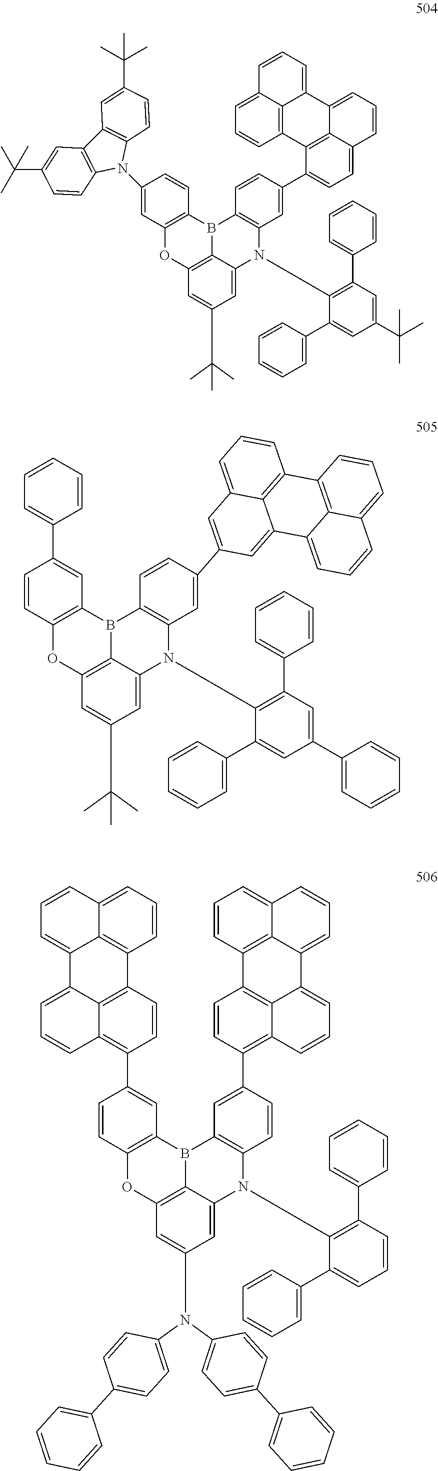 [SMILES: CC(C)(C)Cc1cc2c3c(c1)N(CCc1c(-c4ccccc4)cc(C(C)(C)C)cc1-c1ccccc1)c1cc(-c4ccc5cccc6c7cccc8cccc(c4c56)c87)ccc1B3c1ccc(-n3c4ccc(C(C)(C)C)cc4c4cc(C(C)(C)C)ccc43)cc1O2 ; CC(C)(C)Cc1cc2c3c(c1)N(CCc1c(-c4ccccc4)cc(-c4ccccc4)cc1-c1ccccc1)c1cc(-c4cc5cccc6c7cccc8cccc(c(c4)c56)c87)ccc1B3c1cc(-c3ccccc3)ccc1O2 ; c1ccc(-c2ccc(N(Cc3cc4c5c(c3)N(CCc3c(-c6ccccc6)cccc3-c3ccccc3)c3ccc(-c6ccc7c8cccc9cccc(c%10cccc6c%107)c98)cc3B5c3cc(-c5ccc6c7cccc8cccc(c9cccc5c96)c87)ccc3O4)c3ccc(-c4ccccc4)cc3)cc2)cc1] 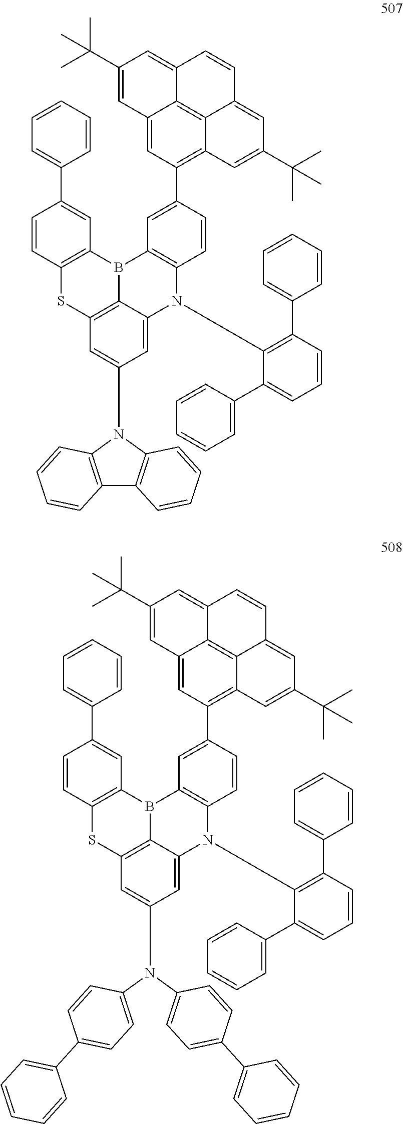 [SMILES: CC(C)(C)c1cc2ccc3cc(C(C)(C)C)cc4c(-c5ccc6c(c5)B5c7cc(-c8ccccc8)ccc7Sc7cc(Cn8c9ccccc9c9ccccc98)cc(c75)N6CCc5c(-c6ccccc6)cccc5-c5ccccc5)cc(c1)c2c34 ; CC(C)(C)c1cc2ccc3cc(C(C)(C)C)cc4c(-c5ccc6c(c5)B5c7cc(-c8ccccc8)ccc7Sc7cc(CN(c8ccc(-c9ccccc9)cc8)c8ccc(-c9ccccc9)cc8)cc(c75)N6CCc5c(-c6ccccc6)cccc5-c5ccccc5)cc(c1)c2c34] 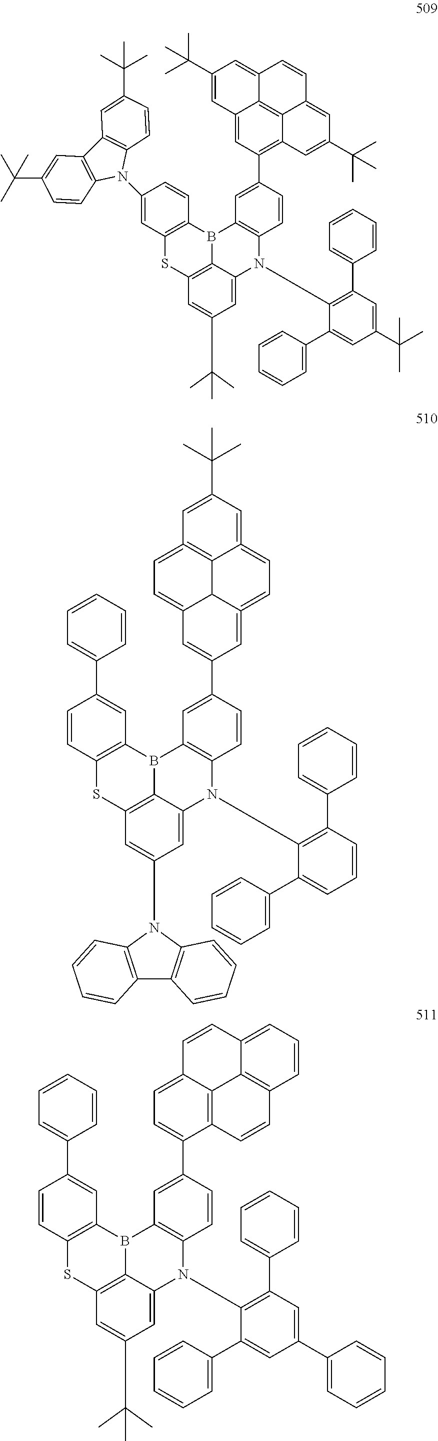 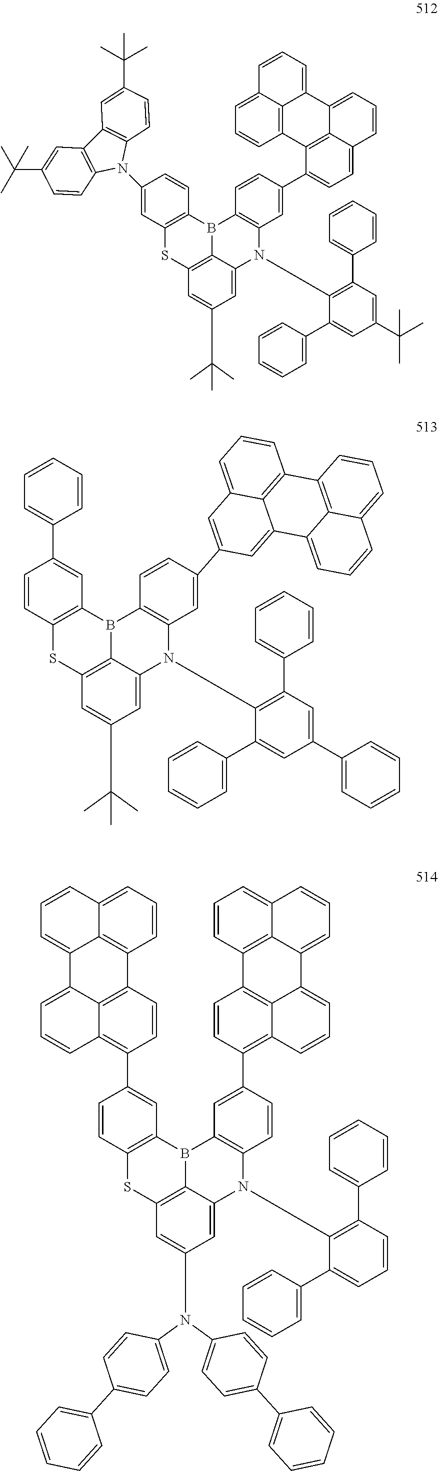 [SMILES: CC(C)(C)Cc1cc2c3c(c1)N(CCc1c(-c4ccccc4)cc(C(C)(C)C)cc1-c1ccccc1)c1cc(-c4ccc5cccc6c7cccc8cccc(c4c56)c87)ccc1B3c1ccc(-n3c4ccc(C(C)(C)C)cc4c4cc(C(C)(C)C)ccc43)cc1S2 ; CC(C)(C)Cc1cc2c3c(c1)N(CCc1c(-c4ccccc4)cc(-c4ccccc4)cc1-c1ccccc1)c1cc(-c4cc5cccc6c7cccc8cccc(c(c4)c56)c87)ccc1B3c1cc(-c3ccccc3)ccc1S2 ; c1ccc(-c2ccc(N(Cc3cc4c5c(c3)N(CCc3c(-c6ccccc6)cccc3-c3ccccc3)c3ccc(-c6ccc7c8cccc9cccc(c%10cccc6c%107)c98)cc3B5c3cc(-c5ccc6c7cccc8cccc(c9cccc5c96)c87)ccc3S4)c3ccc(-c4ccccc4)cc3)cc2)cc1] 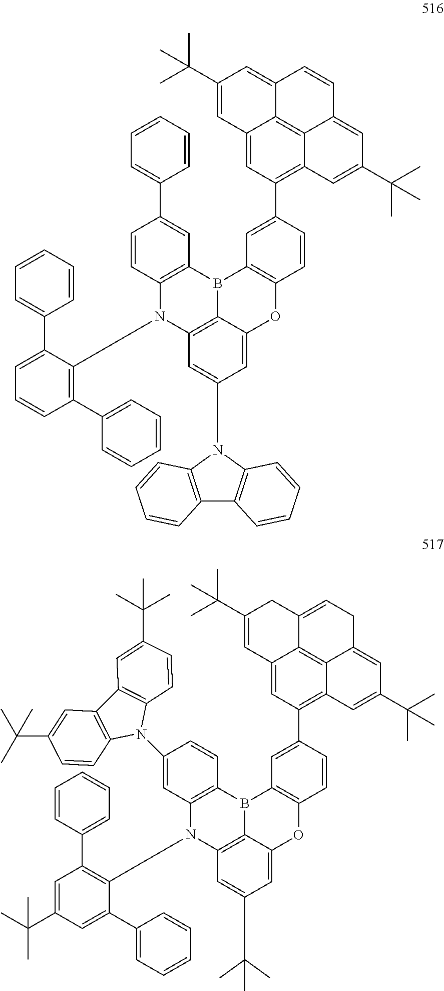 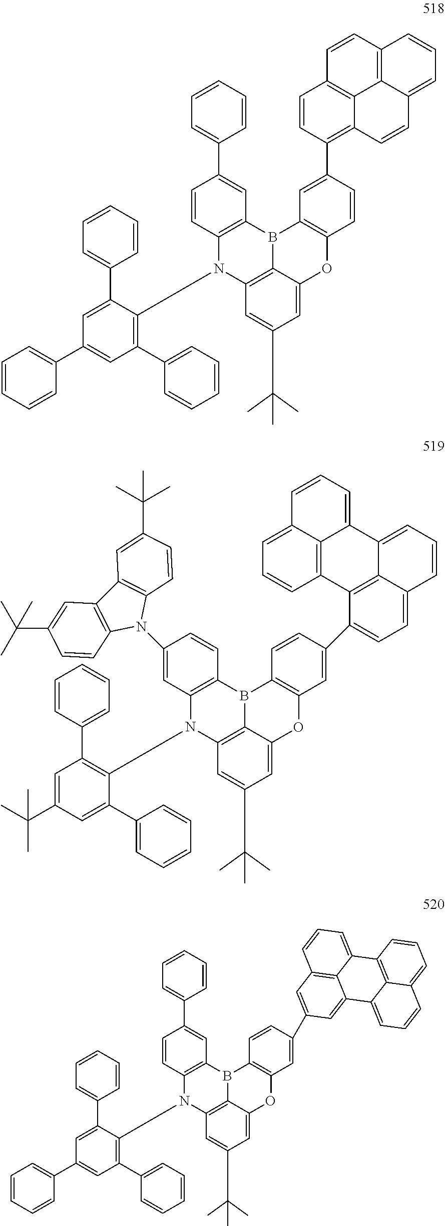 [SMILES: CC(C)(C)Cc1cc2c3c(c1)N(CCc1c(-c4ccccc4)cc(-c4ccccc4)cc1-c1ccccc1)c1ccc(-c4ccccc4)cc1B3c1cc(-c3ccc4ccc5cccc6ccc3c4c56)ccc1O2 ; CC(C)(C)Cc1cc2c3c(c1)N(CCc1c(-c4ccccc4)cc(C(C)(C)C)cc1-c1ccccc1)c1cc(-n4c5ccc(C(C)(C)C)cc5c5cc(C(C)(C)C)ccc54)ccc1B3c1ccc(-c3ccc4cccc5c6cccc7cccc(c3c45)c76)cc1O2 ; CC(C)(C)Cc1cc2c3c(c1)N(CCc1c(-c4ccccc4)cc(-c4ccccc4)cc1-c1ccccc1)c1ccc(-c4ccccc4)cc1B3c1ccc(-c3cc4cccc5c6cccc7cccc(c(c3)c45)c76)cc1O2] 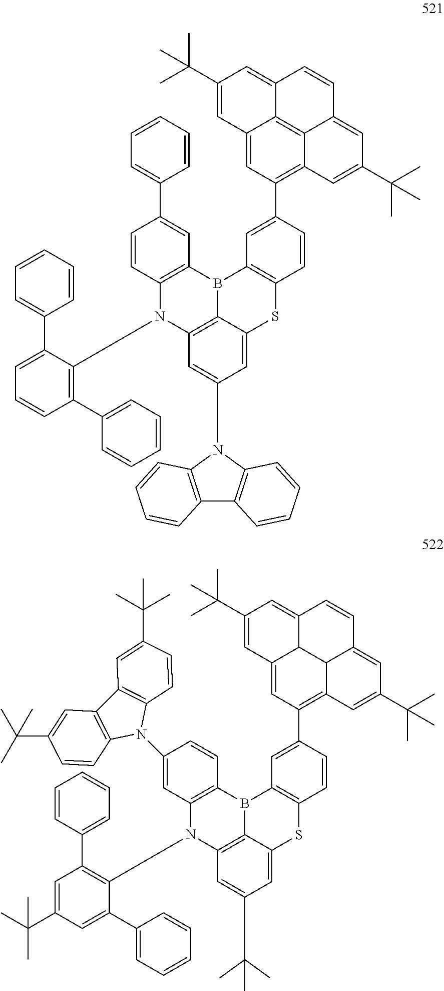 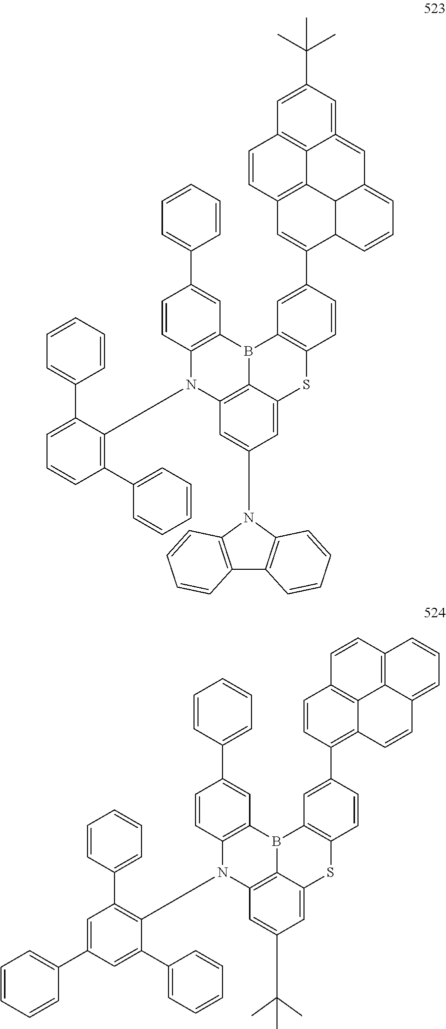 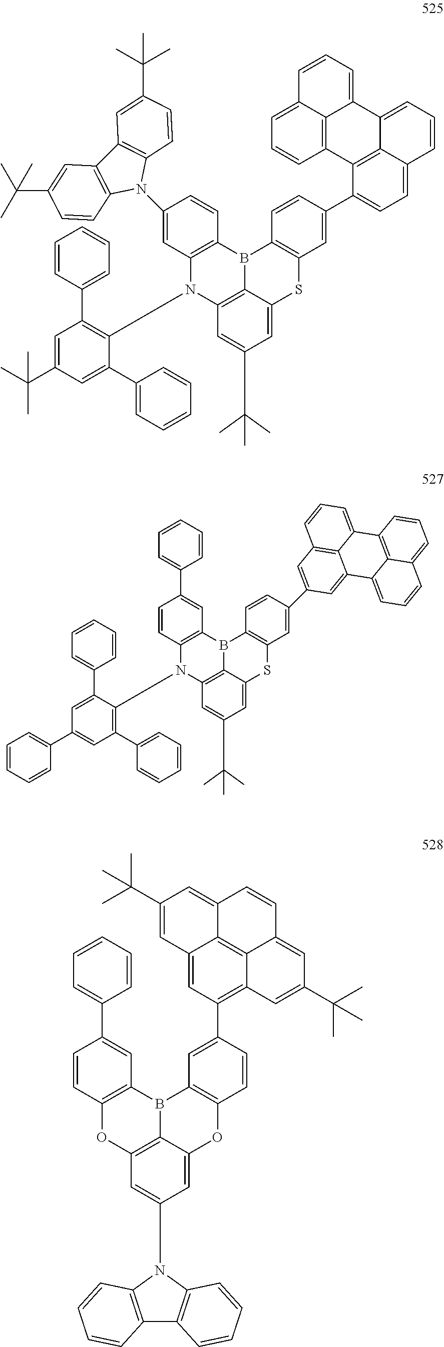 [SMILES: CC(C)(C)Cc1cc2c3c(c1)N(CCc1c(-c4ccccc4)cc(C(C)(C)C)cc1-c1ccccc1)c1cc(-n4c5ccc(C(C)(C)C)cc5c5cc(C(C)(C)C)ccc54)ccc1B3c1ccc(-c3ccc4cccc5c6cccc7cccc(c3c45)c76)cc1S2 ; CC(C)(C)Cc1cc2c3c(c1)N(CCc1c(-c4ccccc4)cc(-c4ccccc4)cc1-c1ccccc1)c1ccc(-c4ccccc4)cc1B3c1ccc(-c3cc4cccc5c6cccc7cccc(c(c3)c45)c76)cc1S2 ; CC(C)(C)c1cc2ccc3cc(C(C)(C)C)cc4c(-c5ccc6c(c5)B5c7cc(-c8ccccc8)ccc7Oc7cc(Cn8c9ccccc9c9ccccc98)cc(c75)O6)cc(c1)c2c34] 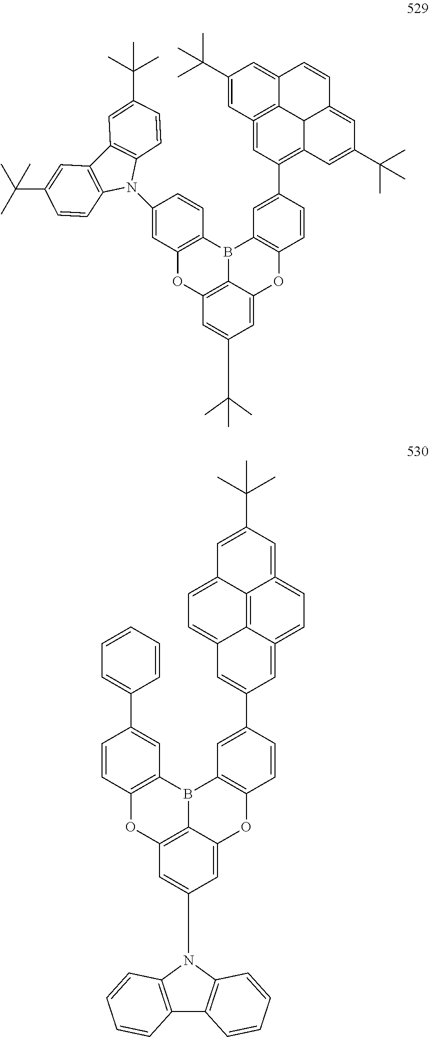 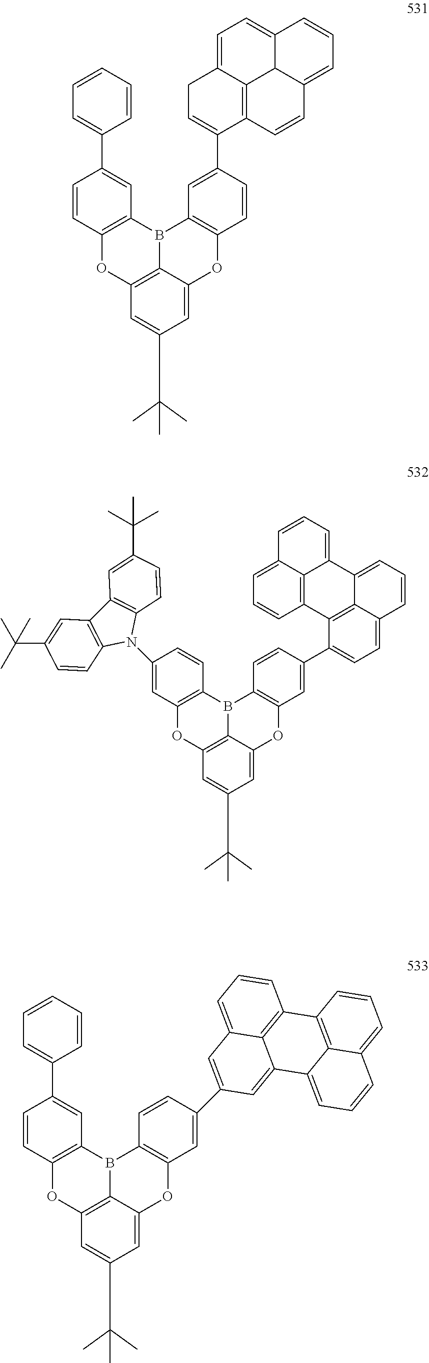 [SMILES: CC(C)(C)Cc1cc2c3c(c1)Oc1ccc(-c4ccccc4)cc1B3c1cc(C3=CCC4=CC=C5C=CC=C6C=CC3=C4C65)ccc1O2 ; CC(C)(C)Cc1cc2c3c(c1)Oc1cc(-n4c5ccc(C(C)(C)C)cc5c5cc(C(C)(C)C)ccc54)ccc1B3c1ccc(-c3ccc4cccc5c6cccc7cccc(c3c45)c76)cc1O2 ; CC(C)(C)Cc1cc2c3c(c1)Oc1ccc(-c4ccccc4)cc1B3c1ccc(-c3cc4cccc5c6cccc7cccc(c(c3)c45)c76)cc1O2] 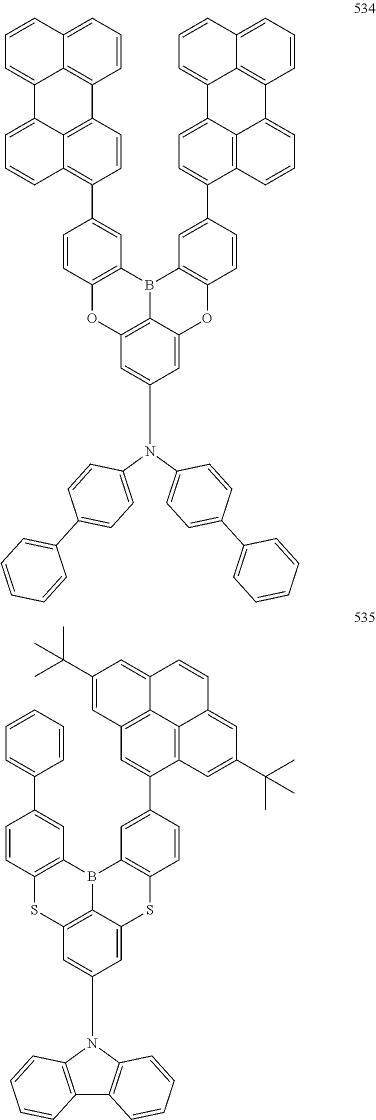 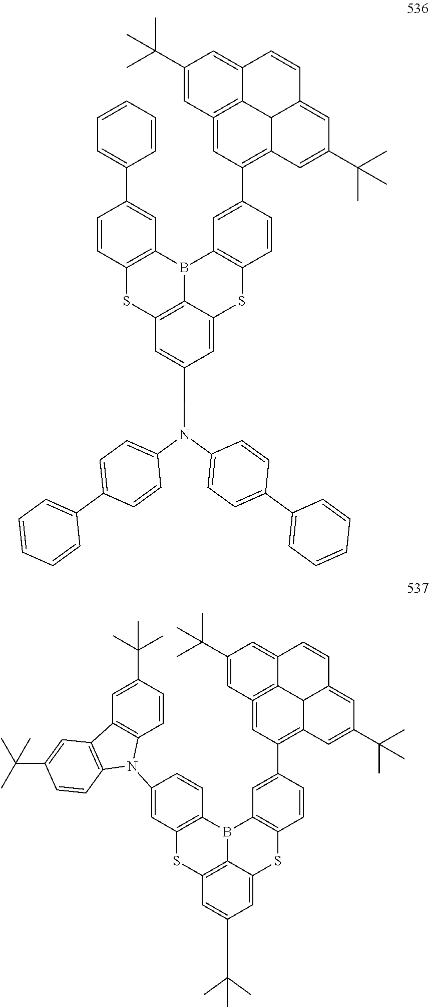 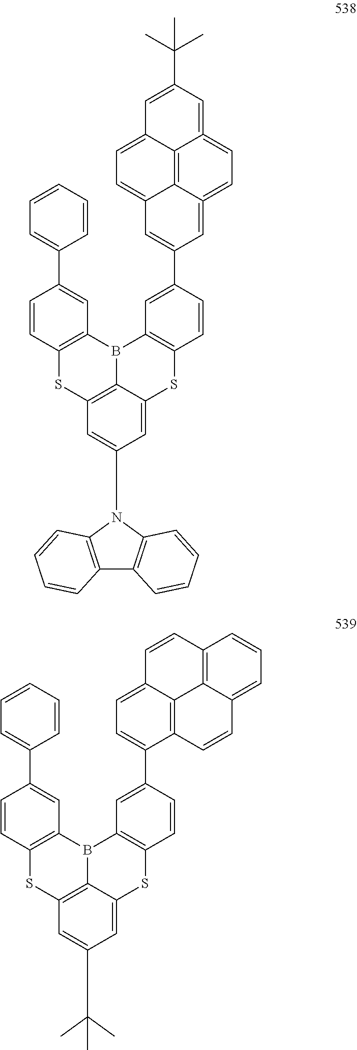 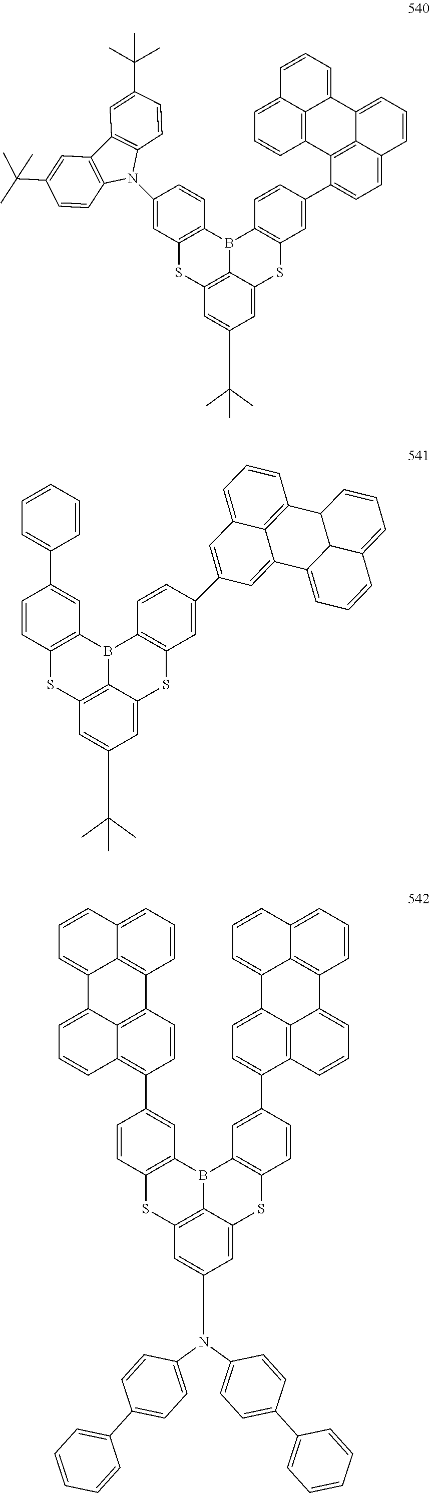 [SMILES: CC(C)(C)Cc1cc2c3c(c1)Sc1cc(-n4c5ccc(C(C)(C)C)cc5c5cc(C(C)(C)C)ccc54)ccc1B3c1ccc(-c3ccc4cccc5c6cccc7cccc(c3c45)c76)cc1S2 ; CC(C)(C)Cc1cc2c3c(c1)Sc1ccc(-c4ccccc4)cc1B3c1ccc(-c3cc4c5c(cccc5c3)C3C=CC=C5C=CC=C4C53)cc1S2 ; c1ccc(-c2ccc(N(Cc3cc4c5c(c3)Sc3ccc(-c6ccc7c8cccc9cccc(c%10cccc6c%107)c98)cc3B5c3cc(-c5ccc6c7cccc8cccc(c9cccc5c96)c87)ccc3S4)c3ccc(-c4ccccc4)cc3)cc2)cc1] 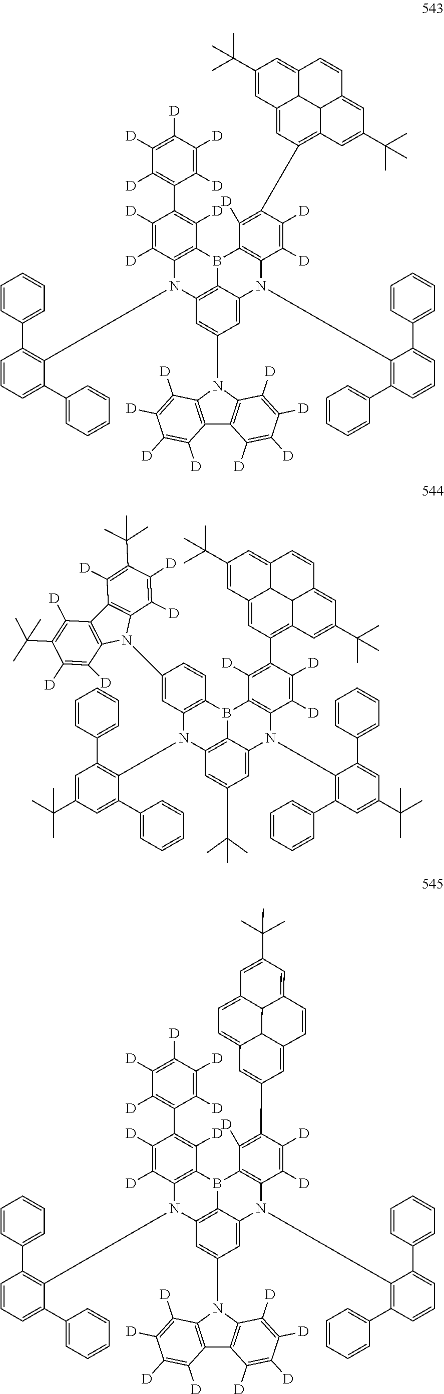 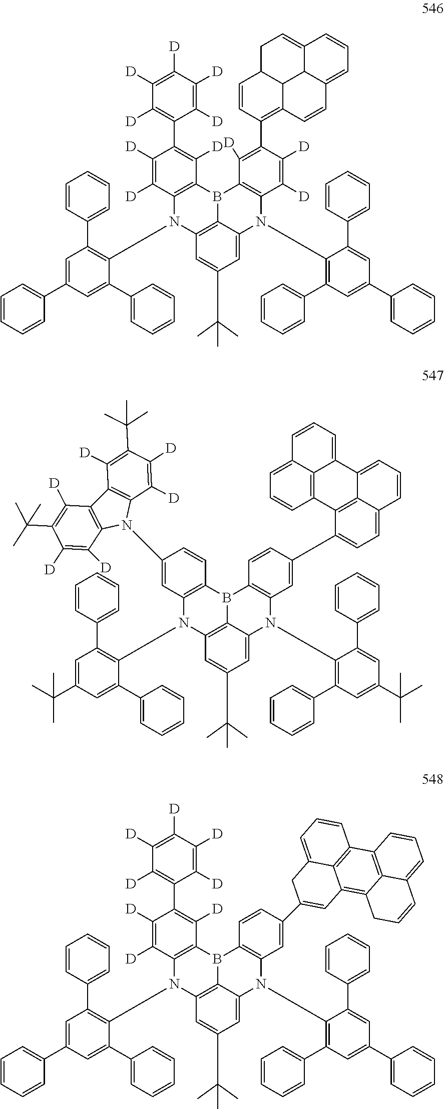 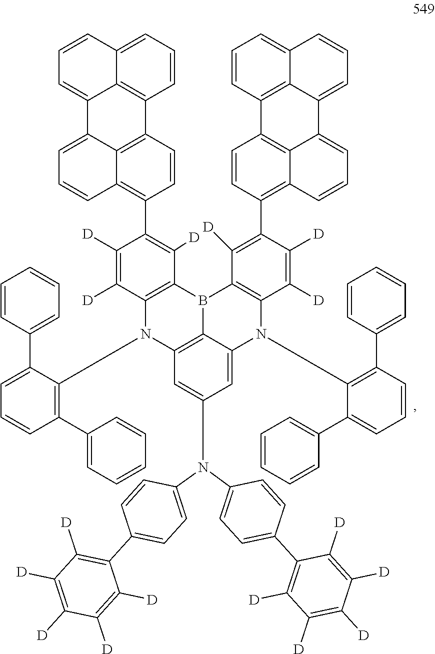 [SMILES: [2H]c1c([2H])c([2H])c(-c2ccc(N(Cc3cc4c5c(c3)N(CCc3c(-c6ccccc6)cccc3-c3ccccc3)c3c([2H])c([2H])c(-c6ccc7c8cccc9cccc(c%10cccc6c%107)c98)c([2H])c3B5c3c([2H])c(-c5ccc6c7cccc8cccc(c9cccc5c96)c87)c([2H])c([2H])c3N4CCc3c(-c4ccccc4)cccc3-c3ccccc3)c3ccc(-c4c([2H])c([2H])c([2H])c([2H])c4[2H])cc3)cc2)c([2H])c1[2H]]
wherein in Compound Group 1,
D represents a deuterium atom.

14. A polycyclic compound represented by Formula 1: 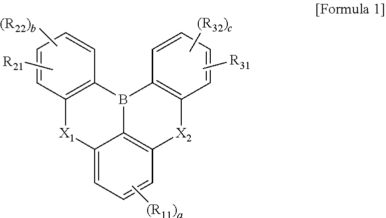
wherein in Formula 1,
a to c are each independently an integer from 0 to 3,
X₁ and X₂ are each independently O, S, or N(Rₐ),
at least one of R₂₁ and R₃₁ is each independently a group represented by Formula 2,
the remainder of R₂₁ and R₃₁ is a substituted or unsubstituted aryl group having 6 to 30 ring-forming carbon atoms or a substituted or unsubstituted heteroaryl group having 2 to 30 ring-forming carbon atoms,
Rₐ is a substituted or unsubstituted aryl group having 6 to 30 ring-forming carbon atoms or a substituted or unsubstituted heteroaryl group having 2 to 30 ring-forming carbon atoms, and is not a group represented by Formula 2,
R₁₁, R₂₂, and R₃₂ are each independently a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and
at least one hydrogen atom in Formula 1 is optionally substituted with a deuterium atom; and 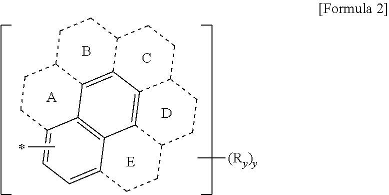
wherein in Formula 2,
at least two of A to E are each a benzene ring,
the remainder of A to E are not present,
y is an integer from 0 to 11,
R_{y} is a hydrogen atom, a deuterium atom, a halogen atom, or a substituted or unsubstituted alkyl group having 1 to 20 carbon atoms, [symbol]
represents a bond to a neighboring atom in Formula 1, and
at least one hydrogen atom in Formula 2 is optionally substituted with a deuterium atom.

15. The polycyclic compound of claim 14, wherein Formula 1 is represented by Formula 3-1 or Formula 3-2: 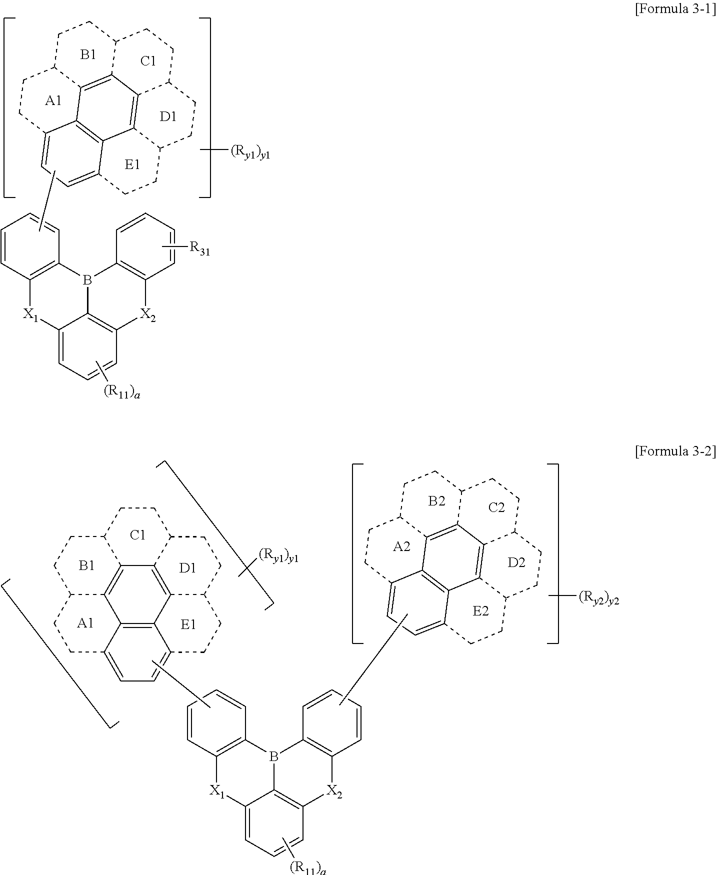
wherein in Formulas 3-1 and 3-2,
at least two of A1 to E1 are each a benzene ring,
the remainder of A1 to E1 are not present,
at least two of A2 to E2 are each a benzene ring,
the remainder of A2 to E2 are not present,
y1 and y2 are each independently an integer from 0 to 11,
R_{y1} and R_{y2} are each independently a hydrogen atom, a deuterium atom, a halogen atom, or a substituted or unsubstituted alkyl group having 1 to 20 carbon atoms,
a, R₁₁, R₃₁, X₁, and X₂ are the same as defined in Formula 1, and
at least one hydrogen atom in Formulas 3-1 and 3-2 is optionally substituted with a deuterium atom.

16. The polycyclic compound of claim 15, wherein in Formula 3-1, R₃₁ is a substituted or unsubstituted carbazole group or a substituted or unsubstituted phenyl group.

17. The polycyclic compound of claim 14, wherein Formula 1 is represented by one of Formulas 4-1 to 4-3: 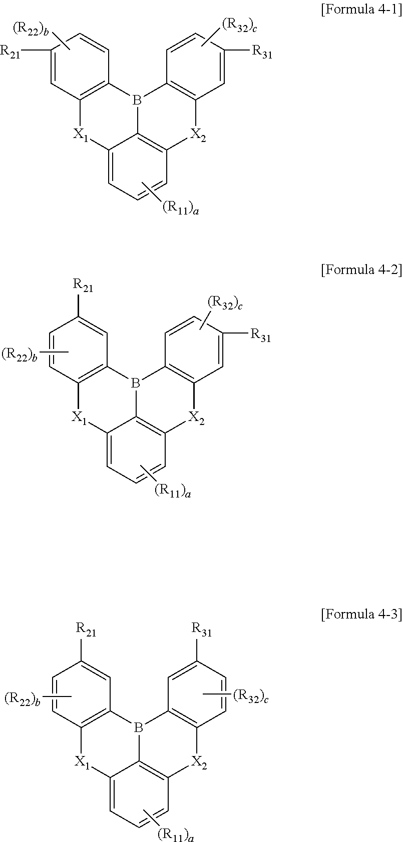
wherein in Formulas 4-1 to 4-3,
a, b, c, X₁, X₂, R₁₁, R₂₁, R₃₁, R₂₂, and R₃₂ are the same as defined in Formula 1, and
at least one hydrogen atom in Formulas 4-1 to 4-3 is optionally substituted with a deuterium atom.

18. The polycyclic compound of claim 14, wherein Formula 1 is represented by Formula 5: 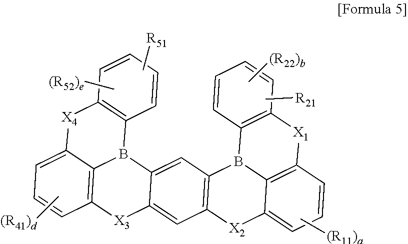
wherein in Formula 5,
at least one of R₂₁ and R₅₁ is each independently a group represented by Formula 2,
the remainder of R₂₁ and R₅₁ is a substituted or unsubstituted aryl group having 6 to 30 ring-forming carbon atoms or a substituted or unsubstituted heteroaryl group having 2 to 30 ring-forming carbon atoms,
X₃ and X₄ are each independently O, S, or N(R_{b}),
d and e are each independently an integer from 0 to 3,
R_{b} is a substituted or unsubstituted aryl group having 6 to 30 ring-forming carbon atoms or a substituted or unsubstituted heteroaryl group having 2 to 30 ring-forming carbon atoms, and is not a group represented by Formula 2,
R₄₁ and R₅₂ are each independently a hydrogen atom, a deuterium atom, a halogen atom, a cyano group, a substituted or unsubstituted amine group, a substituted or unsubstituted boron group, a substituted or unsubstituted thio group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
a, b, R₁₁, R₂₂, X₁, and X₂ are the same as defined in Formula 1, and
at least one hydrogen atom in Formula 5 is optionally substituted with a deuterium atom.

19. The polycyclic compound of claim 14, wherein a group represented by Formula 2 is represented one of Formulas D1 to D6: 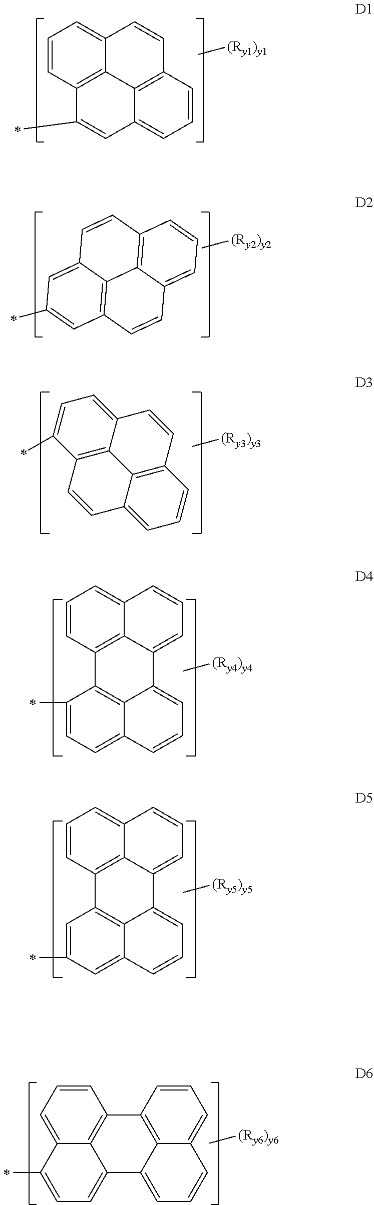
wherein in Formulas D1 to D6,
y1 to y3 are each independently an integer from 0 to 9,
y4 to y6 are each independently an integer from 0 to 11,
R_{y1} to R_{y6} are each independently a hydrogen atom, a deuterium atom, or an unsubstituted t-butyl group, [symbol]
represents a bond to a neighboring atom in Formula 1, and
at least one hydrogen atom in Formulas D1 to D6 is optionally substituted with a deuterium atom.

20. The polycyclic compound of claim 14, wherein the polycyclic compound represented by Formula 1 is selected from Compound Group 1: 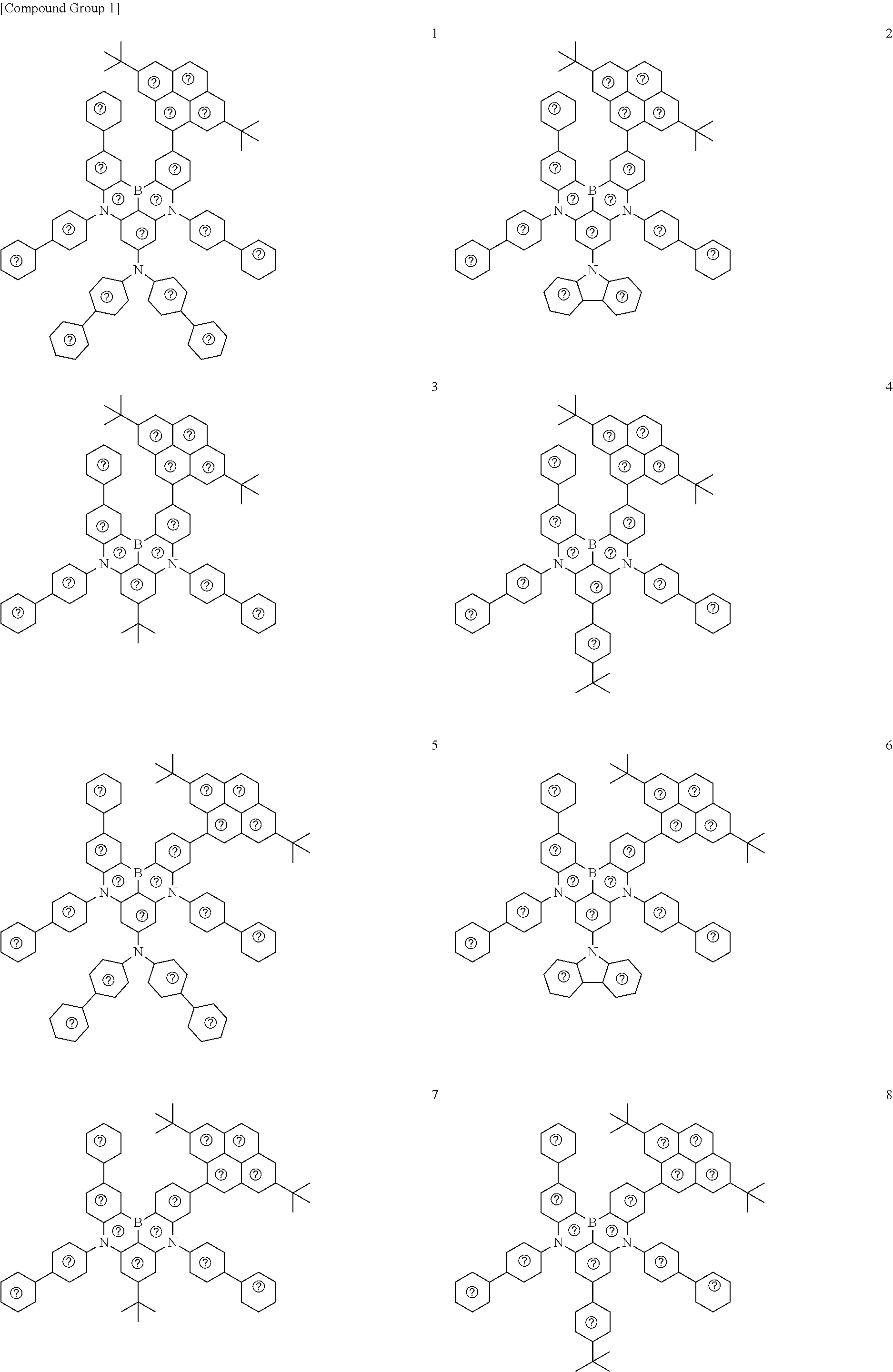 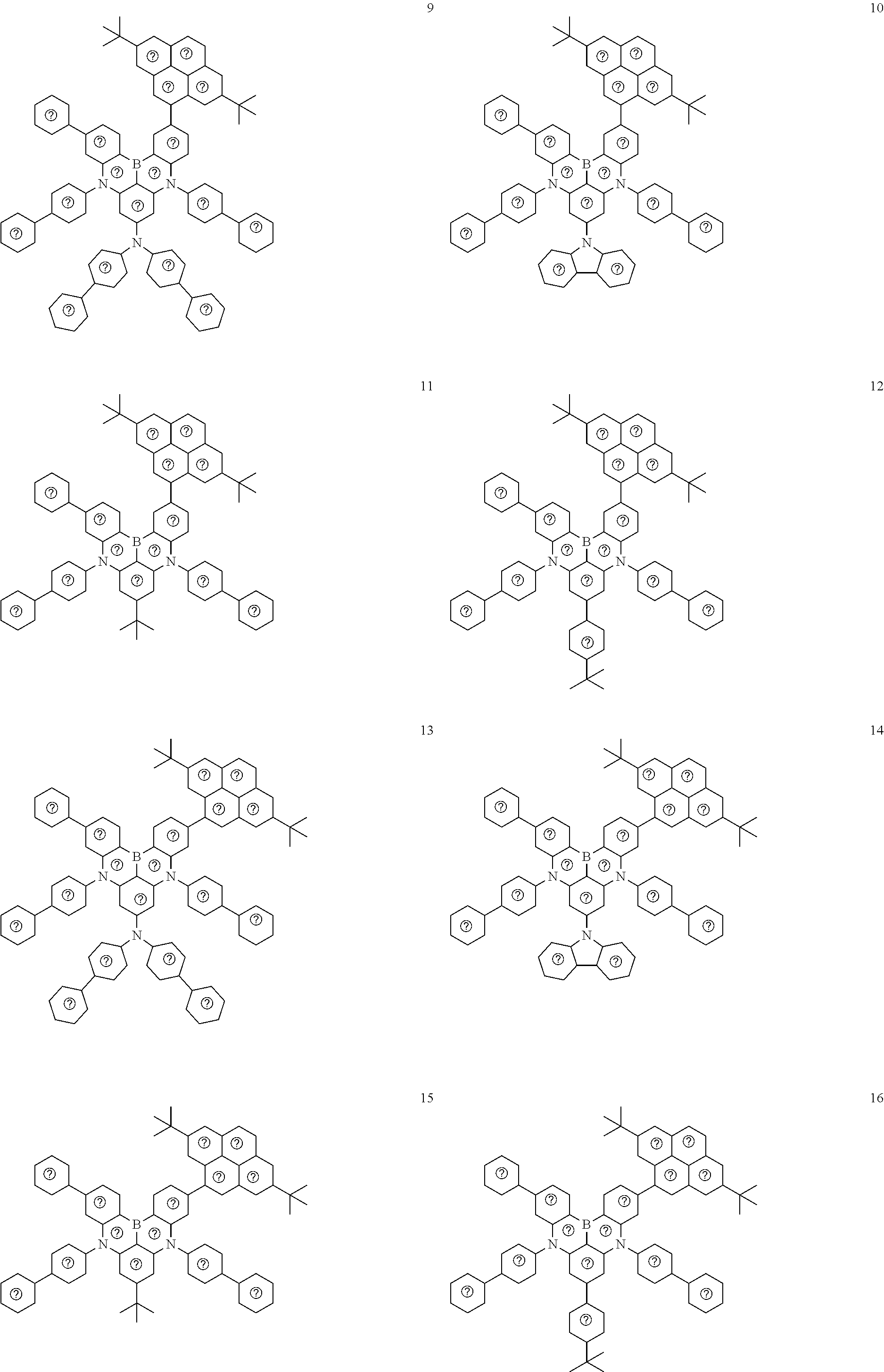 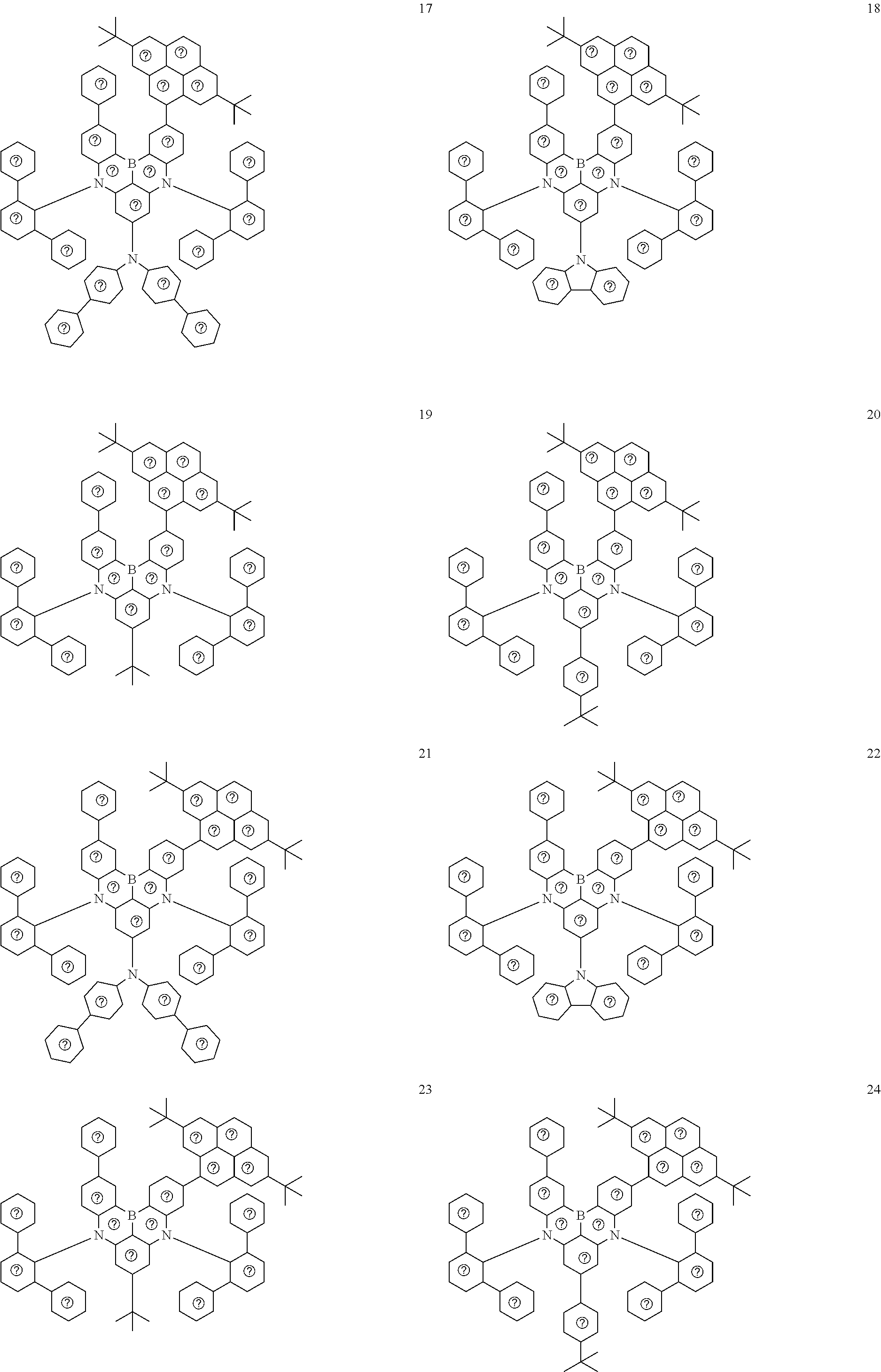 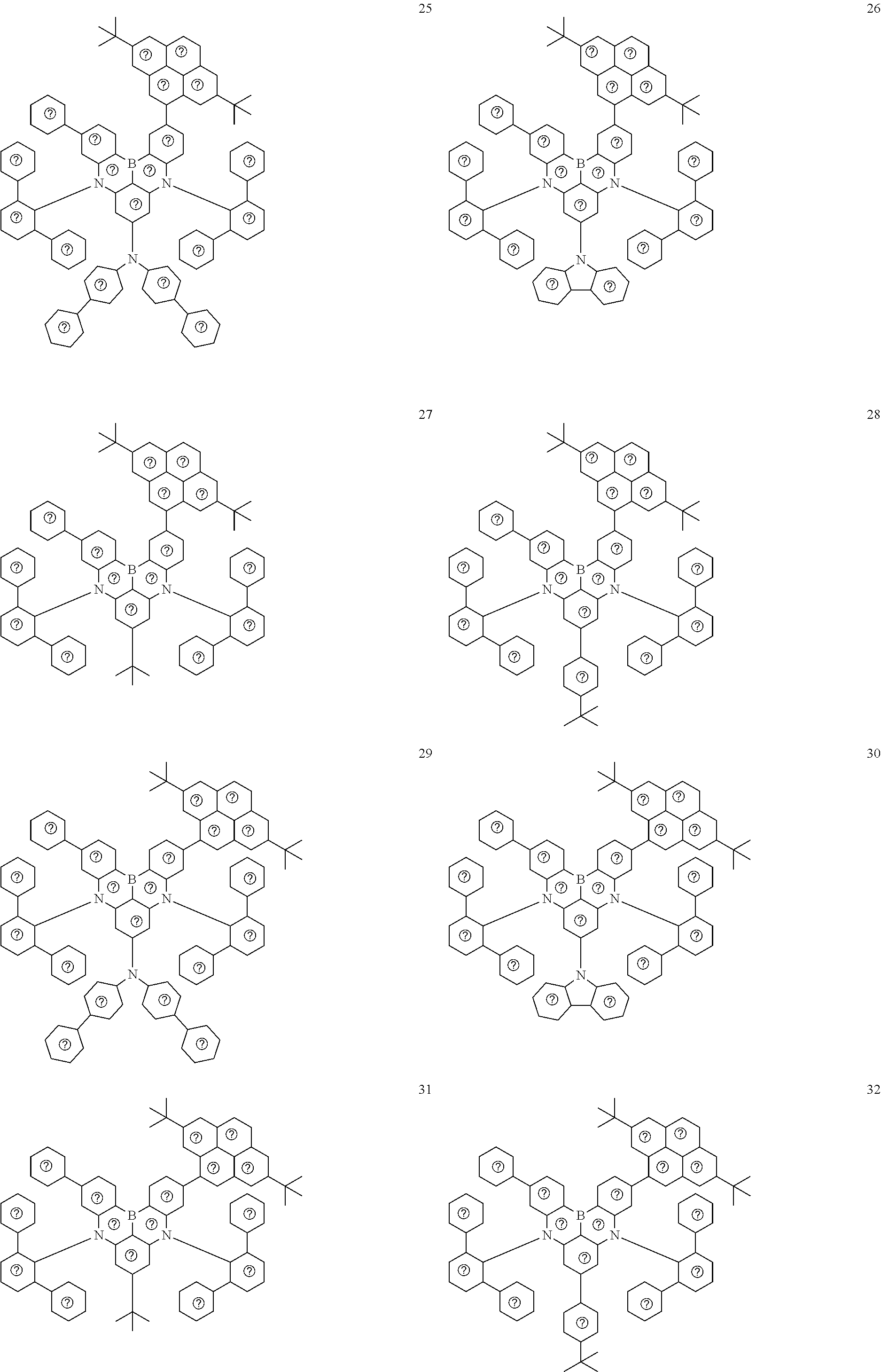 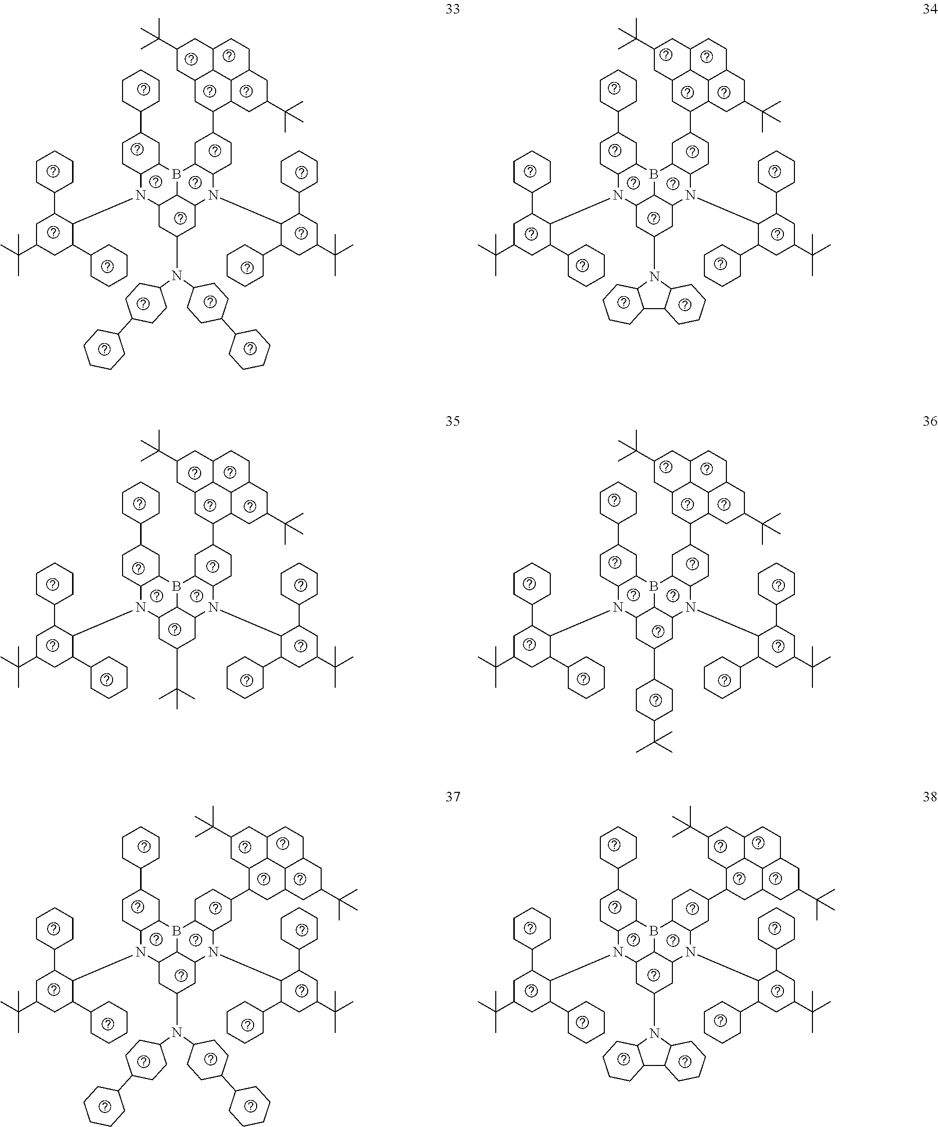 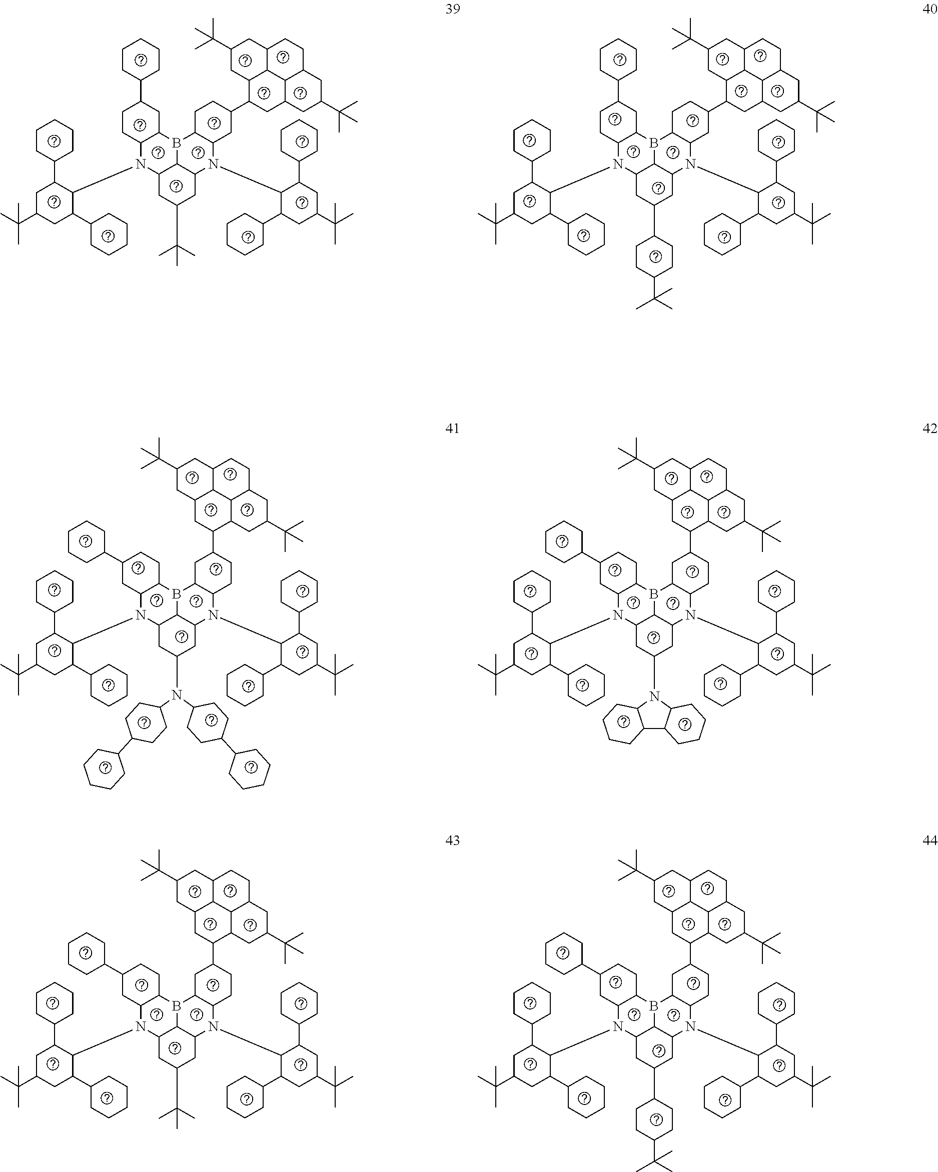 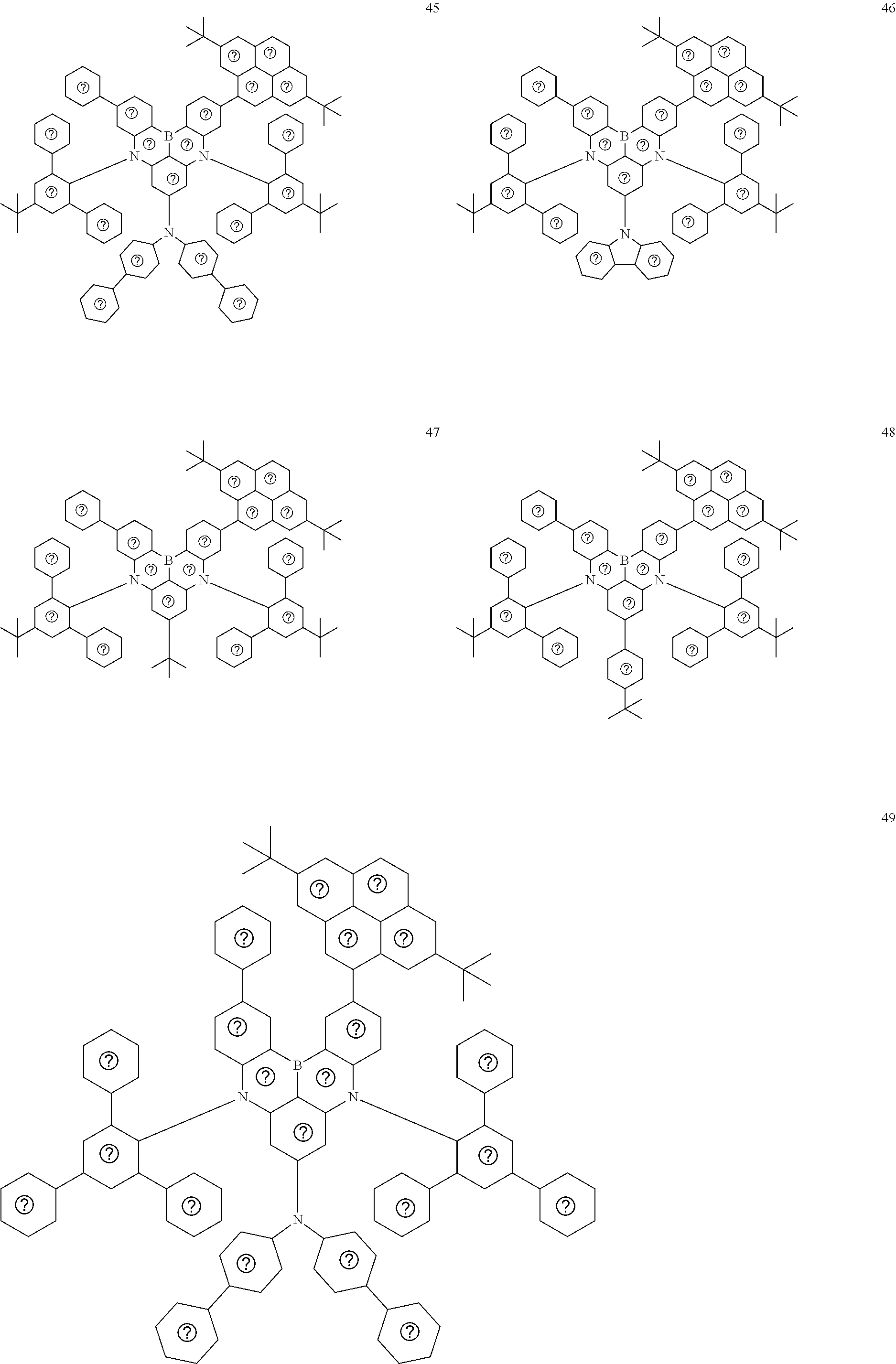 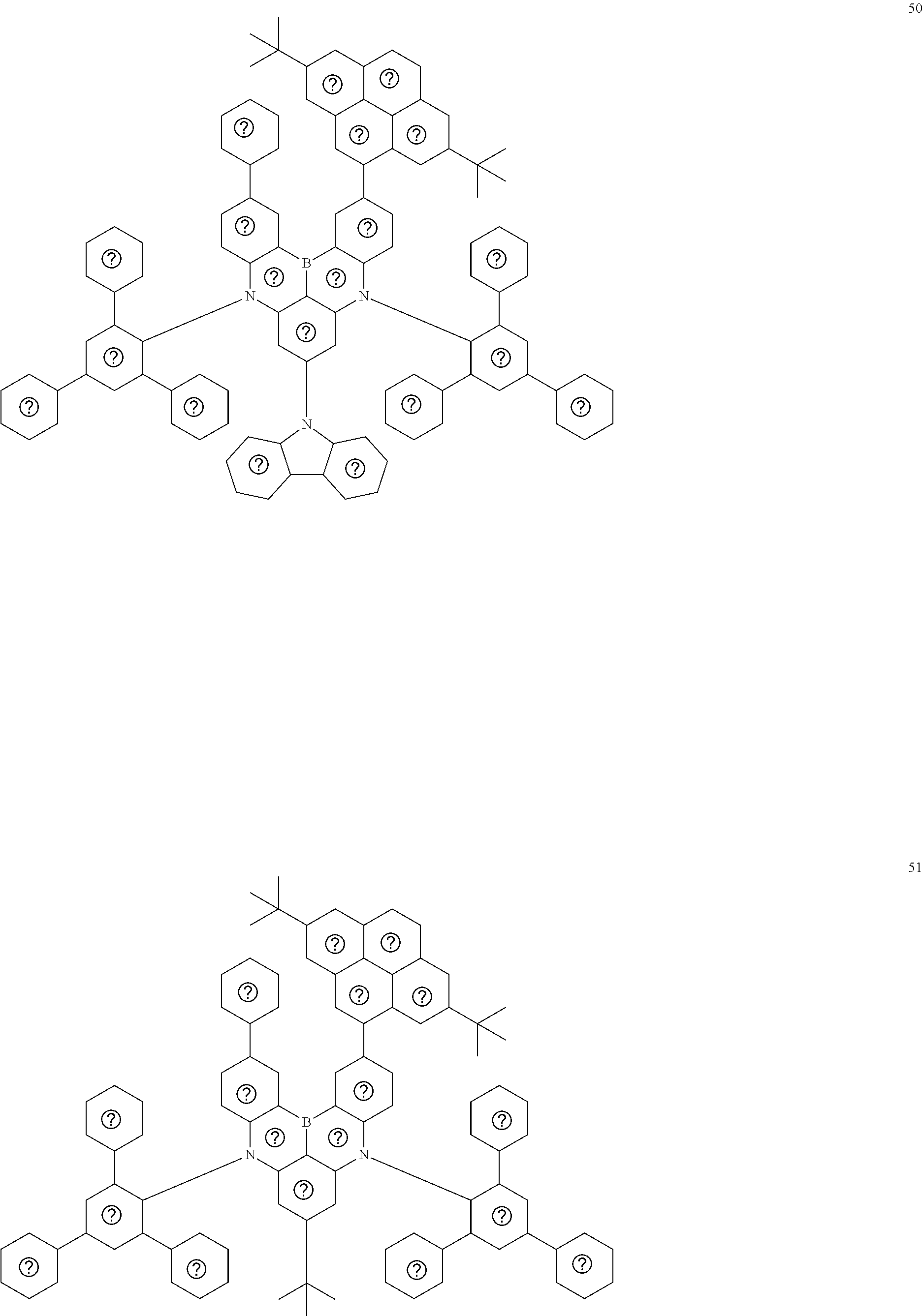 [SMILES: CC(C)(C)C1CC2CCC3CC(C(C)(C)C)CC4C(C5CCC6C(C5)B5C7CC(C8CCCCC8)CCC7N(C7C(C8CCCCC8)CC(C8CCCCC8)CC7C7CCCCC7)C7CC(N8C9CCCCC9C9CCCCC98)CC(C57)N6C5C(C6CCCCC6)CC(C6CCCCC6)CC5C5CCCCC5)CC(C1)C2C34 ; CC(C)(C)C1CC2CCC3CC(C(C)(C)C)CC4C(C5CCC6C(C5)B5C7CC(C8CCCCC8)CCC7N(C7C(C8CCCCC8)CC(C8CCCCC8)CC7C7CCCCC7)C7CC(C(C)(C)C)CC(C57)N6C5C(C6CCCCC6)CC(C6CCCCC6)CC5C5CCCCC5)CC(C1)C2C34] 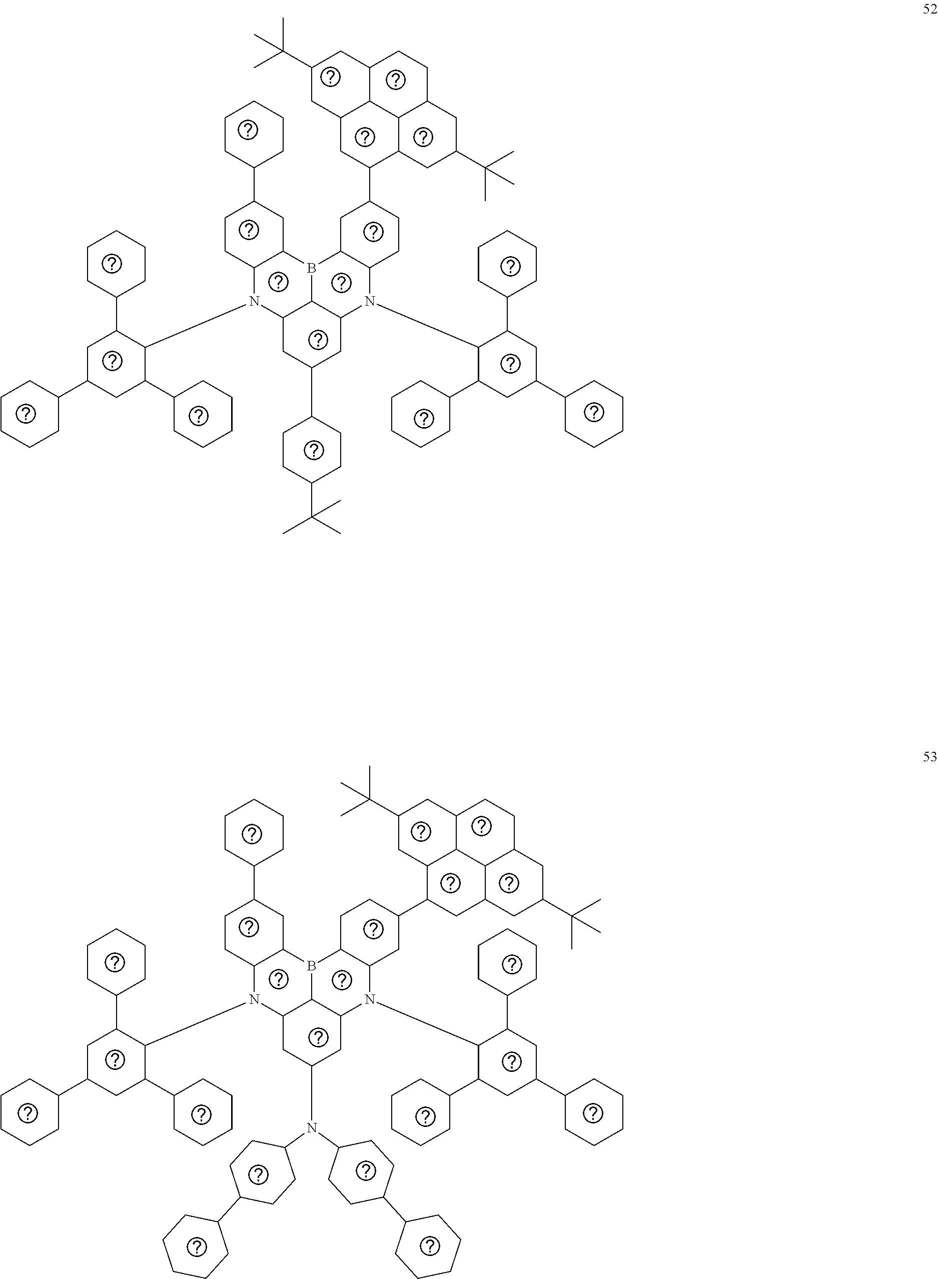 [SMILES: CC(C)(C)C1CCC(C2CC3C4B(C5CC(C6CCCCC6)CCC5N3C3C(C5CCCCC5)CC(C5CCCCC5)CC3C3CCCCC3)C3CC(C5CC6CC(C(C)(C)C)CC7CCC8CC(C(C)(C)C)CC5C8C76)CCC3N(C3C(C5CCCCC5)CC(C5CCCCC5)CC3C3CCCCC3)C4C2)CC1 ; CC(C)(C)C1CC2CCC3CC(C(C)(C)C)CC4C(C5CCC6B7C8CC(C9CCCCC9)CCC8N(C8C(C9CCCCC9)CC(C9CCCCC9)CC8C8CCCCC8)C8CC(N(C9CCC(C%10CCCCC%10)CC9)C9CCC(C%10CCCCC%10)CC9)CC(C78)N(C7C(C8CCCCC8)CC(C8CCCCC8)CC7C7CCCCC7)C6C5)CC(C1)C2C34] 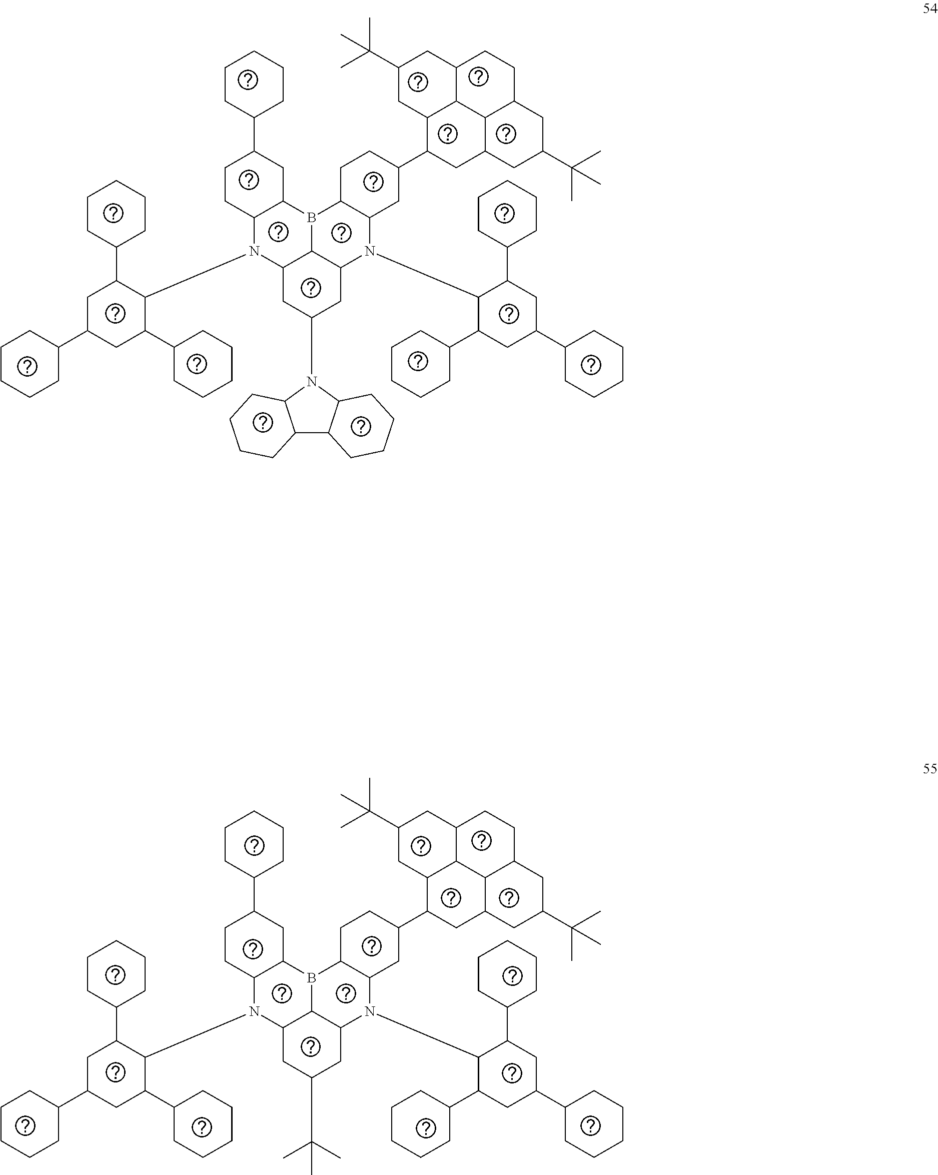 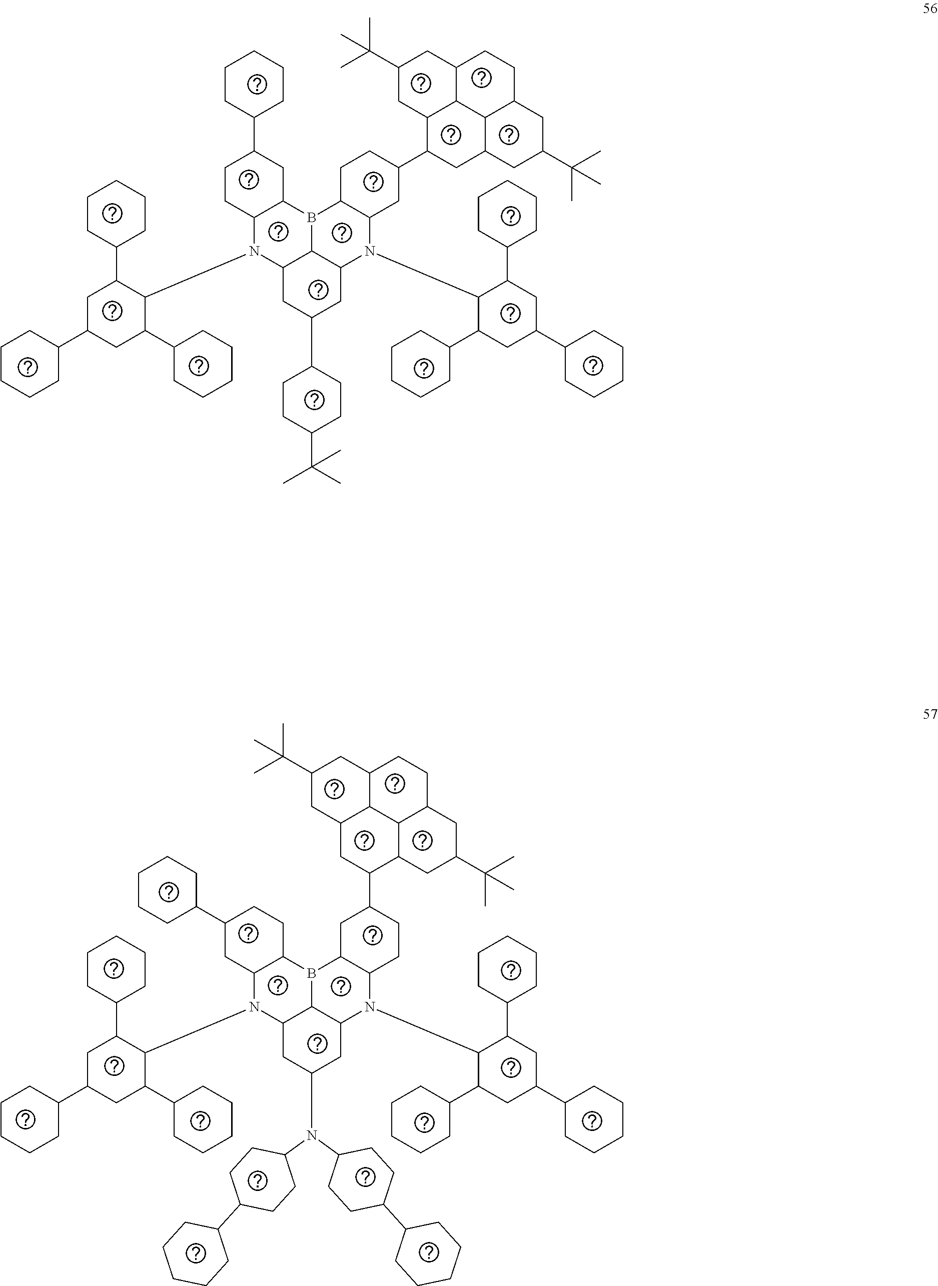 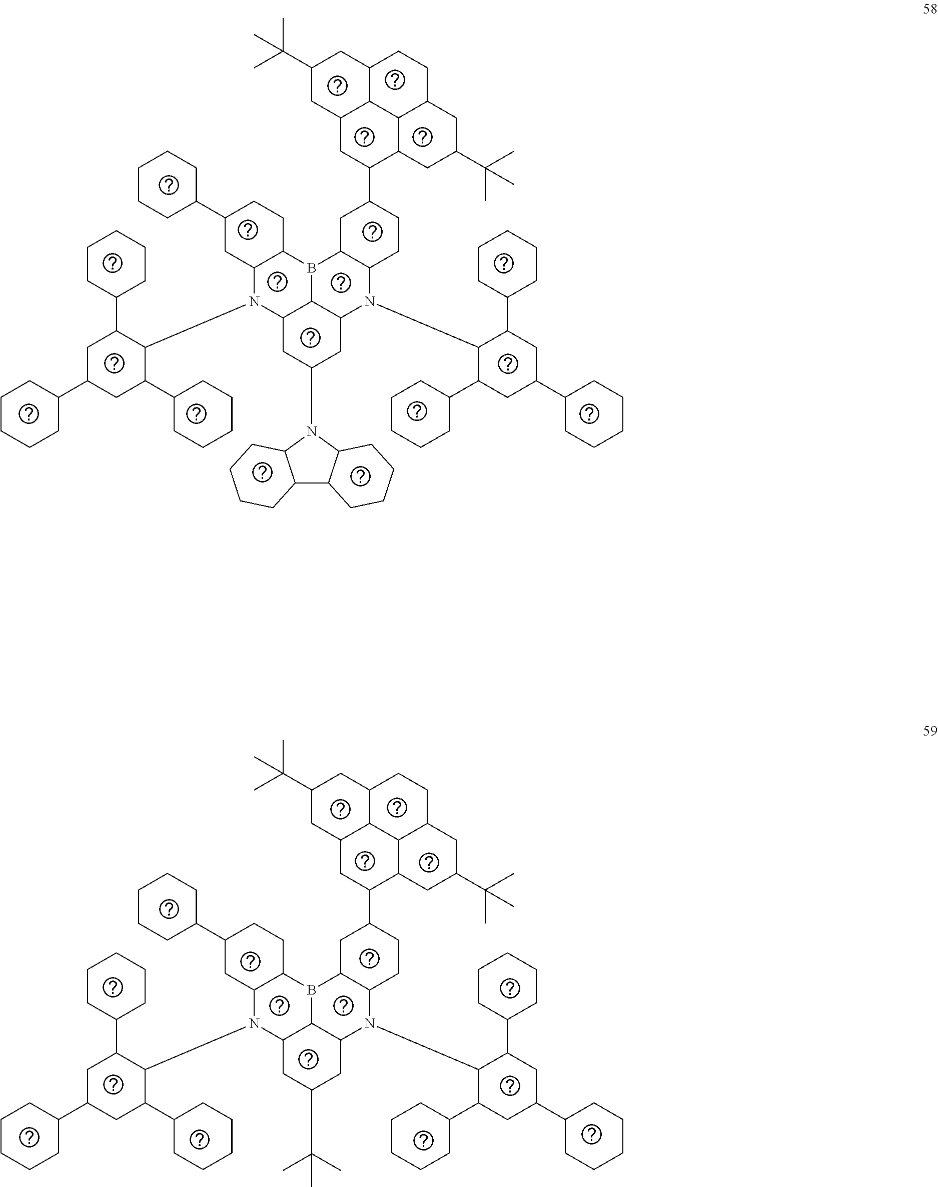 [SMILES: CC(C)(C)C1CC2CCC3CC(C(C)(C)C)CC4C(C5CCC6C(C5)B5C7CCC(C8CCCCC8)CC7N(C7C(C8CCCCC8)CC(C8CCCCC8)CC7C7CCCCC7)C7CC(N8C9CCCCC9C9CCCCC98)CC(C57)N6C5C(C6CCCCC6)CC(C6CCCCC6)CC5C5CCCCC5)CC(C1)C2C34 ; CC(C)(C)C1CC2CCC3CC(C(C)(C)C)CC4C(C5CCC6C(C5)B5C7CCC(C8CCCCC8)CC7N(C7C(C8CCCCC8)CC(C8CCCCC8)CC7C7CCCCC7)C7CC(C(C)(C)C)CC(C57)N6C5C(C6CCCCC6)CC(C6CCCCC6)CC5C5CCCCC5)CC(C1)C2C34] 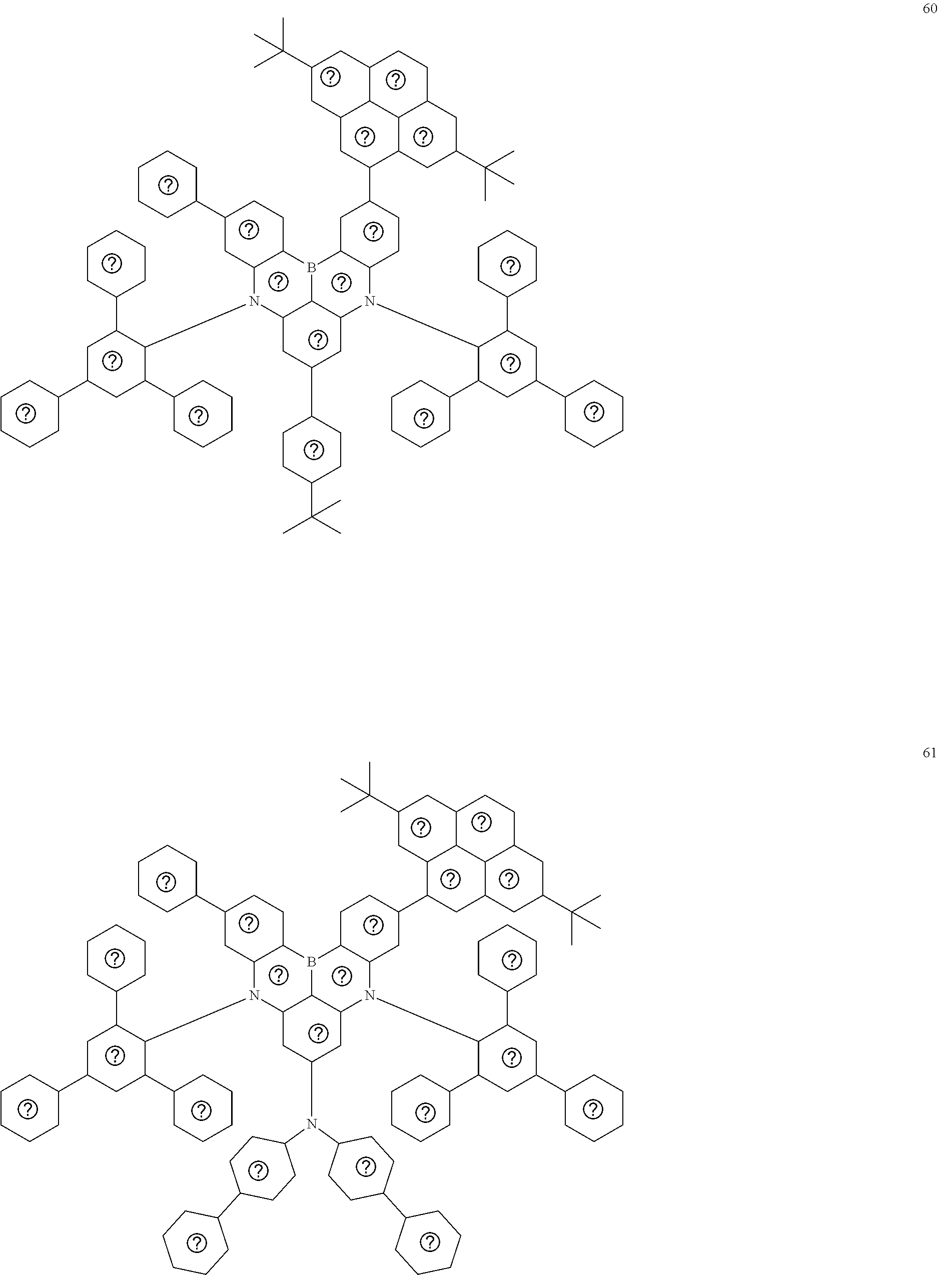 [SMILES: CC(C)(C)C1CCC(C2CC3C4B(C5CC(C6CC7CC(C(C)(C)C)CC8CCC9CC(C(C)(C)C)CC6C9C87)CCC5N3C3C(C5CCCCC5)CC(C5CCCCC5)CC3C3CCCCC3)C3CCC(C5CCCCC5)CC3N(C3C(C5CCCCC5)CC(C5CCCCC5)CC3C3CCCCC3)C4C2)CC1 ; CC(C)(C)C1CC2CCC3CC(C(C)(C)C)CC4C(C5CCC6B7C8CCC(C9CCCCC9)CC8N(C8C(C9CCCCC9)CC(C9CCCCC9)CC8C8CCCCC8)C8CC(N(C9CCC(C%10CCCCC%10)CC9)C9CCC(C%10CCCCC%10)CC9)CC(C78)N(C7C(C8CCCCC8)CC(C8CCCCC8)CC7C7CCCCC7)C6C5)CC(C1)C2C34] 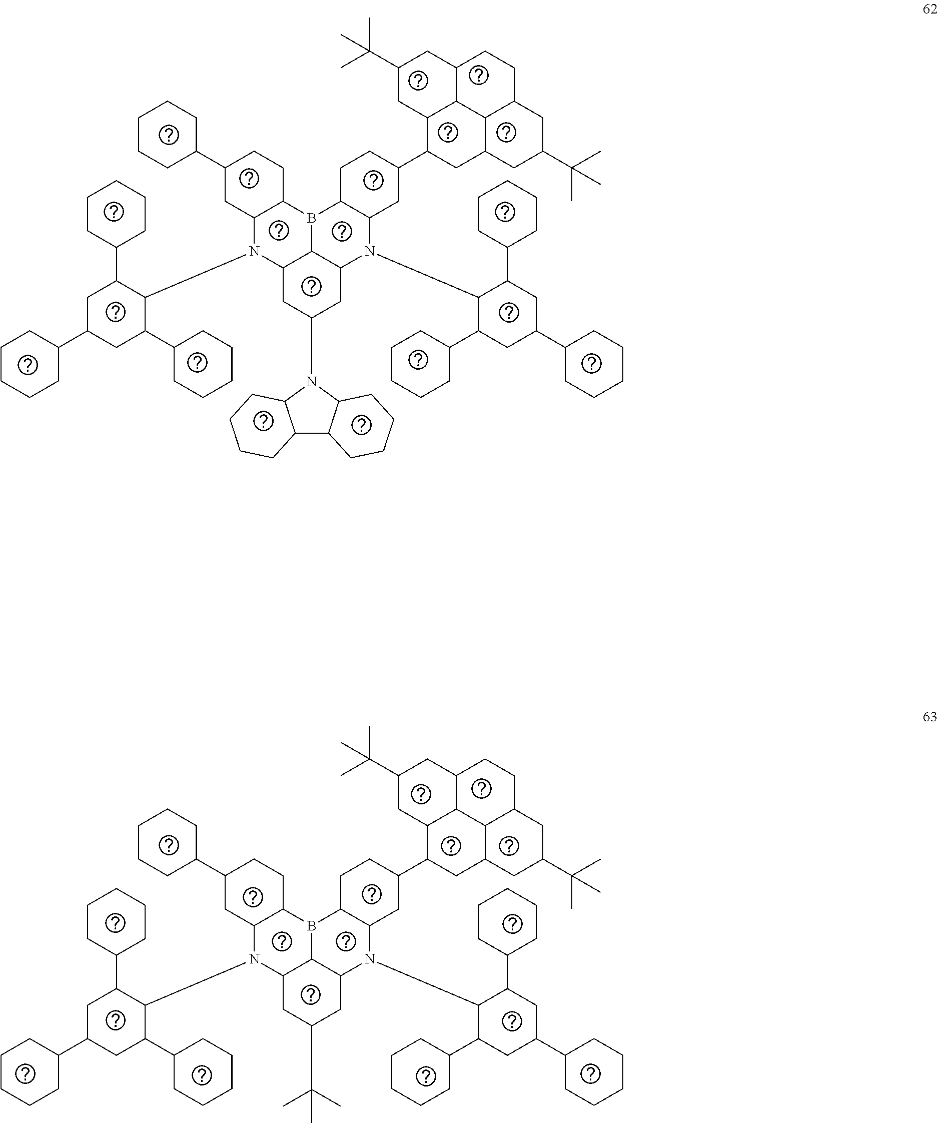 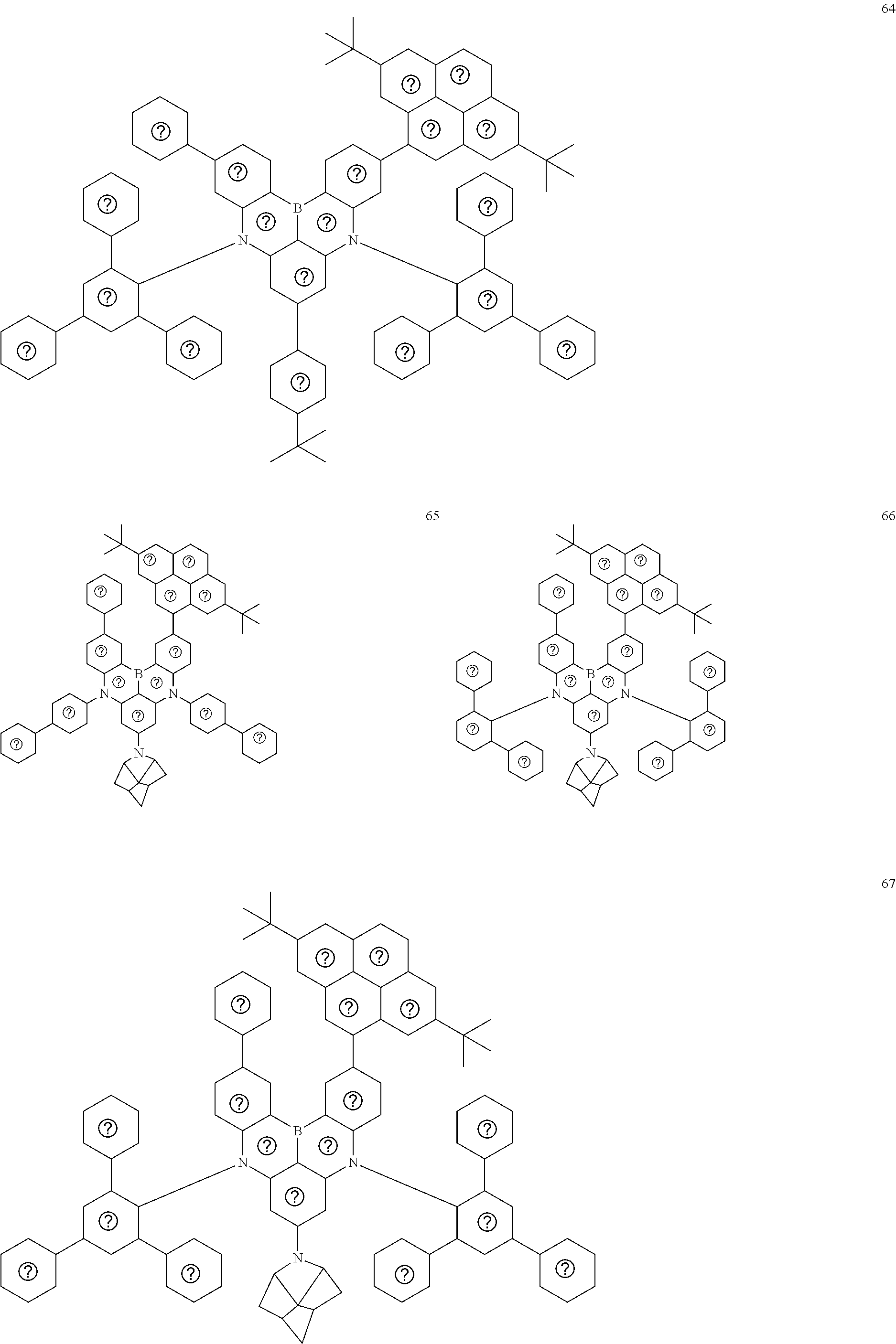 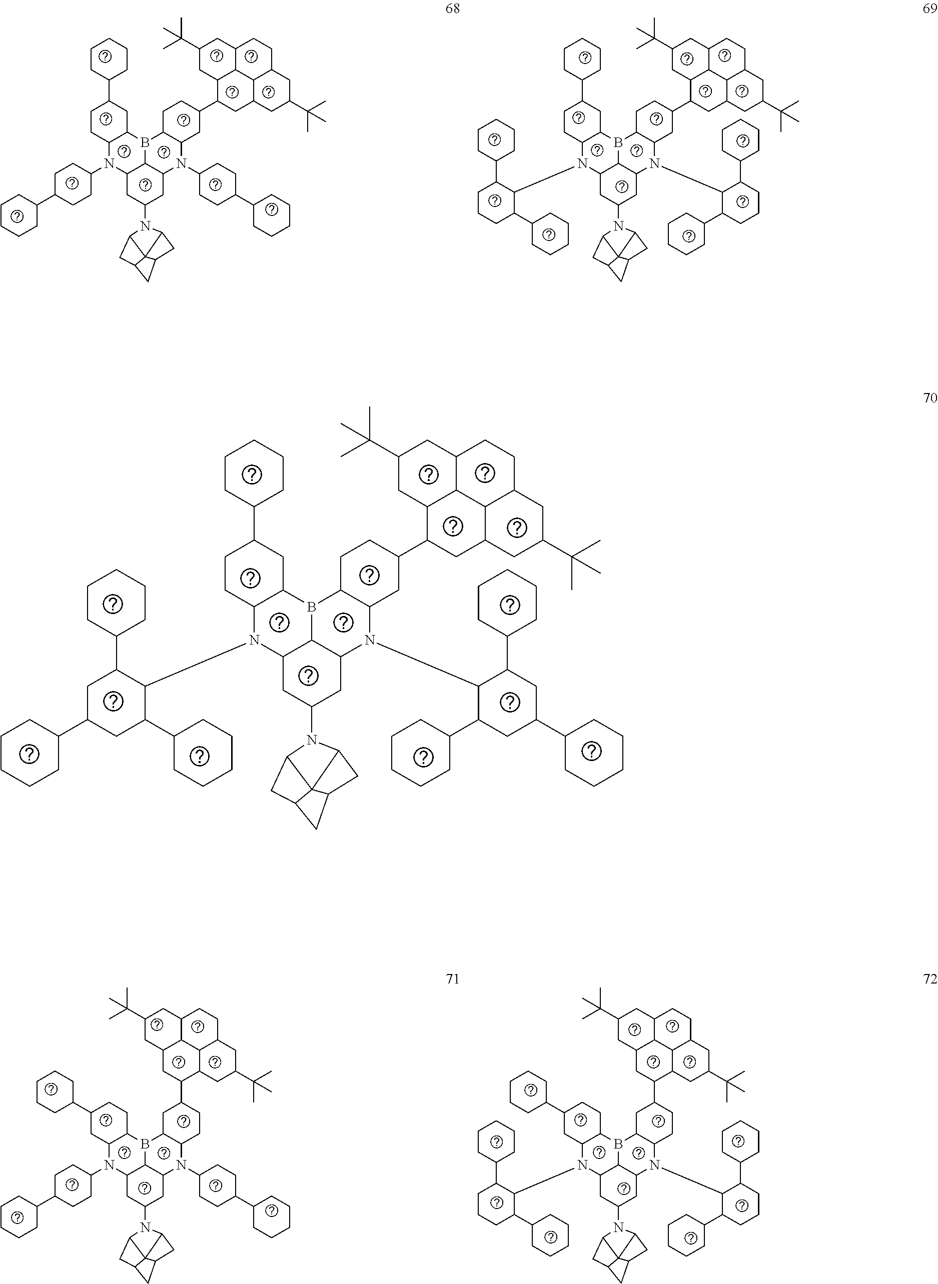 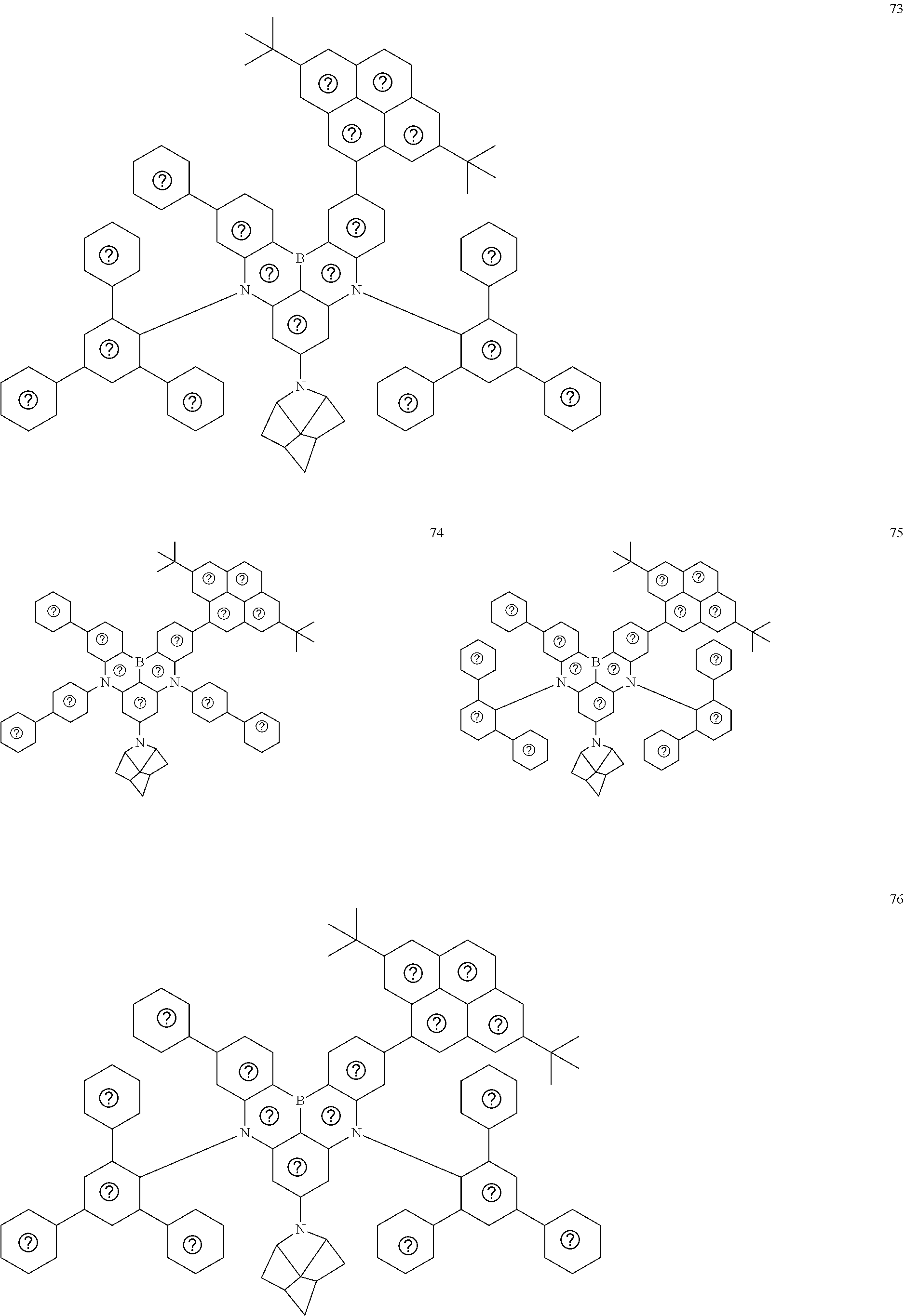 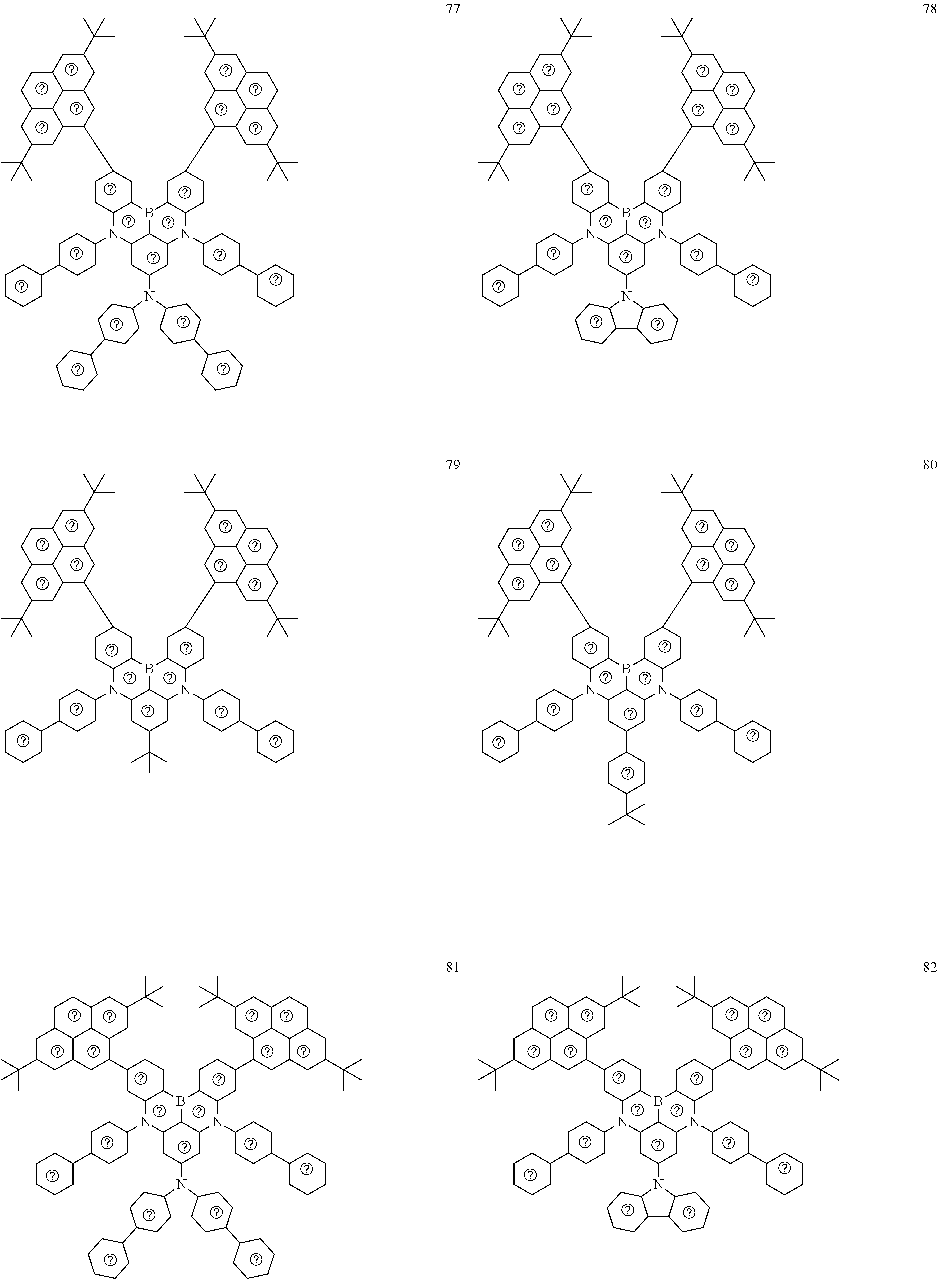 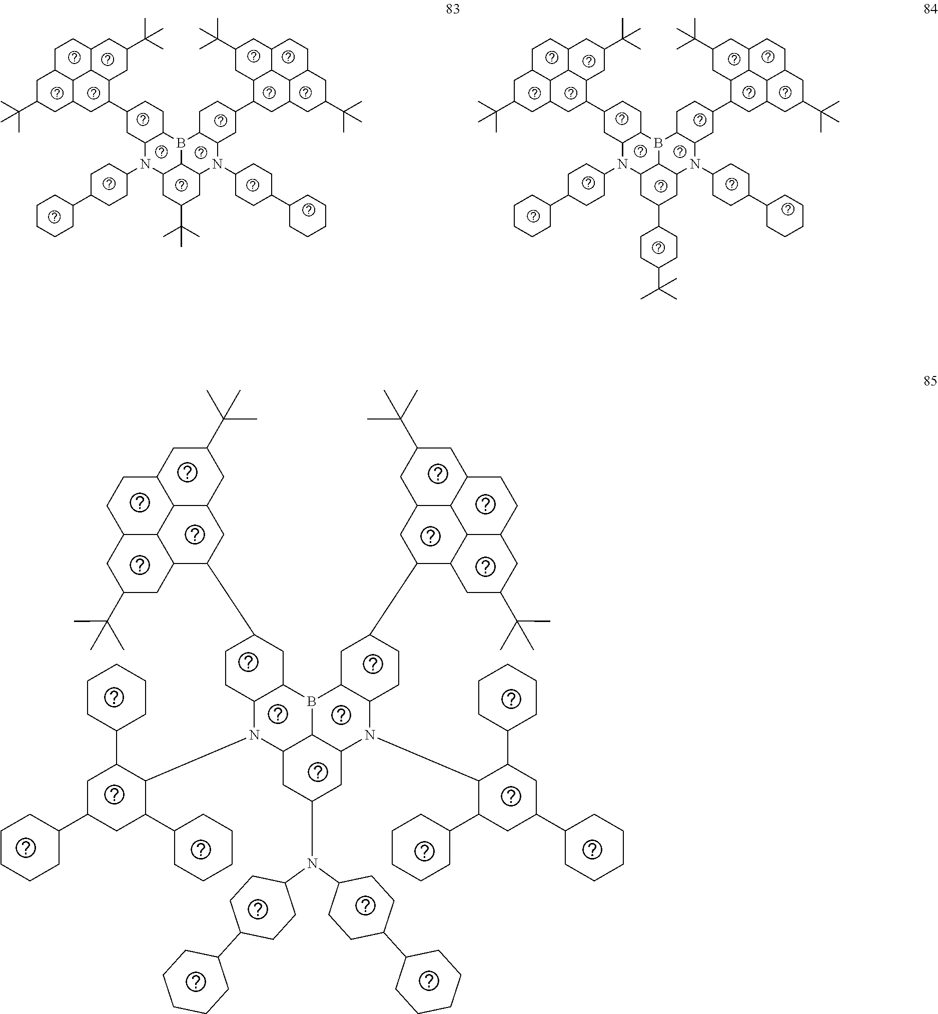 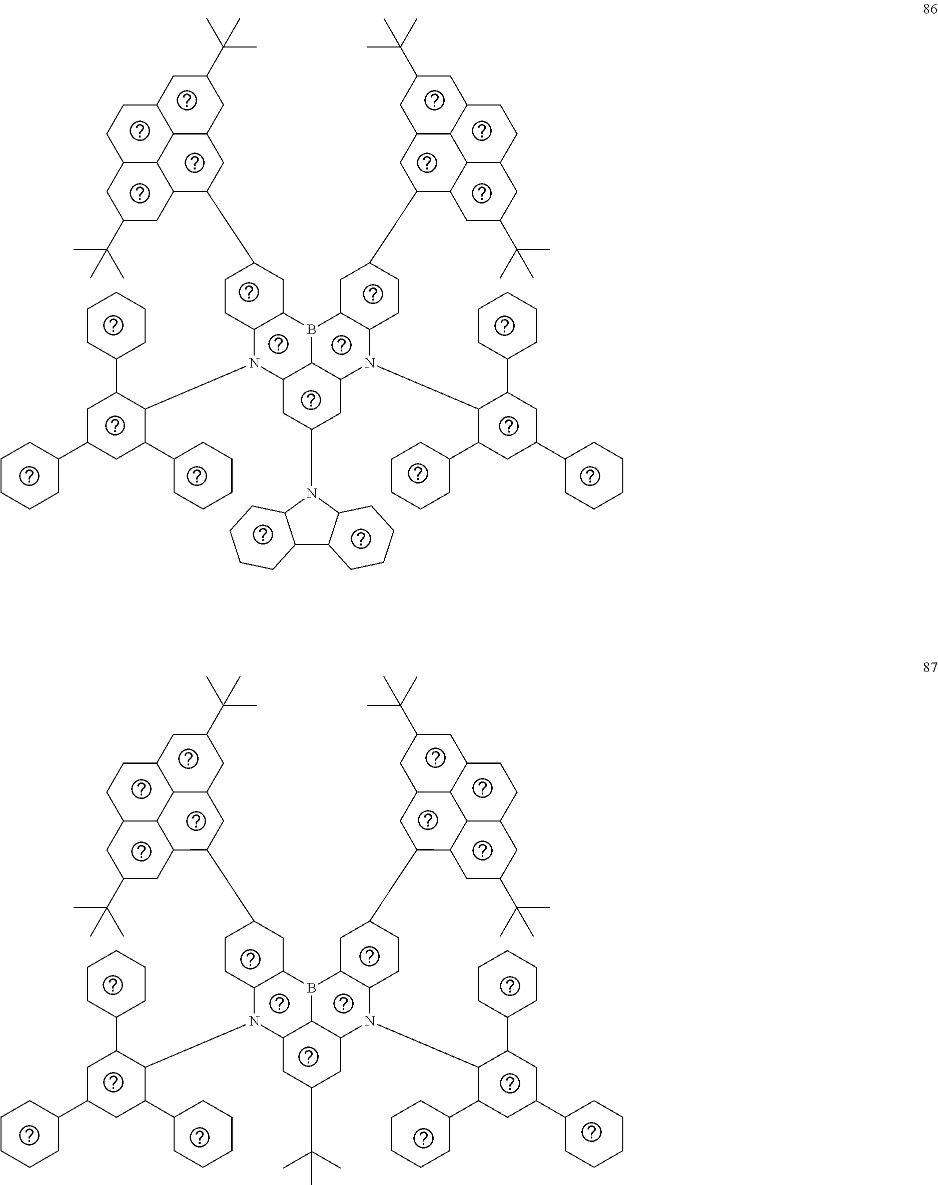 [SMILES: CC(C)(C)C1CC2CCC3CC(C(C)(C)C)CC4C(C5CCC6C(C5)B5C7CC(C8CC9CC(C(C)(C)C)CC%10CCC%11CC(C(C)(C)C)CC8C%11C%109)CCC7N(C7C(C8CCCCC8)CC(C8CCCCC8)CC7C7CCCCC7)C7CC(N8C9CCCCC9C9CCCCC98)CC(C57)N6C5C(C6CCCCC6)CC(C6CCCCC6)CC5C5CCCCC5)CC(C1)C2C34 ; CC(C)(C)C1CC2CCC3CC(C(C)(C)C)CC4C(C5CCC6C(C5)B5C7CC(C8CC9CC(C(C)(C)C)CC%10CCC%11CC(C(C)(C)C)CC8C%11C%109)CCC7N(C7C(C8CCCCC8)CC(C8CCCCC8)CC7C7CCCCC7)C7CC(C(C)(C)C)CC(C57)N6C5C(C6CCCCC6)CC(C6CCCCC6)CC5C5CCCCC5)CC(C1)C2C34] 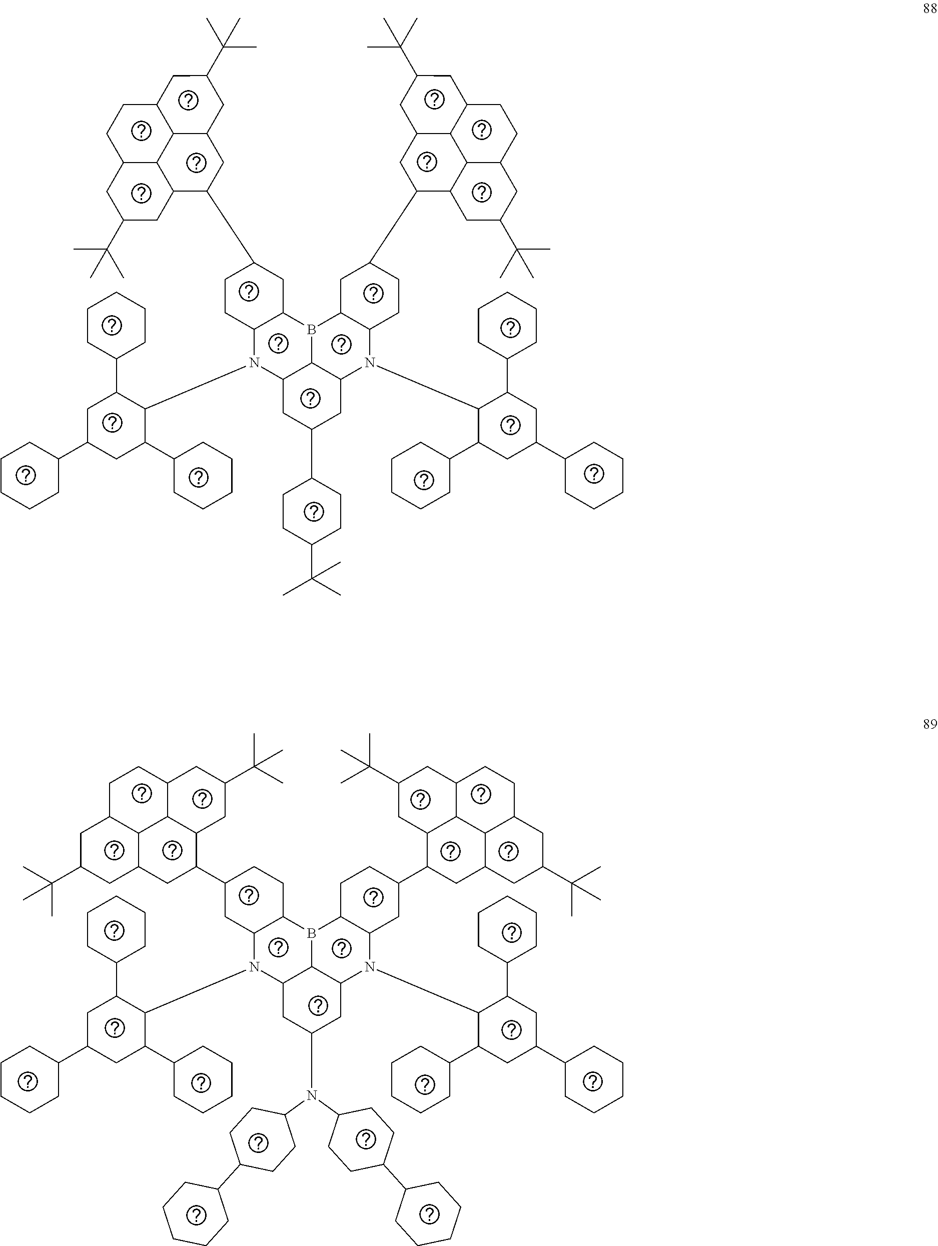 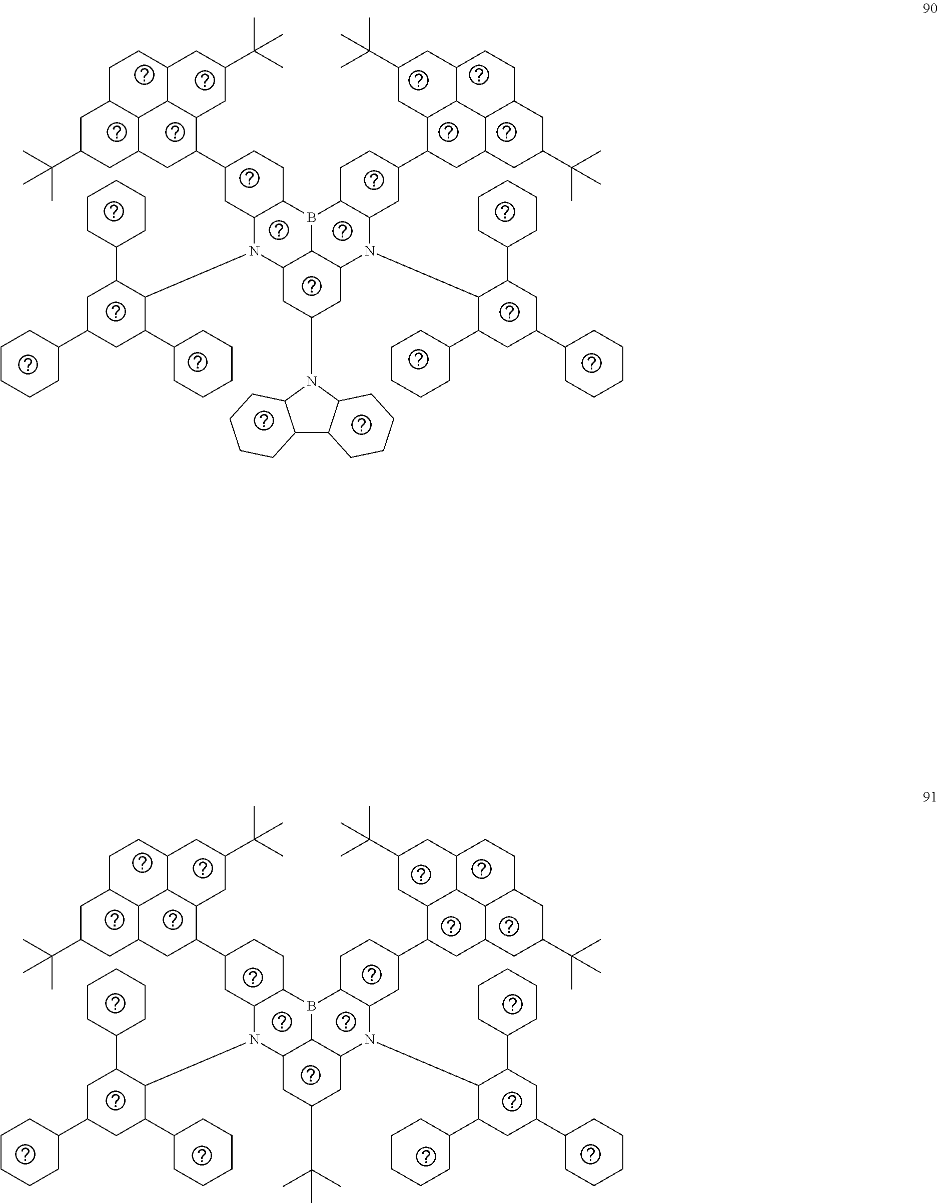 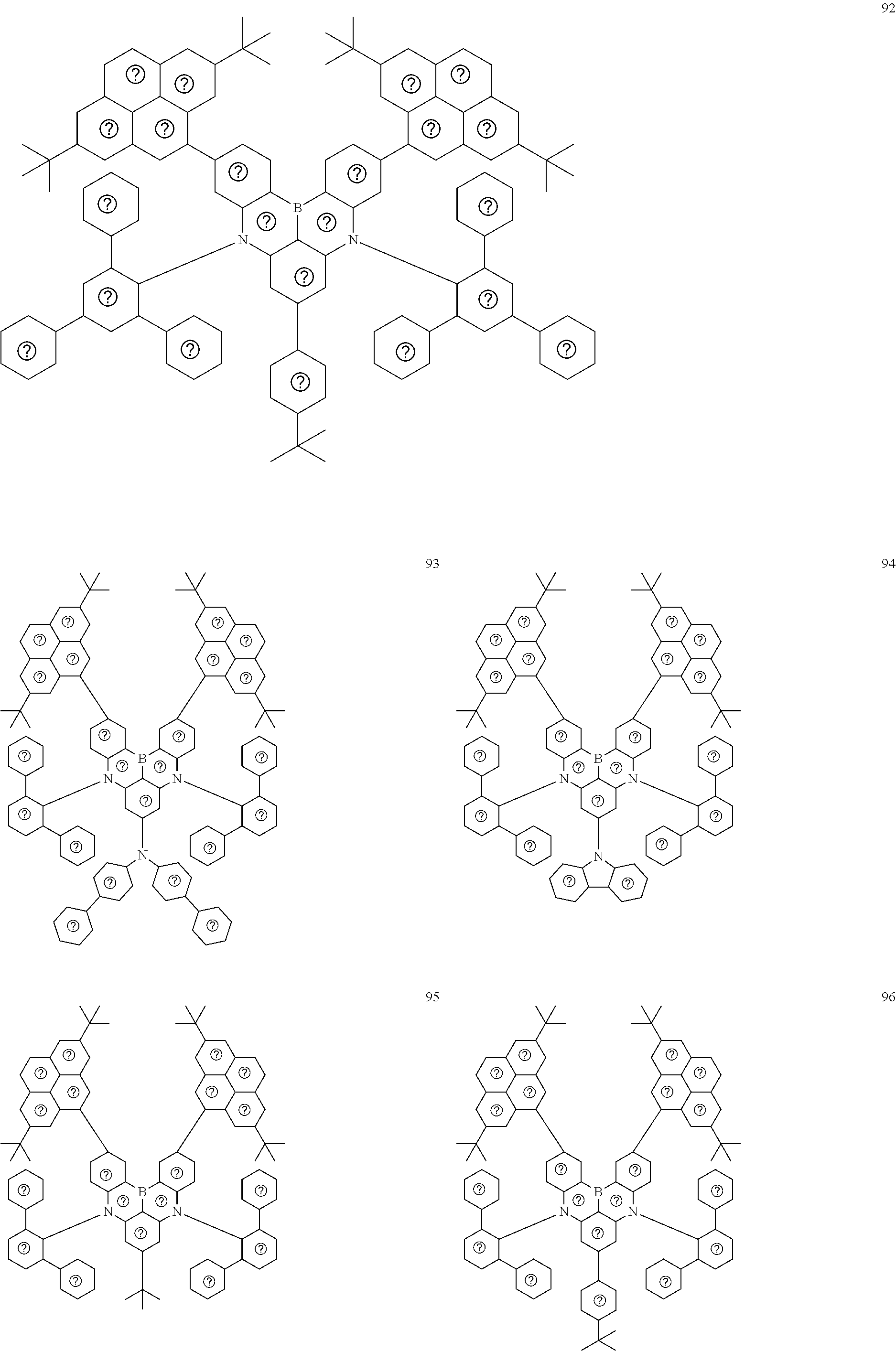 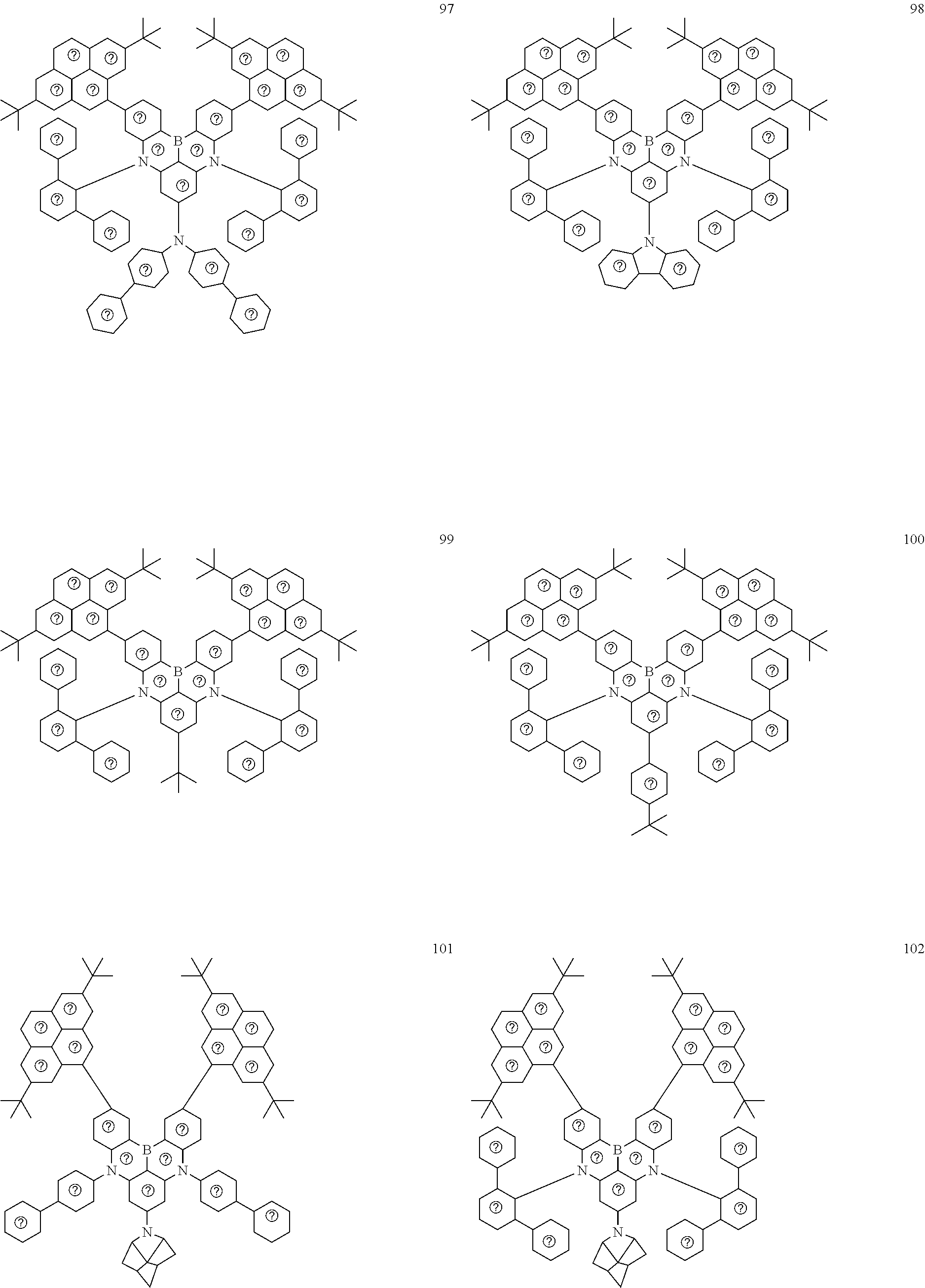 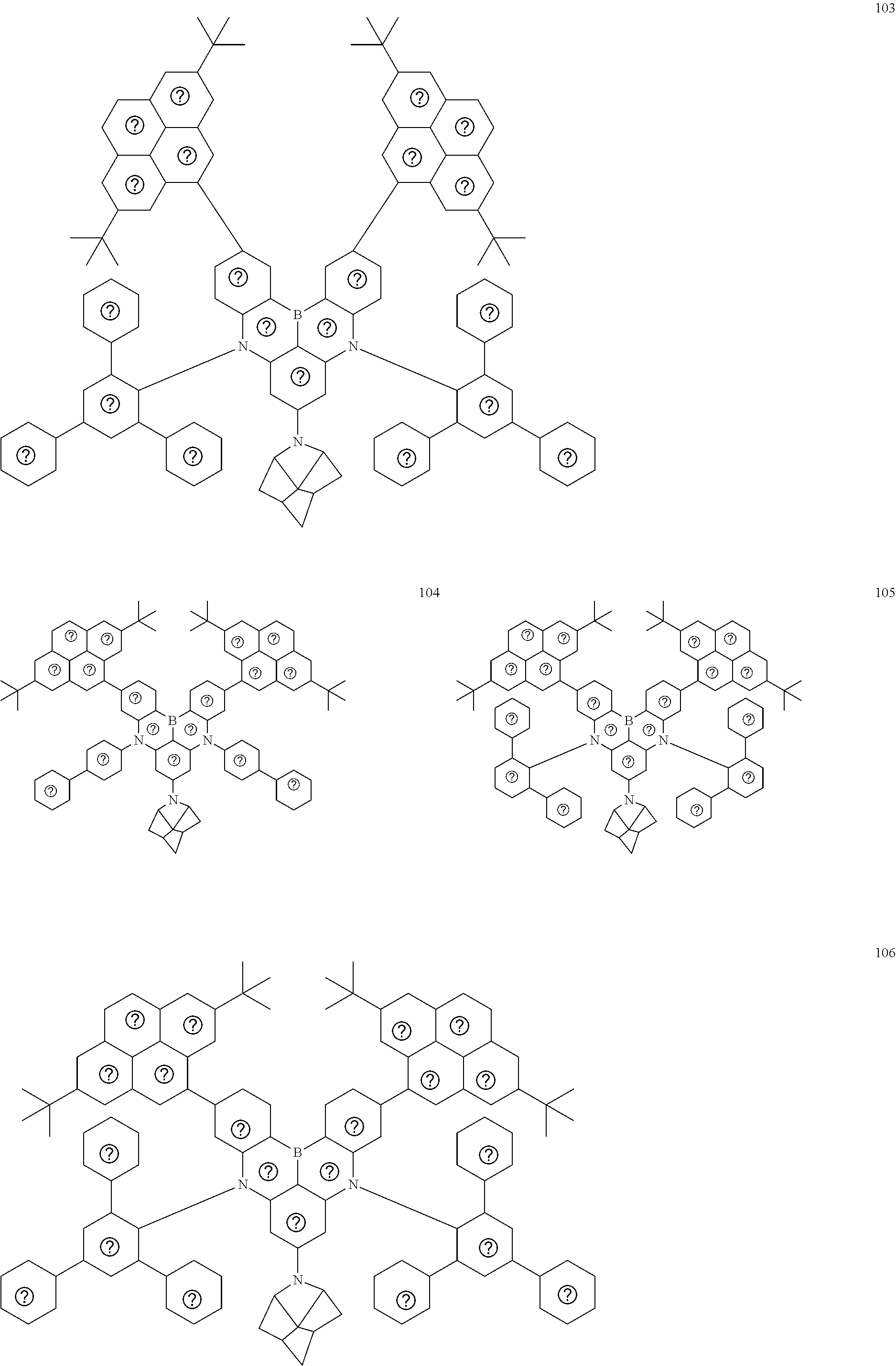 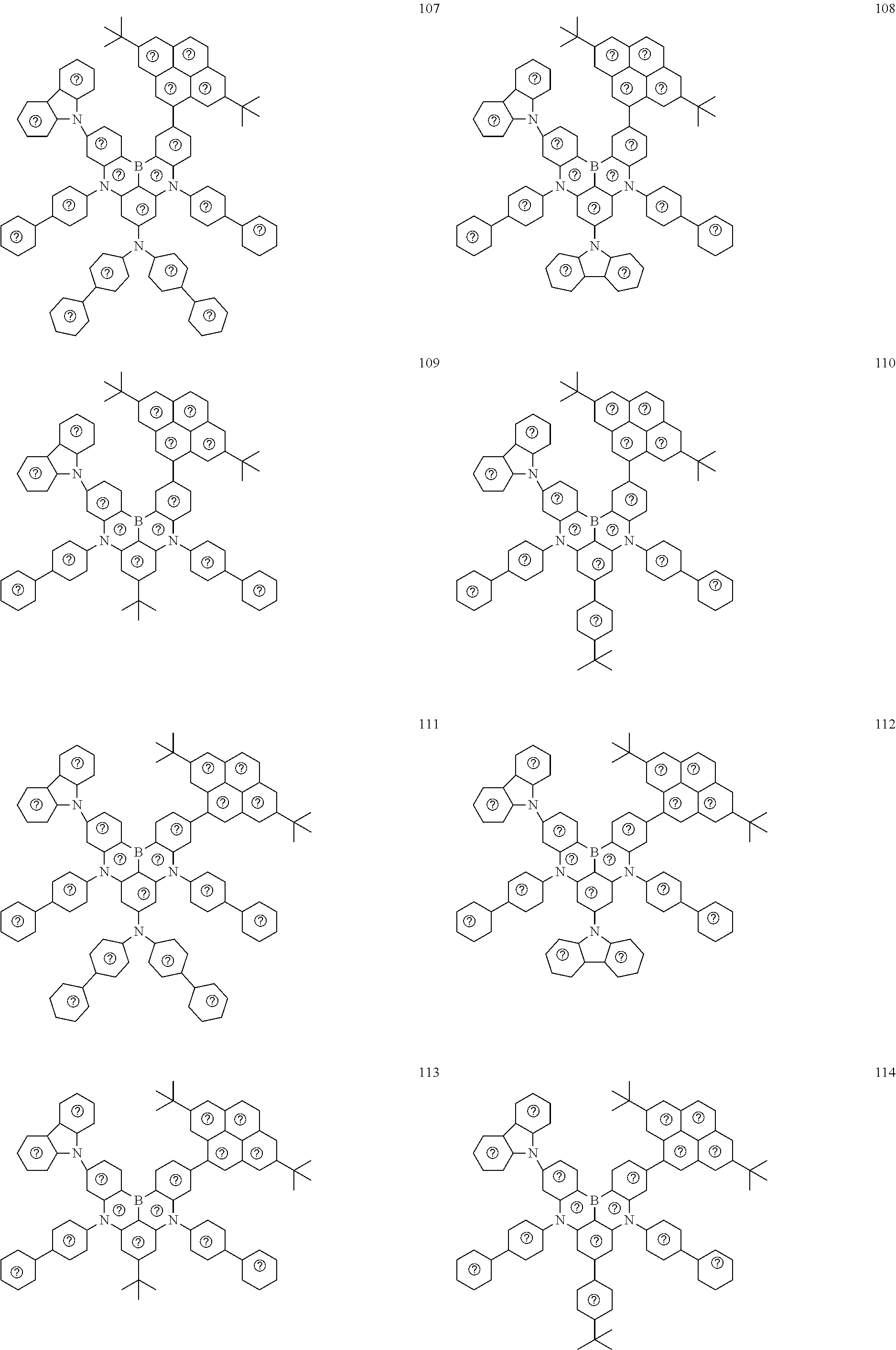 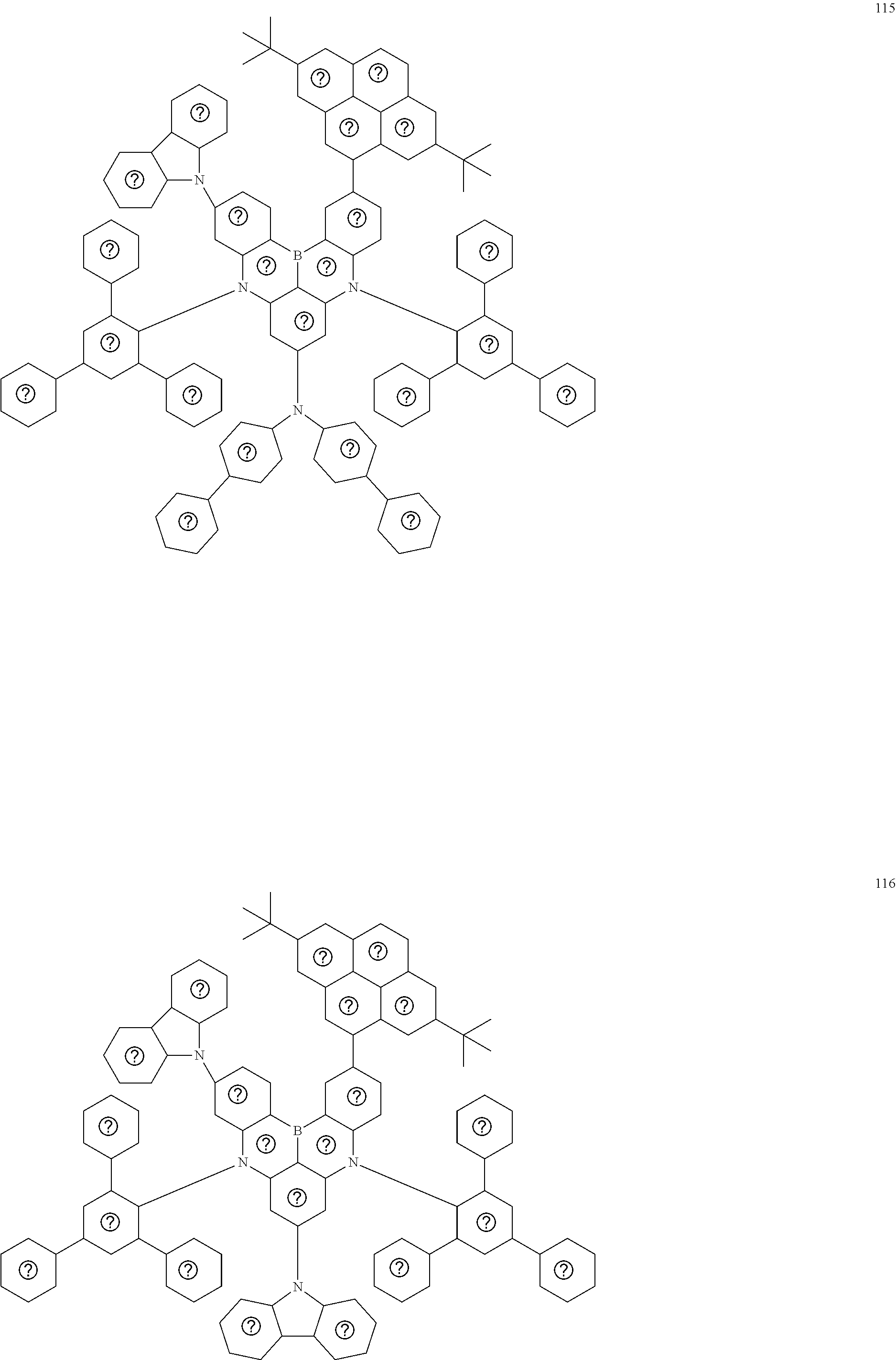 [SMILES: CC(C)(C)C1CC2CCC3CC(C(C)(C)C)CC4C(C5CCC6C(C5)B5C7CCC(N8C9CCCCC9C9CCCCC98)CC7N(C7C(C8CCCCC8)CC(C8CCCCC8)CC7C7CCCCC7)C7CC(N(C8CCC(C9CCCCC9)CC8)C8CCC(C9CCCCC9)CC8)CC(C57)N6C5C(C6CCCCC6)CC(C6CCCCC6)CC5C5CCCCC5)CC(C1)C2C34 ; CC(C)(C)C1CC2CCC3CC(C(C)(C)C)CC4C(C5CCC6C(C5)B5C7CCC(N8C9CCCCC9C9CCCCC98)CC7N(C7C(C8CCCCC8)CC(C8CCCCC8)CC7C7CCCCC7)C7CC(N8C9CCCCC9C9CCCCC98)CC(C57)N6C5C(C6CCCCC6)CC(C6CCCCC6)CC5C5CCCCC5)CC(C1)C2C34] 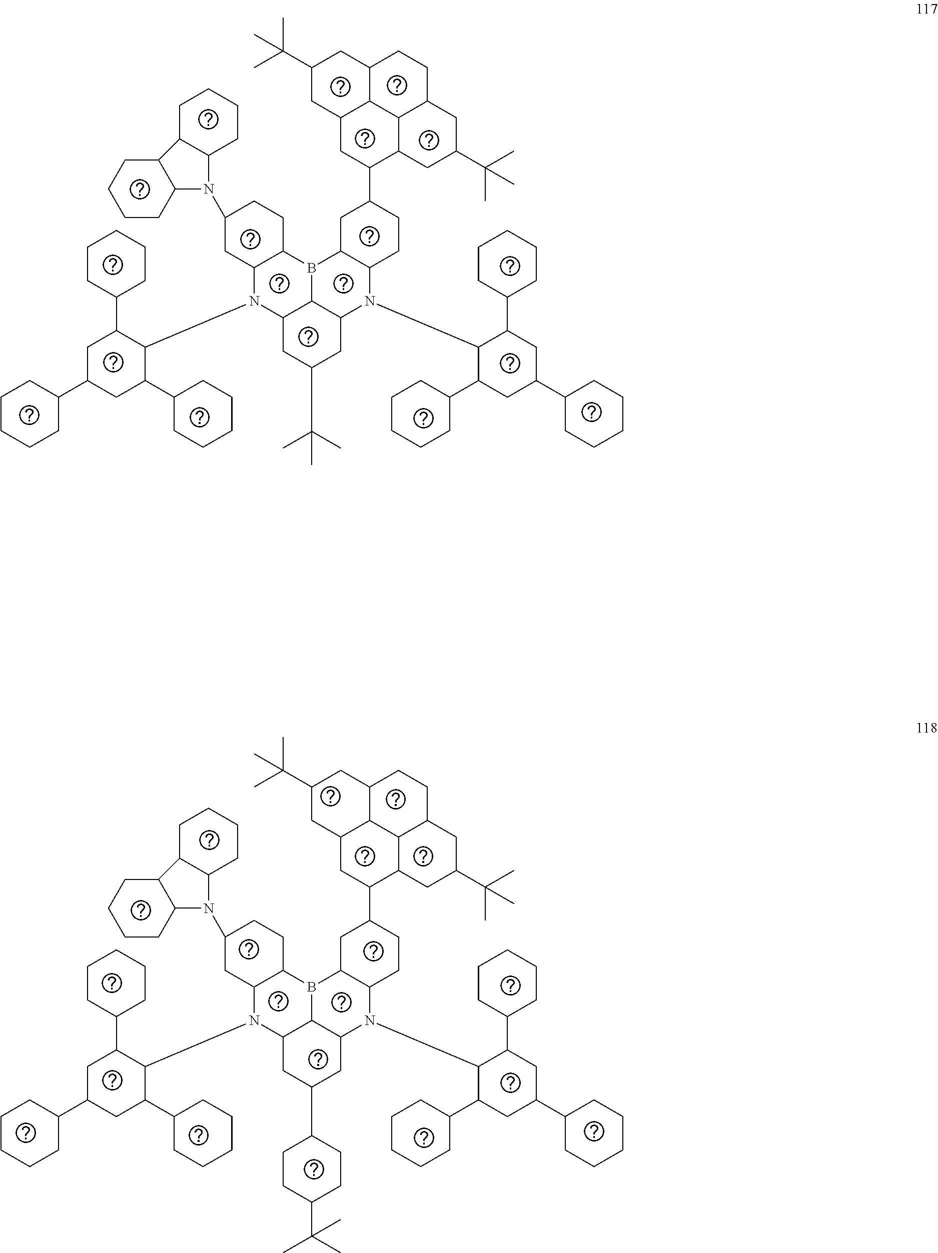 [SMILES: CC(C)(C)C1CC2CCC3CC(C(C)(C)C)CC4C(C5CCC6C(C5)B5C7CCC(N8C9CCCCC9C9CCCCC98)CC7N(C7C(C8CCCCC8)CC(C8CCCCC8)CC7C7CCCCC7)C7CC(C(C)(C)C)CC(C57)N6C5C(C6CCCCC6)CC(C6CCCCC6)CC5C5CCCCC5)CC(C1)C2C34 ; CC(C)(C)C1CCC(C2CC3C4B(C5CC(C6CC7CC(C(C)(C)C)CC8CCC9CC(C(C)(C)C)CC6C9C87)CCC5N3C3C(C5CCCCC5)CC(C5CCCCC5)CC3C3CCCCC3)C3CCC(N5C6CCCCC6C6CCCCC65)CC3N(C3C(C5CCCCC5)CC(C5CCCCC5)CC3C3CCCCC3)C4C2)CC1] 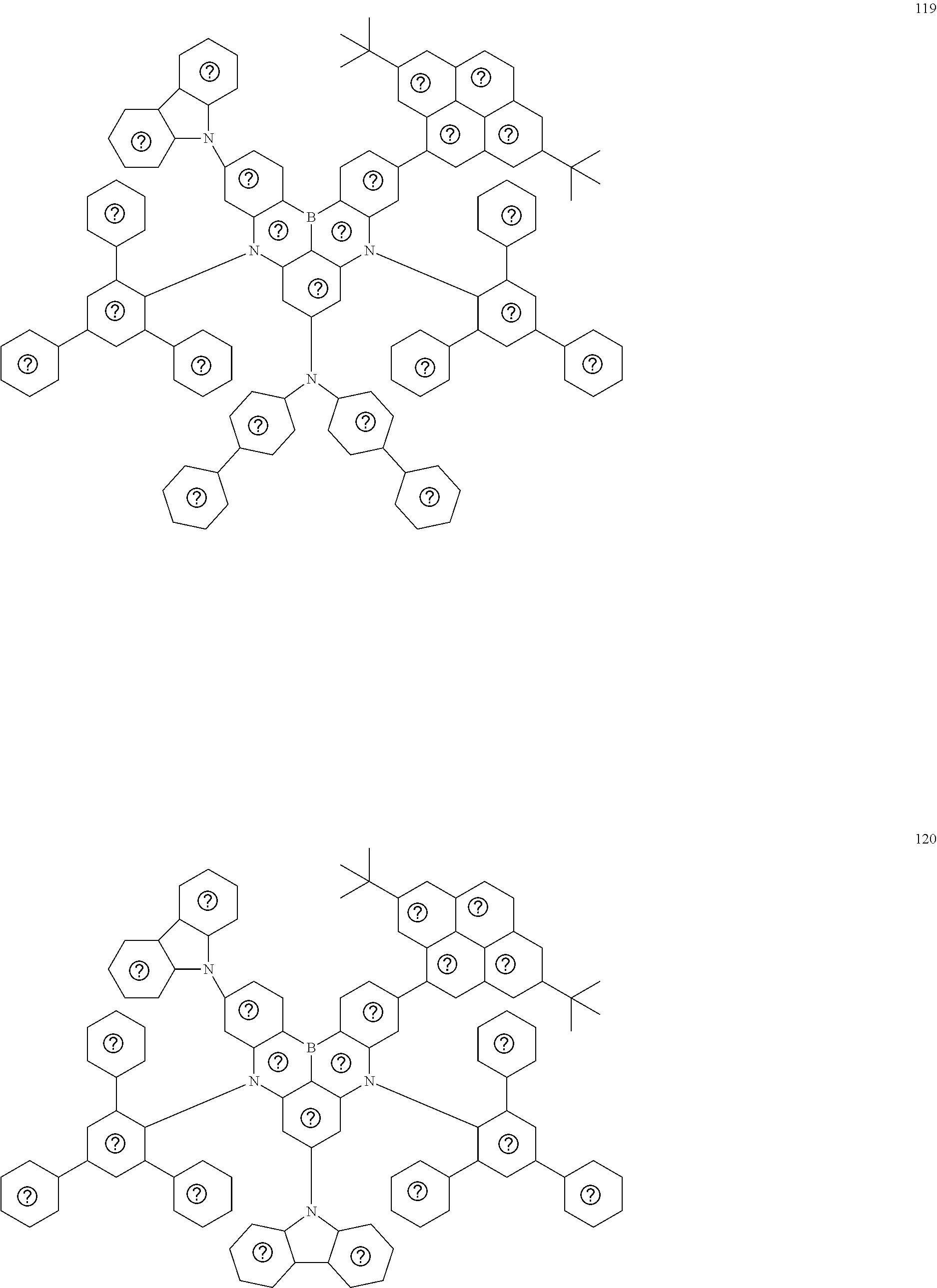 [SMILES: CC(C)(C)C1CC2CCC3CC(C(C)(C)C)CC4C(C5CCC6B7C8CCC(N9C%10CCCCC%10C%10CCCCC%109)CC8N(C8C(C9CCCCC9)CC(C9CCCCC9)CC8C8CCCCC8)C8CC(N(C9CCC(C%10CCCCC%10)CC9)C9CCC(C%10CCCCC%10)CC9)CC(C78)N(C7C(C8CCCCC8)CC(C8CCCCC8)CC7C7CCCCC7)C6C5)CC(C1)C2C34 ; CC(C)(C)C1CC2CCC3CC(C(C)(C)C)CC4C(C5CCC6B7C8CCC(N9C%10CCCCC%10C%10CCCCC%109)CC8N(C8C(C9CCCCC9)CC(C9CCCCC9)CC8C8CCCCC8)C8CC(N9C%10CCCCC%10C%10CCCCC%109)CC(C78)N(C7C(C8CCCCC8)CC(C8CCCCC8)CC7C7CCCCC7)C6C5)CC(C1)C2C34] 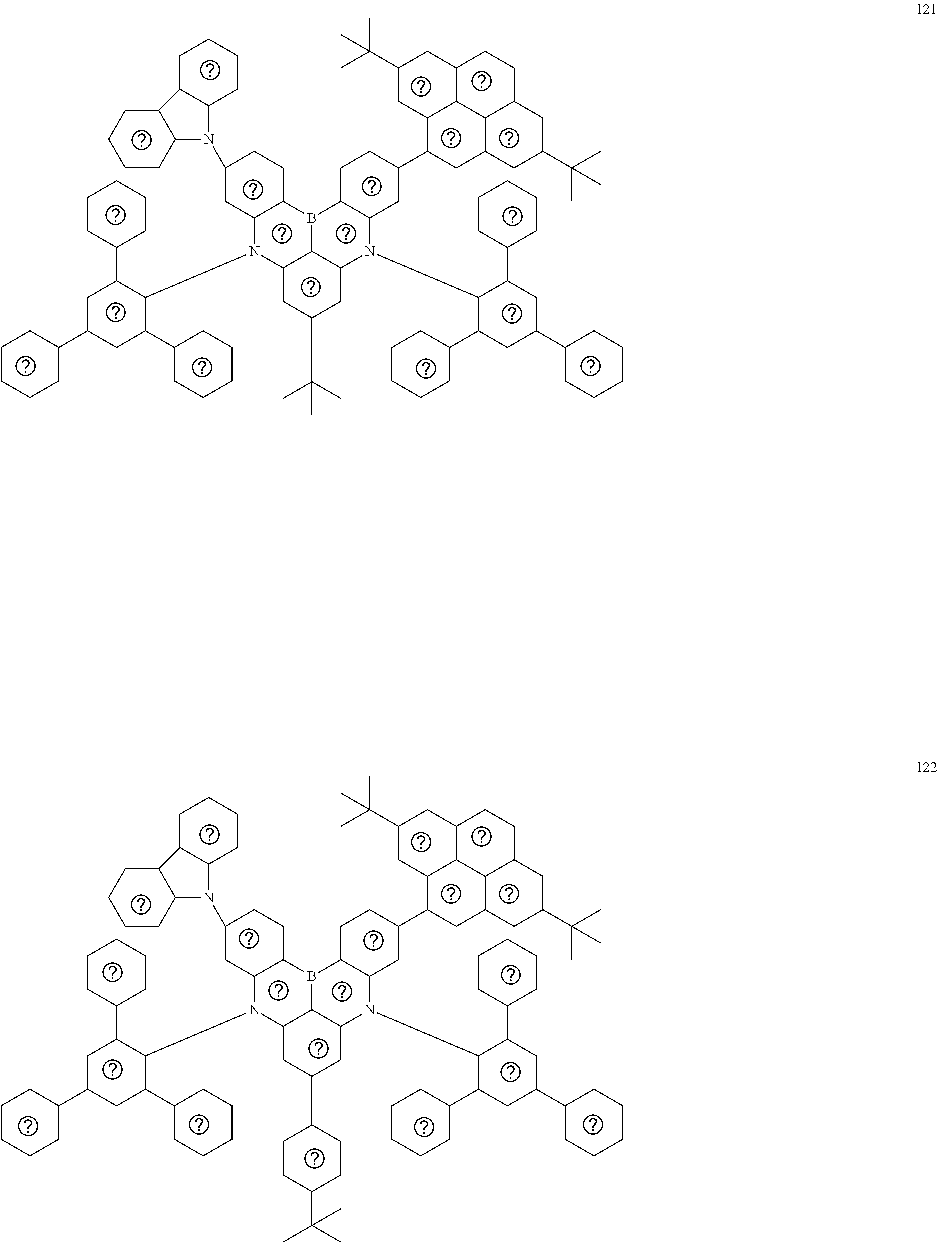 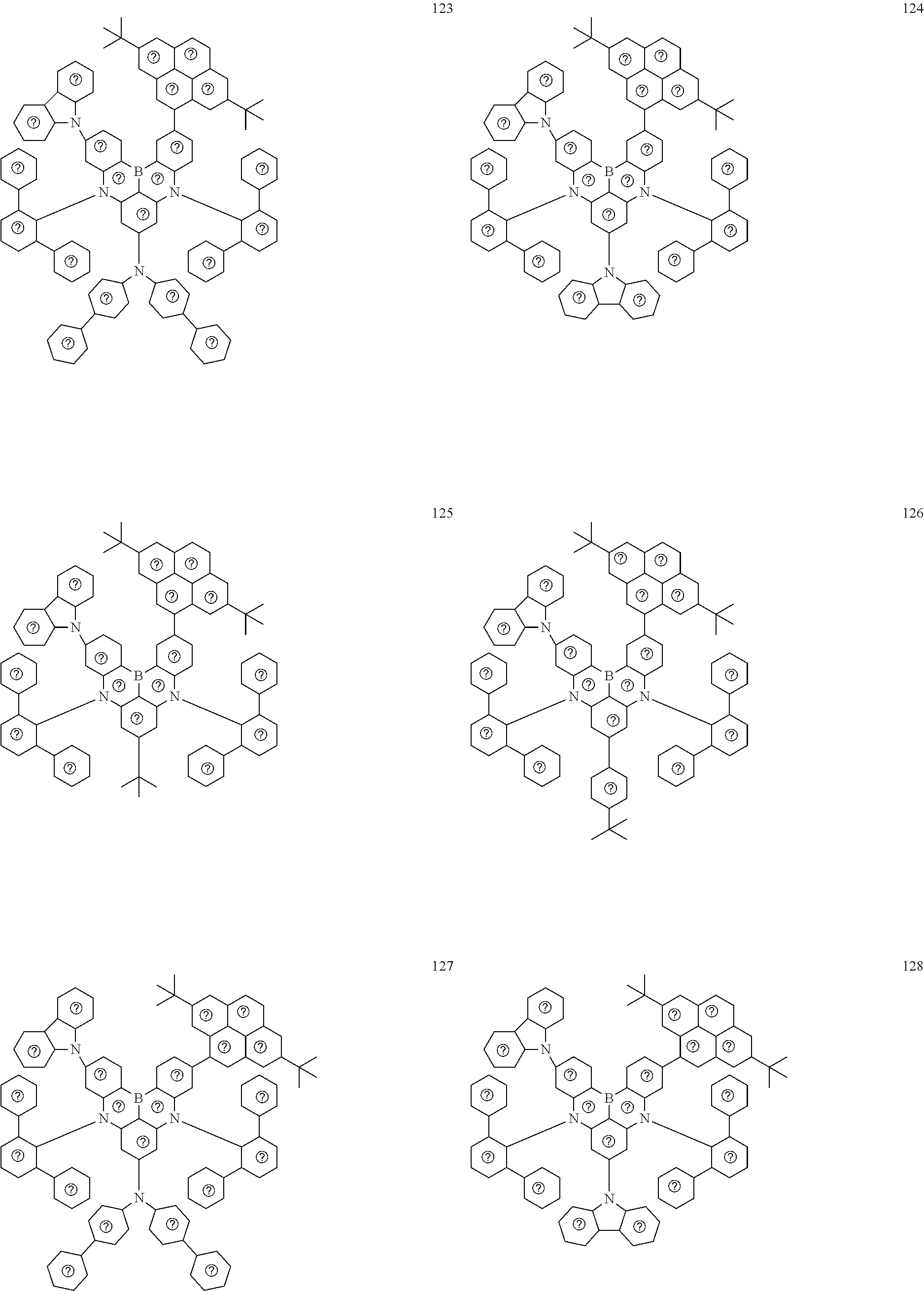 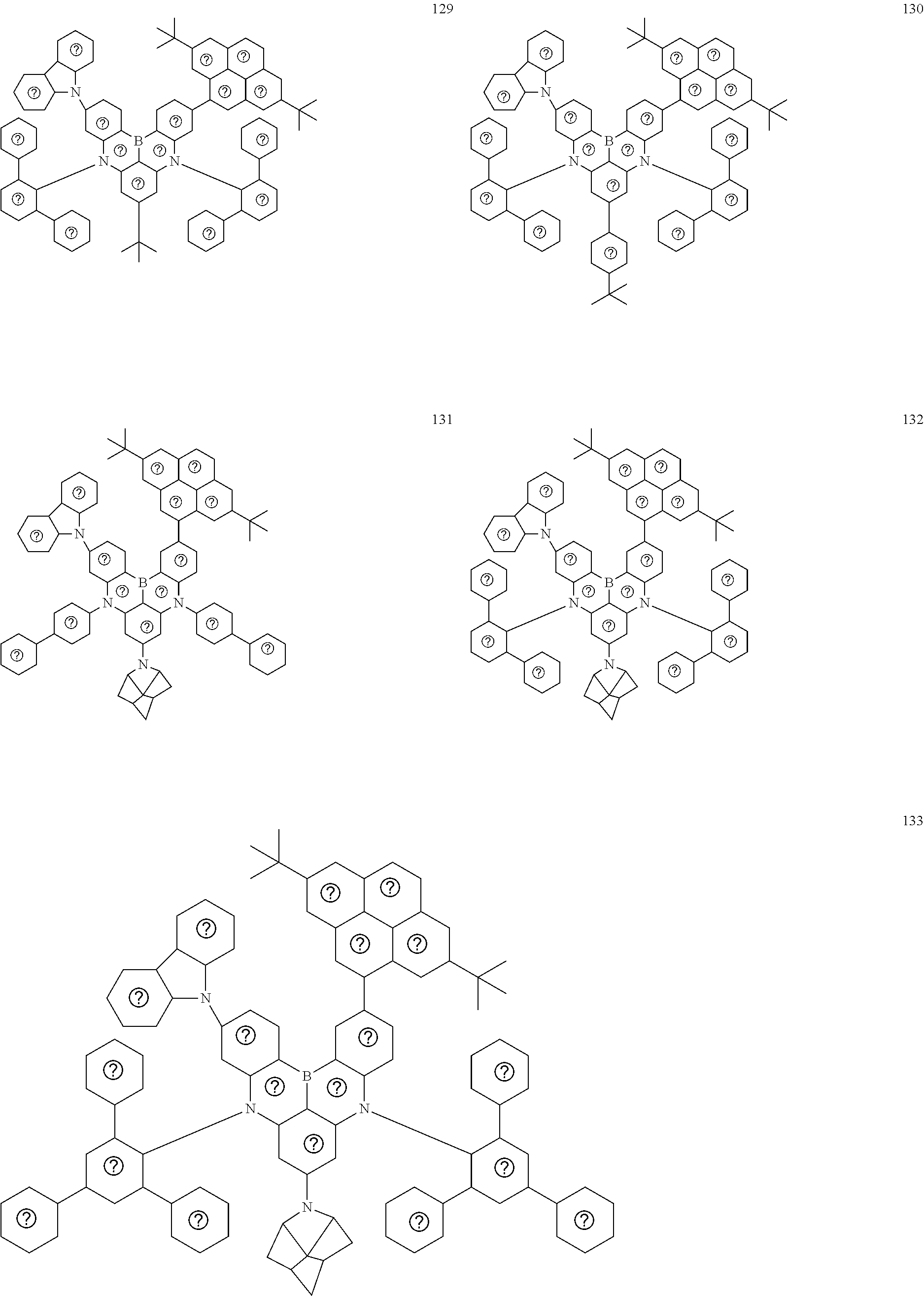 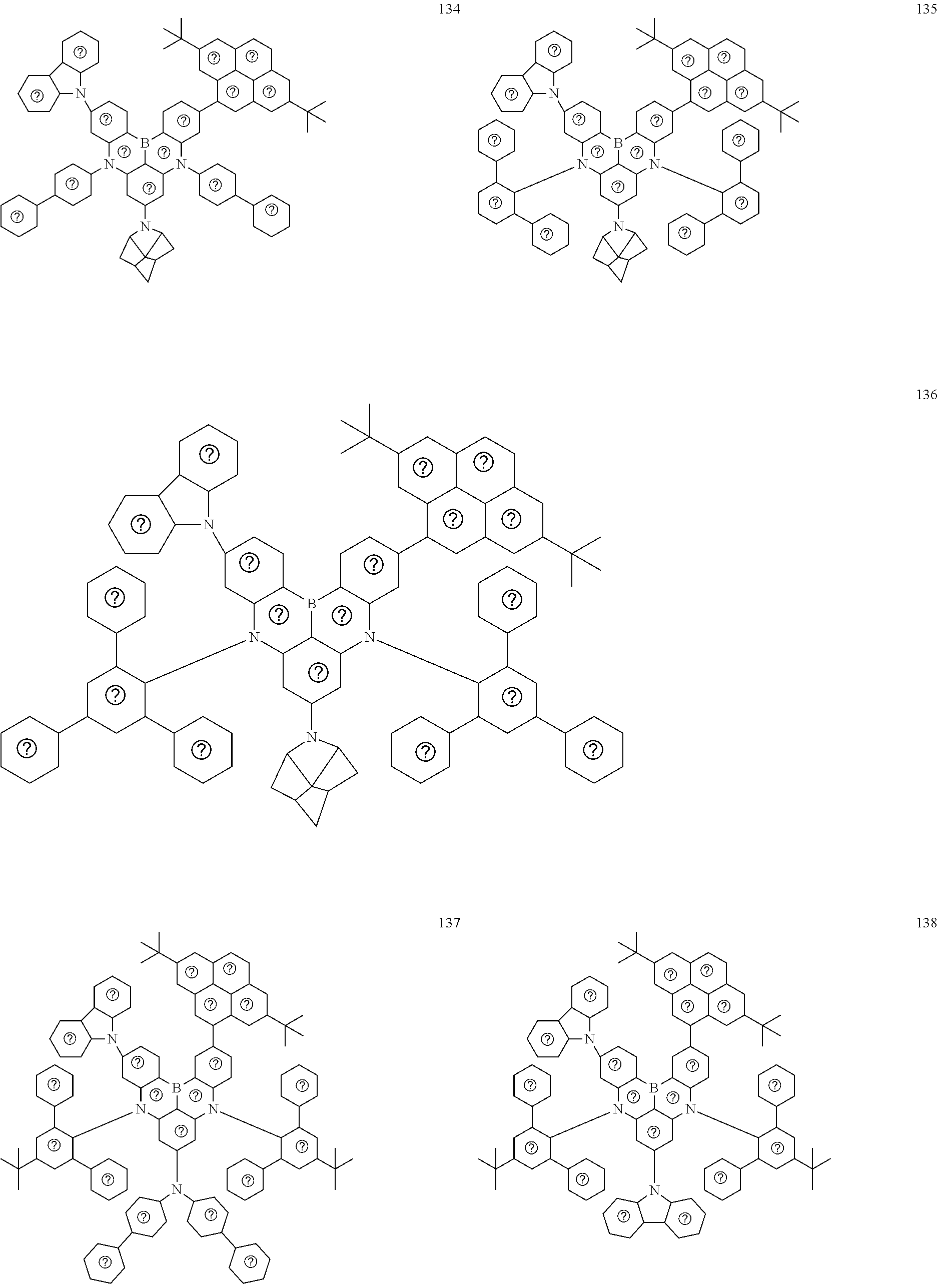 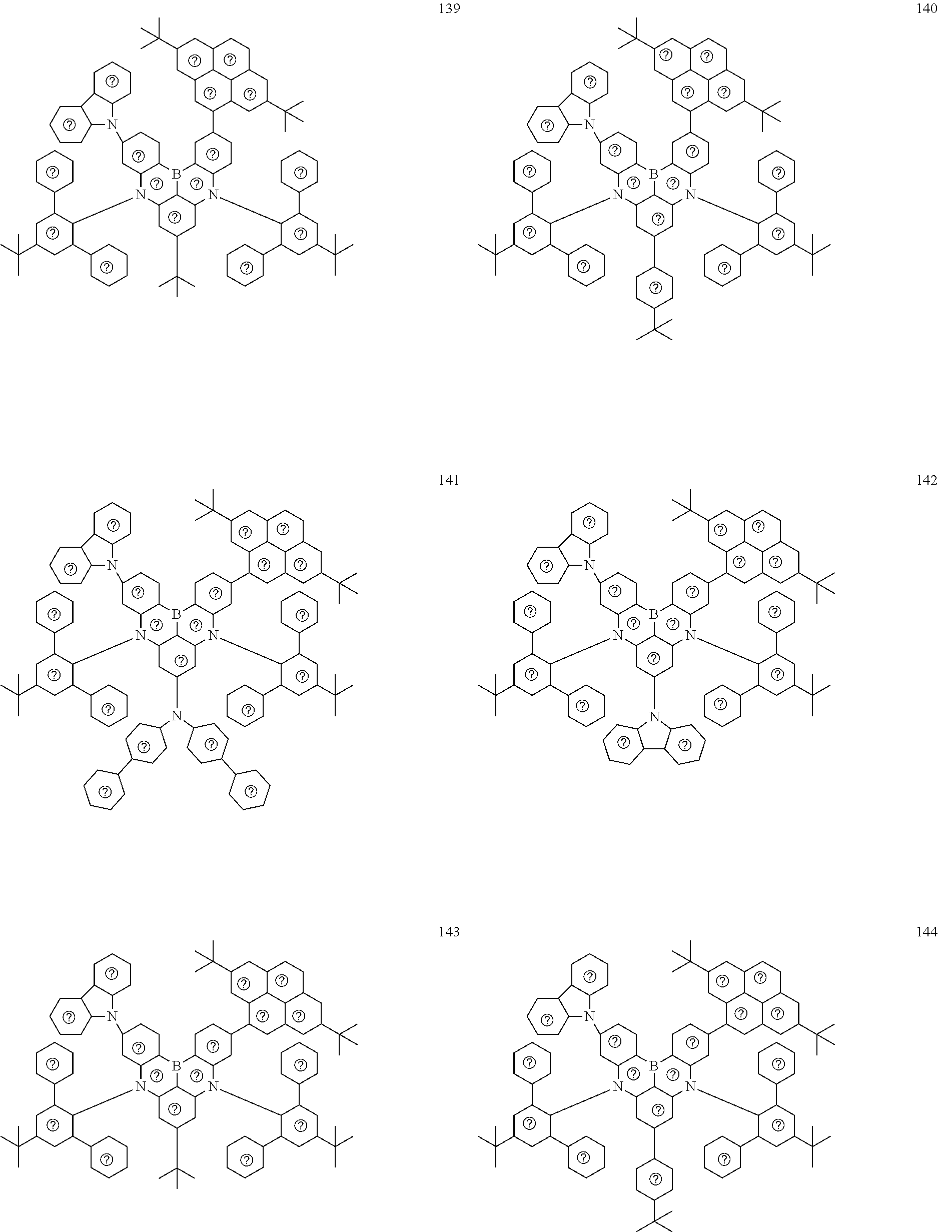 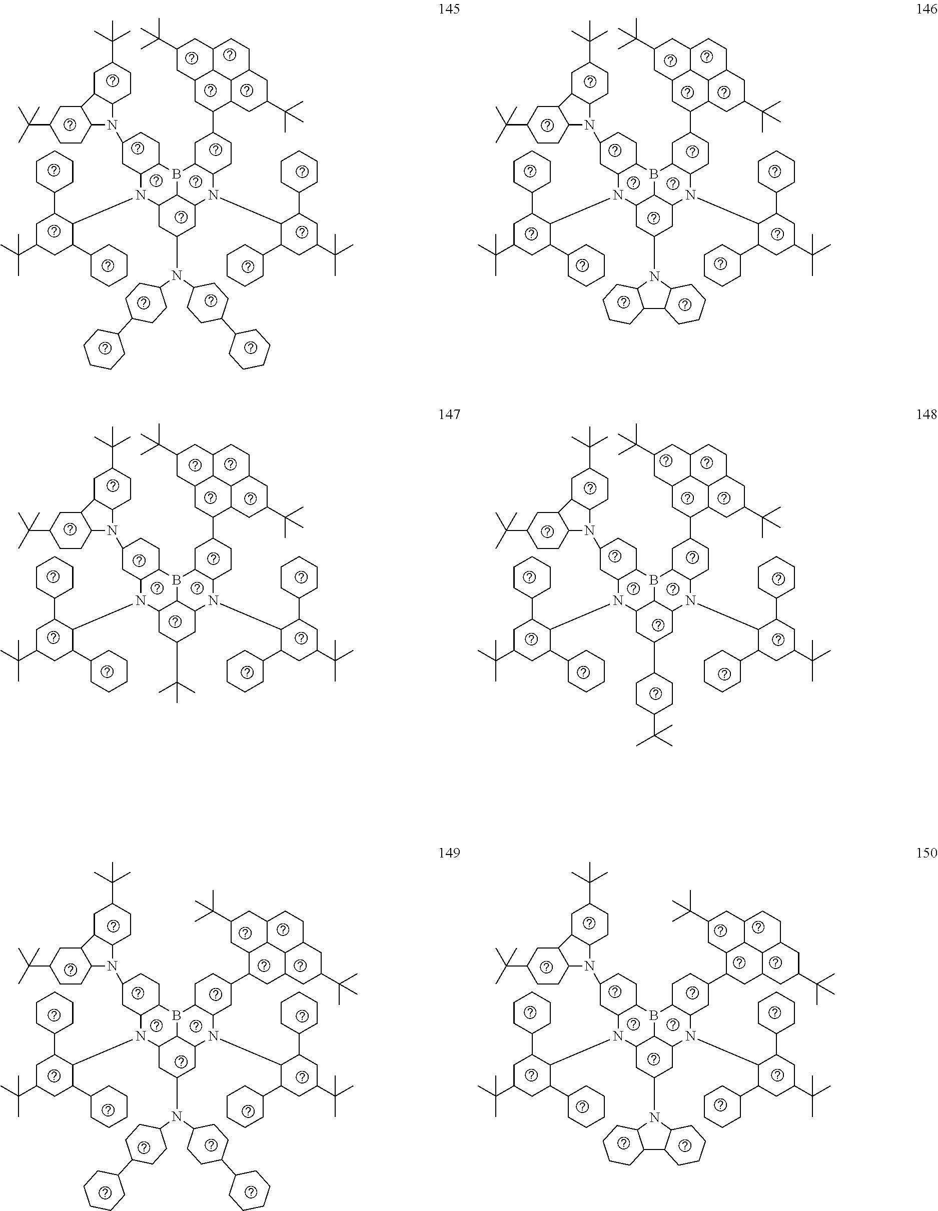 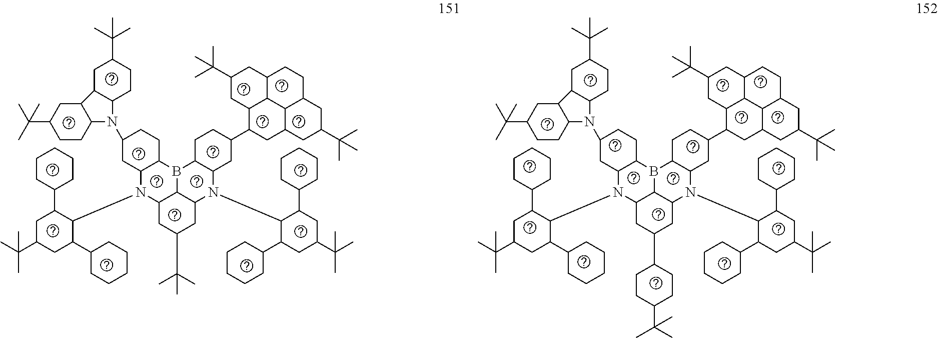 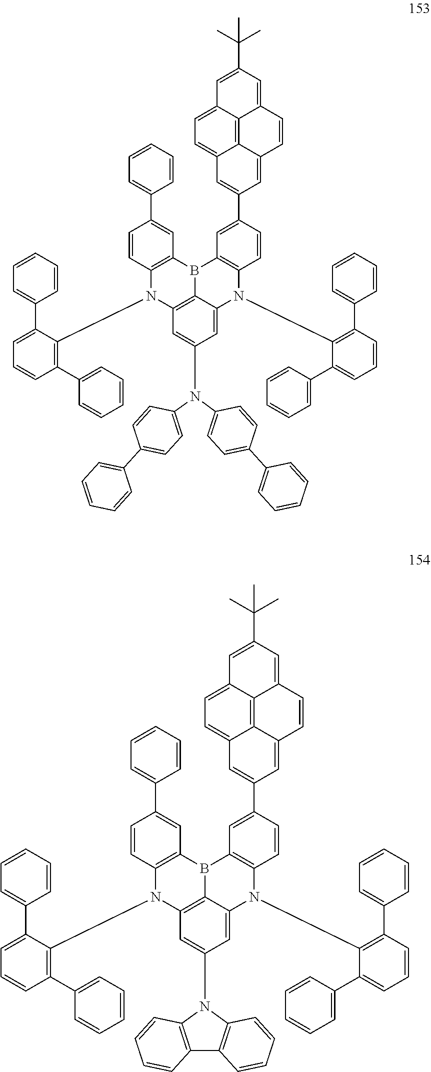 [SMILES: CC(C)(C)c1cc2ccc3cc(-c4ccc5c(c4)B4c6cc(-c7ccccc7)ccc6N(c6c(-c7ccccc7)cccc6-c6ccccc6)c6cc(N(c7ccc(-c8ccccc8)cc7)c7ccc(-c8ccccc8)cc7)cc(c64)N5c4c(-c5ccccc5)cccc4-c4ccccc4)cc4ccc(c1)c2c34 ; CC(C)(C)c1cc2ccc3cc(-c4ccc5c(c4)B4c6cc(-c7ccccc7)ccc6N(c6c(-c7ccccc7)cccc6-c6ccccc6)c6cc(-n7c8ccccc8c8ccccc87)cc(c64)N5c4c(-c5ccccc5)cccc4-c4ccccc4)cc4ccc(c1)c2c34] 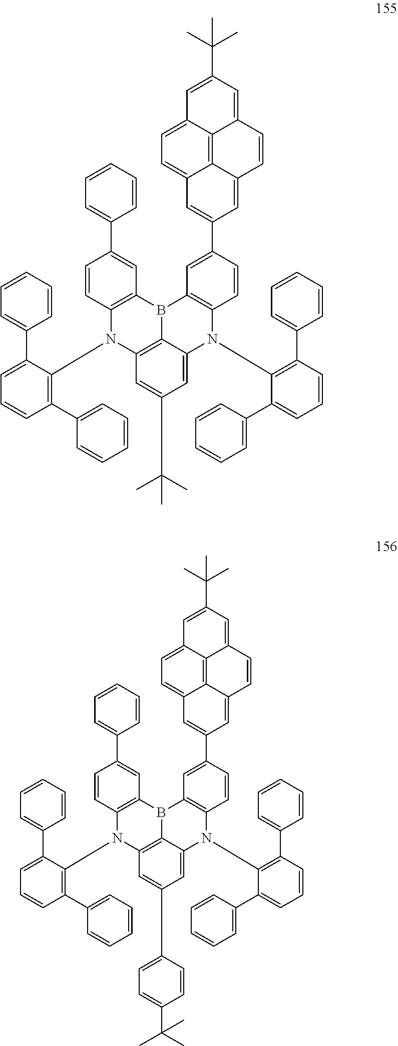 [SMILES: CC(C)(C)c1cc2c3c(c1)N(c1c(-c4ccccc4)cccc1-c1ccccc1)c1ccc(-c4cc5ccc6cc(C(C)(C)C)cc7ccc(c4)c5c67)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6ccc7cc(C(C)(C)C)cc8ccc(c5)c6c78)cc2B4c2cc(-c4ccccc4)ccc2N3c2c(-c3ccccc3)cccc2-c2ccccc2)cc1] 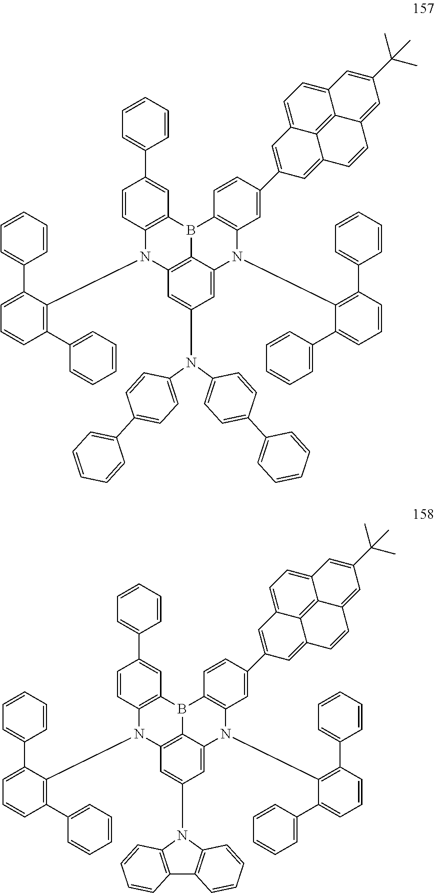 [SMILES: CC(C)(C)c1cc2ccc3cc(-c4ccc5c(c4)N(c4c(-c6ccccc6)cccc4-c4ccccc4)c4cc(N(c6ccc(-c7ccccc7)cc6)c6ccc(-c7ccccc7)cc6)cc6c4B5c4cc(-c5ccccc5)ccc4N6c4c(-c5ccccc5)cccc4-c4ccccc4)cc4ccc(c1)c2c34 ; CC(C)(C)c1cc2ccc3cc(-c4ccc5c(c4)N(c4c(-c6ccccc6)cccc4-c4ccccc4)c4cc(-n6c7ccccc7c7ccccc76)cc6c4B5c4cc(-c5ccccc5)ccc4N6c4c(-c5ccccc5)cccc4-c4ccccc4)cc4ccc(c1)c2c34] 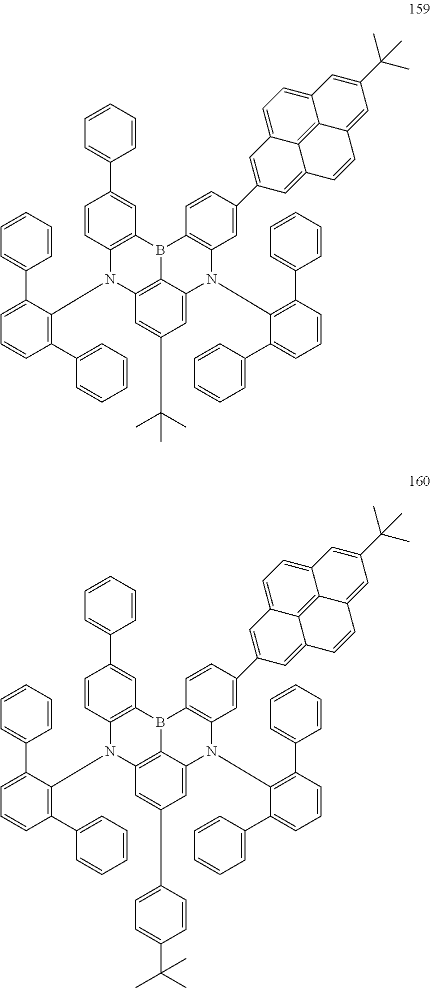 [SMILES: CC(C)(C)c1cc2c3c(c1)N(c1c(-c4ccccc4)cccc1-c1ccccc1)c1cc(-c4cc5ccc6cc(C(C)(C)C)cc7ccc(c4)c5c67)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5cc6ccc7cc(C(C)(C)C)cc8ccc(c5)c6c78)ccc2B4c2cc(-c4ccccc4)ccc2N3c2c(-c3ccccc3)cccc2-c2ccccc2)cc1] 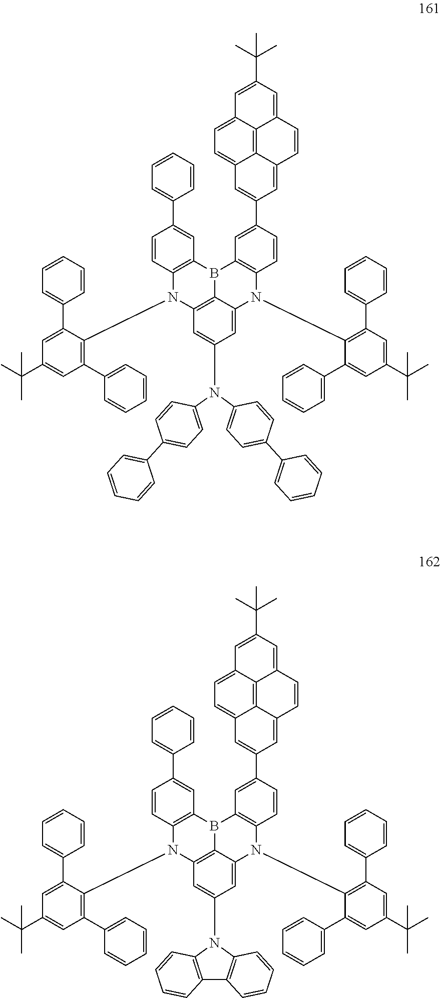 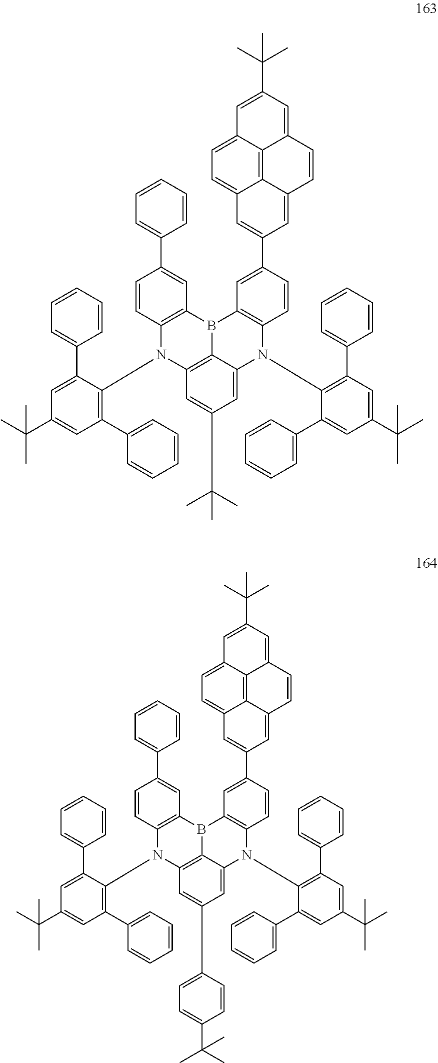 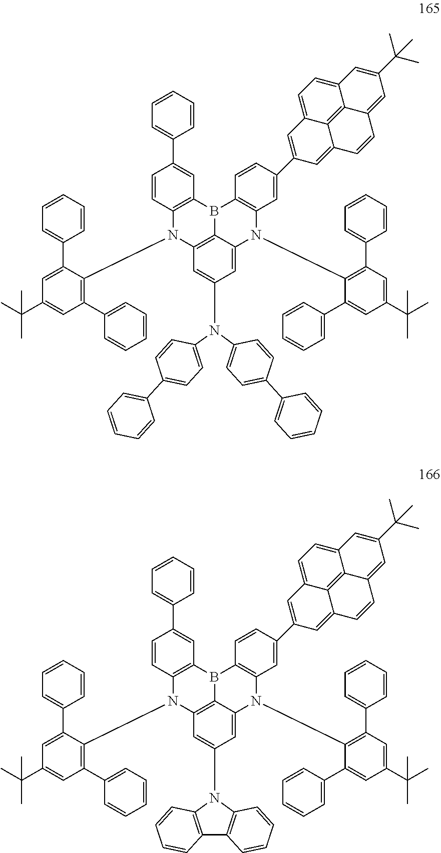 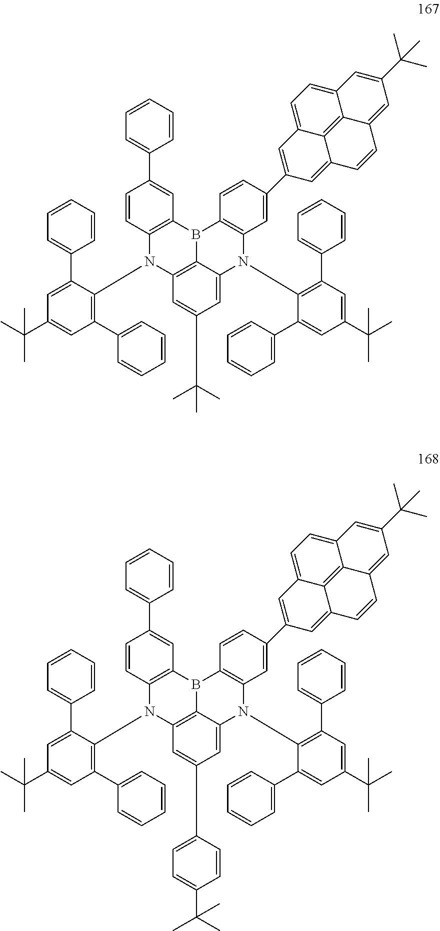 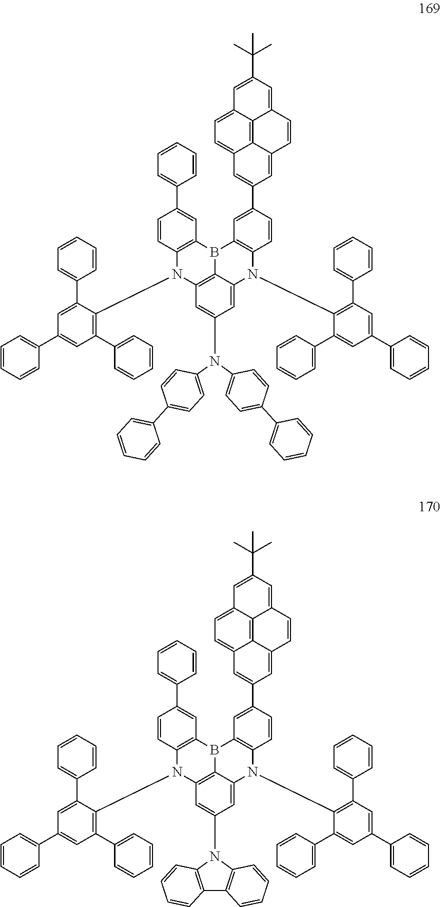 [SMILES: CC(C)(C)c1cc2ccc3cc(-c4ccc5c(c4)B4c6cc(-c7ccccc7)ccc6N(c6c(-c7ccccc7)cc(-c7ccccc7)cc6-c6ccccc6)c6cc(N(c7ccc(-c8ccccc8)cc7)c7ccc(-c8ccccc8)cc7)cc(c64)N5c4c(-c5ccccc5)cc(-c5ccccc5)cc4-c4ccccc4)cc4ccc(c1)c2c34 ; CC(C)(C)c1cc2ccc3cc(-c4ccc5c(c4)B4c6cc(-c7ccccc7)ccc6N(c6c(-c7ccccc7)cc(-c7ccccc7)cc6-c6ccccc6)c6cc(-n7c8ccccc8c8ccccc87)cc(c64)N5c4c(-c5ccccc5)cc(-c5ccccc5)cc4-c4ccccc4)cc4ccc(c1)c2c34] 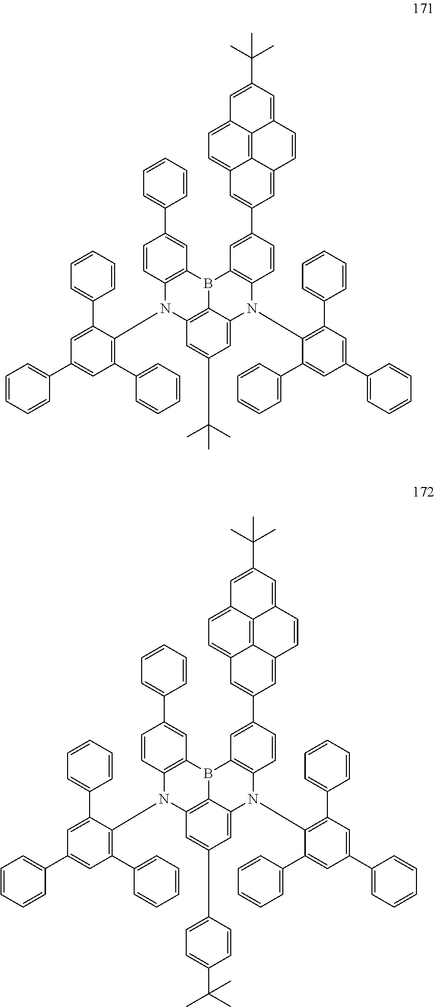 [SMILES: CC(C)(C)c1cc2c3c(c1)N(c1c(-c4ccccc4)cc(-c4ccccc4)cc1-c1ccccc1)c1ccc(-c4cc5ccc6cc(C(C)(C)C)cc7ccc(c4)c5c67)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5cc6ccc7cc(C(C)(C)C)cc8ccc(c5)c6c78)cc2B4c2cc(-c4ccccc4)ccc2N3c2c(-c3ccccc3)cc(-c3ccccc3)cc2-c2ccccc2)cc1] 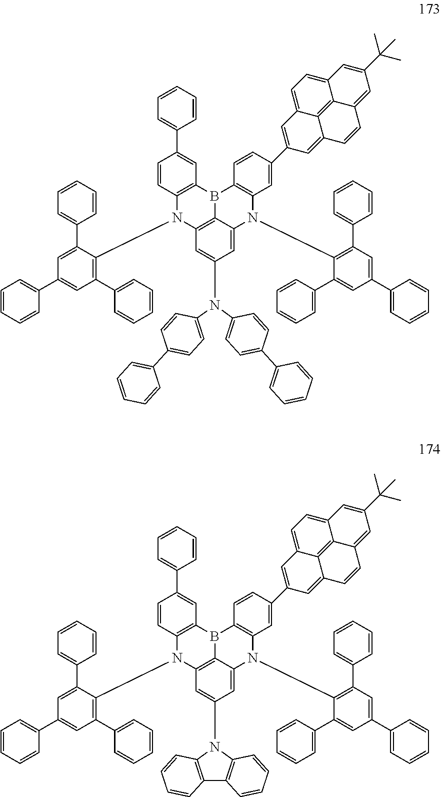 [SMILES: CC(C)(C)c1cc2ccc3cc(-c4ccc5c(c4)N(c4c(-c6ccccc6)cc(-c6ccccc6)cc4-c4ccccc4)c4cc(N(c6ccc(-c7ccccc7)cc6)c6ccc(-c7ccccc7)cc6)cc6c4B5c4cc(-c5ccccc5)ccc4N6c4c(-c5ccccc5)cc(-c5ccccc5)cc4-c4ccccc4)cc4ccc(c1)c2c34 ; CC(C)(C)c1cc2ccc3cc(-c4ccc5c(c4)N(c4c(-c6ccccc6)cc(-c6ccccc6)cc4-c4ccccc4)c4cc(-n6c7ccccc7c7ccccc76)cc6c4B5c4cc(-c5ccccc5)ccc4N6c4c(-c5ccccc5)cc(-c5ccccc5)cc4-c4ccccc4)cc4ccc(c1)c2c34] 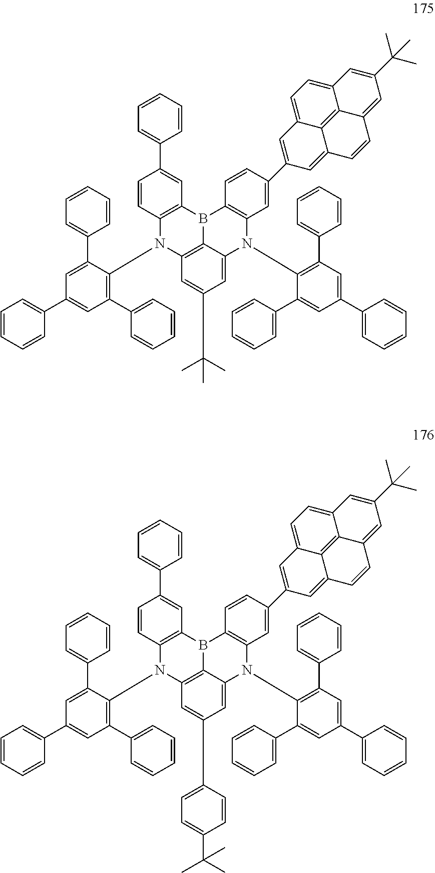 [SMILES: CC(C)(C)c1cc2c3c(c1)N(c1c(-c4ccccc4)cc(-c4ccccc4)cc1-c1ccccc1)c1cc(-c4cc5ccc6cc(C(C)(C)C)cc7ccc(c4)c5c67)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5cc6ccc7cc(C(C)(C)C)cc8ccc(c5)c6c78)ccc2B4c2cc(-c4ccccc4)ccc2N3c2c(-c3ccccc3)cc(-c3ccccc3)cc2-c2ccccc2)cc1] 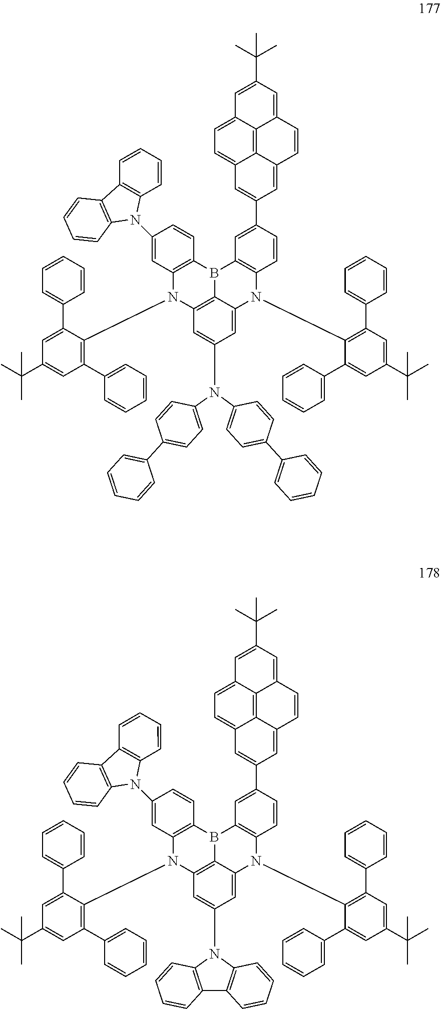 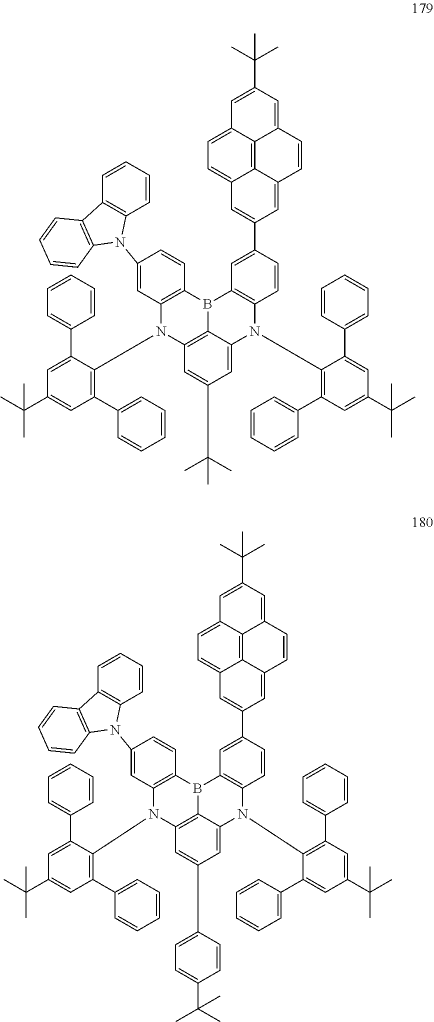 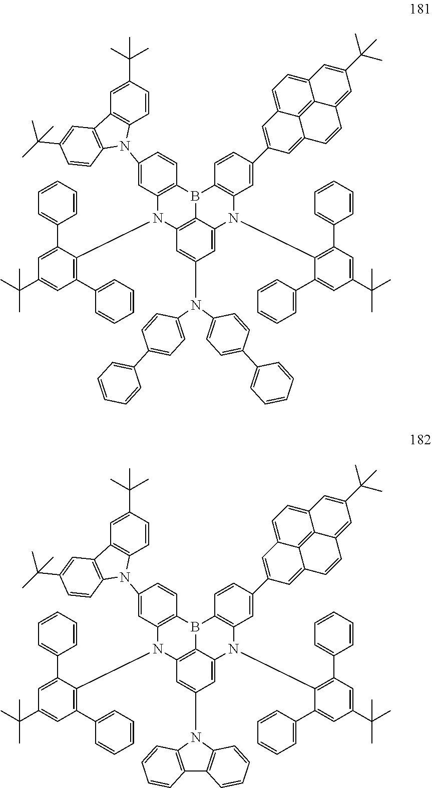 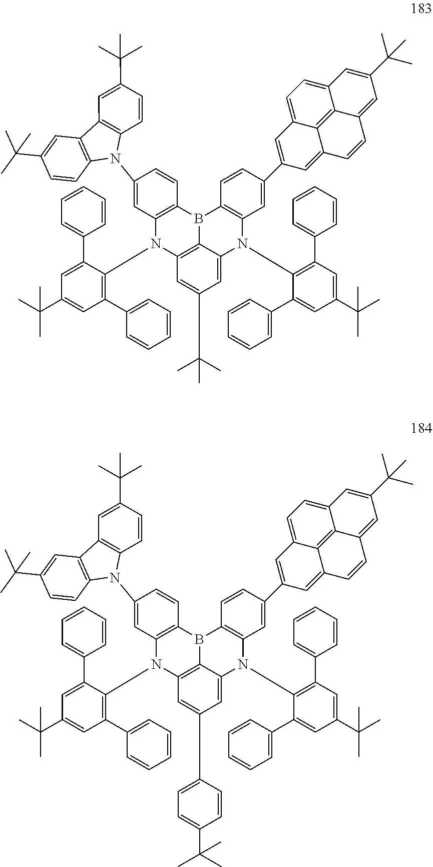 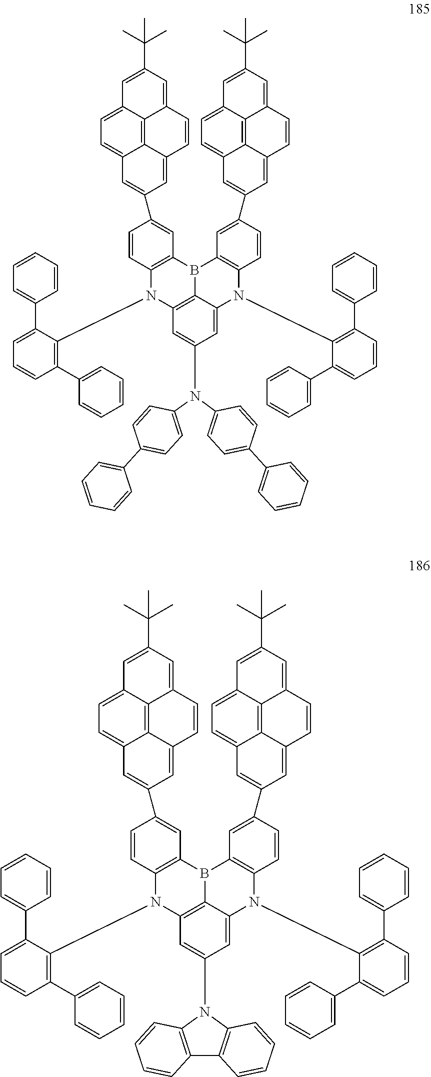 [SMILES: CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cccc6-c6ccccc6)c6cc(N(c7ccc(-c8ccccc8)cc7)c7ccc(-c8ccccc8)cc7)cc(c64)N5c4c(-c5ccccc5)cccc4-c4ccccc4)cc4ccc(c1)c2c34 ; CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cccc6-c6ccccc6)c6cc(-n7c8ccccc8c8ccccc87)cc(c64)N5c4c(-c5ccccc5)cccc4-c4ccccc4)cc4ccc(c1)c2c34] 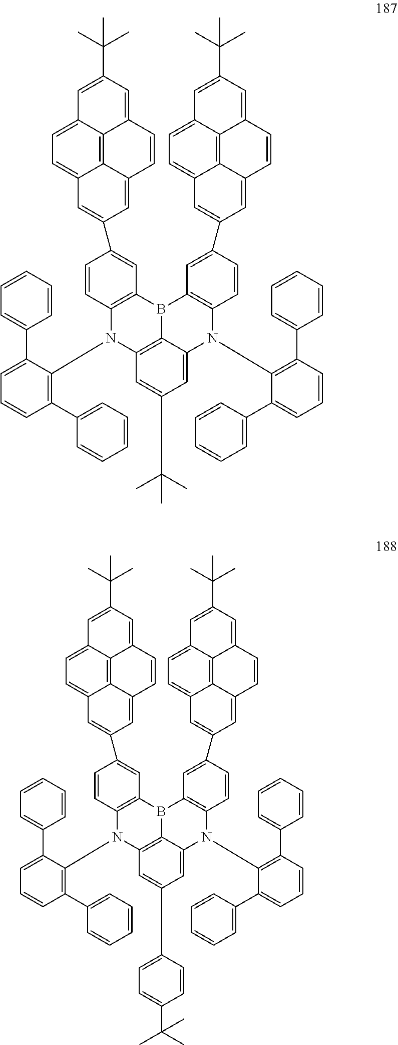 [SMILES: CC(C)(C)c1cc2c3c(c1)N(c1c(-c4ccccc4)cccc1-c1ccccc1)c1ccc(-c4cc5ccc6cc(C(C)(C)C)cc7ccc(c4)c5c67)cc1B3c1cc(-c3cc4ccc5cc(C(C)(C)C)cc6ccc(c3)c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5cc6ccc7cc(C(C)(C)C)cc8ccc(c5)c6c78)cc2B4c2cc(-c4cc5ccc6cc(C(C)(C)C)cc7ccc(c4)c5c67)ccc2N3c2c(-c3ccccc3)cccc2-c2ccccc2)cc1] 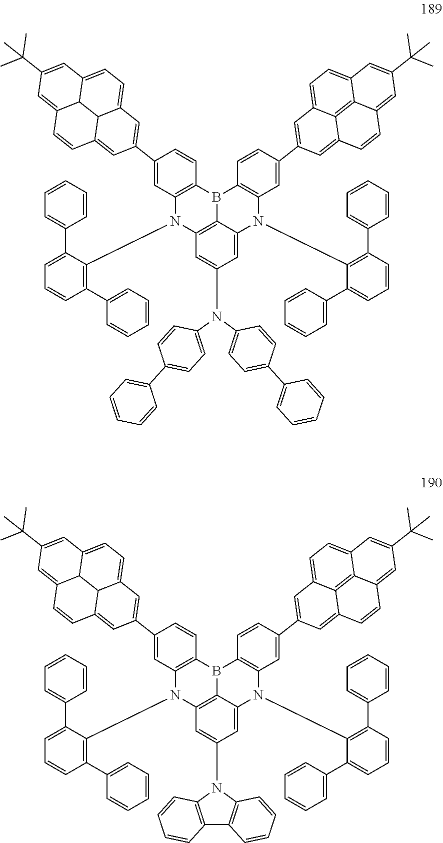 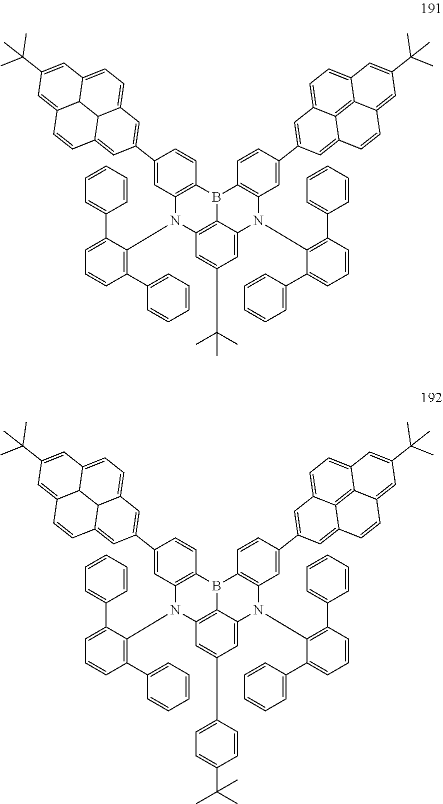 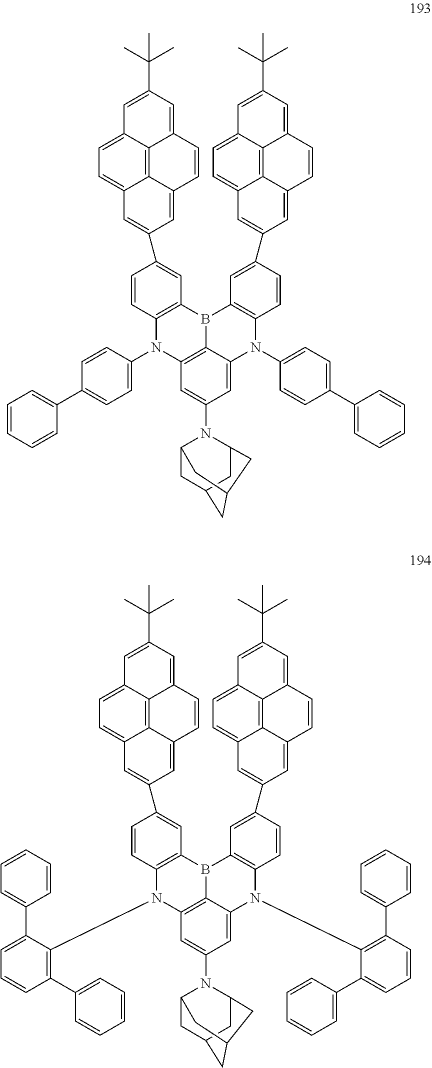 [SMILES: CC(C)(C)c1cc2ccc3cc(-c4ccc5c(c4)B4c6cc(-c7cc8ccc9cc(C(C)(C)C)cc%10ccc(c7)c8c9%10)ccc6N(c6ccc(-c7ccccc7)cc6)c6cc(N7C8CC9CC(C8)CC7C9)cc(c64)N5c4ccc(-c5ccccc5)cc4)cc4ccc(c1)c2c34 ; CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cccc6-c6ccccc6)c6cc(N7C8CC9CC(C8)CC7C9)cc(c64)N5c4c(-c5ccccc5)cccc4-c4ccccc4)cc4ccc(c1)c2c34] 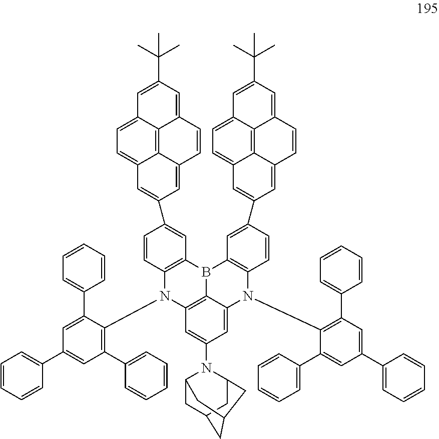 [SMILES: CC(C)(C)c1cc2ccc3cc(-c4ccc5c(c4)B4c6cc(-c7cc8ccc9cc(C(C)(C)C)cc%10ccc(c7)c8c9%10)ccc6N(c6c(-c7ccccc7)cc(-c7ccccc7)cc6-c6ccccc6)c6cc(N7C8CC9CC(C8)CC7C9)cc(c64)N5c4c(-c5ccccc5)cc(-c5ccccc5)cc4-c4ccccc4)cc4ccc(c1)c2c34] 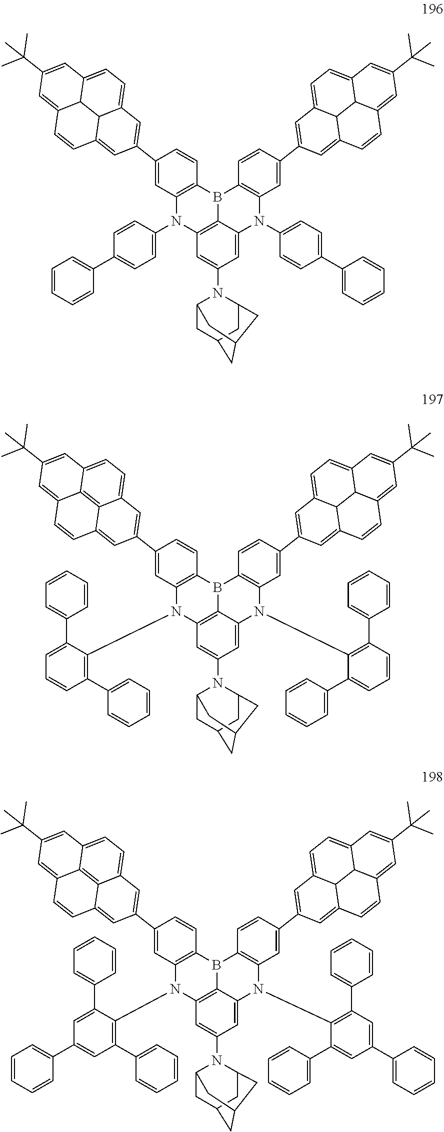 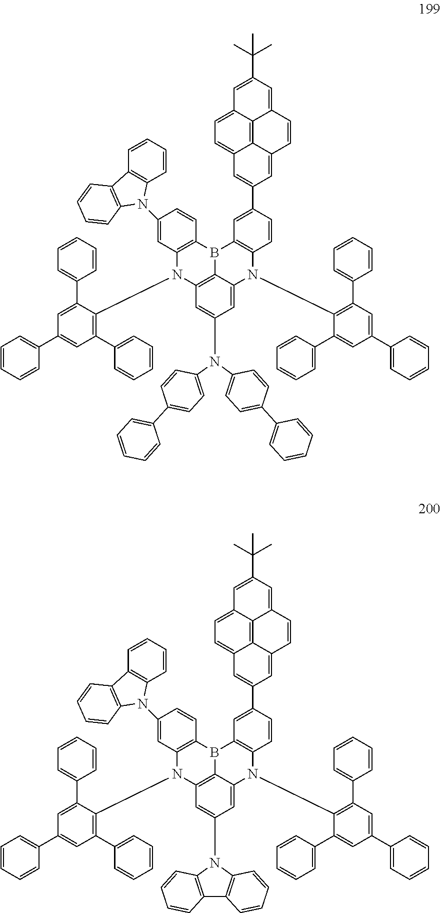 [SMILES: CC(C)(C)c1cc2ccc3cc(-c4ccc5c(c4)B4c6ccc(-n7c8ccccc8c8ccccc87)cc6N(c6c(-c7ccccc7)cc(-c7ccccc7)cc6-c6ccccc6)c6cc(N(c7ccc(-c8ccccc8)cc7)c7ccc(-c8ccccc8)cc7)cc(c64)N5c4c(-c5ccccc5)cc(-c5ccccc5)cc4-c4ccccc4)cc4ccc(c1)c2c34 ; CC(C)(C)c1cc2ccc3cc(-c4ccc5c(c4)B4c6ccc(-n7c8ccccc8c8ccccc87)cc6N(c6c(-c7ccccc7)cc(-c7ccccc7)cc6-c6ccccc6)c6cc(-n7c8ccccc8c8ccccc87)cc(c64)N5c4c(-c5ccccc5)cc(-c5ccccc5)cc4-c4ccccc4)cc4ccc(c1)c2c34] 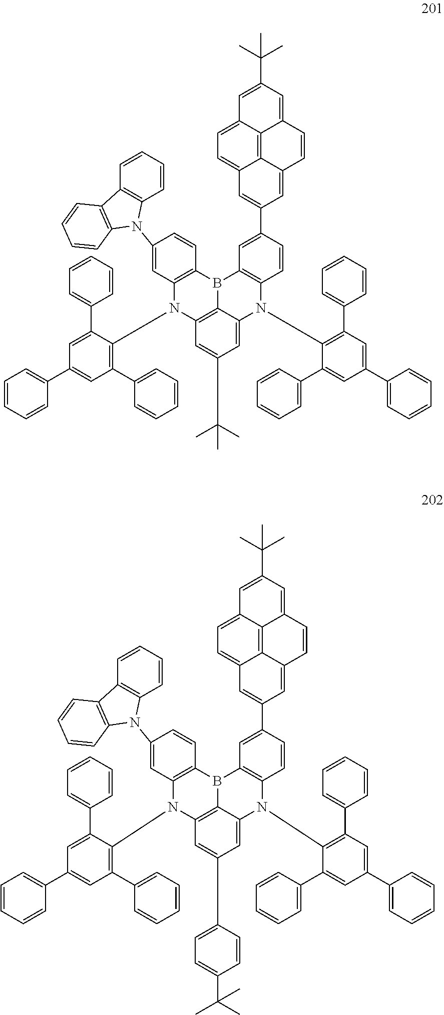 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1cc(-c3cc4ccc5cc(C(C)(C)C)cc6ccc(c3)c4c56)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4cc5ccc6cc(C(C)(C)C)cc7ccc(c4)c5c67)ccc2N3c2c(-c3ccccc3)cc(-c3ccccc3)cc2-c2ccccc2)cc1] 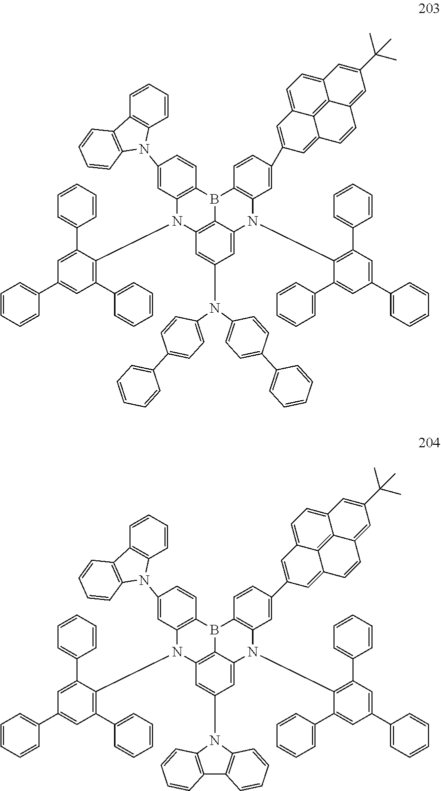 [SMILES: CC(C)(C)c1cc2ccc3cc(-c4ccc5c(c4)N(c4c(-c6ccccc6)cc(-c6ccccc6)cc4-c4ccccc4)c4cc(N(c6ccc(-c7ccccc7)cc6)c6ccc(-c7ccccc7)cc6)cc6c4B5c4ccc(-n5c7ccccc7c7ccccc75)cc4N6c4c(-c5ccccc5)cc(-c5ccccc5)cc4-c4ccccc4)cc4ccc(c1)c2c34 ; CC(C)(C)c1cc2ccc3cc(-c4ccc5c(c4)N(c4c(-c6ccccc6)cc(-c6ccccc6)cc4-c4ccccc4)c4cc(-n6c7ccccc7c7ccccc76)cc6c4B5c4ccc(-n5c7ccccc7c7ccccc75)cc4N6c4c(-c5ccccc5)cc(-c5ccccc5)cc4-c4ccccc4)cc4ccc(c1)c2c34] 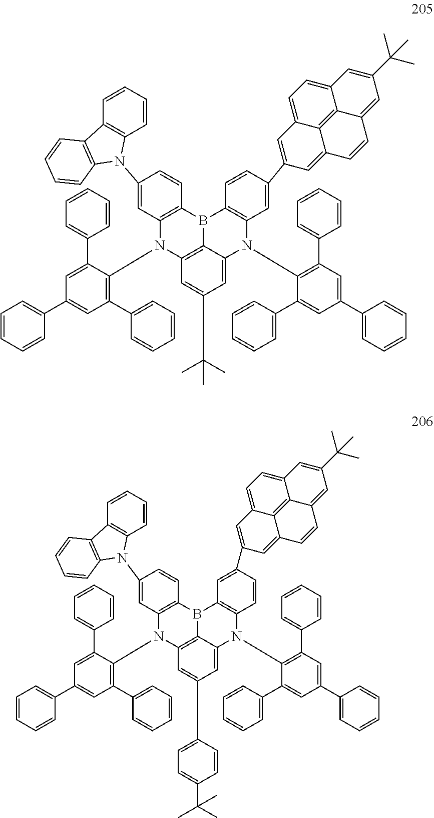 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc(-c3cc4ccc5cc(C(C)(C)C)cc6ccc(c3)c4c56)cc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4cc5ccc6cc(C(C)(C)C)cc7ccc(c4)c5c67)ccc2N3c2c(-c3ccccc3)cc(-c3ccccc3)cc2-c2ccccc2)cc1] 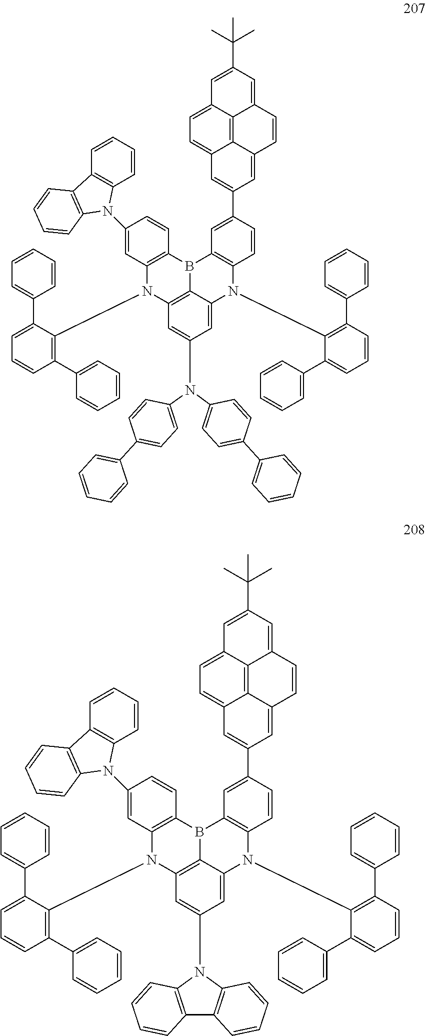 [SMILES: CC(C)(C)c1cc2ccc3cc(-c4ccc5c(c4)B4c6ccc(-n7c8ccccc8c8ccccc87)cc6N(c6c(-c7ccccc7)cccc6-c6ccccc6)c6cc(N(c7ccc(-c8ccccc8)cc7)c7ccc(-c8ccccc8)cc7)cc(c64)N5c4c(-c5ccccc5)cccc4-c4ccccc4)cc4ccc(c1)c2c34 ; CC(C)(C)c1cc2ccc3cc(-c4ccc5c(c4)B4c6ccc(-n7c8ccccc8c8ccccc87)cc6N(c6c(-c7ccccc7)cccc6-c6ccccc6)c6cc(-n7c8ccccc8c8ccccc87)cc(c64)N5c4c(-c5ccccc5)cccc4-c4ccccc4)cc4ccc(c1)c2c34] 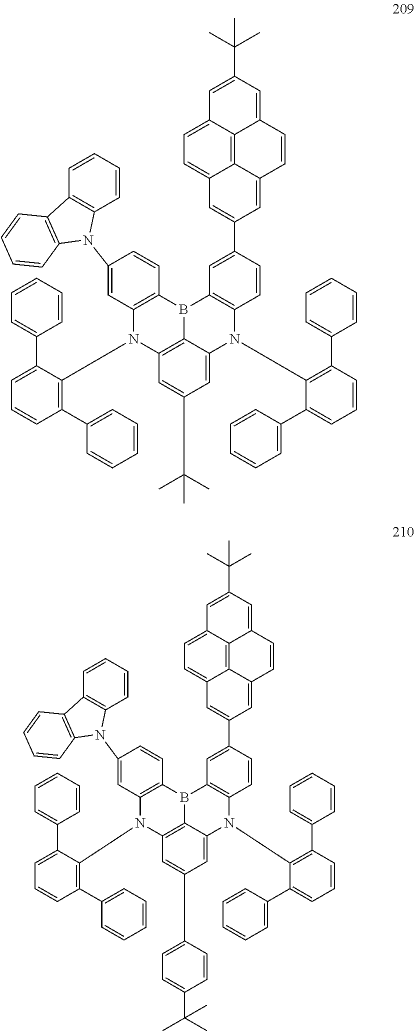 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3cc4ccc5cc(C(C)(C)C)cc6ccc(c3)c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4cc5ccc6cc(C(C)(C)C)cc7ccc(c4)c5c67)ccc2N3c2c(-c3ccccc3)cccc2-c2ccccc2)cc1] 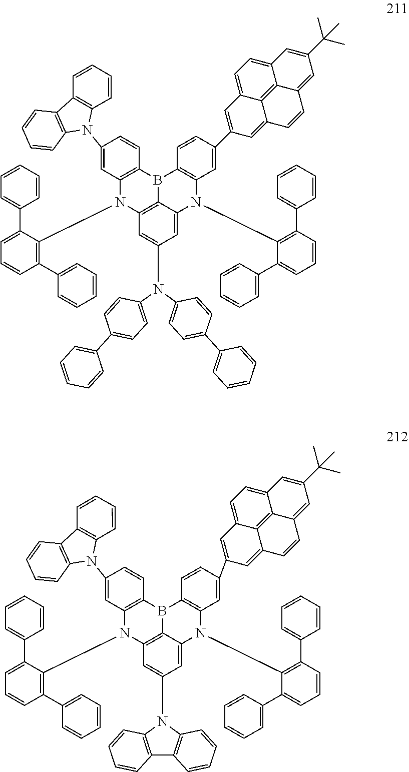 [SMILES: CC(C)(C)c1cc2ccc3cc(-c4ccc5c(c4)N(c4c(-c6ccccc6)cccc4-c4ccccc4)c4cc(N(c6ccc(-c7ccccc7)cc6)c6ccc(-c7ccccc7)cc6)cc6c4B5c4ccc(-n5c7ccccc7c7ccccc75)cc4N6c4c(-c5ccccc5)cccc4-c4ccccc4)cc4ccc(c1)c2c34 ; CC(C)(C)c1cc2ccc3cc(-c4ccc5c(c4)N(c4c(-c6ccccc6)cccc4-c4ccccc4)c4cc(-n6c7ccccc7c7ccccc76)cc6c4B5c4ccc(-n5c7ccccc7c7ccccc75)cc4N6c4c(-c5ccccc5)cccc4-c4ccccc4)cc4ccc(c1)c2c34] 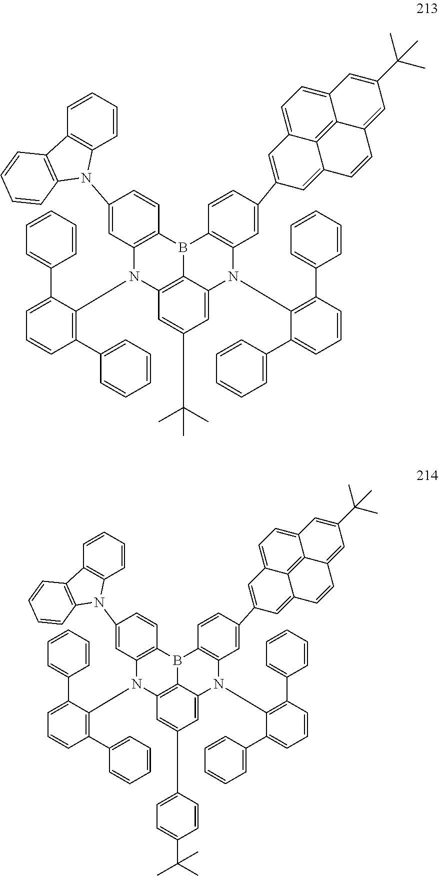 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-c3cc4ccc5cc(C(C)(C)C)cc6ccc(c3)c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4cc5ccc6cc(C(C)(C)C)cc7ccc(c4)c5c67)cc2N3c2c(-c3ccccc3)cccc2-c2ccccc2)cc1] 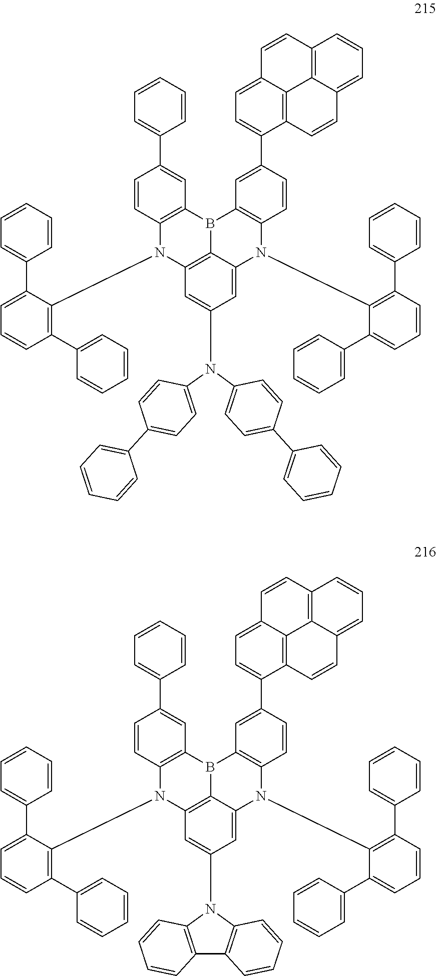 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7ccc8cccc9ccc6c7c89)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5ccc6ccc7cccc8ccc5c6c78)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 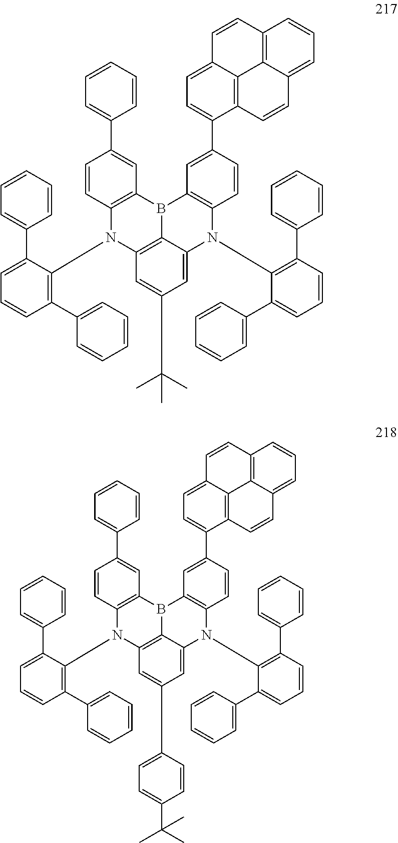 [SMILES: CC(C)(C)c1cc2c3c(c1)N(c1c(-c4ccccc4)cccc1-c1ccccc1)c1ccc(-c4ccc5ccc6cccc7ccc4c5c67)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6ccc7cccc8ccc5c6c78)cc2B4c2cc(-c4ccccc4)ccc2N3c2c(-c3ccccc3)cccc2-c2ccccc2)cc1] 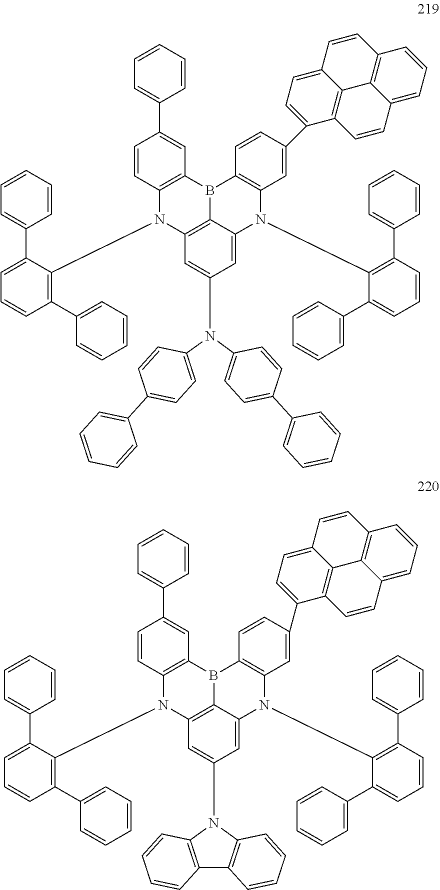 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7ccc8cccc9ccc6c7c89)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5ccc6ccc7cccc8ccc5c6c78)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 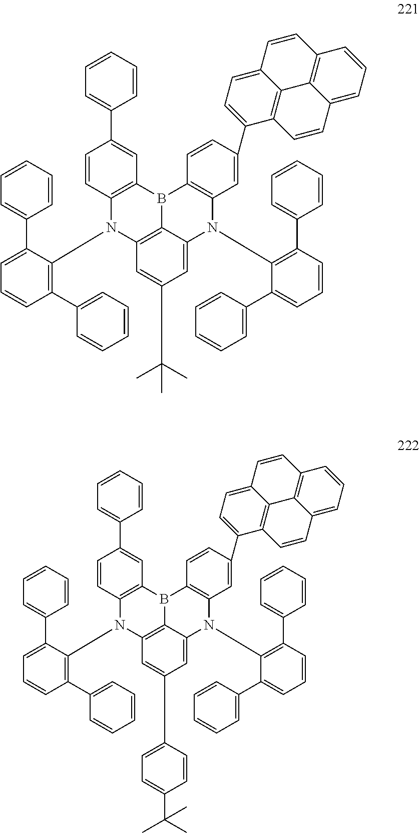 [SMILES: CC(C)(C)c1cc2c3c(c1)N(c1c(-c4ccccc4)cccc1-c1ccccc1)c1cc(-c4ccc5ccc6cccc7ccc4c5c67)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6ccc7cccc8ccc5c6c78)ccc2B4c2cc(-c4ccccc4)ccc2N3c2c(-c3ccccc3)cccc2-c2ccccc2)cc1] 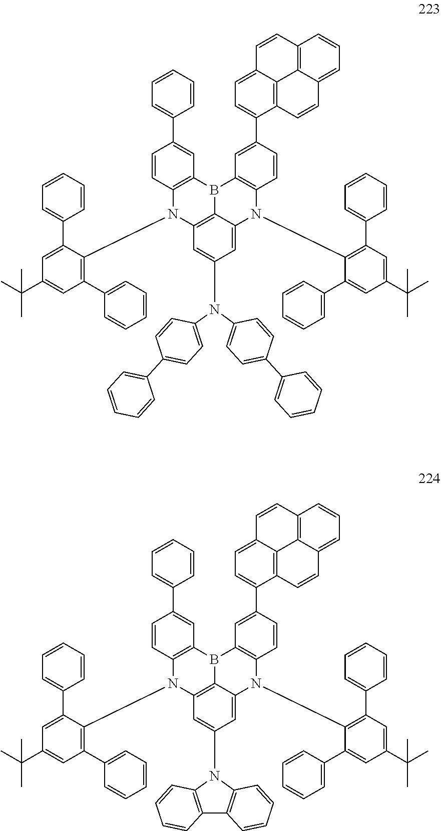 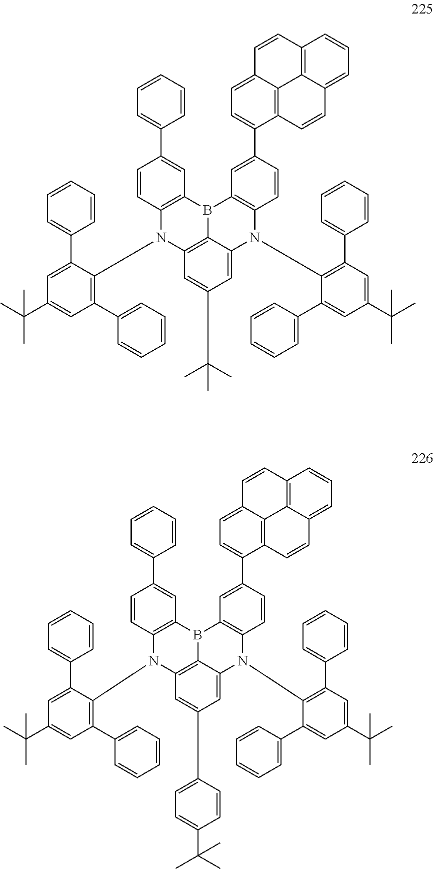 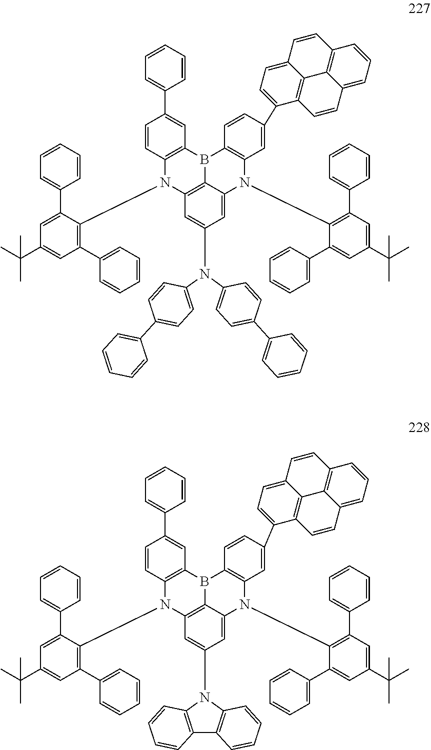 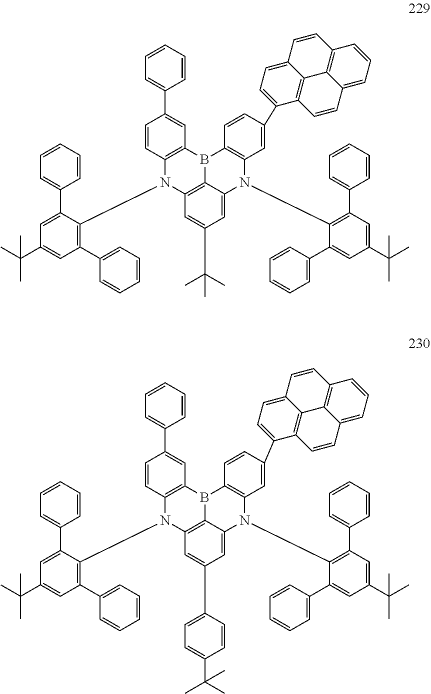 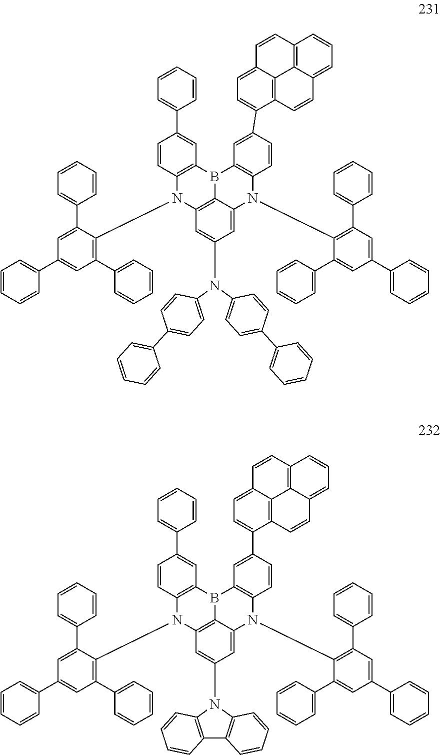 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccc7ccc8cccc9ccc6c7c89)cc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4cc(-c5ccc6ccc7cccc8ccc5c6c78)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1] 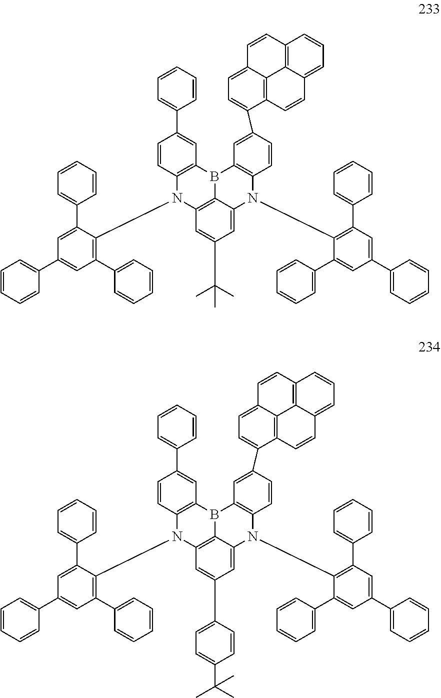 [SMILES: CC(C)(C)c1cc2c3c(c1)N(c1c(-c4ccccc4)cc(-c4ccccc4)cc1-c1ccccc1)c1ccc(-c4ccc5ccc6cccc7ccc4c5c67)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5ccc6ccc7cccc8ccc5c6c78)cc2B4c2cc(-c4ccccc4)ccc2N3c2c(-c3ccccc3)cc(-c3ccccc3)cc2-c2ccccc2)cc1] 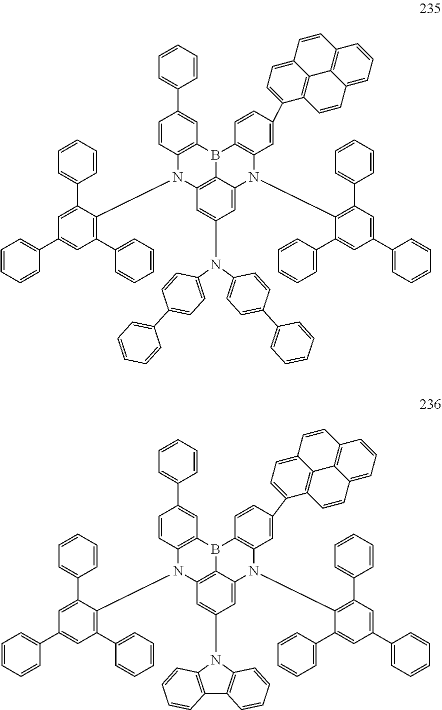 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-c6ccc7ccc8cccc9ccc6c7c89)ccc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4ccc(-c5ccc6ccc7cccc8ccc5c6c78)cc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1] 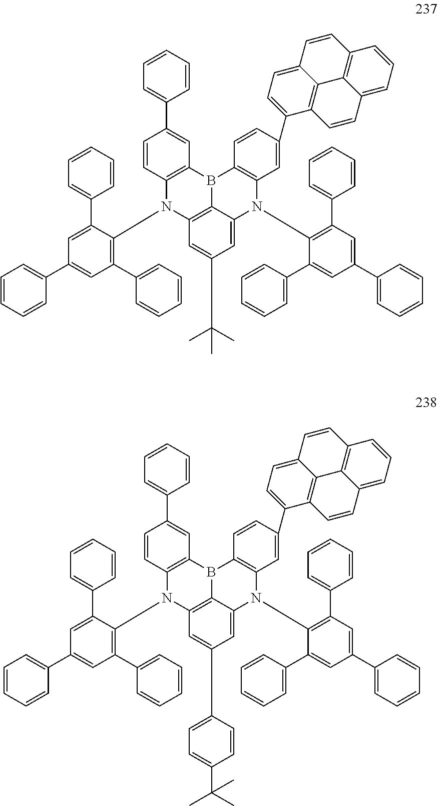 [SMILES: CC(C)(C)c1cc2c3c(c1)N(c1c(-c4ccccc4)cc(-c4ccccc4)cc1-c1ccccc1)c1cc(-c4ccc5ccc6cccc7ccc4c5c67)ccc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-c5ccc6ccc7cccc8ccc5c6c78)ccc2B4c2cc(-c4ccccc4)ccc2N3c2c(-c3ccccc3)cc(-c3ccccc3)cc2-c2ccccc2)cc1] 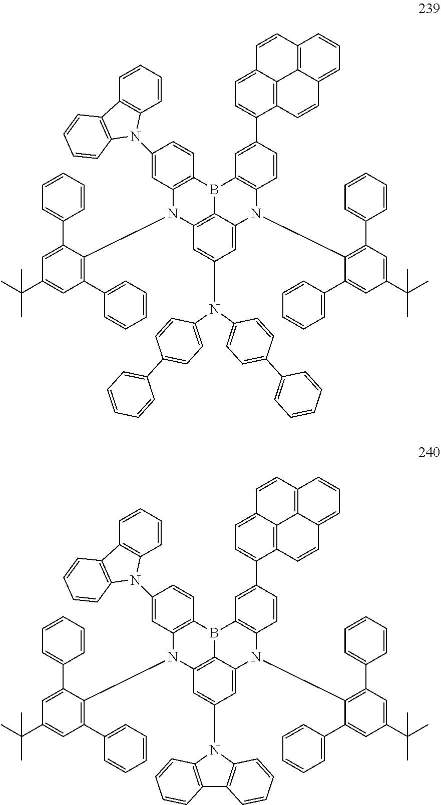 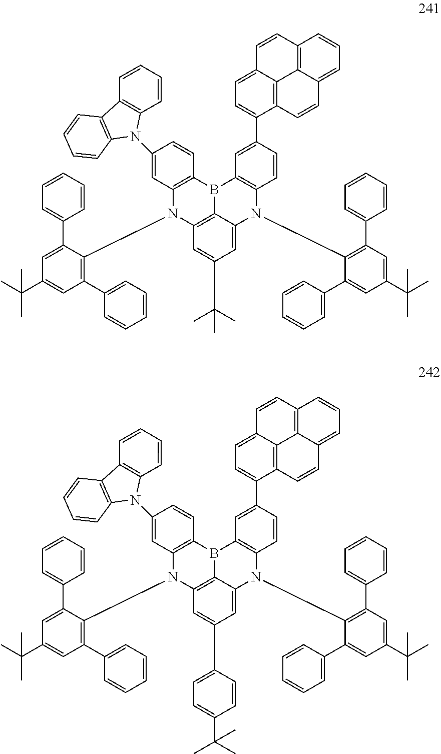 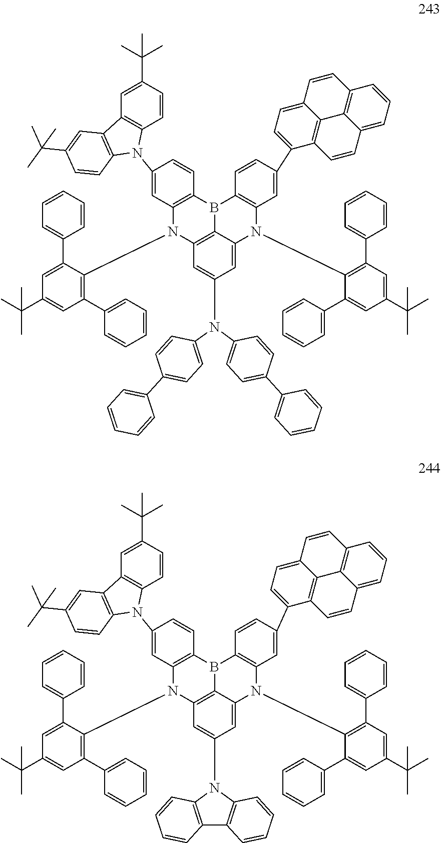 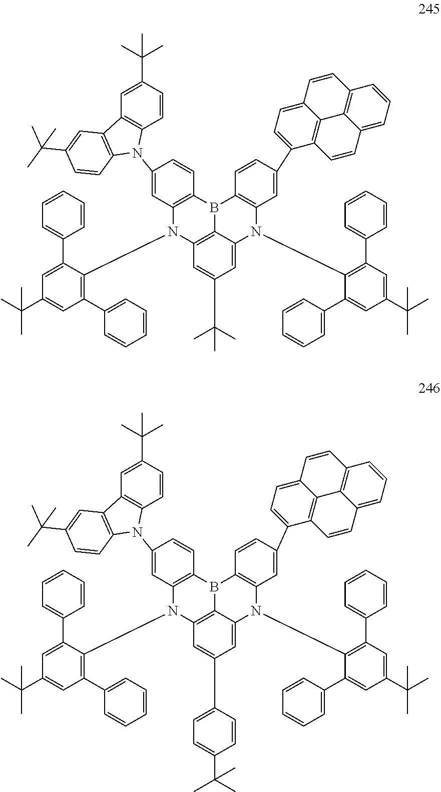 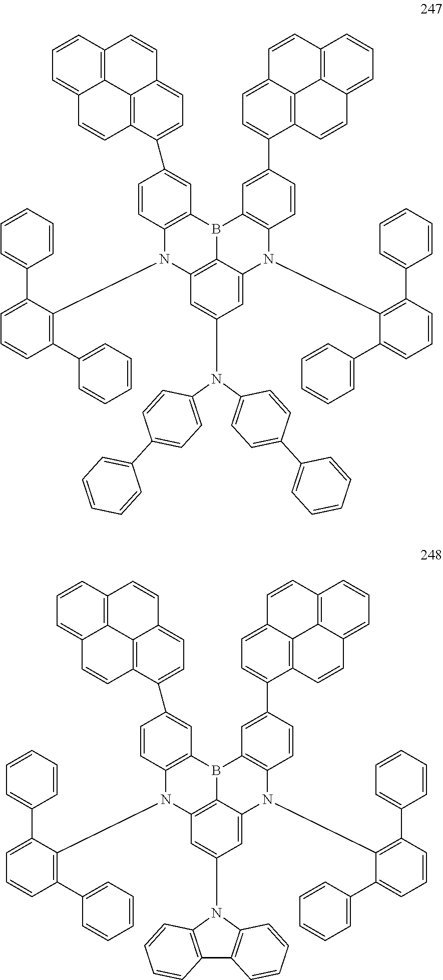 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7ccc8cccc9ccc6c7c89)cc3B5c3cc(-c5ccc6ccc7cccc8ccc5c6c78)ccc3N4c3c(-c4ccccc4)cccc3-c3ccccc3)cc2)cc1 ; c1ccc(-c2cccc(-c3ccccc3)c2N2c3ccc(-c4ccc5ccc6cccc7ccc4c5c67)cc3B3c4cc(-c5ccc6ccc7cccc8ccc5c6c78)ccc4N(c4c(-c5ccccc5)cccc4-c4ccccc4)c4cc(-n5c6ccccc6c6ccccc65)cc2c43)cc1] 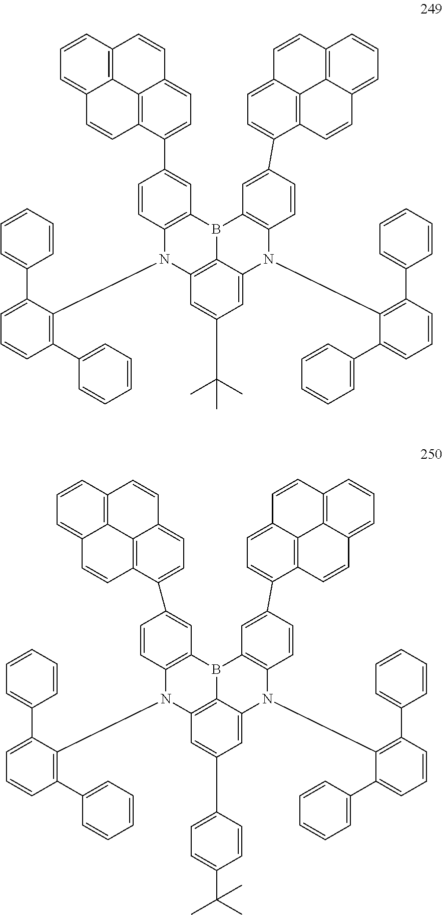 [SMILES: CC(C)(C)c1cc2c3c(c1)N(c1c(-c4ccccc4)cccc1-c1ccccc1)c1ccc(-c4ccc5ccc6cccc7ccc4c5c67)cc1B3c1cc(-c3ccc4ccc5cccc6ccc3c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6ccc7cccc8ccc5c6c78)cc2B4c2cc(-c4ccc5ccc6cccc7ccc4c5c67)ccc2N3c2c(-c3ccccc3)cccc2-c2ccccc2)cc1] 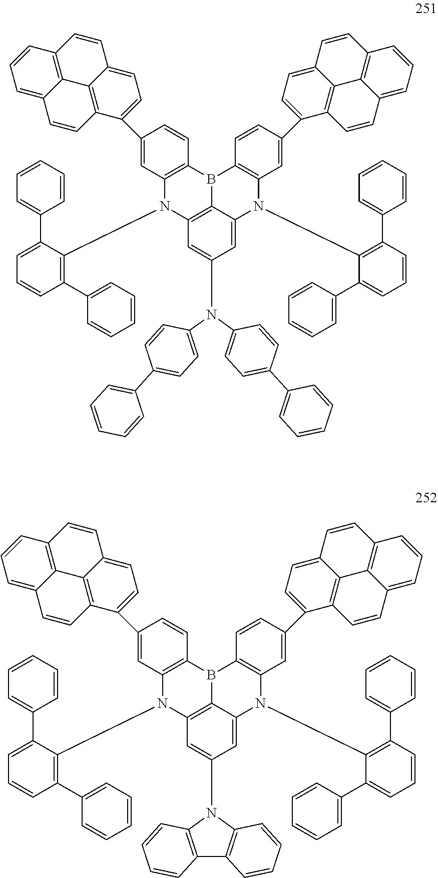 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7ccc8cccc9ccc6c7c89)ccc3B5c3ccc(-c5ccc6ccc7cccc8ccc5c6c78)cc3N4c3c(-c4ccccc4)cccc3-c3ccccc3)cc2)cc1 ; c1ccc(-c2cccc(-c3ccccc3)c2N2c3cc(-c4ccc5ccc6cccc7ccc4c5c67)ccc3B3c4ccc(-c5ccc6ccc7cccc8ccc5c6c78)cc4N(c4c(-c5ccccc5)cccc4-c4ccccc4)c4cc(-n5c6ccccc6c6ccccc65)cc2c43)cc1] 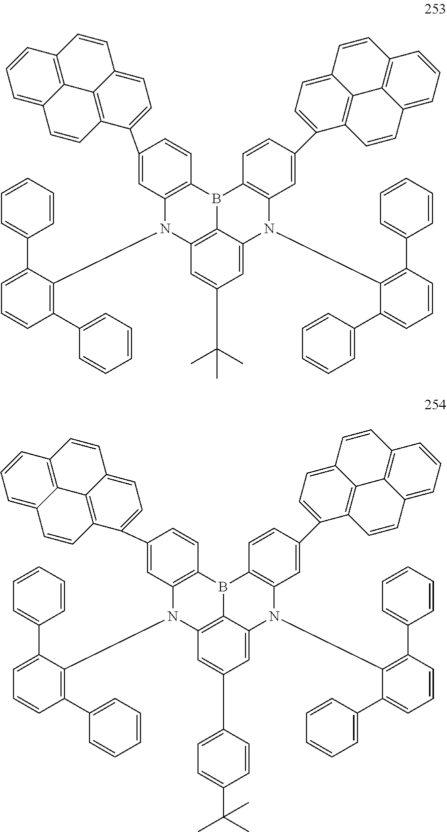 [SMILES: CC(C)(C)c1cc2c3c(c1)N(c1c(-c4ccccc4)cccc1-c1ccccc1)c1cc(-c4ccc5ccc6cccc7ccc4c5c67)ccc1B3c1ccc(-c3ccc4ccc5cccc6ccc3c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6ccc7cccc8ccc5c6c78)ccc2B4c2ccc(-c4ccc5ccc6cccc7ccc4c5c67)cc2N3c2c(-c3ccccc3)cccc2-c2ccccc2)cc1] 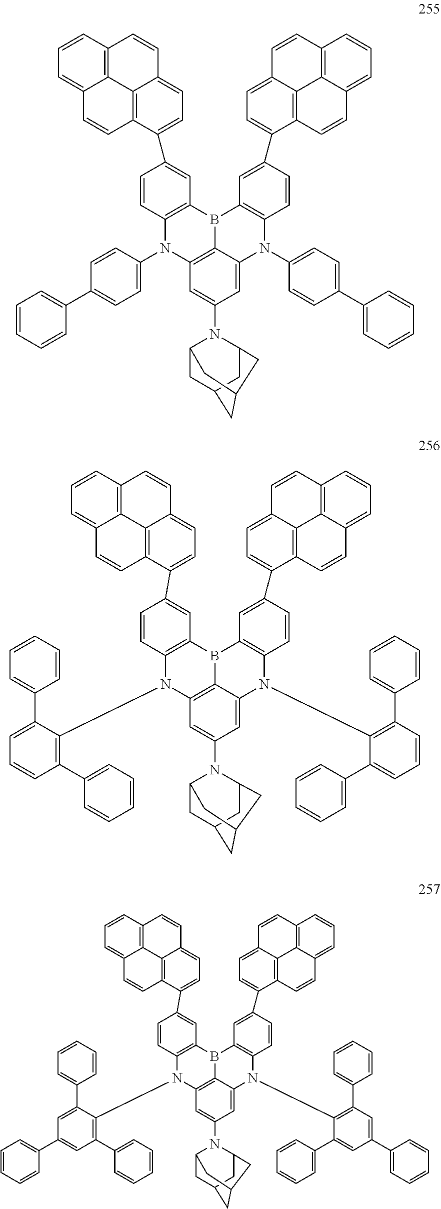 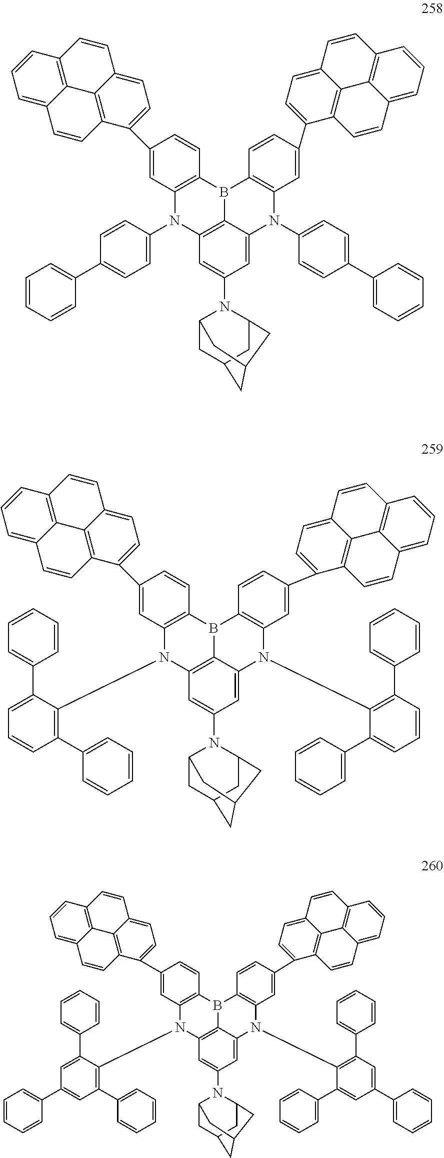 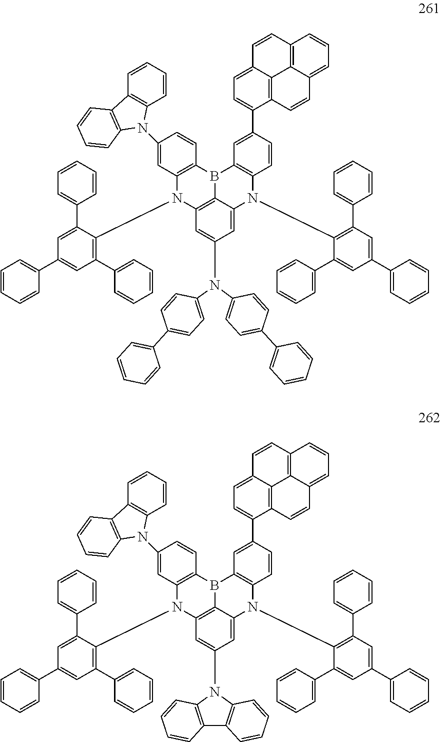 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3cc(-c5ccc6ccc7cccc8ccc5c6c78)ccc3N4c3c(-c4ccccc4)cc(-c4ccccc4)cc3-c3ccccc3)cc2)cc1 ; c1ccc(-c2cc(-c3ccccc3)c(N3c4ccc(-c5ccc6ccc7cccc8ccc5c6c78)cc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1] 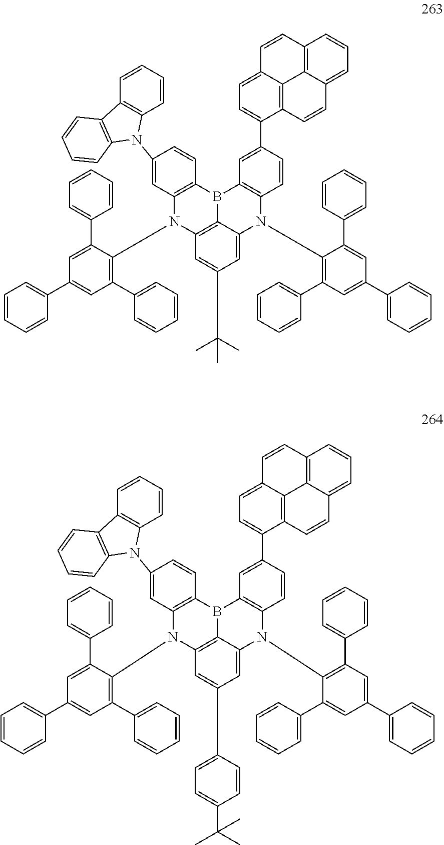 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1cc(-c3ccc4ccc5cccc6ccc3c4c56)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2cc(-c4ccc5ccc6cccc7ccc4c5c67)ccc2N3c2c(-c3ccccc3)cc(-c3ccccc3)cc2-c2ccccc2)cc1] 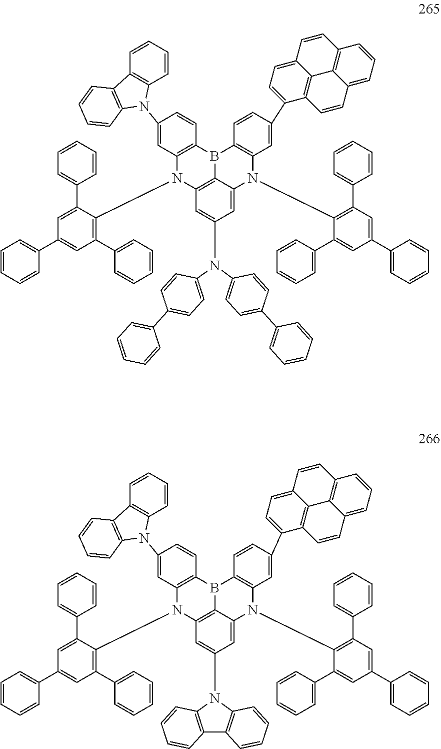 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3cc(-n6c7ccccc7c7ccccc76)ccc3B5c3ccc(-c5ccc6ccc7cccc8ccc5c6c78)cc3N4c3c(-c4ccccc4)cc(-c4ccccc4)cc3-c3ccccc3)cc2)cc1 ; c1ccc(-c2cc(-c3ccccc3)c(N3c4cc(-c5ccc6ccc7cccc8ccc5c6c78)ccc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1] 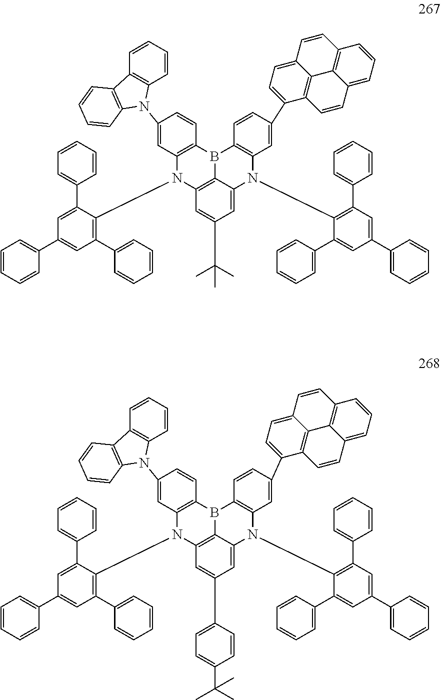 [SMILES: CC(C)(C)c1cc2c3c(c1)N(c1c(-c4ccccc4)cc(-c4ccccc4)cc1-c1ccccc1)c1cc(-n4c5ccccc5c5ccccc54)ccc1B3c1ccc(-c3ccc4ccc5cccc6ccc3c4c56)cc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2cc(-n5c6ccccc6c6ccccc65)ccc2B4c2ccc(-c4ccc5ccc6cccc7ccc4c5c67)cc2N3c2c(-c3ccccc3)cc(-c3ccccc3)cc2-c2ccccc2)cc1] 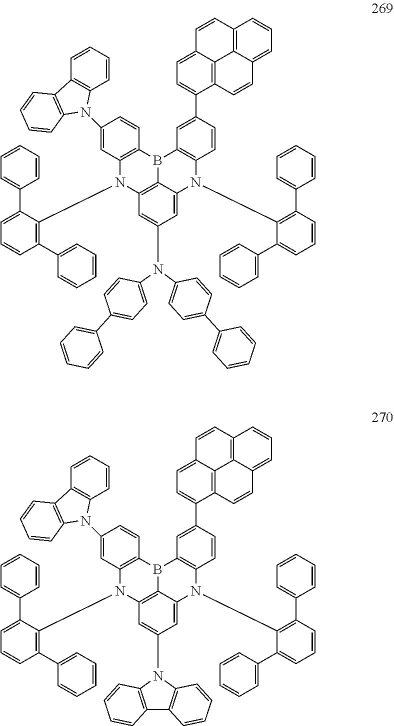 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3cc(-c5ccc6ccc7cccc8ccc5c6c78)ccc3N4c3c(-c4ccccc4)cccc3-c3ccccc3)cc2)cc1 ; c1ccc(-c2cccc(-c3ccccc3)c2N2c3ccc(-c4ccc5ccc6cccc7ccc4c5c67)cc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1] 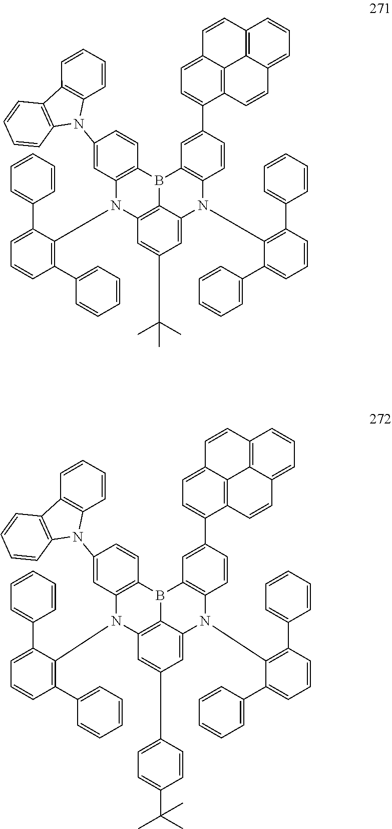 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccc4ccc5cccc6ccc3c4c56)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2cc(-c4ccc5ccc6cccc7ccc4c5c67)ccc2N3c2c(-c3ccccc3)cccc2-c2ccccc2)cc1] 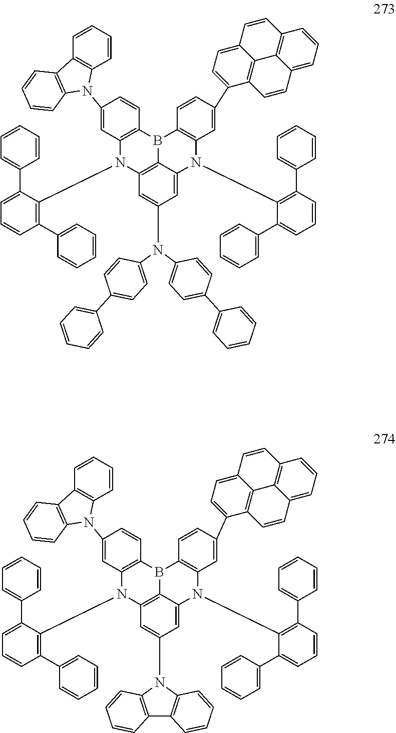 [SMILES: c1ccc(-c2ccc(N(c3ccc(-c4ccccc4)cc3)c3cc4c5c(c3)N(c3c(-c6ccccc6)cccc3-c3ccccc3)c3cc(-n6c7ccccc7c7ccccc76)ccc3B5c3ccc(-c5ccc6ccc7cccc8ccc5c6c78)cc3N4c3c(-c4ccccc4)cccc3-c3ccccc3)cc2)cc1 ; c1ccc(-c2cccc(-c3ccccc3)c2N2c3cc(-c4ccc5ccc6cccc7ccc4c5c67)ccc3B3c4ccc(-n5c6ccccc6c6ccccc65)cc4N(c4c(-c5ccccc5)cccc4-c4ccccc4)c4cc(-n5c6ccccc6c6ccccc65)cc2c43)cc1] 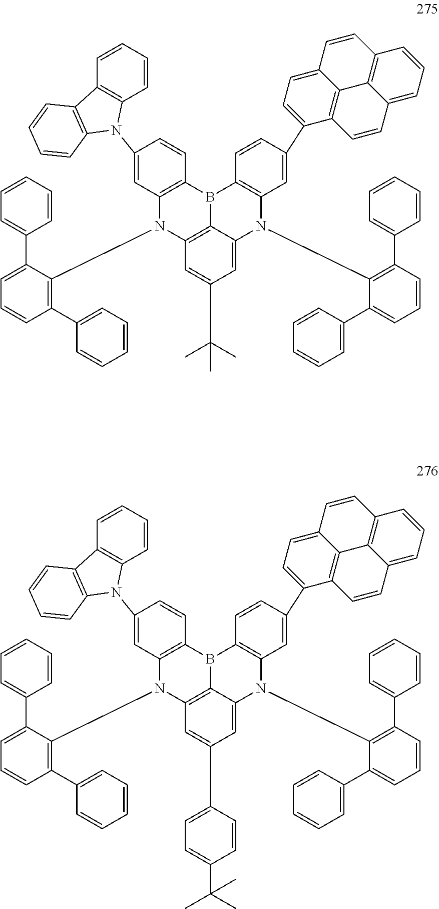 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(-c3ccc4ccc5cccc6ccc3c4c56)cc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-n5c6ccccc6c6ccccc65)ccc2B4c2ccc(-c4ccc5ccc6cccc7ccc4c5c67)cc2N3c2c(-c3ccccc3)cccc2-c2ccccc2)cc1] 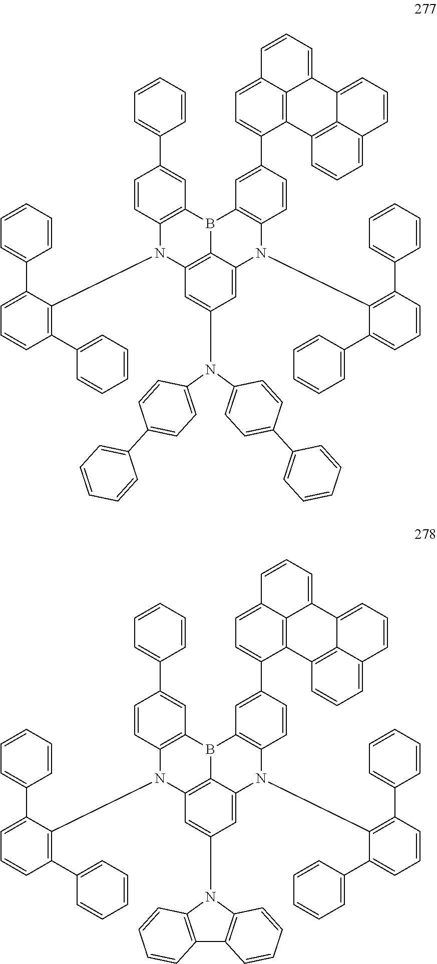 [SMILES: c1ccc(-c2ccc(N(c3ccc(-c4ccccc4)cc3)c3cc4c5c(c3)N(c3c(-c6ccccc6)cccc3-c3ccccc3)c3ccc(-c6ccc7cccc8c9cccc%10cccc(c6c78)c%109)cc3B5c3cc(-c5ccccc5)ccc3N4c3c(-c4ccccc4)cccc3-c3ccccc3)cc2)cc1 ; c1ccc(-c2ccc3c(c2)B2c4cc(-c5ccc6cccc7c8cccc9cccc(c5c67)c98)ccc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 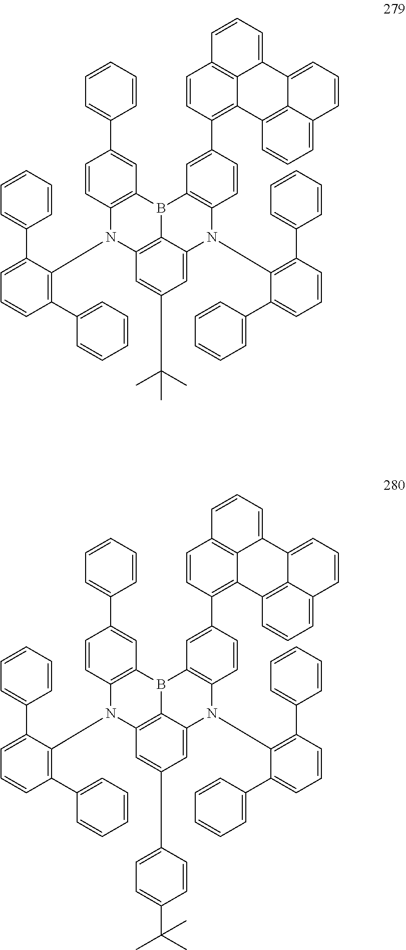 [SMILES: CC(C)(C)c1cc2c3c(c1)N(c1c(-c4ccccc4)cccc1-c1ccccc1)c1ccc(-c4ccc5cccc6c7cccc8cccc(c4c56)c87)cc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2ccc(-c5ccc6cccc7c8cccc9cccc(c5c67)c98)cc2B4c2cc(-c4ccccc4)ccc2N3c2c(-c3ccccc3)cccc2-c2ccccc2)cc1] 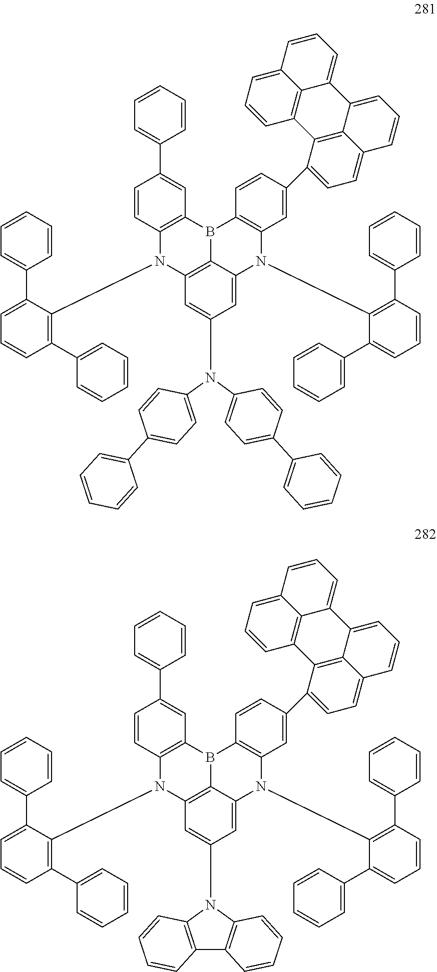 [SMILES: c1ccc(-c2ccc(N(c3ccc(-c4ccccc4)cc3)c3cc4c5c(c3)N(c3c(-c6ccccc6)cccc3-c3ccccc3)c3cc(-c6ccc7cccc8c9cccc%10cccc(c6c78)c%109)ccc3B5c3cc(-c5ccccc5)ccc3N4c3c(-c4ccccc4)cccc3-c3ccccc3)cc2)cc1 ; c1ccc(-c2ccc3c(c2)B2c4ccc(-c5ccc6cccc7c8cccc9cccc(c5c67)c98)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 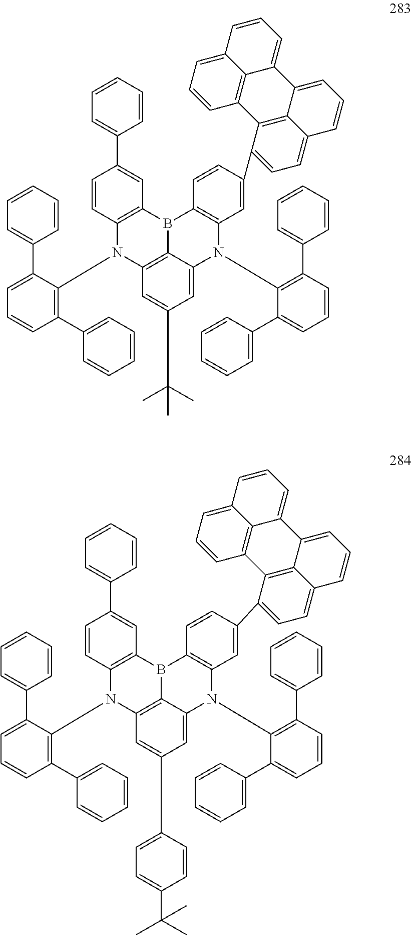 [SMILES: CC(C)(C)c1cc2c3c(c1)N(c1c(-c4ccccc4)cccc1-c1ccccc1)c1cc(-c4ccc5cccc6c7cccc8cccc(c4c56)c87)ccc1B3c1cc(-c3ccccc3)ccc1N2c1c(-c2ccccc2)cccc1-c1ccccc1 ; CC(C)(C)c1ccc(-c2cc3c4c(c2)N(c2c(-c5ccccc5)cccc2-c2ccccc2)c2cc(-c5ccc6cccc7c8cccc9cccc(c5c67)c98)ccc2B4c2cc(-c4ccccc4)ccc2N3c2c(-c3ccccc3)cccc2-c2ccccc2)cc1] 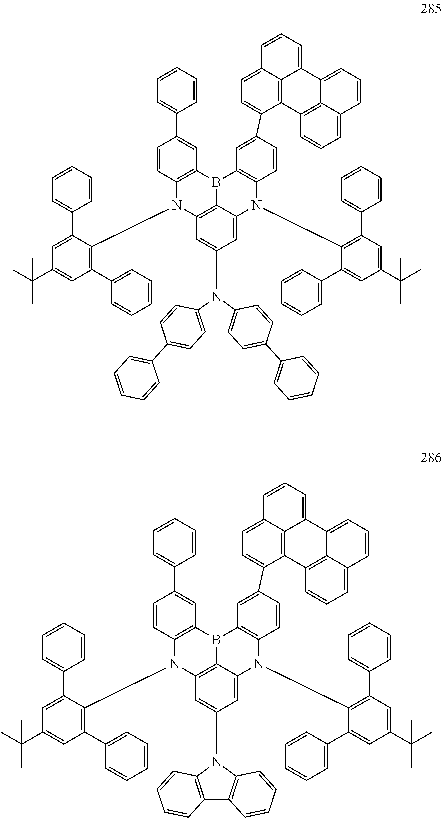 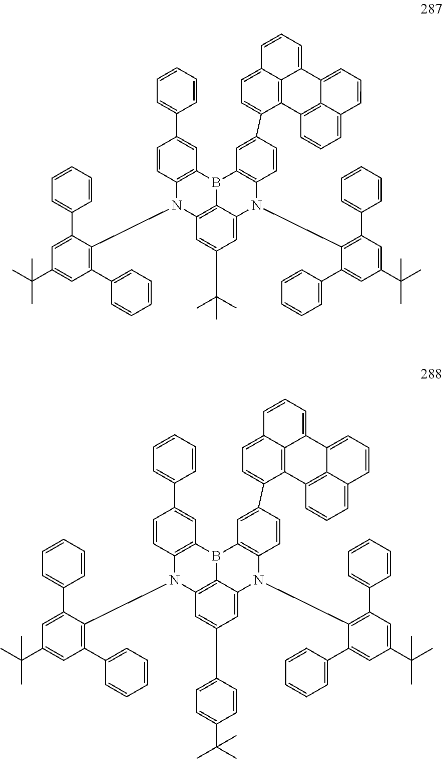 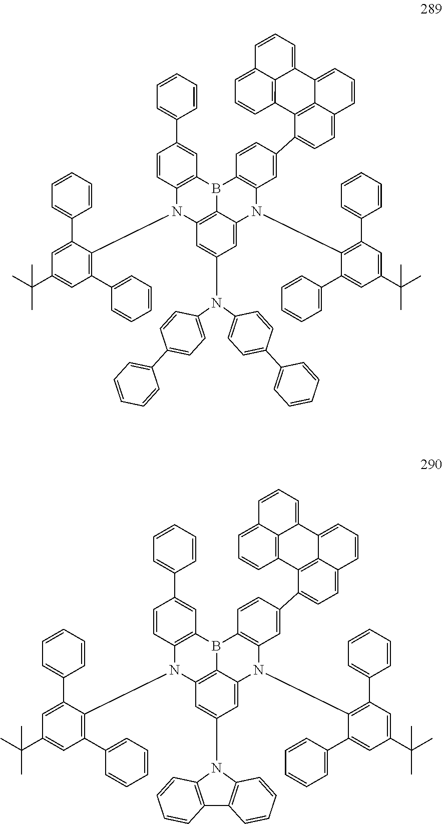 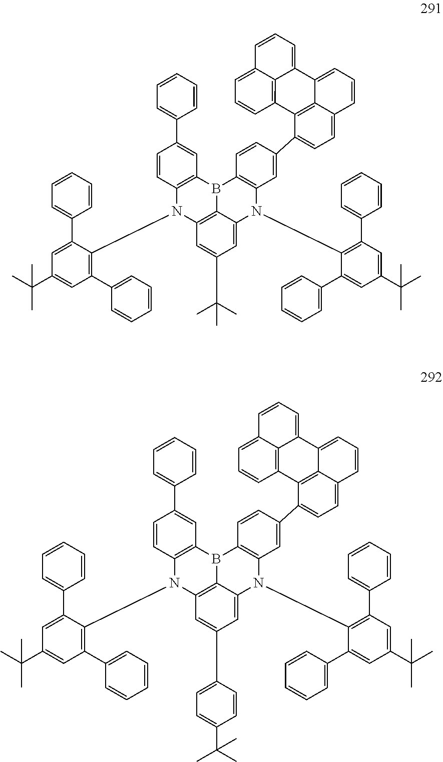 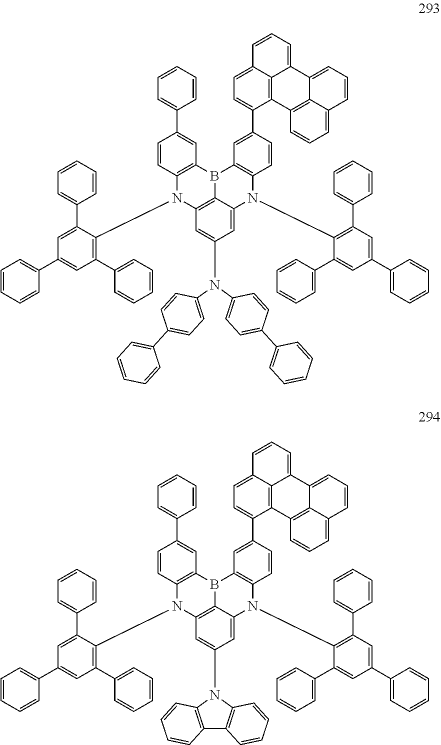 [SMILES: c1ccc(-c2ccc(N(c3ccc(-c4ccccc4)cc3)c3cc4c5c(c3)N(c3c(-c6ccccc6)cc(-c6ccccc6)cc3-c3ccccc3)c3ccc(-c6ccc7cccc8c9cccc%10cccc(c6c78)c%109)cc3B5c3cc(-c5ccccc5)ccc3N4c3c(-c4ccccc4)cc(-c4ccccc4)cc3-c3ccccc3)cc2)cc1 ; c1ccc(-c2ccc3c(c2)B2c4cc(-c5ccc6cccc7c8cccc9cccc(c5c67)c98)ccc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1] 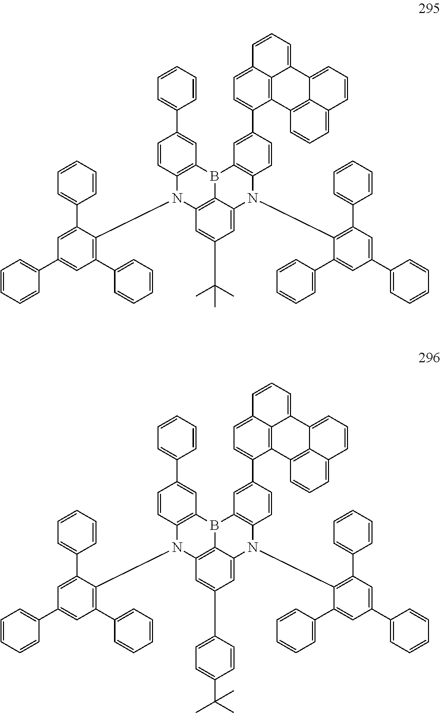 [SMILES: CC(C)(C)c1cc2c3c(c1)N(c1c(-c4ccccc4)cc(-c4ccccc4)cc1-c1ccccc1)c1ccc(-c4ccc5cccc6c7cccc8cccc(c4c56)c87)cc1B3c1cc(-c3ccccc3)ccc1N2c1c(-c2ccccc2)cc(-c2ccccc2)cc1-c1ccccc1 ; CC(C)(C)c1ccc(-c2cc3c4c(c2)N(c2c(-c5ccccc5)cc(-c5ccccc5)cc2-c2ccccc2)c2ccc(-c5ccc6cccc7c8cccc9cccc(c5c67)c98)cc2B4c2cc(-c4ccccc4)ccc2N3c2c(-c3ccccc3)cc(-c3ccccc3)cc2-c2ccccc2)cc1] 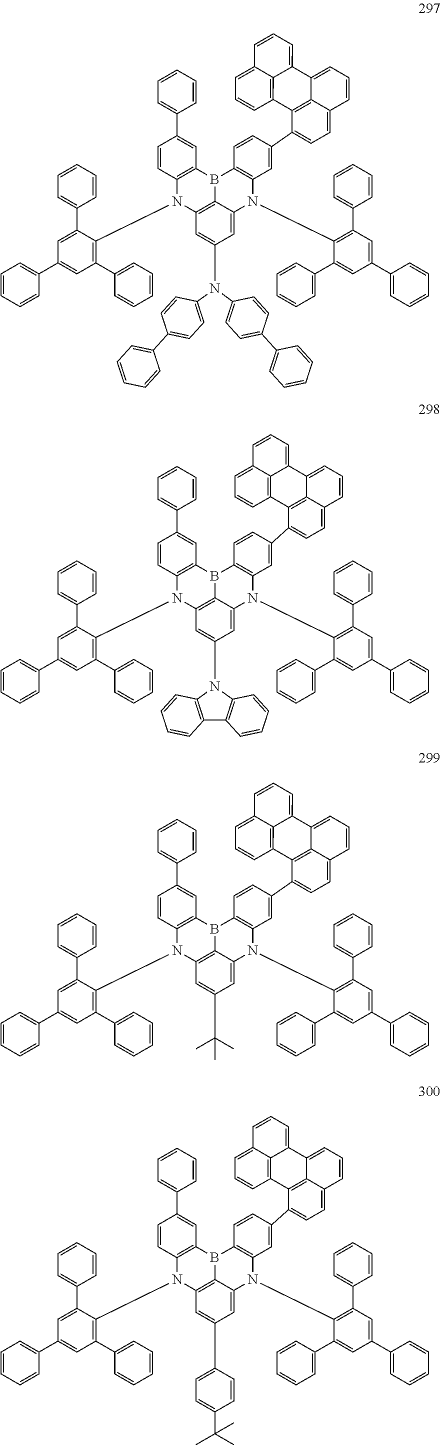 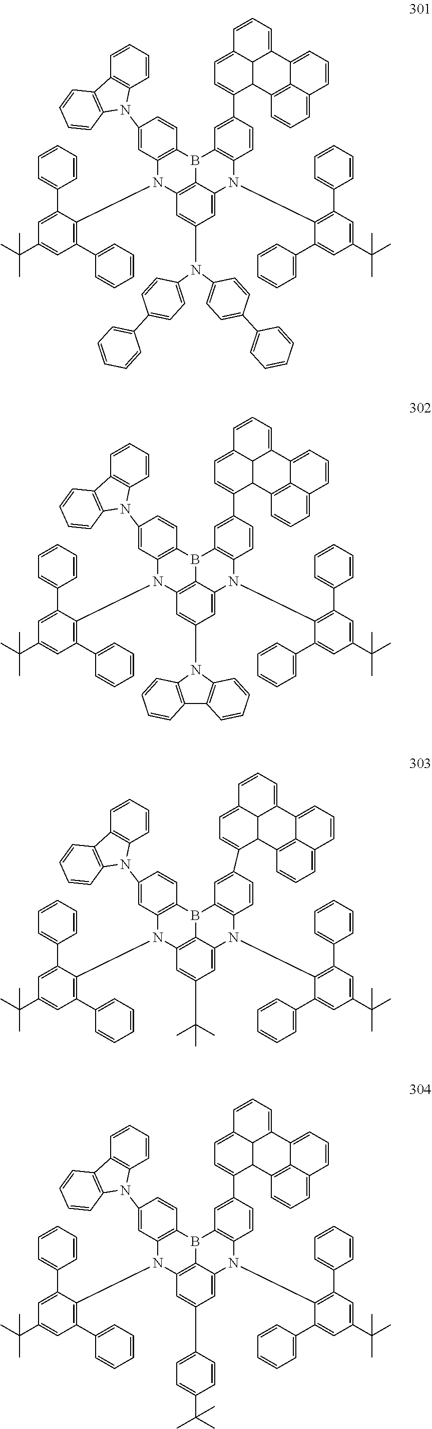 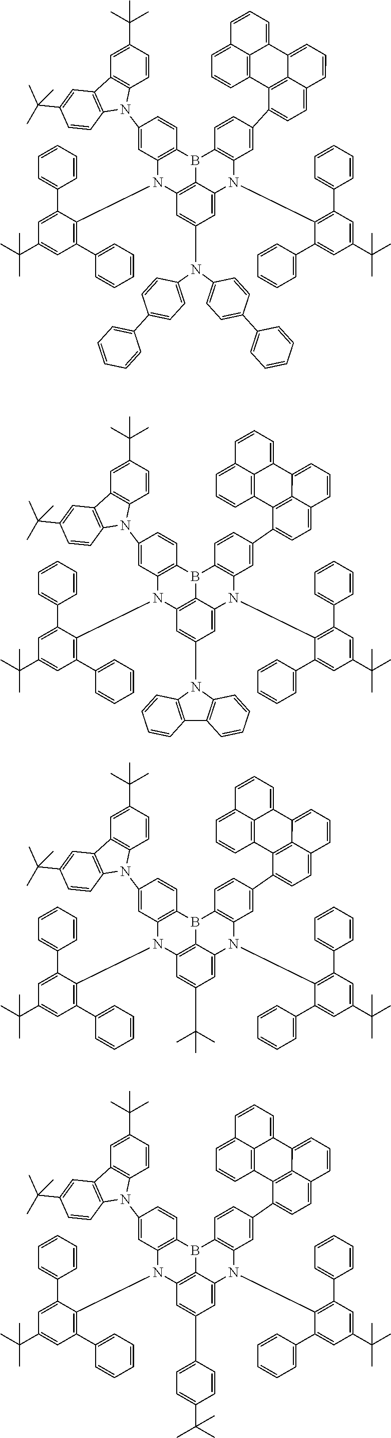 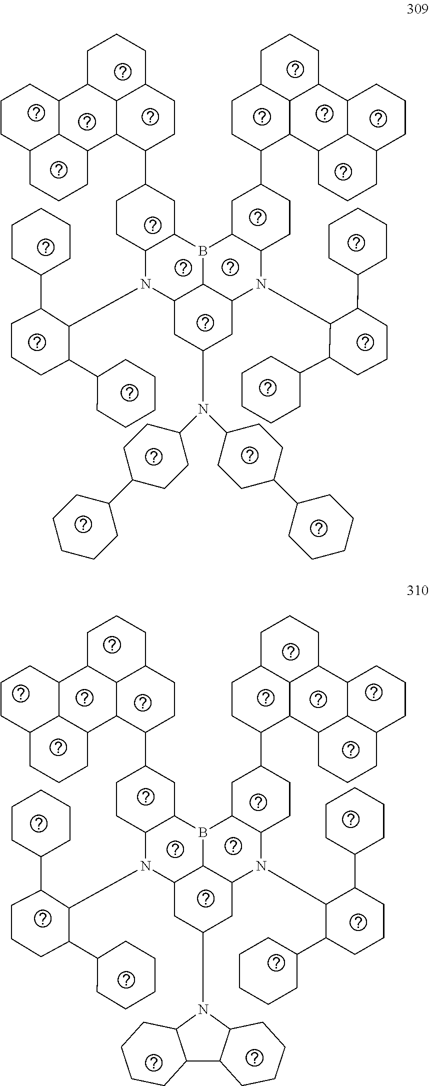 [SMILES: C1CCC(C2CCC(N(C3CCC(C4CCCCC4)CC3)C3CC4C5B(C6CC(C7CCC8CCCC9C%10CCCC%11CCCC(C%11%10)C7C89)CCC6N4C4C(C6CCCCC6)CCCC4C4CCCCC4)C4CC(C6CCC7CCCC8C9CCCC%10CCCC(C%109)C6C78)CCC4N(C4C(C6CCCCC6)CCCC4C4CCCCC4)C5C3)CC2)CC1 ; C1CCC(C2CCCC(C3CCCCC3)C2N2C3CCC(C4CCC5CCCC6C7CCCC8CCCC(C87)C4C56)CC3B3C4CC(C5CCC6CCCC7C8CCCC9CCCC(C98)C5C67)CCC4N(C4C(C5CCCCC5)CCCC4C4CCCCC4)C4CC(N5C6CCCCC6C6CCCCC65)CC2C34)CC1] 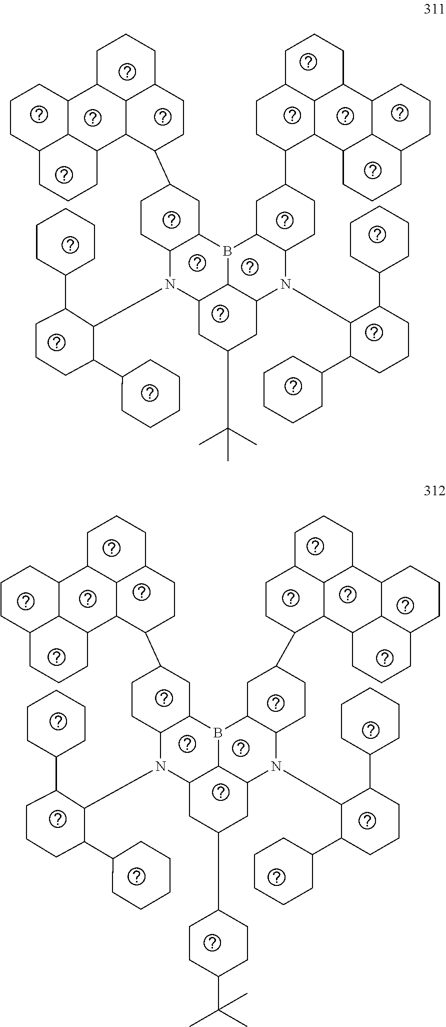 [SMILES: CC(C)(C)C1CC2C3B(C4CC(C5CCC6CCCC7C8CCCC9CCCC(C98)C5C67)CCC4N2C2C(C4CCCCC4)CCCC2C2CCCCC2)C2CC(C4CCC5CCCC6C7CCCC8CCCC(C87)C4C56)CCC2N(C2C(C4CCCCC4)CCCC2C2CCCCC2)C3C1 ; CC(C)(C)C1CCC(C2CC3C4B(C5CC(C6CCC7CCCC8C9CCCC%10CCCC(C%109)C6C78)CCC5N3C3C(C5CCCCC5)CCCC3C3CCCCC3)C3CC(C5CCC6CCCC7C8CCCC9CCCC(C98)C5C67)CCC3N(C3C(C5CCCCC5)CCCC3C3CCCCC3)C4C2)CC1] 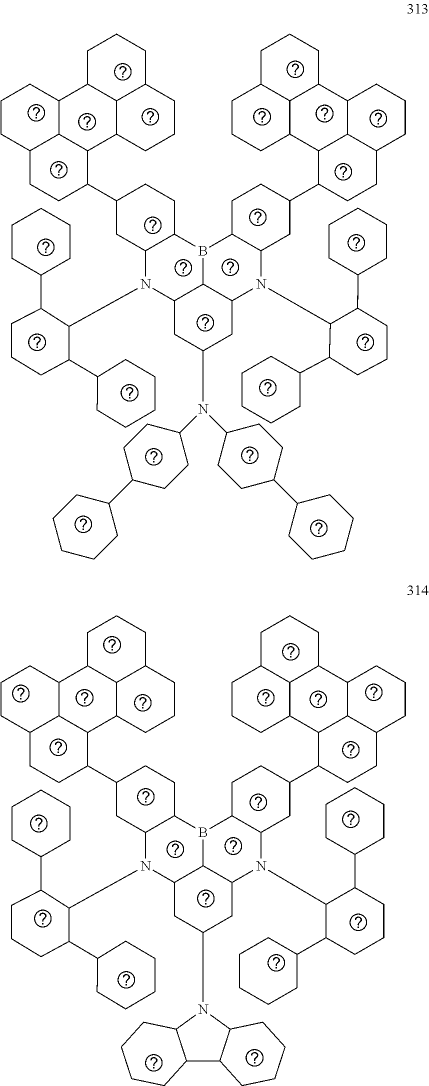 [SMILES: C1CCC(C2CCC(N(C3CCC(C4CCCCC4)CC3)C3CC4C5B(C6CCC(C7CCC8CCCC9C%10CCCC%11CCCC(C%11%10)C7C89)CC6N4C4C(C6CCCCC6)CCCC4C4CCCCC4)C4CCC(C6CCC7CCCC8C9CCCC%10CCCC(C%109)C6C78)CC4N(C4C(C6CCCCC6)CCCC4C4CCCCC4)C5C3)CC2)CC1 ; C1CCC(C2CCCC(C3CCCCC3)C2N2C3CC(C4CCC5CCCC6C7CCCC8CCCC(C87)C4C56)CCC3B3C4CCC(C5CCC6CCCC7C8CCCC9CCCC(C98)C5C67)CC4N(C4C(C5CCCCC5)CCCC4C4CCCCC4)C4CC(N5C6CCCCC6C6CCCCC65)CC2C34)CC1] 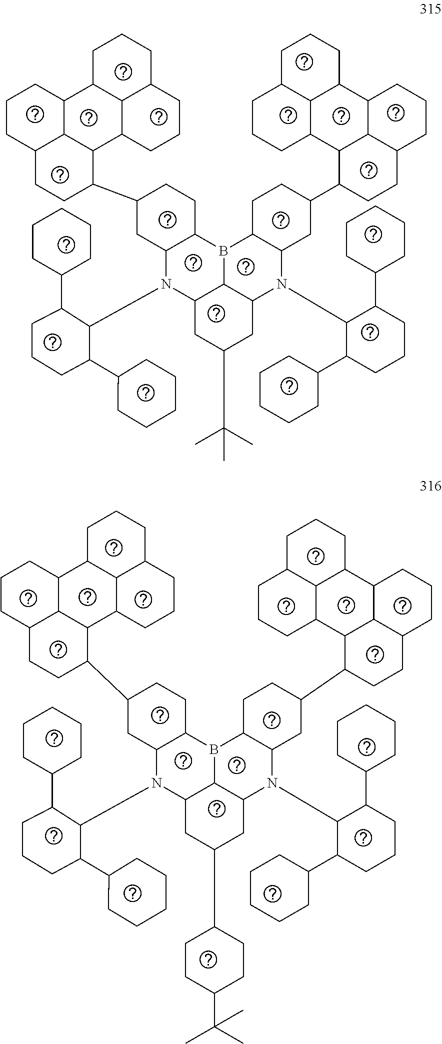 [SMILES: CC(C)(C)C1CC2C3B(C4CCC(C5CCC6CCCC7C8CCCC9CCCC(C98)C5C67)CC4N2C2C(C4CCCCC4)CCCC2C2CCCCC2)C2CCC(C4CCC5CCCC6C7CCCC8CCCC(C87)C4C56)CC2N(C2C(C4CCCCC4)CCCC2C2CCCCC2)C3C1 ; CC(C)(C)C1CCC(C2CC3C4B(C5CCC(C6CCC7CCCC8C9CCCC%10CCCC(C%109)C6C78)CC5N3C3C(C5CCCCC5)CCCC3C3CCCCC3)C3CCC(C5CCC6CCCC7C8CCCC9CCCC(C98)C5C67)CC3N(C3C(C5CCCCC5)CCCC3C3CCCCC3)C4C2)CC1] 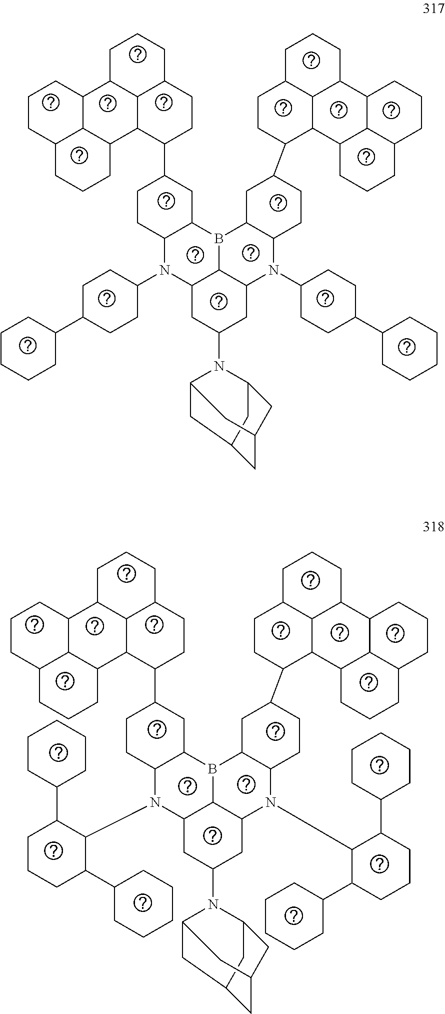 [SMILES: C1CCC(C2CCC(N3C4CCC(C5CCC6CCCC7C8CCCC9CCCC(C98)C5C67)CC4B4C5CC(C6CCC7CCCC8C9CCCC%10CCCC(C%109)C6C78)CCC5N(C5CCC(C6CCCCC6)CC5)C5CC(N6C7CC8CC(C7)CC6C8)CC3C45)CC2)CC1 ; C1CCC(C2CCCC(C3CCCCC3)C2N2C3CCC(C4CCC5CCCC6C7CCCC8CCCC(C87)C4C56)CC3B3C4CC(C5CCC6CCCC7C8CCCC9CCCC(C98)C5C67)CCC4N(C4C(C5CCCCC5)CCCC4C4CCCCC4)C4CC(N5C6CC7CC(C6)CC5C7)CC2C34)CC1] 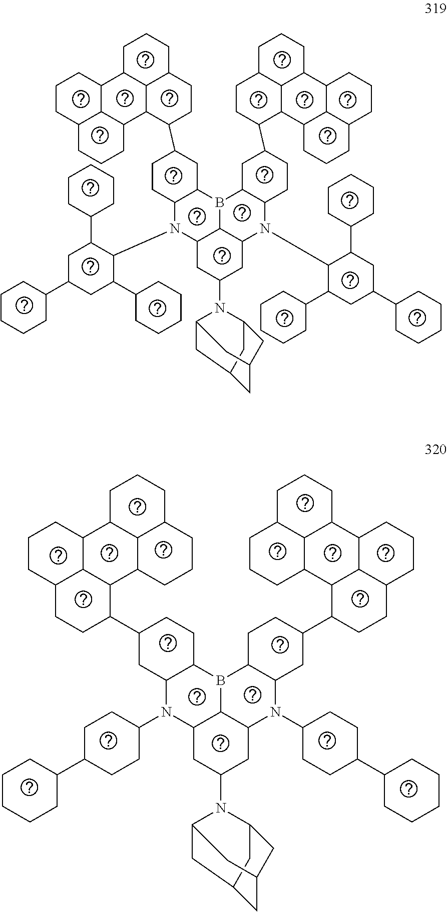 [SMILES: C1CCC(C2CC(C3CCCCC3)C(N3C4CCC(C5CCC6CCCC7C8CCCC9CCCC(C98)C5C67)CC4B4C5CC(C6CCC7CCCC8C9CCCC%10CCCC(C%109)C6C78)CCC5N(C5C(C6CCCCC6)CC(C6CCCCC6)CC5C5CCCCC5)C5CC(N6C7CC8CC(C7)CC6C8)CC3C45)C(C3CCCCC3)C2)CC1 ; C1CCC(C2CCC(N3C4CC(C5CCC6CCCC7C8CCCC9CCCC(C98)C5C67)CCC4B4C5CCC(C6CCC7CCCC8C9CCCC%10CCCC(C%109)C6C78)CC5N(C5CCC(C6CCCCC6)CC5)C5CC(N6C7CC8CC(C7)CC6C8)CC3C45)CC2)CC1] 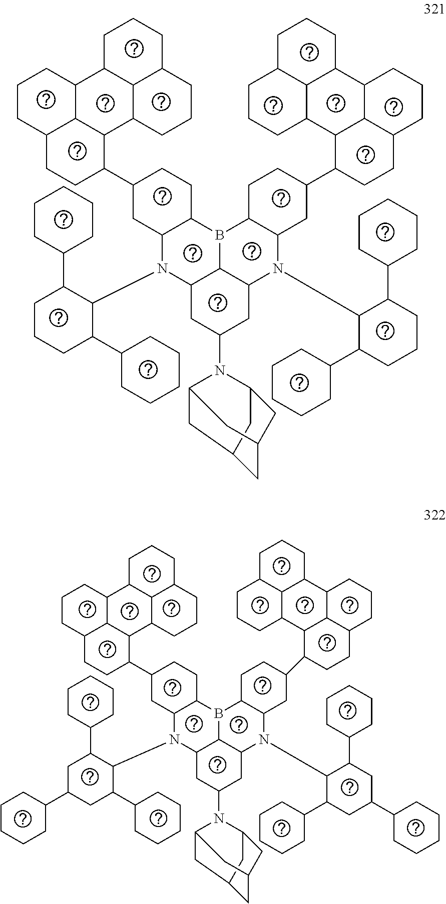 [SMILES: C1CCC(C2CCCC(C3CCCCC3)C2N2C3CC(C4CCC5CCCC6C7CCCC8CCCC(C87)C4C56)CCC3B3C4CCC(C5CCC6CCCC7C8CCCC9CCCC(C98)C5C67)CC4N(C4C(C5CCCCC5)CCCC4C4CCCCC4)C4CC(N5C6CC7CC(C6)CC5C7)CC2C34)CC1 ; C1CCC(C2CC(C3CCCCC3)C(N3C4CC(C5CCC6CCCC7C8CCCC9CCCC(C98)C5C67)CCC4B4C5CCC(C6CCC7CCCC8C9CCCC%10CCCC(C%109)C6C78)CC5N(C5C(C6CCCCC6)CC(C6CCCCC6)CC5C5CCCCC5)C5CC(N6C7CC8CC(C7)CC6C8)CC3C45)C(C3CCCCC3)C2)CC1] 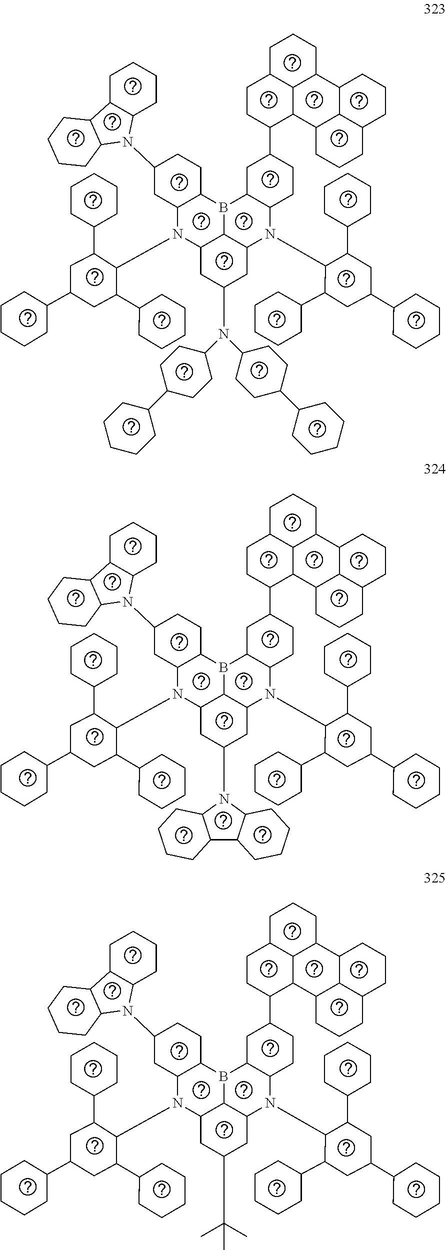 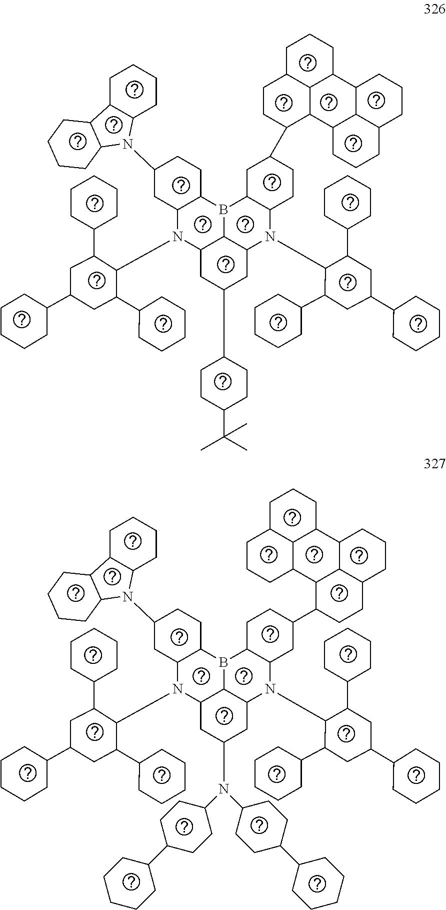 [SMILES: CC(C)(C)C1CCC(C2CC3C4B(C5CC(C6CCC7CCCC8C9CCCC%10CCCC(C%109)C6C78)CCC5N3C3C(C5CCCCC5)CC(C5CCCCC5)CC3C3CCCCC3)C3CCC(N5C6CCCCC6C6CCCCC65)CC3N(C3C(C5CCCCC5)CC(C5CCCCC5)CC3C3CCCCC3)C4C2)CC1 ; C1CCC(C2CCC(N(C3CCC(C4CCCCC4)CC3)C3CC4C5B(C6CCC(C7CCC8CCCC9C%10CCCC%11CCCC(C%11%10)C7C89)CC6N4C4C(C6CCCCC6)CC(C6CCCCC6)CC4C4CCCCC4)C4CCC(N6C7CCCCC7C7CCCCC76)CC4N(C4C(C6CCCCC6)CC(C6CCCCC6)CC4C4CCCCC4)C5C3)CC2)CC1] 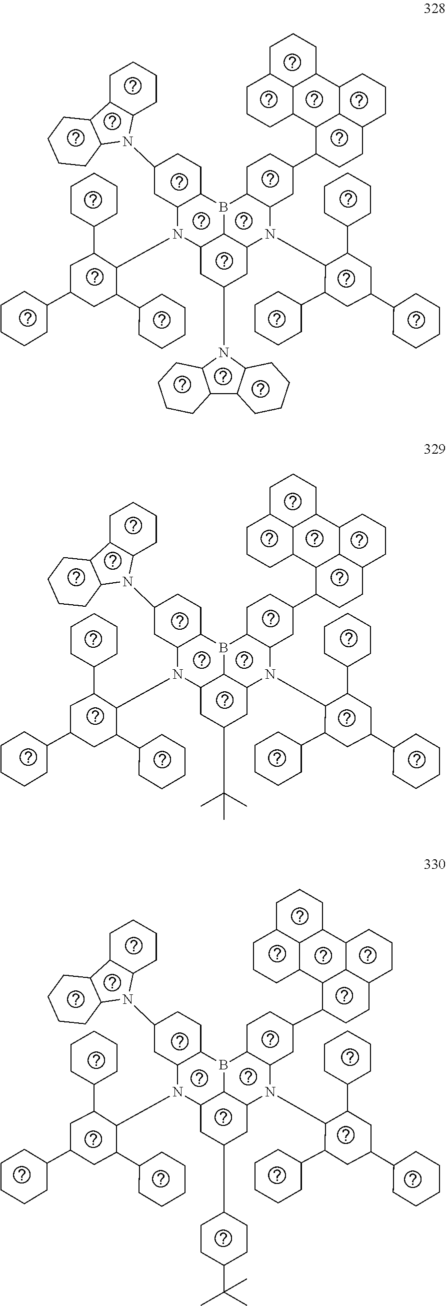 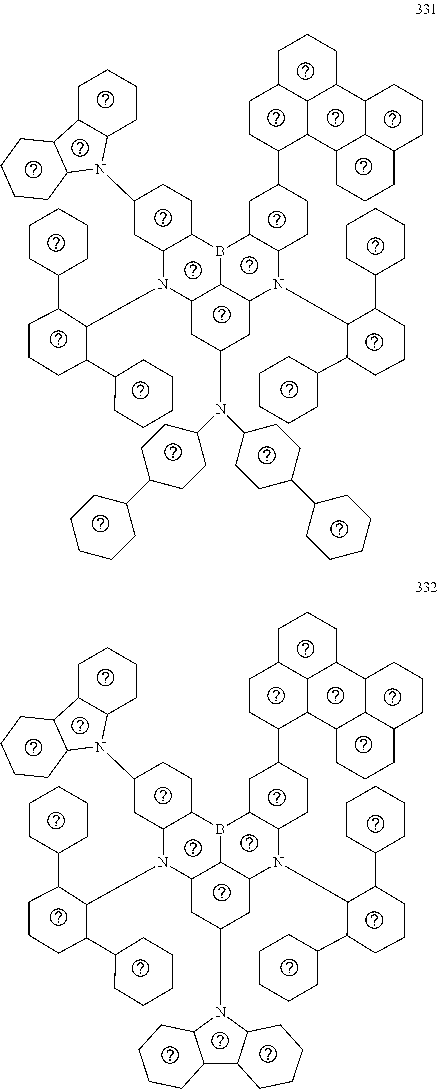 [SMILES: C1CCC(C2CCC(N(C3CCC(C4CCCCC4)CC3)C3CC4C5B(C6CC(C7CCC8CCCC9C%10CCCC%11CCCC(C%11%10)C7C89)CCC6N4C4C(C6CCCCC6)CCCC4C4CCCCC4)C4CCC(N6C7CCCCC7C7CCCCC76)CC4N(C4C(C6CCCCC6)CCCC4C4CCCCC4)C5C3)CC2)CC1 ; C1CCC(C2CCCC(C3CCCCC3)C2N2C3CCC(C4CCC5CCCC6C7CCCC8CCCC(C87)C4C56)CC3B3C4CCC(N5C6CCCCC6C6CCCCC65)CC4N(C4C(C5CCCCC5)CCCC4C4CCCCC4)C4CC(N5C6CCCCC6C6CCCCC65)CC2C34)CC1] 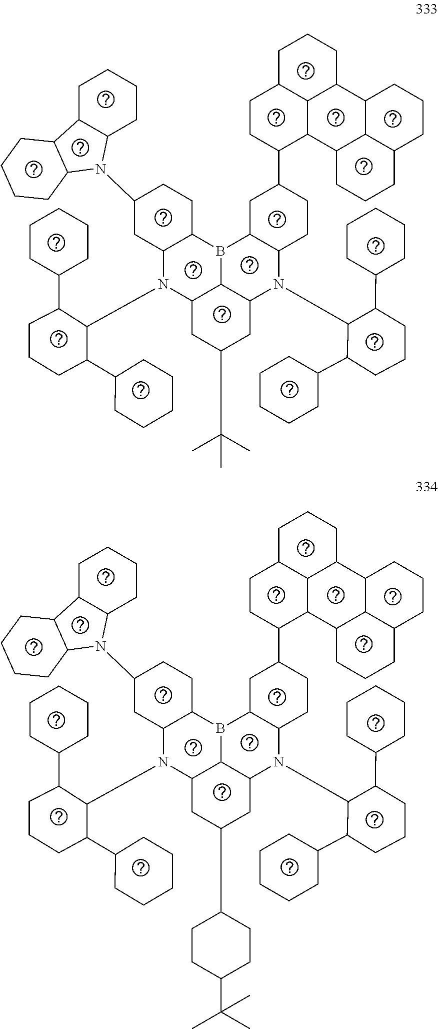 [SMILES: CC(C)(C)C1CC2C3B(C4CC(C5CCC6CCCC7C8CCCC9CCCC(C98)C5C67)CCC4N2C2C(C4CCCCC4)CCCC2C2CCCCC2)C2CCC(N4C5CCCCC5C5CCCCC54)CC2N(C2C(C4CCCCC4)CCCC2C2CCCCC2)C3C1 ; CC(C)(C)C1CCC(C2CC3C4B(C5CC(C6CCC7CCCC8C9CCCC%10CCCC(C%109)C6C78)CCC5N3C3C(C5CCCCC5)CCCC3C3CCCCC3)C3CCC(N5C6CCCCC6C6CCCCC65)CC3N(C3C(C5CCCCC5)CCCC3C3CCCCC3)C4C2)CC1] 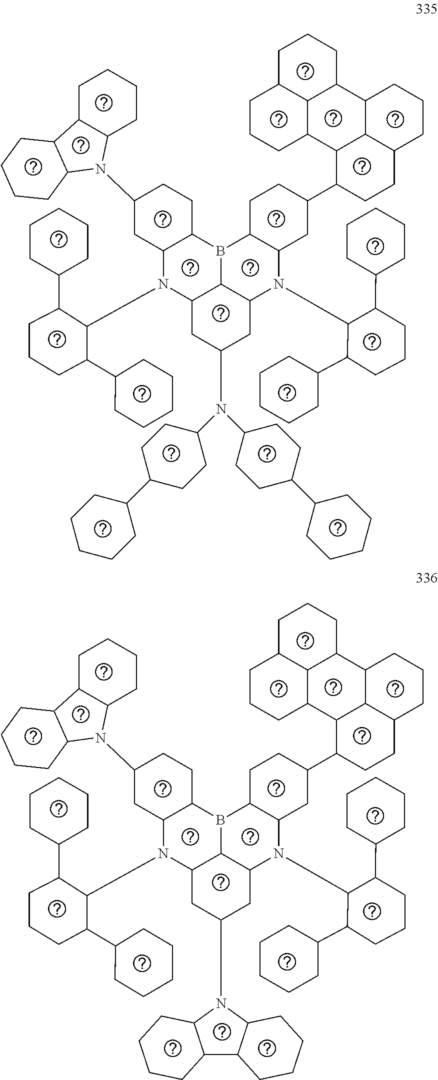 [SMILES: C1CCC(C2CCC(N(C3CCC(C4CCCCC4)CC3)C3CC4C5B(C6CCC(C7CCC8CCCC9C%10CCCC%11CCCC(C%11%10)C7C89)CC6N4C4C(C6CCCCC6)CCCC4C4CCCCC4)C4CCC(N6C7CCCCC7C7CCCCC76)CC4N(C4C(C6CCCCC6)CCCC4C4CCCCC4)C5C3)CC2)CC1 ; C1CCC(C2CCCC(C3CCCCC3)C2N2C3CC(C4CCC5CCCC6C7CCCC8CCCC(C87)C4C56)CCC3B3C4CCC(N5C6CCCCC6C6CCCCC65)CC4N(C4C(C5CCCCC5)CCCC4C4CCCCC4)C4CC(N5C6CCCCC6C6CCCCC65)CC2C34)CC1] 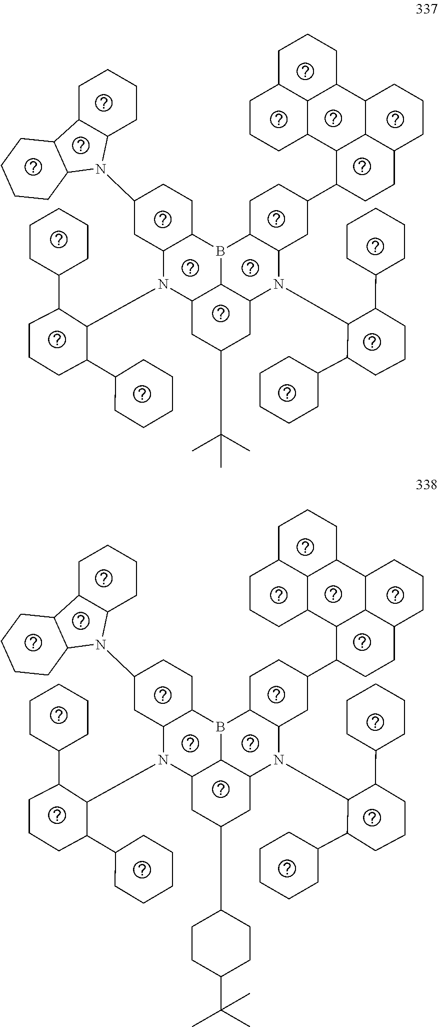 [SMILES: CC(C)(C)C1CC2C3B(C4CCC(C5CCC6CCCC7C8CCCC9CCCC(C98)C5C67)CC4N2C2C(C4CCCCC4)CCCC2C2CCCCC2)C2CCC(N4C5CCCCC5C5CCCCC54)CC2N(C2C(C4CCCCC4)CCCC2C2CCCCC2)C3C1 ; CC(C)(C)C1CCC(C2CC3C4B(C5CCC(C6CCC7CCCC8C9CCCC%10CCCC(C%109)C6C78)CC5N3C3C(C5CCCCC5)CCCC3C3CCCCC3)C3CCC(N5C6CCCCC6C6CCCCC65)CC3N(C3C(C5CCCCC5)CCCC3C3CCCCC3)C4C2)CC1] 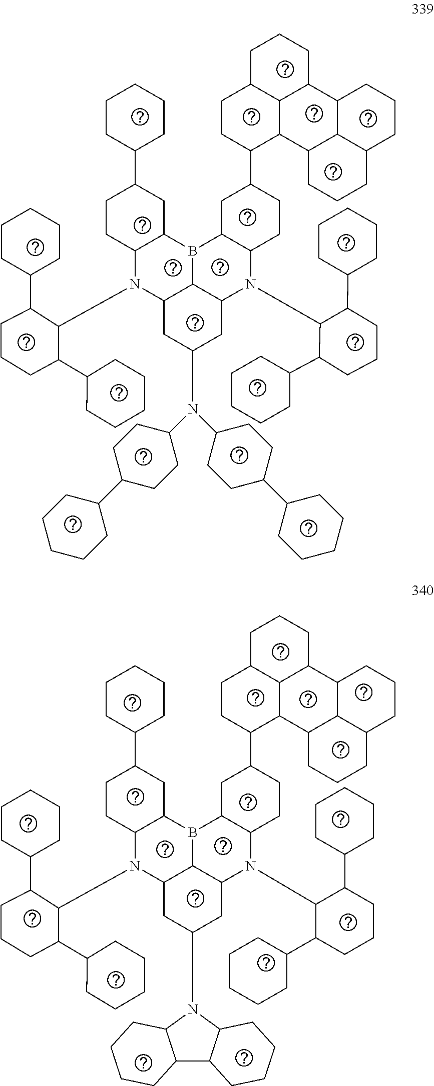 [SMILES: C1CCC(C2CCC(N(C3CCC(C4CCCCC4)CC3)C3CC4C5B(C6CC(C7CCCCC7)CCC6N4C4C(C6CCCCC6)CCCC4C4CCCCC4)C4CC(C6CCC7CCCC8C9CCCC%10CCCC(C%109)C6C78)CCC4N(C4C(C6CCCCC6)CCCC4C4CCCCC4)C5C3)CC2)CC1 ; C1CCC(C2CCC3C(C2)B2C4CC(C5CCC6CCCC7C8CCCC9CCCC(C98)C5C67)CCC4N(C4C(C5CCCCC5)CCCC4C4CCCCC4)C4CC(N5C6CCCCC6C6CCCCC65)CC(C24)N3C2C(C3CCCCC3)CCCC2C2CCCCC2)CC1] 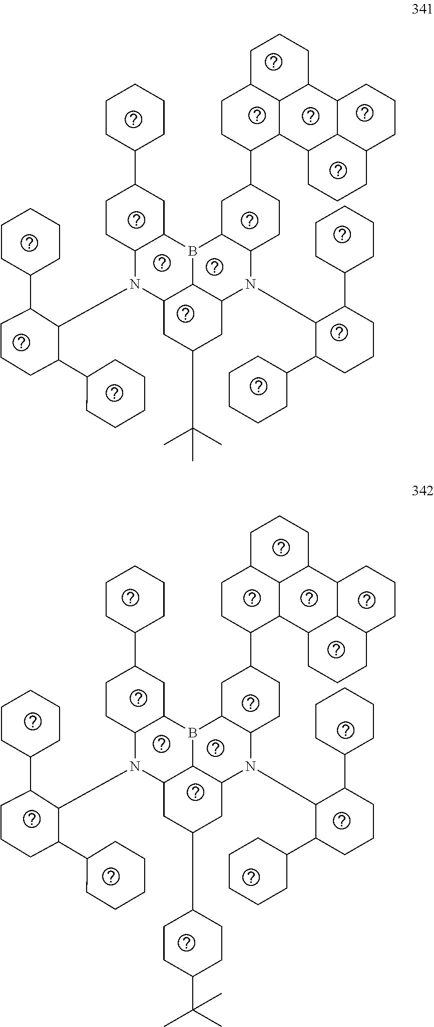 [SMILES: CC(C)(C)C1CC2C3B(C4CC(C5CCCCC5)CCC4N2C2C(C4CCCCC4)CCCC2C2CCCCC2)C2CC(C4CCC5CCCC6C7CCCC8CCCC(C87)C4C56)CCC2N(C2C(C4CCCCC4)CCCC2C2CCCCC2)C3C1 ; CC(C)(C)C1CCC(C2CC3C4B(C5CC(C6CCCCC6)CCC5N3C3C(C5CCCCC5)CCCC3C3CCCCC3)C3CC(C5CCC6CCCC7C8CCCC9CCCC(C98)C5C67)CCC3N(C3C(C5CCCCC5)CCCC3C3CCCCC3)C4C2)CC1] 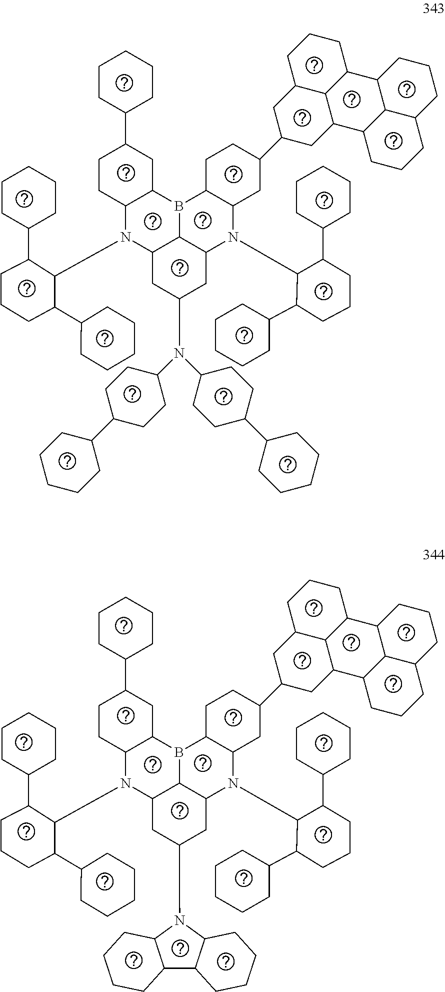 [SMILES: C1CCC(C2CCC(N(C3CCC(C4CCCCC4)CC3)C3CC4C5B(C6CC(C7CCCCC7)CCC6N4C4C(C6CCCCC6)CCCC4C4CCCCC4)C4CCC(C6CC7CCCC8C9CCCC%10CCCC(C(C6)C78)C%109)CC4N(C4C(C6CCCCC6)CCCC4C4CCCCC4)C5C3)CC2)CC1 ; C1CCC(C2CCC3C(C2)B2C4CCC(C5CC6CCCC7C8CCCC9CCCC(C(C5)C67)C98)CC4N(C4C(C5CCCCC5)CCCC4C4CCCCC4)C4CC(N5C6CCCCC6C6CCCCC65)CC(C24)N3C2C(C3CCCCC3)CCCC2C2CCCCC2)CC1] 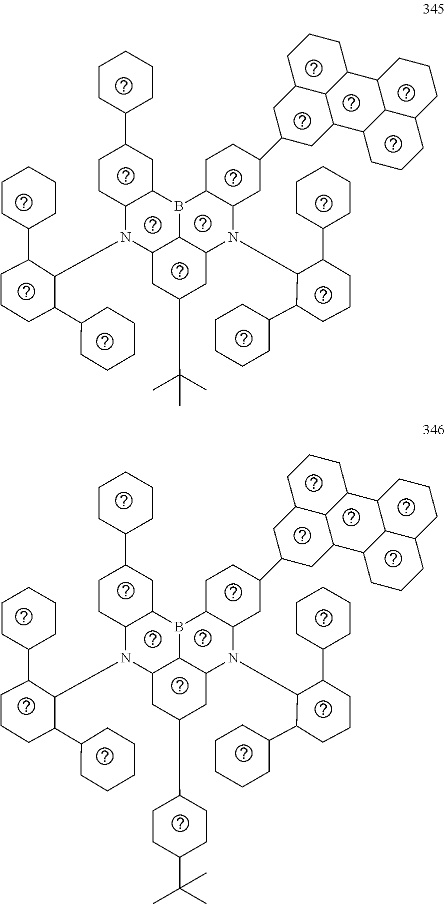 [SMILES: CC(C)(C)C1CC2C3B(C4CC(C5CCCCC5)CCC4N2C2C(C4CCCCC4)CCCC2C2CCCCC2)C2CCC(C4CC5CCCC6C7CCCC8CCCC(C(C4)C56)C87)CC2N(C2C(C4CCCCC4)CCCC2C2CCCCC2)C3C1 ; CC(C)(C)C1CCC(C2CC3C4B(C5CC(C6CCCCC6)CCC5N3C3C(C5CCCCC5)CCCC3C3CCCCC3)C3CCC(C5CC6CCCC7C8CCCC9CCCC(C(C5)C67)C98)CC3N(C3C(C5CCCCC5)CCCC3C3CCCCC3)C4C2)CC1] 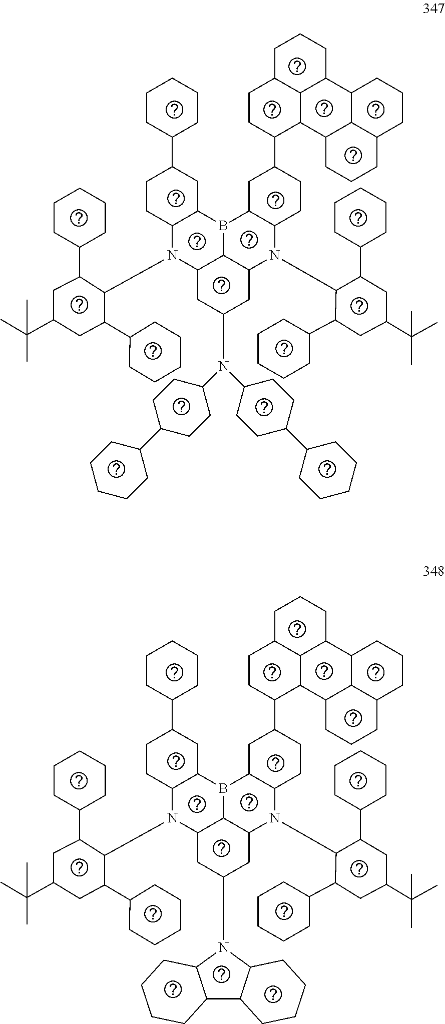 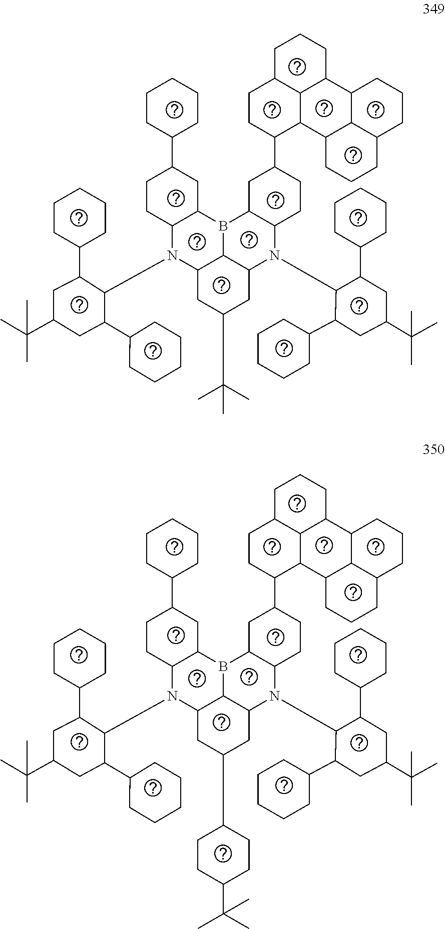 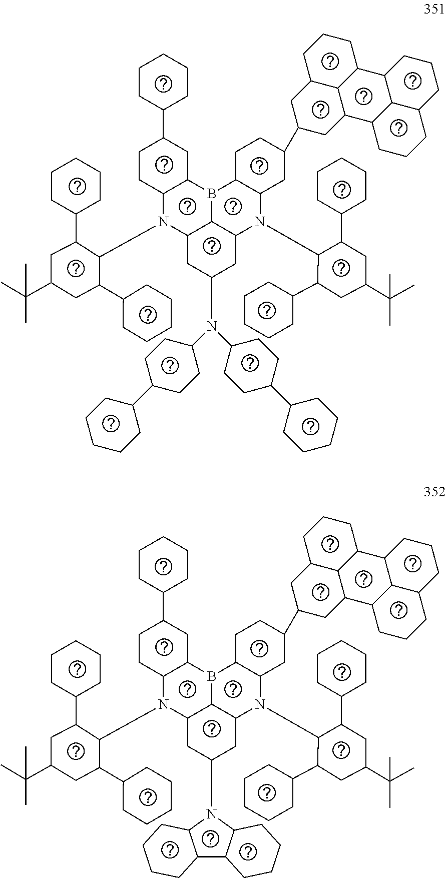 [SMILES: CC(C)(C)C1CC(C2CCCCC2)C(N2C3CCC(C4CCCCC4)CC3B3C4CCC(C5CC6CCCC7C8CCCC9CCCC(C(C5)C67)C98)CC4N(C4C(C5CCCCC5)CC(C(C)(C)C)CC4C4CCCCC4)C4CC(N(C5CCC(C6CCCCC6)CC5)C5CCC(C6CCCCC6)CC5)CC2C34)C(C2CCCCC2)C1 ; CC(C)(C)C1CC(C2CCCCC2)C(N2C3CCC(C4CCCCC4)CC3B3C4CCC(C5CC6CCCC7C8CCCC9CCCC(C(C5)C67)C98)CC4N(C4C(C5CCCCC5)CC(C(C)(C)C)CC4C4CCCCC4)C4CC(N5C6CCCCC6C6CCCCC65)CC2C34)C(C2CCCCC2)C1] 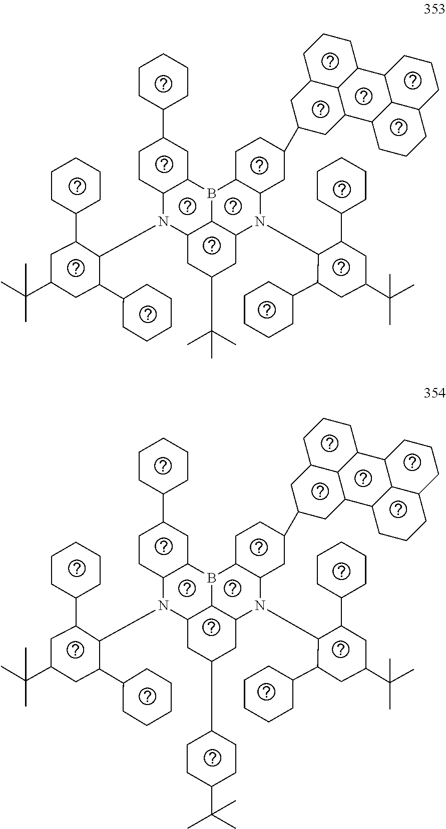 [SMILES: CC(C)(C)C1CC(C2CCCCC2)C(N2C3CCC(C4CCCCC4)CC3B3C4CCC(C5CC6CCCC7C8CCCC9CCCC(C(C5)C67)C98)CC4N(C4C(C5CCCCC5)CC(C(C)(C)C)CC4C4CCCCC4)C4CC(C(C)(C)C)CC2C34)C(C2CCCCC2)C1 ; CC(C)(C)C1CCC(C2CC3C4B(C5CC(C6CCCCC6)CCC5N3C3C(C5CCCCC5)CC(C(C)(C)C)CC3C3CCCCC3)C3CCC(C5CC6CCCC7C8CCCC9CCCC(C(C5)C67)C98)CC3N(C3C(C5CCCCC5)CC(C(C)(C)C)CC3C3CCCCC3)C4C2)CC1] 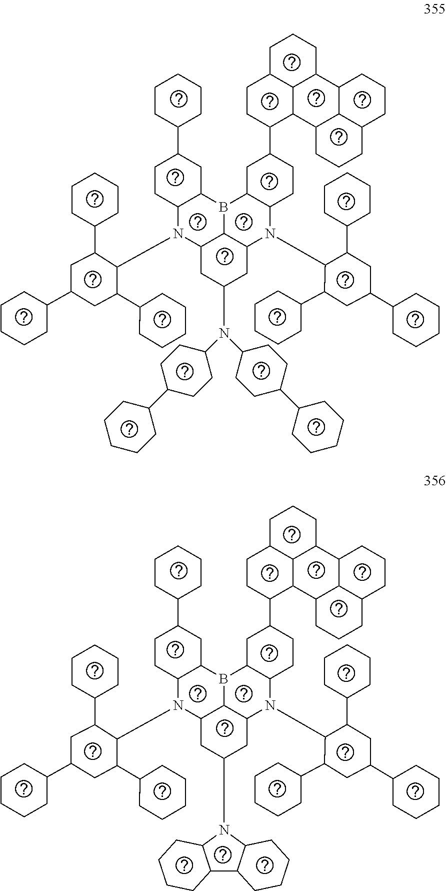 [SMILES: C1CCC(C2CCC(N(C3CCC(C4CCCCC4)CC3)C3CC4C5B(C6CC(C7CCCCC7)CCC6N4C4C(C6CCCCC6)CC(C6CCCCC6)CC4C4CCCCC4)C4CC(C6CCC7CCCC8C9CCCC%10CCCC(C%109)C6C78)CCC4N(C4C(C6CCCCC6)CC(C6CCCCC6)CC4C4CCCCC4)C5C3)CC2)CC1 ; C1CCC(C2CCC3C(C2)B2C4CC(C5CCC6CCCC7C8CCCC9CCCC(C98)C5C67)CCC4N(C4C(C5CCCCC5)CC(C5CCCCC5)CC4C4CCCCC4)C4CC(N5C6CCCCC6C6CCCCC65)CC(C24)N3C2C(C3CCCCC3)CC(C3CCCCC3)CC2C2CCCCC2)CC1] 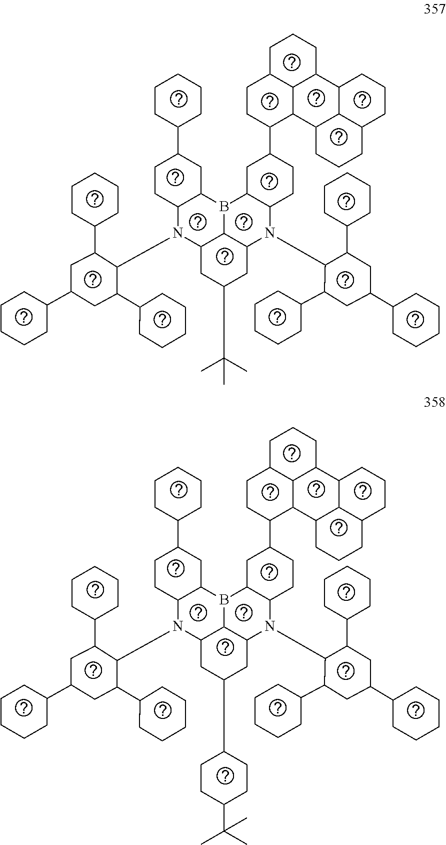 [SMILES: CC(C)(C)C1CC2C3B(C4CC(C5CCCCC5)CCC4N2C2C(C4CCCCC4)CC(C4CCCCC4)CC2C2CCCCC2)C2CC(C4CCC5CCCC6C7CCCC8CCCC(C87)C4C56)CCC2N(C2C(C4CCCCC4)CC(C4CCCCC4)CC2C2CCCCC2)C3C1 ; CC(C)(C)C1CCC(C2CC3C4B(C5CC(C6CCCCC6)CCC5N3C3C(C5CCCCC5)CC(C5CCCCC5)CC3C3CCCCC3)C3CC(C5CCC6CCCC7C8CCCC9CCCC(C98)C5C67)CCC3N(C3C(C5CCCCC5)CC(C5CCCCC5)CC3C3CCCCC3)C4C2)CC1] 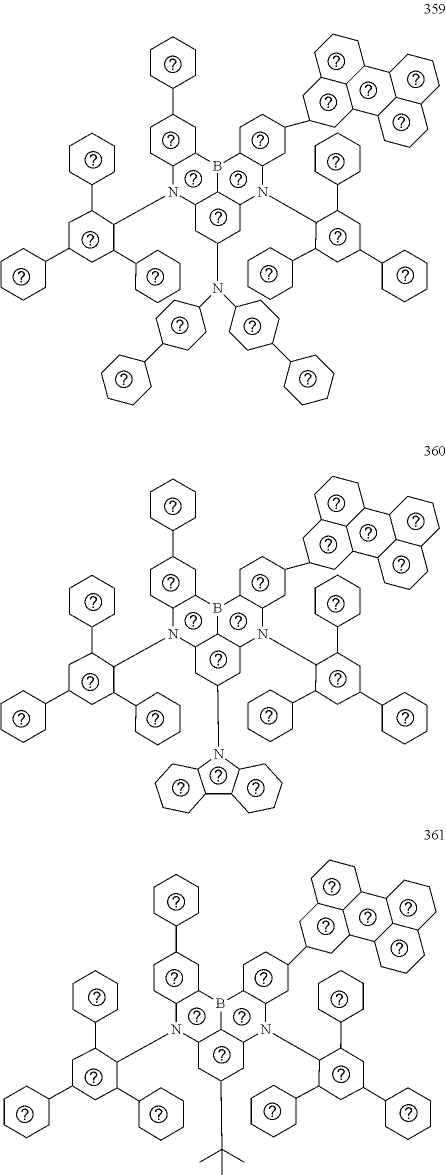 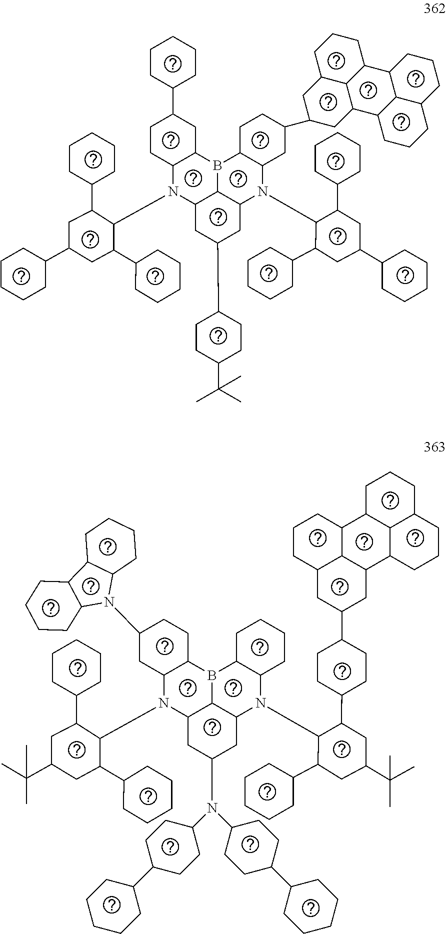 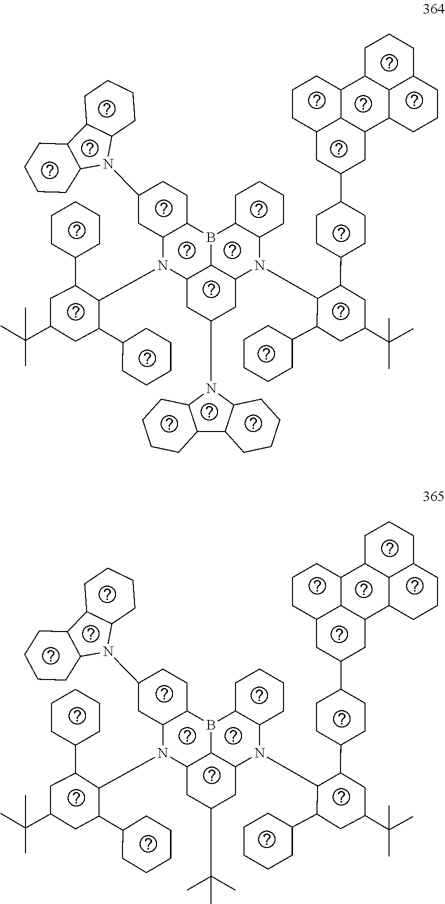 [SMILES: CC(C)(C)C1CC(C2CCCCC2)C(N2C3CCCCC3B3C4CCC(N5C6CCCCC6C6CCCCC65)CC4N(C4C(C5CCCCC5)CC(C(C)(C)C)CC4C4CCCCC4)C4CC(N5C6CCCCC6C6CCCCC65)CC2C34)C(C2CCC(C3CC4CCCC5C6CCCC7CCCC(C(C3)C45)C76)CC2)C1 ; CC(C)(C)C1CC(C2CCCCC2)C(N2C3CCCCC3B3C4CCC(N5C6CCCCC6C6CCCCC65)CC4N(C4C(C5CCCCC5)CC(C(C)(C)C)CC4C4CCCCC4)C4CC(C(C)(C)C)CC2C34)C(C2CCC(C3CC4CCCC5C6CCCC7CCCC(C(C3)C45)C76)CC2)C1] 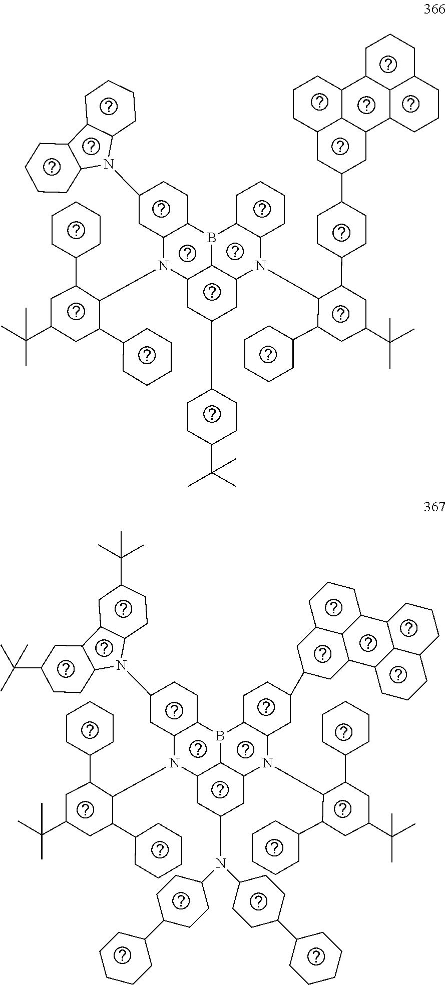 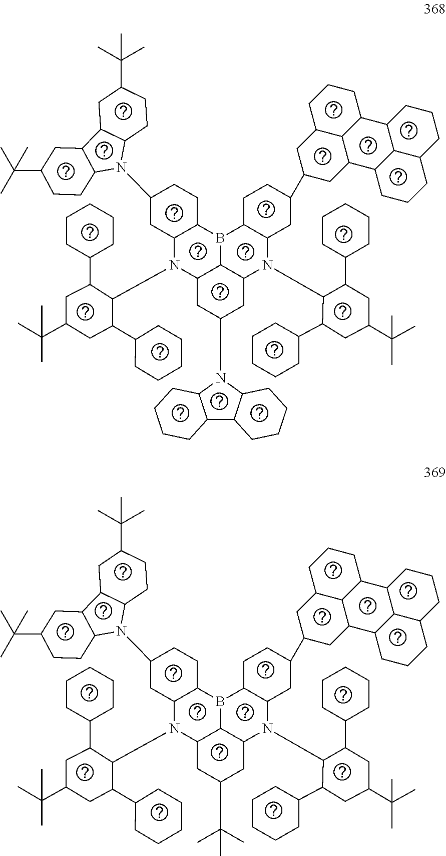 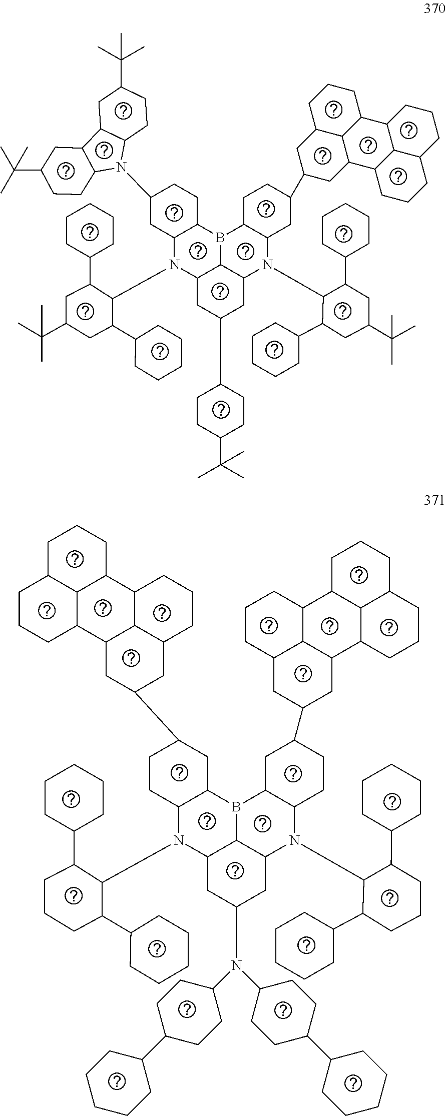 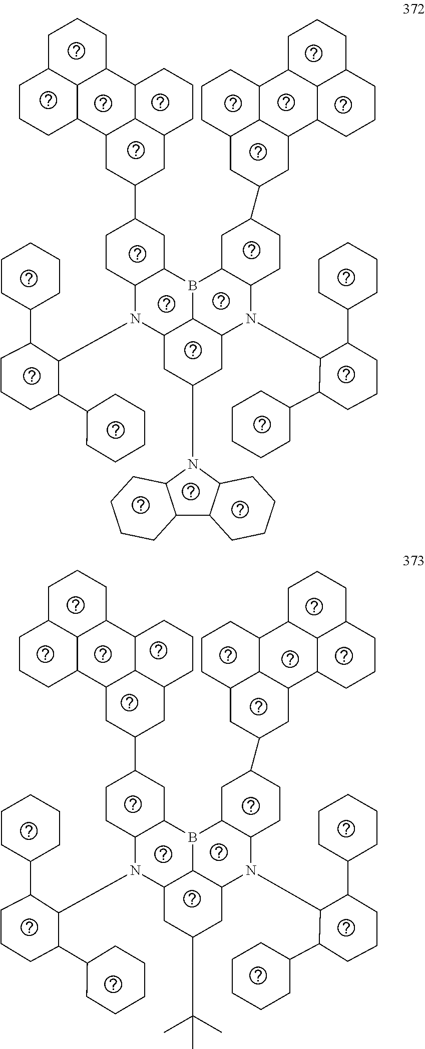 [SMILES: C1CCC(C2CCCC(C3CCCCC3)C2N2C3CCC(C4CC5CCCC6C7CCCC8CCCC(C(C4)C56)C87)CC3B3C4CC(C5CC6CCCC7C8CCCC9CCCC(C(C5)C67)C98)CCC4N(C4C(C5CCCCC5)CCCC4C4CCCCC4)C4CC(N5C6CCCCC6C6CCCCC65)CC2C34)CC1 ; CC(C)(C)C1CC2C3B(C4CC(C5CC6CCCC7C8CCCC9CCCC(C(C5)C67)C98)CCC4N2C2C(C4CCCCC4)CCCC2C2CCCCC2)C2CC(C4CC5CCCC6C7CCCC8CCCC(C(C4)C56)C87)CCC2N(C2C(C4CCCCC4)CCCC2C2CCCCC2)C3C1] 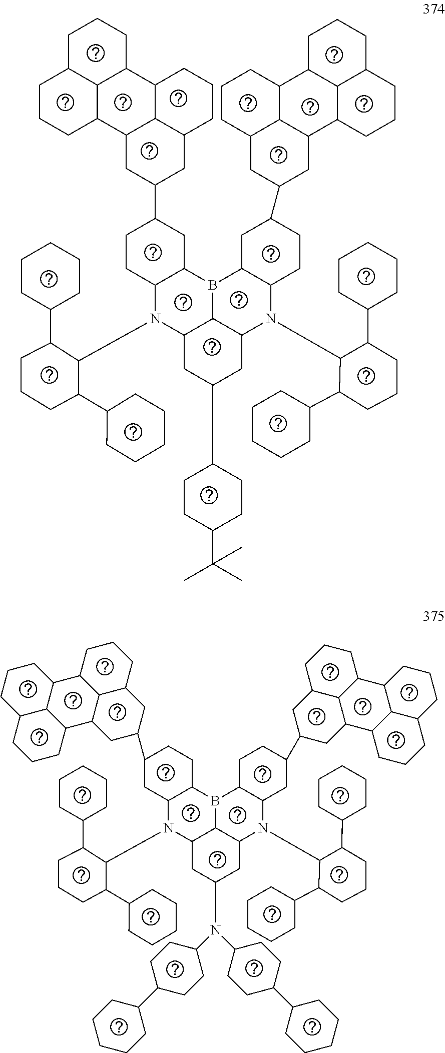 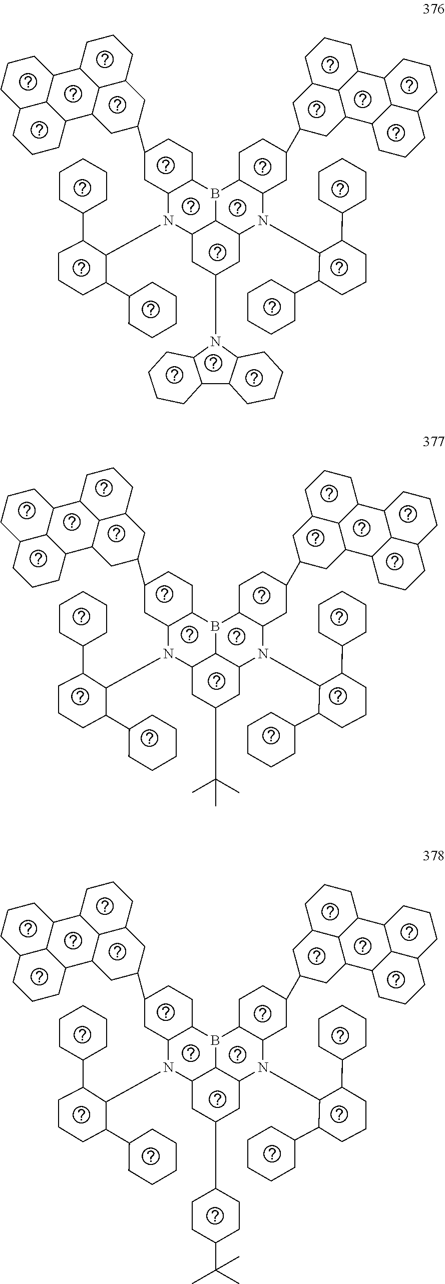 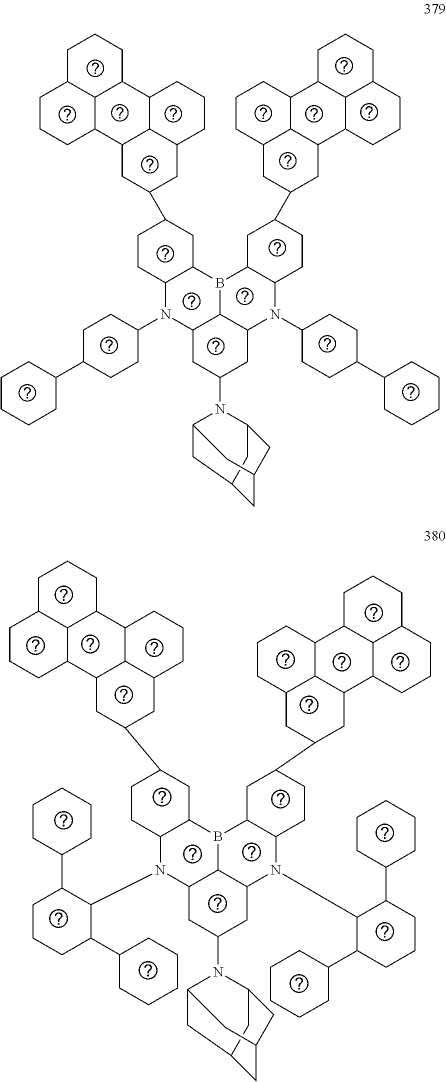 [SMILES: C1CCC(C2CCC(N3C4CCC(C5CC6CCCC7C8CCCC9CCCC(C(C5)C67)C98)CC4B4C5CC(C6CC7CCCC8C9CCCC%10CCCC(C(C6)C78)C%109)CCC5N(C5CCC(C6CCCCC6)CC5)C5CC(N6C7CC8CC(C7)CC6C8)CC3C45)CC2)CC1 ; C1CCC(C2CCCC(C3CCCCC3)C2N2C3CCC(C4CC5CCCC6C7CCCC8CCCC(C(C4)C56)C87)CC3B3C4CC(C5CC6CCCC7C8CCCC9CCCC(C(C5)C67)C98)CCC4N(C4C(C5CCCCC5)CCCC4C4CCCCC4)C4CC(N5C6CC7CC(C6)CC5C7)CC2C34)CC1] 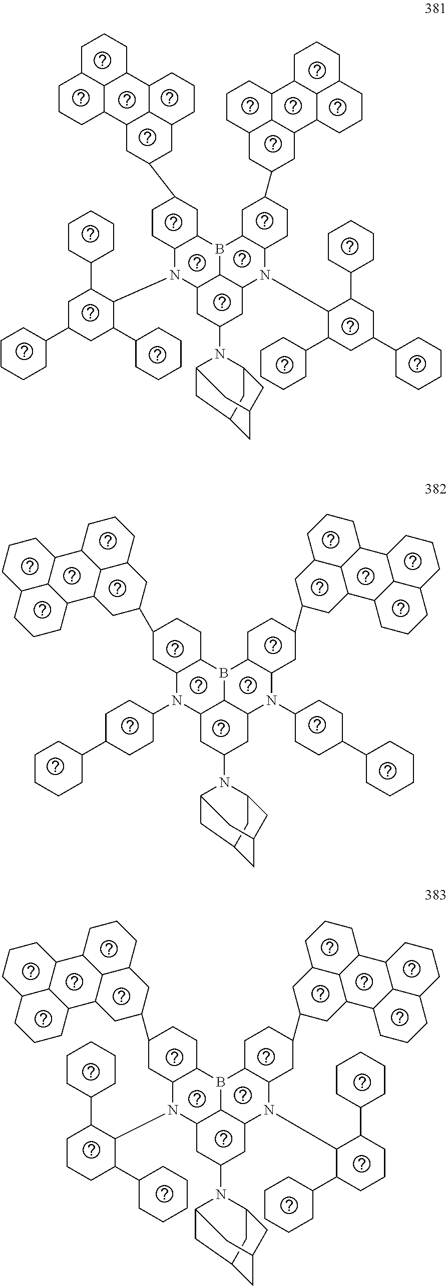 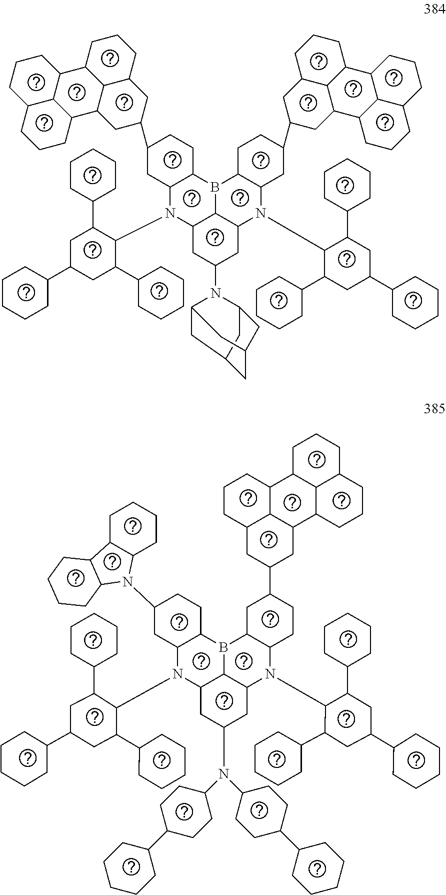 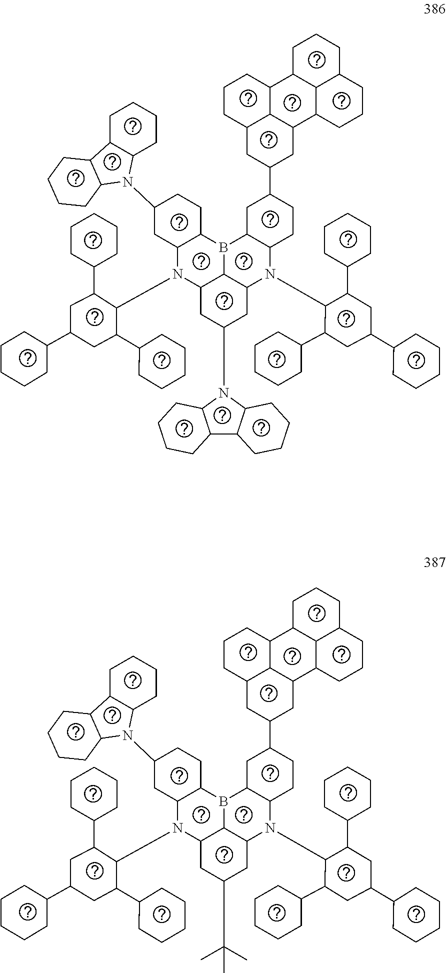 [SMILES: C1CCC(C2CC(C3CCCCC3)C(N3C4CCC(C5CC6CCCC7C8CCCC9CCCC(C(C5)C67)C98)CC4B4C5CCC(N6C7CCCCC7C7CCCCC76)CC5N(C5C(C6CCCCC6)CC(C6CCCCC6)CC5C5CCCCC5)C5CC(N6C7CCCCC7C7CCCCC76)CC3C45)C(C3CCCCC3)C2)CC1 ; CC(C)(C)C1CC2C3B(C4CC(C5CC6CCCC7C8CCCC9CCCC(C(C5)C67)C98)CCC4N2C2C(C4CCCCC4)CC(C4CCCCC4)CC2C2CCCCC2)C2CCC(N4C5CCCCC5C5CCCCC54)CC2N(C2C(C4CCCCC4)CC(C4CCCCC4)CC2C2CCCCC2)C3C1] 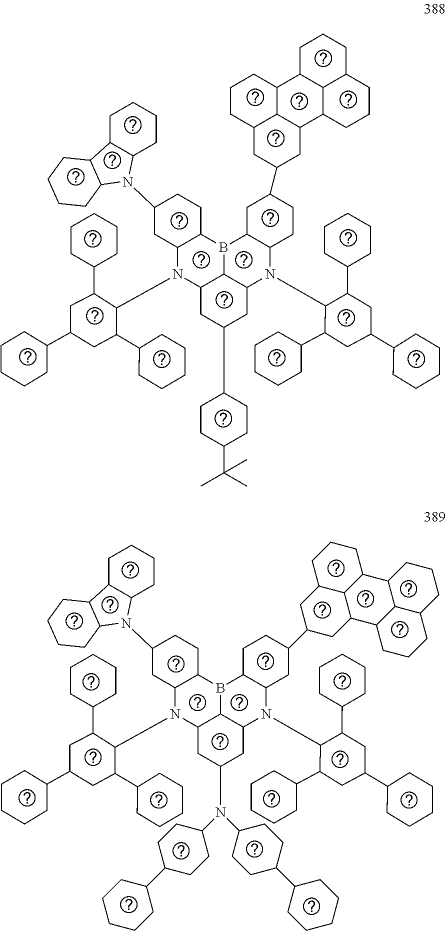 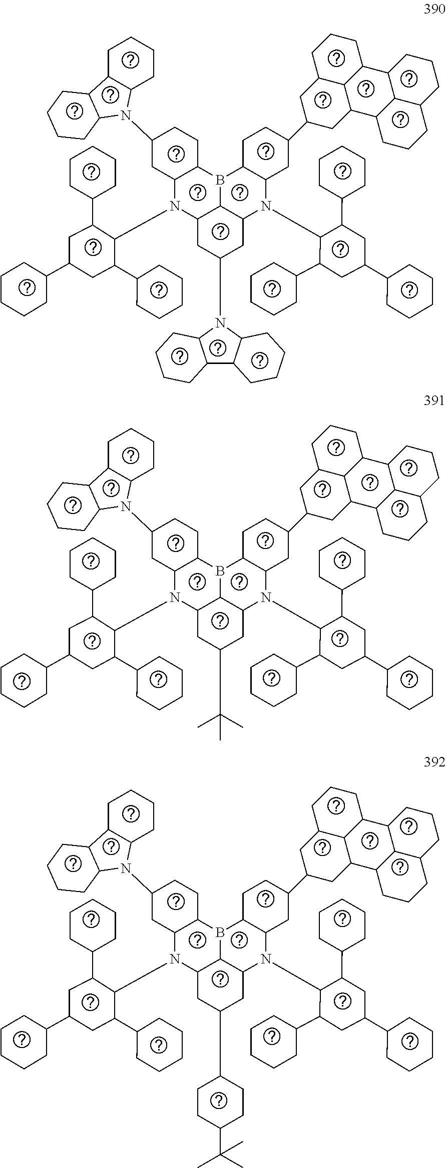 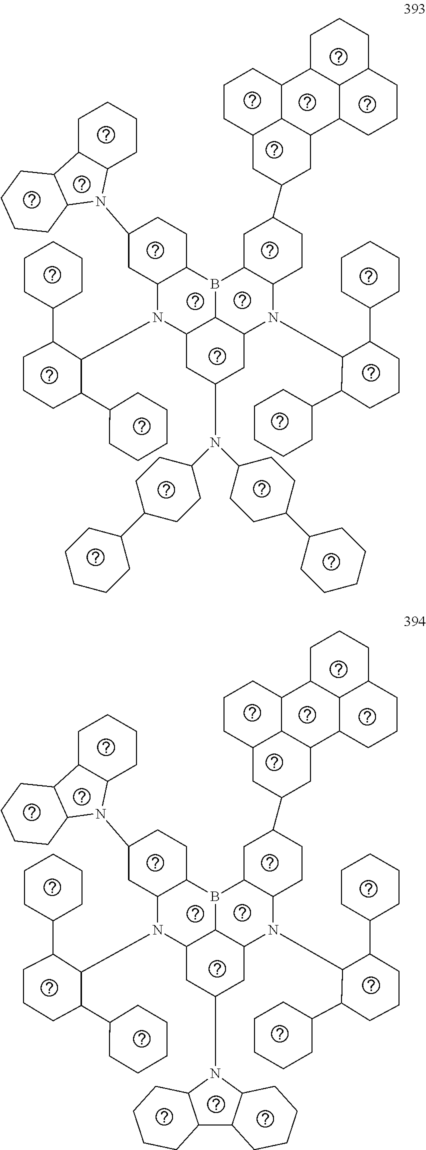 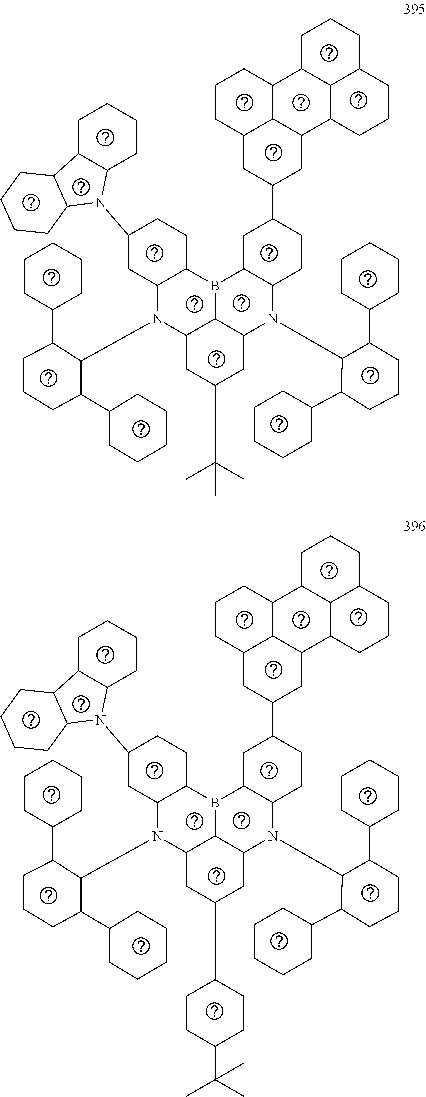 [SMILES: CC(C)(C)C1CC2C3B(C4CC(C5CC6CCCC7C8CCCC9CCCC(C(C5)C67)C98)CCC4N2C2C(C4CCCCC4)CCCC2C2CCCCC2)C2CCC(N4C5CCCCC5C5CCCCC54)CC2N(C2C(C4CCCCC4)CCCC2C2CCCCC2)C3C1 ; CC(C)(C)C1CCC(C2CC3C4B(C5CC(C6CC7CCCC8C9CCCC%10CCCC(C(C6)C78)C%109)CCC5N3C3C(C5CCCCC5)CCCC3C3CCCCC3)C3CCC(N5C6CCCCC6C6CCCCC65)CC3N(C3C(C5CCCCC5)CCCC3C3CCCCC3)C4C2)CC1] 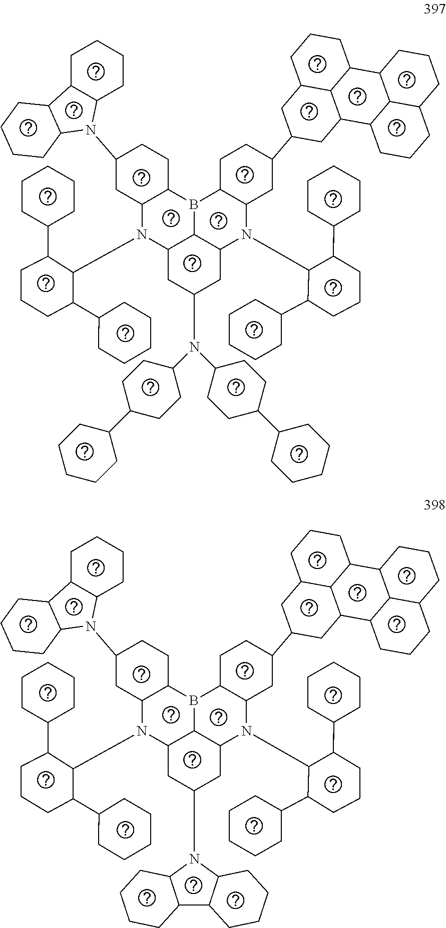 [SMILES: C1CCC(C2CCC(N(C3CCC(C4CCCCC4)CC3)C3CC4C5B(C6CCC(C7CC8CCCC9C%10CCCC%11CCCC(C(C7)C89)C%11%10)CC6N4C4C(C6CCCCC6)CCCC4C4CCCCC4)C4CCC(N6C7CCCCC7C7CCCCC76)CC4N(C4C(C6CCCCC6)CCCC4C4CCCCC4)C5C3)CC2)CC1 ; C1CCC(C2CCCC(C3CCCCC3)C2N2C3CC(C4CC5CCCC6C7CCCC8CCCC(C(C4)C56)C87)CCC3B3C4CCC(N5C6CCCCC6C6CCCCC65)CC4N(C4C(C5CCCCC5)CCCC4C4CCCCC4)C4CC(N5C6CCCCC6C6CCCCC65)CC2C34)CC1] 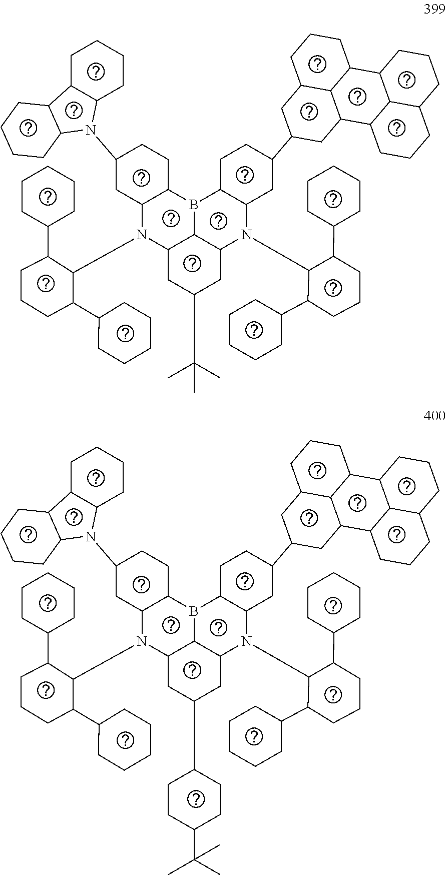 [SMILES: CC(C)(C)C1CC2C3B(C4CCC(C5CC6CCCC7C8CCCC9CCCC(C(C5)C67)C98)CC4N2C2C(C4CCCCC4)CCCC2C2CCCCC2)C2CCC(N4C5CCCCC5C5CCCCC54)CC2N(C2C(C4CCCCC4)CCCC2C2CCCCC2)C3C1 ; CC(C)(C)C1CCC(C2CC3C4B(C5CCC(C6CC7CCCC8C9CCCC%10CCCC(C(C6)C78)C%109)CC5N3C3C(C5CCCCC5)CCCC3C3CCCCC3)C3CCC(N5C6CCCCC6C6CCCCC65)CC3N(C3C(C5CCCCC5)CCCC3C3CCCCC3)C4C2)CC1] 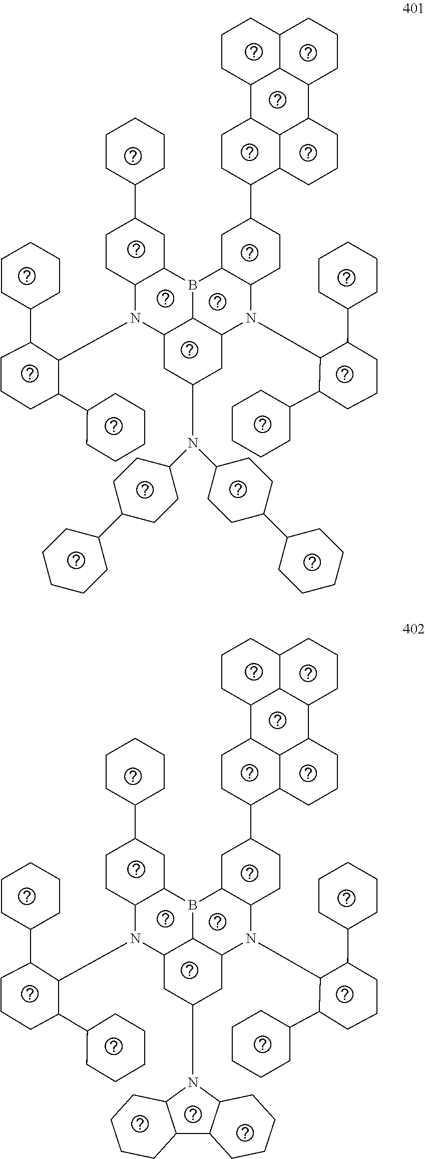 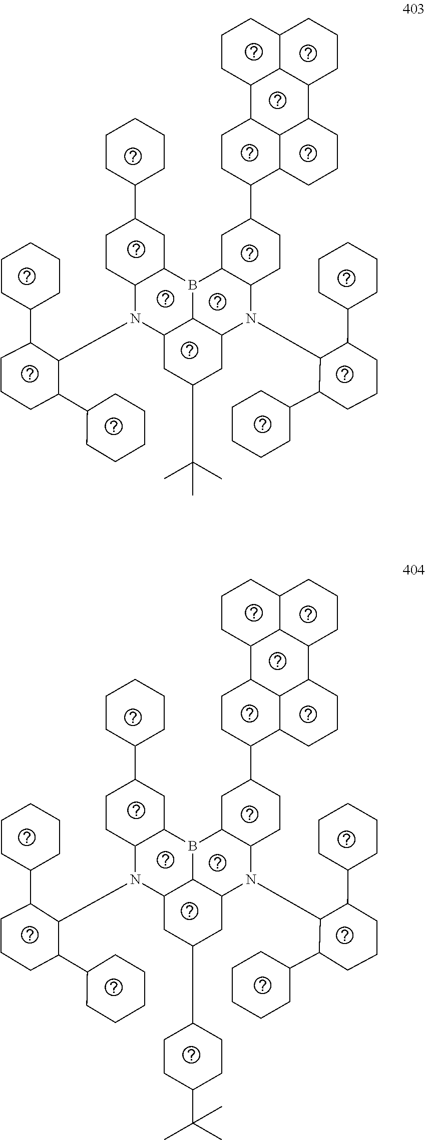 [SMILES: CC(C)(C)C1CC2C3B(C4CC(C5CCCCC5)CCC4N2C2C(C4CCCCC4)CCCC2C2CCCCC2)C2CC(C4CCC5C6CCCC7CCCC(C8CCCC4C85)C76)CCC2N(C2C(C4CCCCC4)CCCC2C2CCCCC2)C3C1 ; CC(C)(C)C1CCC(C2CC3C4B(C5CC(C6CCCCC6)CCC5N3C3C(C5CCCCC5)CCCC3C3CCCCC3)C3CC(C5CCC6C7CCCC8CCCC(C9CCCC5C96)C87)CCC3N(C3C(C5CCCCC5)CCCC3C3CCCCC3)C4C2)CC1] 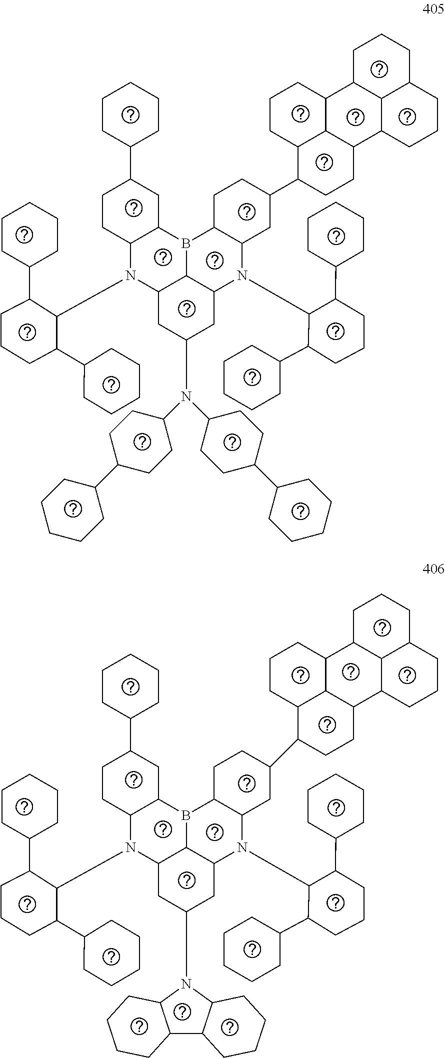 [SMILES: C1CCC(C2CCC(N(C3CCC(C4CCCCC4)CC3)C3CC4C5B(C6CC(C7CCCCC7)CCC6N4C4C(C6CCCCC6)CCCC4C4CCCCC4)C4CCC(C6CCC7C8CCCC9CCCC(C%10CCCC6C%107)C98)CC4N(C4C(C6CCCCC6)CCCC4C4CCCCC4)C5C3)CC2)CC1 ; C1CCC(C2CCC3C(C2)B2C4CCC(C5CCC6C7CCCC8CCCC(C9CCCC5C96)C87)CC4N(C4C(C5CCCCC5)CCCC4C4CCCCC4)C4CC(N5C6CCCCC6C6CCCCC65)CC(C24)N3C2C(C3CCCCC3)CCCC2C2CCCCC2)CC1] 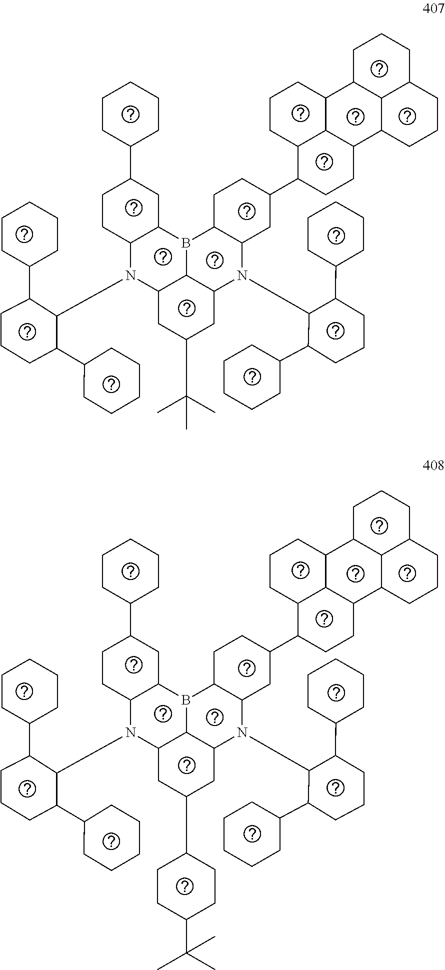 [SMILES: CC(C)(C)C1CC2C3B(C4CC(C5CCCCC5)CCC4N2C2C(C4CCCCC4)CCCC2C2CCCCC2)C2CCC(C4CCC5C6CCCC7CCCC(C8CCCC4C85)C76)CC2N(C2C(C4CCCCC4)CCCC2C2CCCCC2)C3C1 ; CC(C)(C)C1CCC(C2CC3C4B(C5CC(C6CCCCC6)CCC5N3C3C(C5CCCCC5)CCCC3C3CCCCC3)C3CCC(C5CCC6C7CCCC8CCCC(C9CCCC5C96)C87)CC3N(C3C(C5CCCCC5)CCCC3C3CCCCC3)C4C2)CC1] 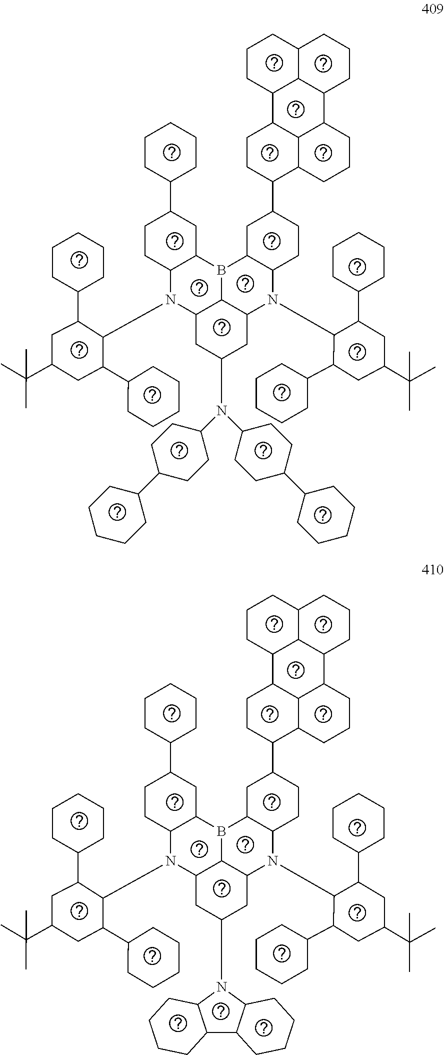 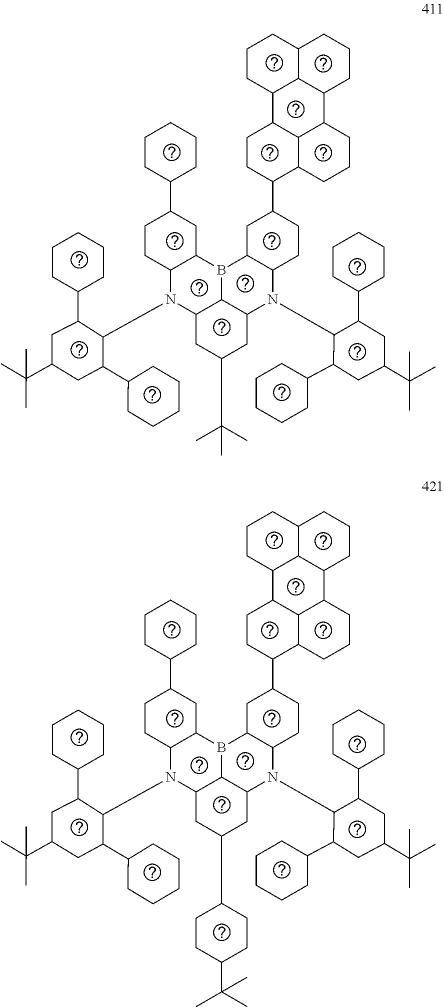 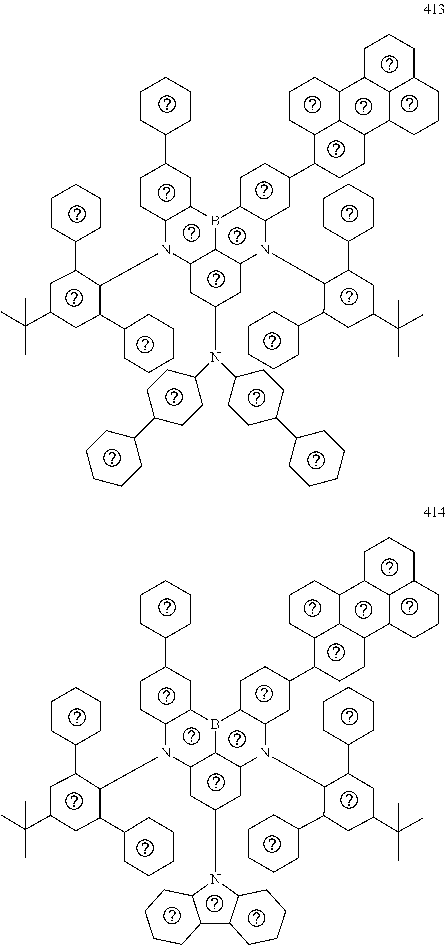 [SMILES: CC(C)(C)C1CC(C2CCCCC2)C(N2C3CCC(C4CCCCC4)CC3B3C4CCC(C5CCC6C7CCCC8CCCC(C9CCCC5C96)C87)CC4N(C4C(C5CCCCC5)CC(C(C)(C)C)CC4C4CCCCC4)C4CC(N(C5CCC(C6CCCCC6)CC5)C5CCC(C6CCCCC6)CC5)CC2C34)C(C2CCCCC2)C1 ; CC(C)(C)C1CC(C2CCCCC2)C(N2C3CCC(C4CCCCC4)CC3B3C4CCC(C5CCC6C7CCCC8CCCC(C9CCCC5C96)C87)CC4N(C4C(C5CCCCC5)CC(C(C)(C)C)CC4C4CCCCC4)C4CC(N5C6CCCCC6C6CCCCC65)CC2C34)C(C2CCCCC2)C1] 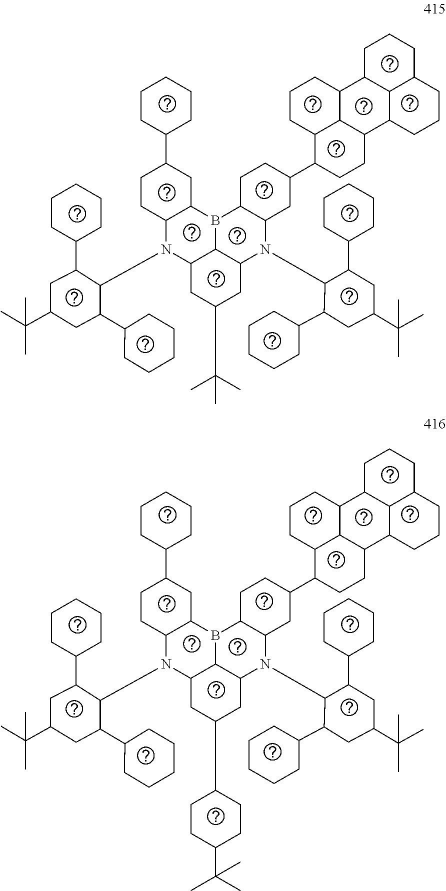 [SMILES: CC(C)(C)C1CC(C2CCCCC2)C(N2C3CCC(C4CCCCC4)CC3B3C4CCC(C5CCC6C7CCCC8CCCC(C9CCCC5C96)C87)CC4N(C4C(C5CCCCC5)CC(C(C)(C)C)CC4C4CCCCC4)C4CC(C(C)(C)C)CC2C34)C(C2CCCCC2)C1 ; CC(C)(C)C1CCC(C2CC3C4B(C5CC(C6CCCCC6)CCC5N3C3C(C5CCCCC5)CC(C(C)(C)C)CC3C3CCCCC3)C3CCC(C5CCC6C7CCCC8CCCC(C9CCCC5C96)C87)CC3N(C3C(C5CCCCC5)CC(C(C)(C)C)CC3C3CCCCC3)C4C2)CC1] 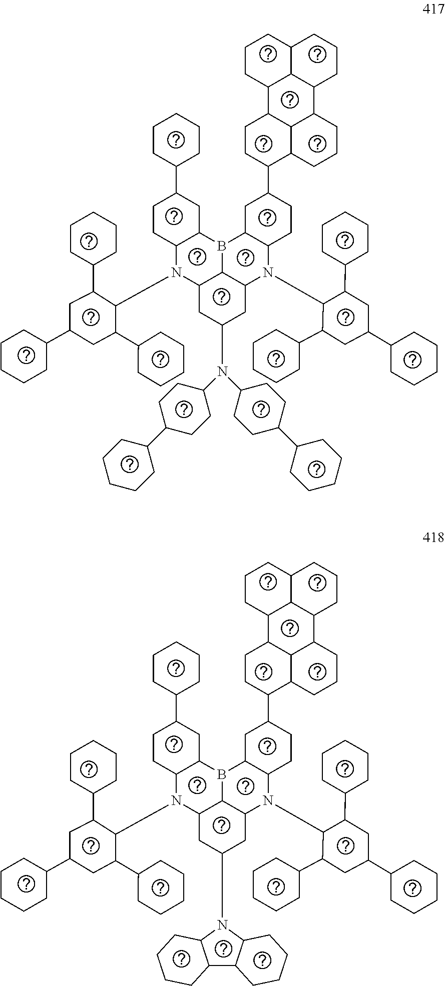 [SMILES: C1CCC(C2CCC(N(C3CCC(C4CCCCC4)CC3)C3CC4C5B(C6CC(C7CCCCC7)CCC6N4C4C(C6CCCCC6)CC(C6CCCCC6)CC4C4CCCCC4)C4CC(C6CCC7C8CCCC9CCCC(C%10CCCC6C%107)C98)CCC4N(C4C(C6CCCCC6)CC(C6CCCCC6)CC4C4CCCCC4)C5C3)CC2)CC1 ; C1CCC(C2CCC3C(C2)B2C4CC(C5CCC6C7CCCC8CCCC(C9CCCC5C96)C87)CCC4N(C4C(C5CCCCC5)CC(C5CCCCC5)CC4C4CCCCC4)C4CC(N5C6CCCCC6C6CCCCC65)CC(C24)N3C2C(C3CCCCC3)CC(C3CCCCC3)CC2C2CCCCC2)CC1] 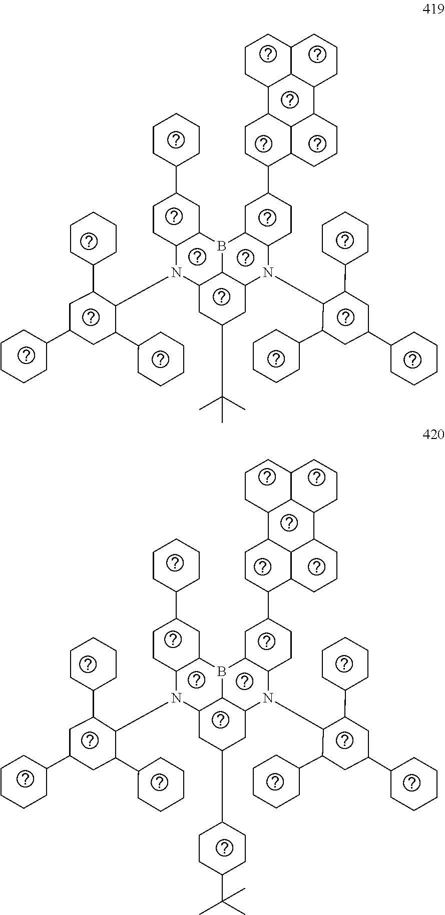 [SMILES: CC(C)(C)C1CC2C3B(C4CC(C5CCCCC5)CCC4N2C2C(C4CCCCC4)CC(C4CCCCC4)CC2C2CCCCC2)C2CC(C4CCC5C6CCCC7CCCC(C8CCCC4C85)C76)CCC2N(C2C(C4CCCCC4)CC(C4CCCCC4)CC2C2CCCCC2)C3C1 ; CC(C)(C)C1CCC(C2CC3C4B(C5CC(C6CCCCC6)CCC5N3C3C(C5CCCCC5)CC(C5CCCCC5)CC3C3CCCCC3)C3CC(C5CCC6C7CCCC8CCCC(C9CCCC5C96)C87)CCC3N(C3C(C5CCCCC5)CC(C5CCCCC5)CC3C3CCCCC3)C4C2)CC1] 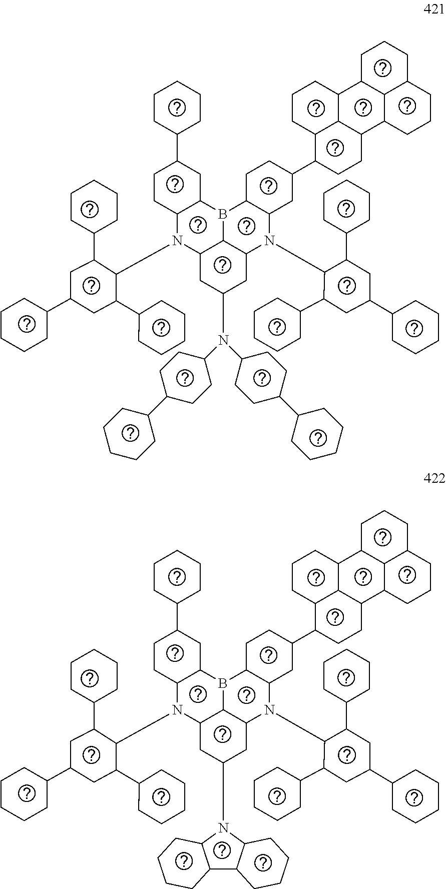 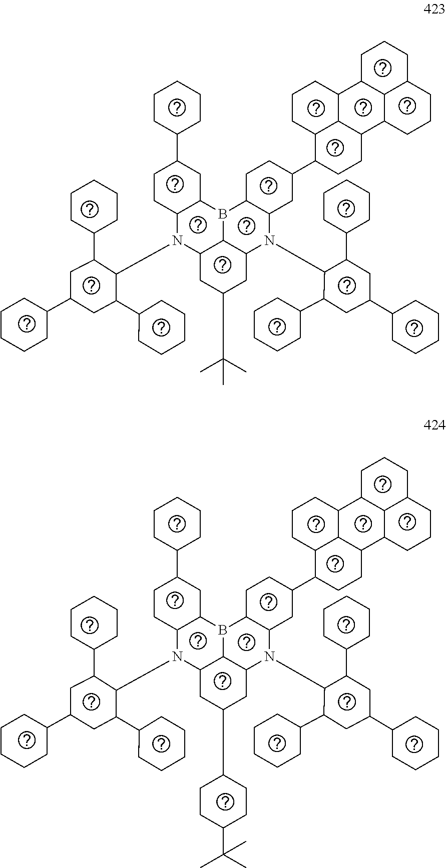 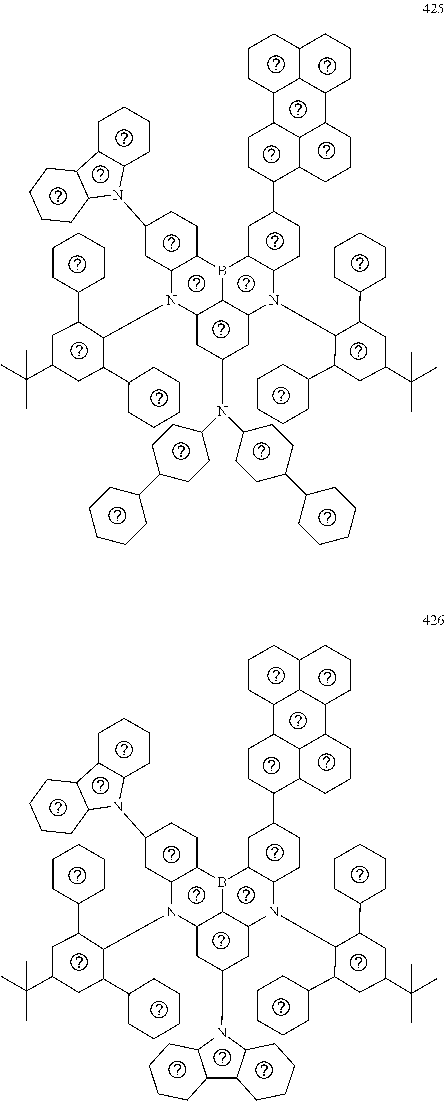 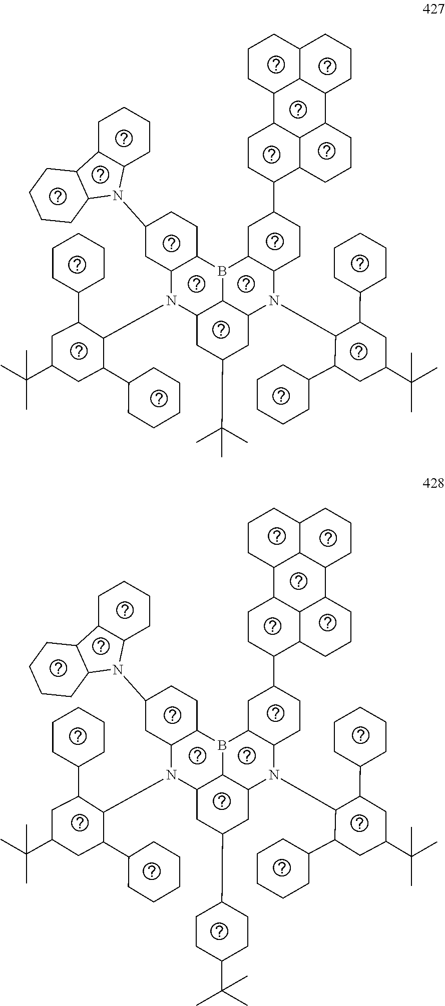 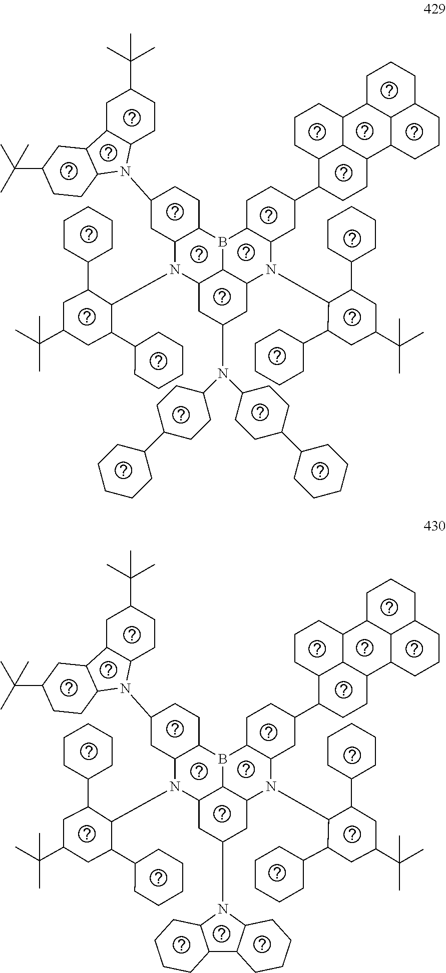 [SMILES: CC(C)(C)C1CCC2C(C1)C1CC(C(C)(C)C)CCC1N2C1CCC2B3C4CCC(C5CCC6C7CCCC8CCCC(C9CCCC5C96)C87)CC4N(C4C(C5CCCCC5)CC(C(C)(C)C)CC4C4CCCCC4)C4CC(N(C5CCC(C6CCCCC6)CC5)C5CCC(C6CCCCC6)CC5)CC(C34)N(C3C(C4CCCCC4)CC(C(C)(C)C)CC3C3CCCCC3)C2C1 ; CC(C)(C)C1CCC2C(C1)C1CC(C(C)(C)C)CCC1N2C1CCC2B3C4CCC(C5CCC6C7CCCC8CCCC(C9CCCC5C96)C87)CC4N(C4C(C5CCCCC5)CC(C(C)(C)C)CC4C4CCCCC4)C4CC(N5C6CCCCC6C6CCCCC65)CC(C34)N(C3C(C4CCCCC4)CC(C(C)(C)C)CC3C3CCCCC3)C2C1] 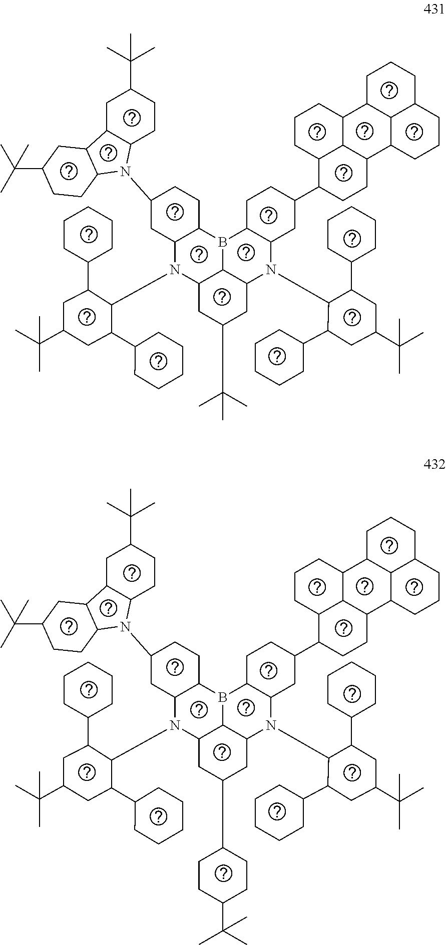 [SMILES: CC(C)(C)C1CCC2C(C1)C1CC(C(C)(C)C)CCC1N2C1CCC2B3C4CCC(C5CCC6C7CCCC8CCCC(C9CCCC5C96)C87)CC4N(C4C(C5CCCCC5)CC(C(C)(C)C)CC4C4CCCCC4)C4CC(C(C)(C)C)CC(C34)N(C3C(C4CCCCC4)CC(C(C)(C)C)CC3C3CCCCC3)C2C1 ; CC(C)(C)C1CCC(C2CC3C4B(C5CCC(C6CCC7C8CCCC9CCCC(C%10CCCC6C%107)C98)CC5N3C3C(C5CCCCC5)CC(C(C)(C)C)CC3C3CCCCC3)C3CCC(N5C6CCC(C(C)(C)C)CC6C6CC(C(C)(C)C)CCC65)CC3N(C3C(C5CCCCC5)CC(C(C)(C)C)CC3C3CCCCC3)C4C2)CC1] 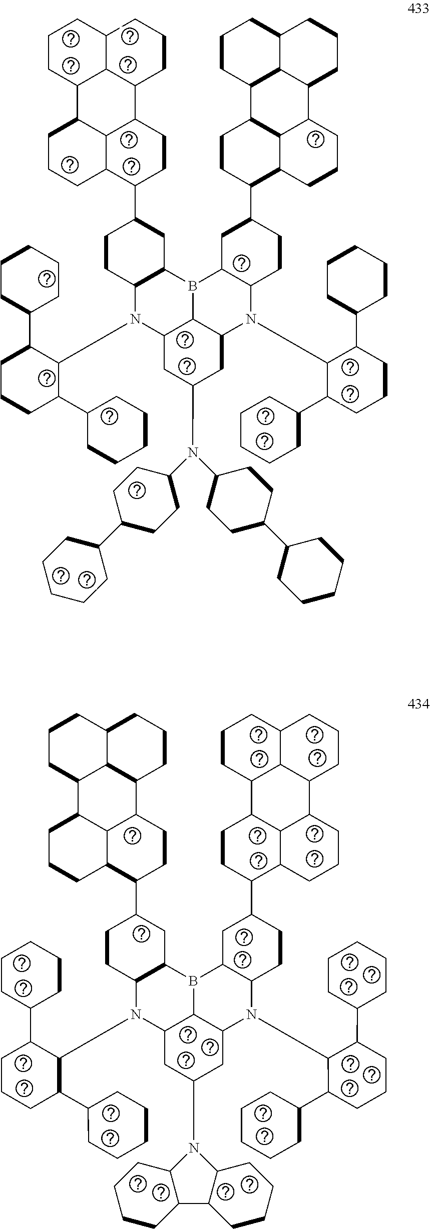 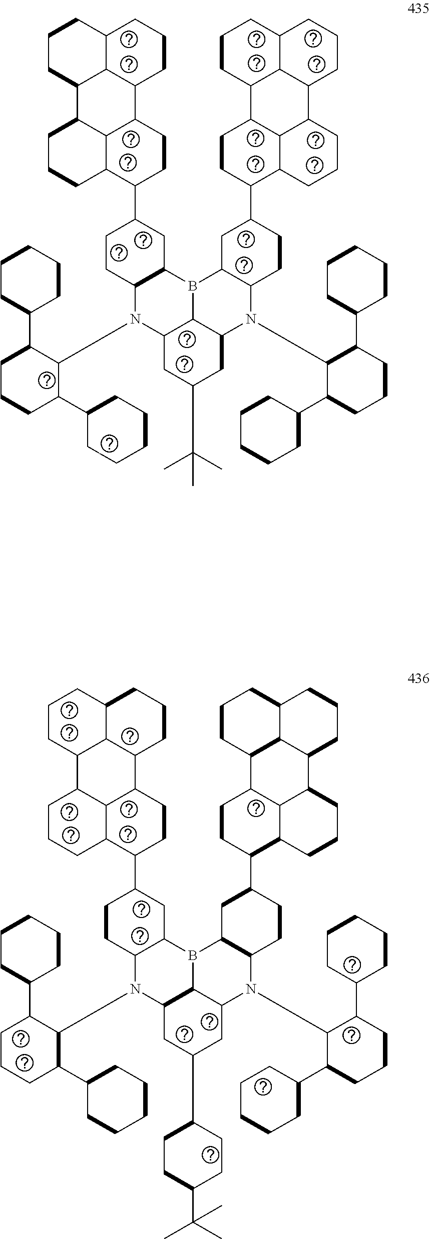 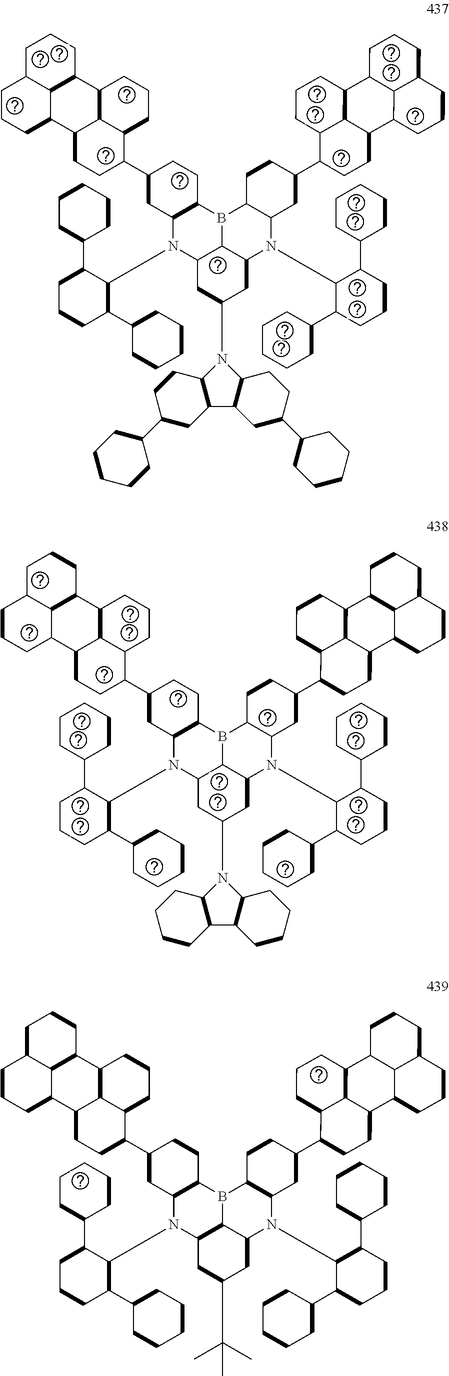 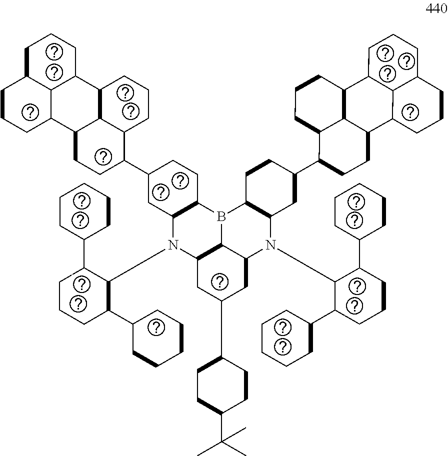 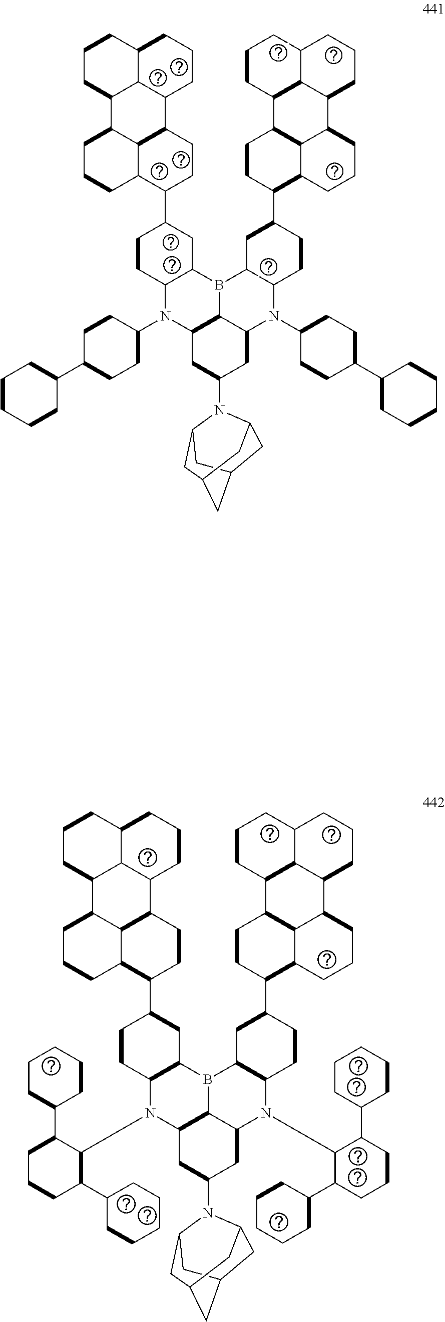 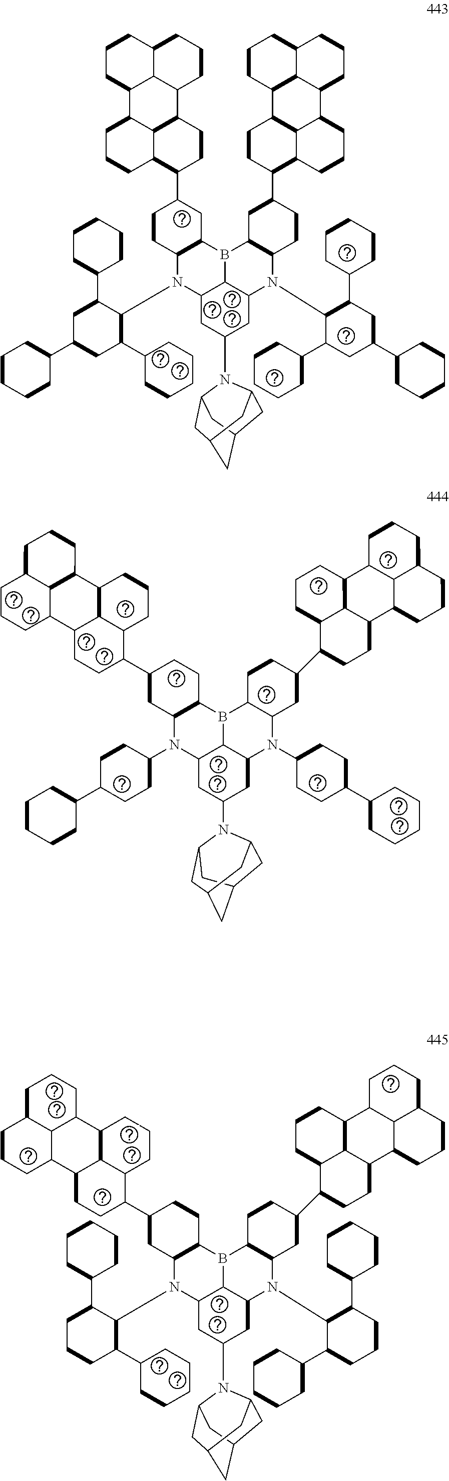 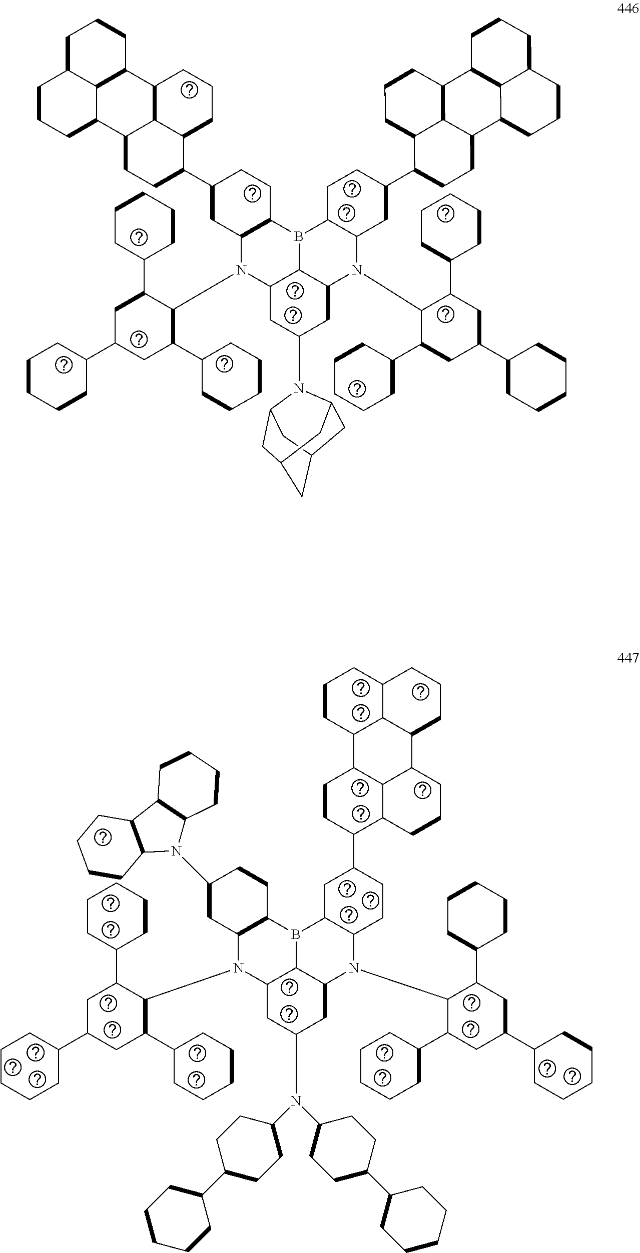 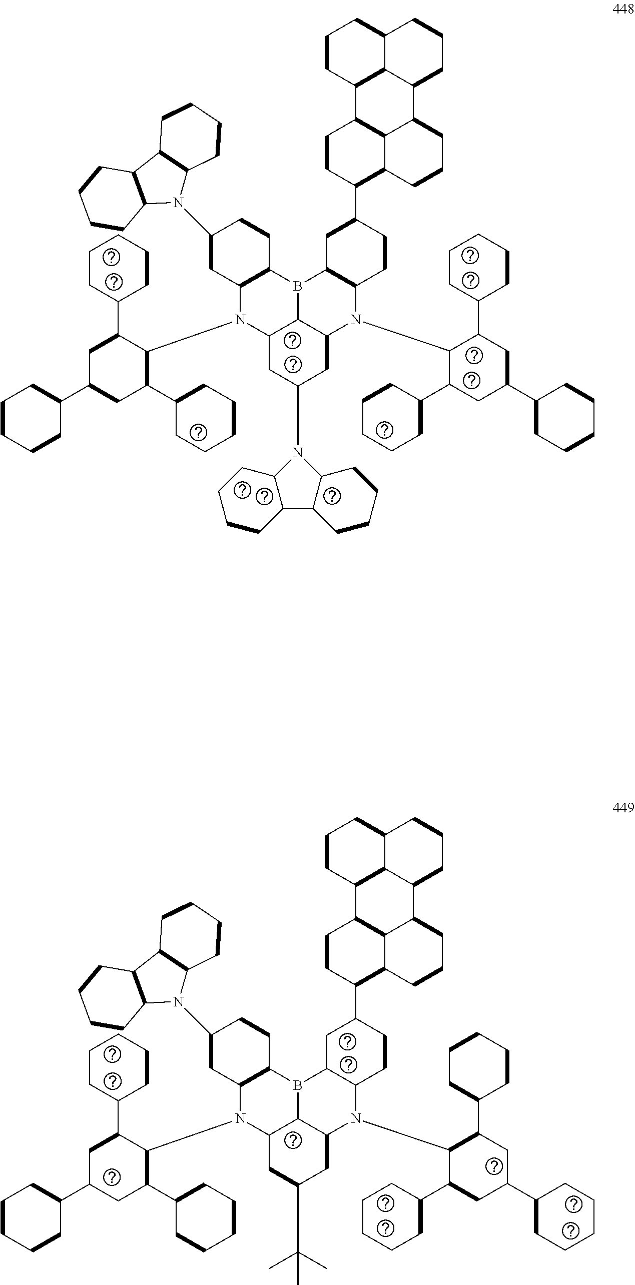 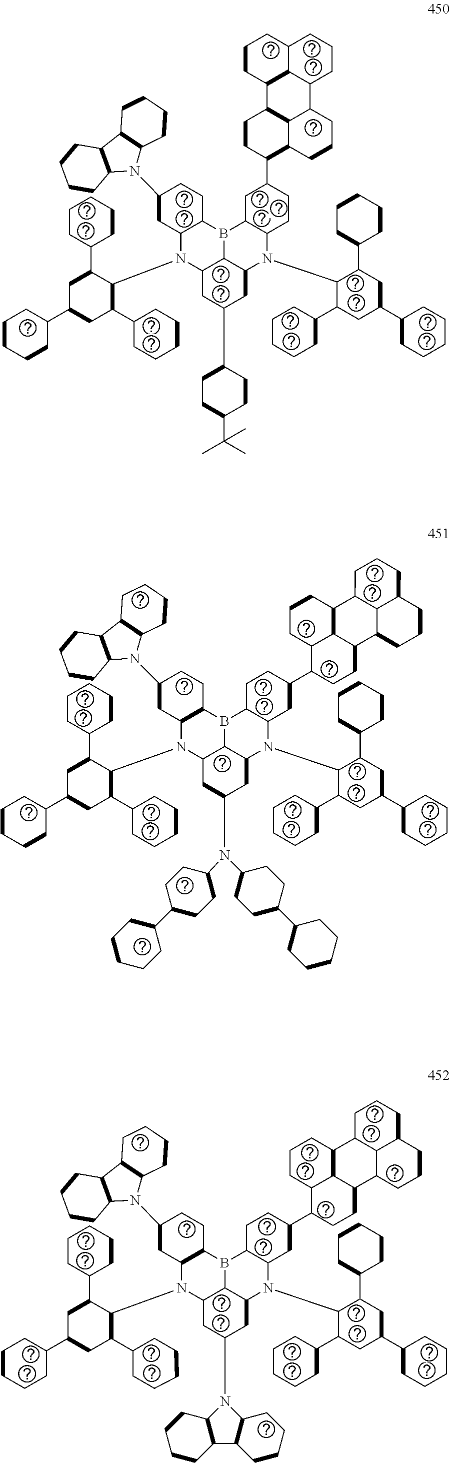 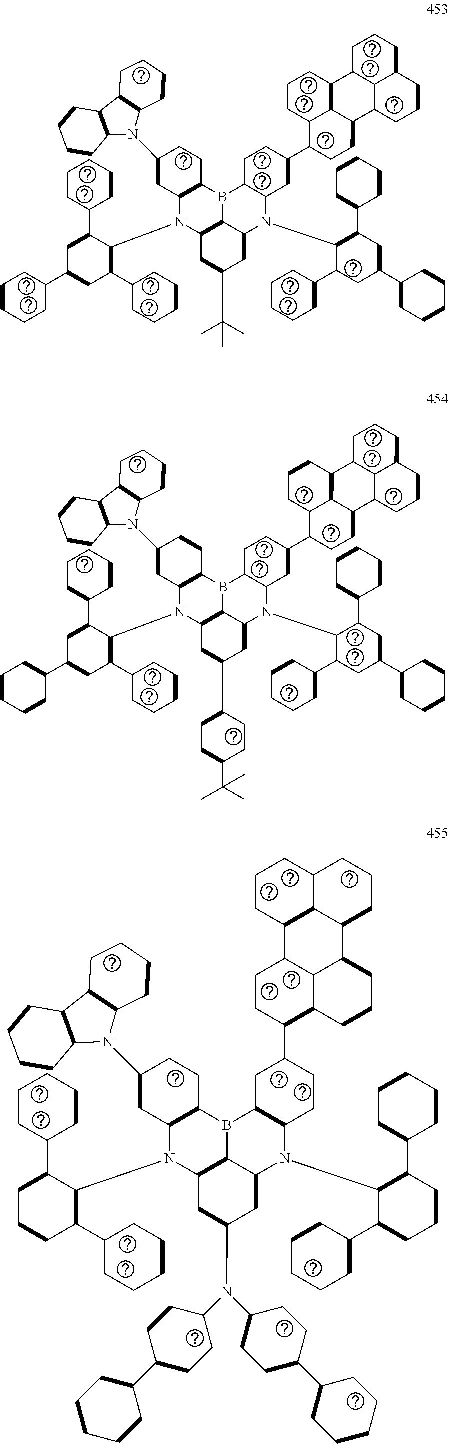 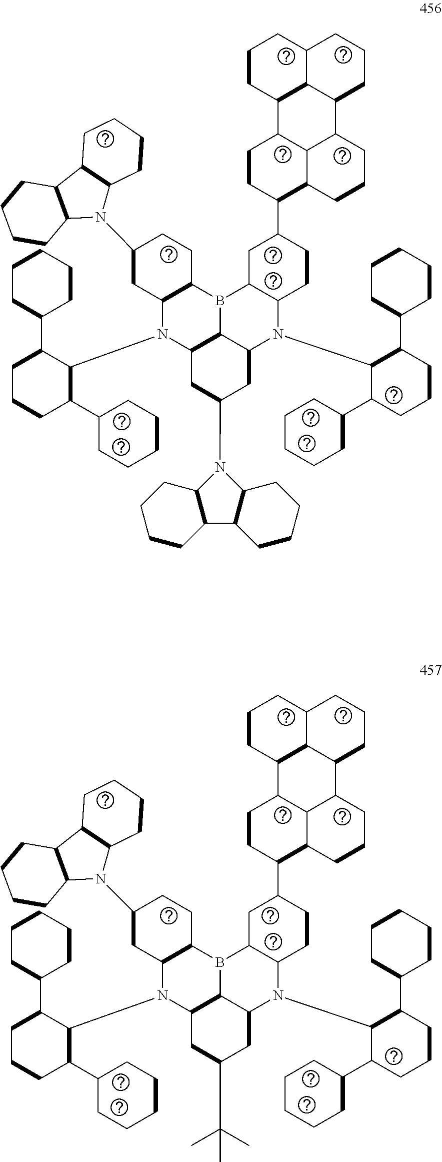 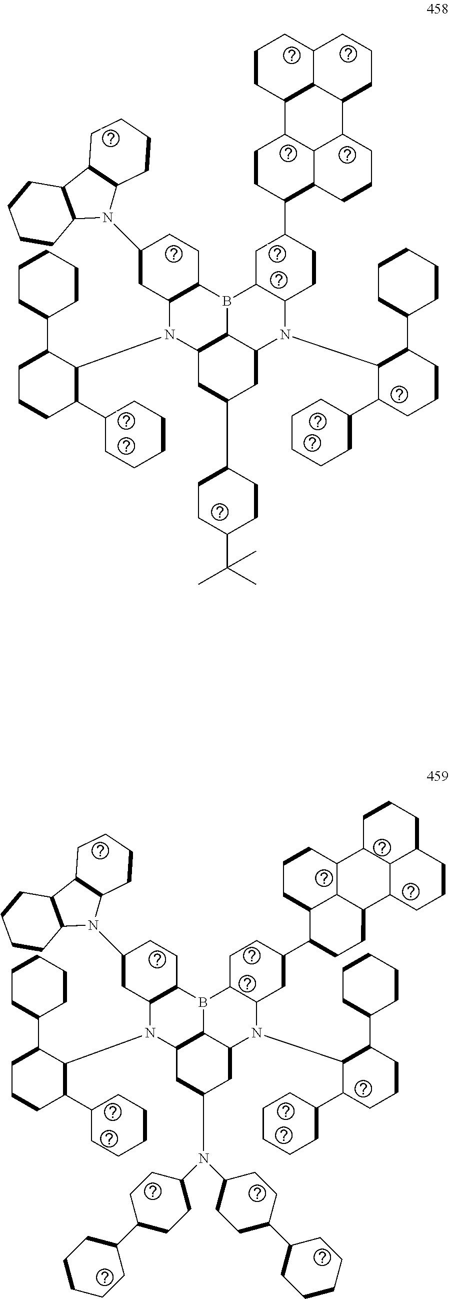 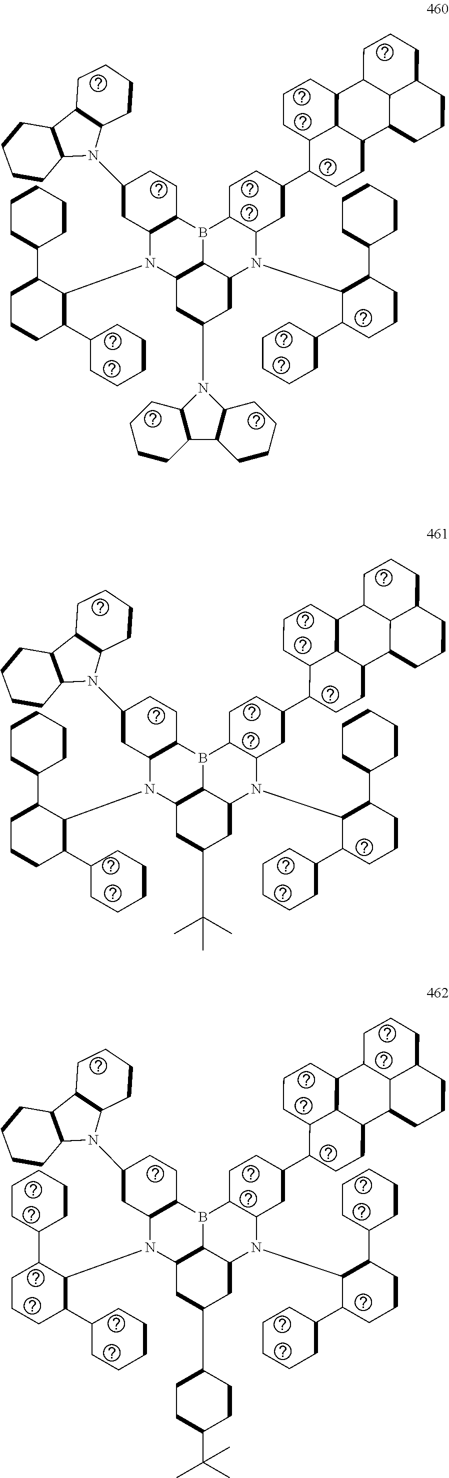 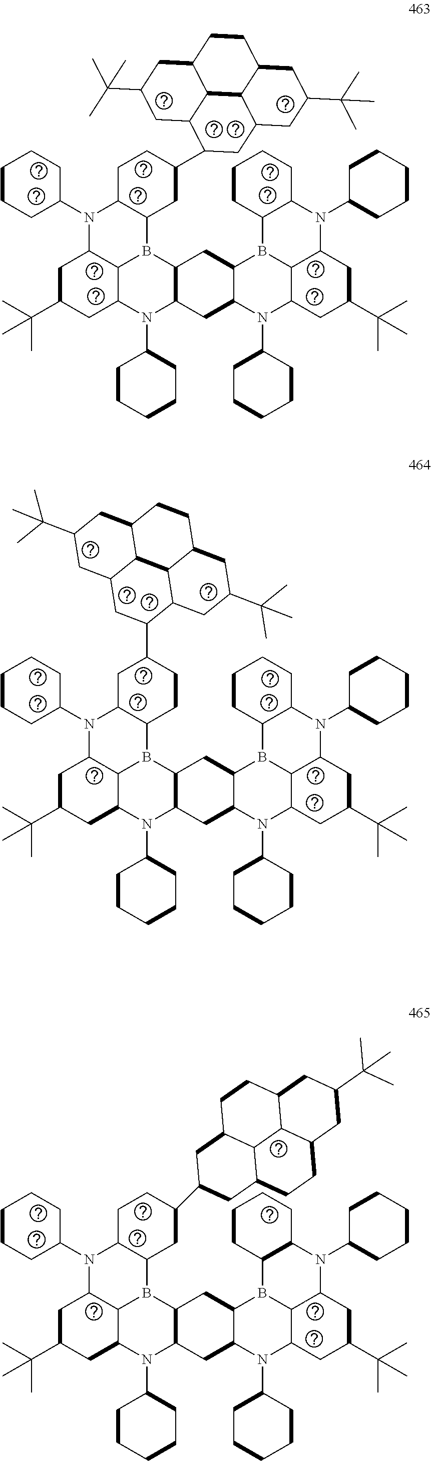 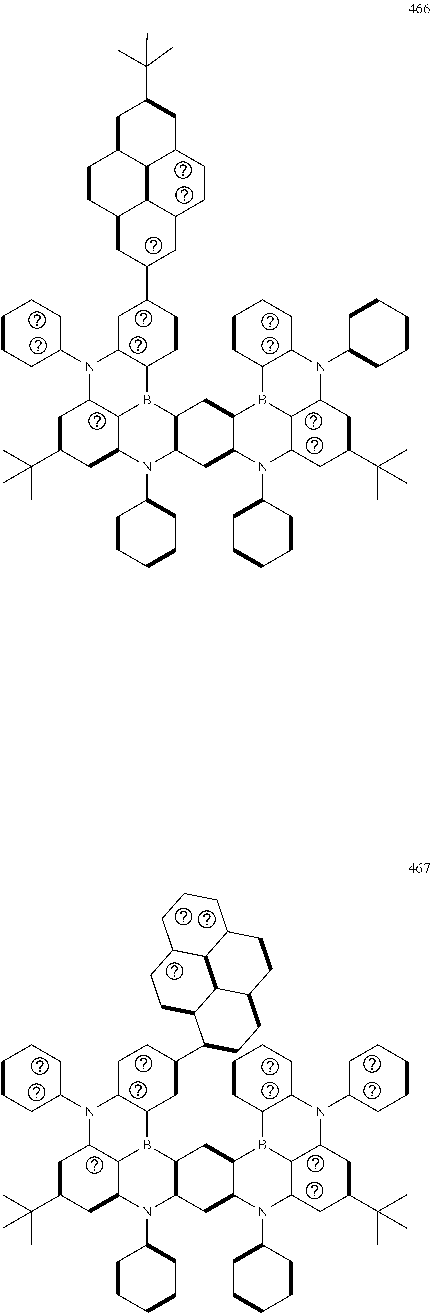 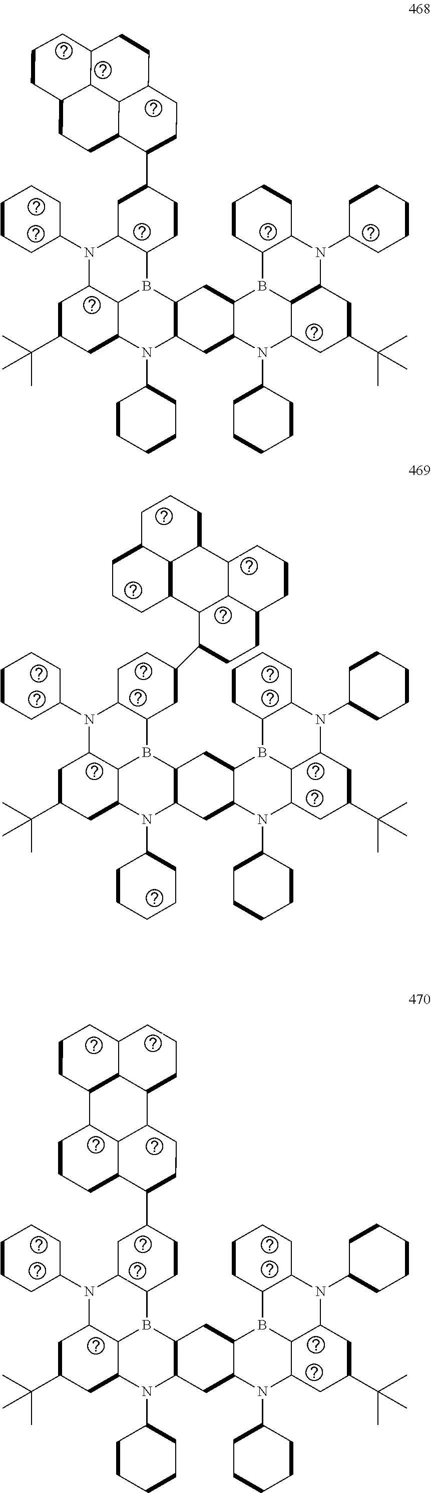 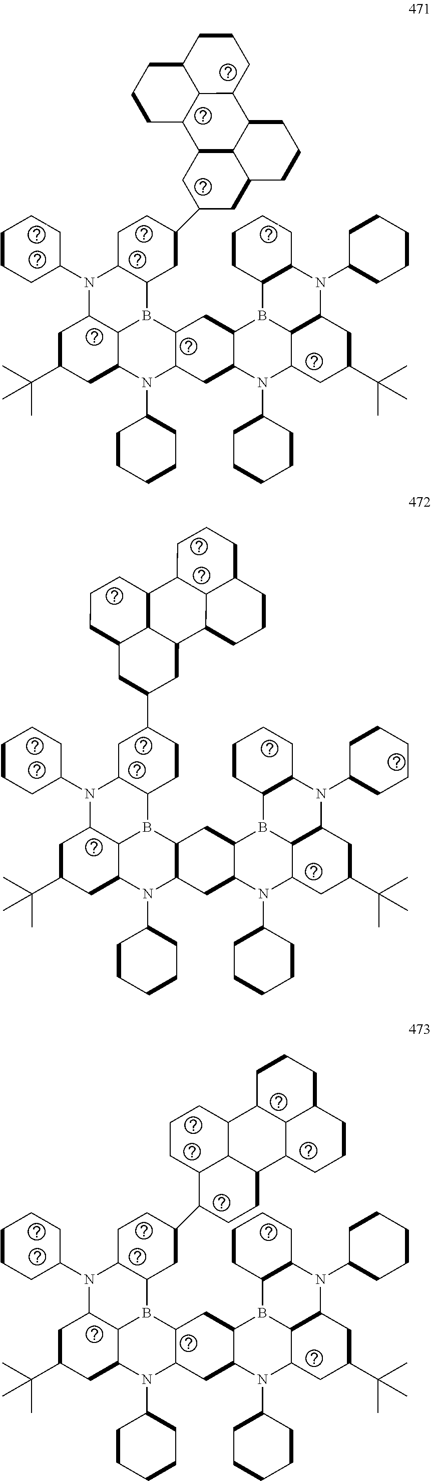 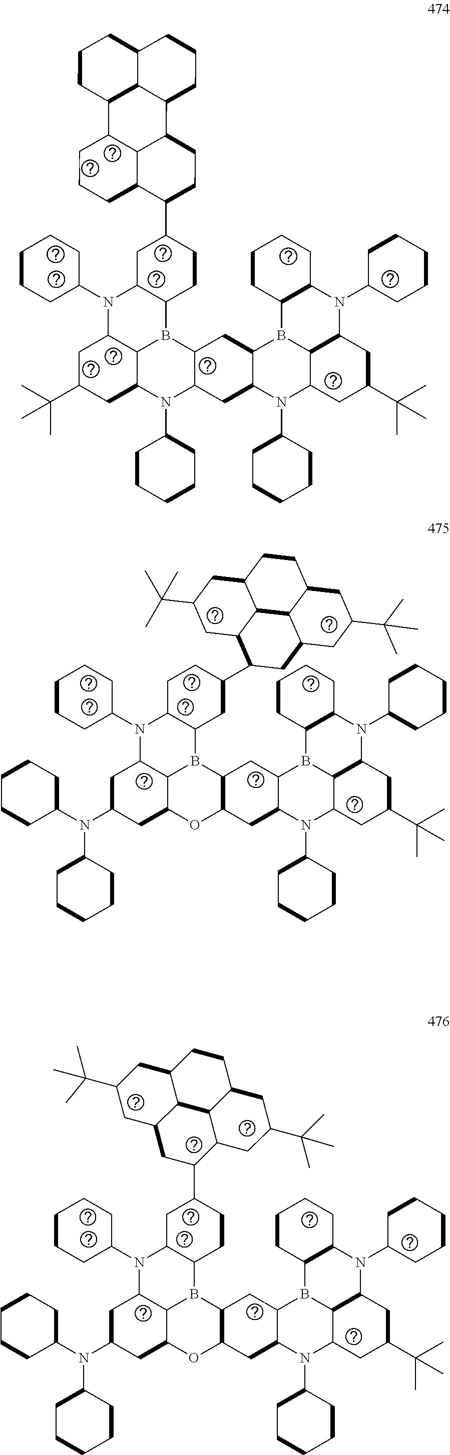 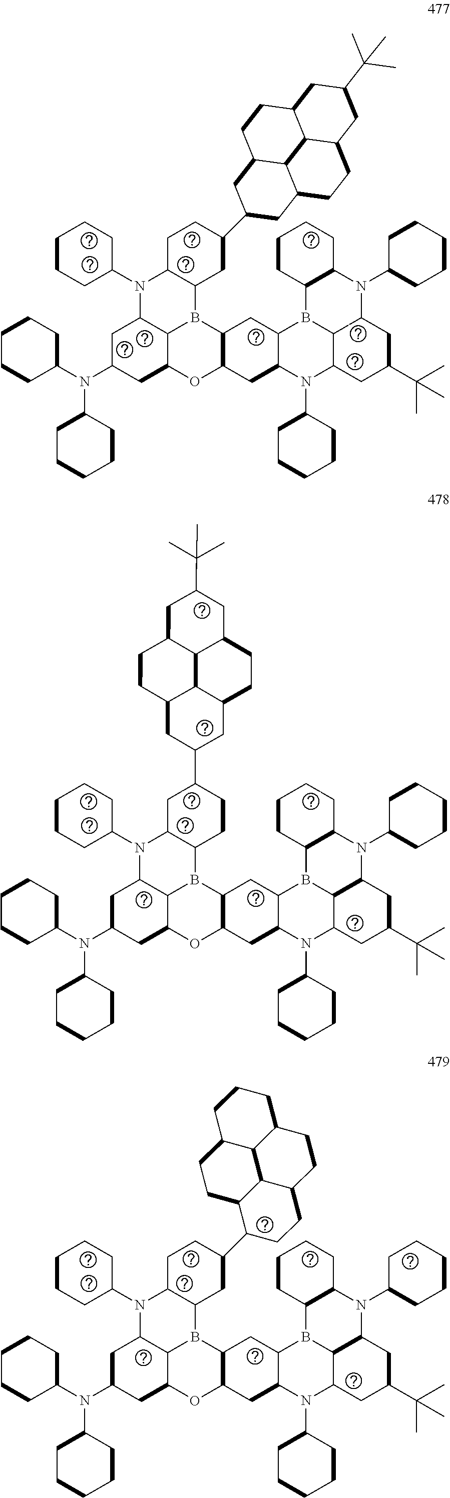 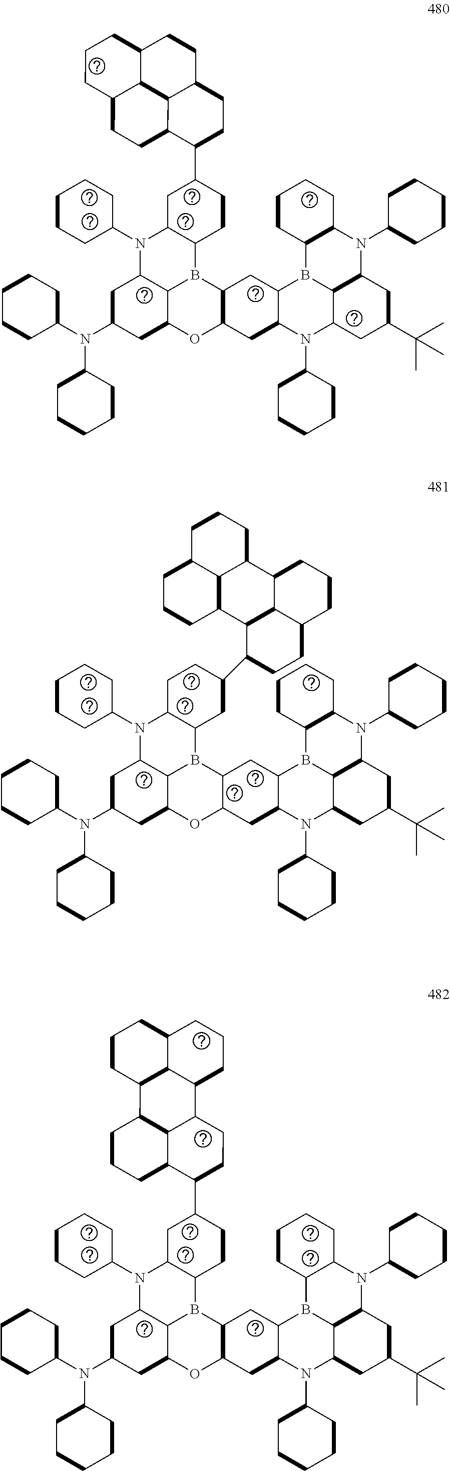 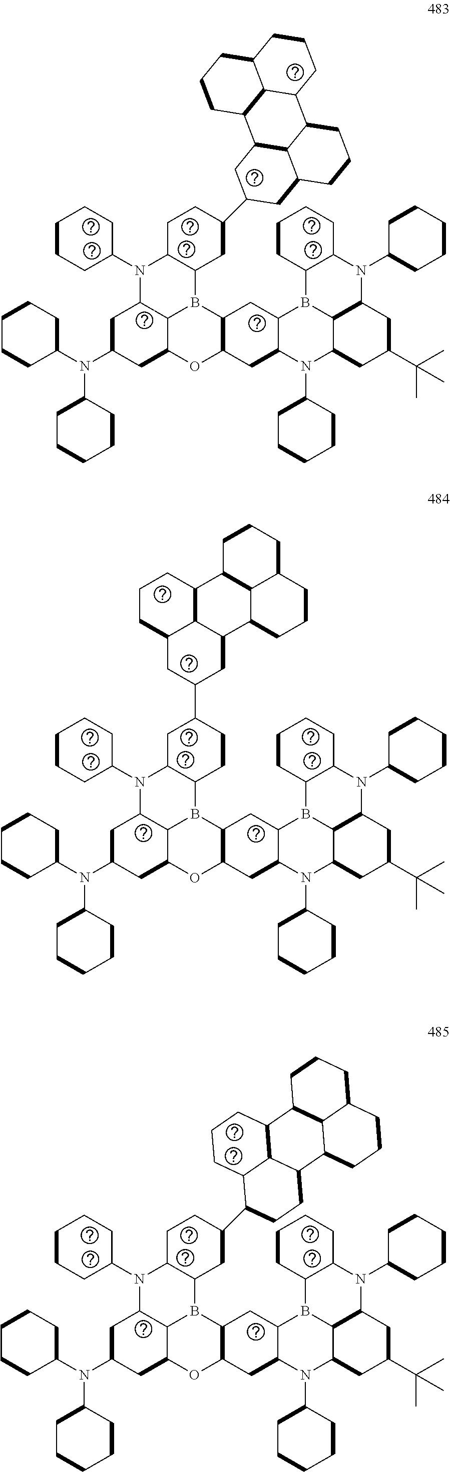 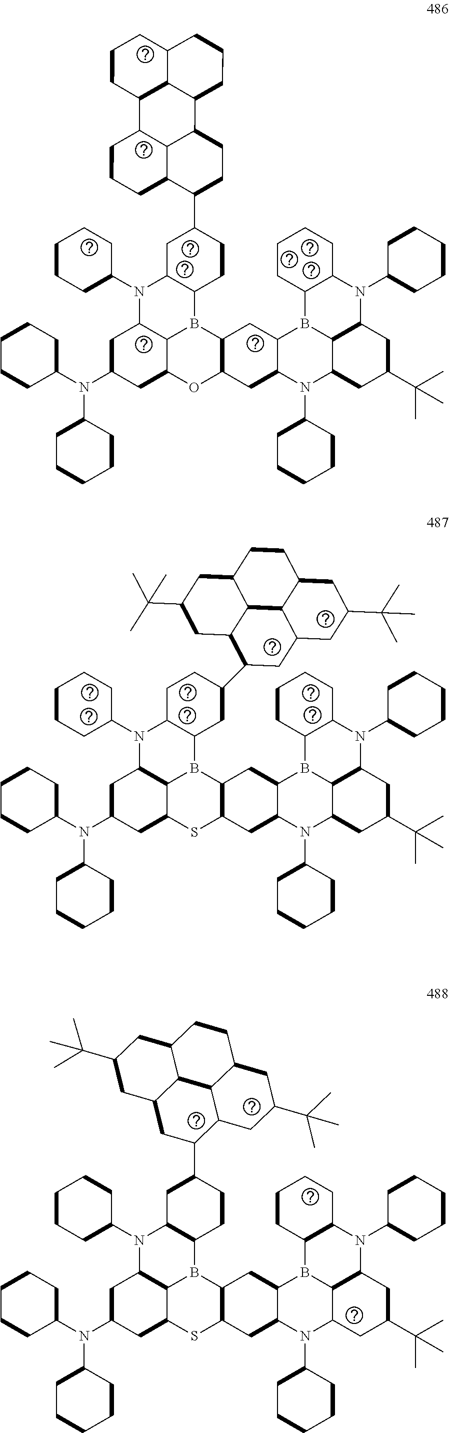 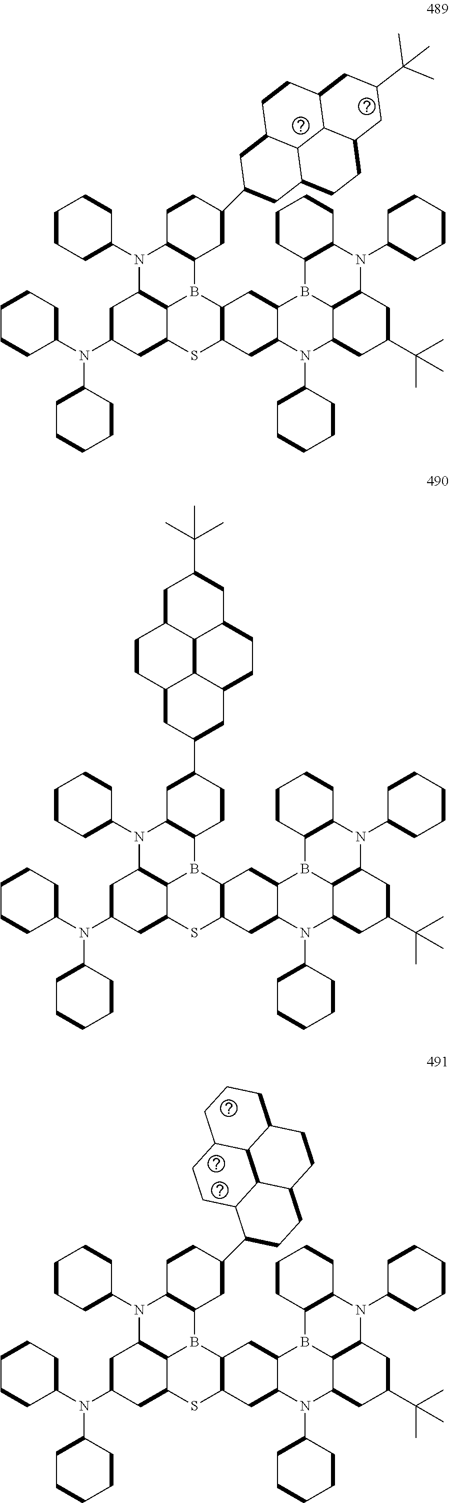 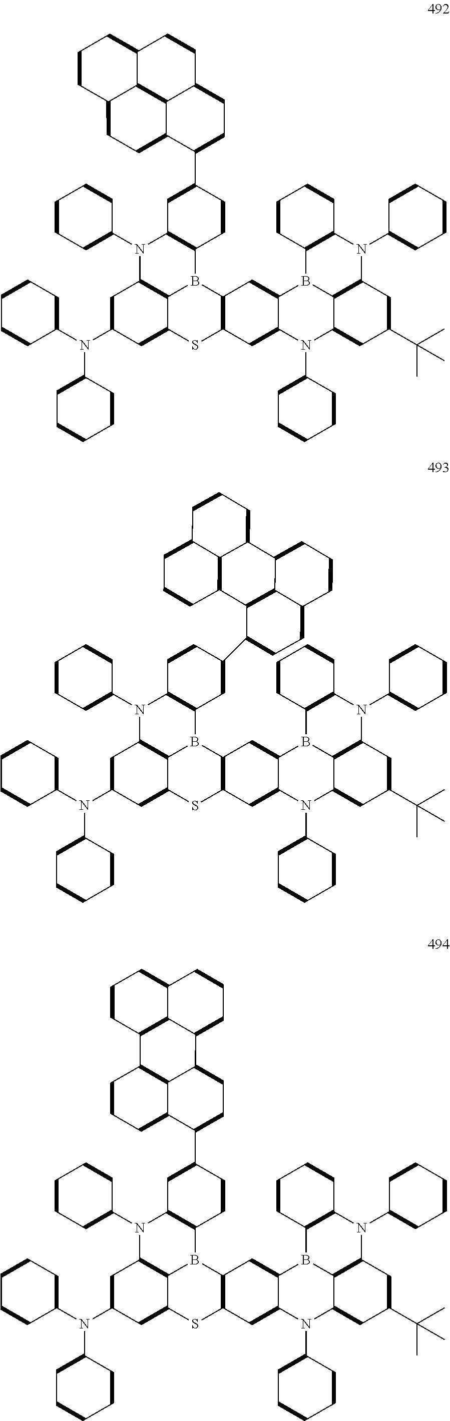 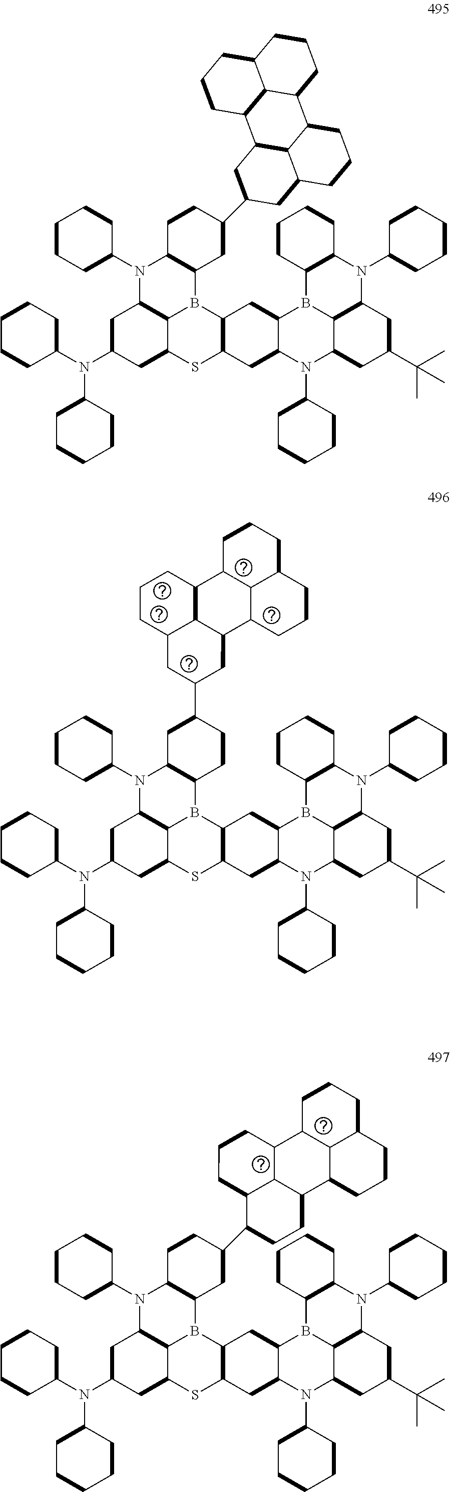 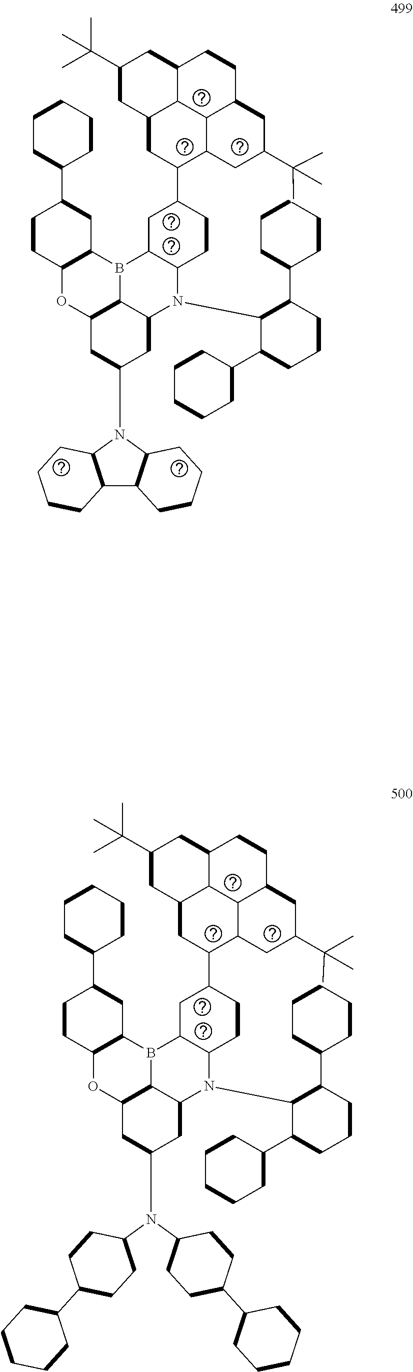 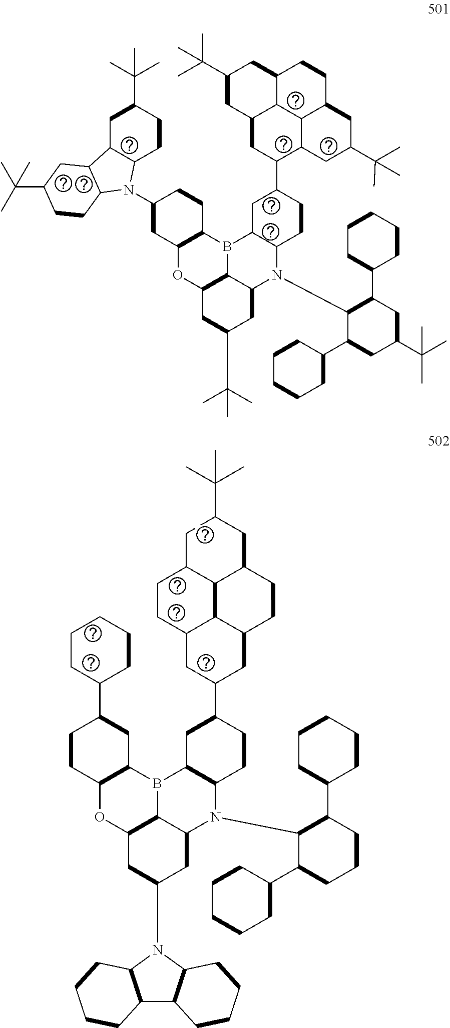 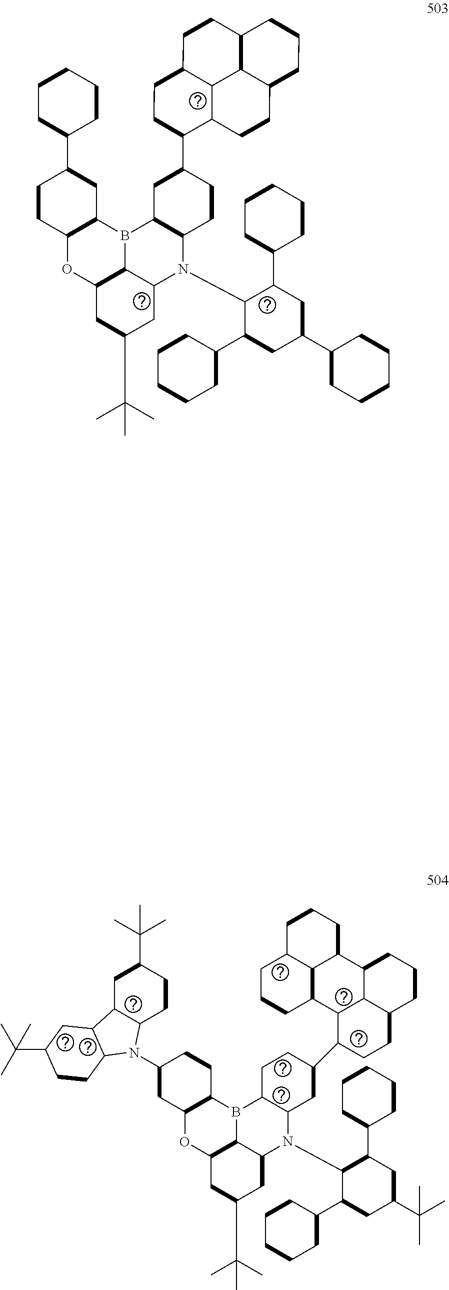 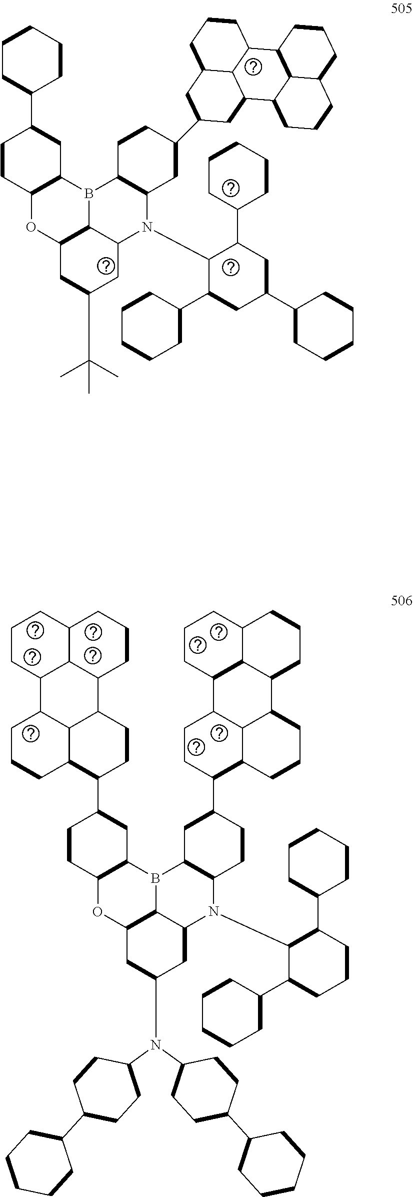 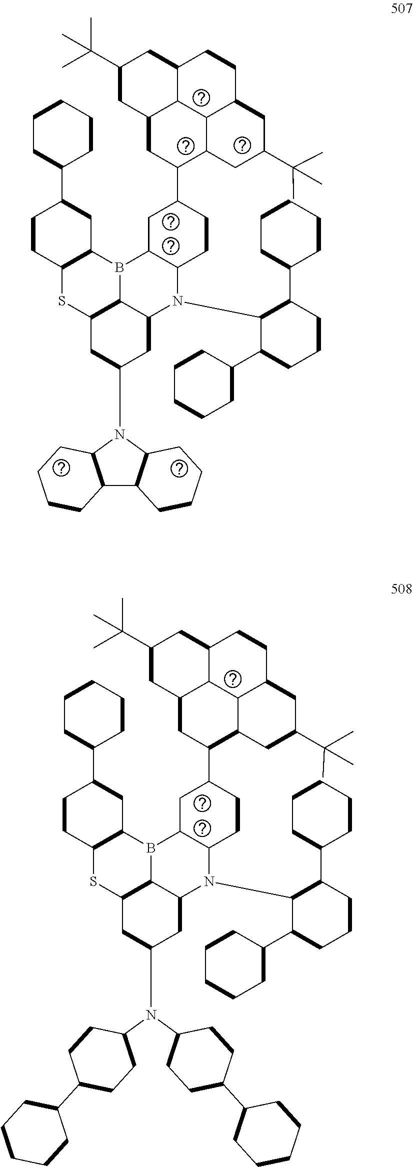 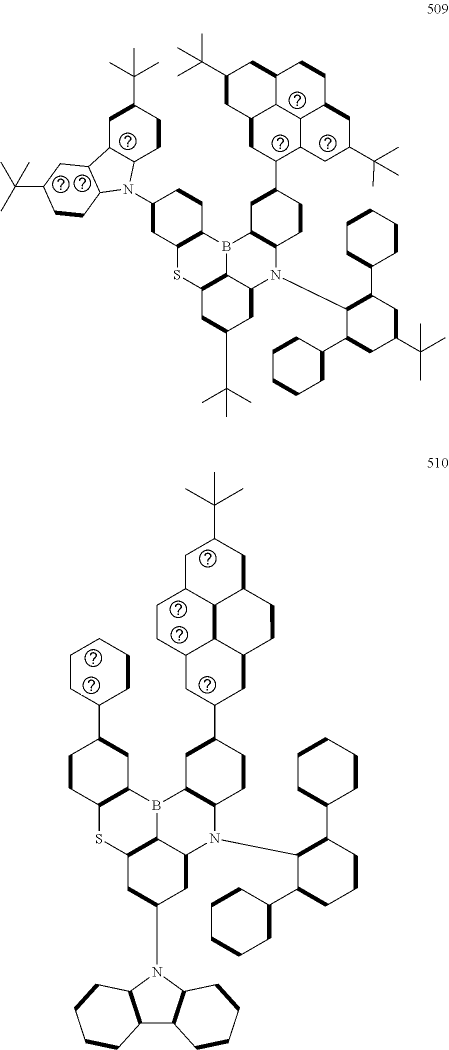 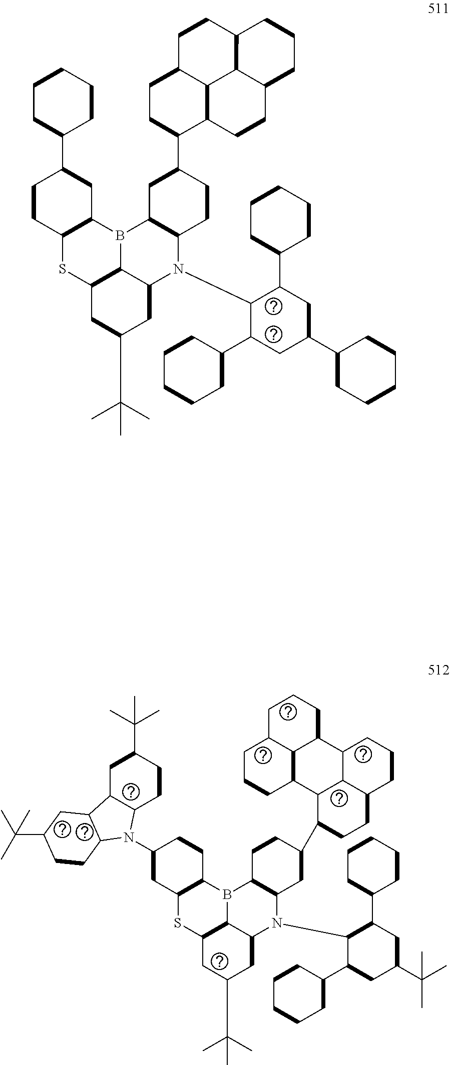 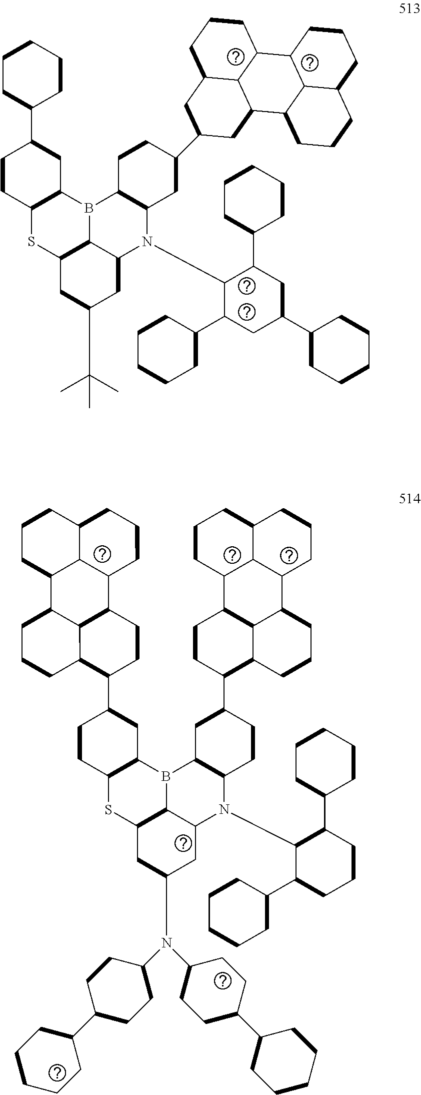 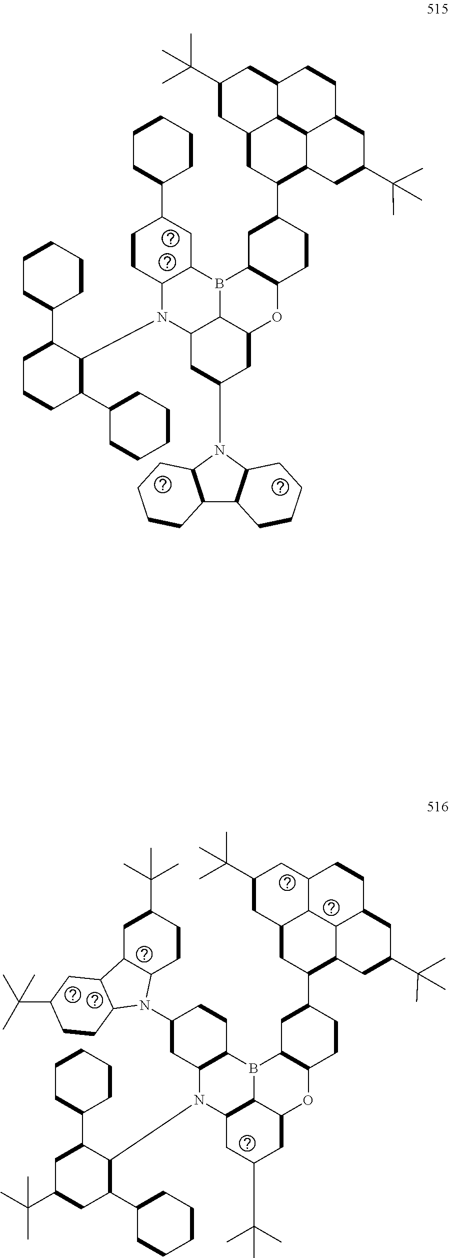 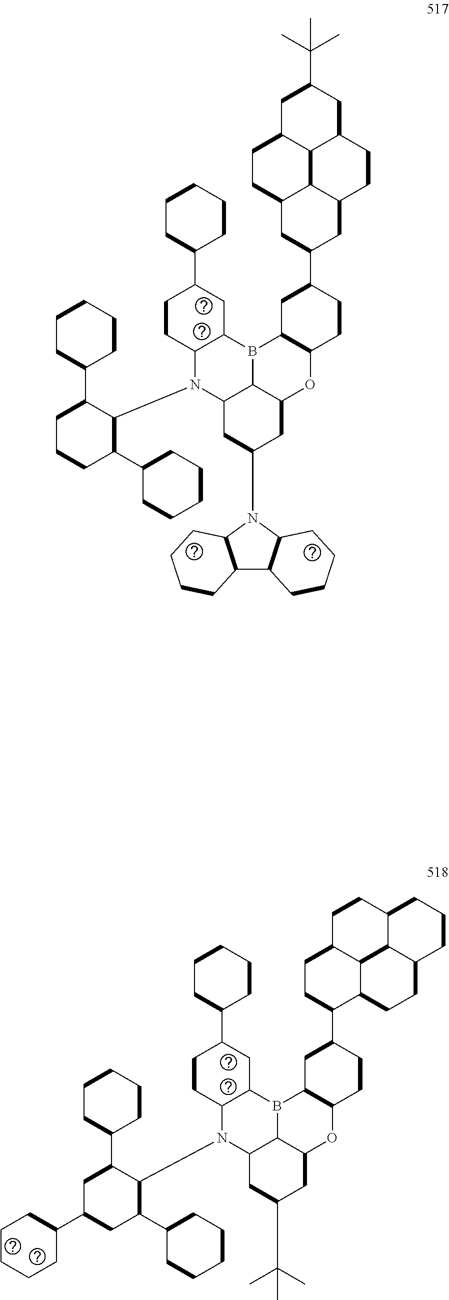 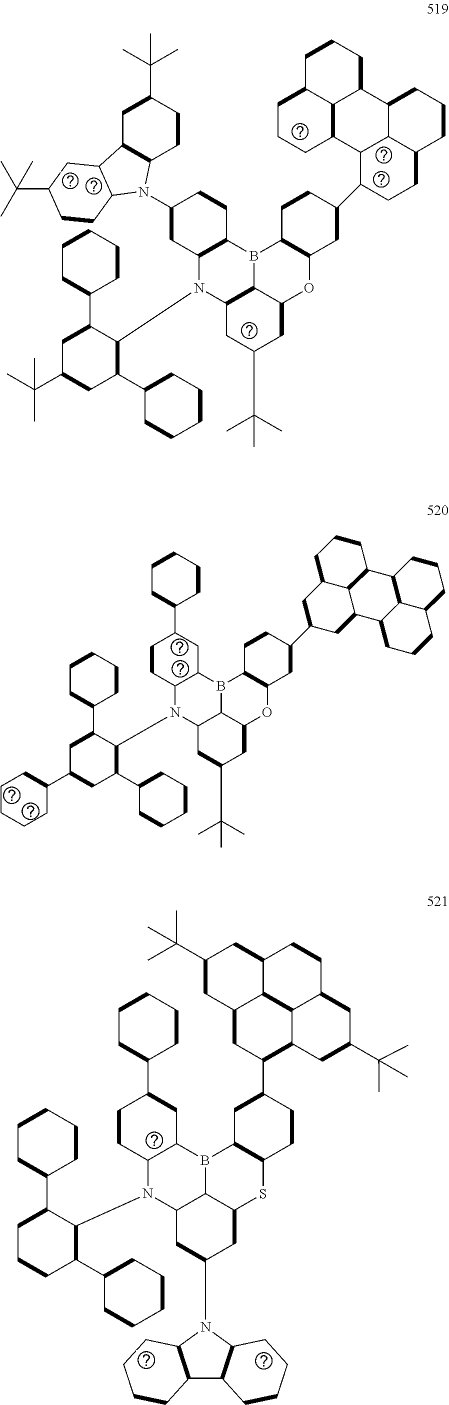 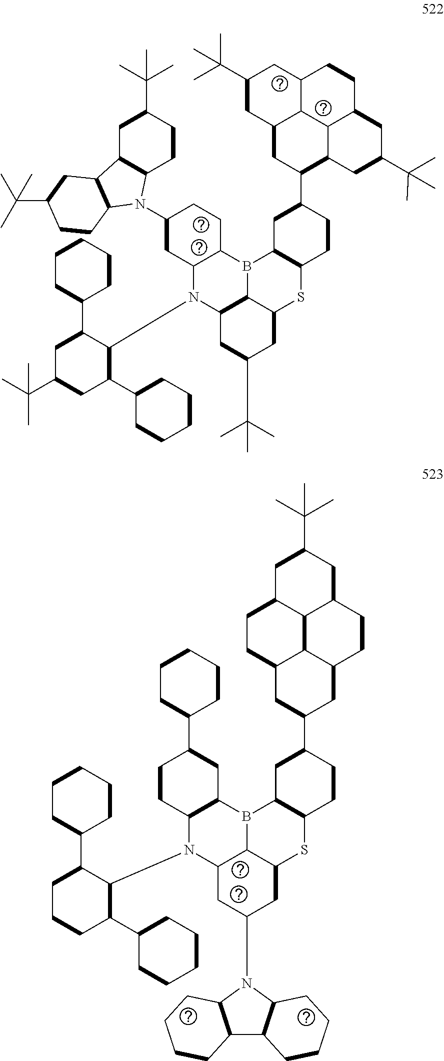 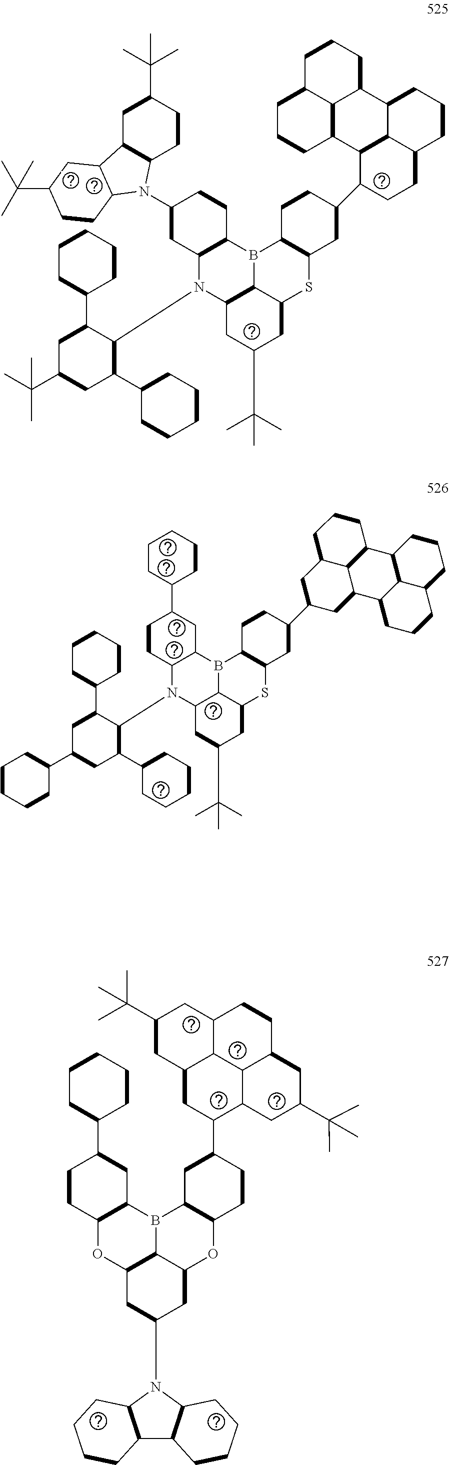 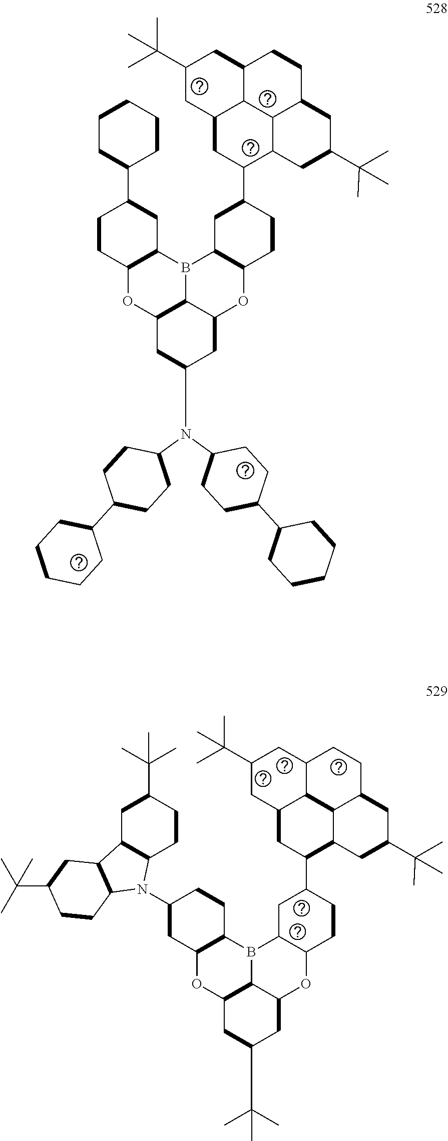 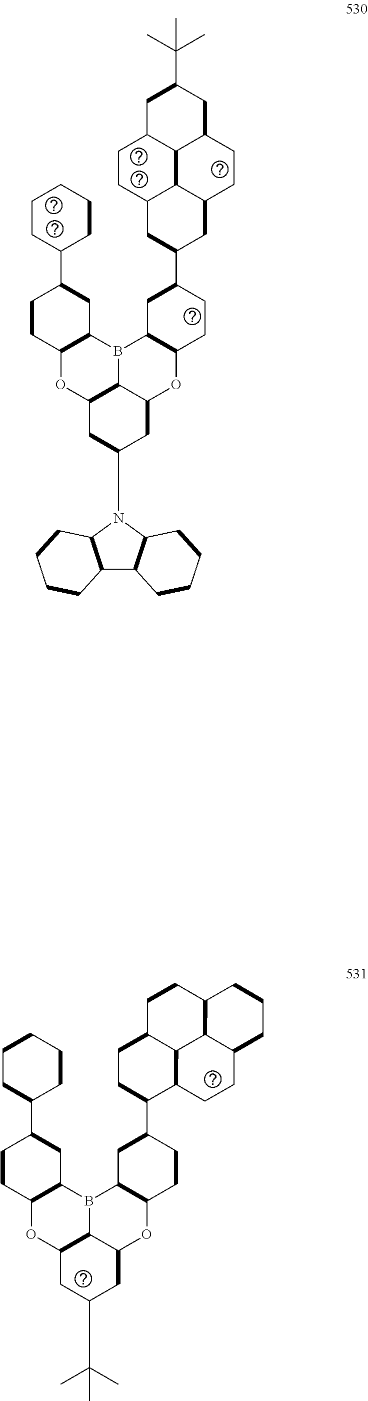 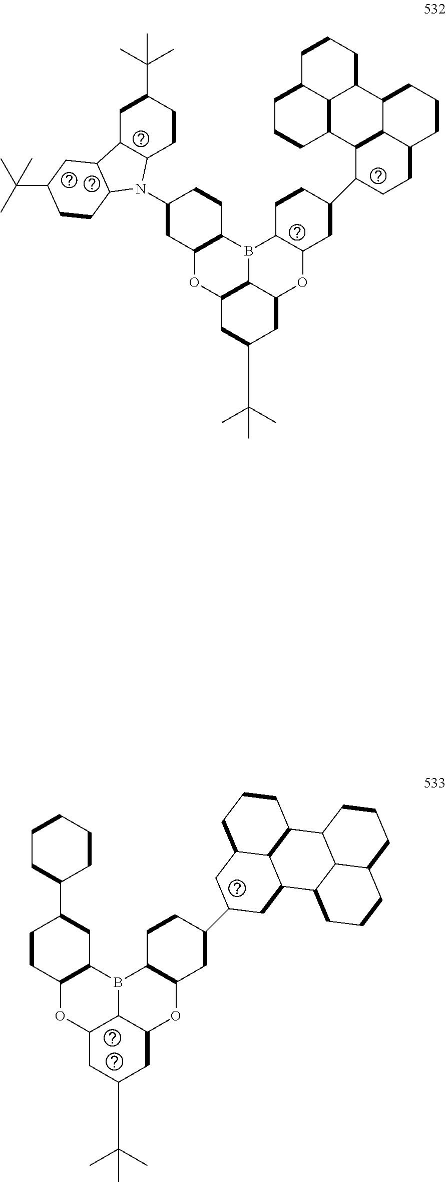 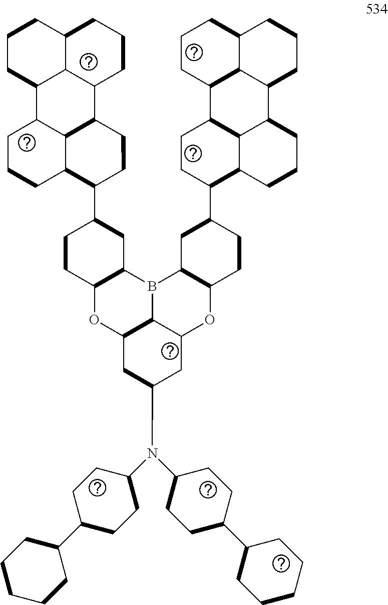 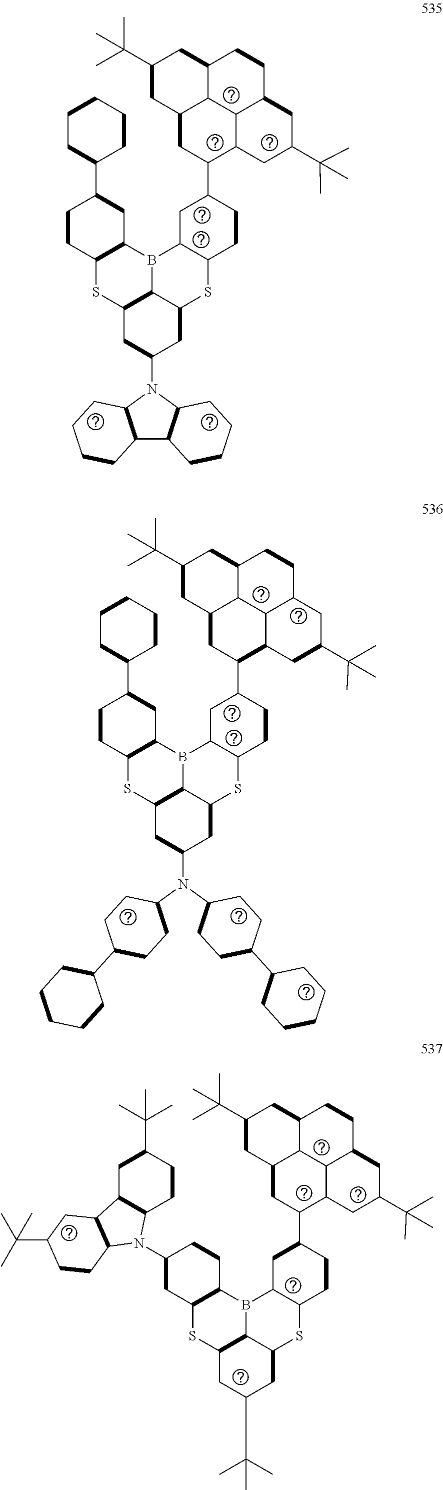 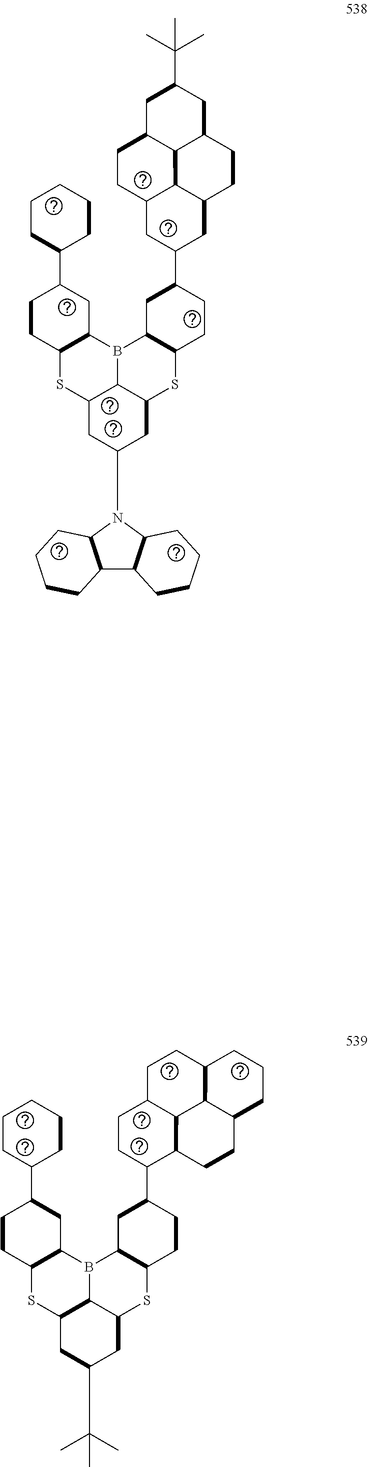 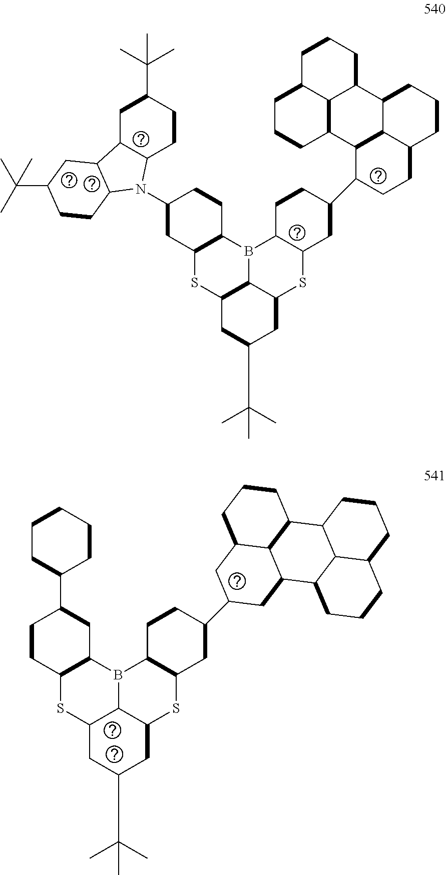 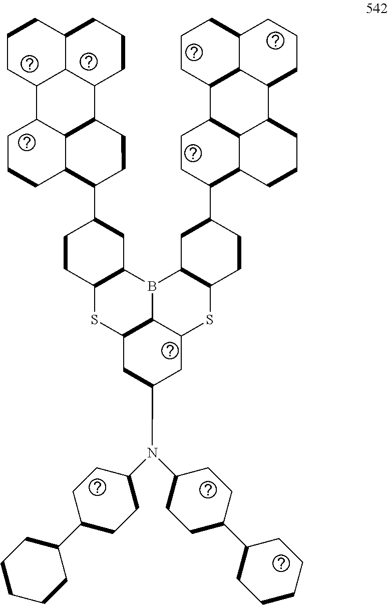 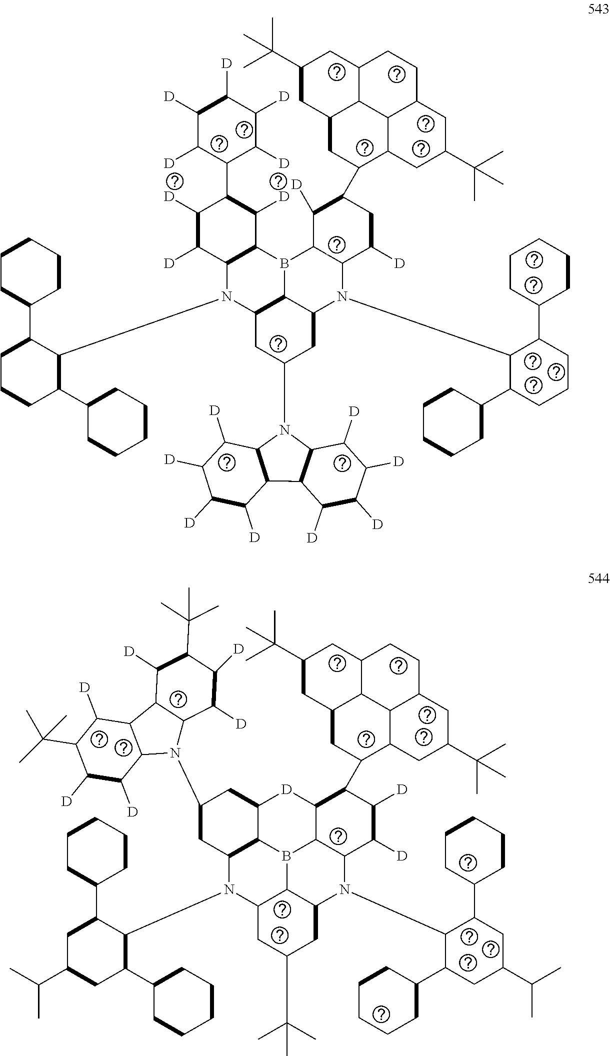 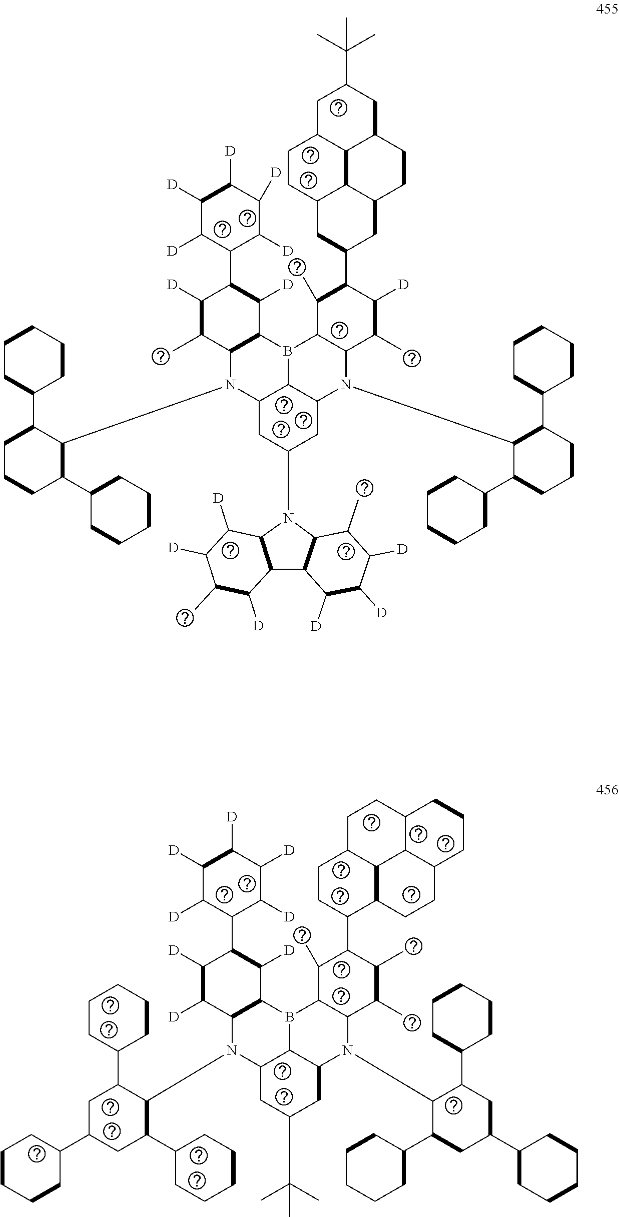 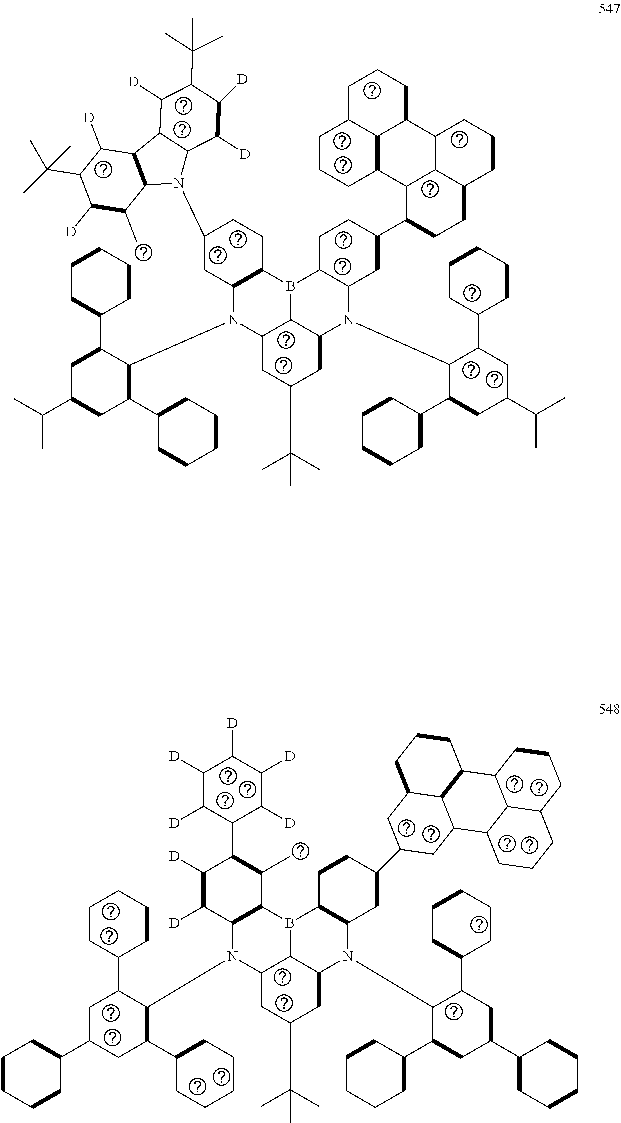 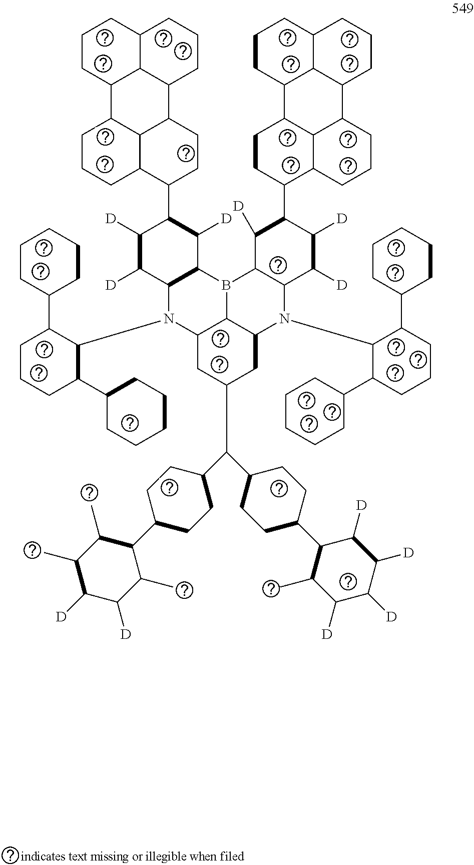
wherein in Compound Group 1,
D represents a deuterium atom.
